(19) United States
(12) Patent Application Publication
(10) Pub. No.: US 2024/0381755 A1
(43) Pub. Date: Nov. 14, 2024

(54) Metal-Assisted Delayed Fluorescent Emitters Employing Benzo-imidazo-phenanthridine and Analogues

(71) Applicant: Arizona Board of Regents on behalf of Arizona State University, Scottsdale, AZ (US)

(72) Inventors: Jian Li, Tempe, AZ (US); Yunlong Ji, Mesa, AZ (US)

(21) Appl. No.: 18/633,298

(22) Filed: Apr. 11, 2024

Related U.S. Application Data
(63) Continuation of application No. 17/332,100, filed on May 27, 2021, now Pat. No. 12,010,908.
Application No. 17/332,100 is a continuation of application No. 16/668,010, filed on Oct. 30, 2019, now Pat. No. 11,063,228.
Application No. 16/668,010 is a continuation of application No. 15/983,680, filed on May 18, 2018, now Pat. No. 10,516,117.
(60) Provisional application No. 62/508,560, filed on May 19, 2017.
(60) Provisional application No. 62/508,782, filed on May 19, 2017.

(51) Int. Cl. H10K 85/30; C07F 15/00; C09K 11/06; H10K 50/11; H10K 50/854; H10K 101/10

(52) U.S. Cl. CPC H10K 85/341; C07F 15/0033; C07F 15/006; C07F 15/0086; C09K 11/06; H10K 85/342; H10K 85/346; C09K 2211/1044; C09K 2211/1074; C09K 2211/185; H10K 50/11; H10K 50/854; H10K 2101/10

(57) ABSTRACT

Metal-assisted delayed fluorescent emitters employing benzo-imidazo-phenanthridine and analogues for full color displays and lighting applications.

### CROSS-REFERENCE TO RELATED APPLICATIONS

This application claims the benefit of U.S. Application No. 62/508,560 entitled “METAL-ASSISTED DELAYED FLUORESCENT EMITTERS EMPLOYING BENZO-IMIDAZO-PHENANTHRIDINE AND ANALOGUES” and U.S. Application No. 62/508,782 entitled “OCTAHEDRAL IRIDIUM (III) METAL-ASSISTED DELAYED FLUORESCENT EMITTERS EMPLOYING BENZO-IMIDAZO-PHENANTHRIDINE AND ANALOGUES,” both of which were filed on May 19, 2017, and both of which are incorporated herein by reference in their entirety.

### STATEMENT OF GOVERNMENT INTEREST

This invention was made with government support under DE-EE0007090 awarded by the Department of Energy. The government has certain rights in the invention.

### TECHNICAL FIELD

This invention relates to metal-assisted delayed fluorescent (MADF) emitters employing benzo-imidazo-phenanthridine and analogues for full color displays and lighting applications.

### BACKGROUND

Compounds capable of absorbing or emitting light can be used in a variety of optical and electro-optical devices, including photo-absorbing devices (e.g., solar- and photo-sensitive devices), photo-emitting devices, organic light-emitting diodes (OLEDs), and devices capable of photo-absorption and photo-emission. Much research has been devoted to the discovery and optimization of organic and organometallic materials for use in optical and electro-optical devices. Metal complexes can be used for many applications, such as emitters for OLEDs. Despite advances in research devoted to optical and electro-optical materials, many currently available materials exhibit a number of disadvantages, including poor processing ability, inefficient emission or absorption, and insufficient stability.

### SUMMARY

General Formulas I-III represent MADF emitters based on cyclic platinum (II) and palladium (II) complexes employing benzo-imidazo-phenanthridine and analogues.

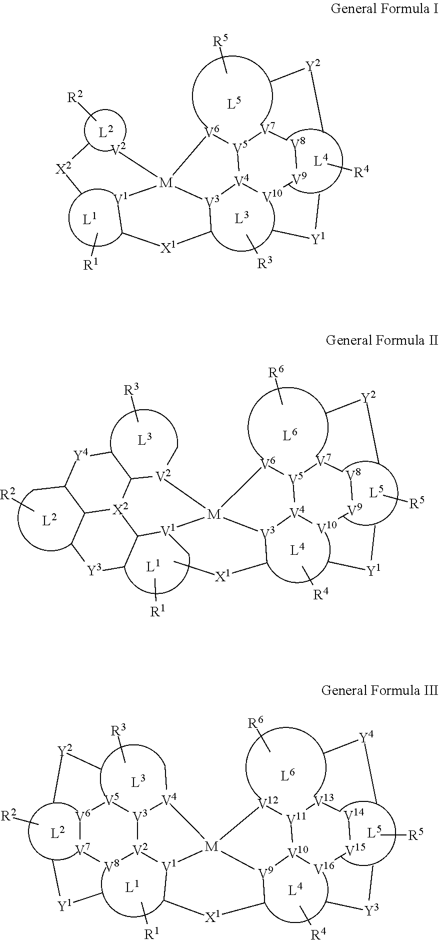

### In General Formulas I-III:

M is Pt (II) or Pd (II),
each of V¹-V¹⁶, if present, is independently C, N, Si, O, S, Ge, P, As, Se, B, Al, or Bi,
each of X¹, X², Y¹, Y², Y³, and Y⁴ is independently present or absent, and each X¹, X², Y¹, Y², Y³, and Y⁴ present independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R⁸, NR⁷, PR⁷, PR⁷R⁸, R⁷P═O, AsR⁷, R⁷As═O, S═O, SO₂, Se═O, SeO₂, BR⁷, BR⁷R⁸, AlR⁷, AlR⁷R⁸, R⁷Bi═O, or BiR⁷,
each of L¹, L², L³, and L⁴ is independently present or absent, and each L¹, L², L³, and L⁴ present independently represents a substituted or unsubstituted aryl, heteroaryl, or N-heterocyclic carbene, and
each of R, R¹, R², R³, R⁴, R⁵, R⁶, R⁷, and R⁸ is independently absent or present as a single substituent or multiple substituents, valency permitting, and each R, R¹, R², R³, R⁴, R⁵, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

General Formula IV represents MADF emitters based on cyclic platinum (II) and palladium (II) complexes employing benzo-imidazo-phenanthridine and analogues.

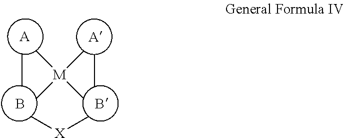

### In General Formula IV:

M is Pt (II) or Pd (II)
X represents a single bond or CR⁷R⁸, C═O, SiR⁷R⁸, GeR⁷R⁸, NR⁷, PR⁷, PR⁷R⁸, R⁷P═O, AsR⁷, R⁷As═O, O, S, S═O, SO₂, Se, Se═O, SeO₂, BR⁷, BR⁷R⁸, AlR⁷, AlR⁷R⁸, R⁷Bi═O, or BiR⁷,

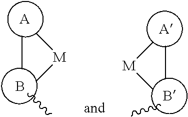

each independently represents one of the following chemical moieties:

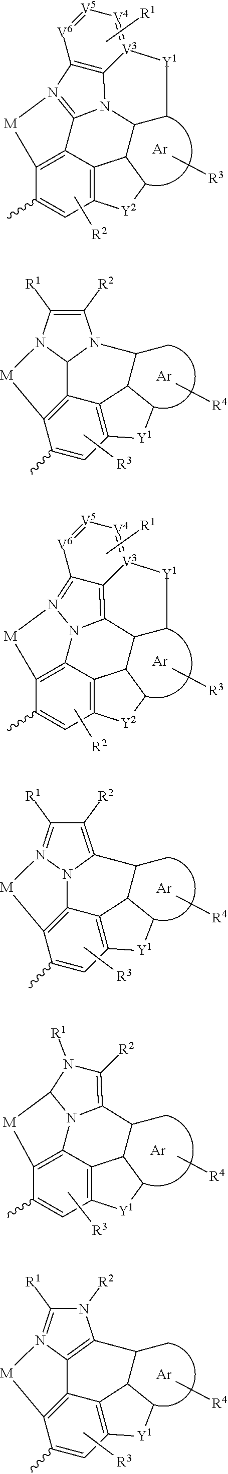

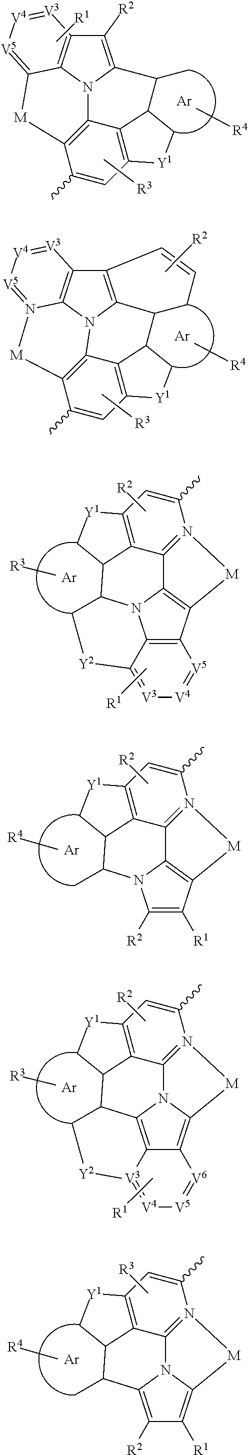

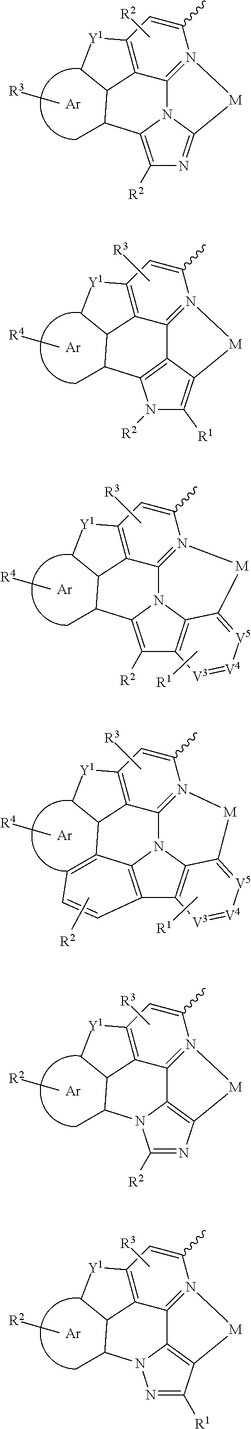

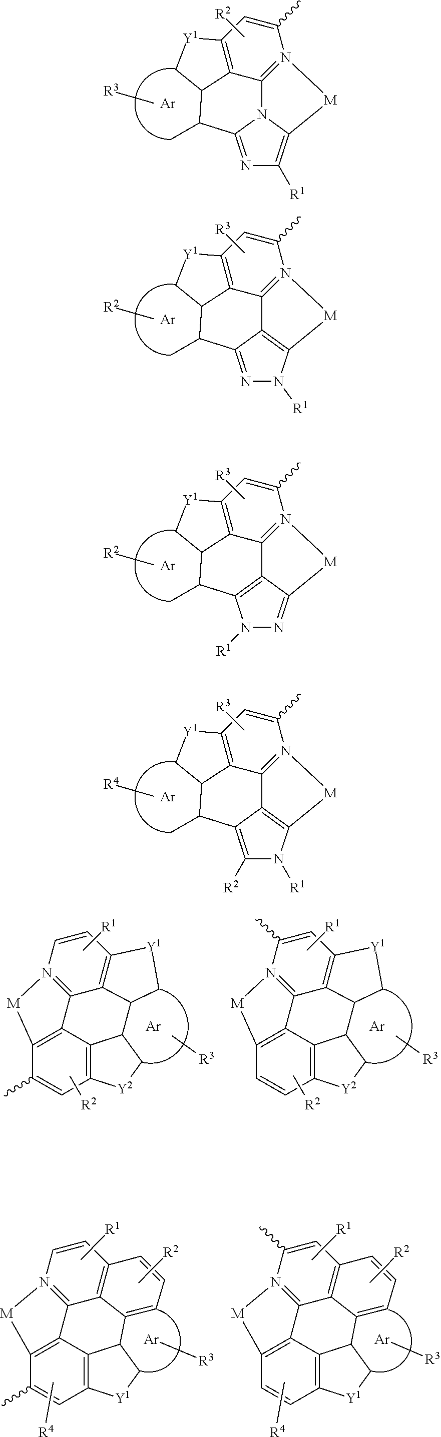

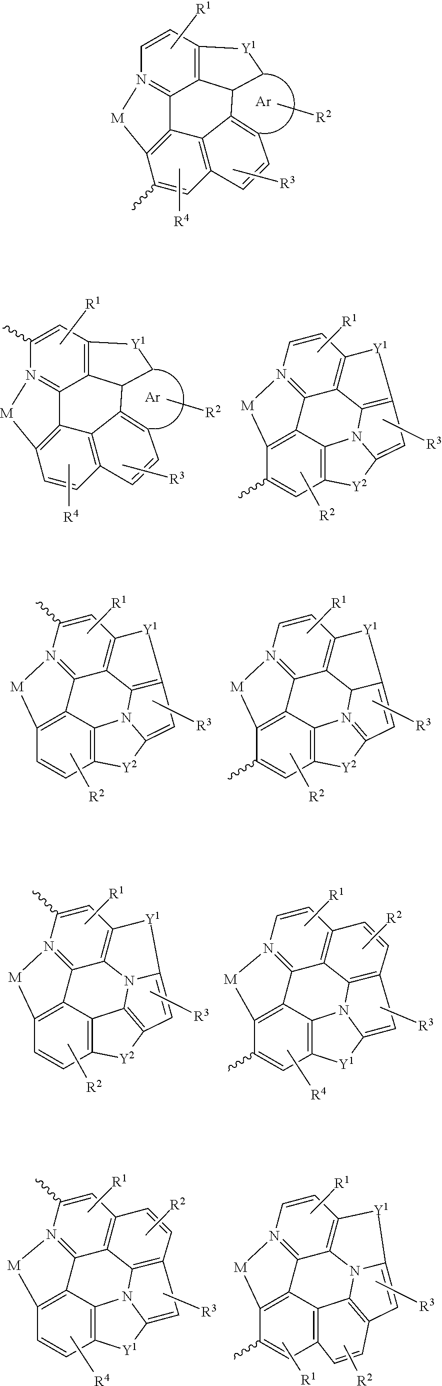

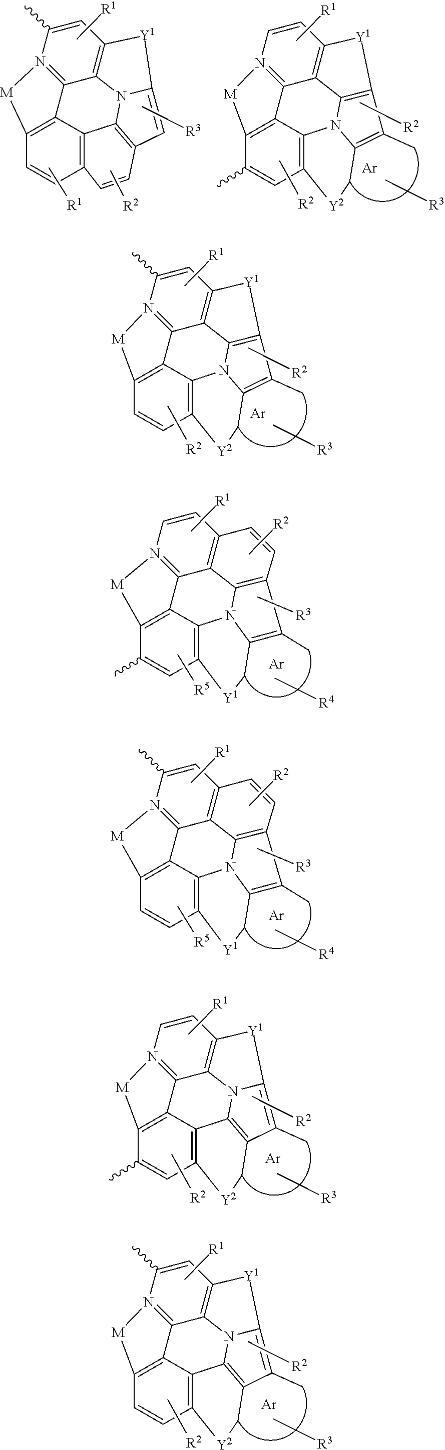

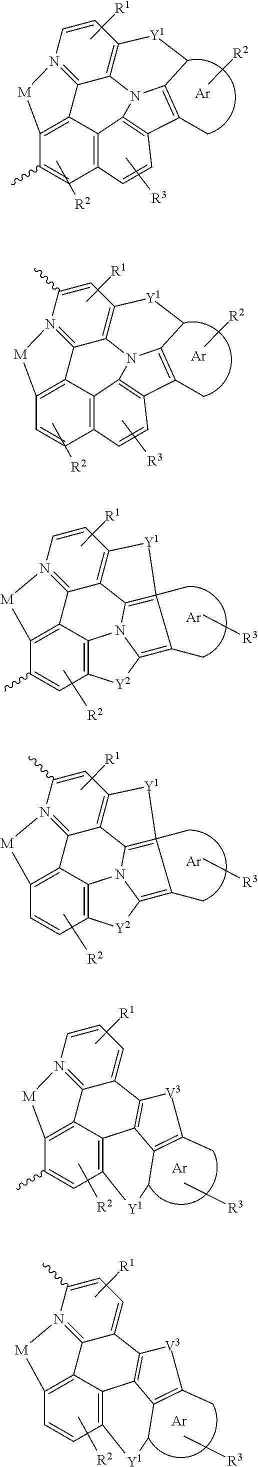

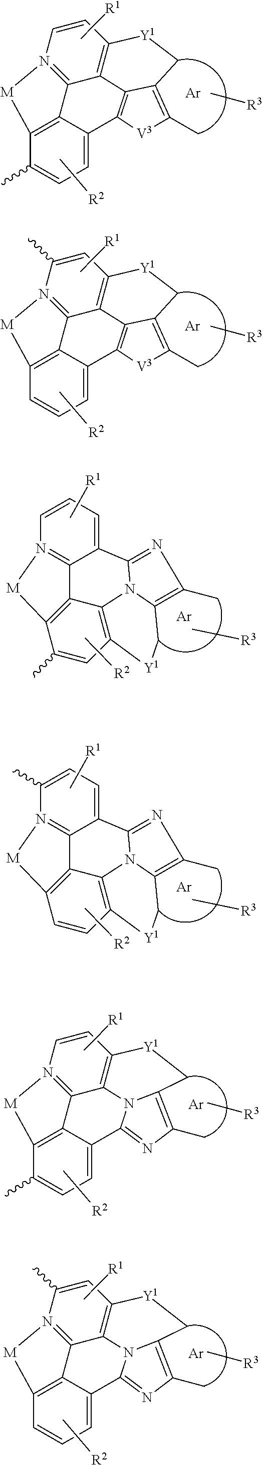

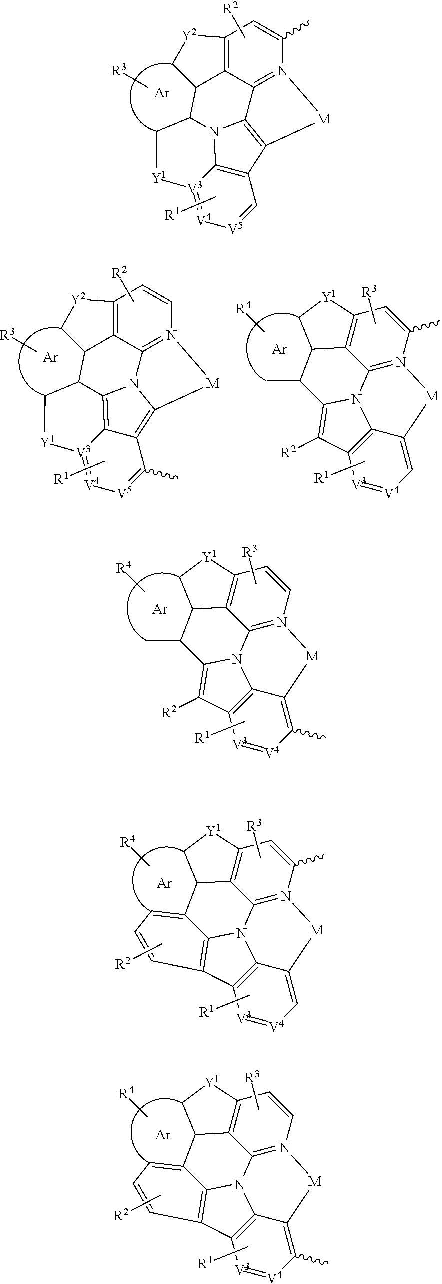

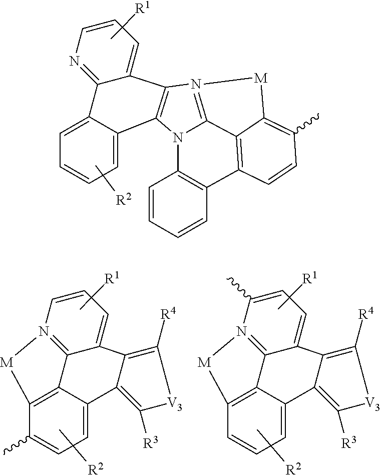

where:
N is nitrogen,
each of V¹, V², V³, V⁴, V⁵, and V⁶, if present, is independently C, N, Si, O, S, Ge, P, As, Se, B, Al, or Bi,
each of X¹, X², Y¹, Y², Y³, and Y⁴ is independently present or absent, and each X¹, X², Y¹, Y², Y³, and Y⁴ present independently represents C, N, Si, O, S, Ge, P, As, Se, B, Al, or Bi, or valency permitting, CR⁷, SiR⁷, GeR⁷, NR⁷, P═O, As═O, B, BR⁷, AlR⁷, Bi═O, CR⁷R⁸, C═O, SiR⁷R⁸, GeR⁷R⁸, NR⁷, PR⁷, PR⁷R⁸, R⁷P═O, AsR⁷, R⁷As═O, S═O, SO₂, Se═O, SeO₂, BR⁷, BR⁷R⁸, AlR⁷, AlR⁷R⁸, R⁷Bi═O, or BiR⁷,
each of L¹, L², L³, and L⁴ is independently present or absent, and each L¹, L², L³, and L⁴ present independently represents a substituted or unsubstituted aryl, heteroaryl, or N-heterocyclic carbene,
each of R, R¹, R², R³, R⁴, R⁵, R⁶, R⁷, and R⁸ is independently absent or present as a single substituent or multiple substituents, valency permitting, and each R, R¹, R², R³, R⁴, R⁵, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and
each of

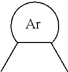

is independently present or absent, and each Ar present independently represents a substituted or unsubstituted aryl, heteroaryl, or N-heterocyclic carbene.

General Formulas V-XIII represent MADF emitters based on cyclic platinum (II) and palladium (II) complexes employing benzo-imidazo-phenanthridine and analogues.

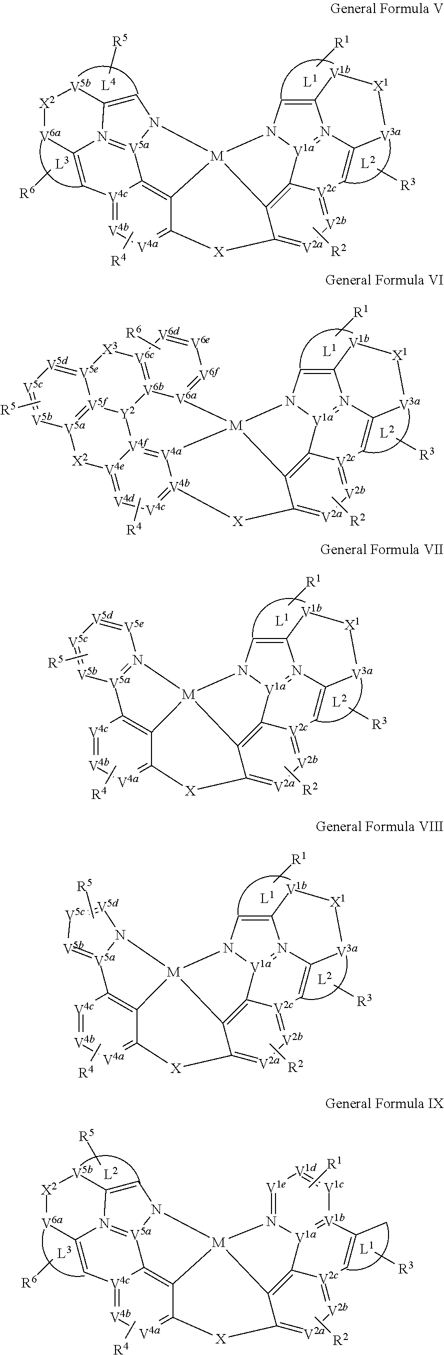

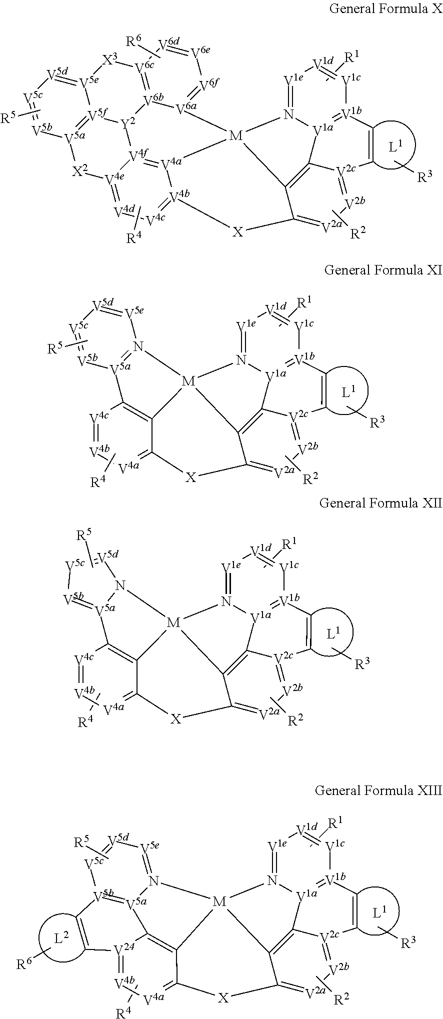

### In General Formulas V-XIII,

M is Pt (II) or Pd (II),
N is nitrogen,
each of V^{1a}-V^{1f}, V^{2a}-V^{2f}, V^{3a}-V^{3f}, v^{4a}-V^{4f}, V^{5a}-V^{5f}, and V^{6a}-V^{6f}, if present, is independently N, C, P, O, S, or Si,
each of X, X¹, X², X³, and X⁴ is independently present or absent, and each X, X¹, X², X³, and X⁴ present independently represents a single bond, CR⁷R⁸, C═O, SiR⁷R⁸, GeR⁷R⁸, NR⁷, PR⁷, PR⁷R⁸, R⁷P═O, AsR⁷, R⁷As═O, O, S, S═O, SO₂, Se, Se═O, SeO₂, BR⁷, BR⁷R⁸, AlR⁷, AlR⁷R⁸, R⁷Bi═O, or BiR⁷,
each of Y¹ and Y² is independently CR, SiR, GeR, N, NR, P, P═O, As, As═O, B, BR, Al, AlR, Bi═O, or Bi,
each of L¹, L², L³, and L⁴ is independently present or absent, and each L¹, L², L³, and L⁴ present independently represents a substituted or unsubstituted aryl, heteroaryl, or N-heterocyclic carbene,
each of R, R¹, R², R³, R⁴, R⁵, R⁶, R⁷, and R⁸ is independently absent or present as a single substituent or multiple substituents, valency permitting, and each R, R¹, R², R³, R⁴, R⁵, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

Octahedral iridium (III) metal-assisted delayed fluorescent (MADF) emitters employing benzo-imidazo-phenanthridine are represented by General Formulas XIV-XVII.

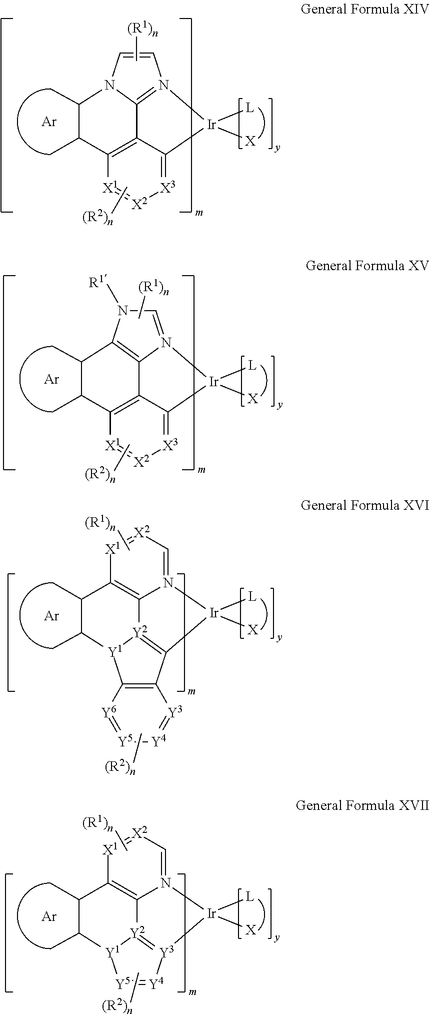

In General Formulas XIV-XVII, y=0, 1, or 2, and m+y=3. For m=3, the moieties can be the same or different. That is, when m=3, the three moieties can be the same, two of the moieties can be the same, or all three of the moieties can be different.

Implementations include a light emitting diode including a complex of General Formulas I-XVII, and a lighting device including such light emitting diode.

These general and specific aspects may be implemented using a device, system or method, or any combination of devices, systems, or methods. The details of one or more embodiments are set forth in the accompanying drawings and the description below. Other features, objects, and advantages will be apparent from the description and drawings, and from the claims.

### BRIEF DESCRIPTION OF THE DRAWINGS

FIG. 1 depicts a cross-sectional view of an organic light-emitting device.

FIG. 2 is an emission spectrum of the metal-assisted delayed fluorescent emitter of Example 3 in tehtrahydro-2-methylfuran at 77K.

FIG. 3 is an emission spectrum of the metal-assisted delayed fluorescent emitter of Example 12 in tehtrahydro-2-methylfuran at 77K.

FIG. 4 is an emission spectrum of the metal-assisted delayed fluorescent emitter of Example 27 in methylene chloride at room temperature.

FIGS. 5A-5C show external quantum efficiency (EQE) versus luminance. EQE versus current density, and an electroluminescent spectrum, respectively, for a light-emitting device including the emitter of Example 46.

FIGS. 6A-6C show external quantum efficiency (EQE) versus luminance, EQE versus current density, and an electroluminescent spectrum, respectively, for a light-emitting device including the emitter of Example 46.

### DETAILED DESCRIPTION

Cyclometalated Pt (II) and Pd (II) complexes have found wide applications as emitters for OLEDs in recent decades. Metal-assisted delayed fluorescent (MADF) emitters based on Pt (II) and Pd (II) complexes can exhibit both singlet and triplet excitons, resulting in a unity internal quantum efficiency and short lifetimes. Through the judicious design of cyclometalating ligands, MADF emitters can display singlet-triplet energy splitting.

MADF emitters based on cyclic platinum (II) and palladium (II) complexes employing benzo-imidazo-phenanthridine and analogues are disclosed. The triplet state consists mostly of the lower energy C\hat{ }N portion of the molecules which is localized on the benzo-imidazo-phenanthridine (or analogues). The singlet energy can be reduced by extending the conjugation of benzo-imidazo-phenanthridine (or analogues) with no or little energy change of triplet energy. The small energy gap between singlet and triplet allows excitons to be thermally promoted to the singlet state and efficiently emitted via thermally assisted delayed fluorescence (TADF) while the remaining triplet excitons can emit via the available efficient phosphorescent pathway. This class of emitters is suitable for full color displays and lighting applications.

MADF emitters employing benzo-imidazo-phenanthridine and analogues include compounds of General Formulas I-III shown below.

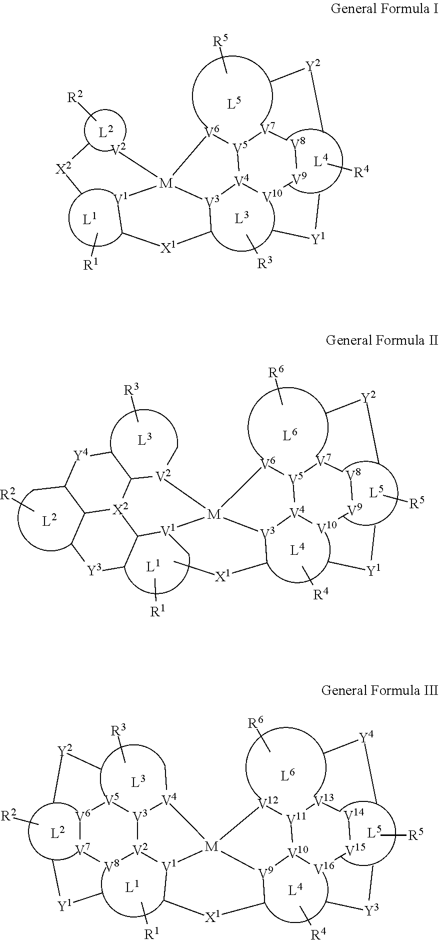

### In General Formulas I-III:

M is Pt (II) or Pd (II),
each of V¹-V¹⁶, if present, is independently C, N, Si, O, S, Ge, P, As, Se, B, Al, or Bi,
each of X¹, X², Y¹, Y², Y³, and Y⁴ is independently present or absent, and each X¹, X², Y¹, Y², Y³, and Y⁴ present independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R⁸, NR⁷, PR⁷, PR⁷R⁸, R⁷P═O, AsR⁷, R⁷As═O, S═O, SO₂, Se═O, SeO₂, BR⁷, BR⁷R⁸, AlR⁷, AlR⁷R⁸, R⁷Bi═O, or BiR⁷,
each of L¹, L², L³, L⁴, L⁵, and L⁶ is independently present or absent, and each L¹, L², L³, L⁴, L⁵, and L⁶ present independently represents a substituted or unsubstituted aryl, heteroaryl, or N-heterocyclic carbene, and
each of R, R¹, R², R³, R⁴, R⁵, R⁶, R⁷, and R⁸ is independently absent or present as a single substituent or multiple substituents, valency permitting, and each R, R¹, R², R³, R⁴, R⁵, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

Examples of suitable substituents R¹-R⁸ include:

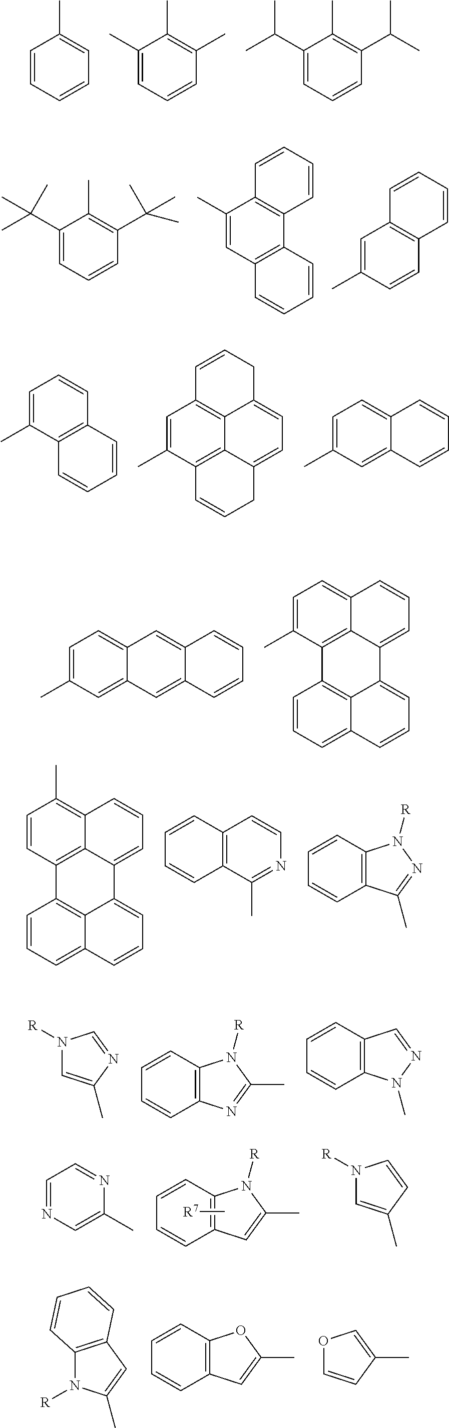

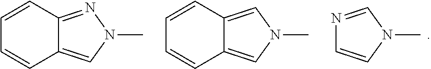

Examples of General Formulas I-III are shown below.

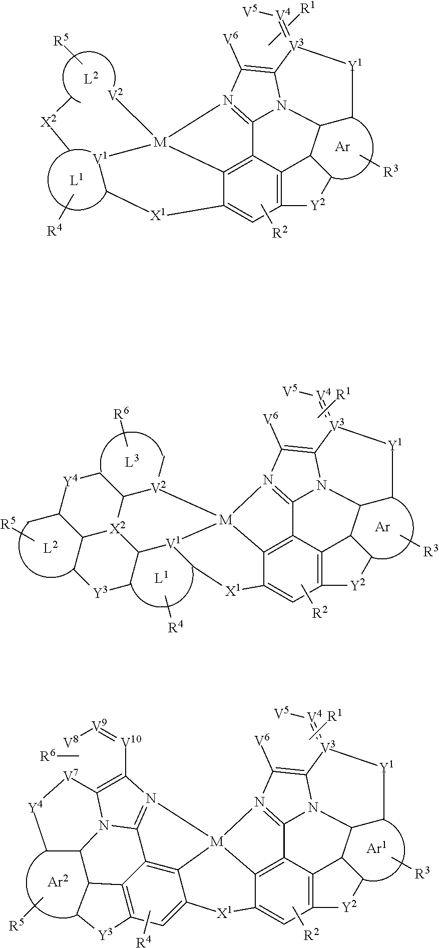

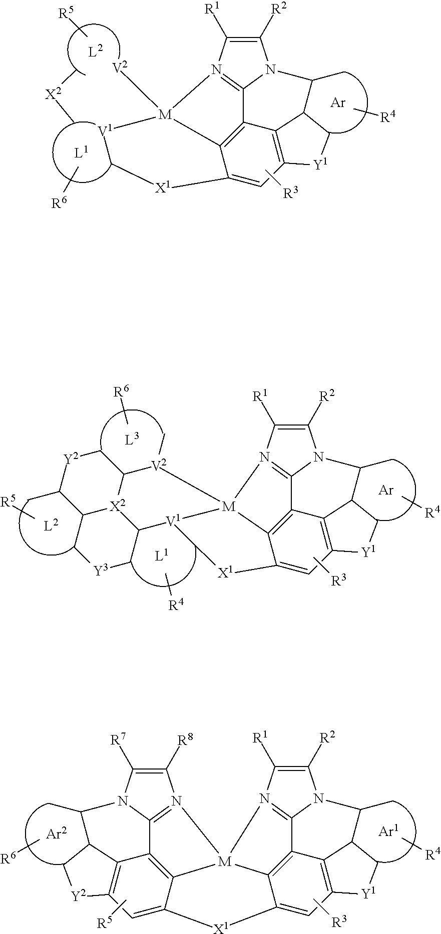

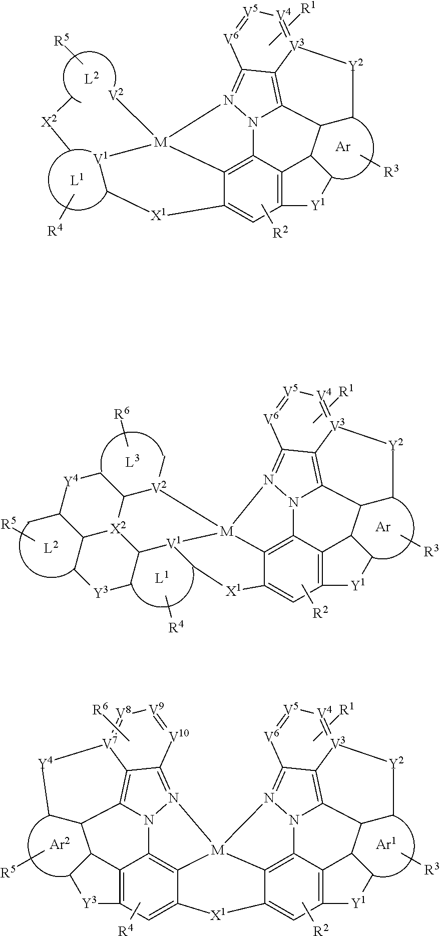

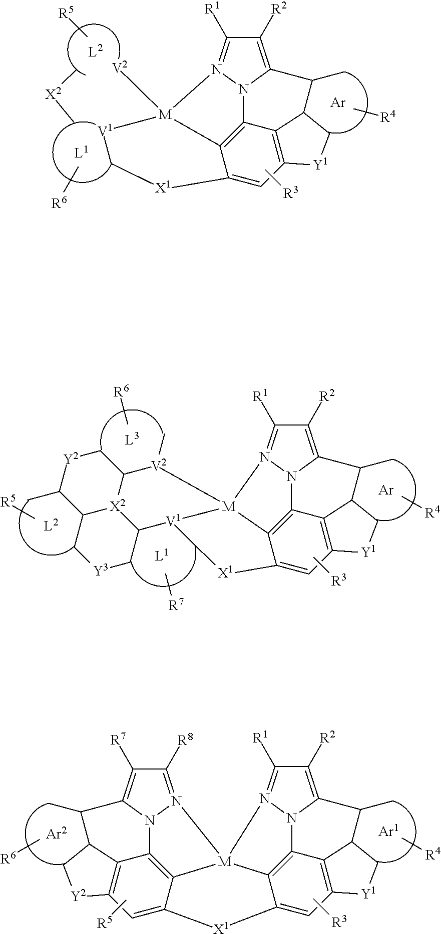

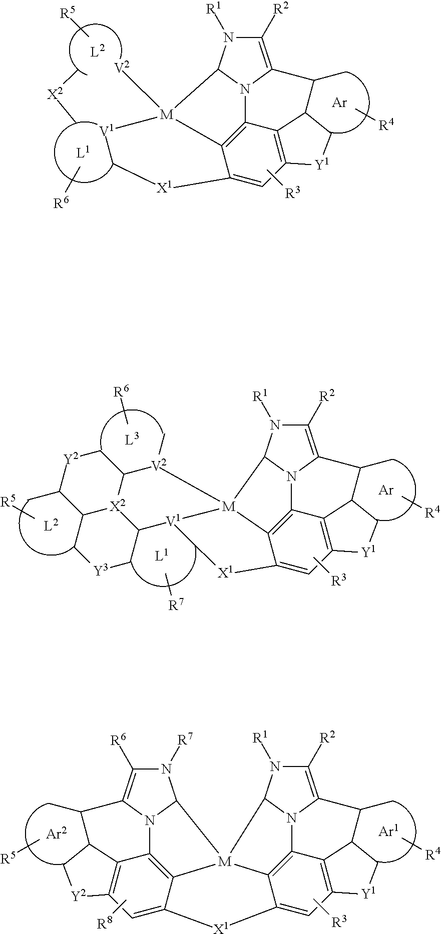

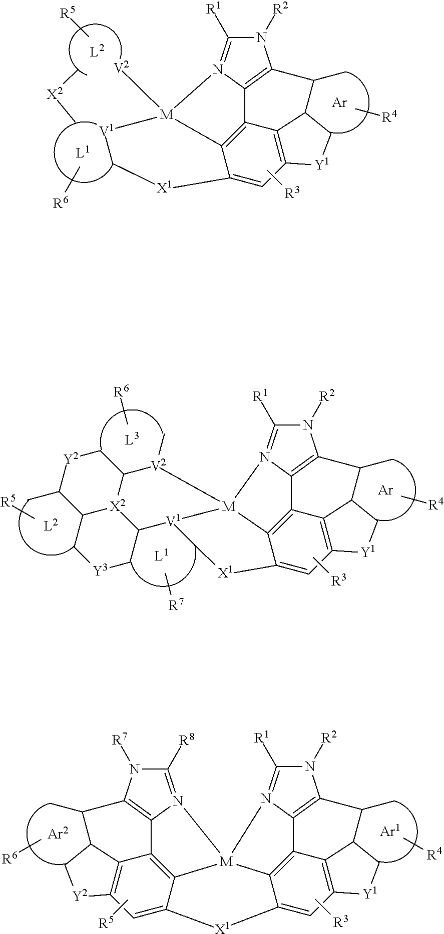

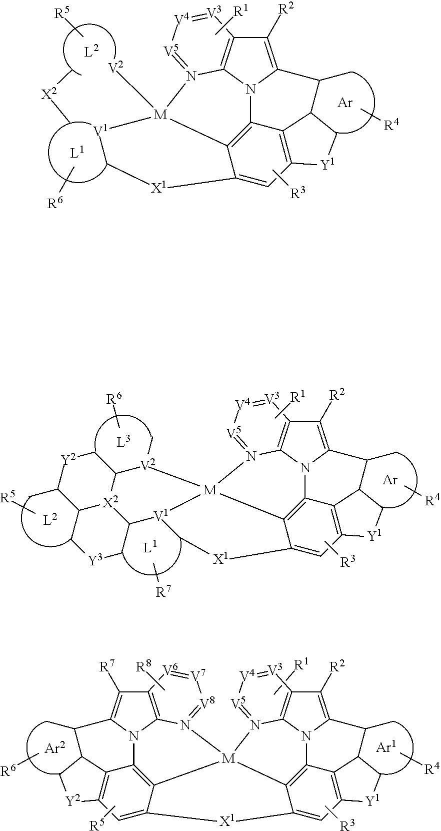

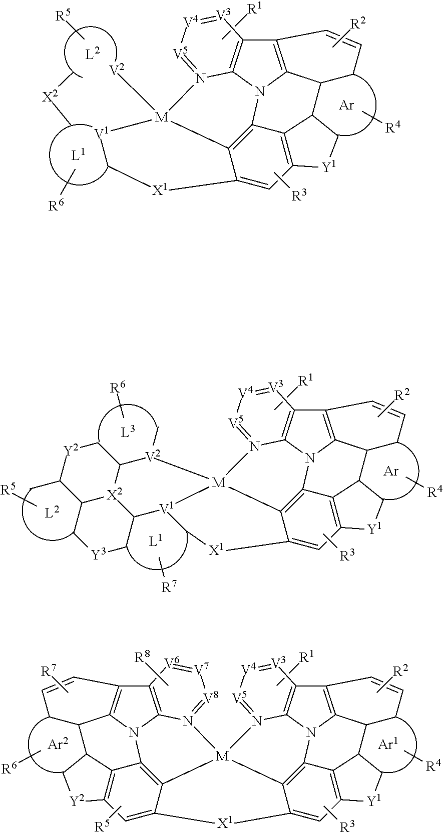

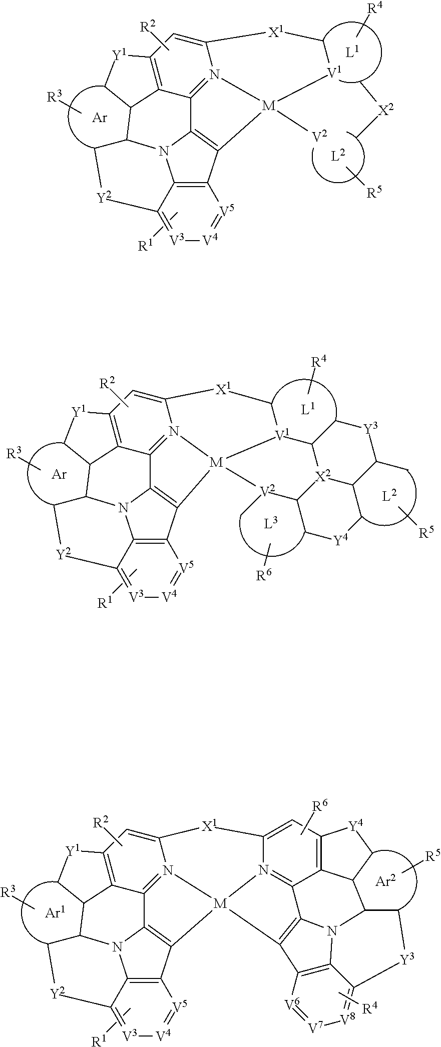

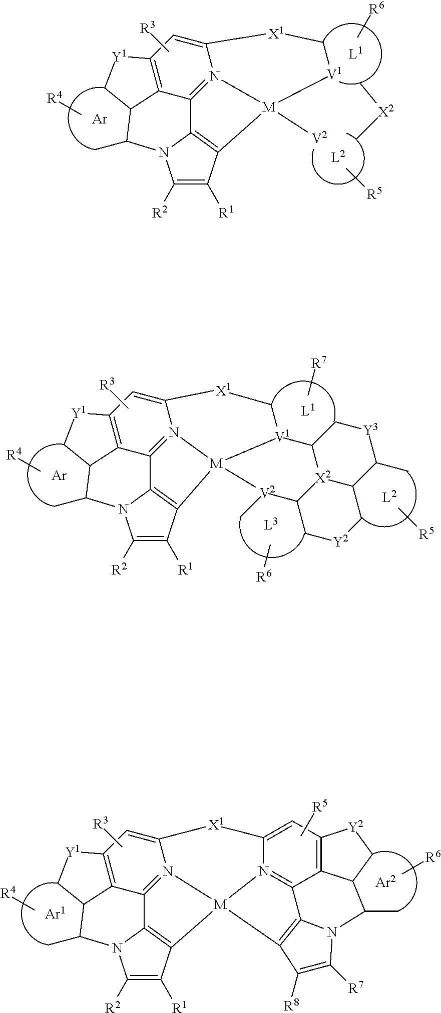

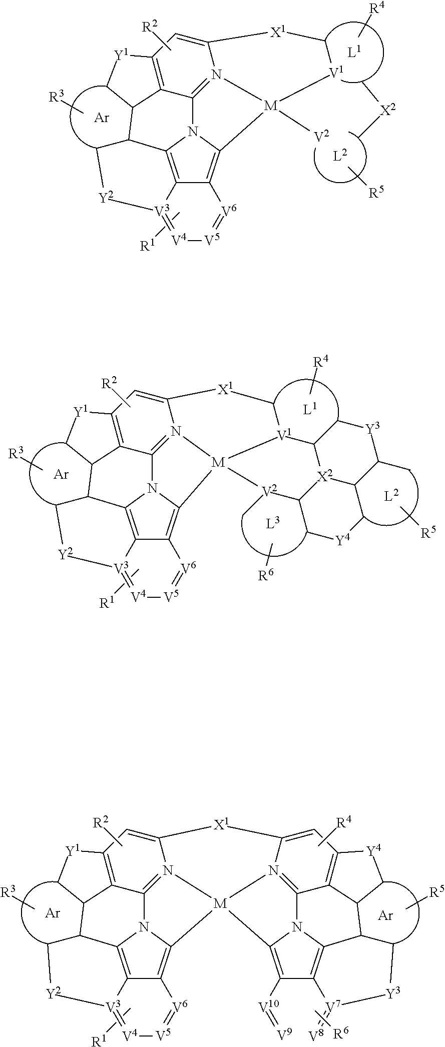

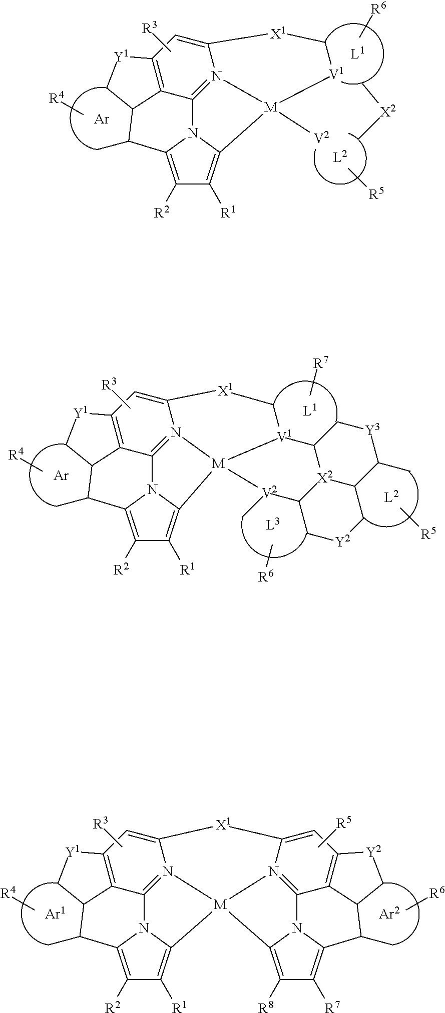

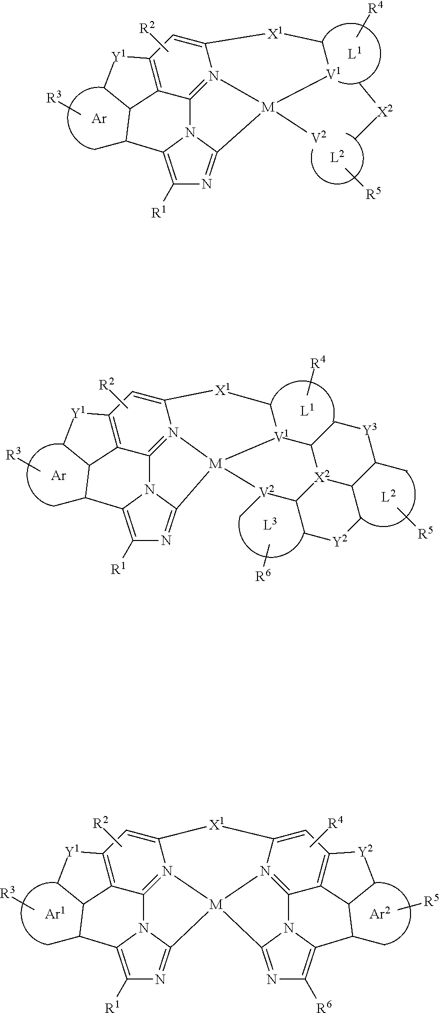

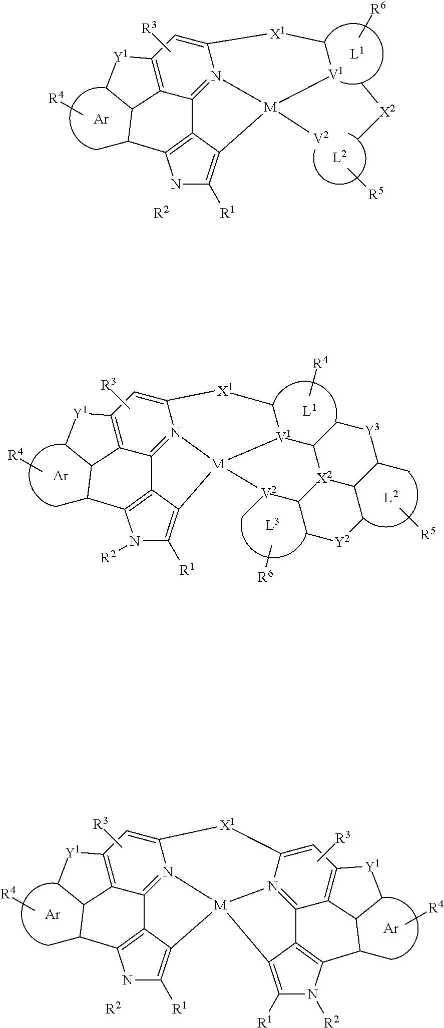

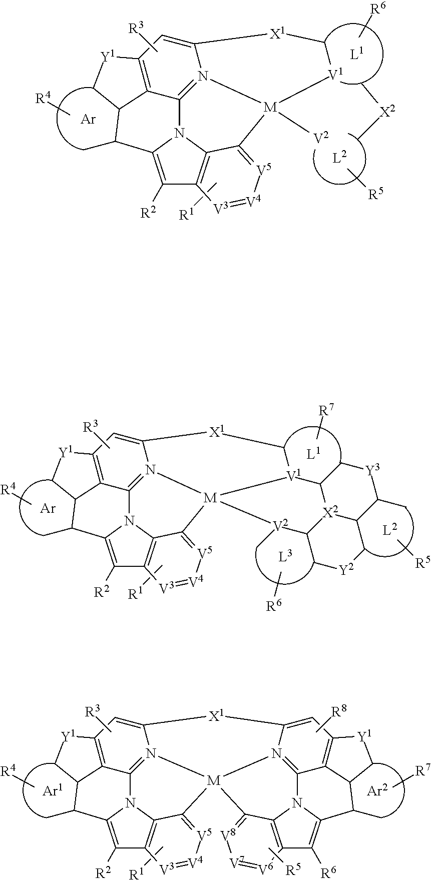

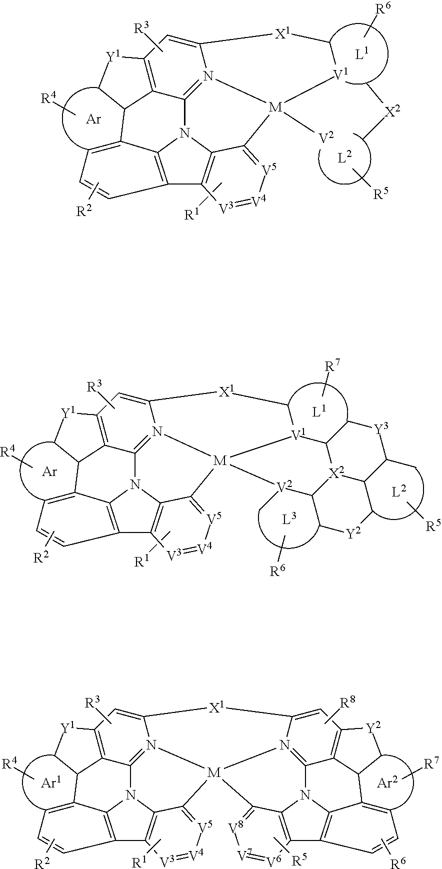

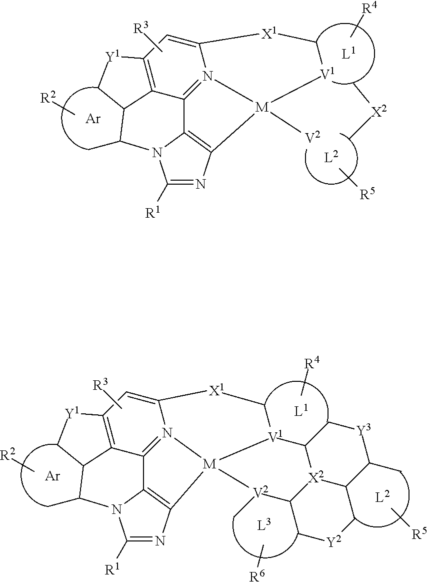

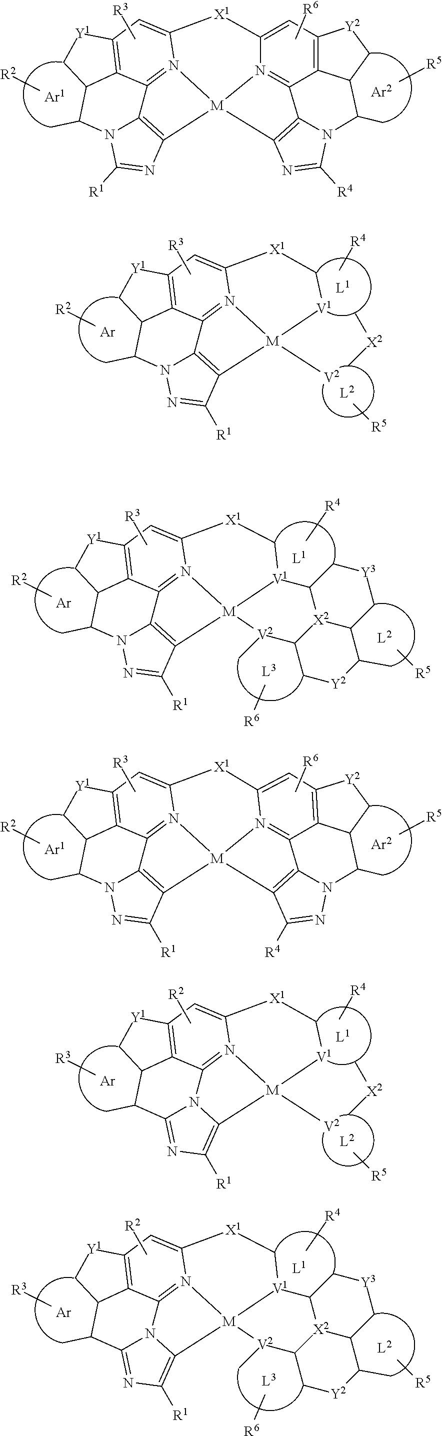

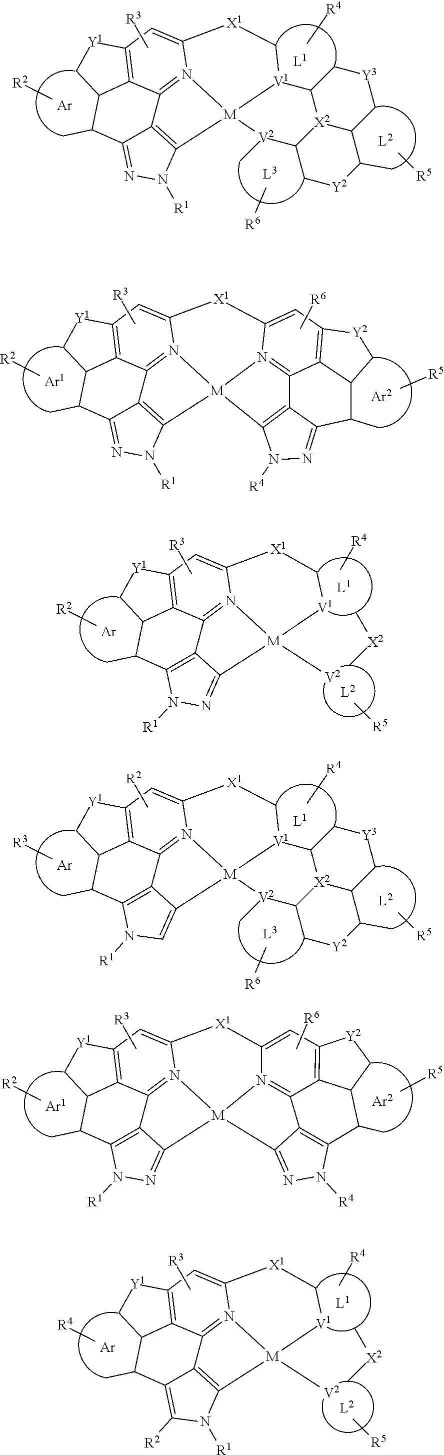

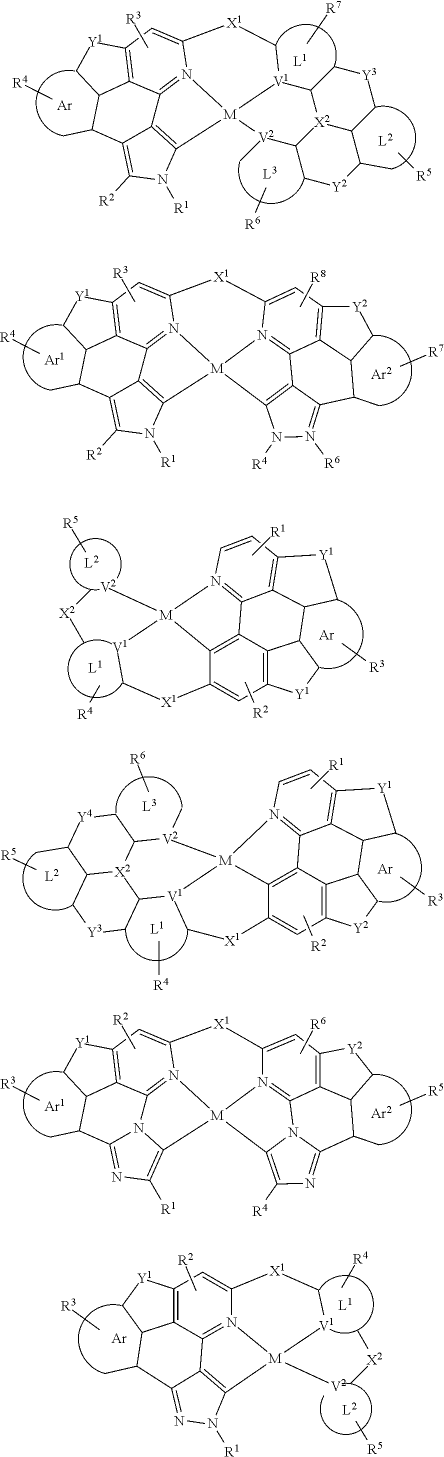

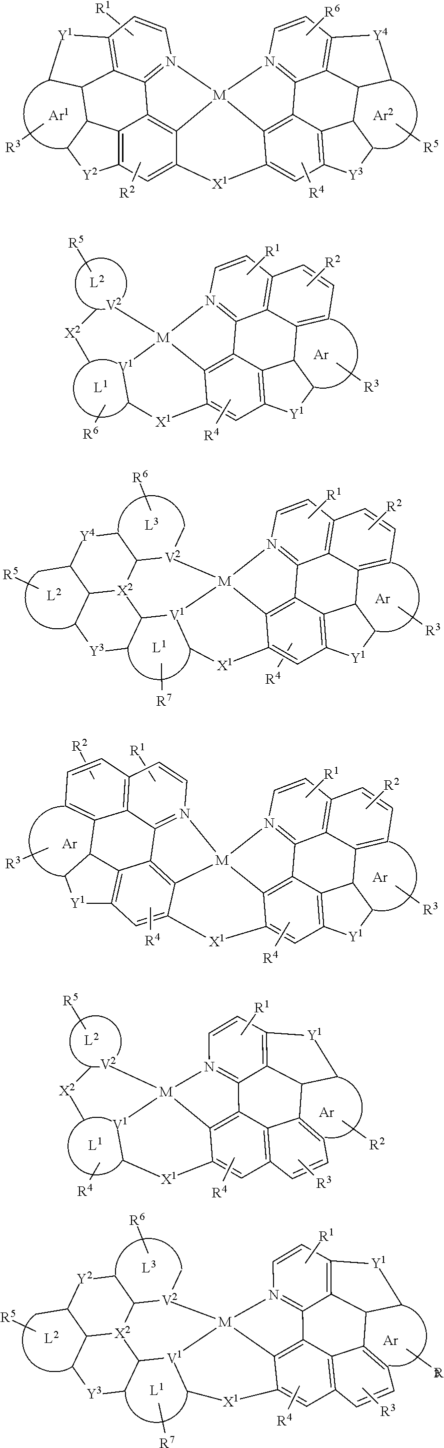

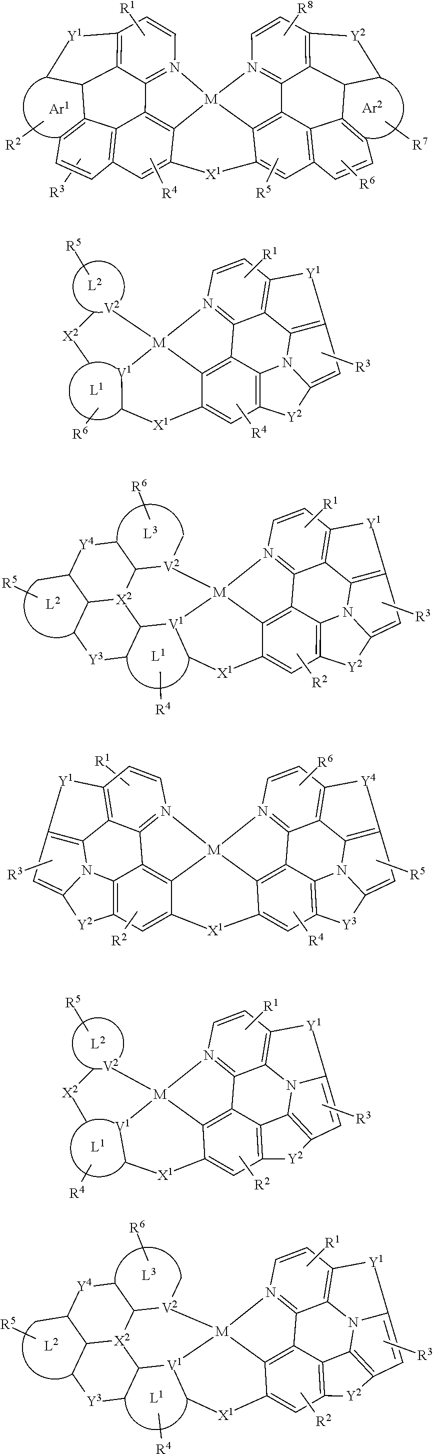

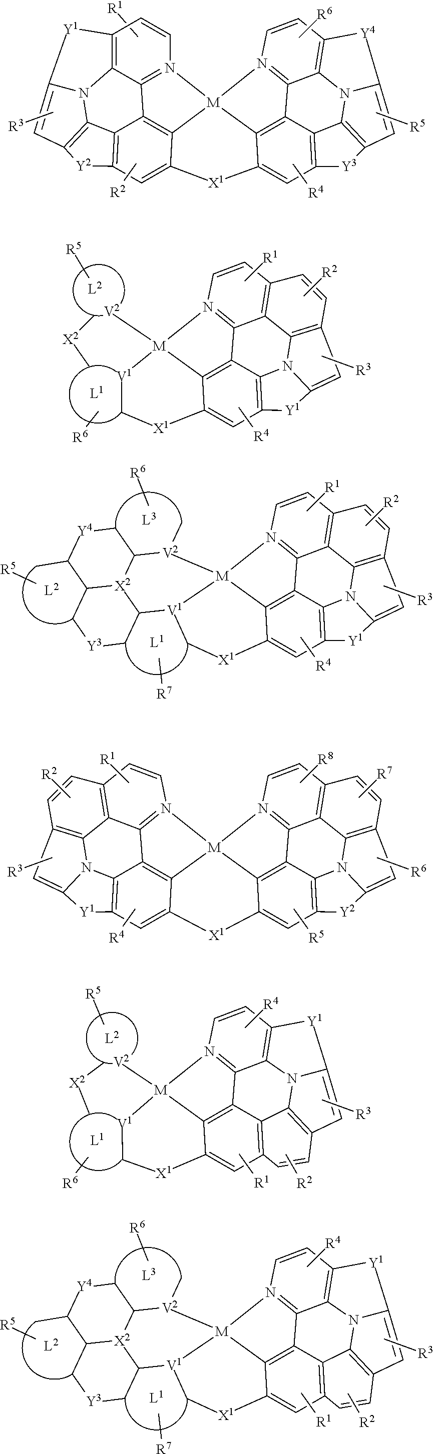

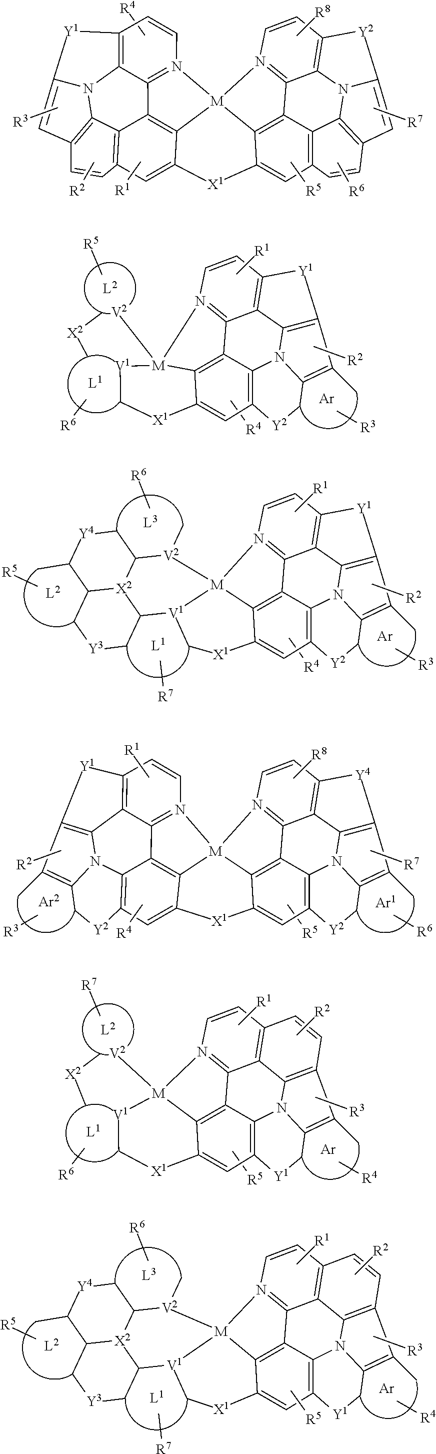

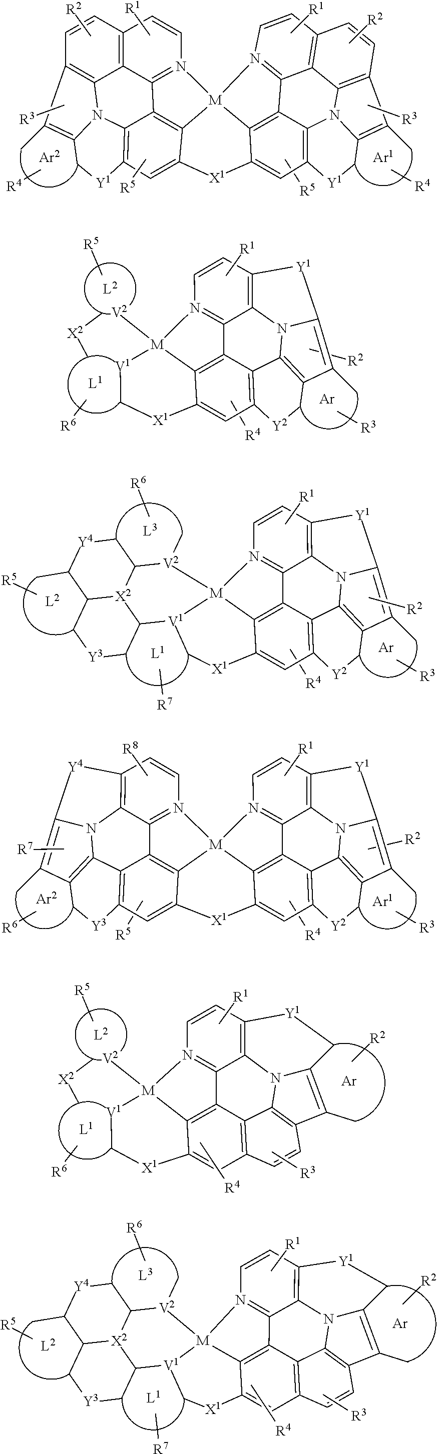

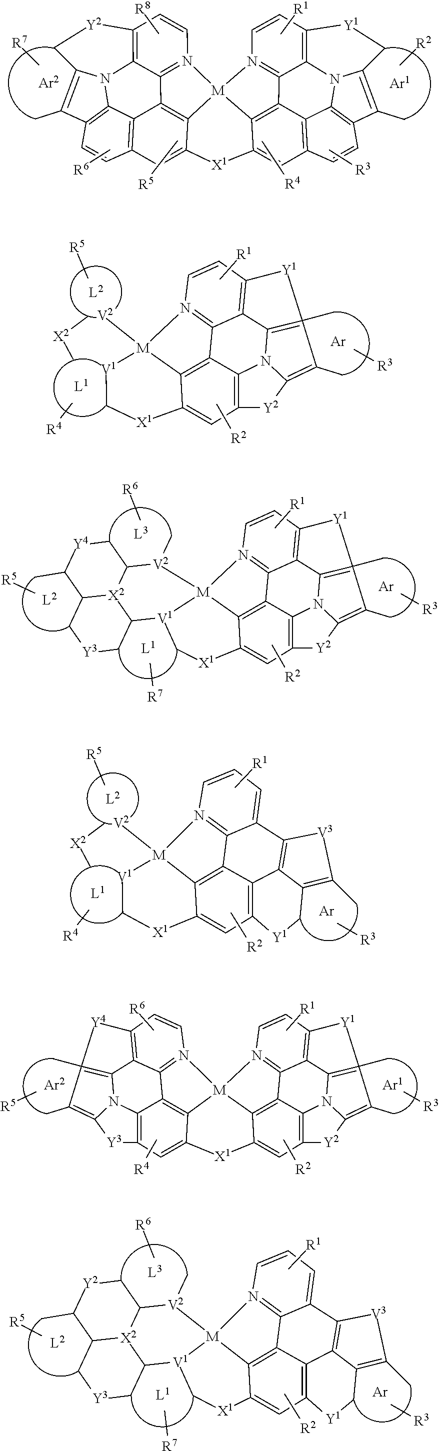

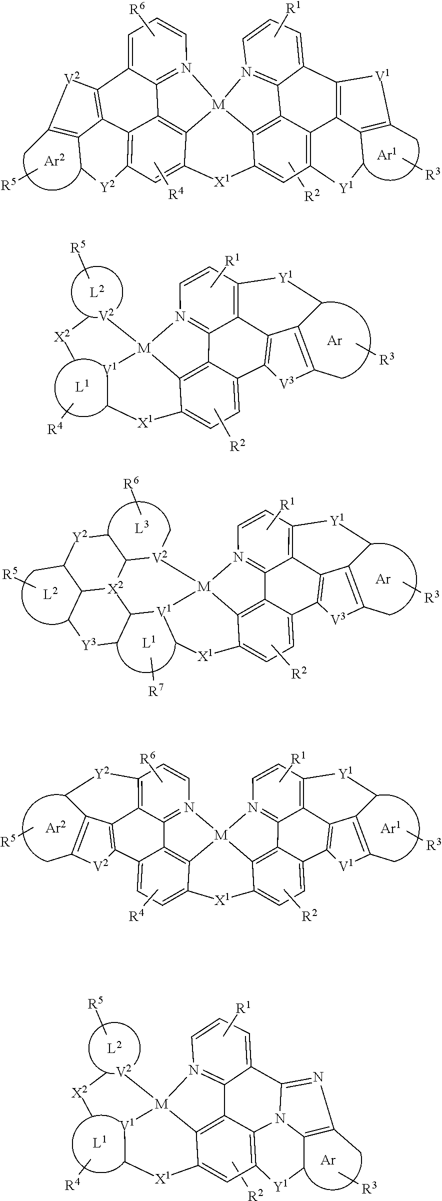

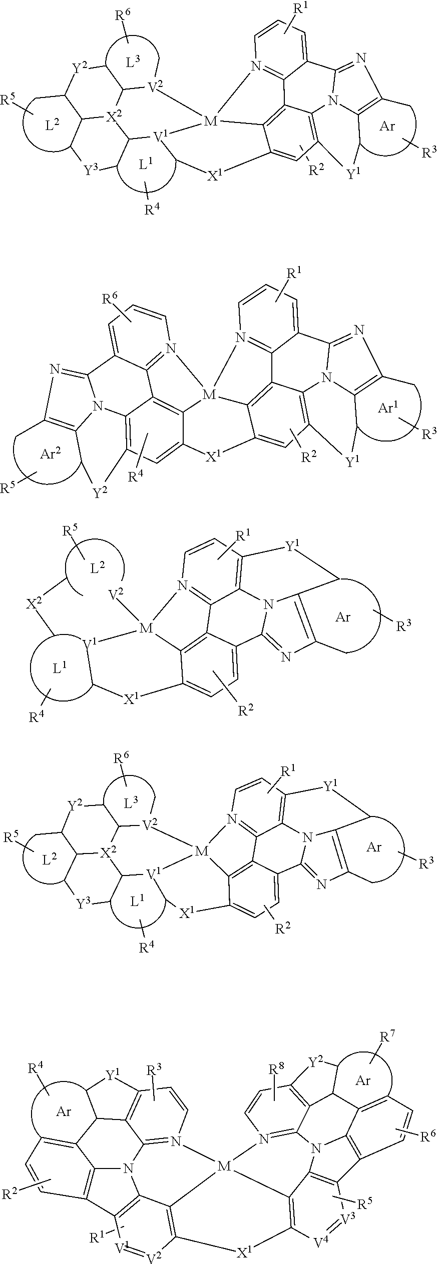

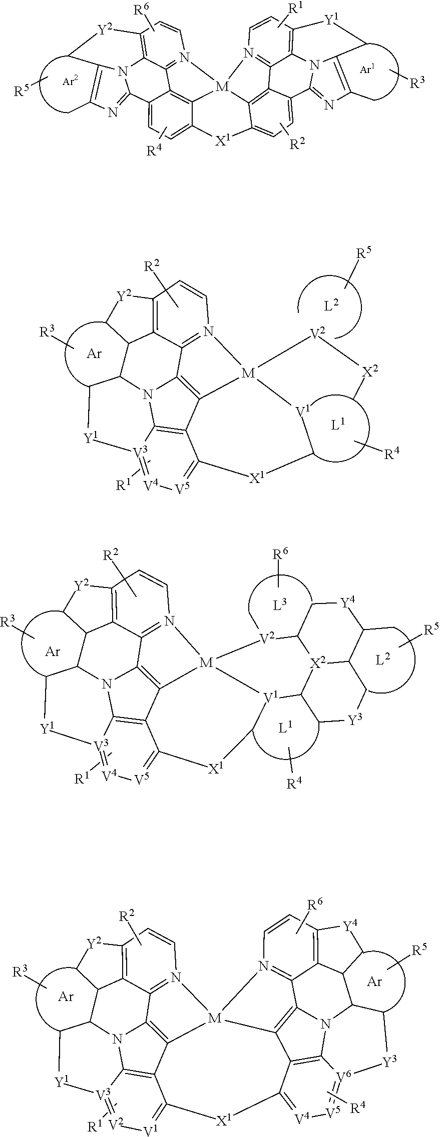

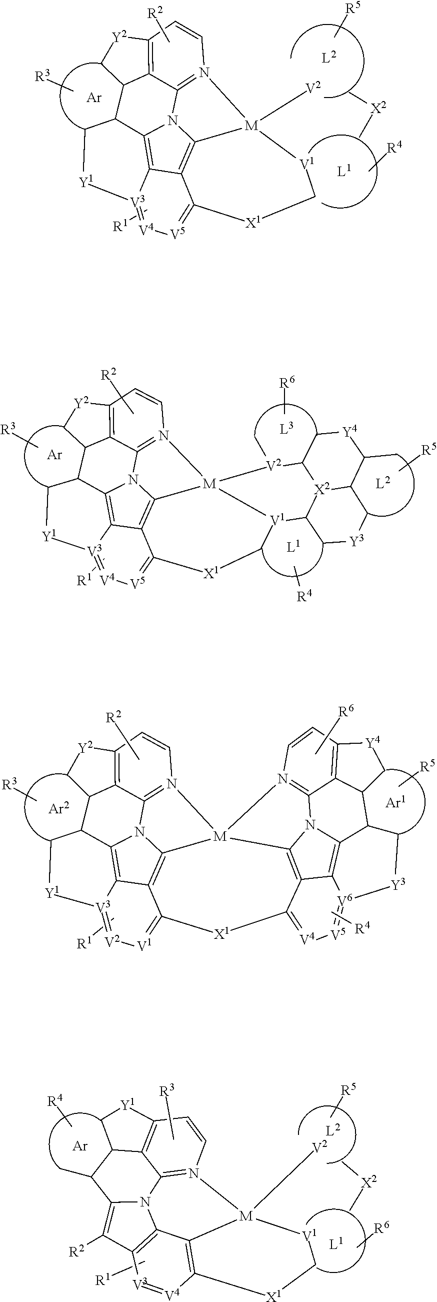

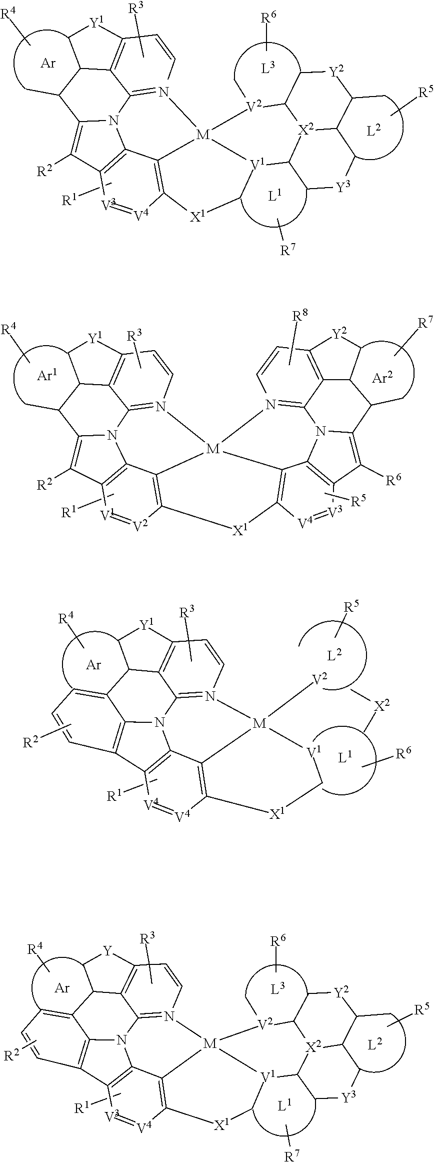

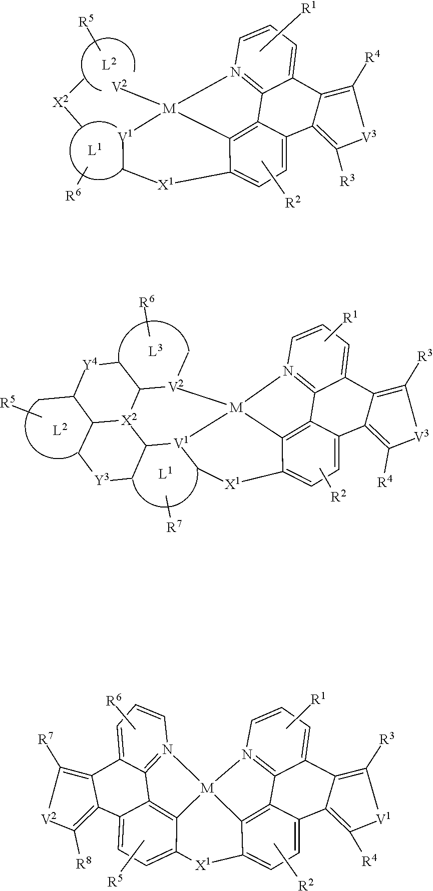

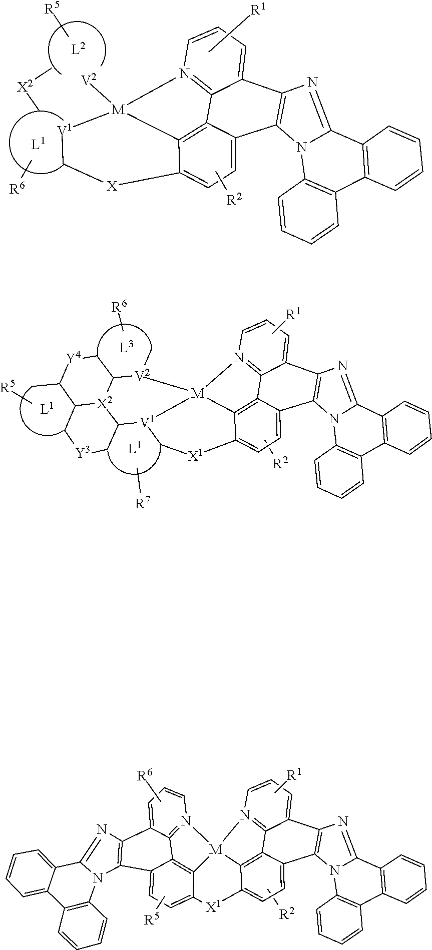

In these Implementations of General Formulas I-II:
M is Pt (II) or Pd (II),
N is nitrogen,
each of V¹-V⁶, if present, is independently C, N, Si, O, S, Ge, P, As, Se, B, Al, or Bi,
each of X¹, X², Y¹, Y², Y³, and Y⁴ is independently present or absent, and if present, each X¹, X², Y¹, Y², Y³, and Y⁴ independently represents C, N, Si, O, S, Ge, P, As, Se, B, Al, or Bi, or valency permitting, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R⁸, NR⁷, PR⁷, PR⁷R⁸, R⁷P═O, ASR⁷, R⁷As═O, S═O, SO₂, Se═O, SeO₂, BR⁷, BR⁷R⁸, AlR⁷, AlR⁷R⁸, R⁷Bi═O, or BiR⁷,
each of L¹, L², L³, and L⁴ is independently present or absent, and each L¹, L², L³, and L⁴ present independently represents a substituted or unsubstituted aryl, heteroaryl, or N-heterocyclic carbene,
each of R, R¹, R², R³, R⁴, R⁵, R⁶, R⁷, and R⁸ is independently absent or present as a single substituent or multiple substituents, valency permitting, and each R, R¹, R², R³, R⁴, R⁵, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

Examples of suitable substituents R¹-R⁸ include:

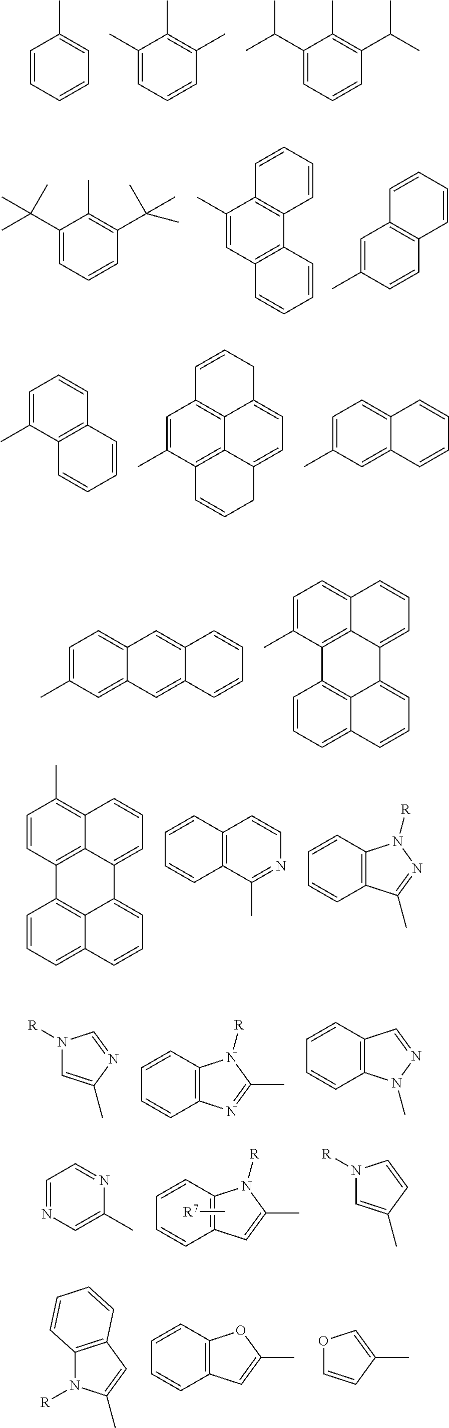

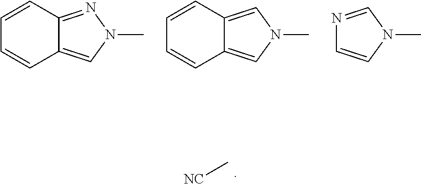

In the implementations of General Formulas I-III, each of

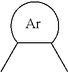

is independently present or absent, and each Ar present independently represents a substituted or unsubstituted aryl, heteroaryl, or N-heterocyclic carbene, including the following moieties:

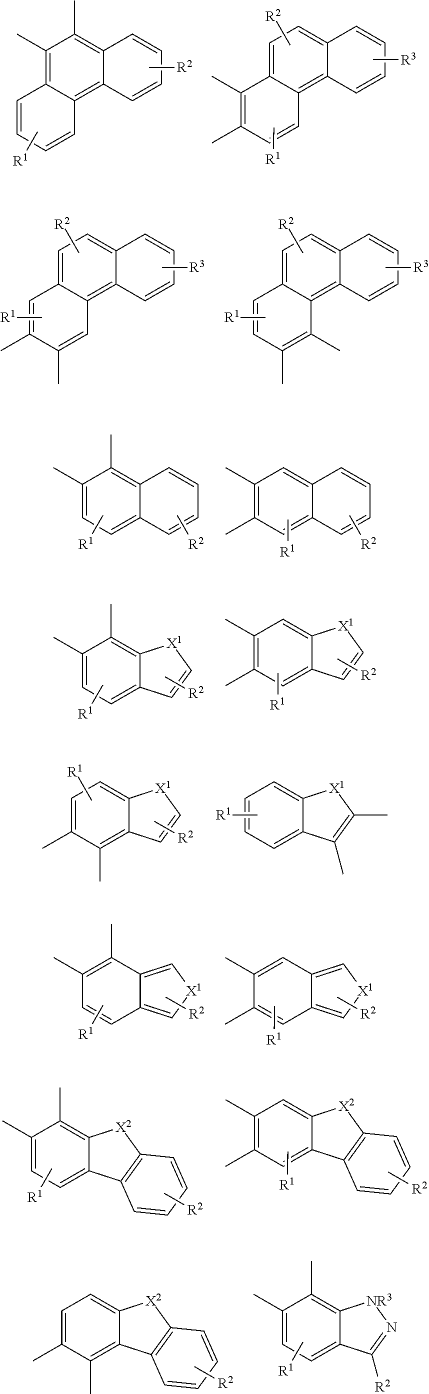

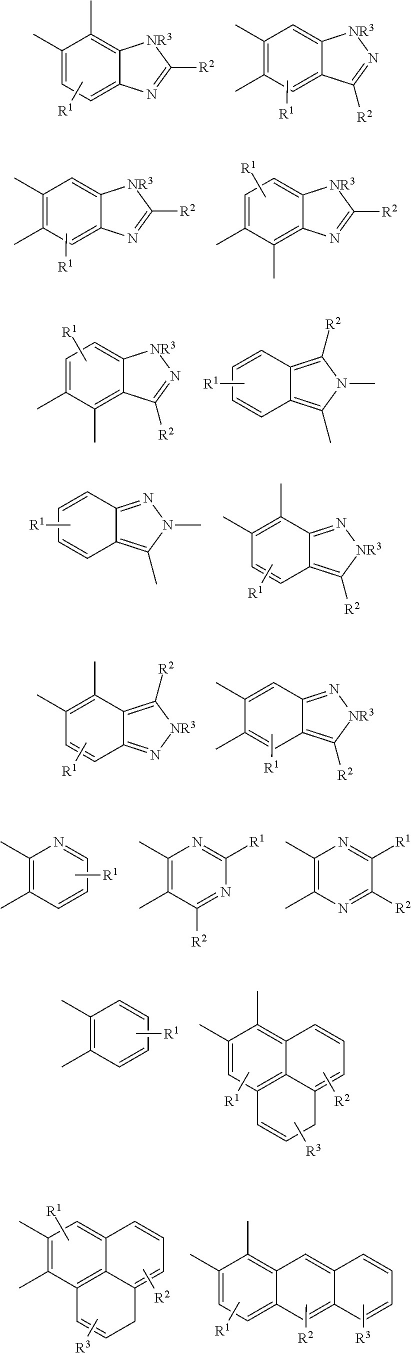

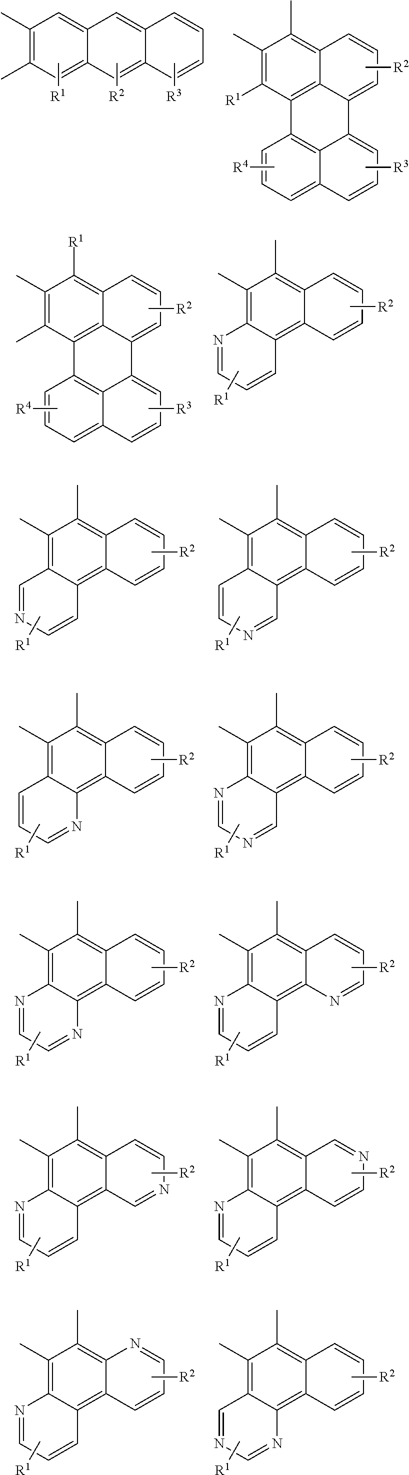

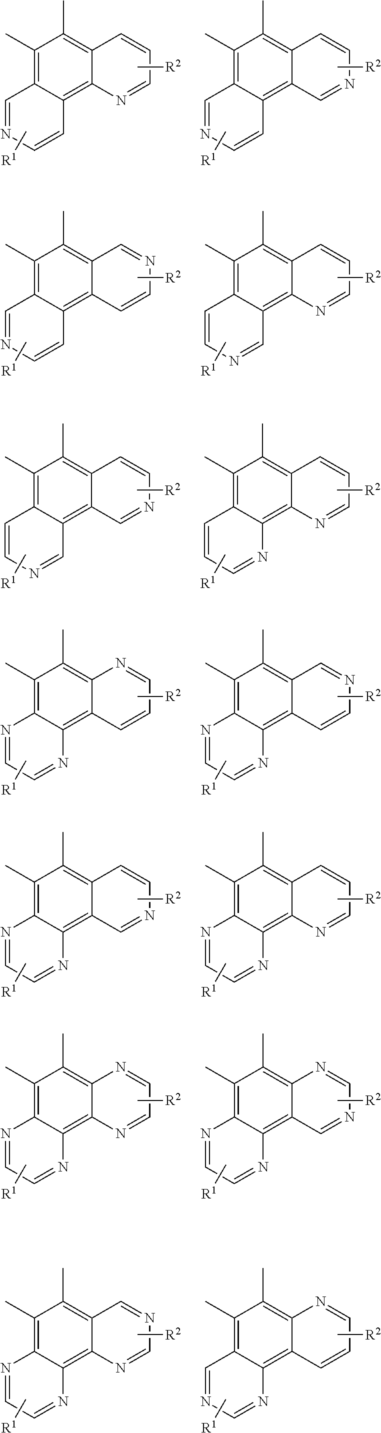

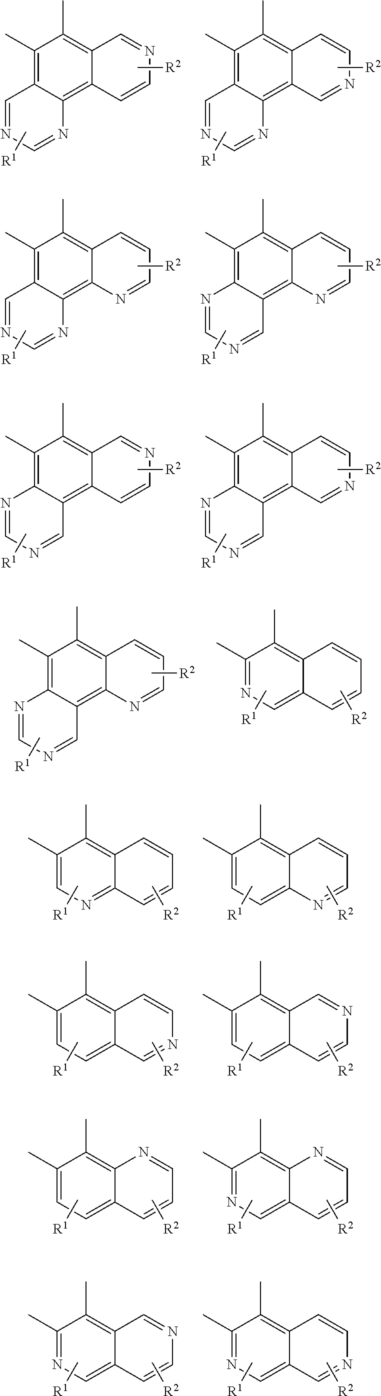

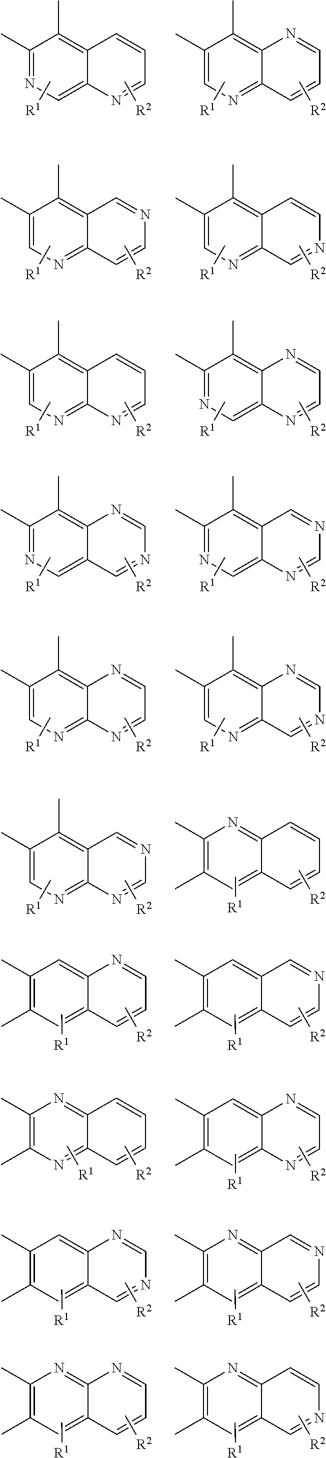

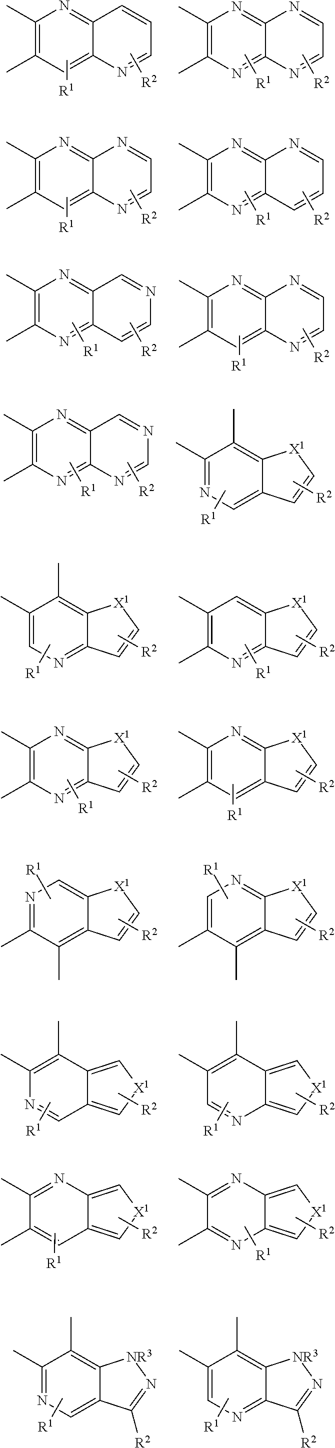

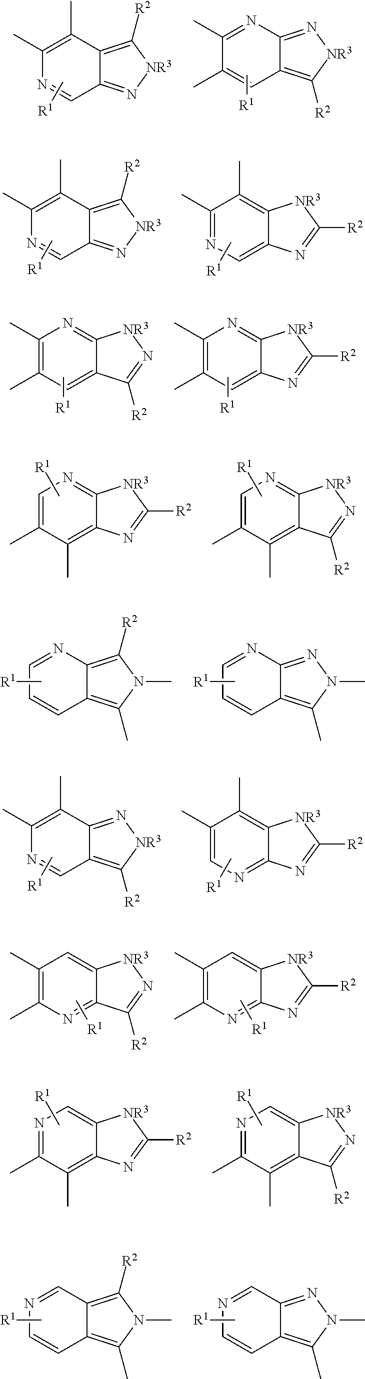

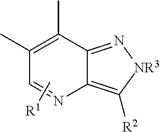

in which R¹, R², R³, R⁴, X¹, and X² are as defined herein.

Compounds of General Formulas I-III are shown below.

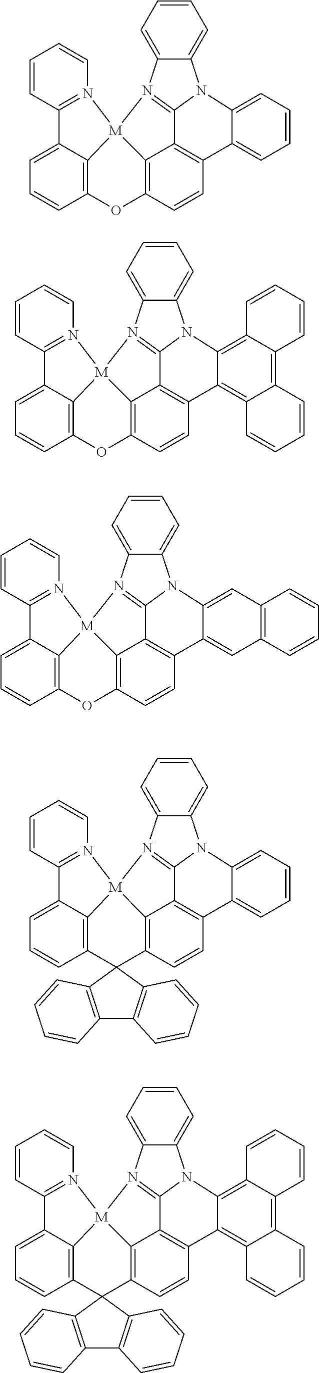

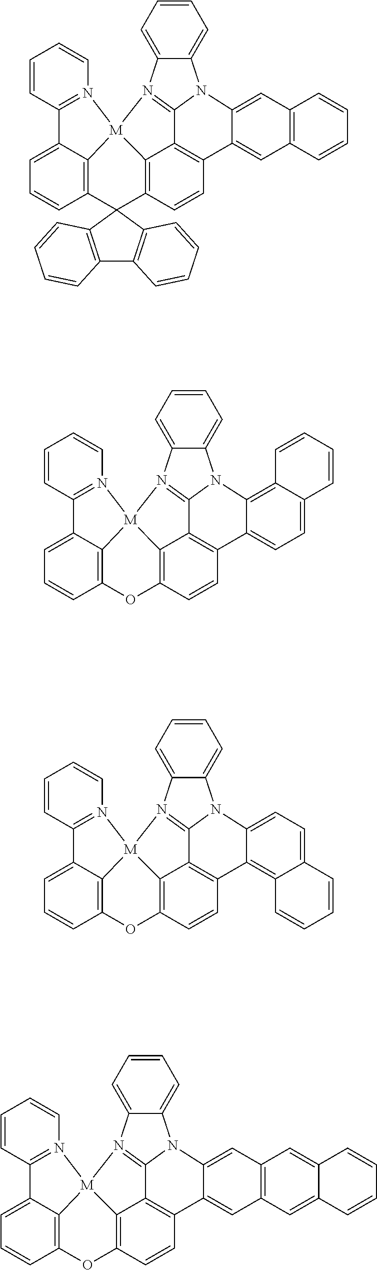

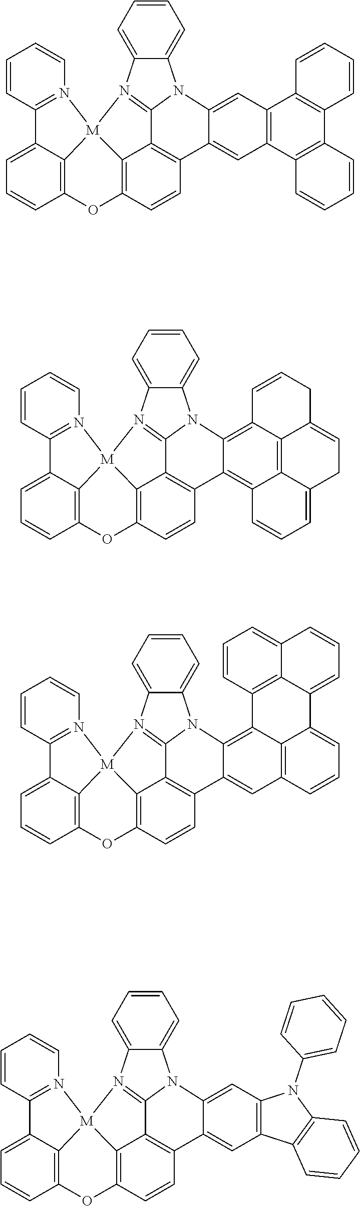

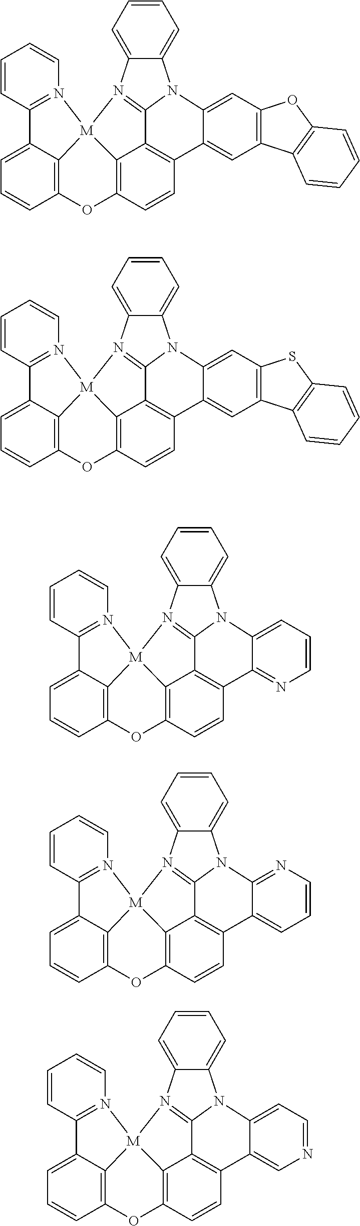

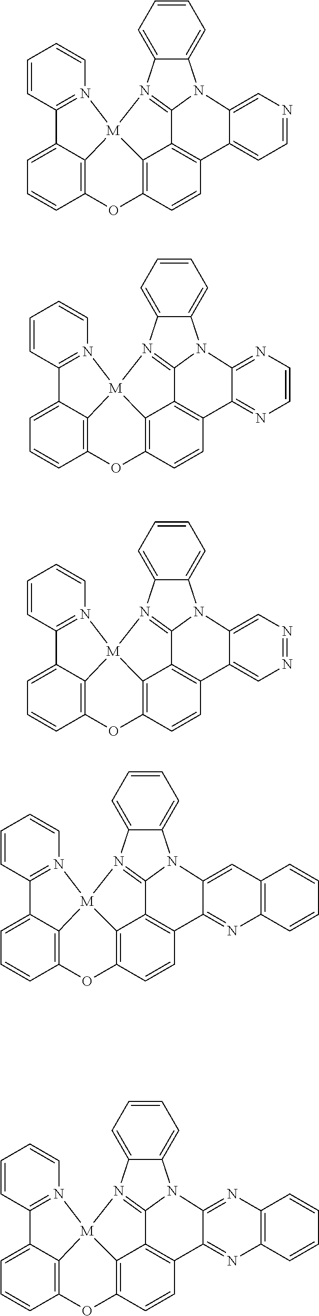

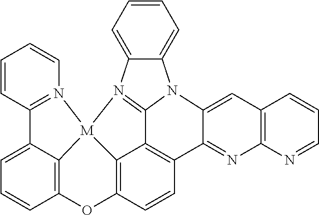

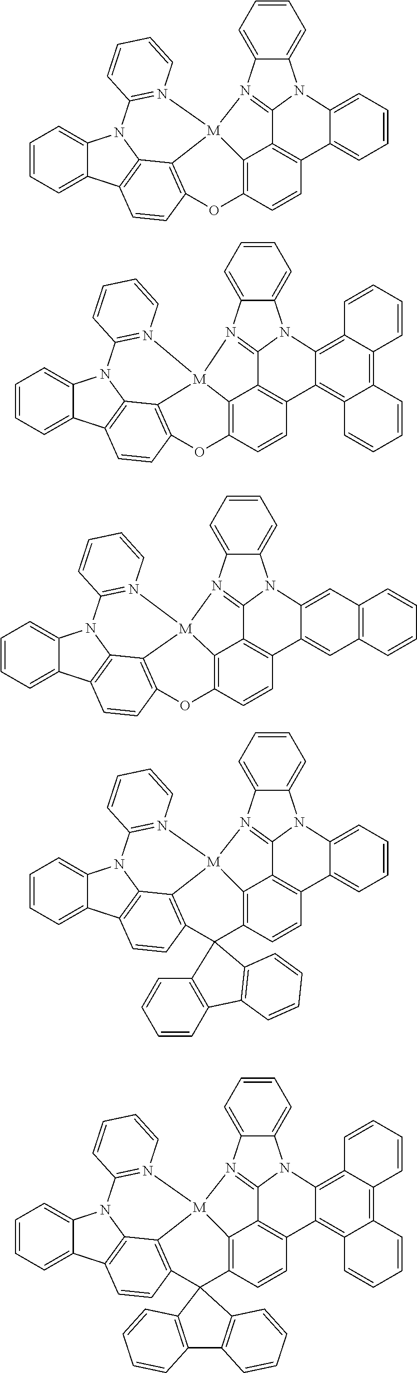

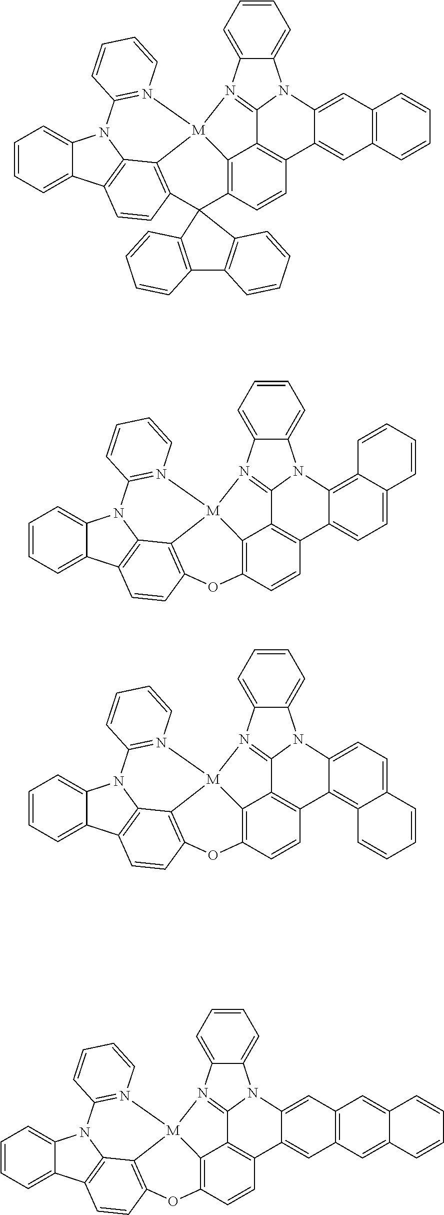

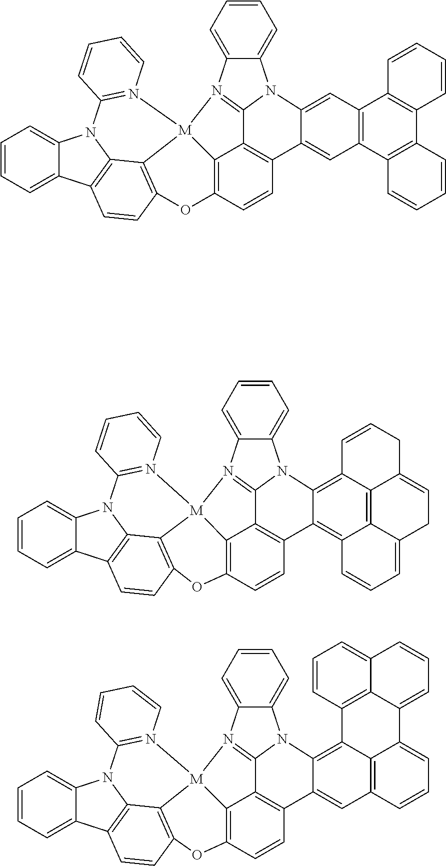

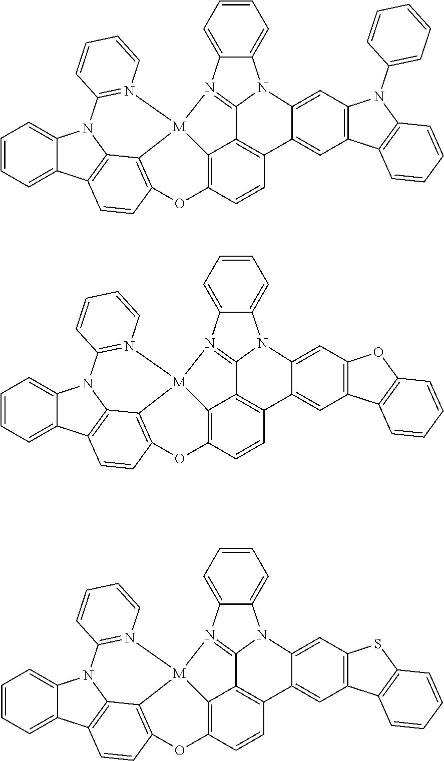

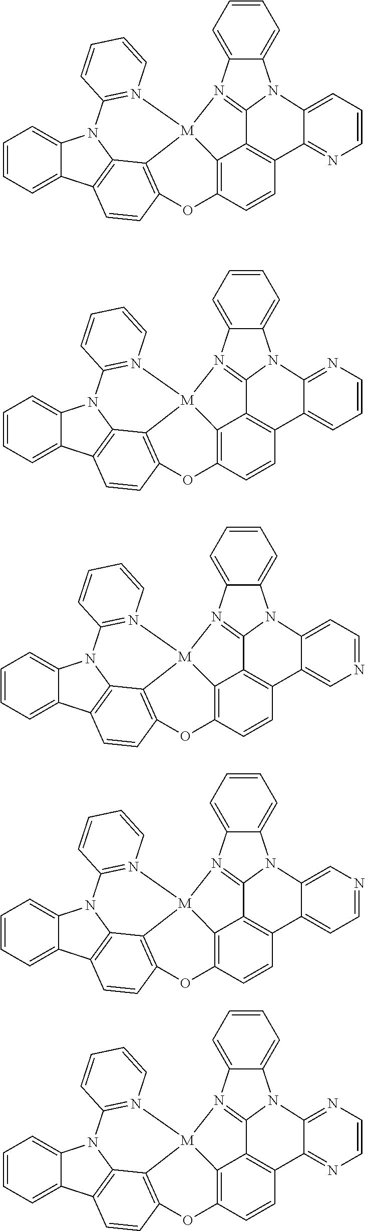

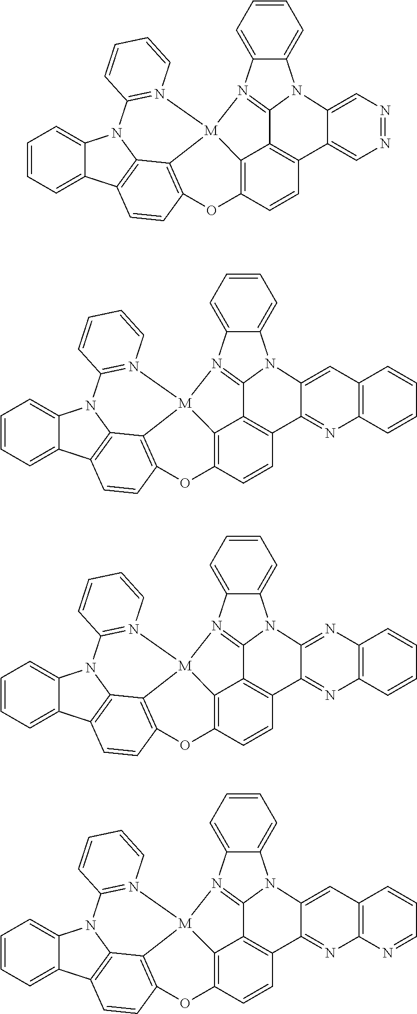

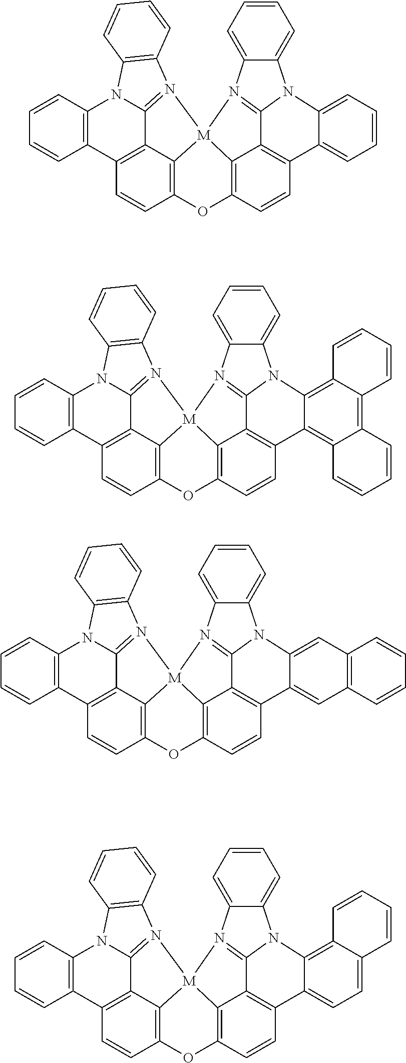

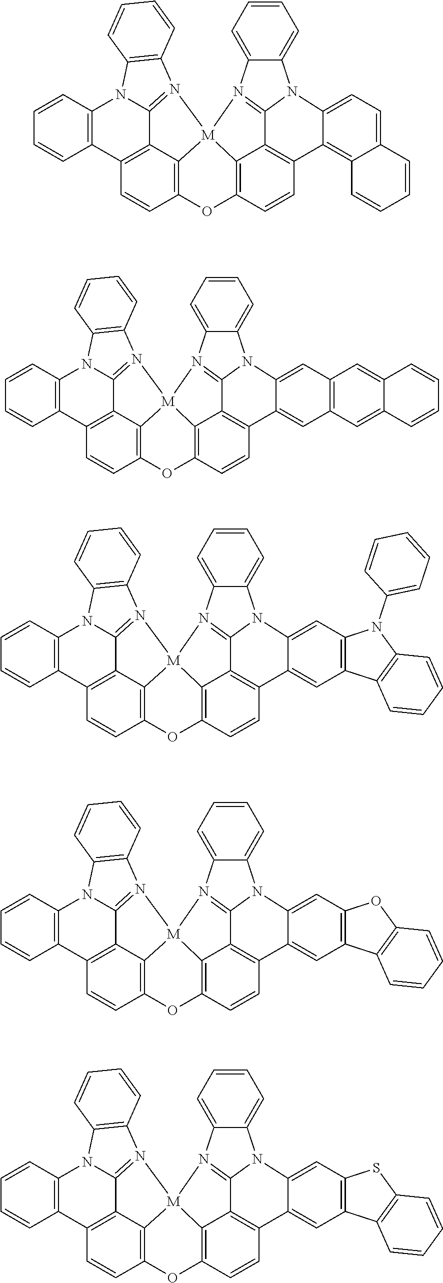

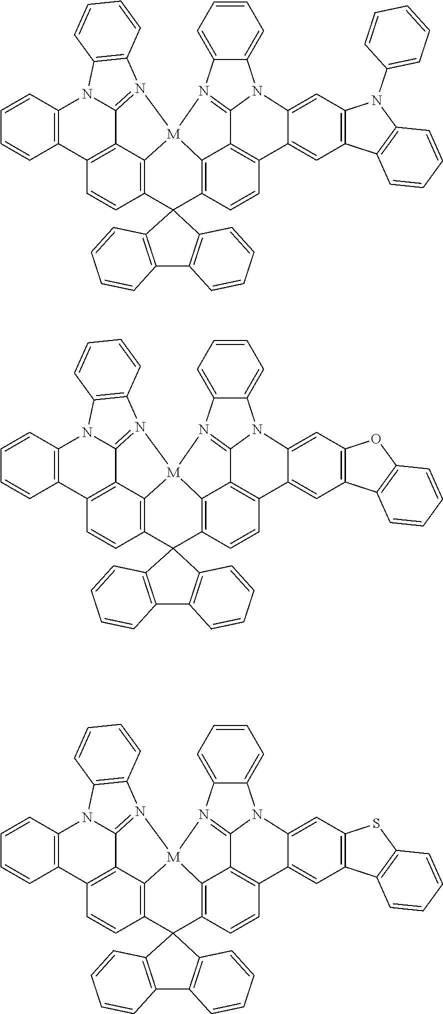

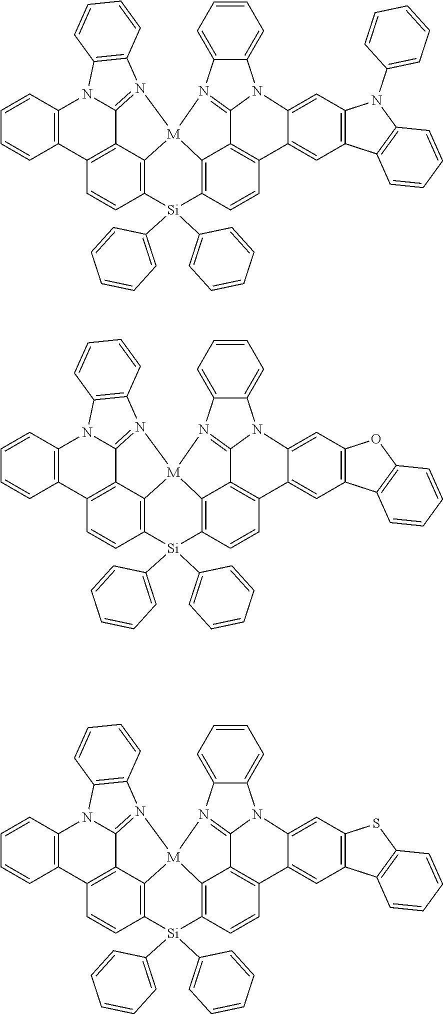

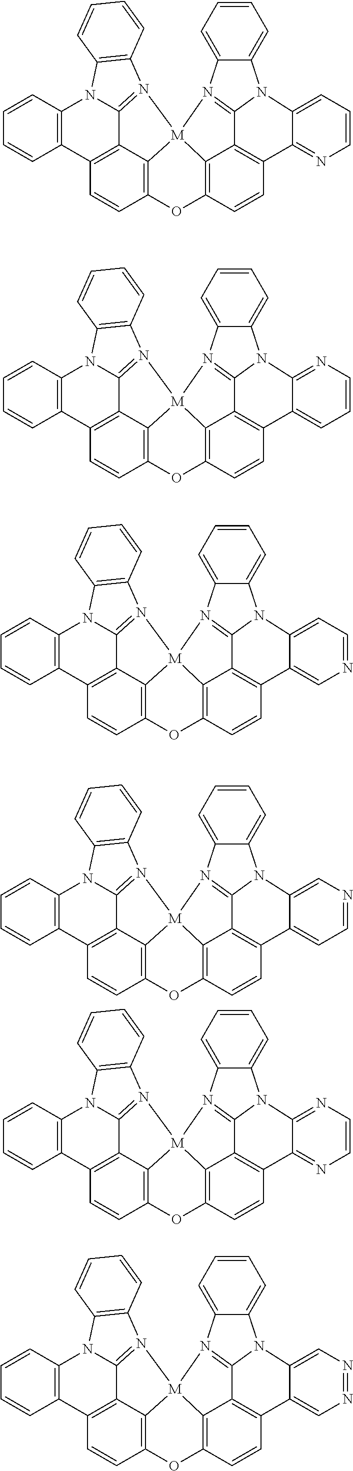

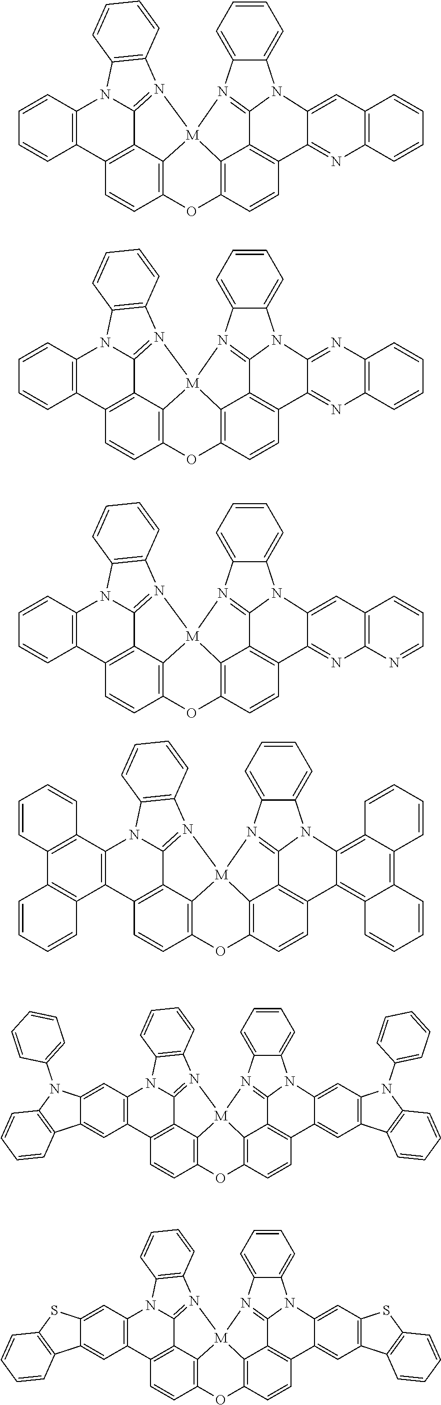

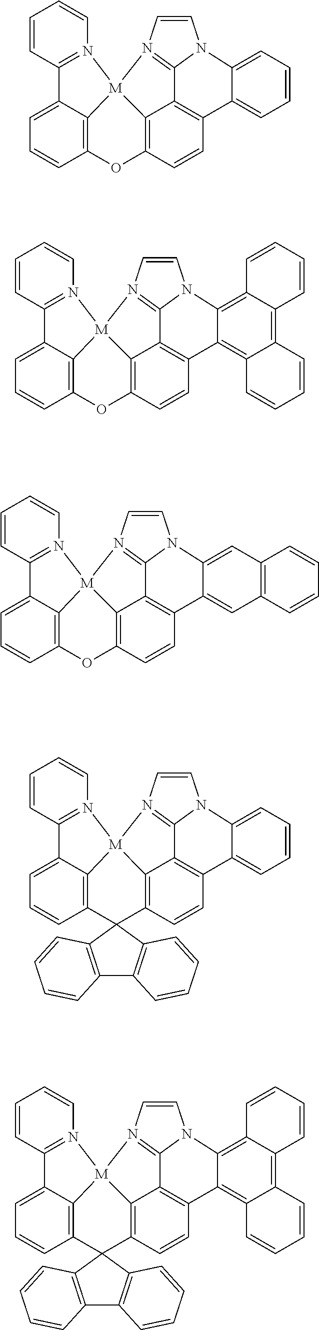

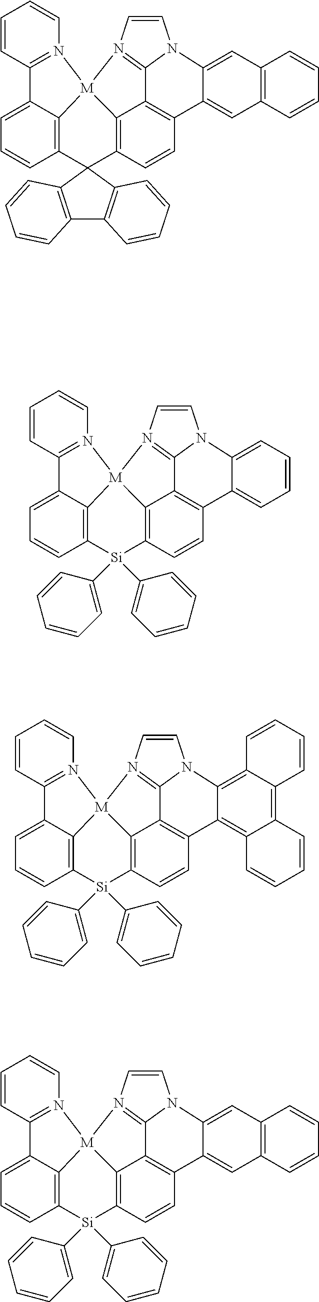

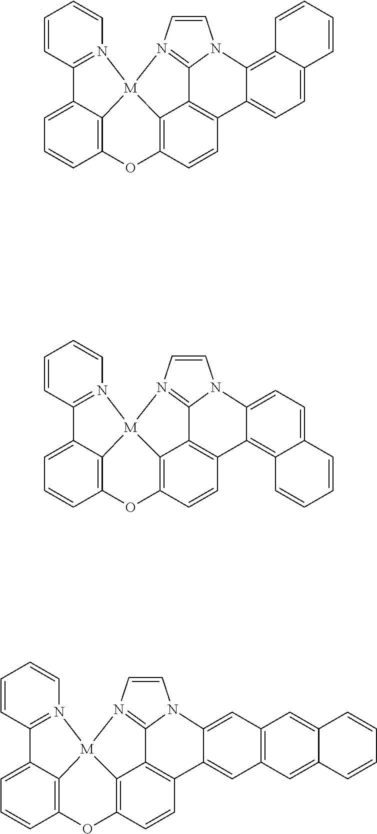

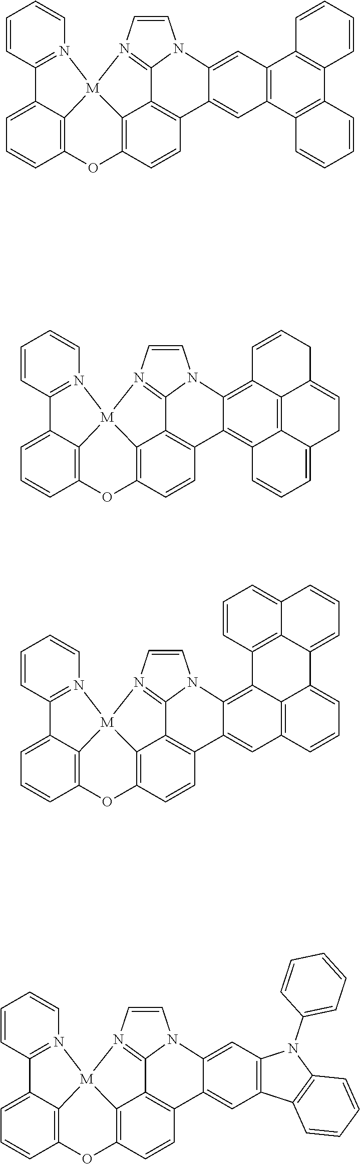

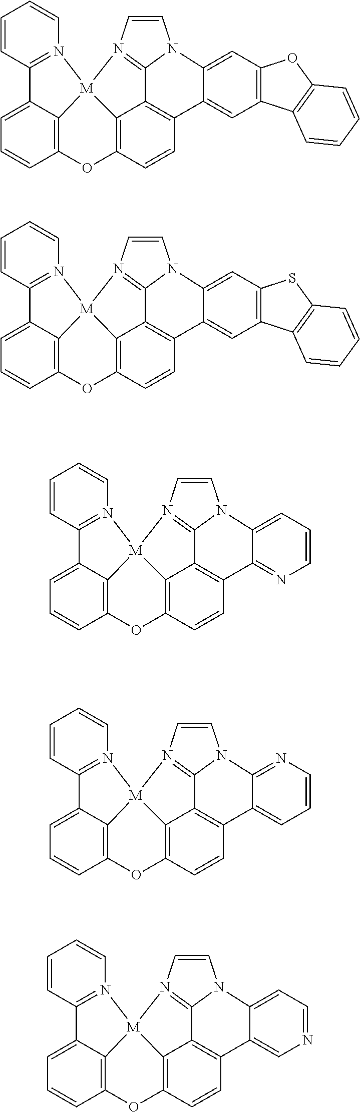

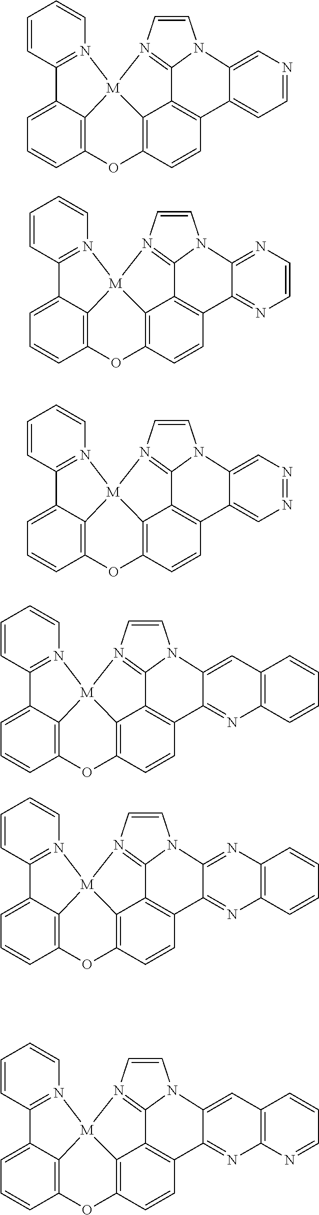

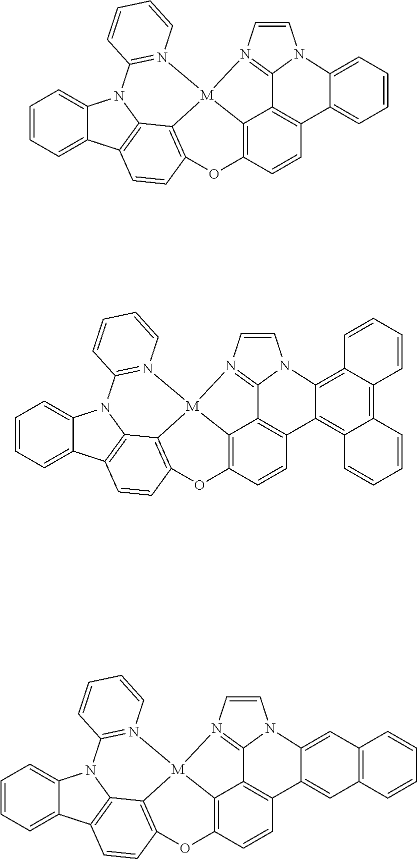

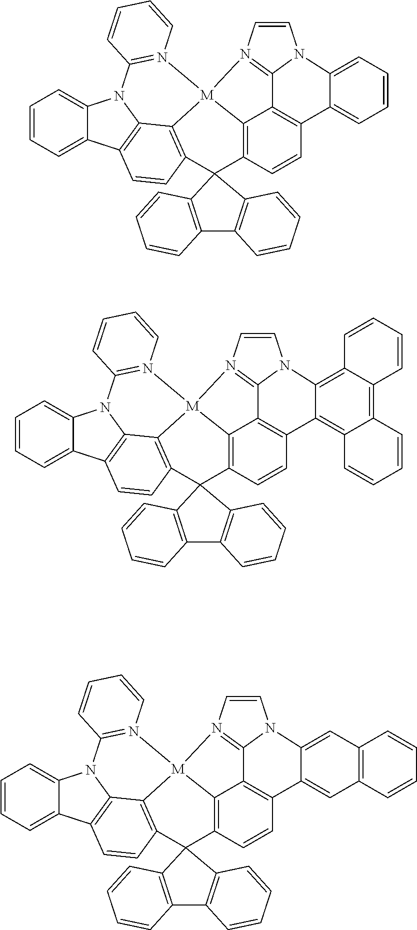

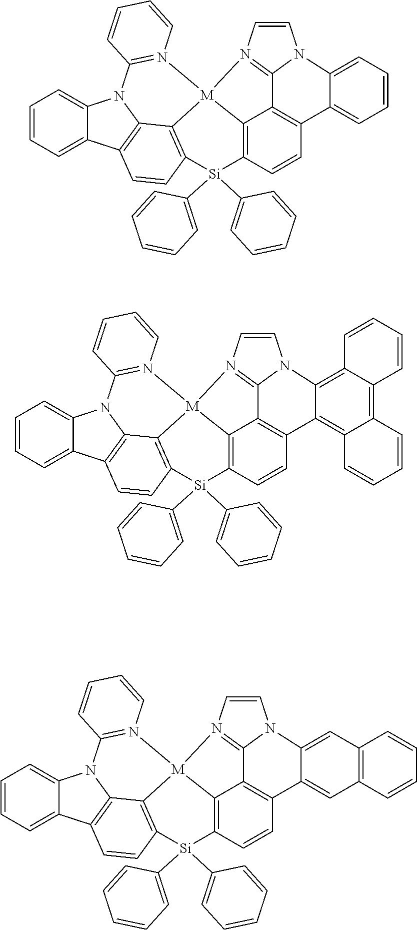

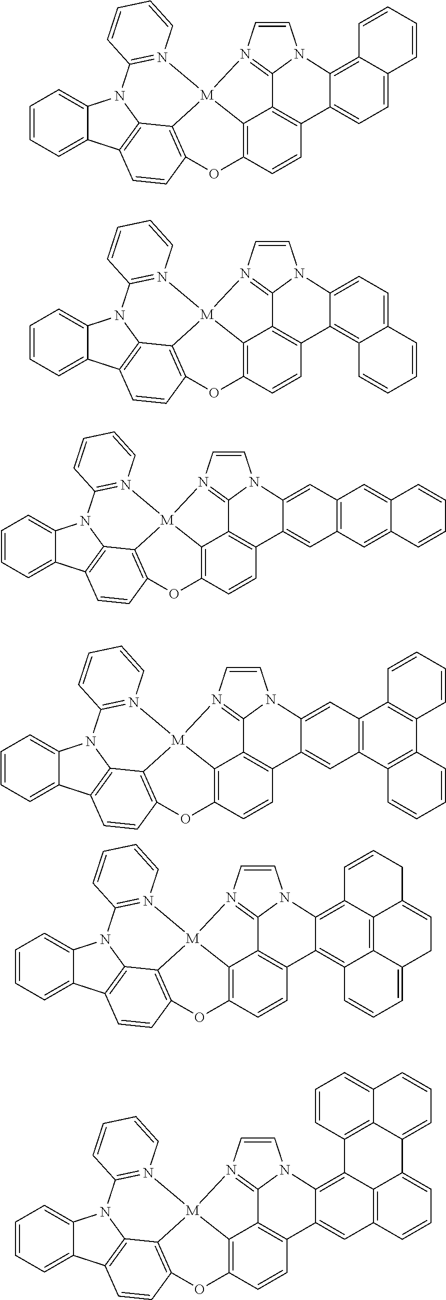

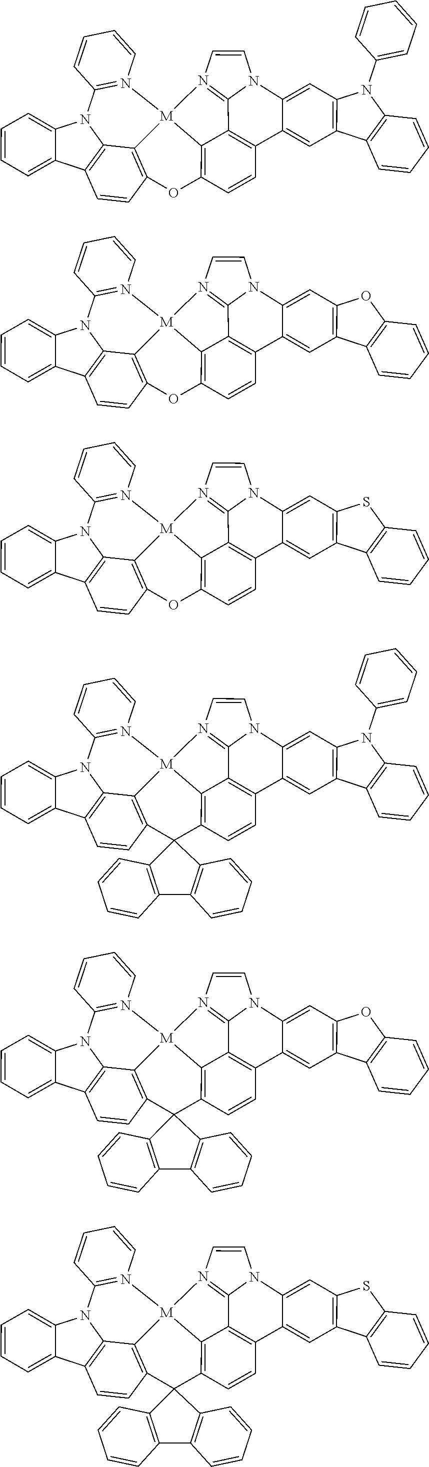

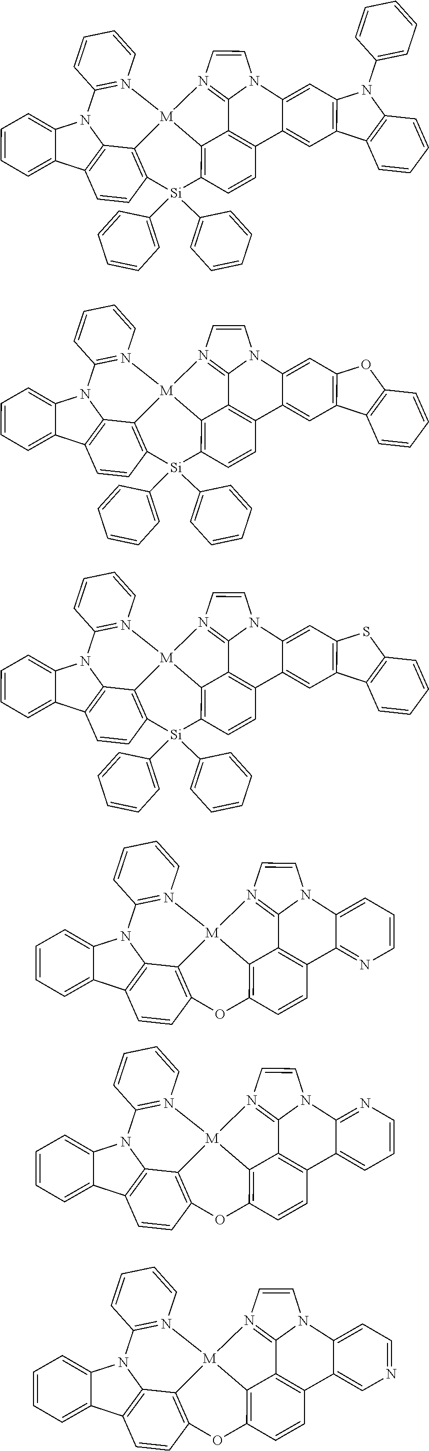

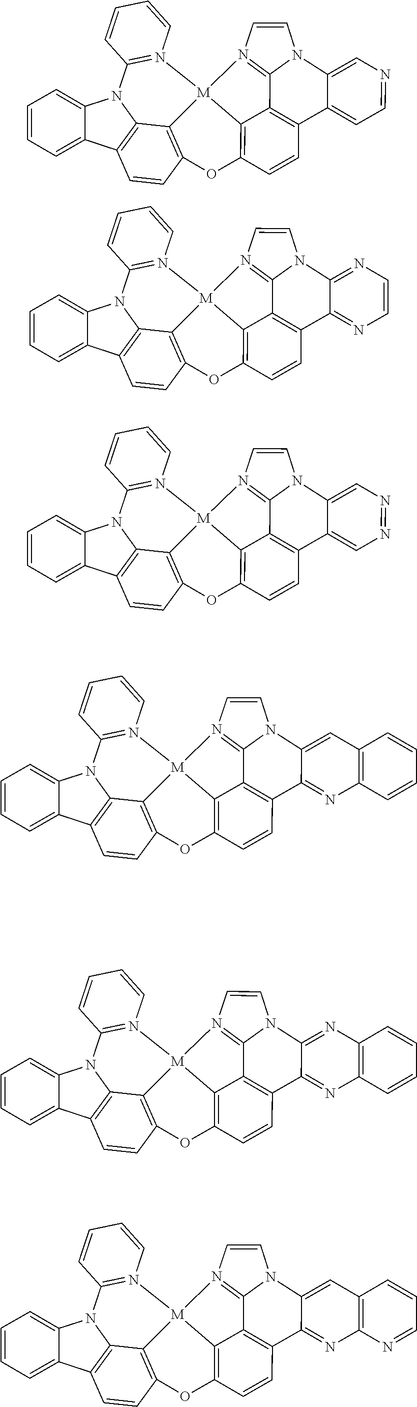

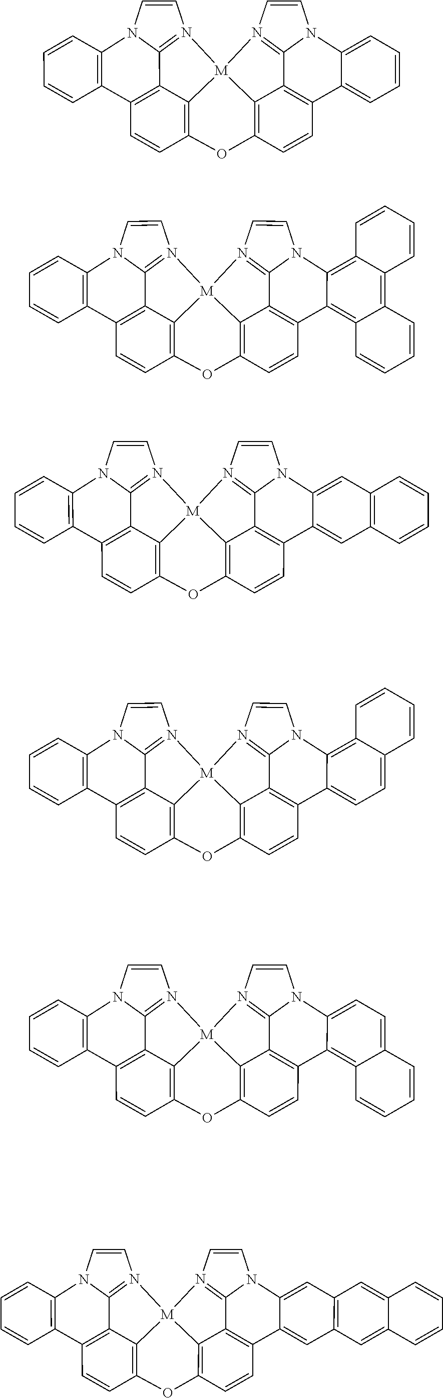

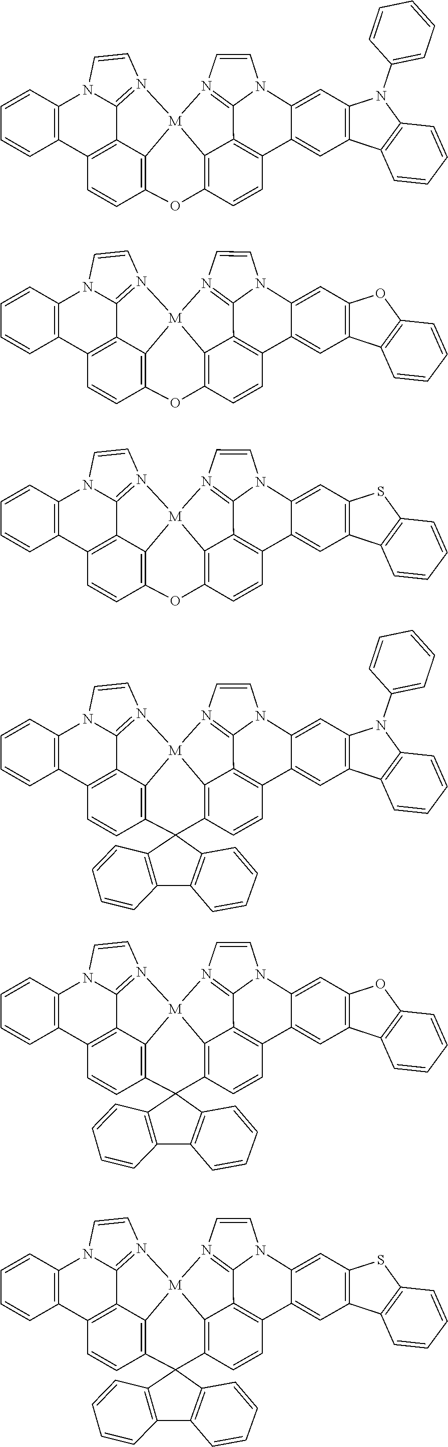

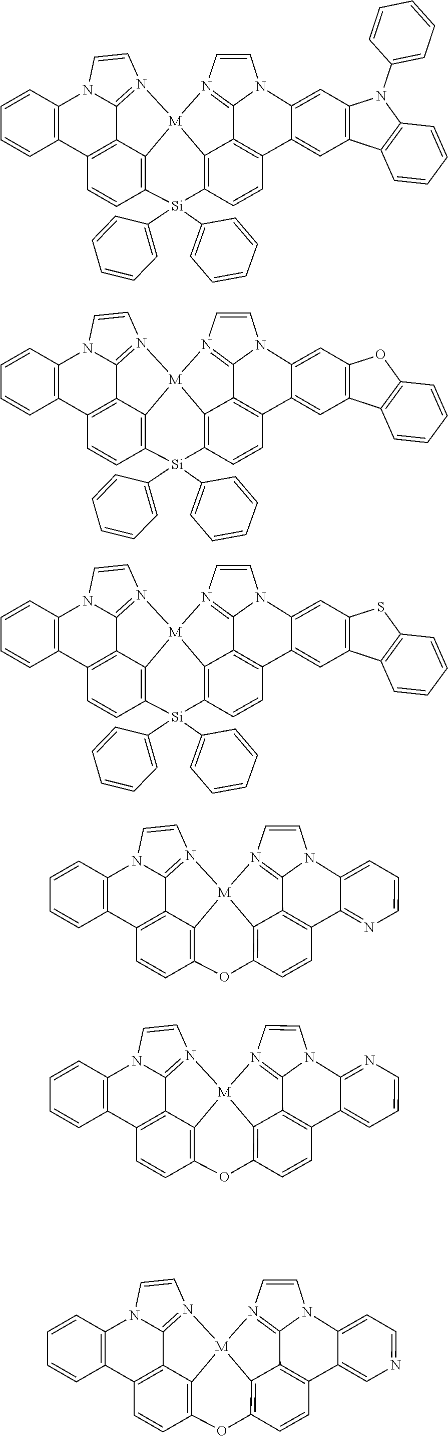

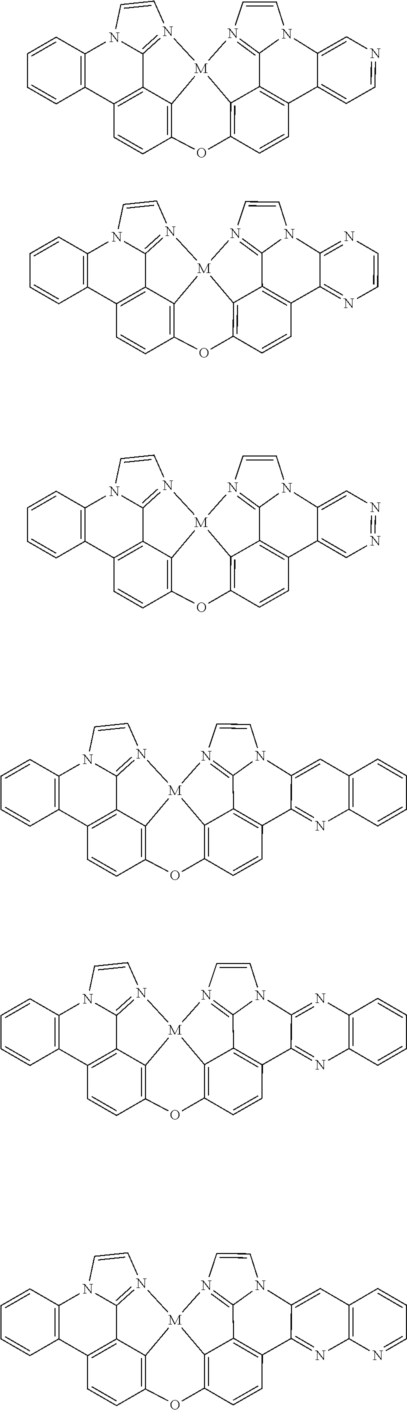

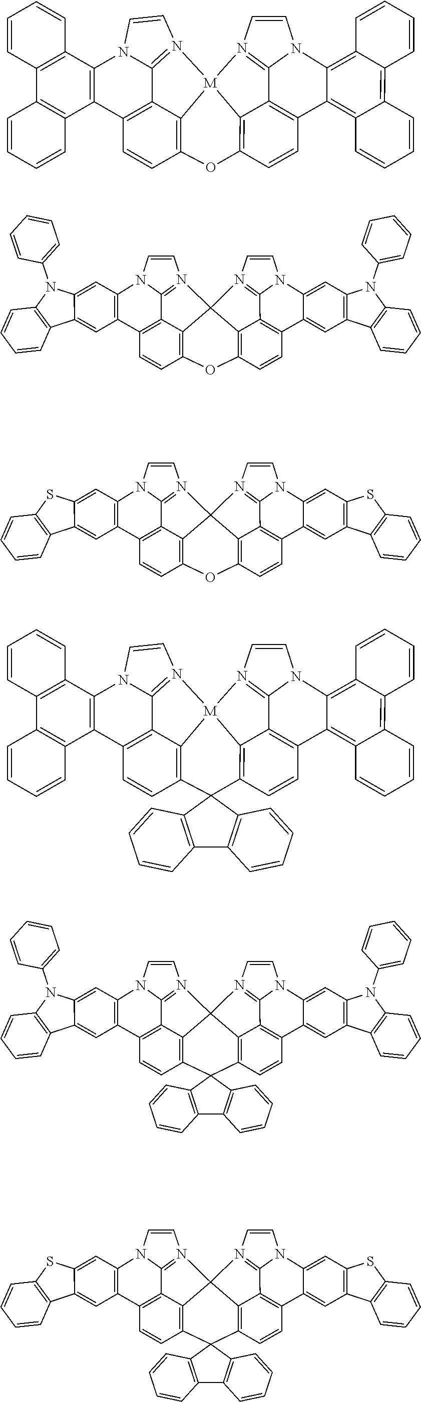

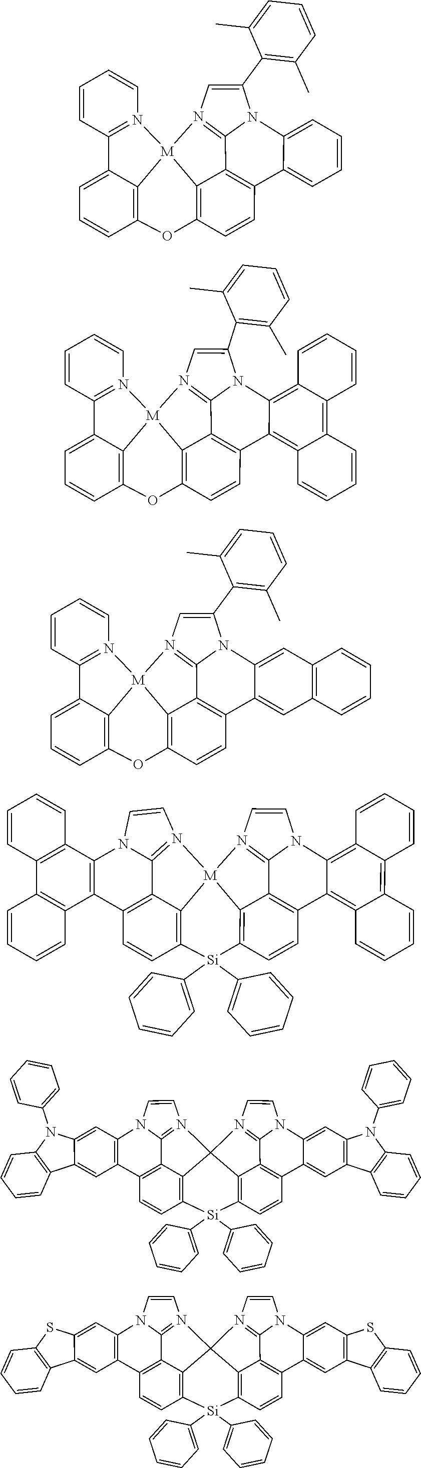

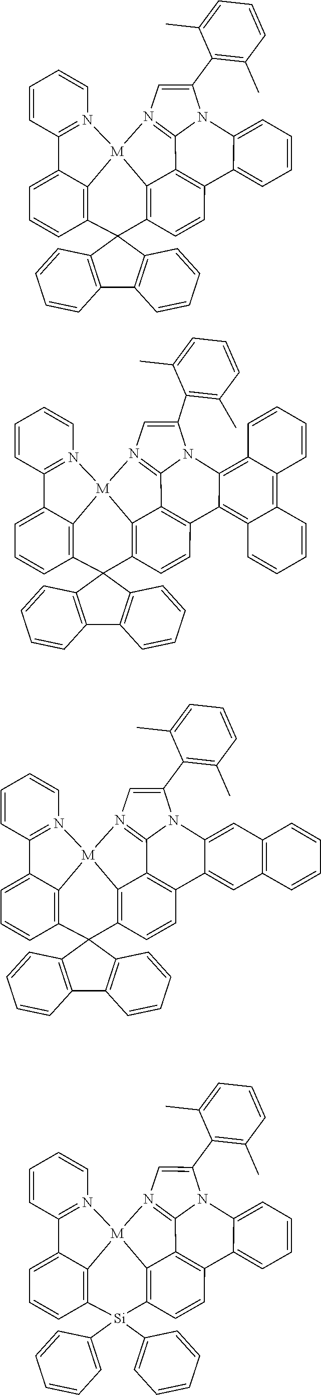

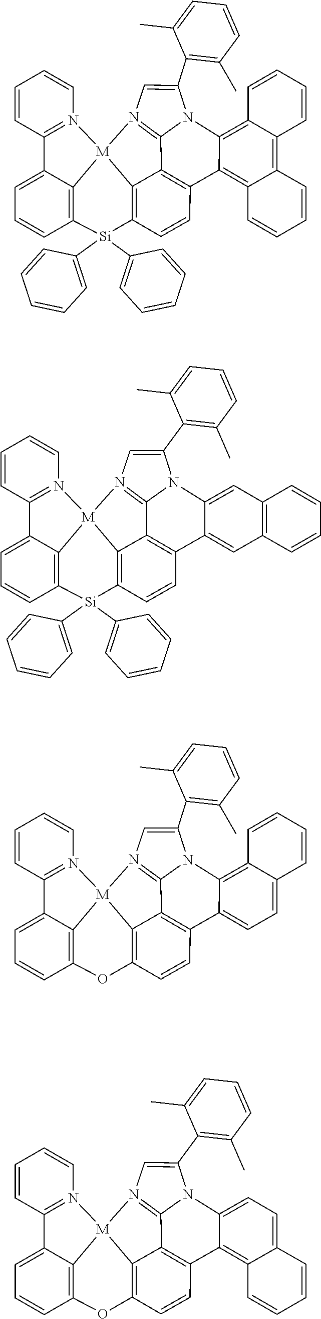

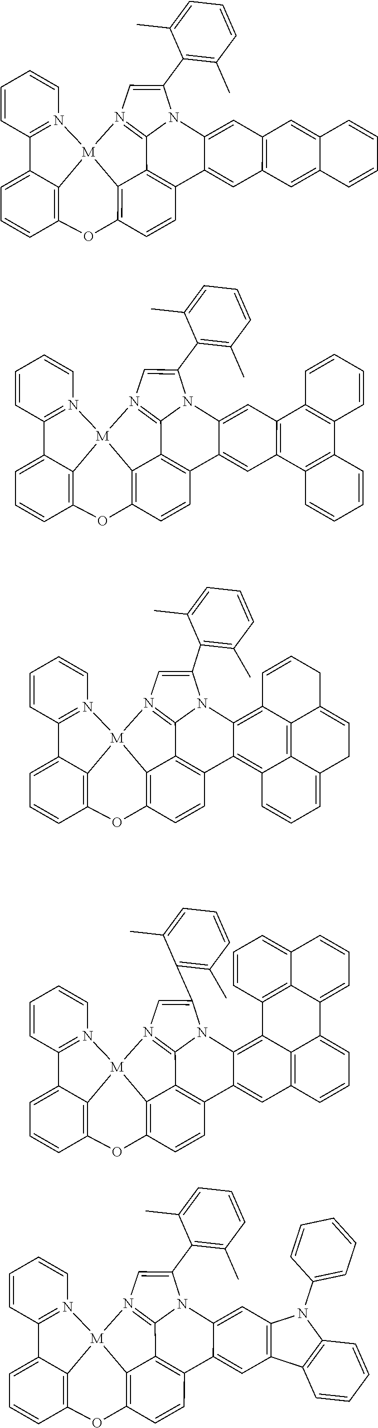

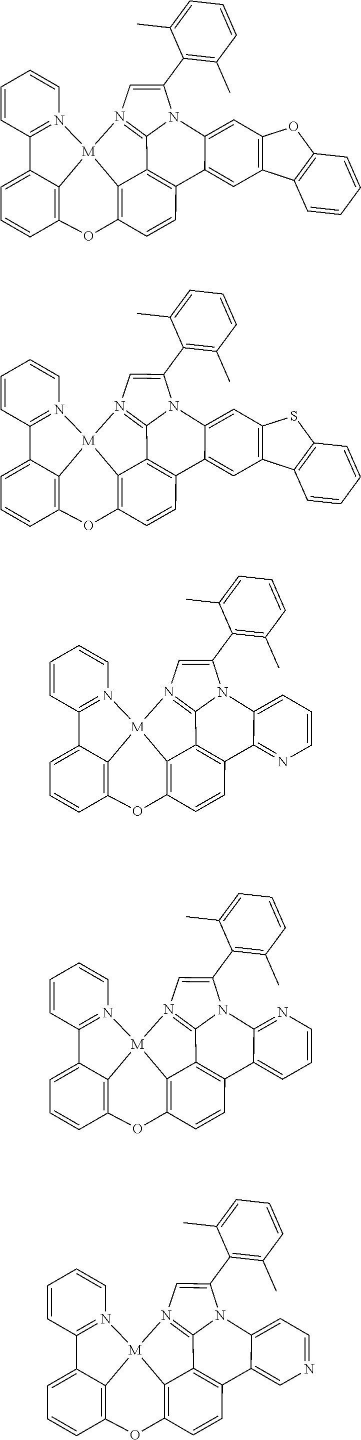

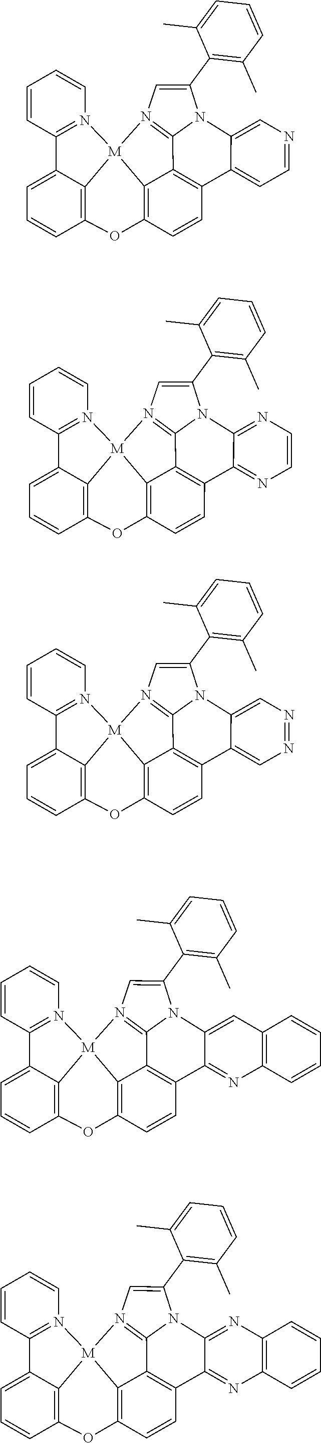

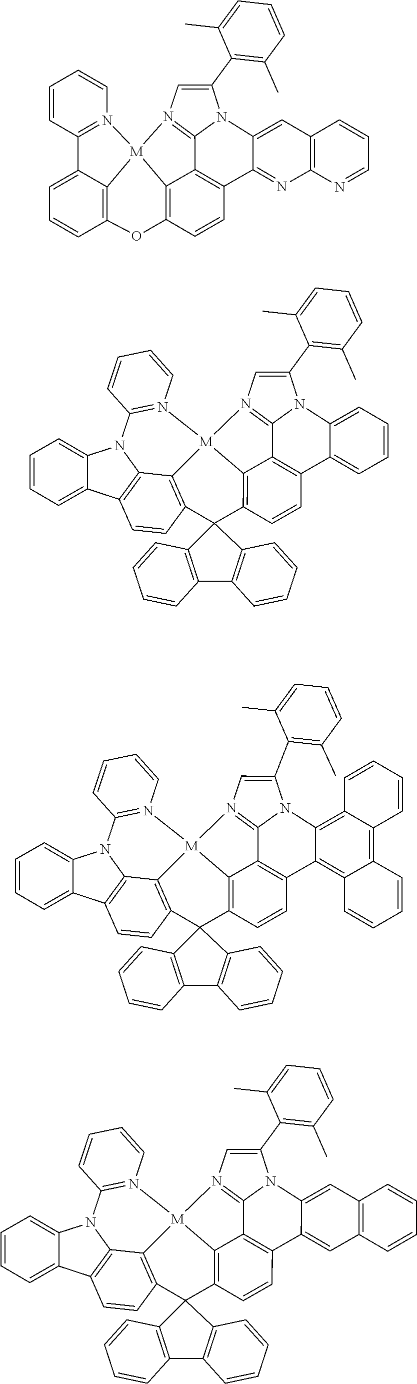

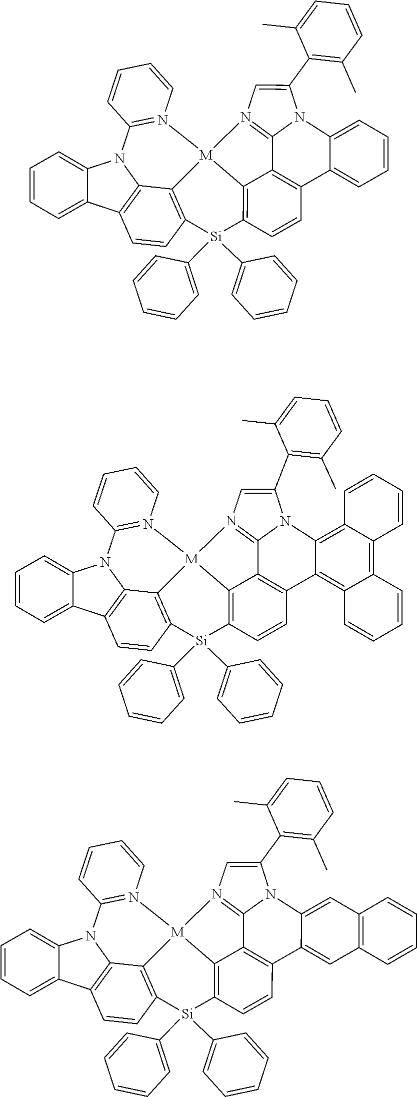

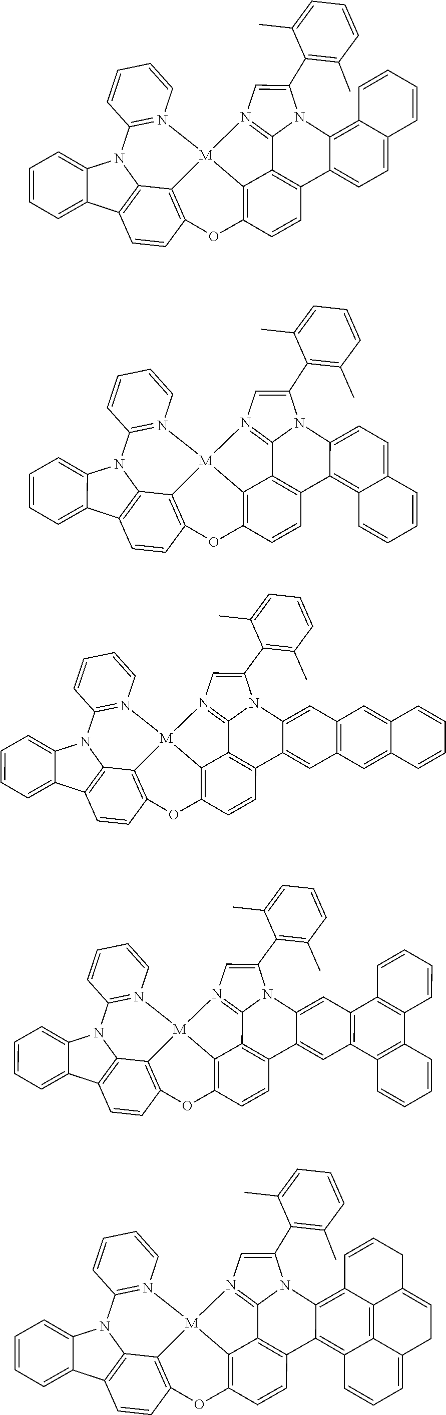

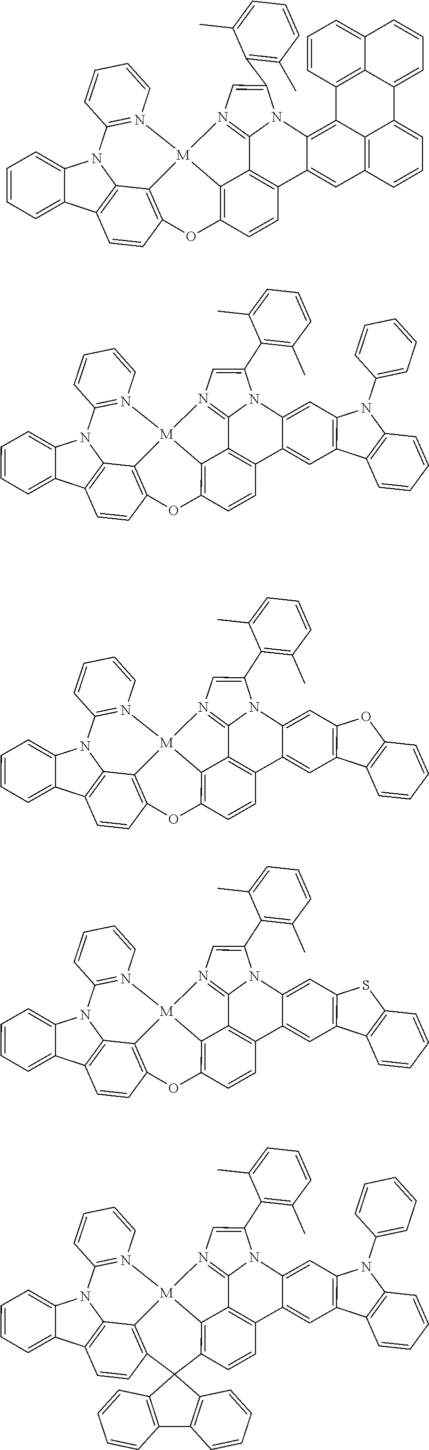

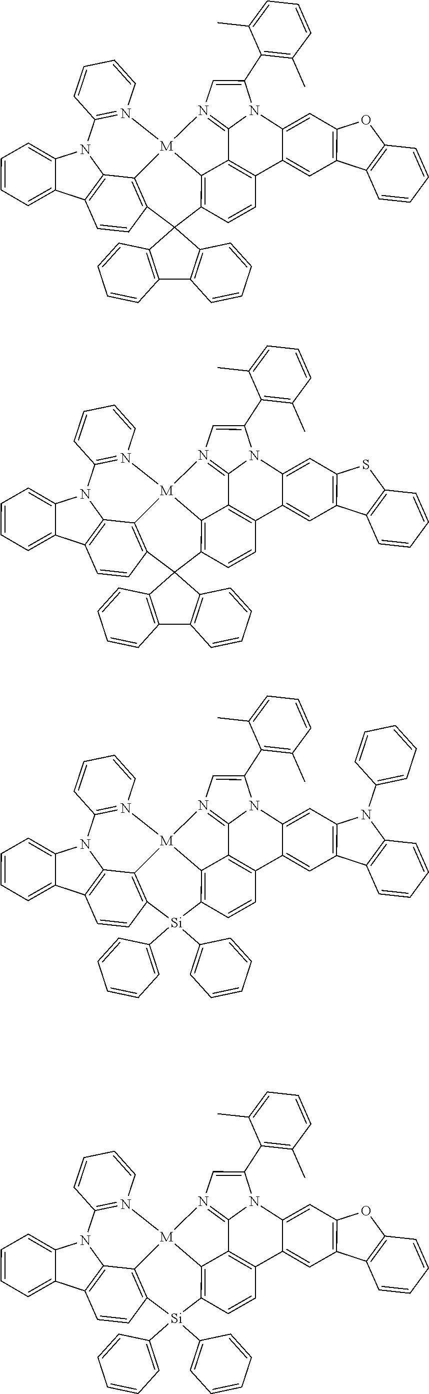

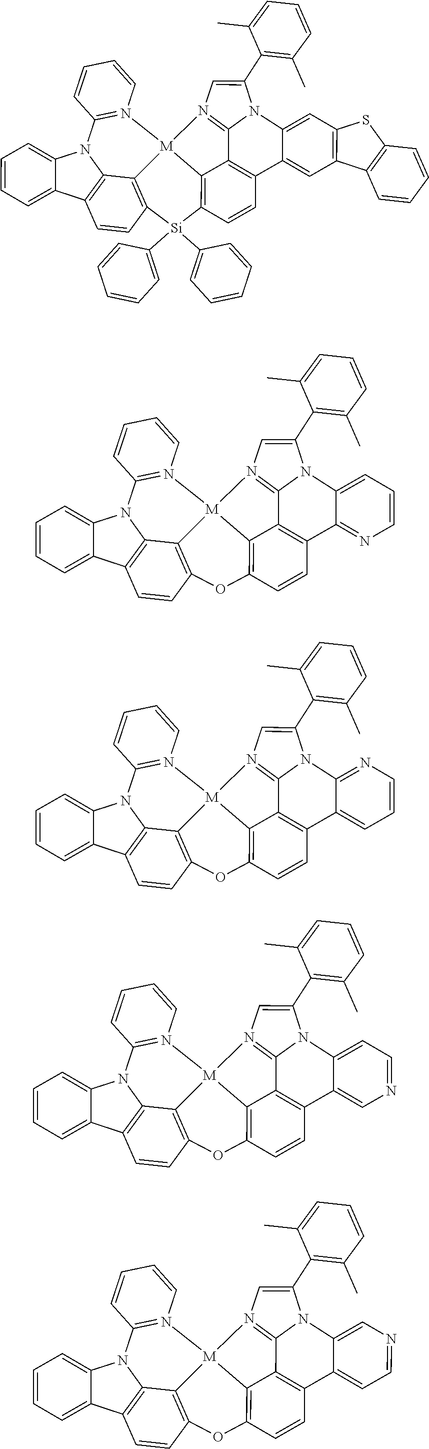

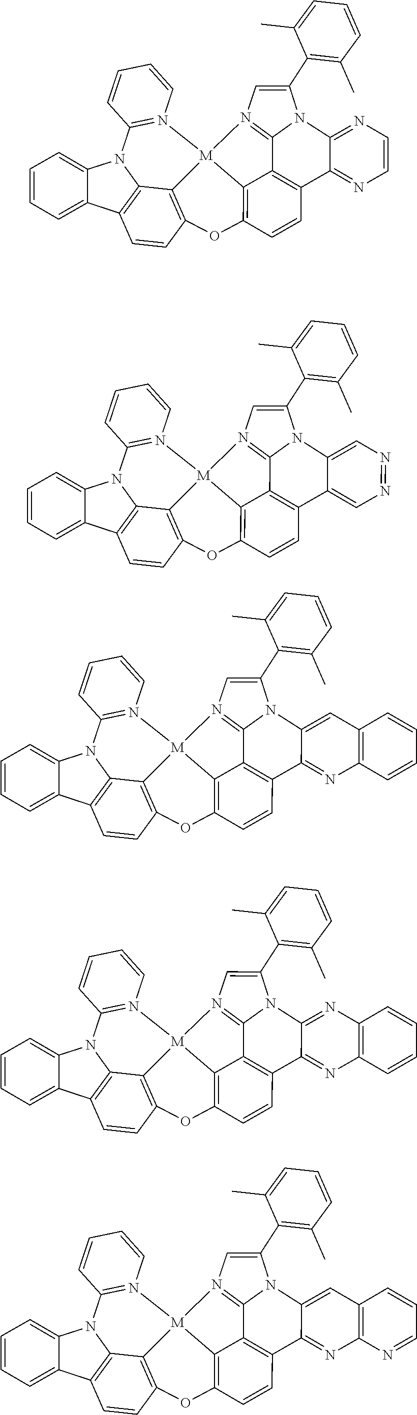

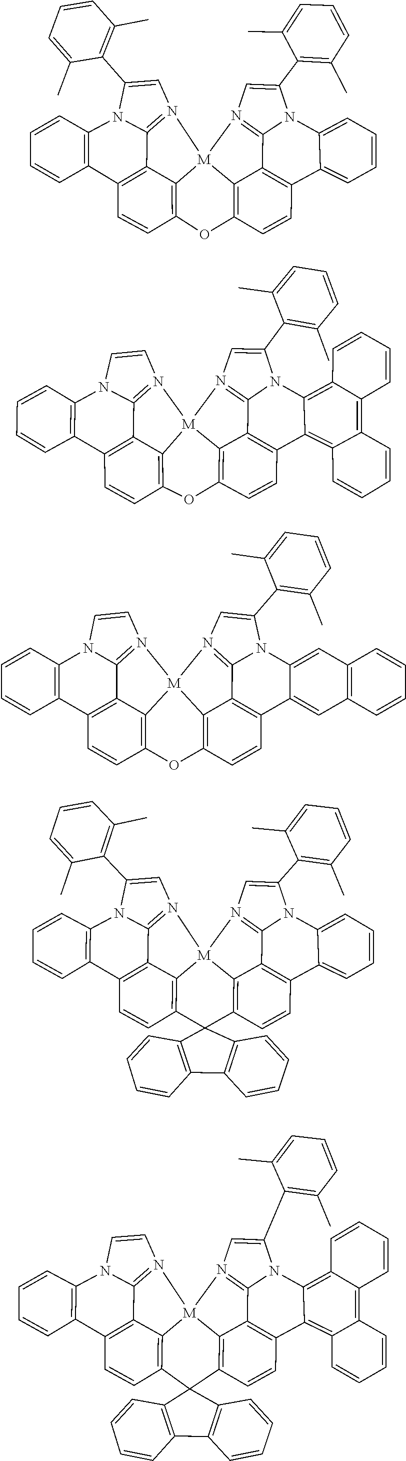

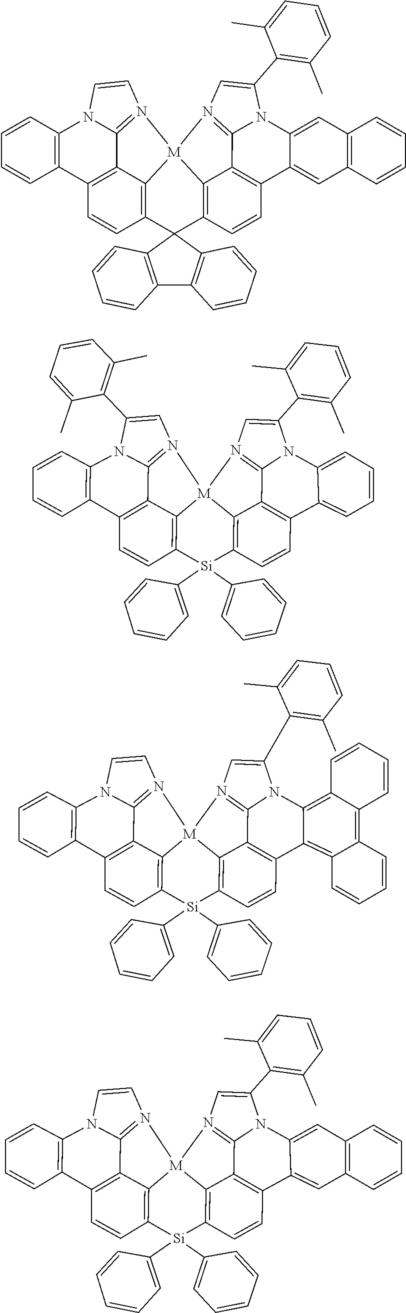

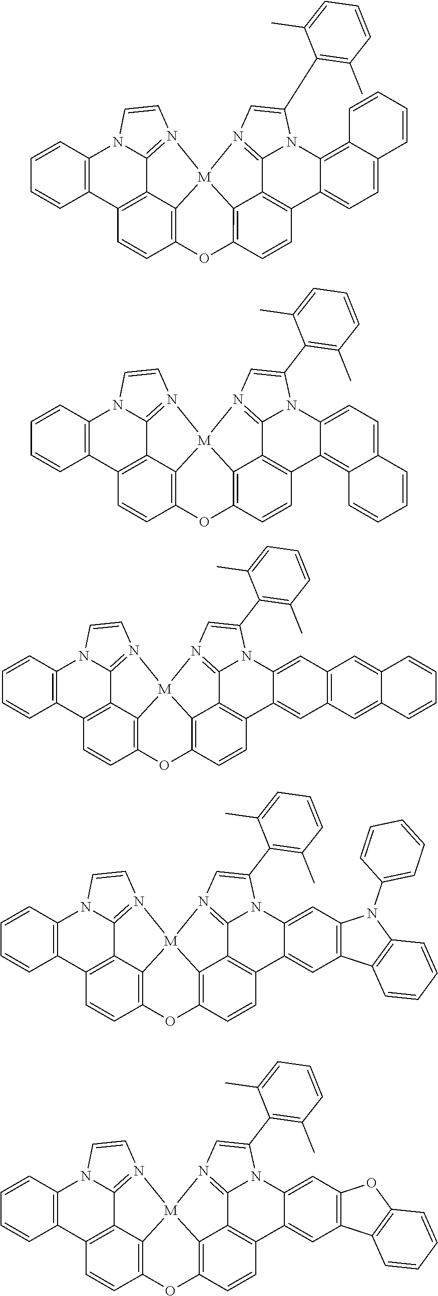

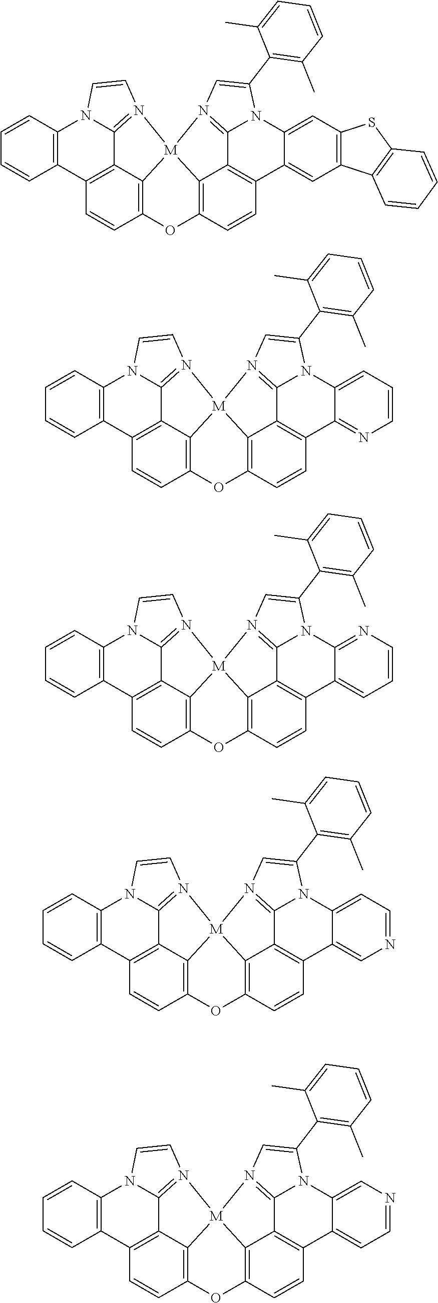

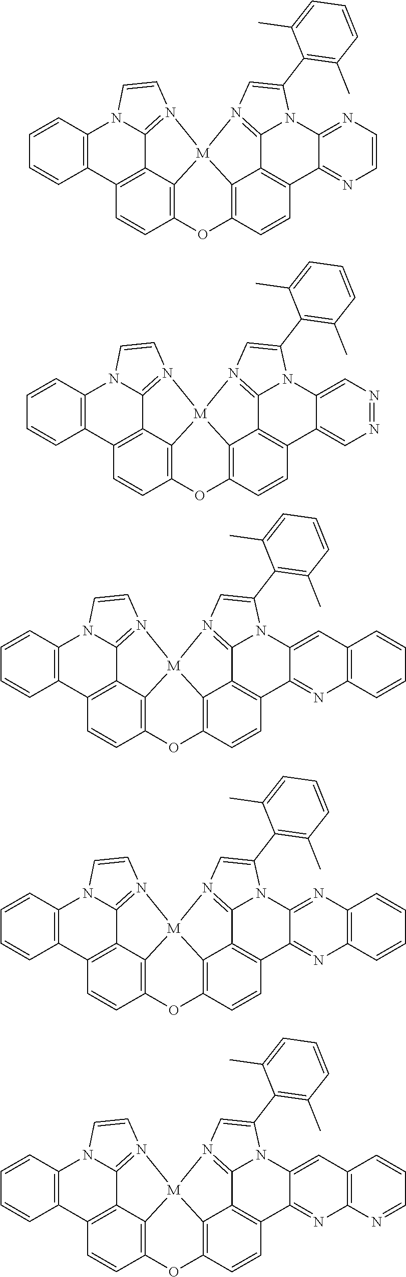

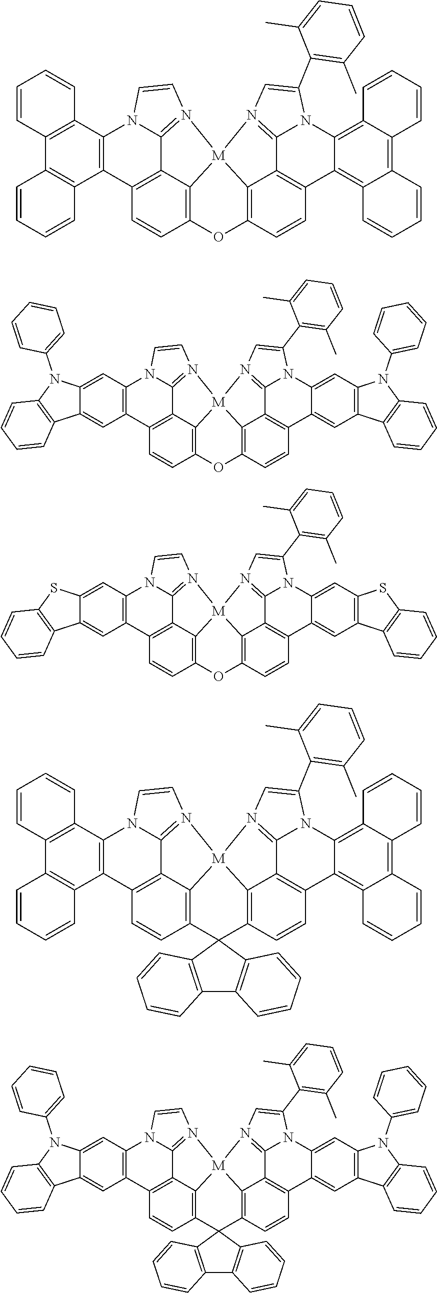

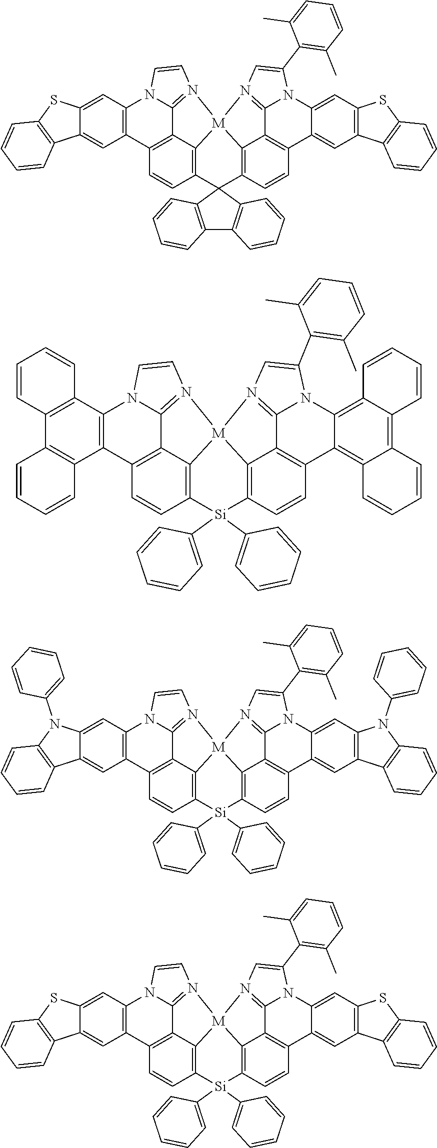

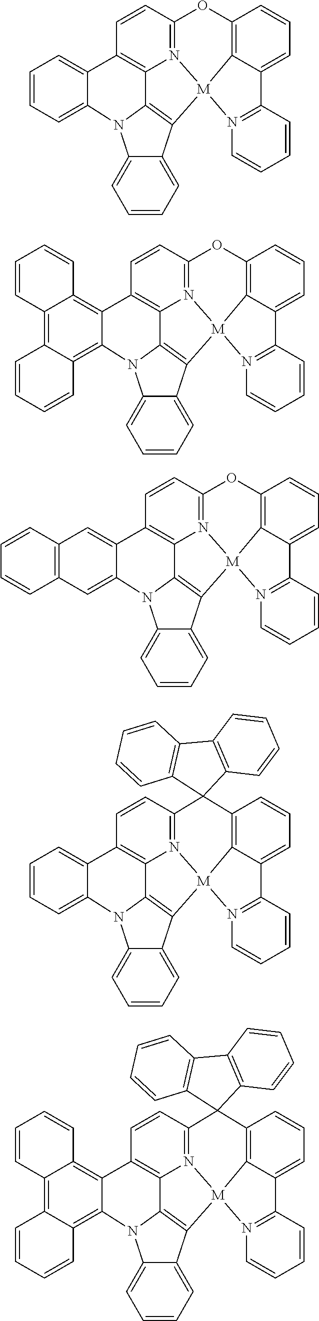

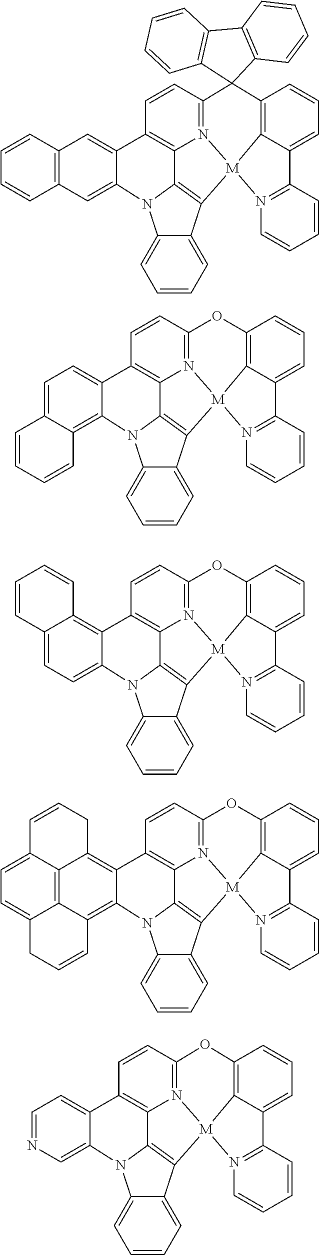

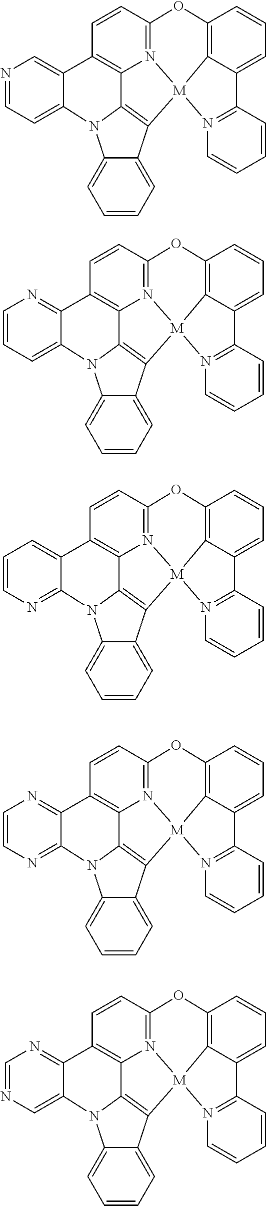

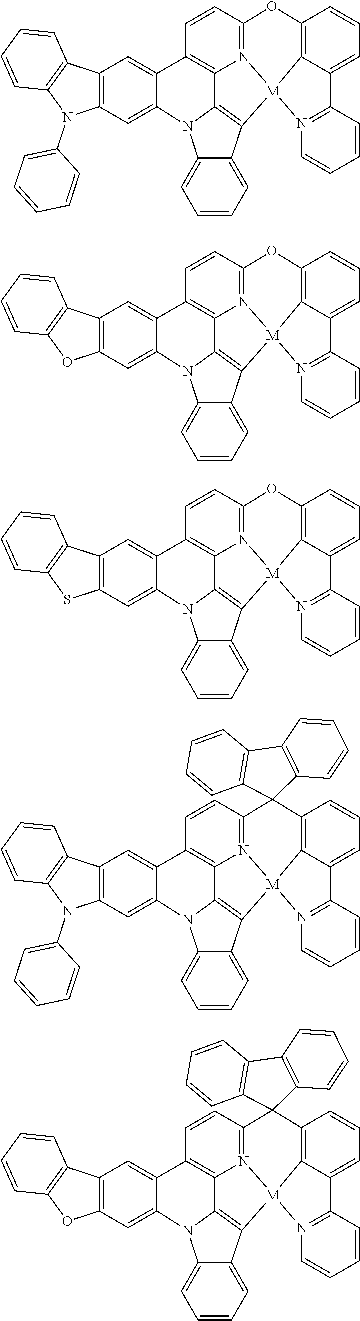

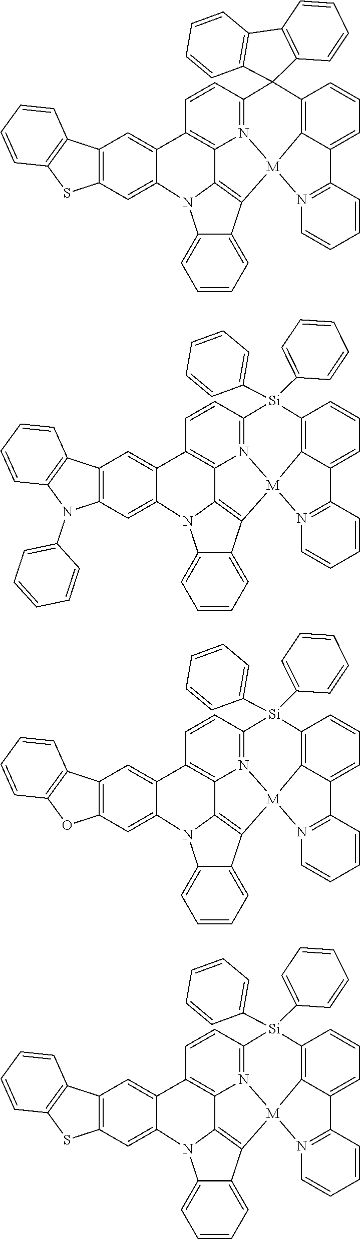

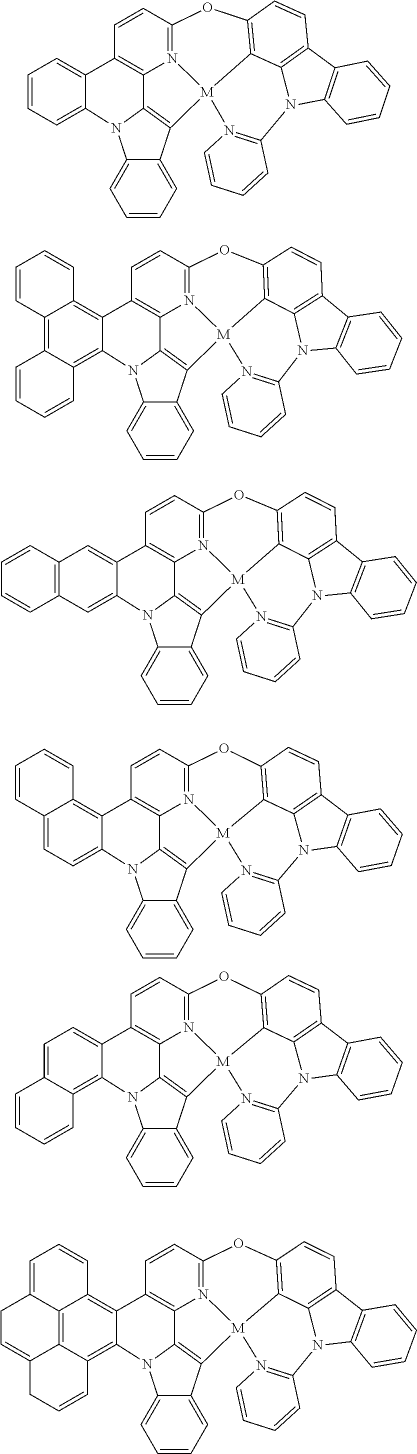

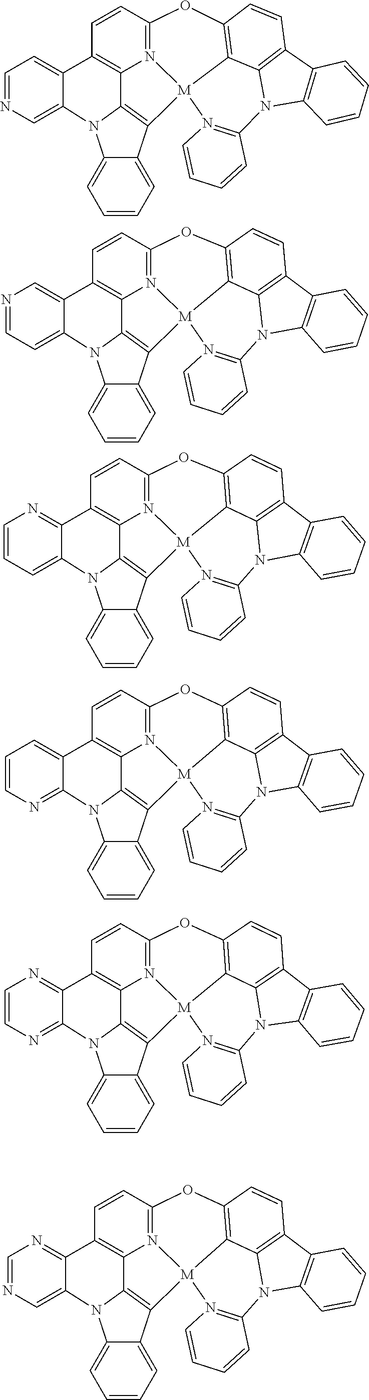

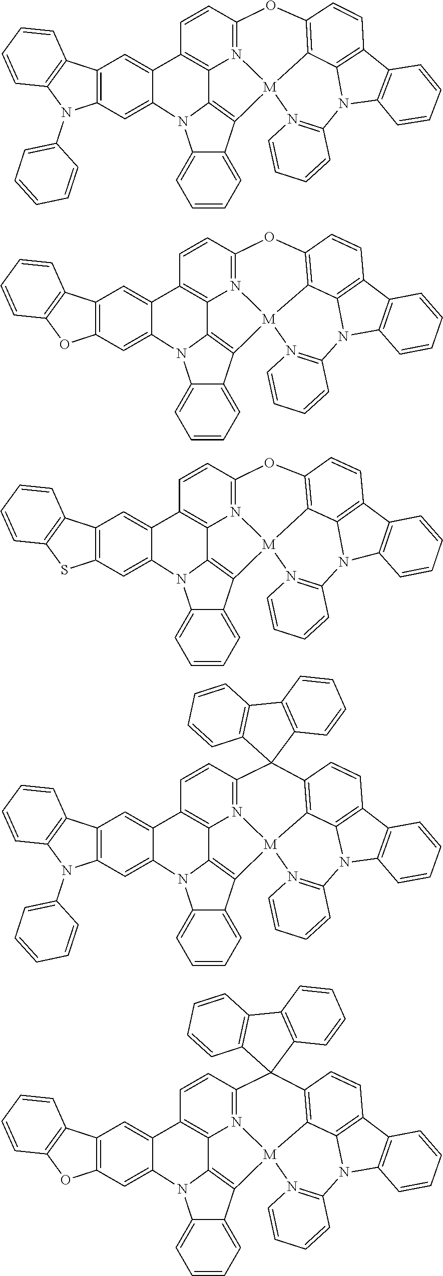

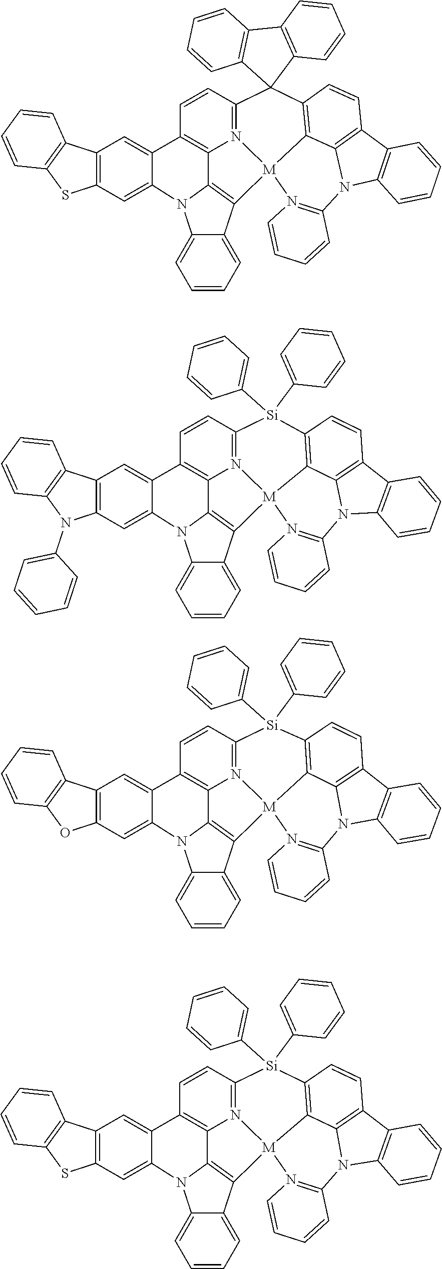

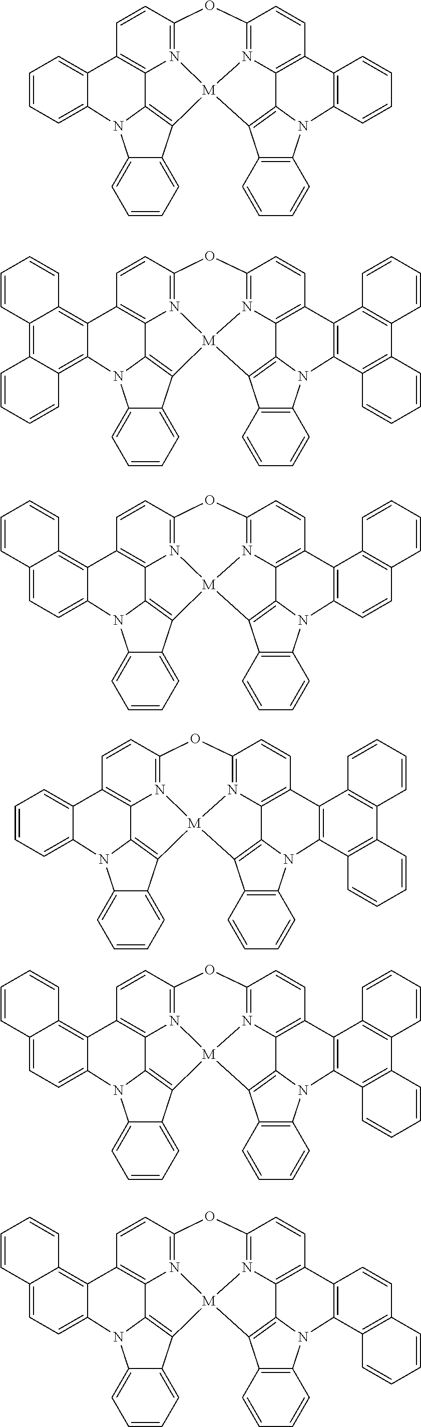

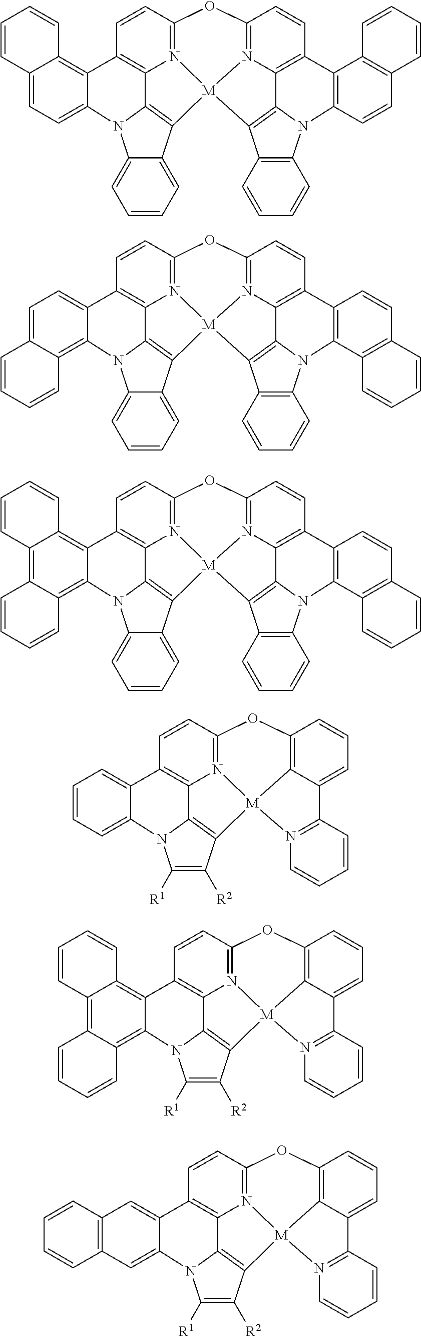

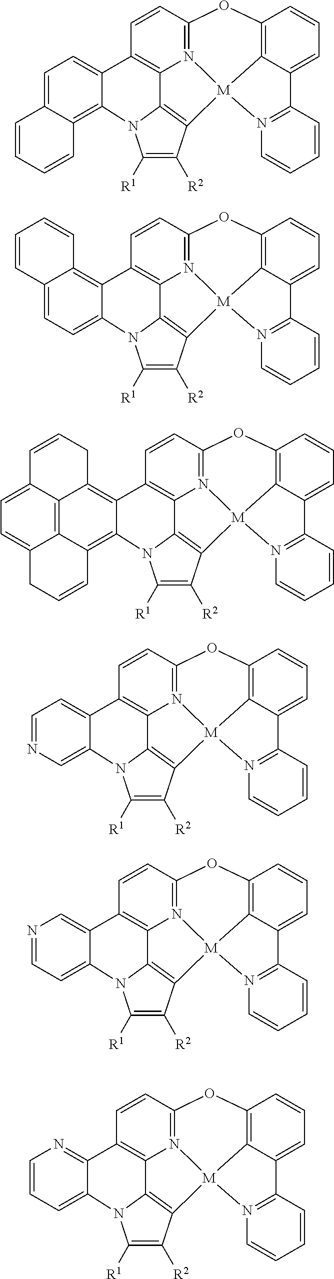

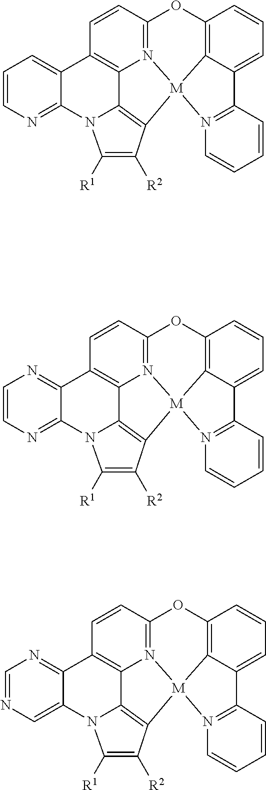

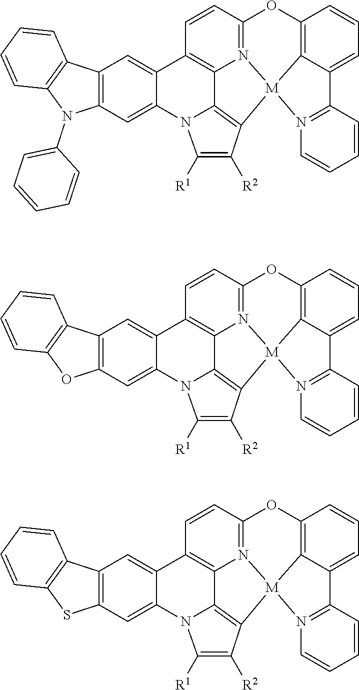

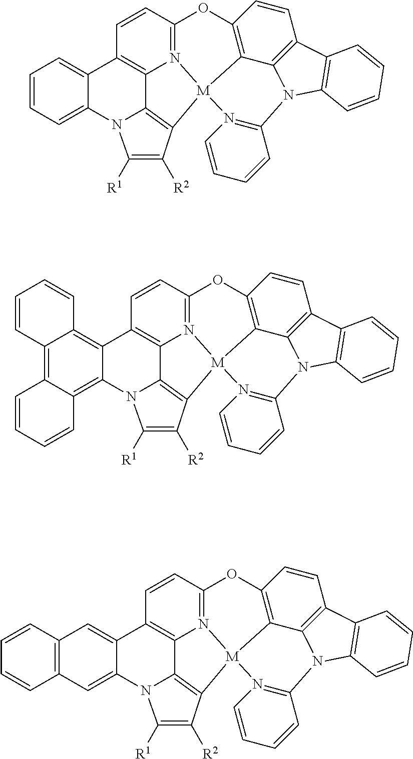

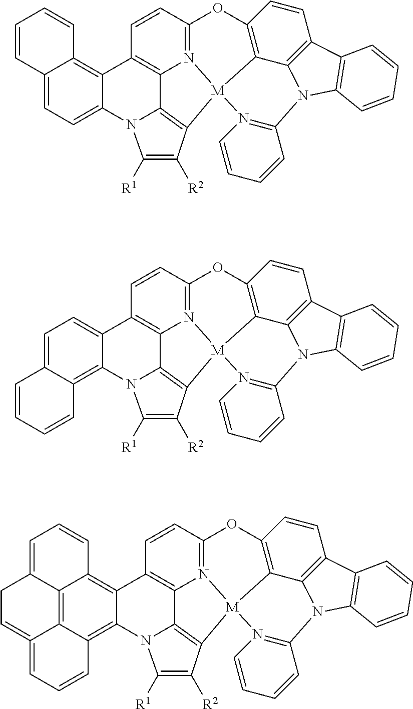

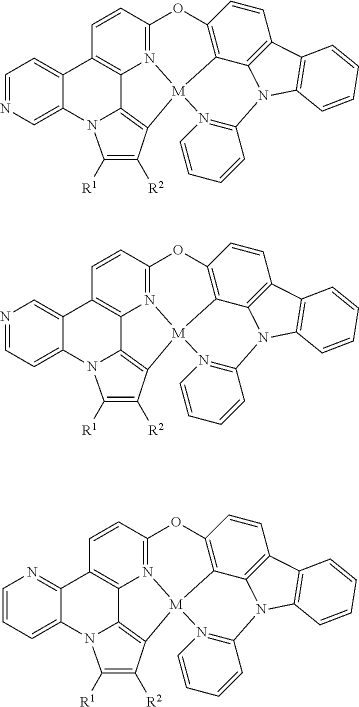

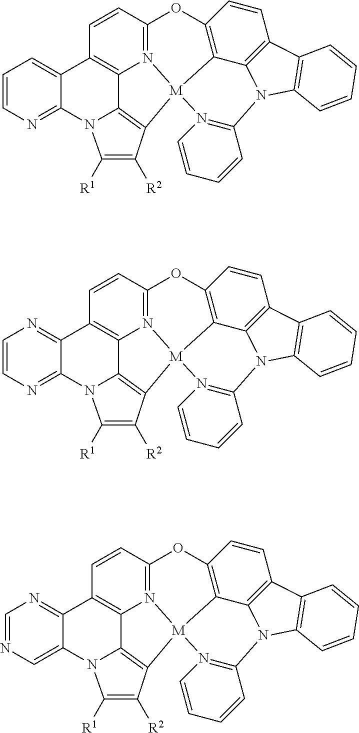

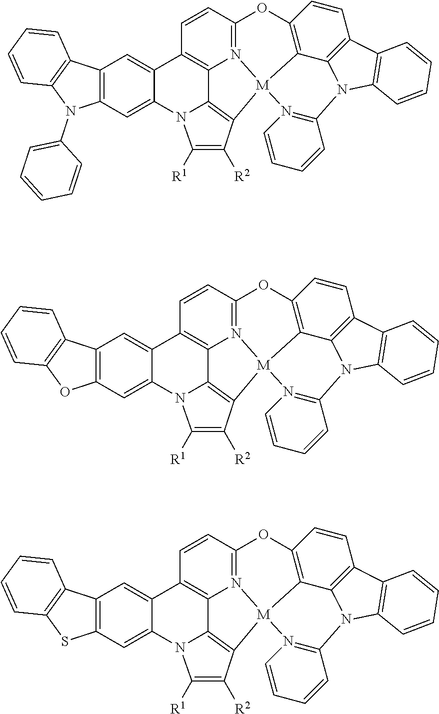

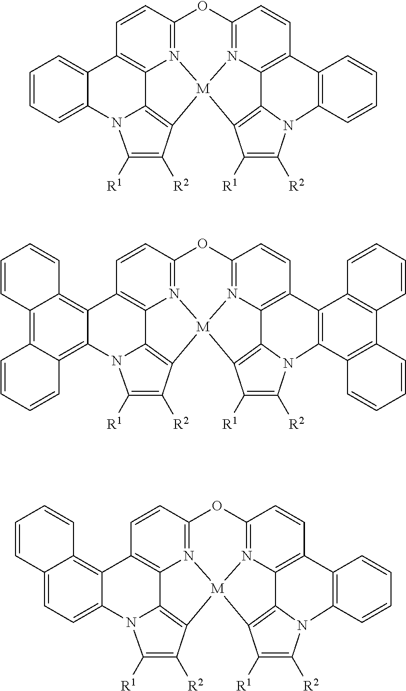

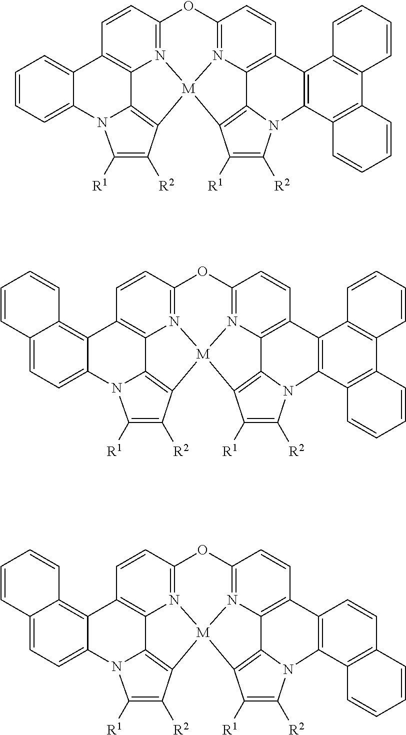

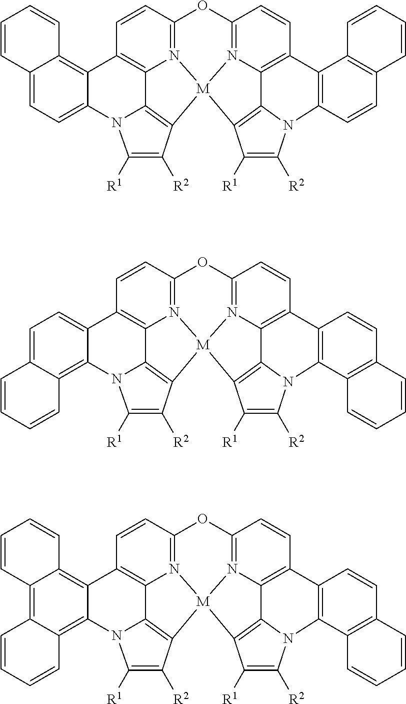

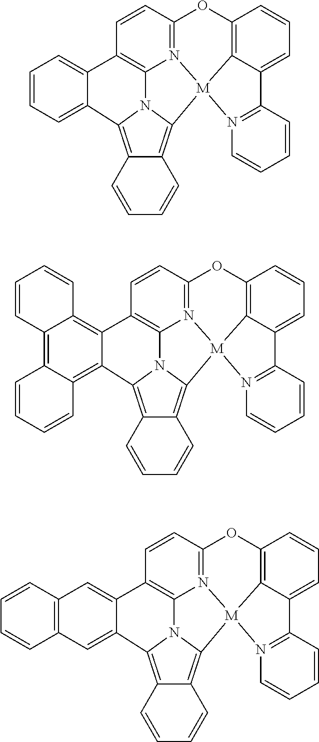

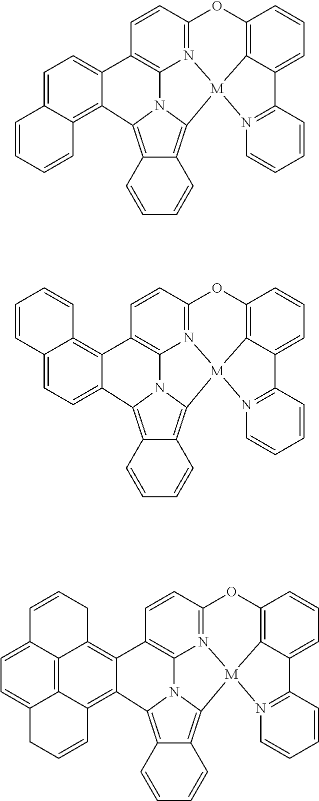

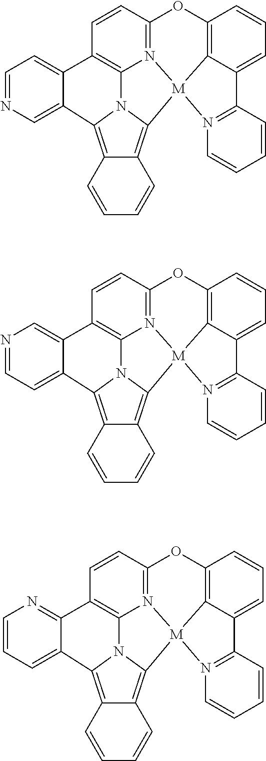

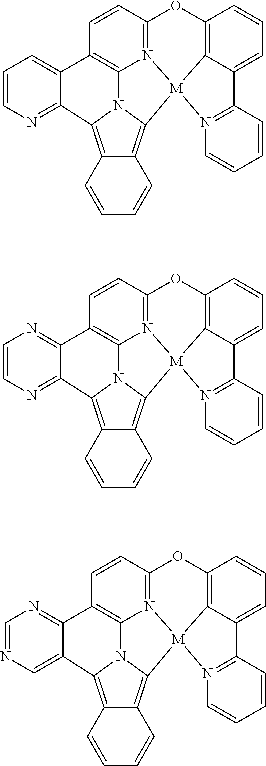

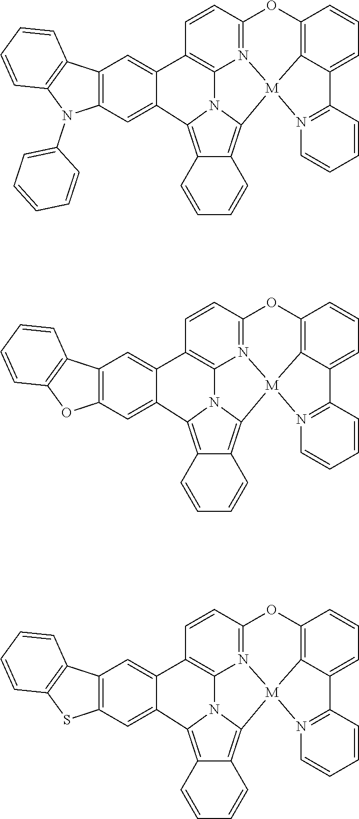

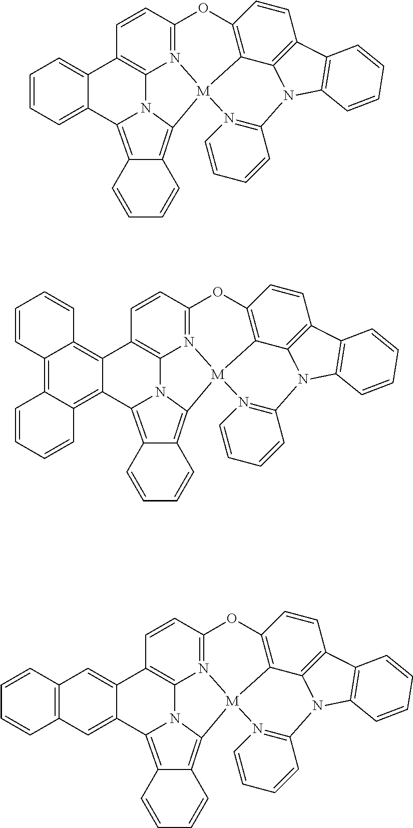

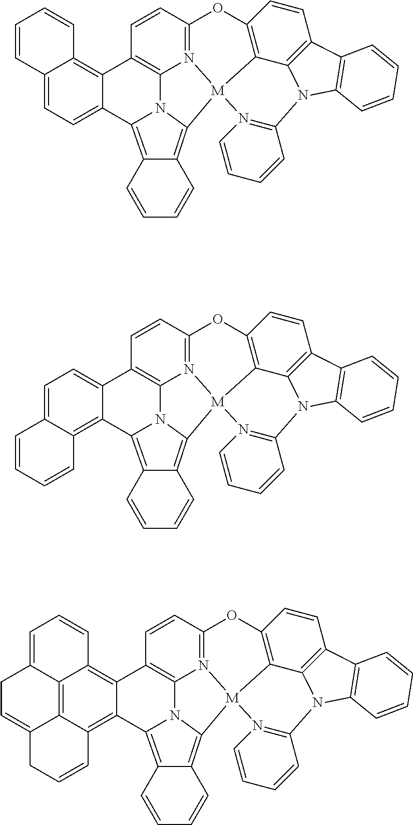

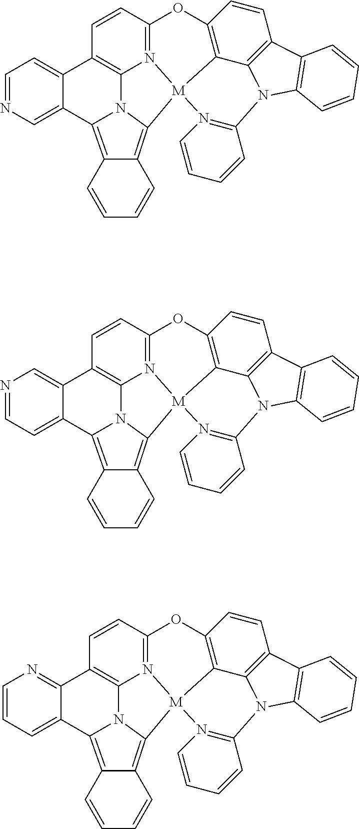

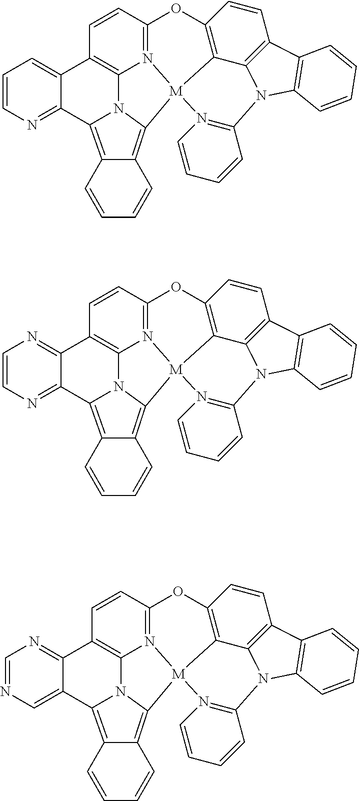

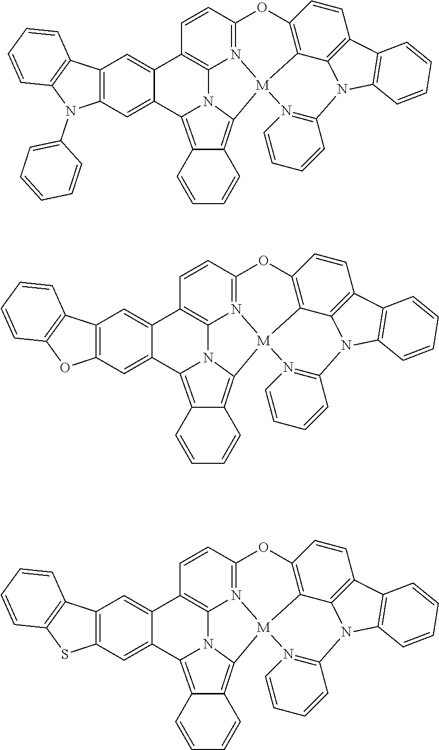

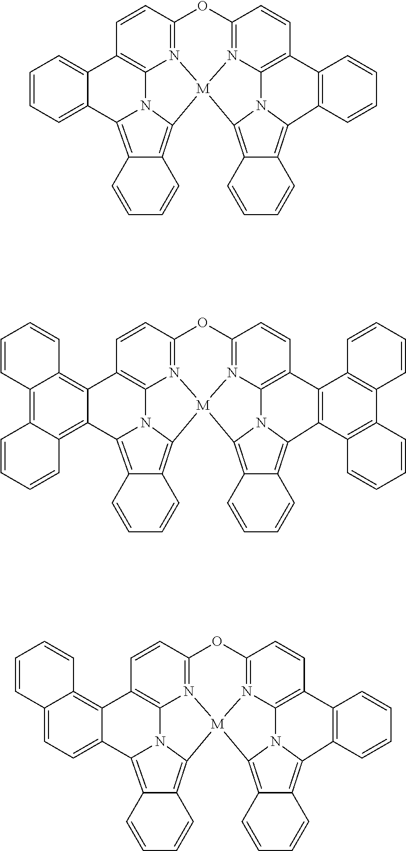

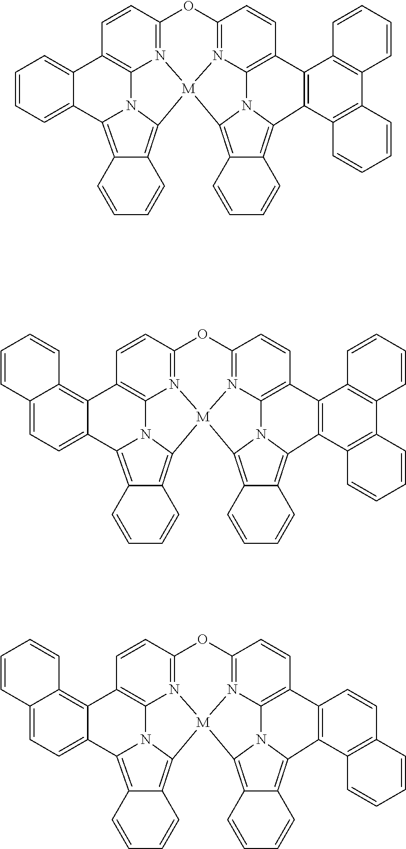

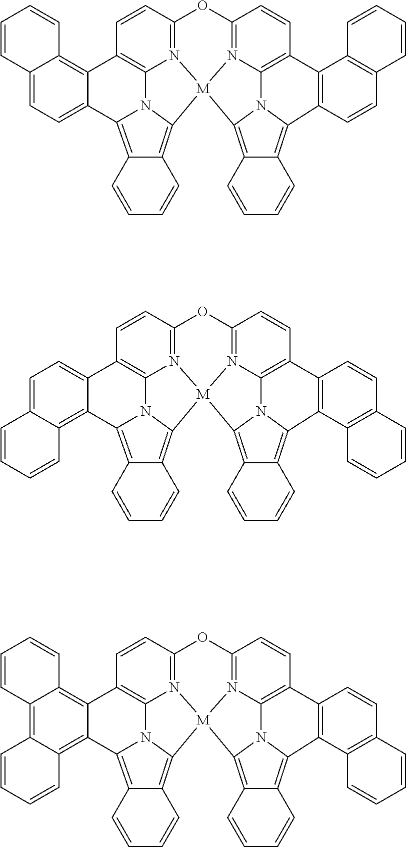

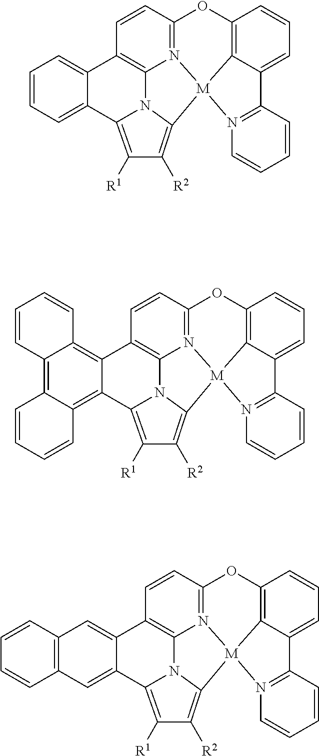

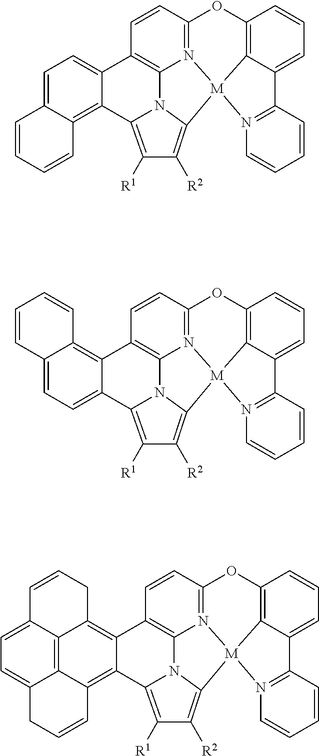

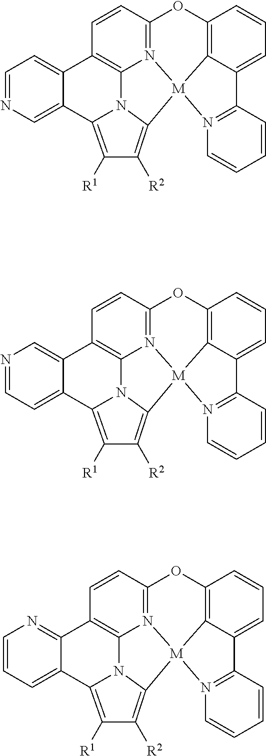

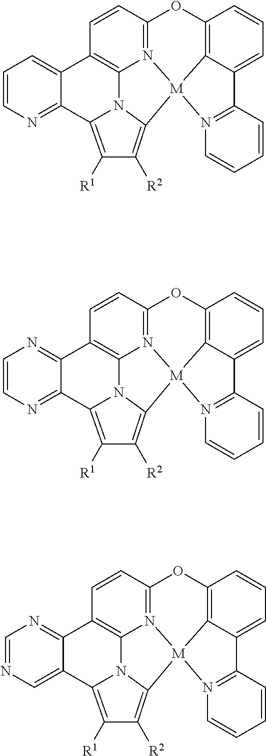

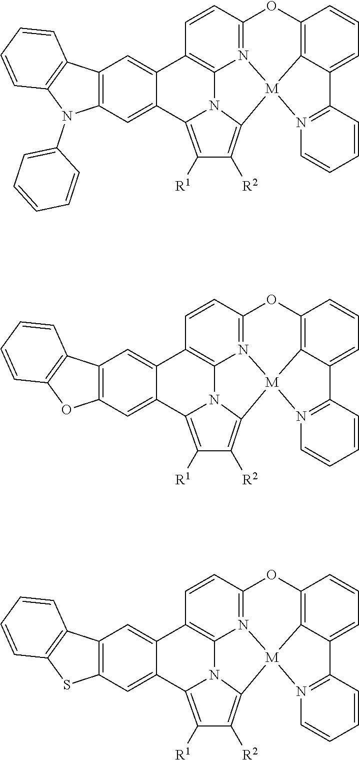

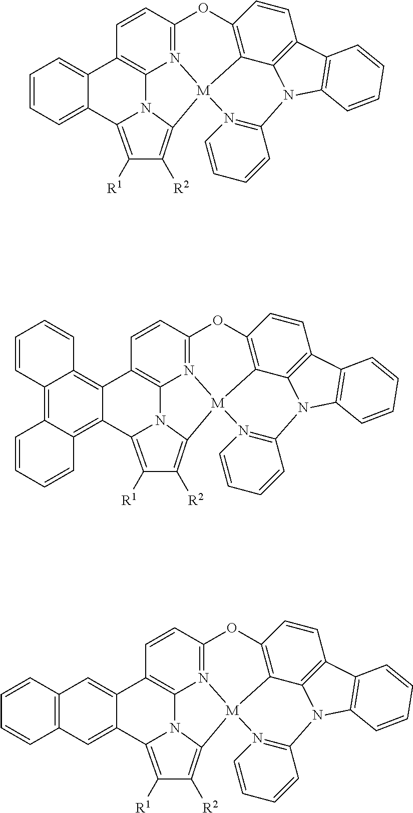

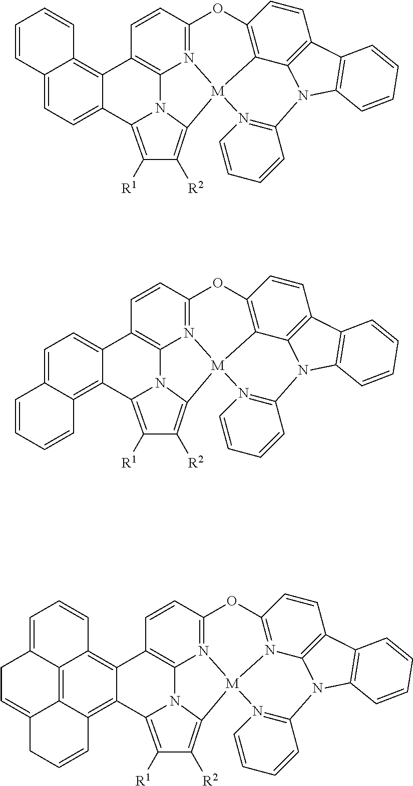

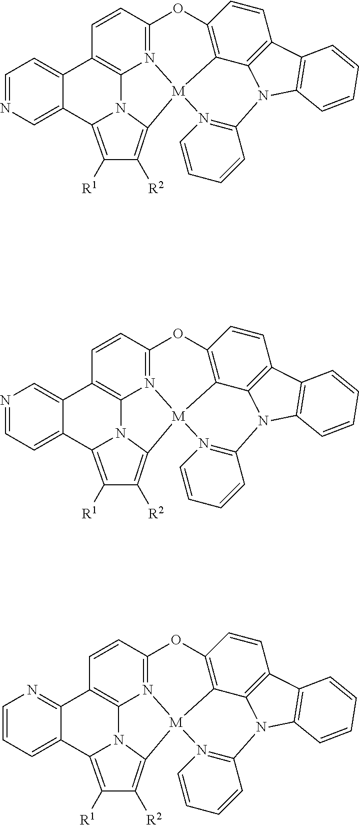

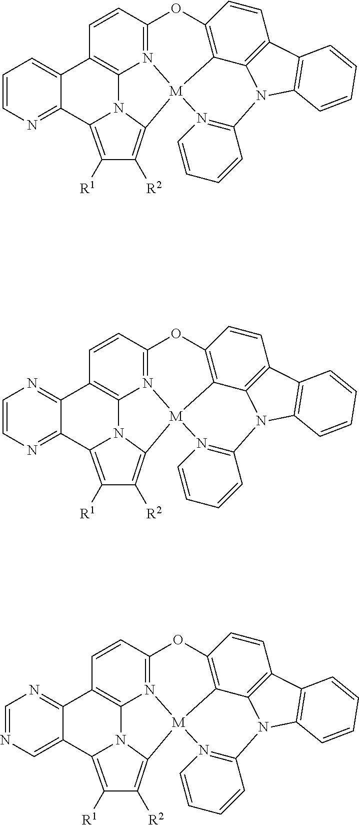

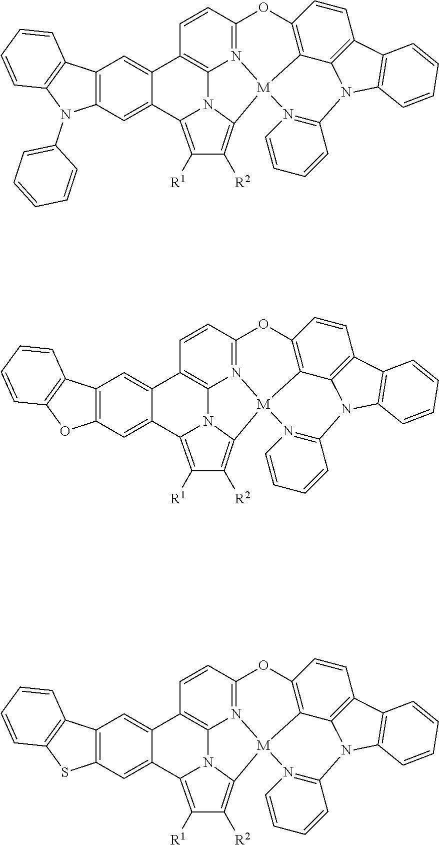

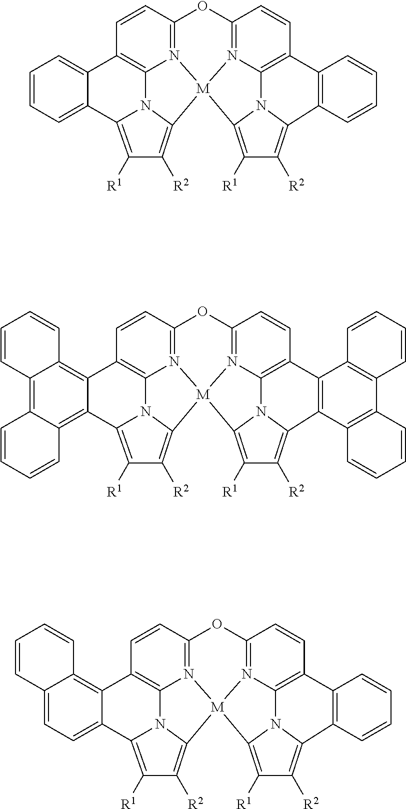

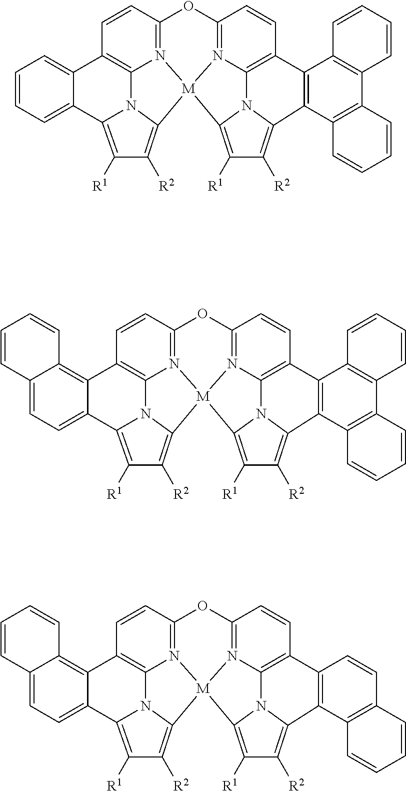

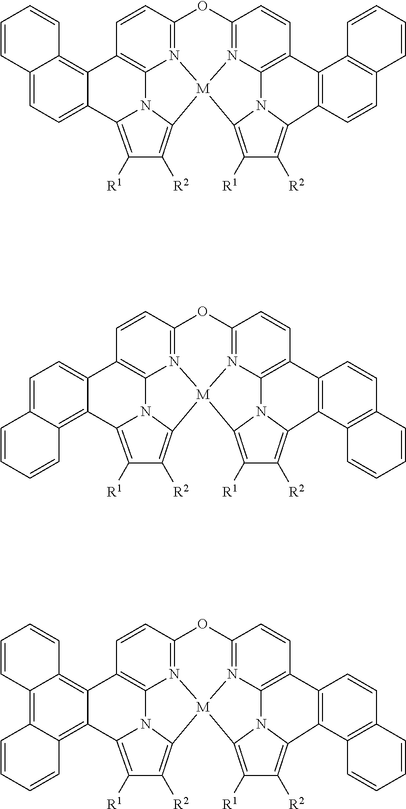

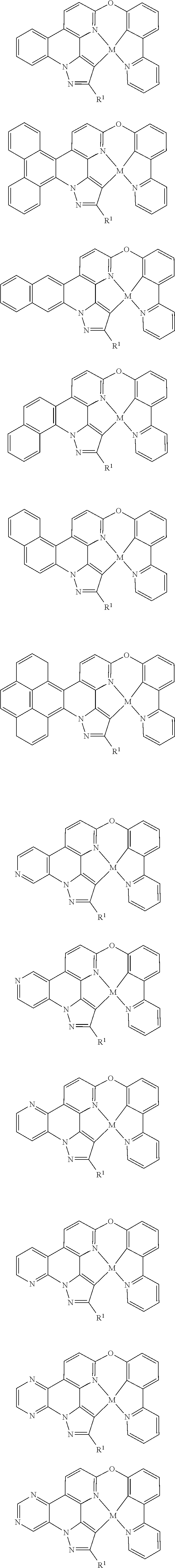

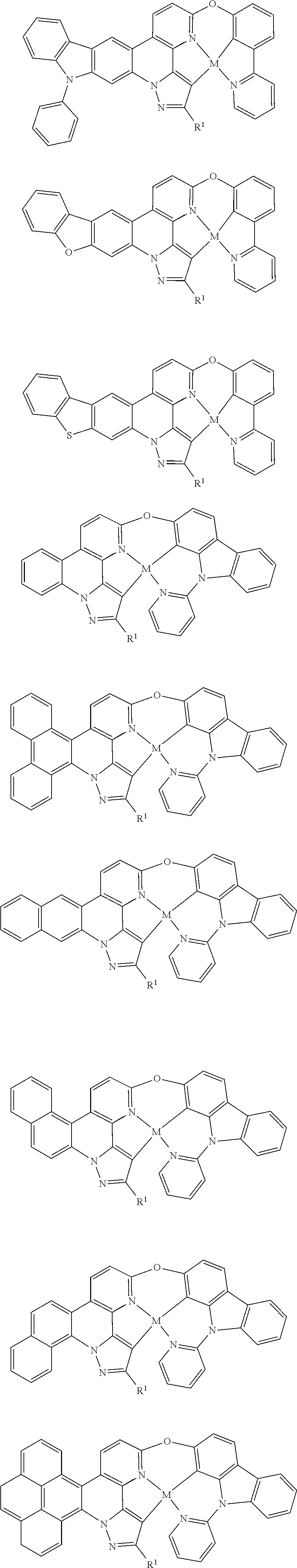

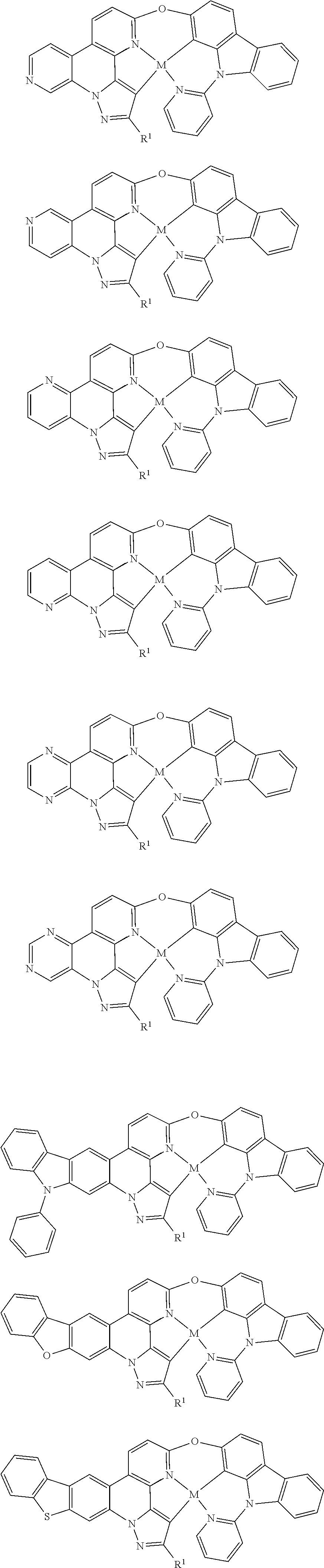

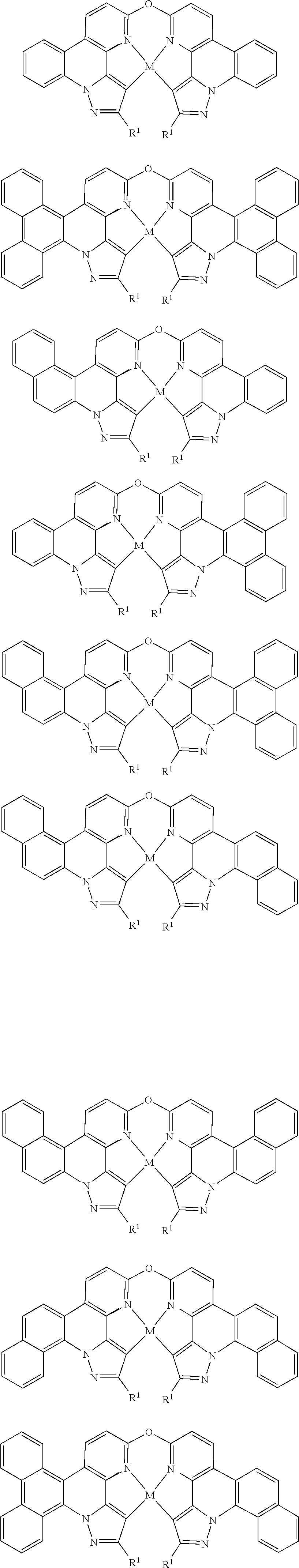

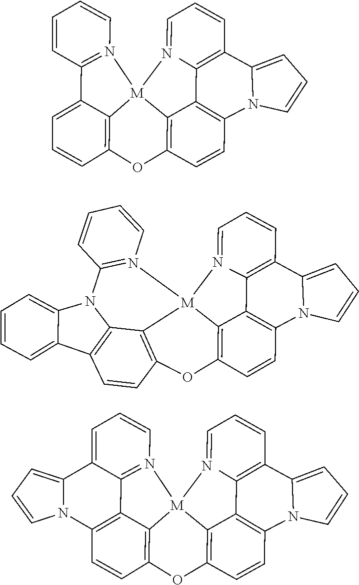

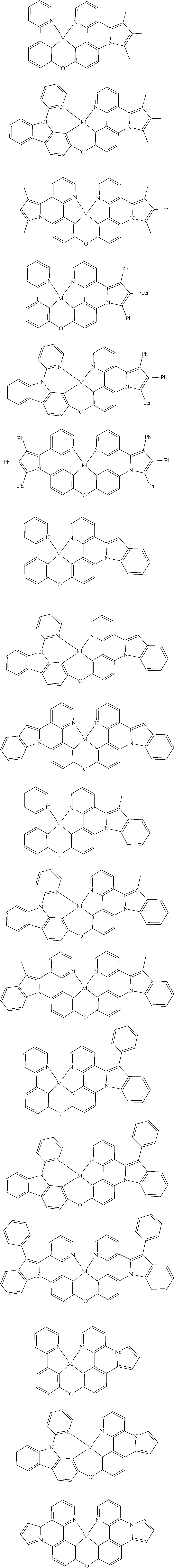

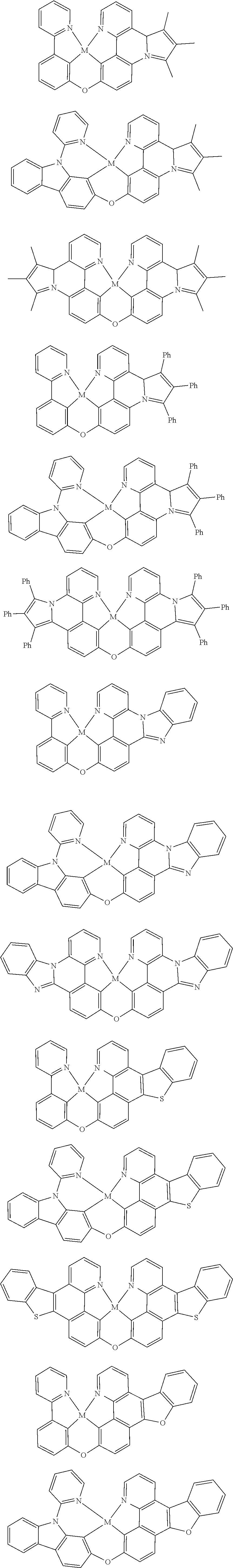

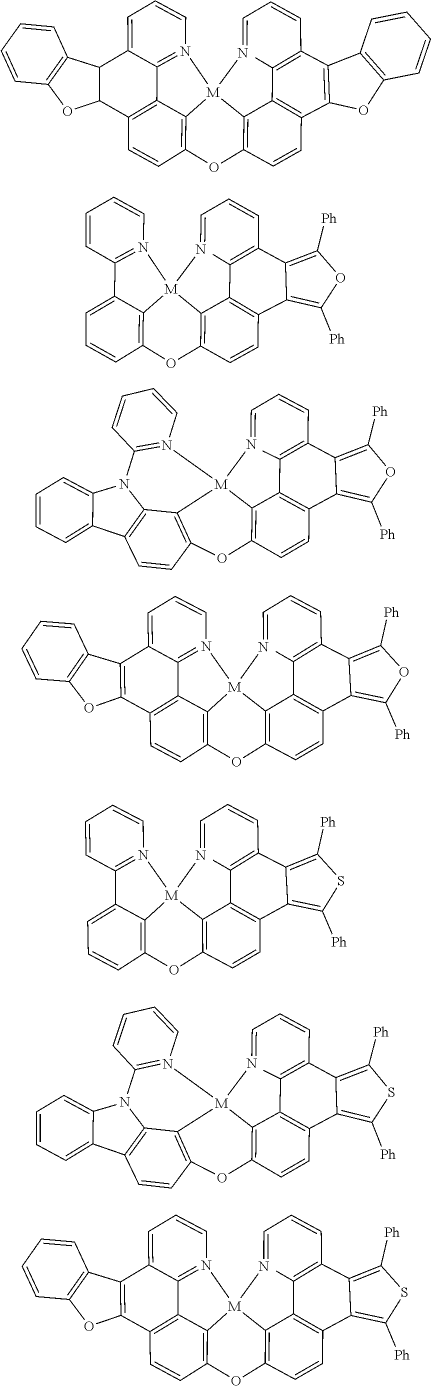

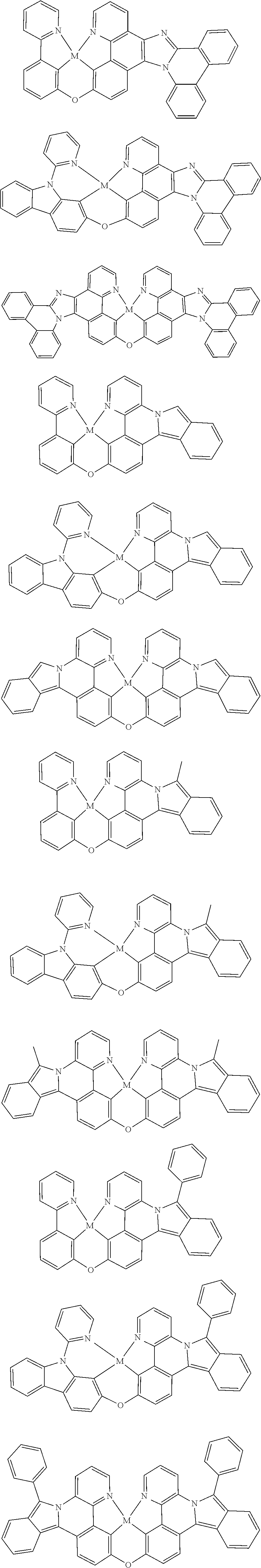

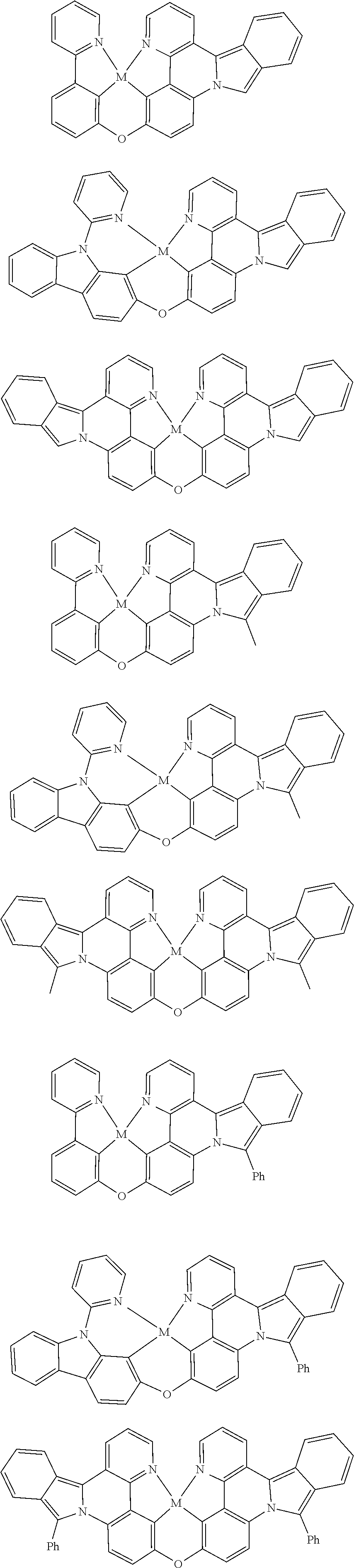

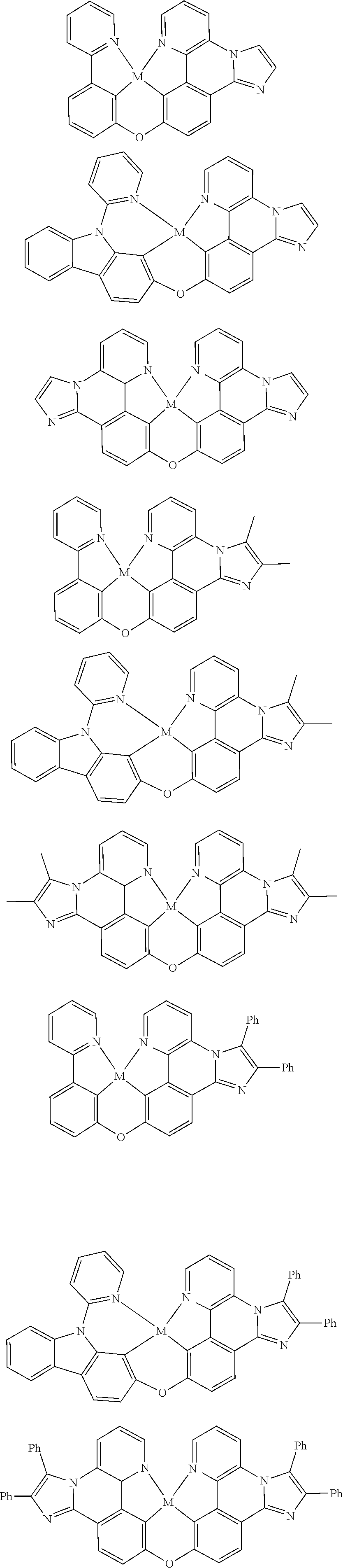

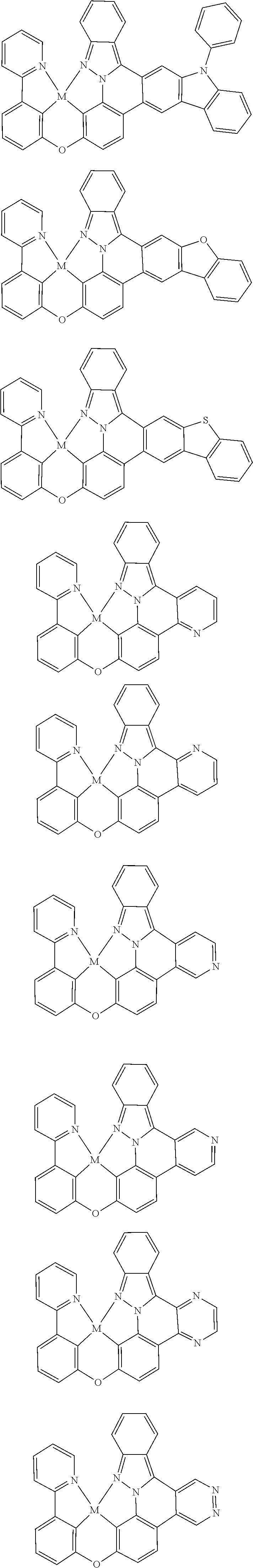

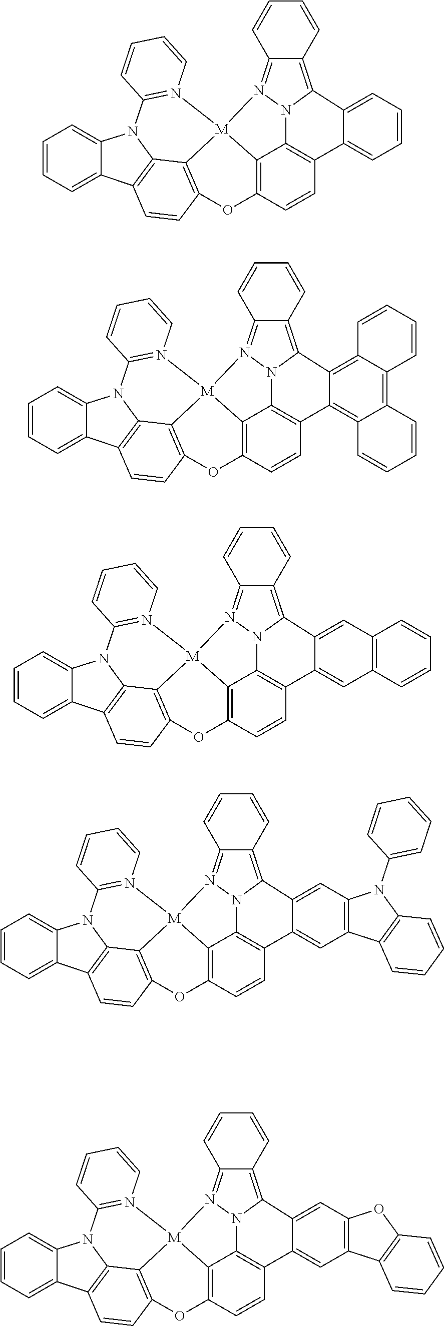

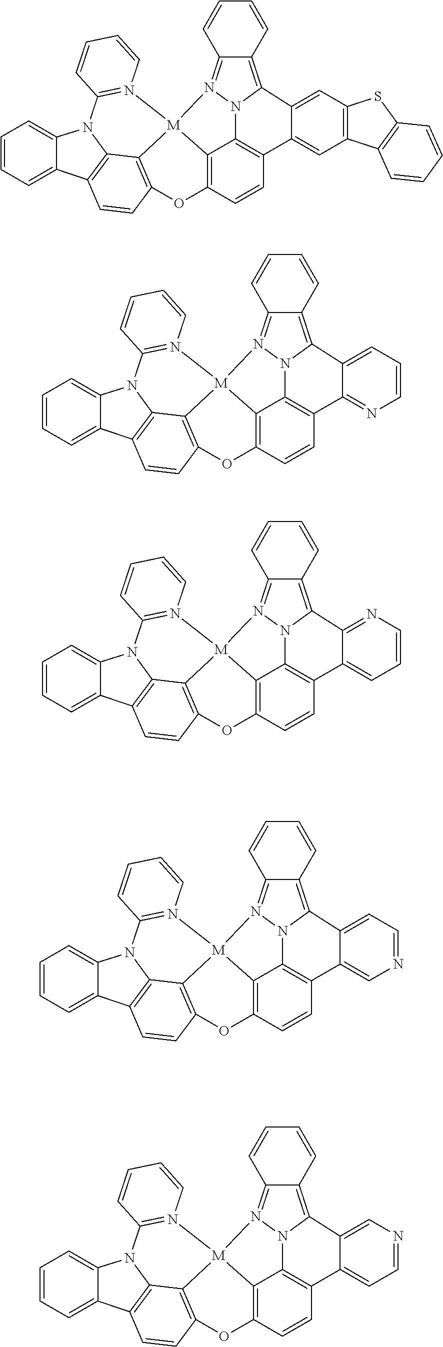

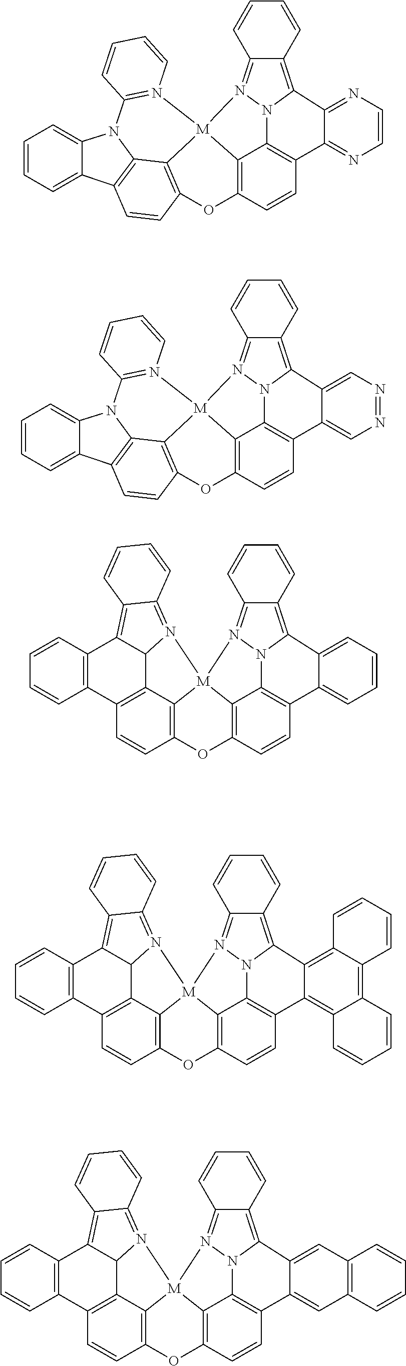

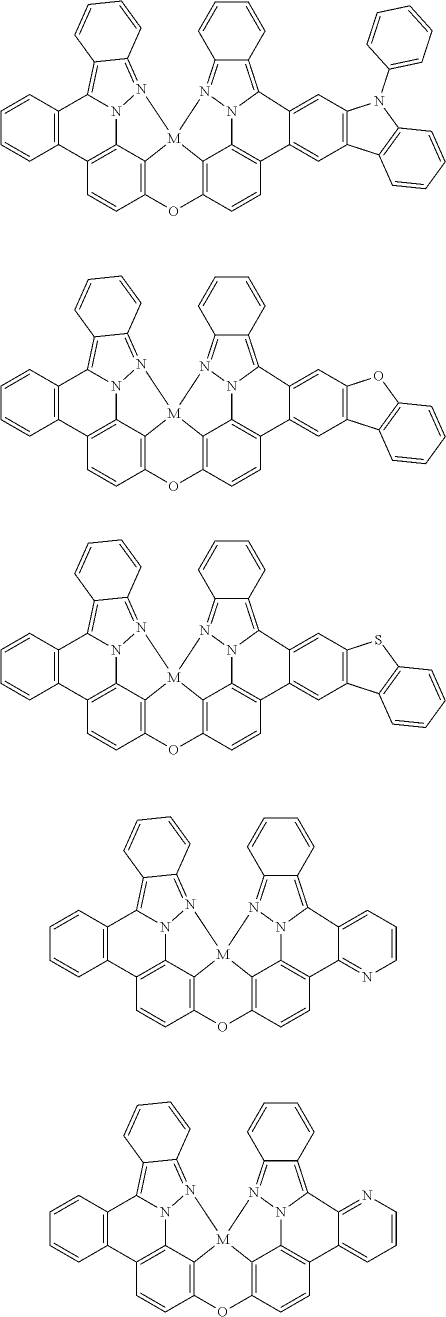

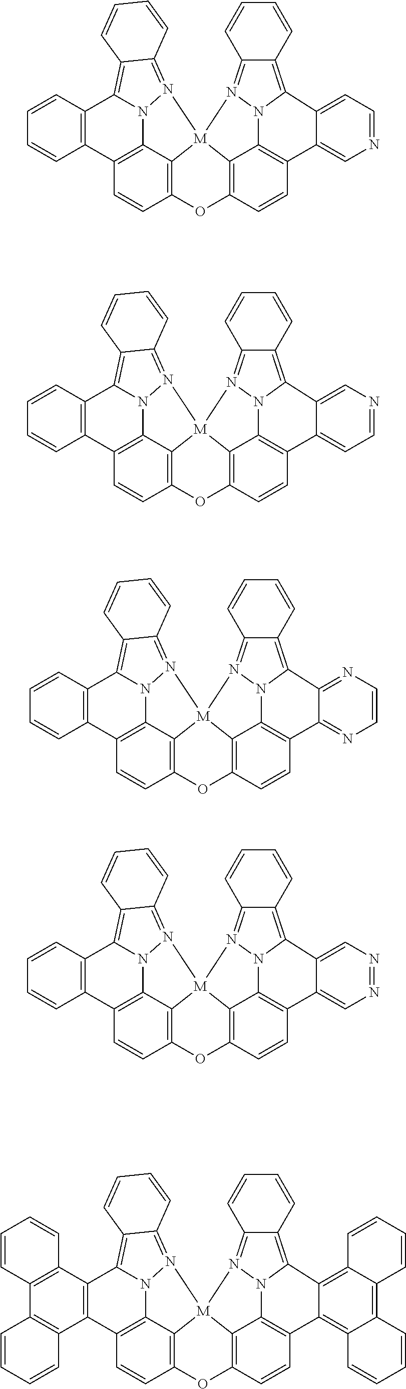

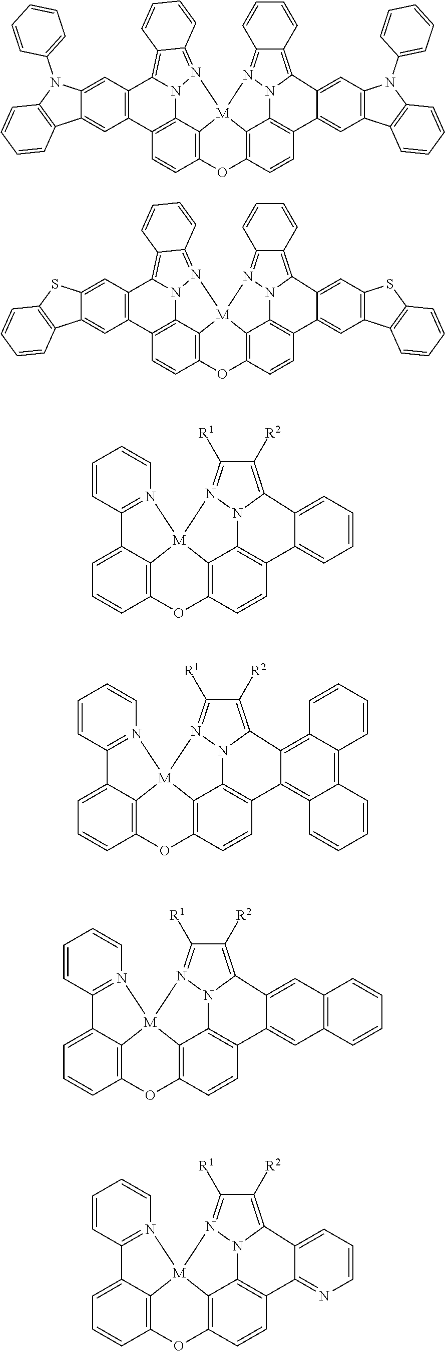

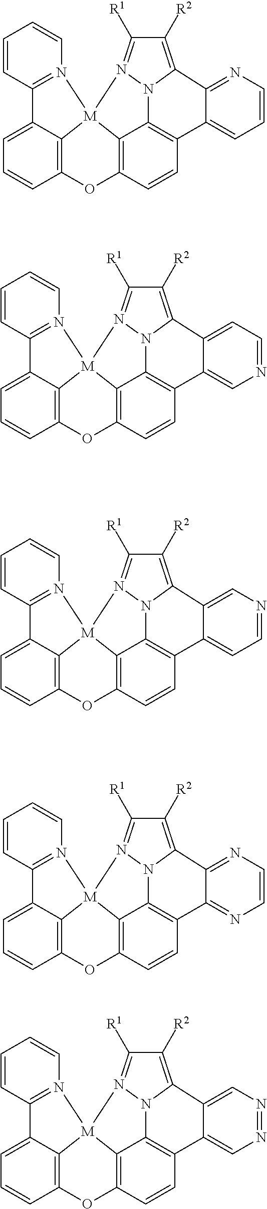

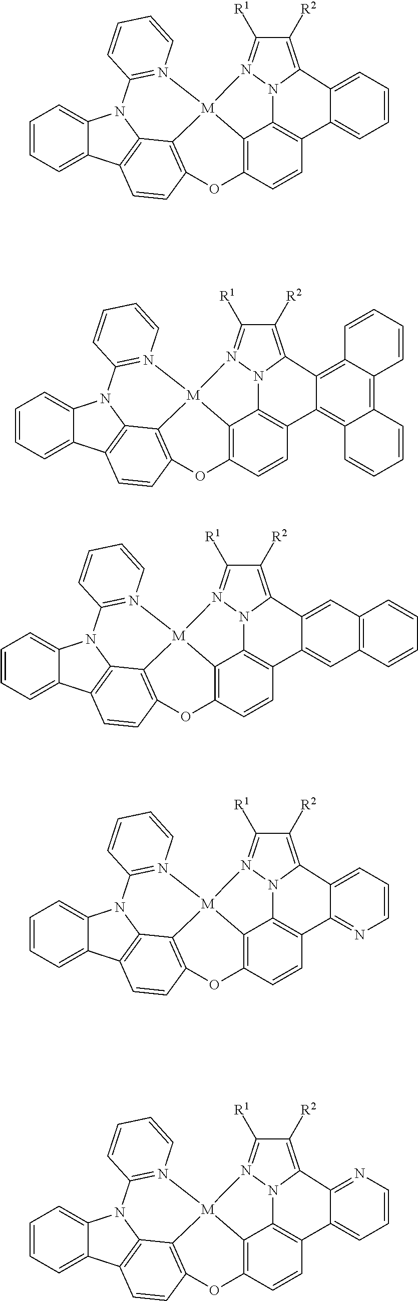

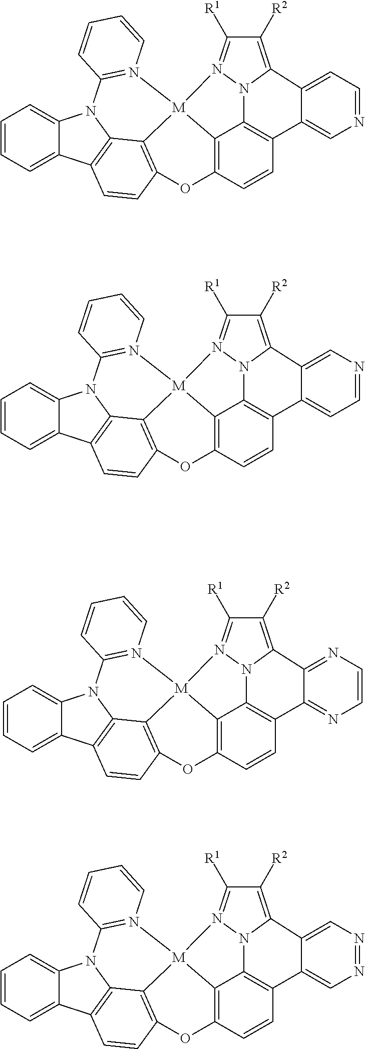

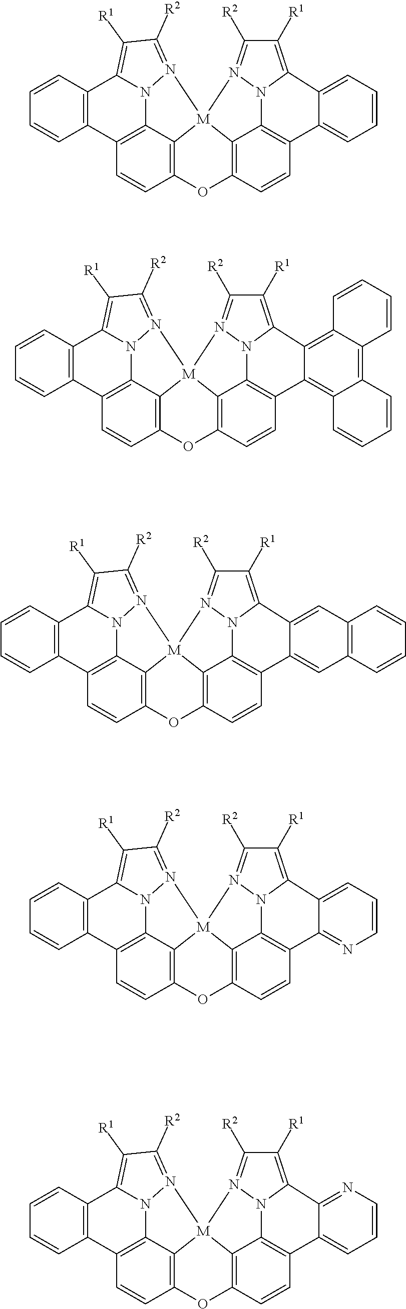

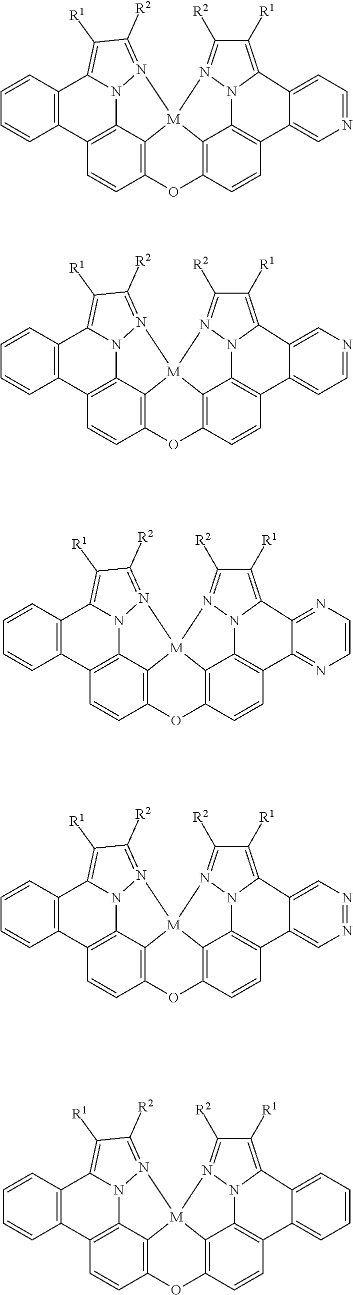

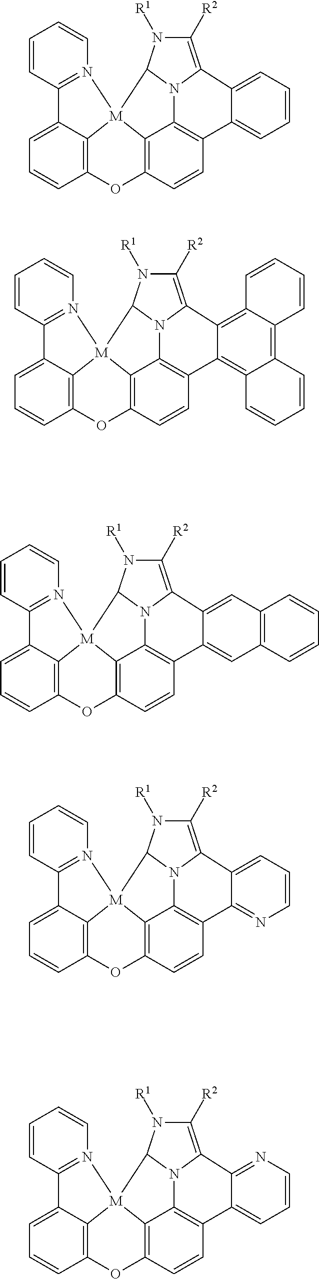

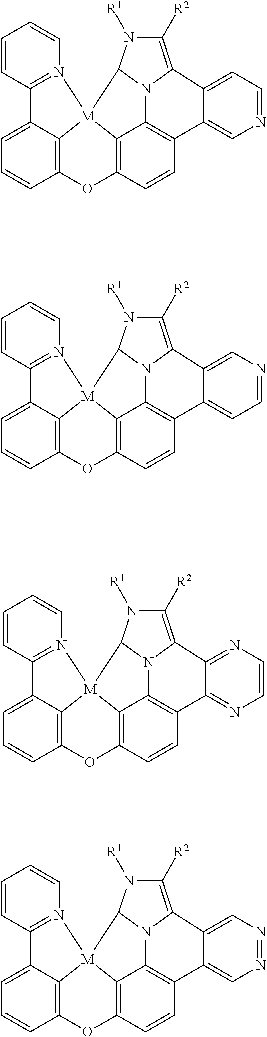

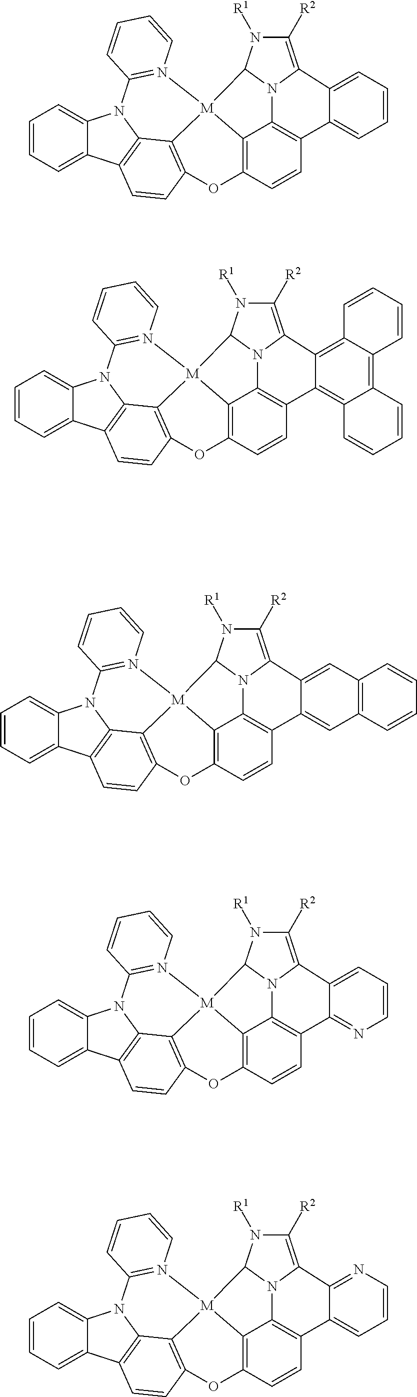

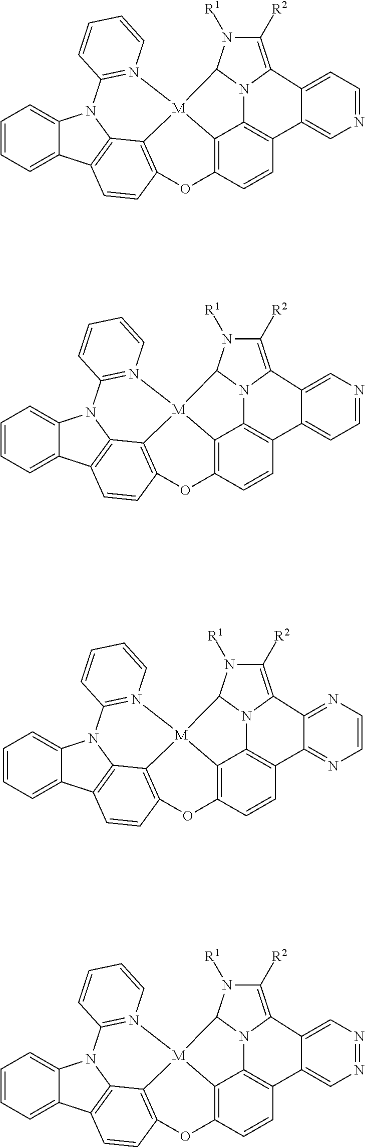

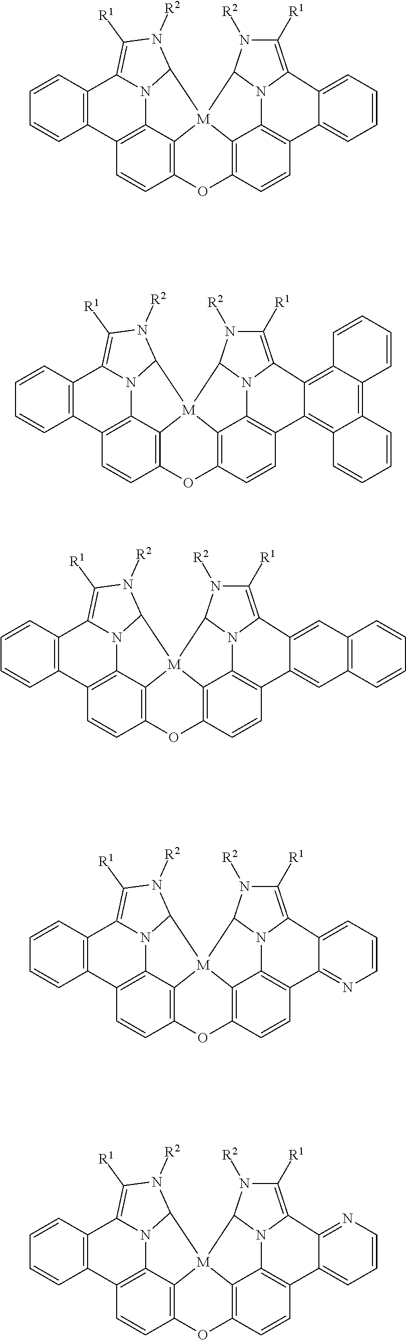

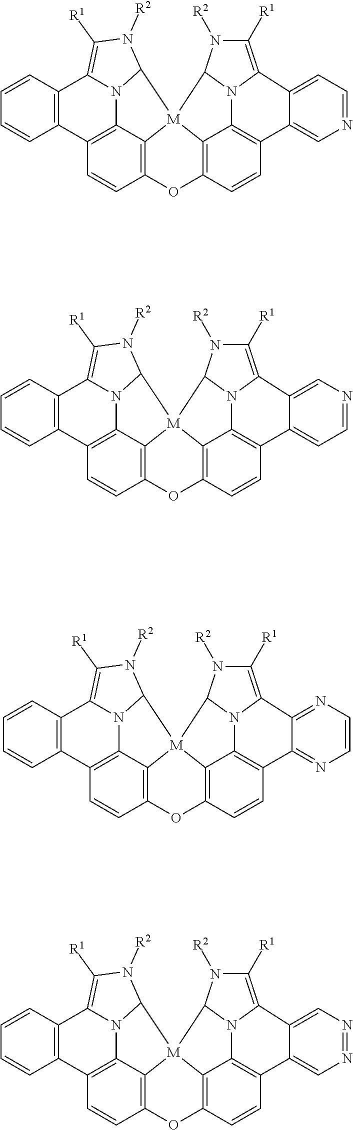

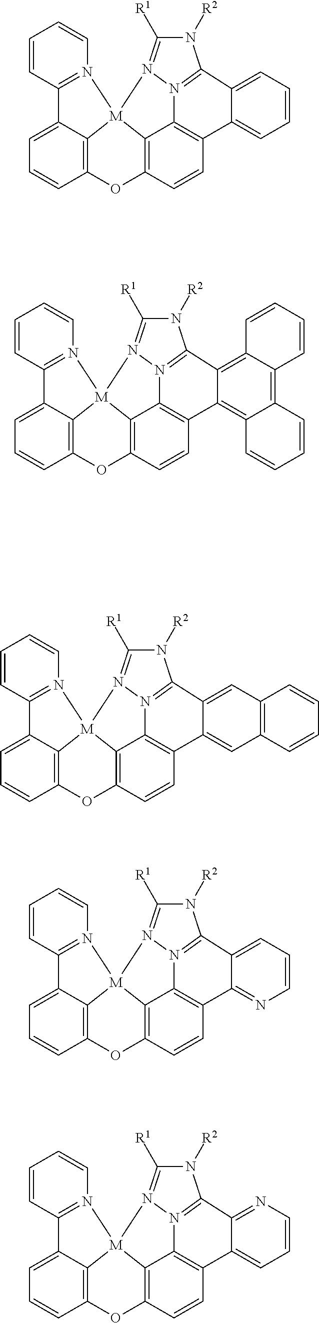

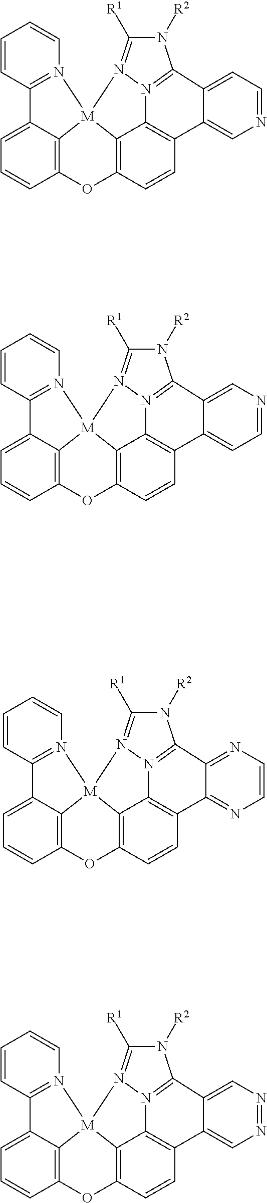

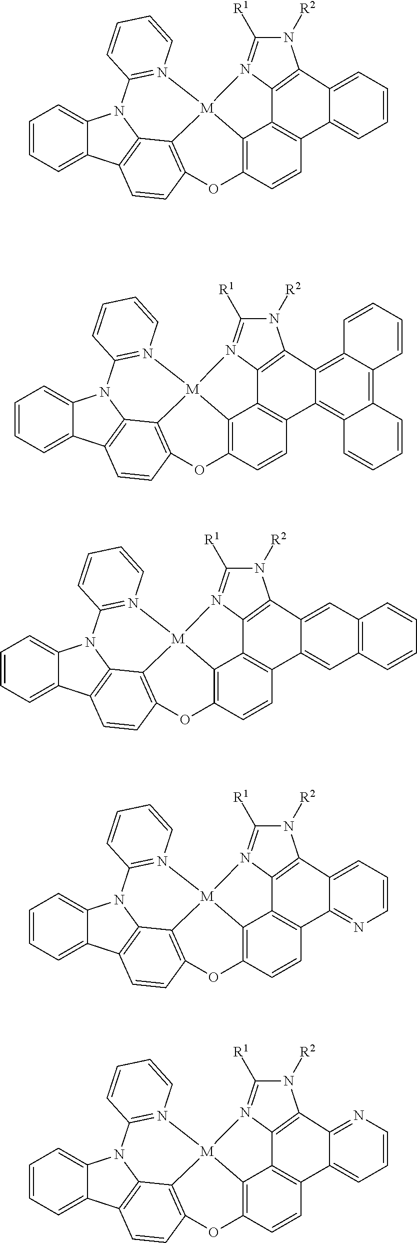

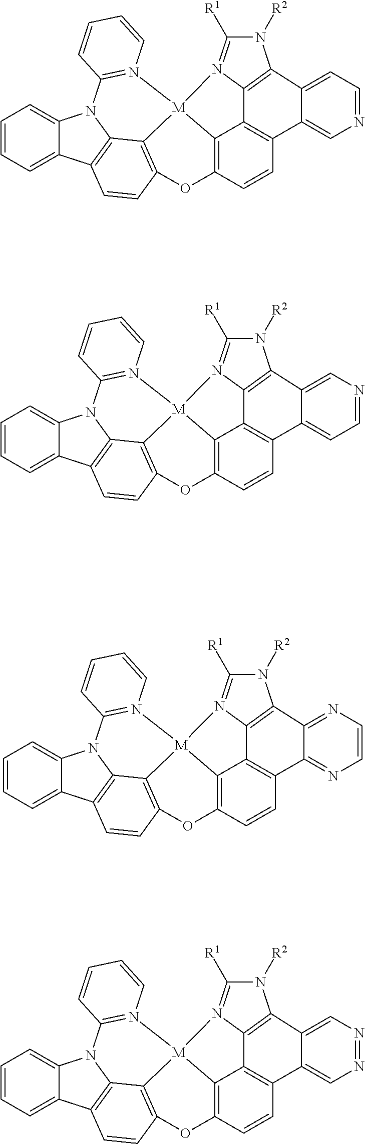

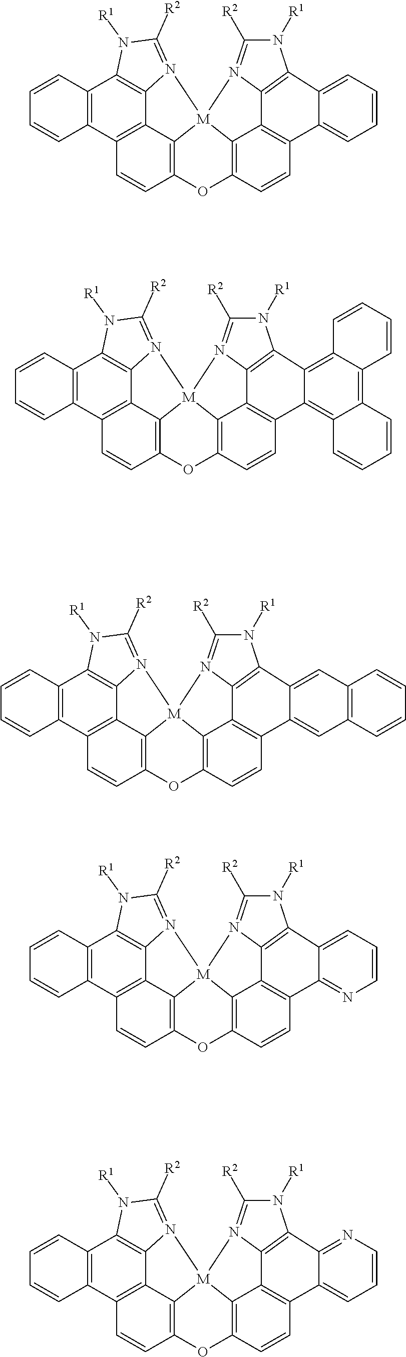

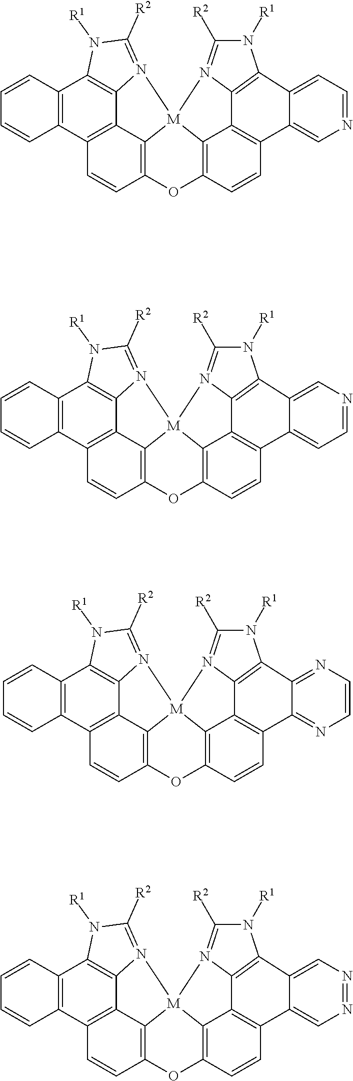

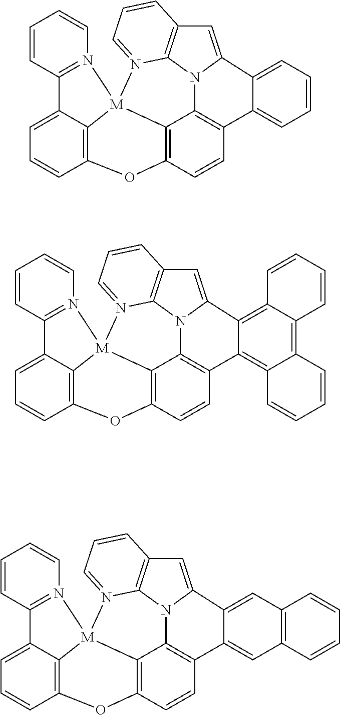

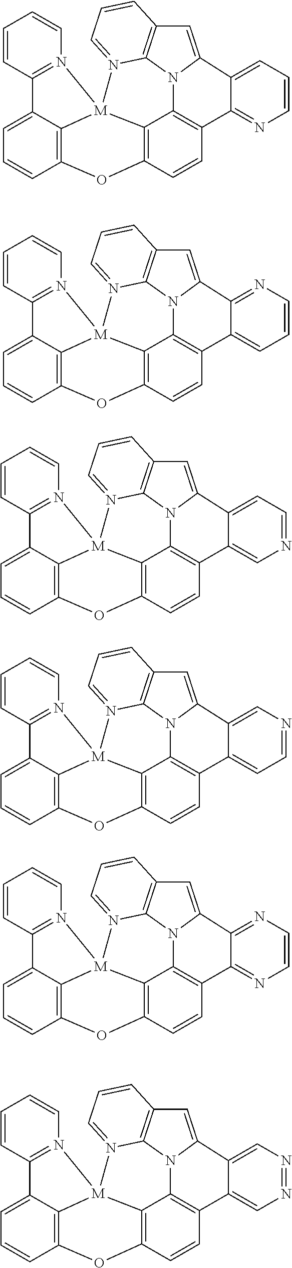

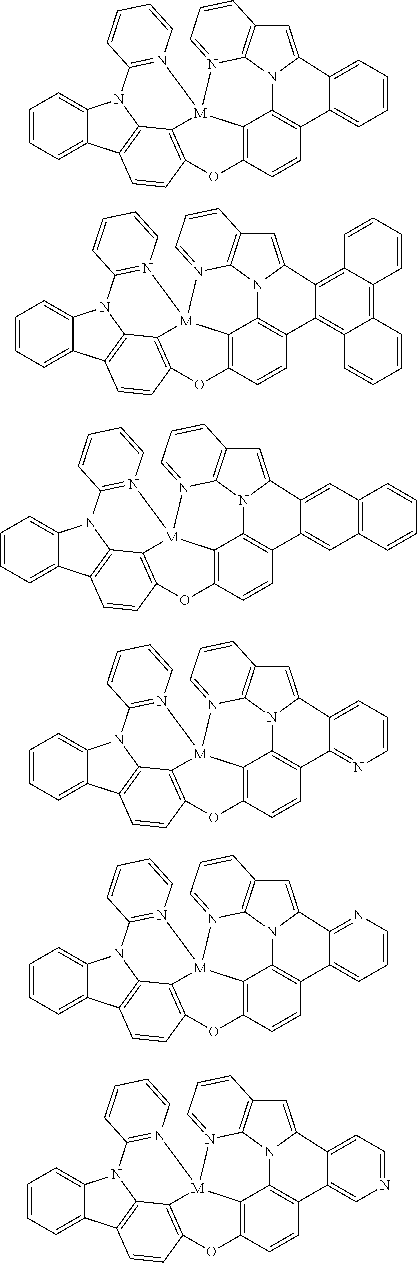

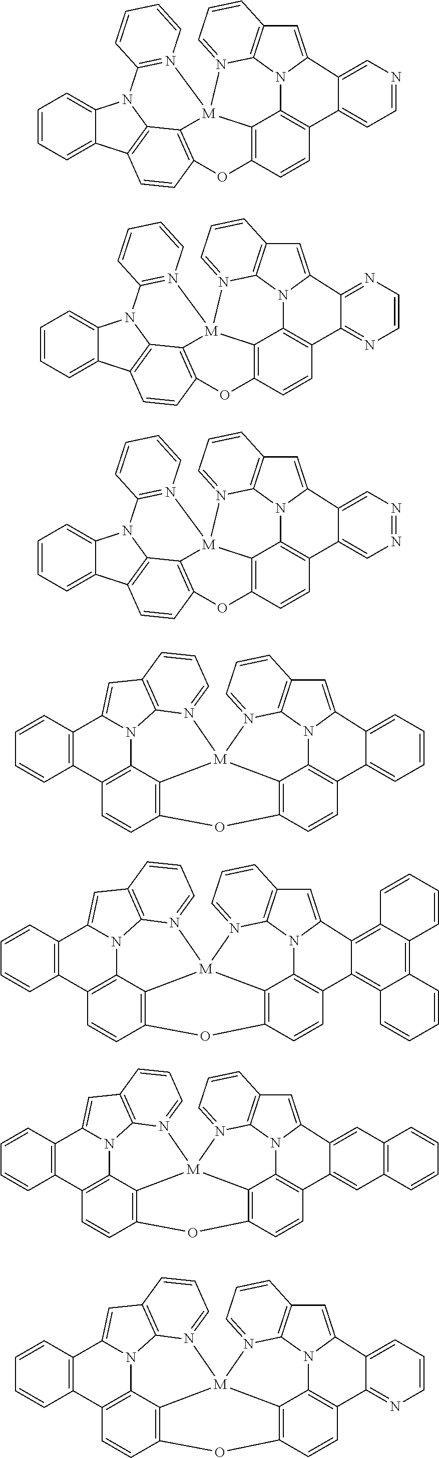

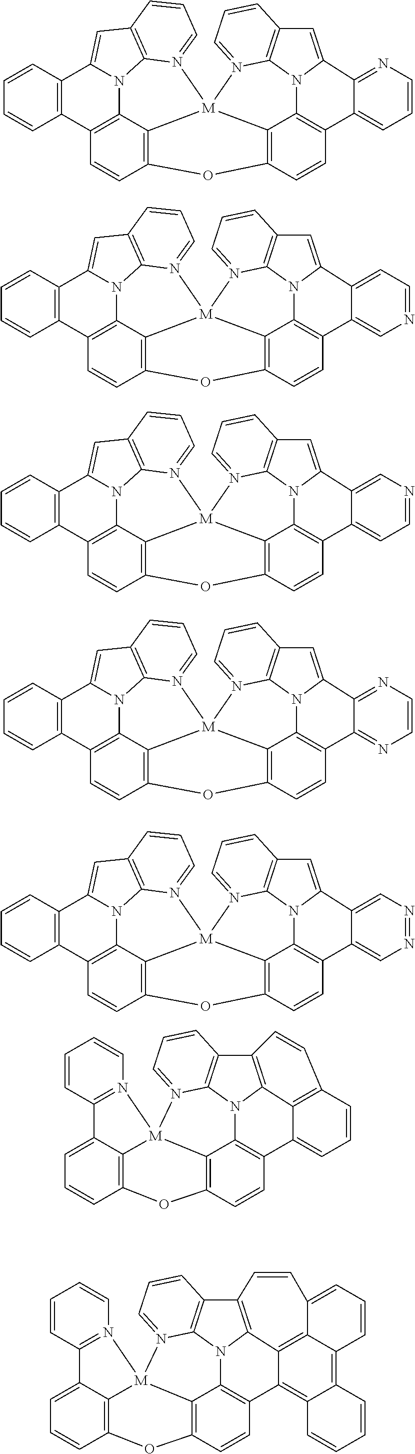

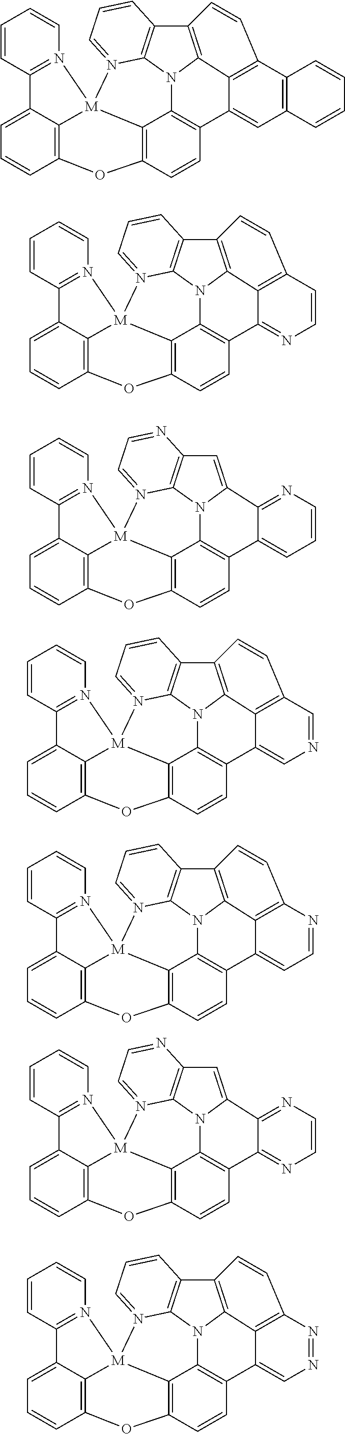

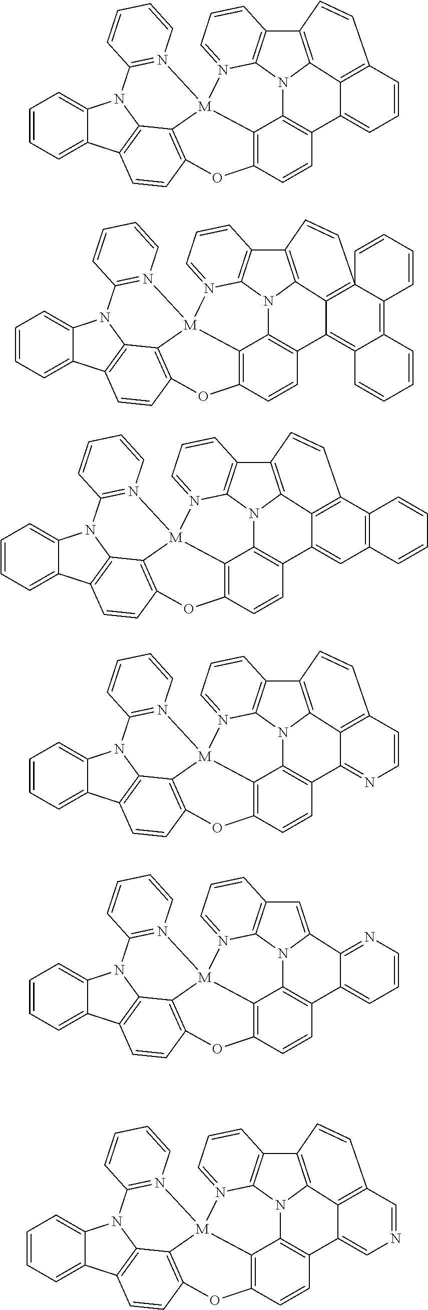

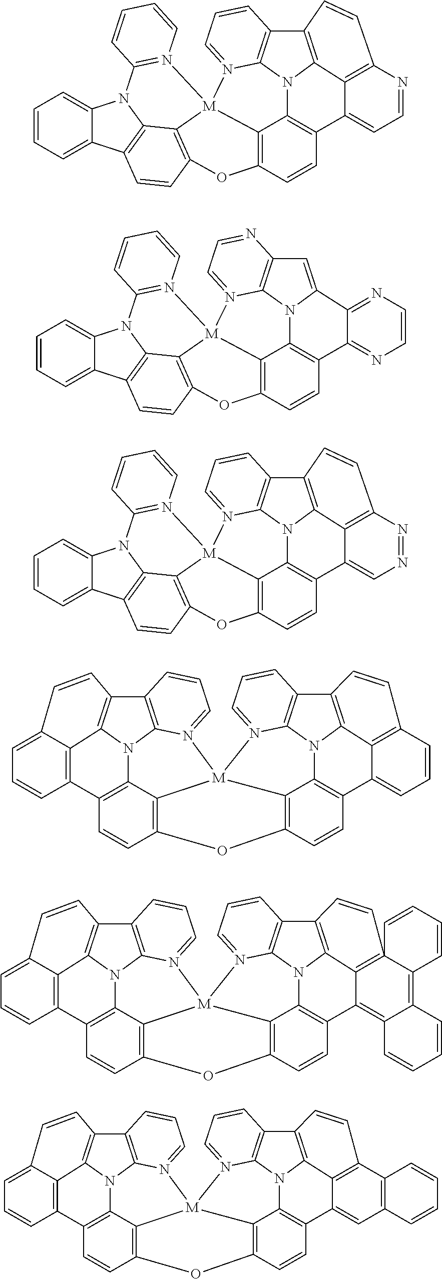

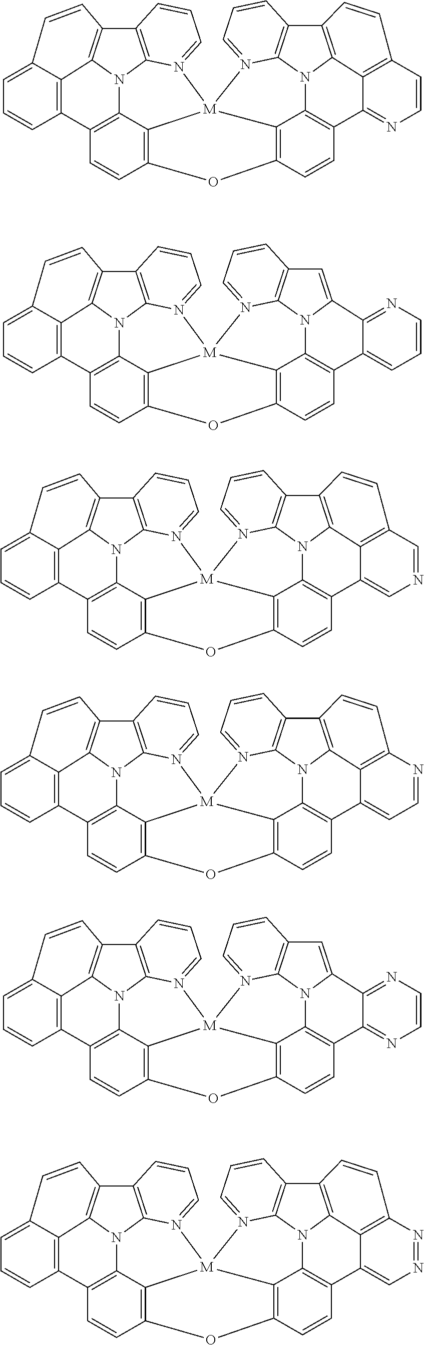

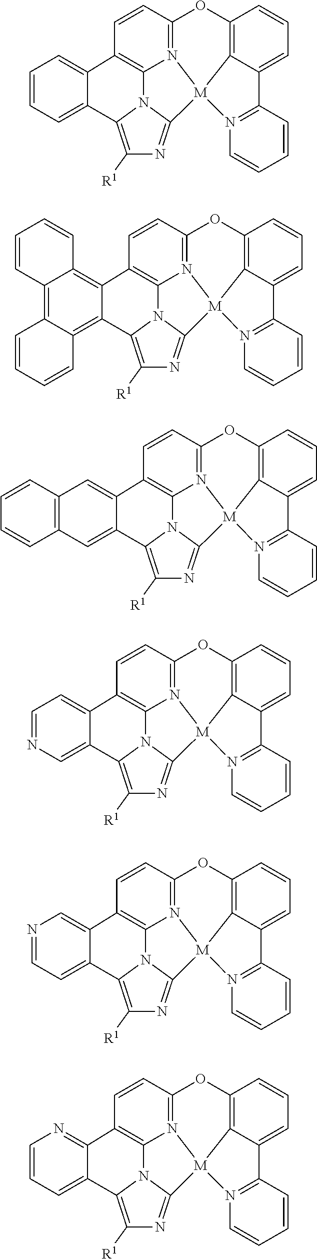

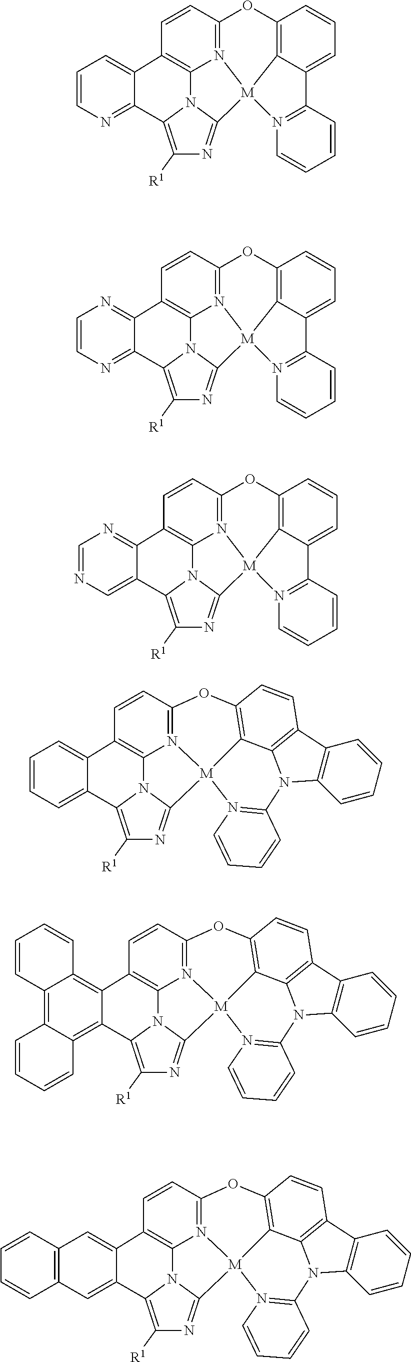

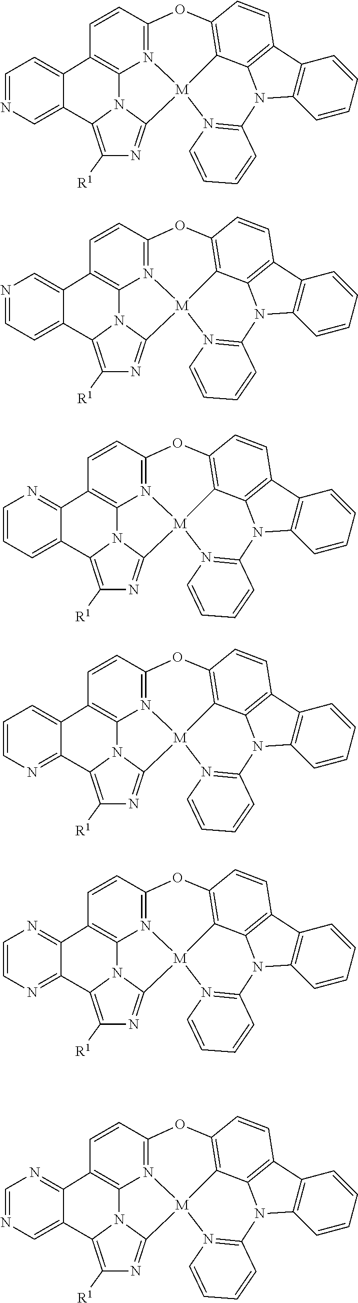

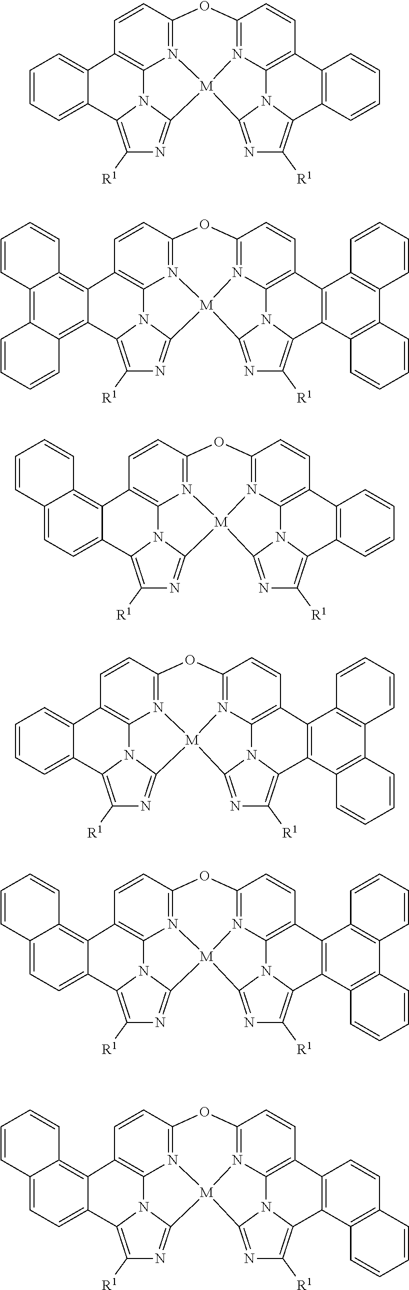

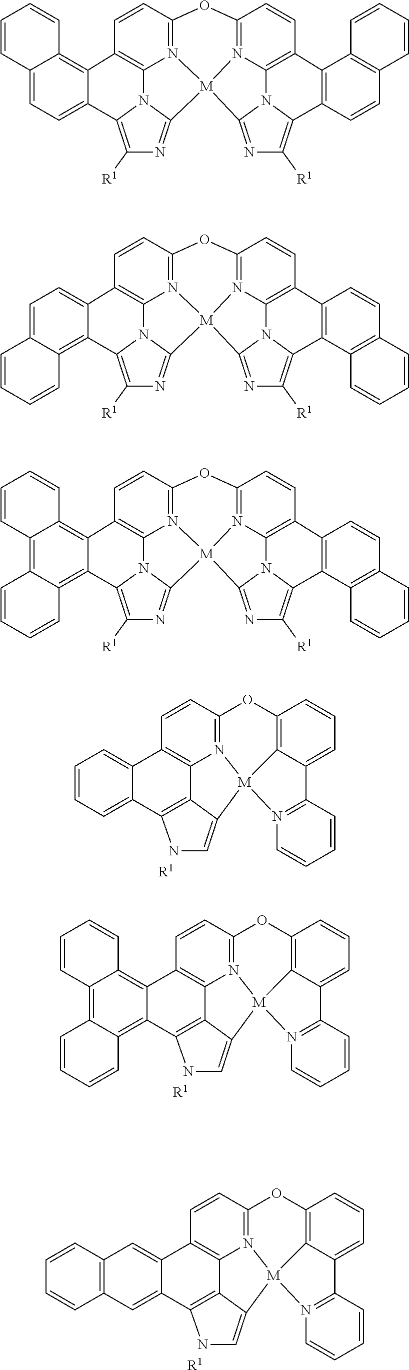

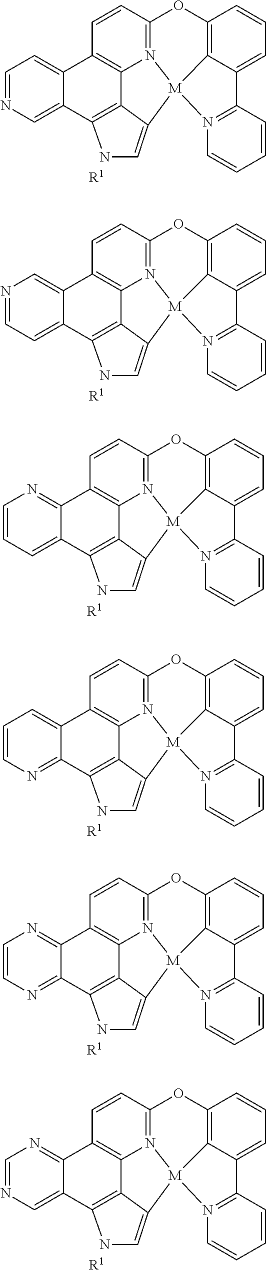

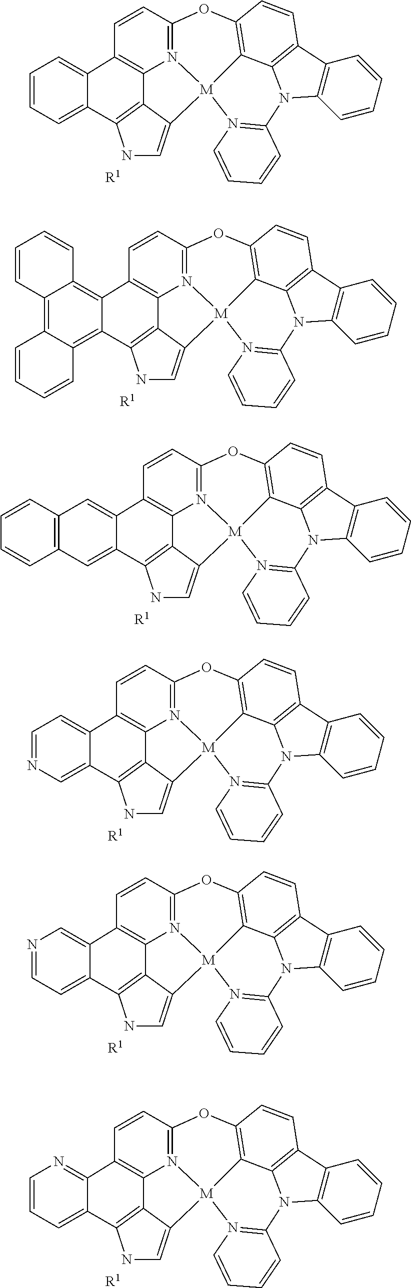

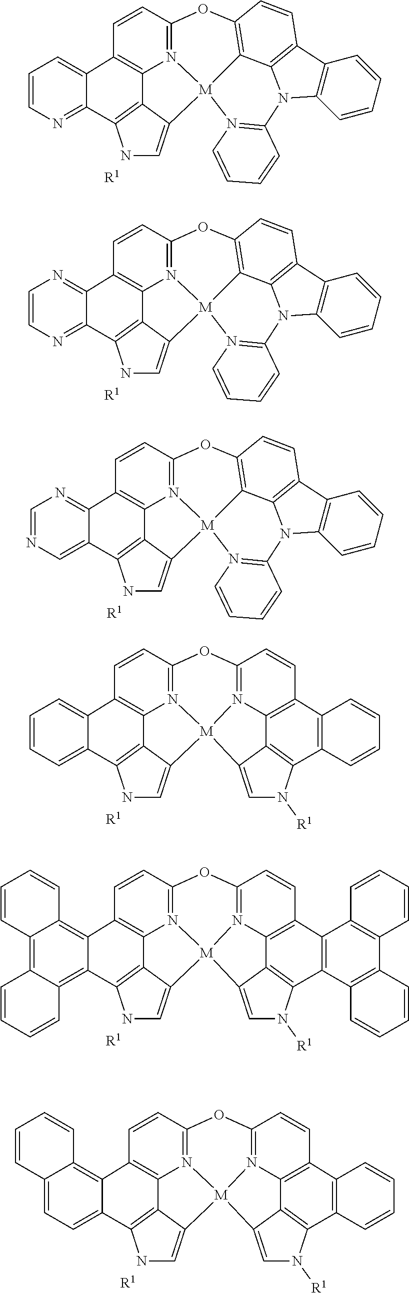

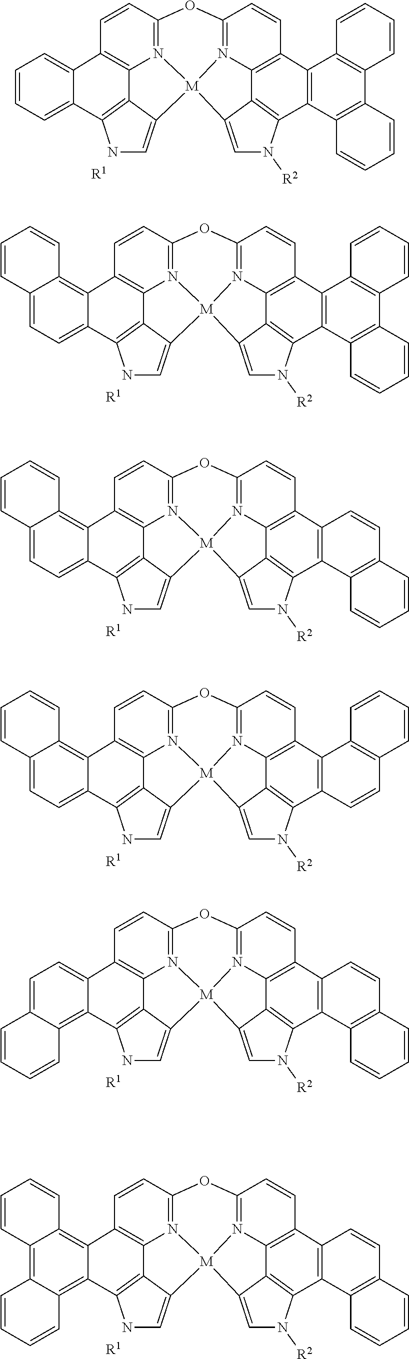

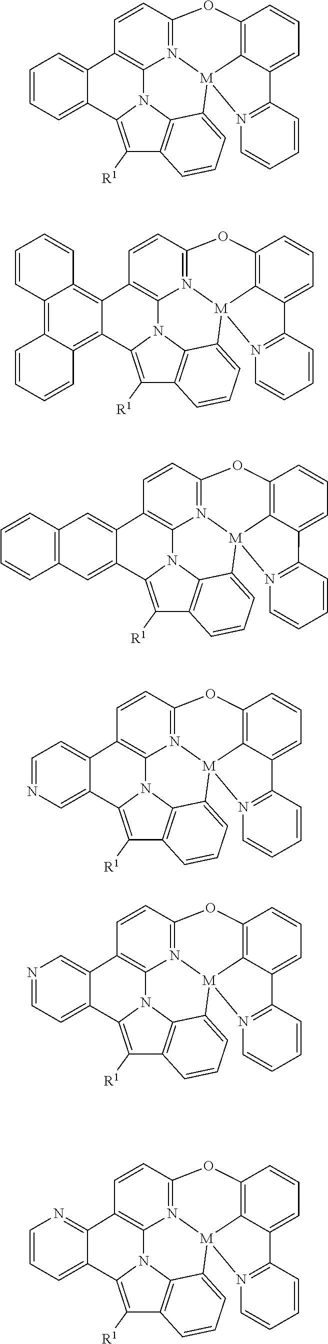

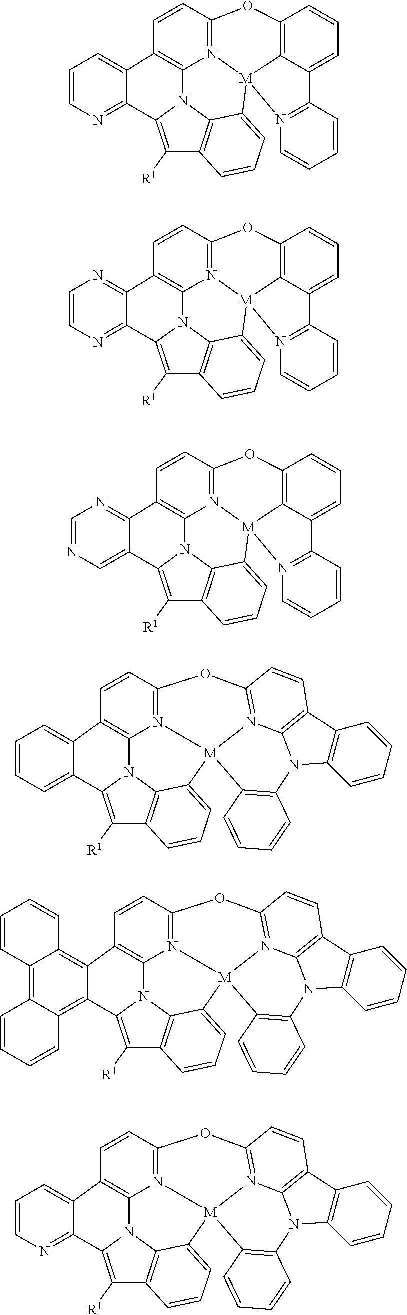

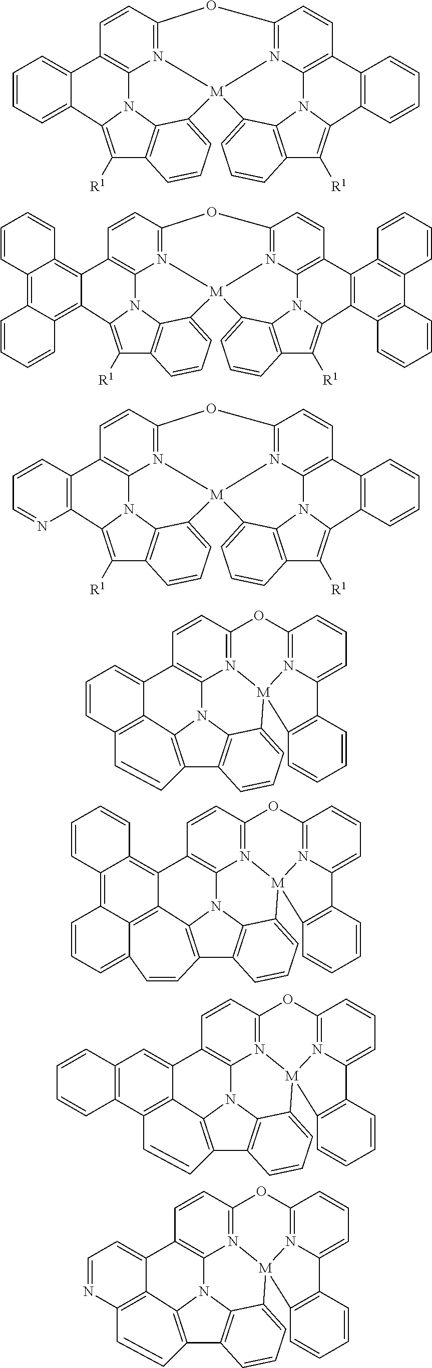

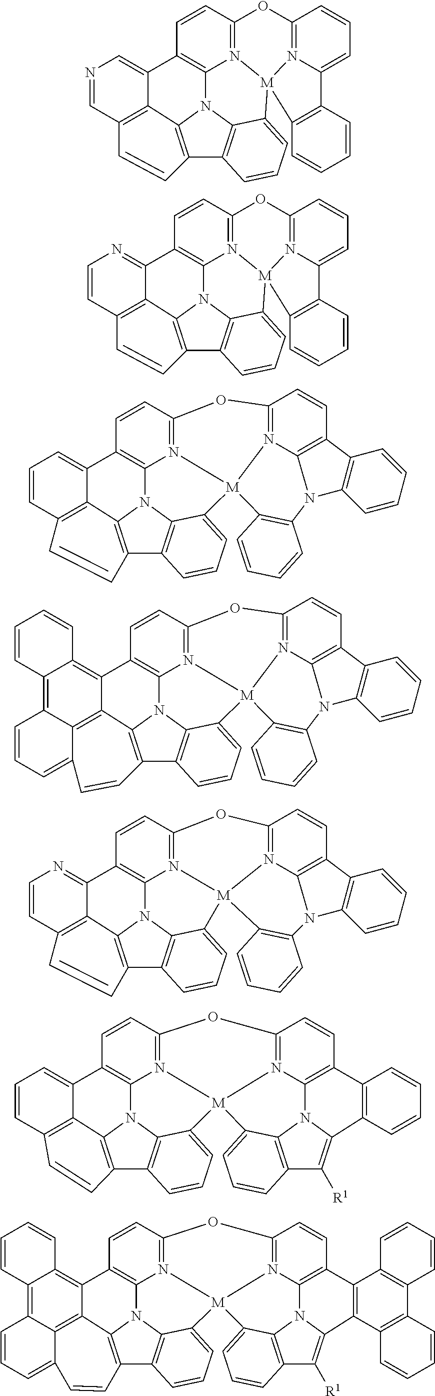

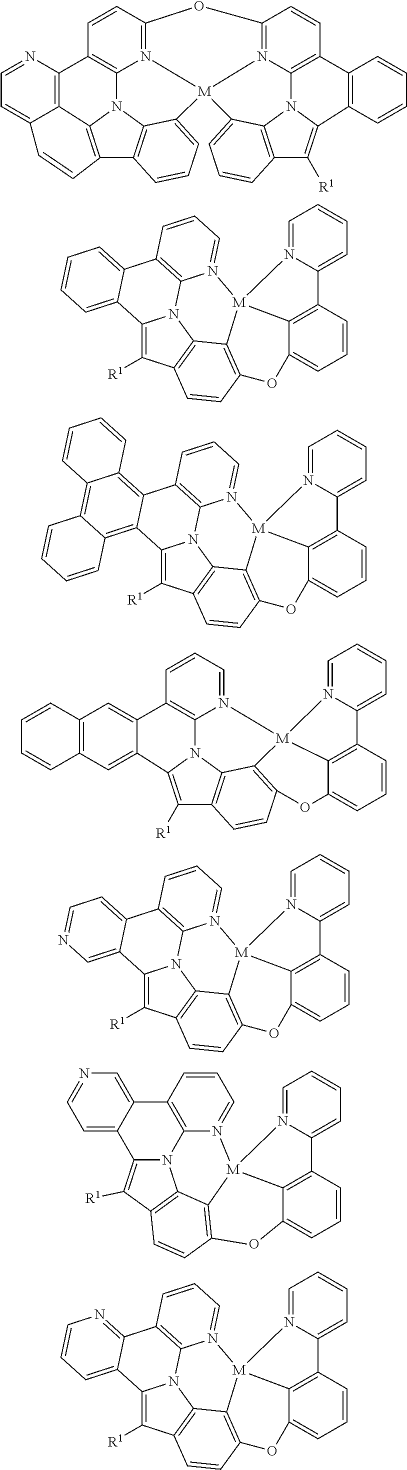

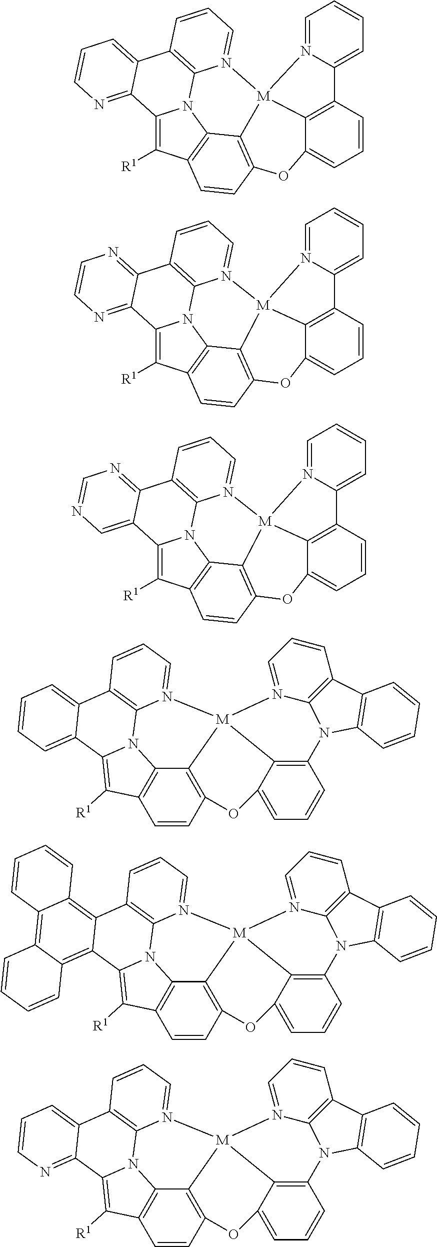

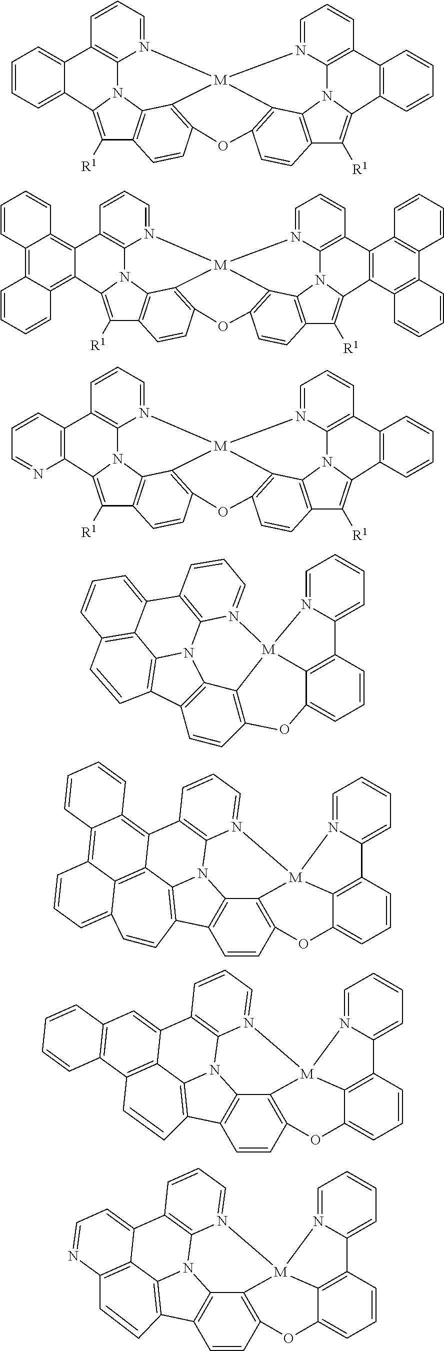

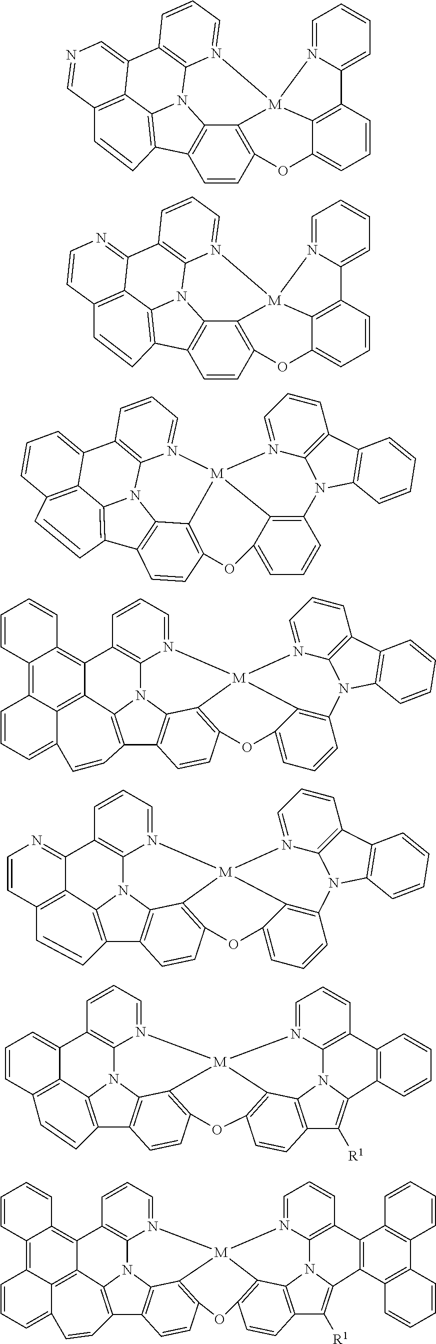

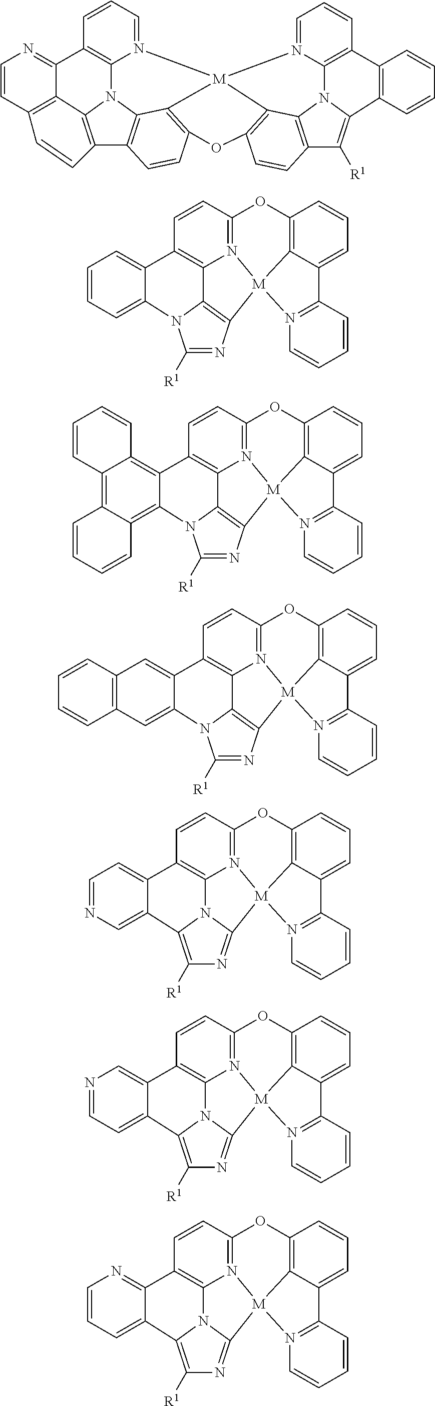

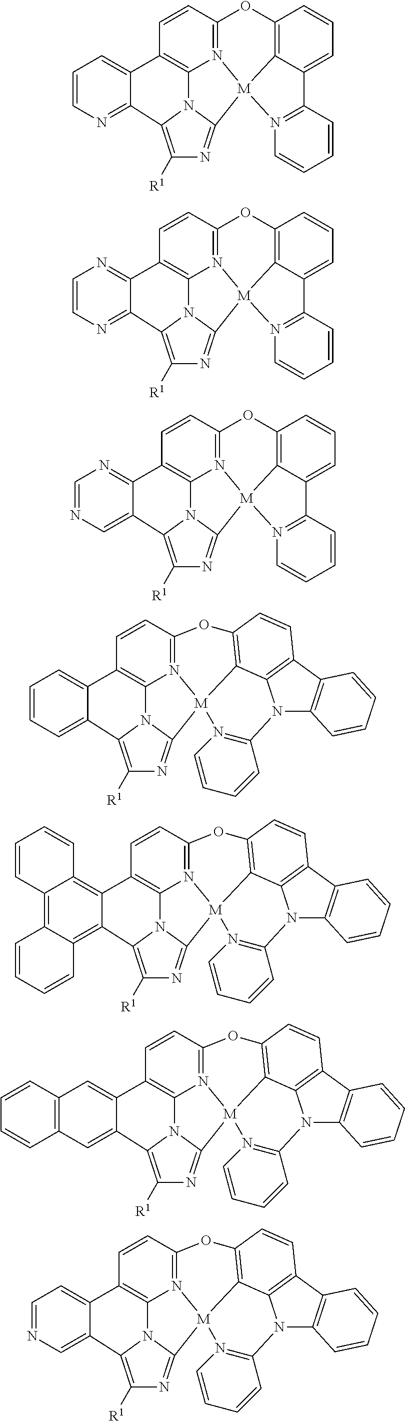

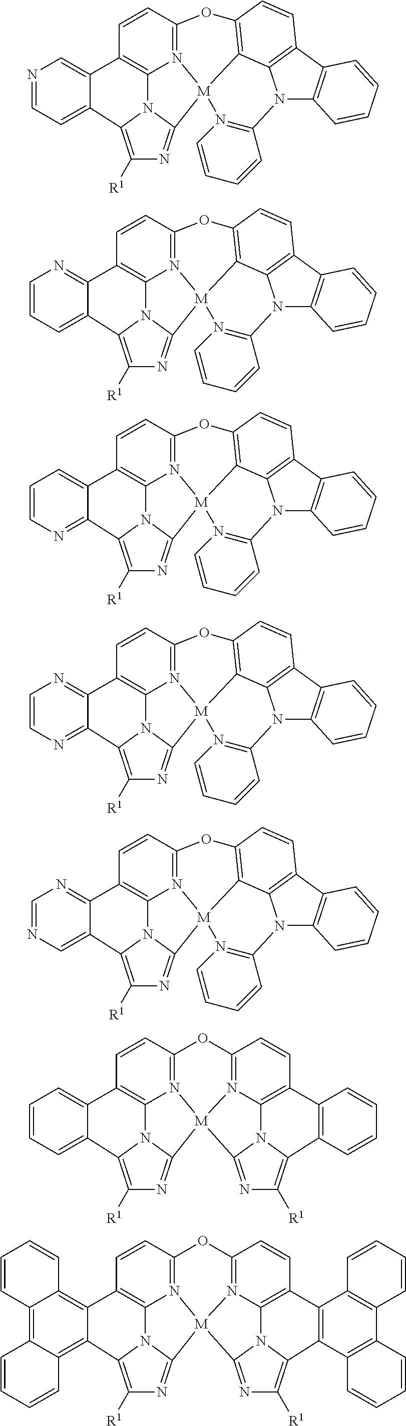

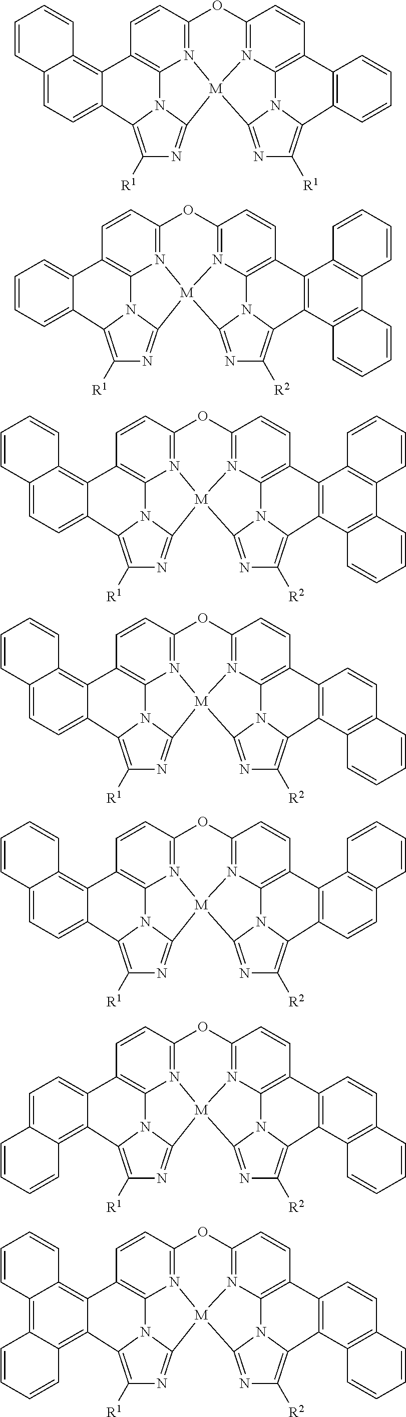

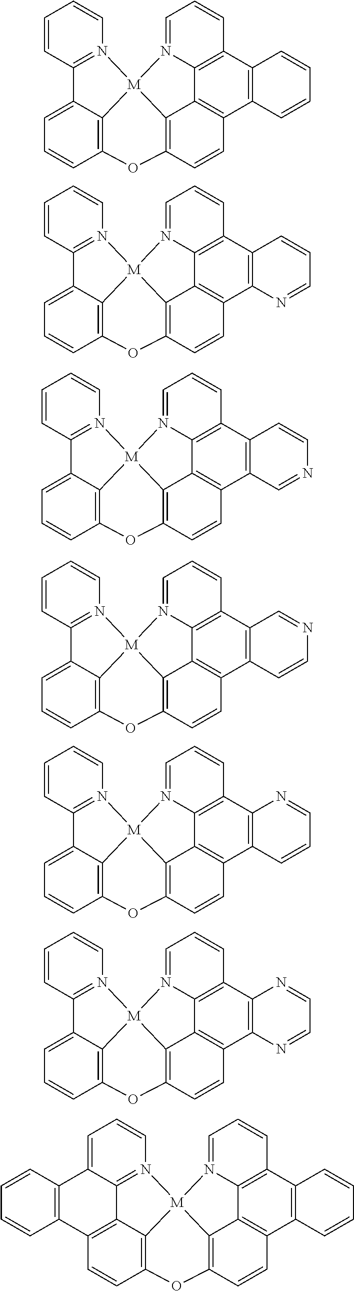

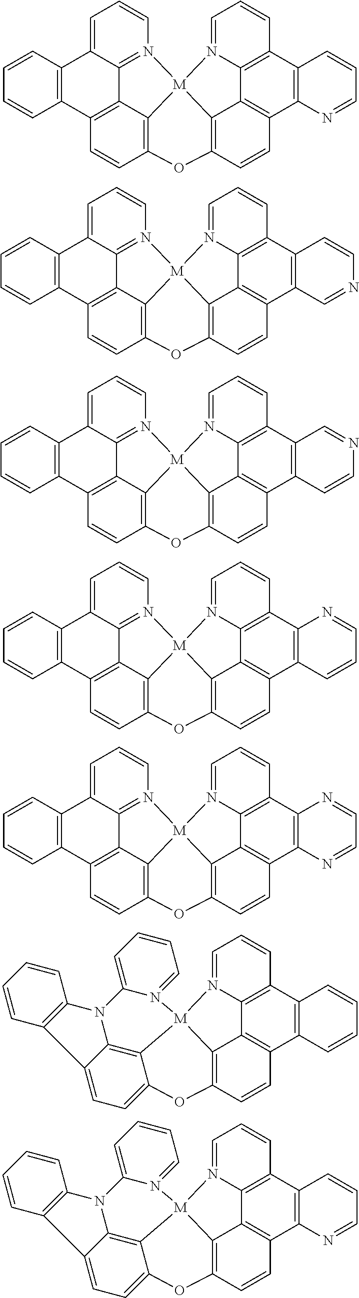

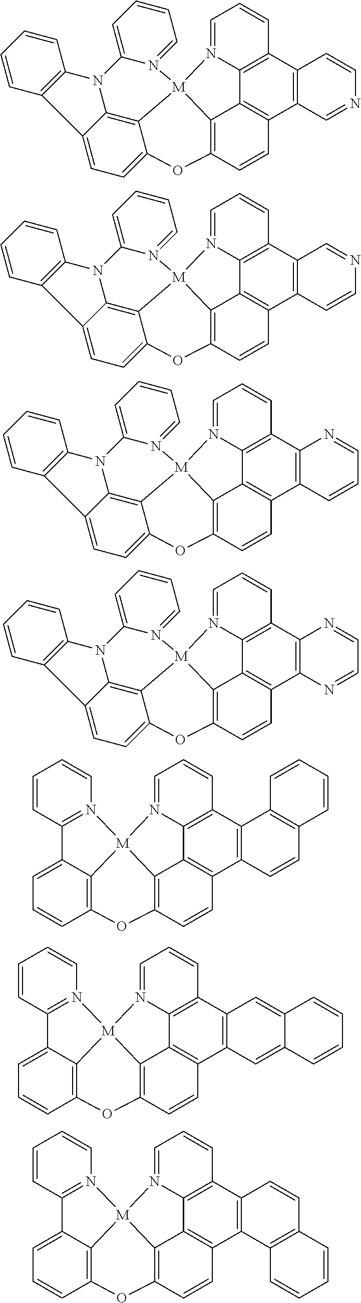

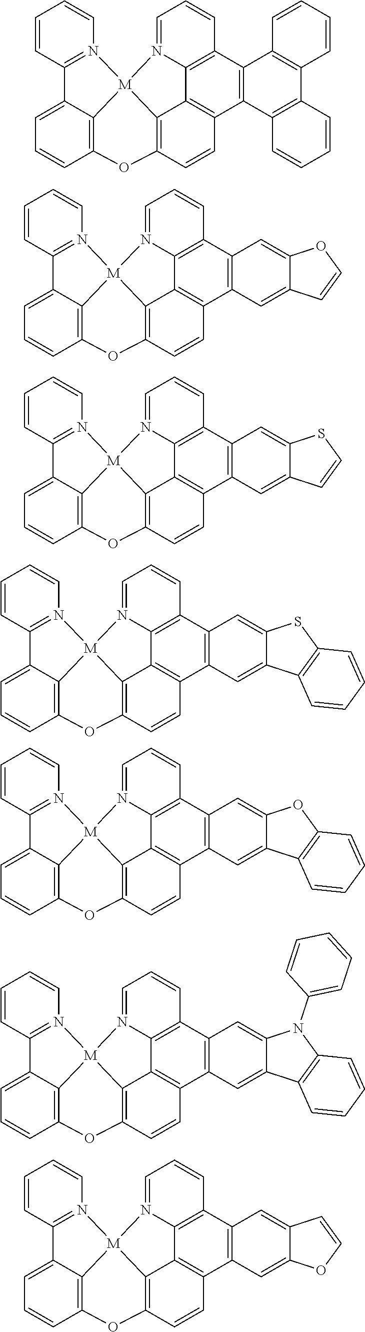

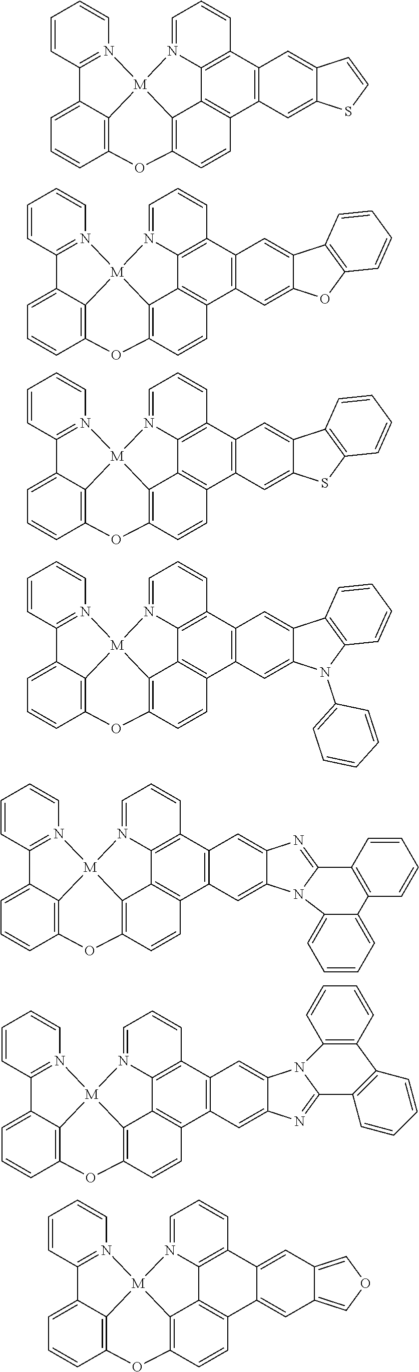

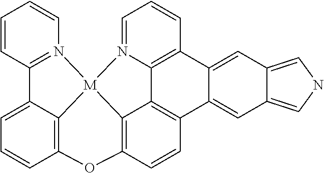

MADF emitters based on cyclic platinum (II) and palladium (II) complexes employing benzo-imidazo-phenanthridine and analogues include compounds of General Formula IV shown below.

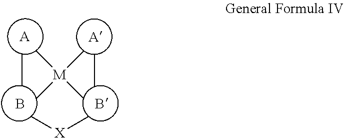

### In General Formula IV:

M is Pt (II) or Pd (II)
X represents a single bond or CR⁷R⁸, C═O, SiR⁷R⁸, GeR⁷R⁸, NR⁷, PR⁷, PR⁷R⁸, R⁷P═O, AsR⁷, R⁷As═O, O, S, S═O, SO₂, Se, Se═O, SeO₂, BR⁷, BR⁷R⁸, AlR⁷, AlR⁷R⁸, R⁷Bi═O, or BiR⁷,

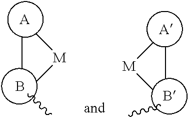

each independently represents one of the following chemical moieties:

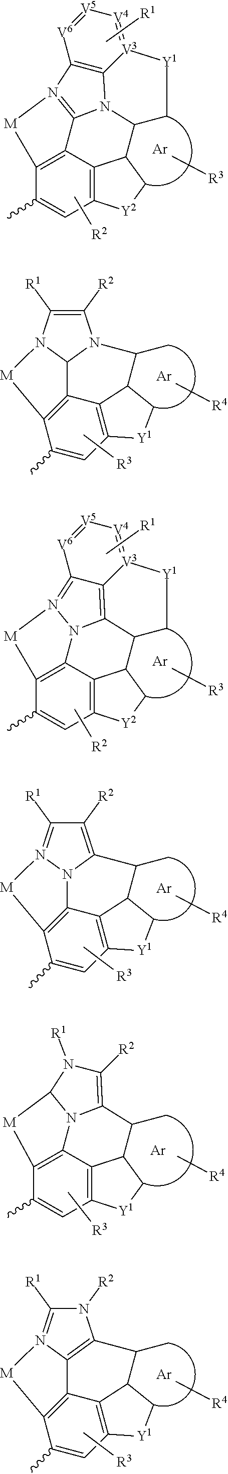

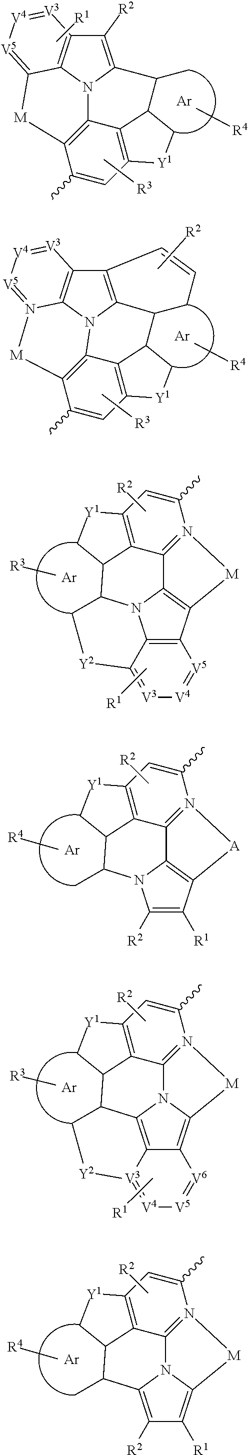

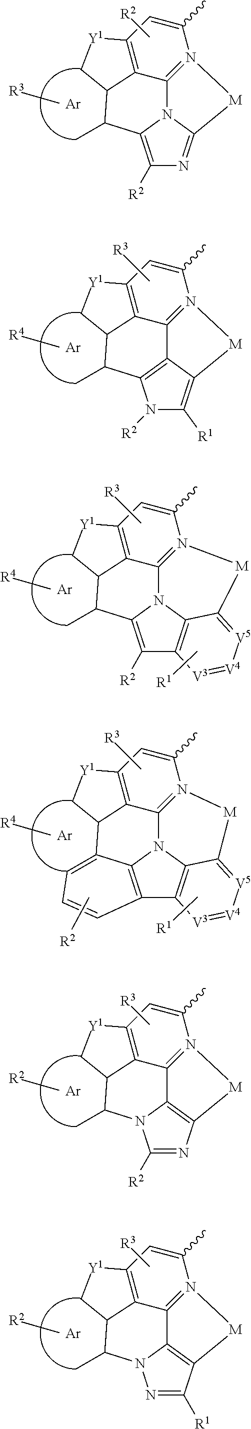

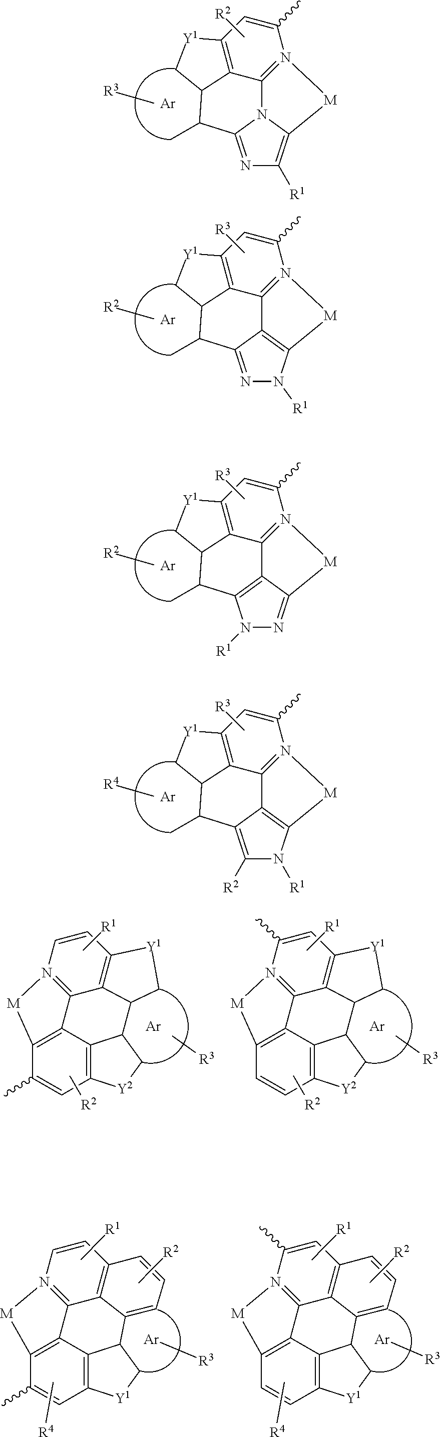

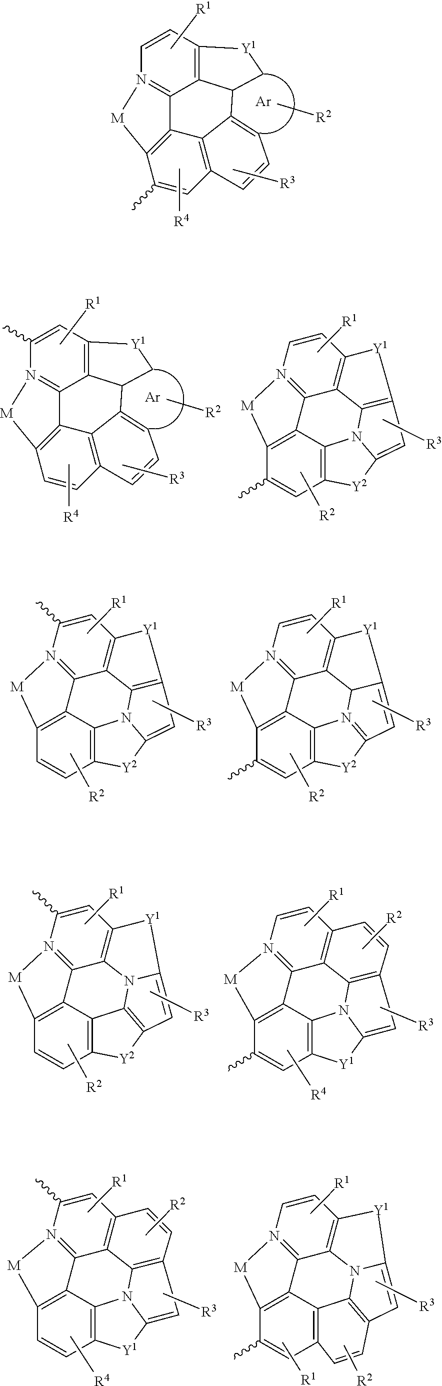

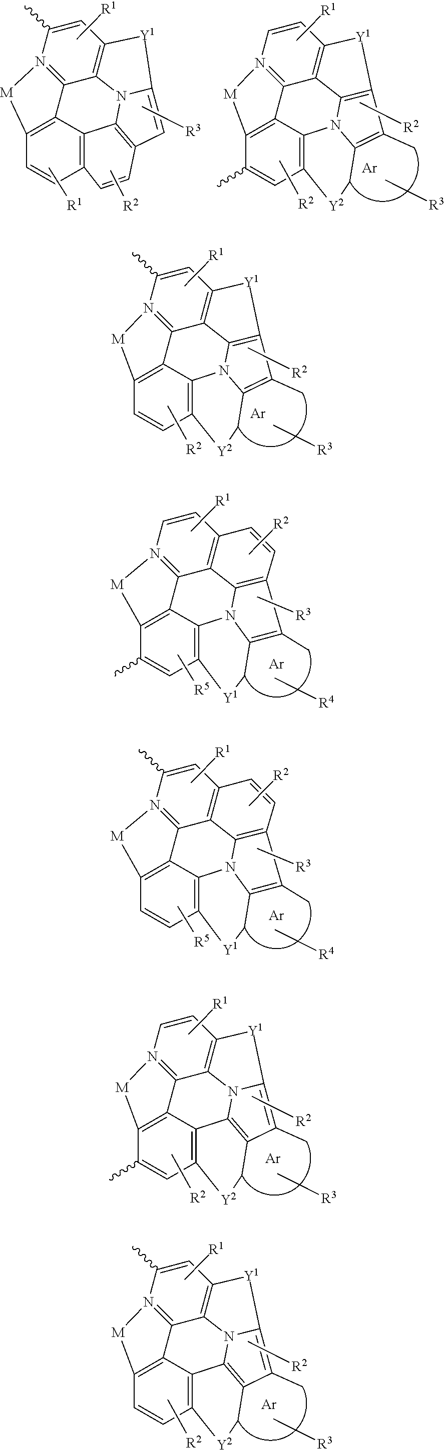

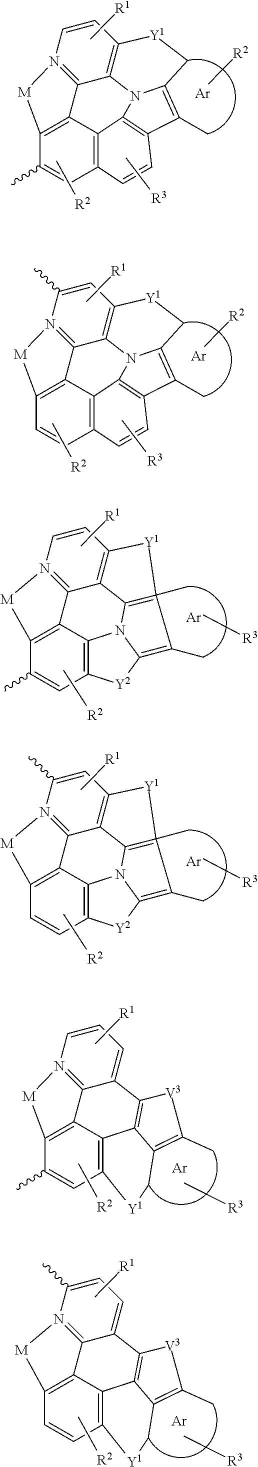

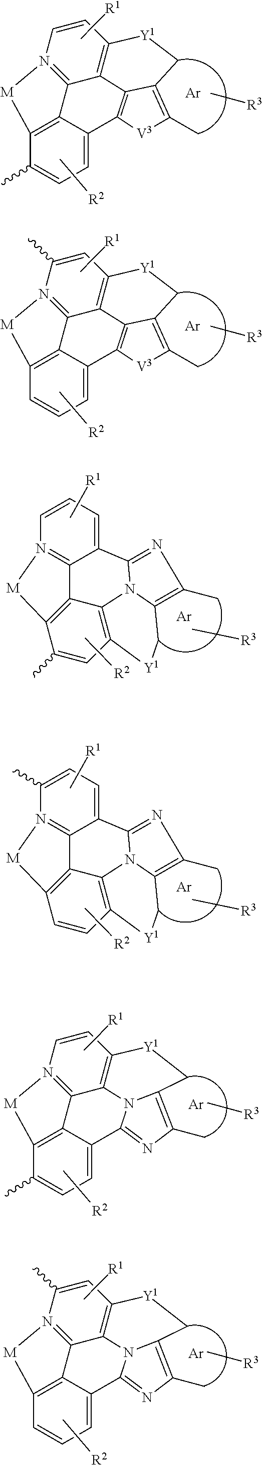

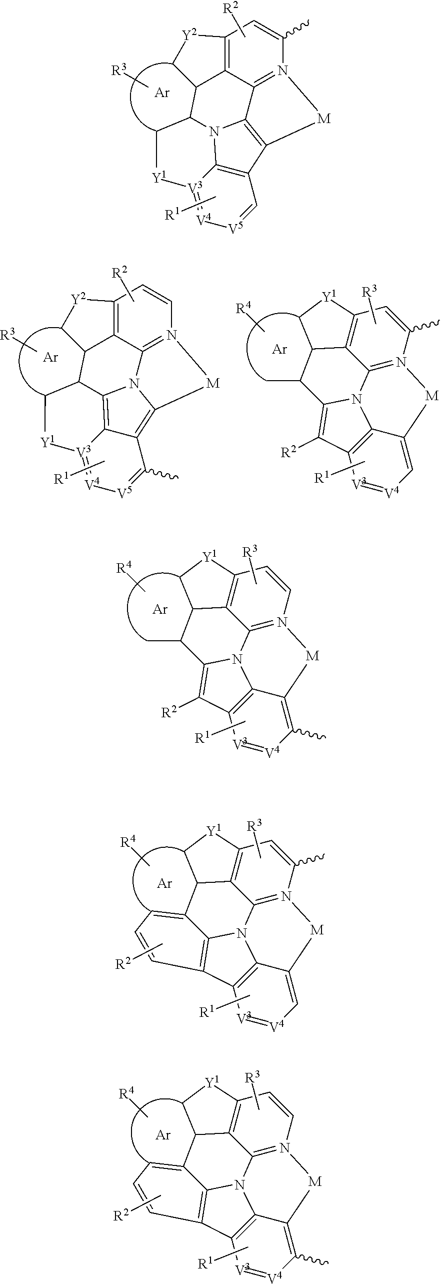

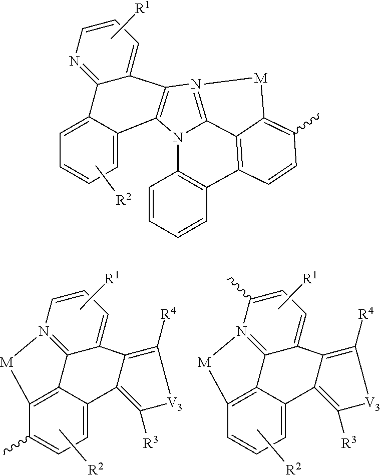

where:
N is nitrogen,
each of V¹, V², V³, V⁴, V⁵, and V⁶, if present, is independently C, N, Si, O, S, Ge, P, As, Se, B, Al, or Bi,
each of X¹, X², Y¹, Y², Y³, and Y⁴ is independently present or absent, and each X¹, X², Y¹, Y², Y³, and Y⁴ present independently represents C, N, Si, O, S, Ge, P, As, Se, B, Al, or Bi, or valency permitting, CR⁷, SiR⁷, GeR⁷, NR⁷, P═O, As═O, B, BR⁷, AlR⁷, Bi═O, CR⁷R⁸, C═O, SiR⁷R⁸, GeR⁷R⁸, NR⁷, PR⁷, PR⁷R⁸, R⁷P═O, AsR⁷, R⁷As═O, S═O, SO₂, Se═O, SeO₂, BR⁷, BR⁷R⁸, AlR⁷, AlR⁷R⁸, R⁷Bi═O, or BiR⁷,
each of L¹, L², L³, and L⁴ is independently present or absent, and each L¹, L², L³, and L⁴ present independently represents a substituted or unsubstituted aryl, heteroaryl, or N-heterocyclic carbene,
each of R, R¹, R², R³, R⁴, R⁵, R⁶, R⁷, and R⁸ is independently absent or present as a single substituent or multiple substituents, valency permitting, and each R, R¹, R², R³, R⁴, R⁵, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and
each of

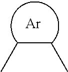

is independently present or absent, and each Ar present independently represents a substituted or unsubstituted aryl, heteroaryl, or N-heterocyclic carbene, where suitable examples of substituents include the following:

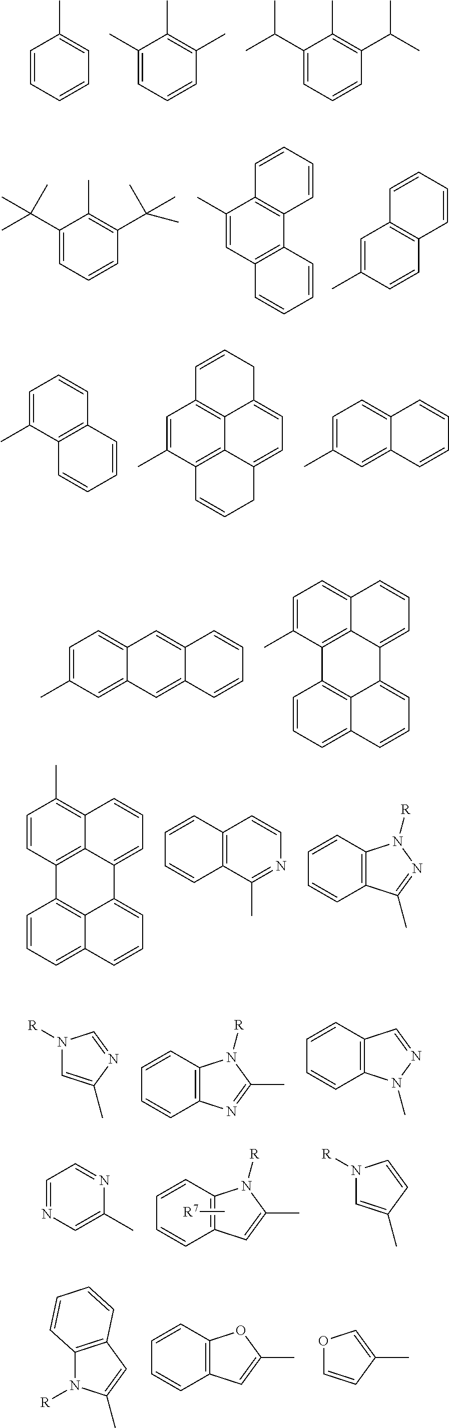

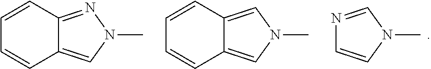

In A-B and A′-B′, Ar is independently present or absent, and each Ar present independently represents a substituted or unsubstituted aryl, heteroaryl, or N-heterocyclic carbene. Suitable examples of Ar include the following:

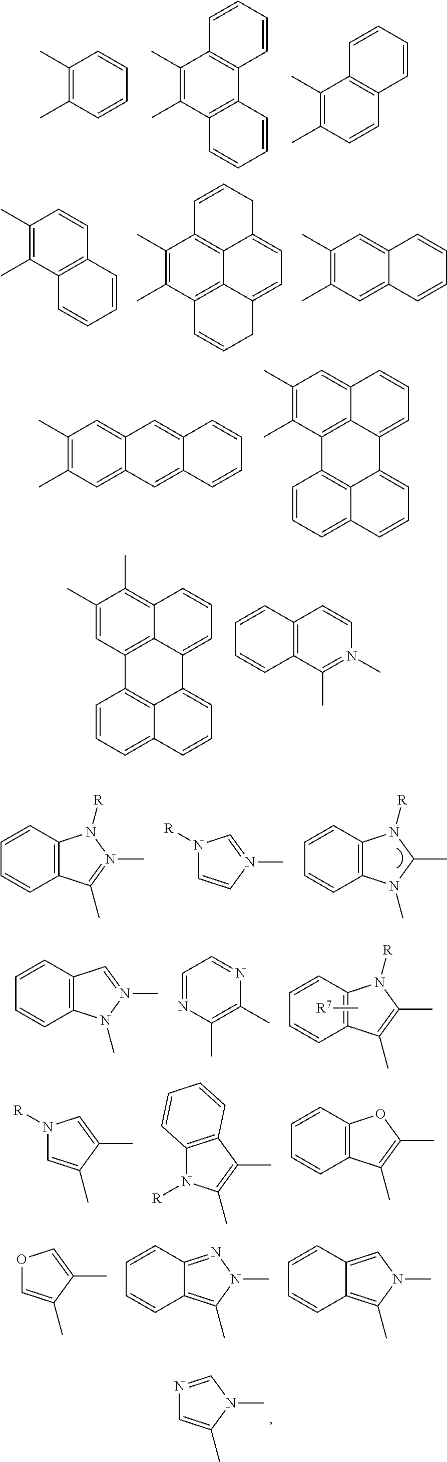

in which R and R⁷ are as defined herein.

Compounds of General Formula IV are shown below.

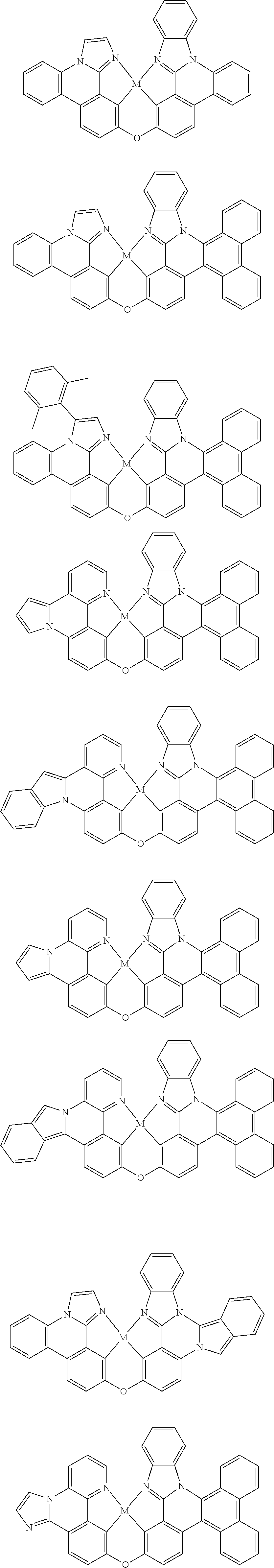

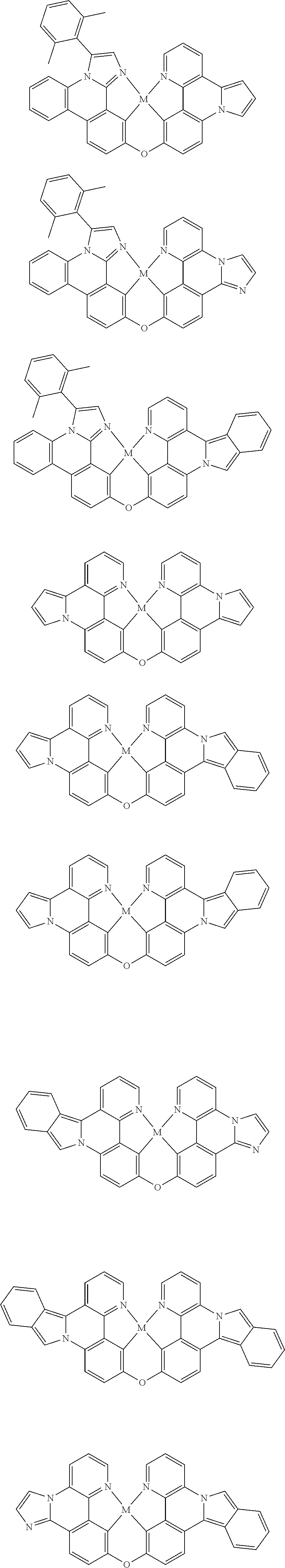

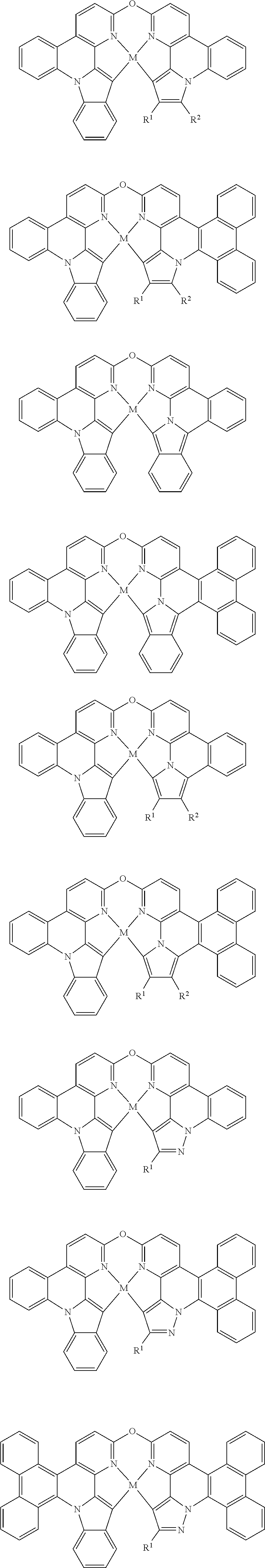

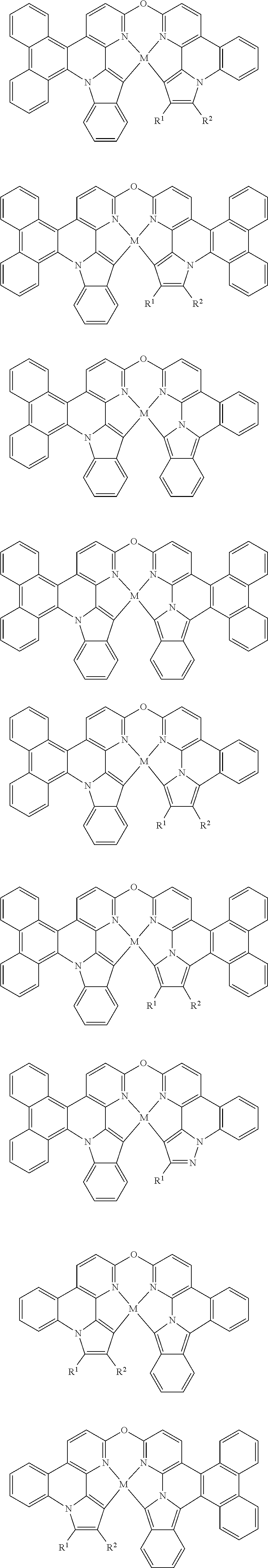

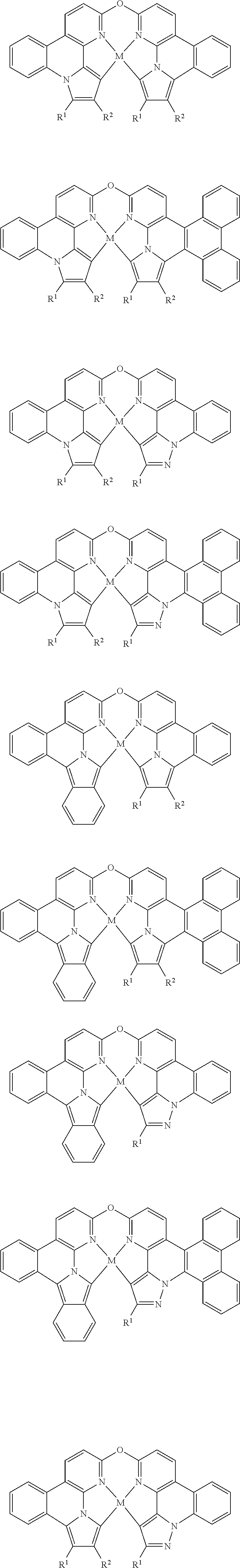

MADF emitters based on cyclic platinum (II) and palladium (II) complexes employing benzo-imidazo-phenanthridine and analogues include General Formulas V-XIII.

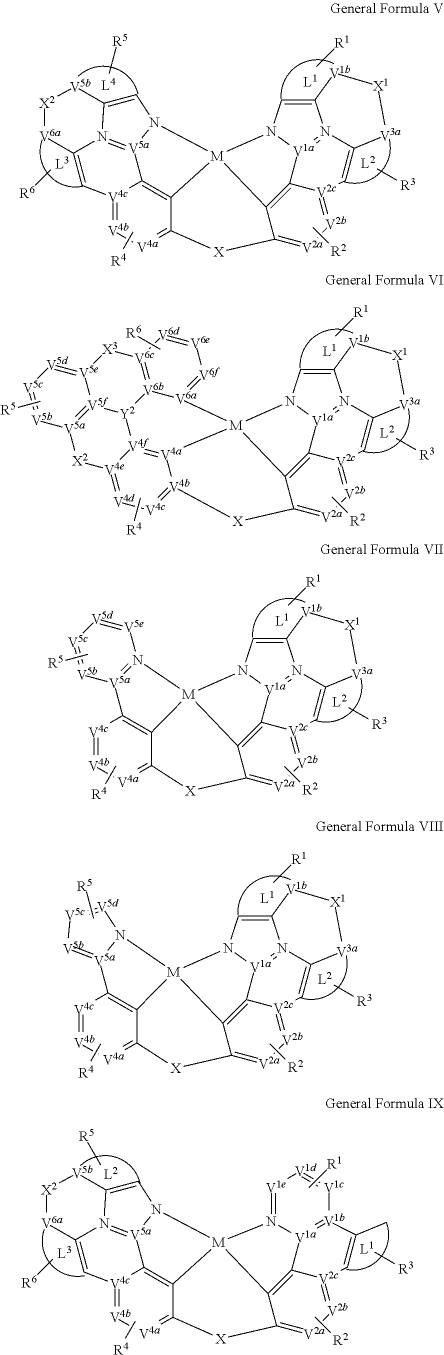

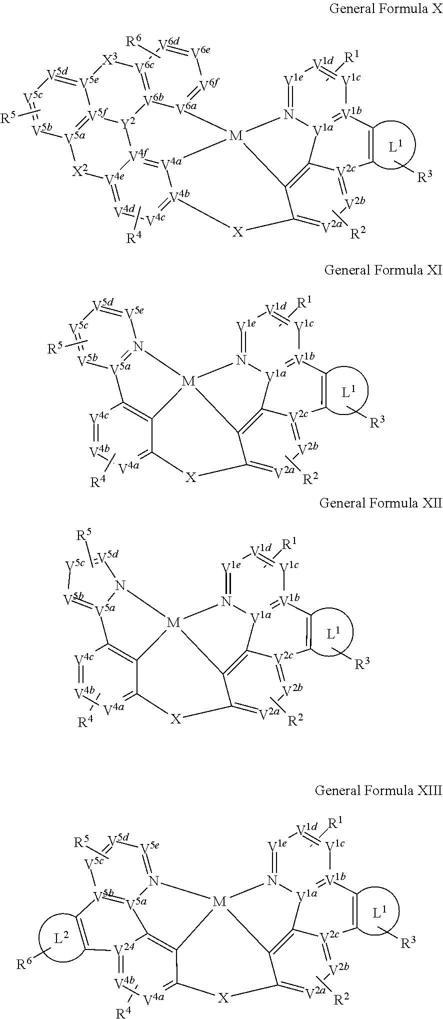

### In General Formulas V-XIII:

M is Pt (II) or Pd (II),
N is nitrogen,
each of V^{1a}-V^{1f}, V^{2a}-V^{2f}, V^{3a}-V^{3f}, v^{4a}-V^{4f}, V^{5a}-V^{5f}, and V^{6a}—V^{6f1}, if present, is independently N, C, P, O, S, or Si,
each of X, X¹, X², X³, and X⁴ is independently present or absent, and each X, X¹, X², X³, and X⁴ present independently represents a single bond, CR⁷R⁸, C═O, SiR⁷R⁸, GeR⁷R⁸, NR⁷, PR⁷, PR⁷R⁸, R⁷P═O, AsR⁷, R⁷As═O, O, S, S═O, SO₂, Se, Se═O, SeO₂, BR⁷, BR⁷R⁸, AlR⁷, AlR⁷R⁸, R⁷Bi═O, or BiR⁷,
each of Y¹ and Y² is independently CR, SiR, GeR, N, NR, P, P═O, As, As═O, B, BR, Al, AlR, Bi═O, or Bi,
each of L¹, L², L³, and L⁴ is independently present or absent, and each L¹, L², L³, and L⁴ present independently represents a substituted or unsubstituted aryl, heteroaryl, or N-heterocyclic carbene,
each of R, R¹, R², R³, R⁴, R⁵, R⁶, R⁷, and R⁸ is independently absent or present as a single substituent or multiple substituents, valency permitting, and each R, R¹, R², R³, R⁴, R⁵, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

Compounds of General Formulas V XIII include the following.

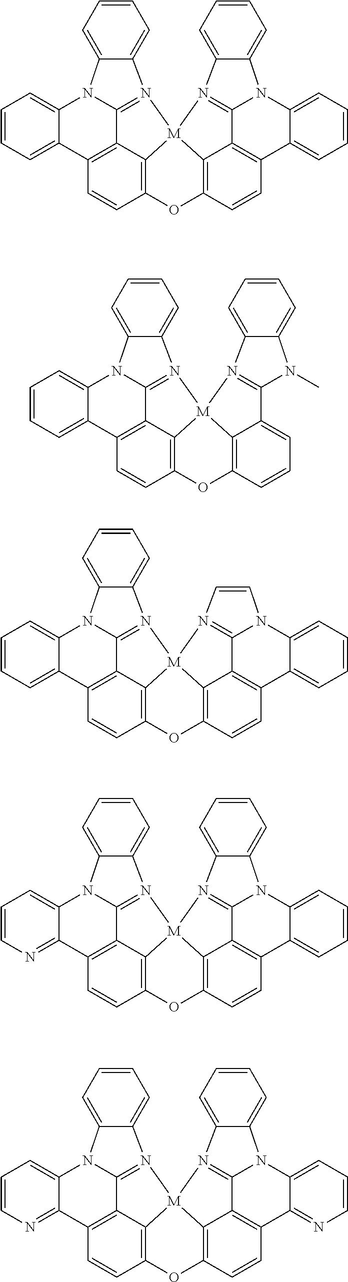

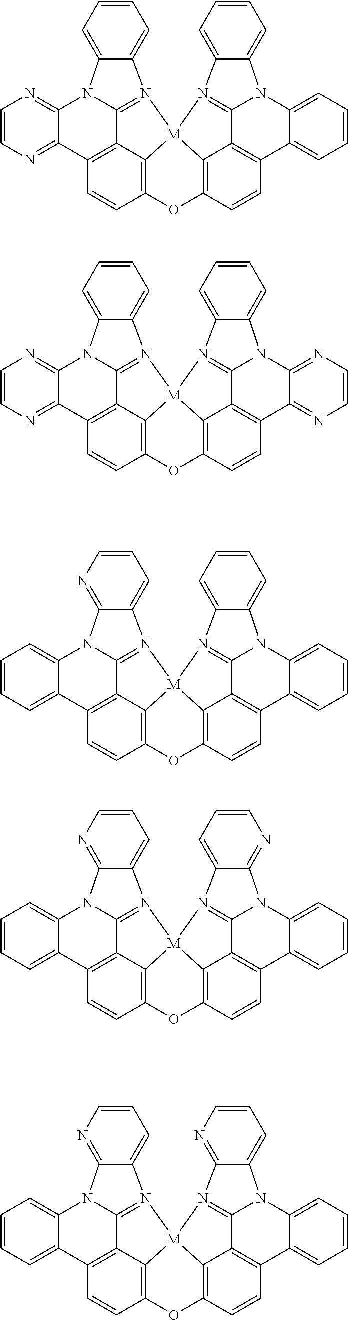

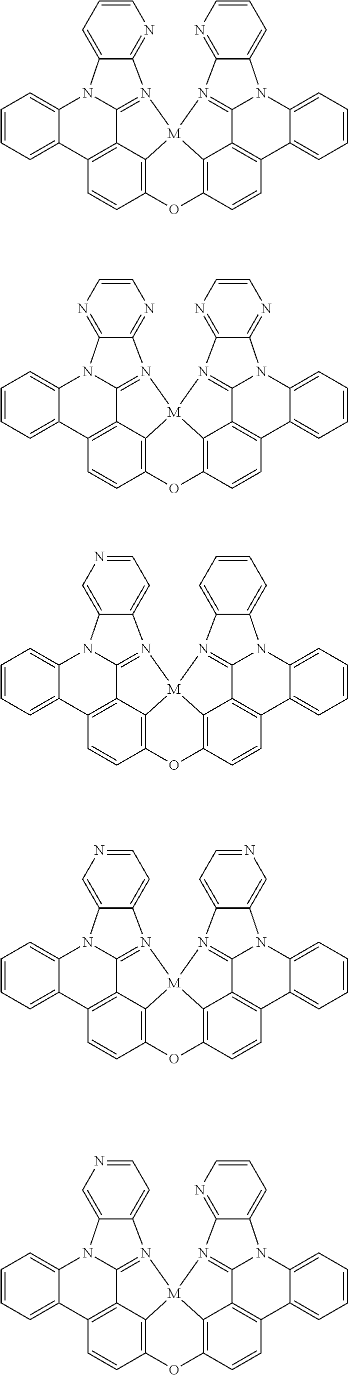

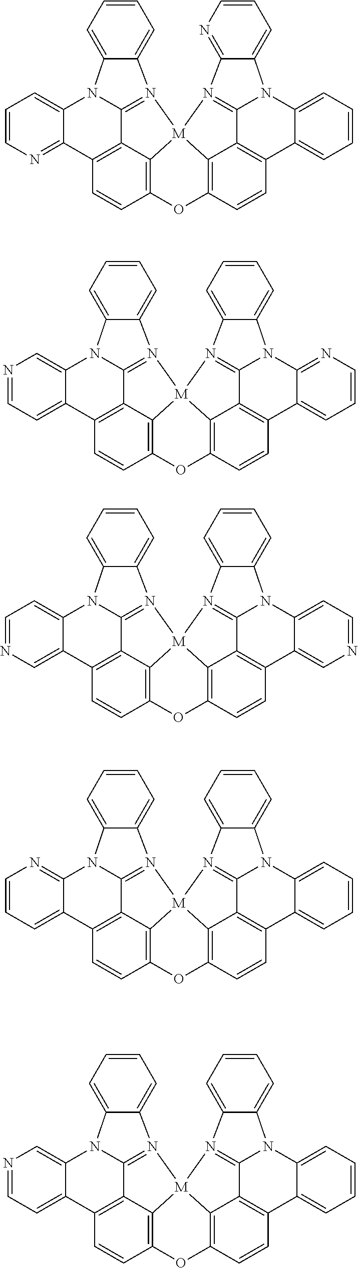

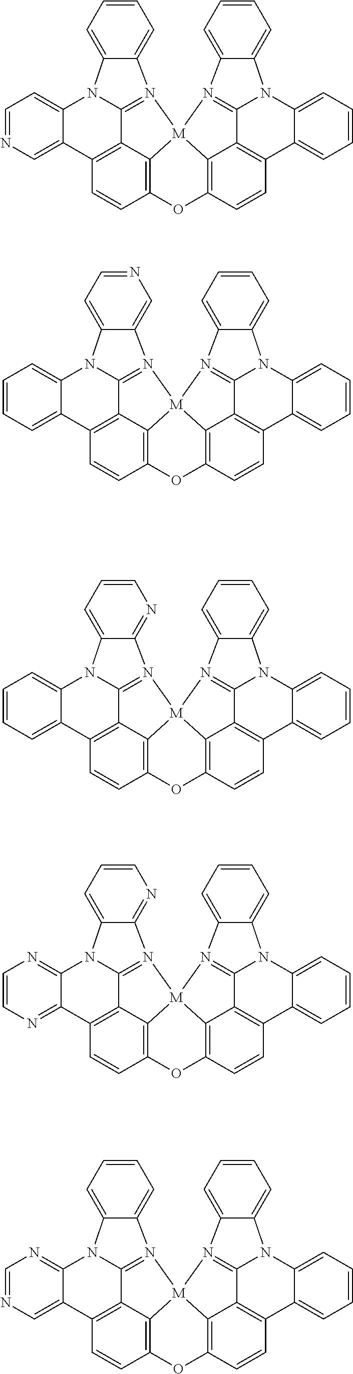

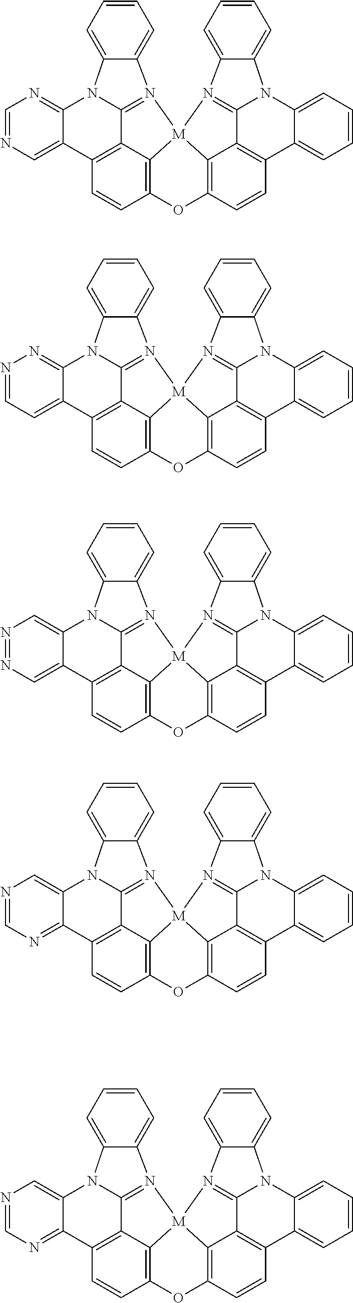

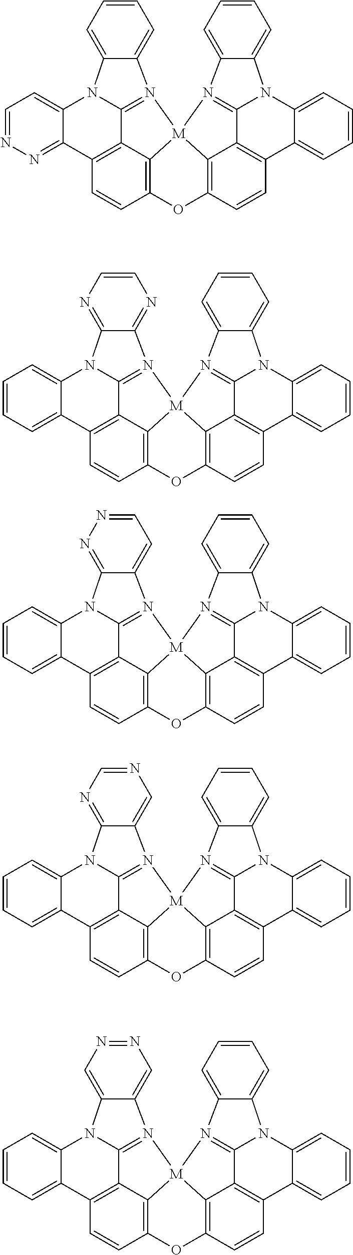

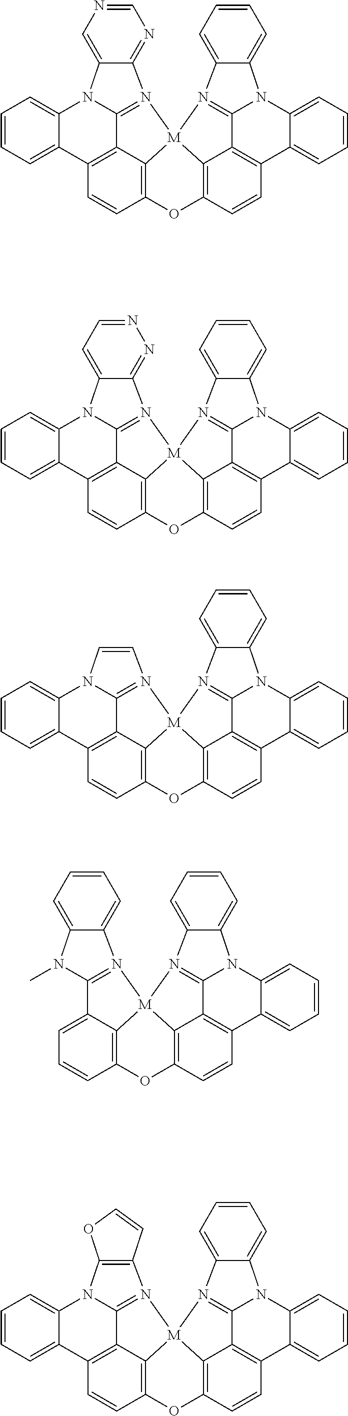

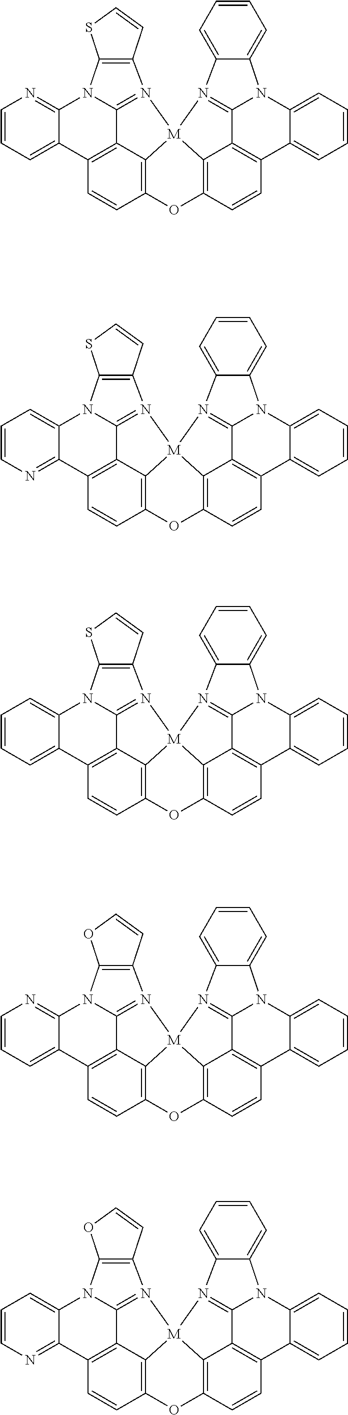

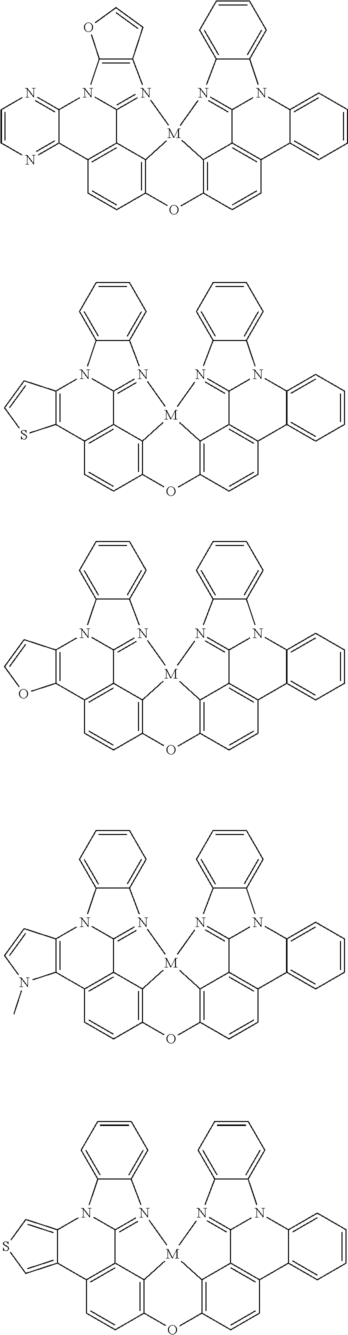

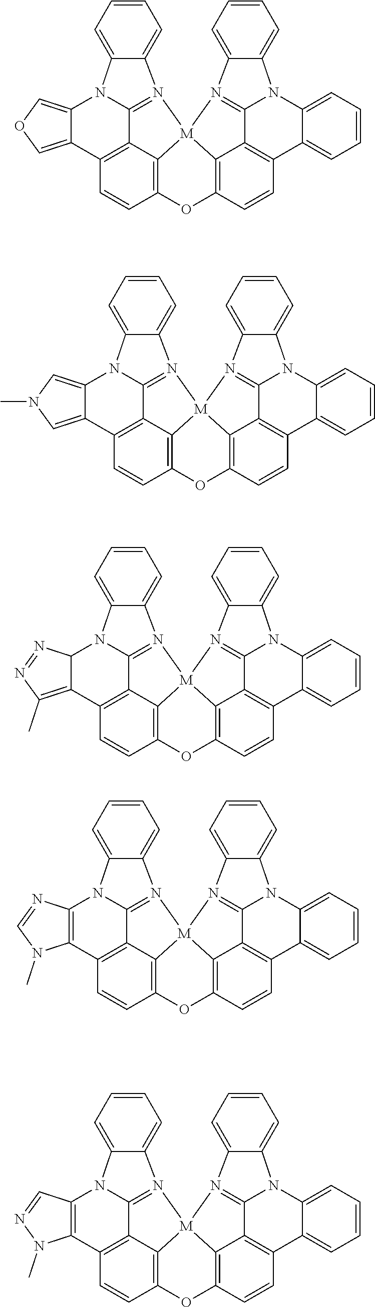

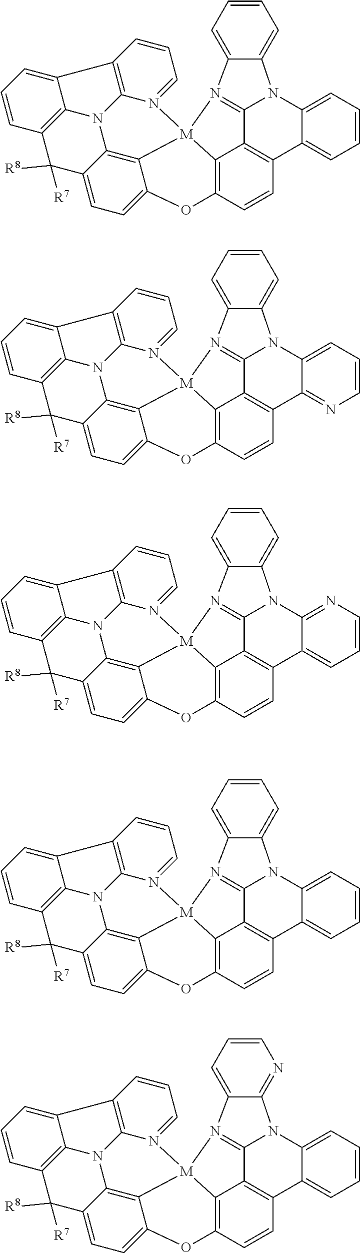

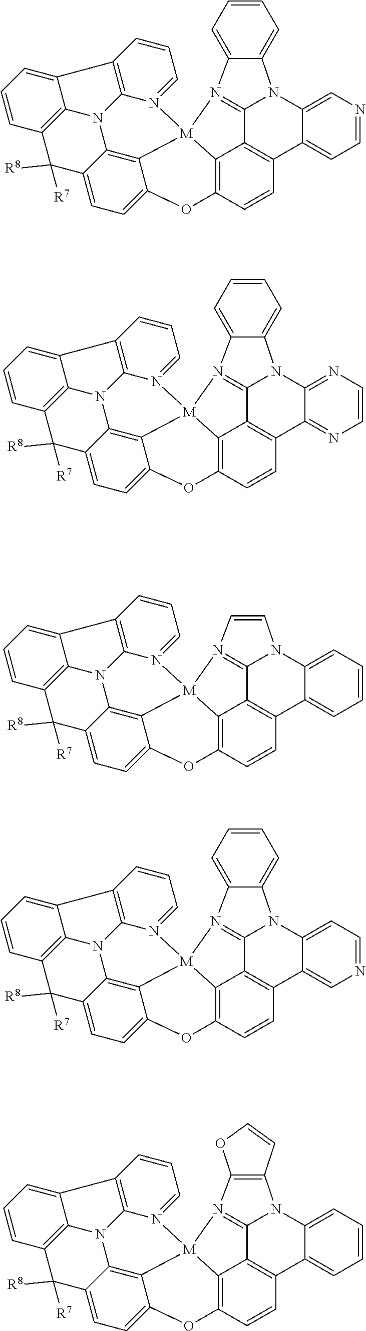

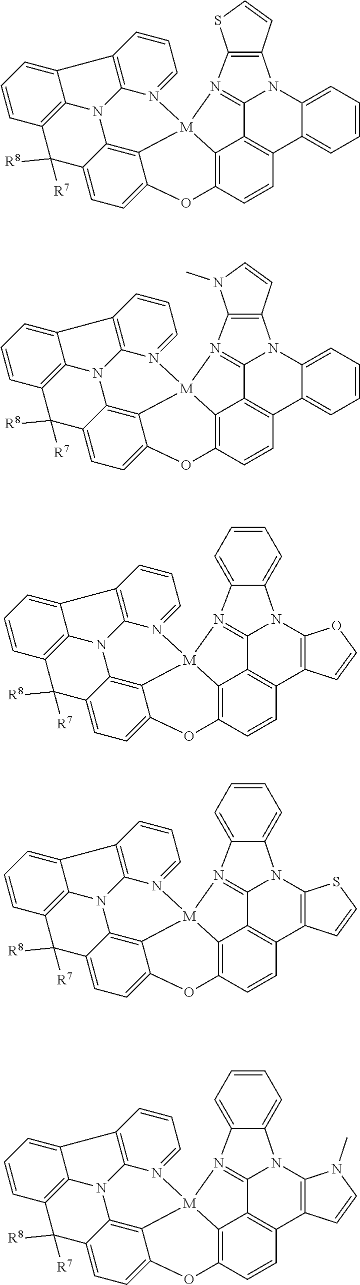

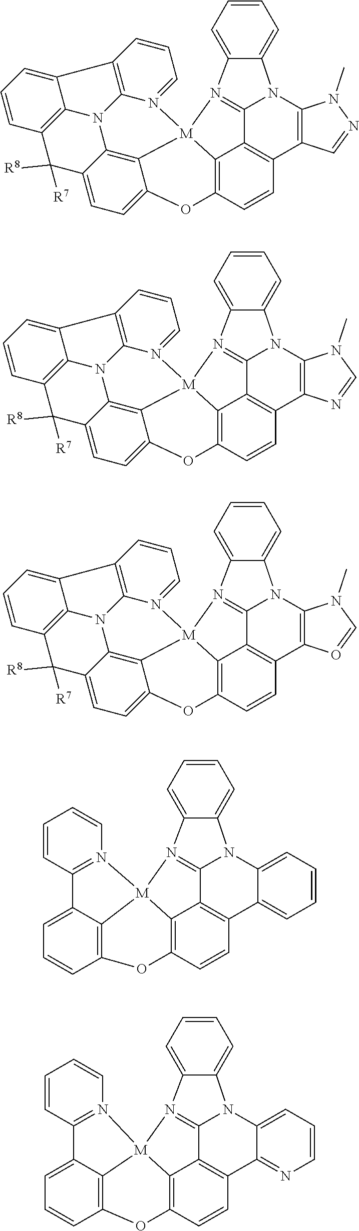

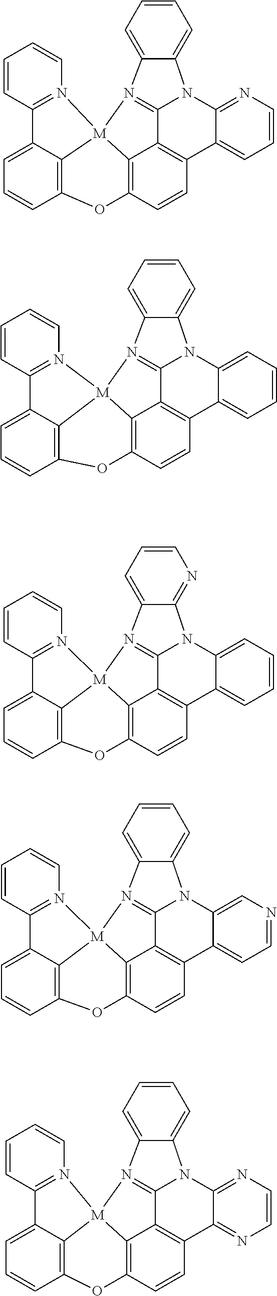

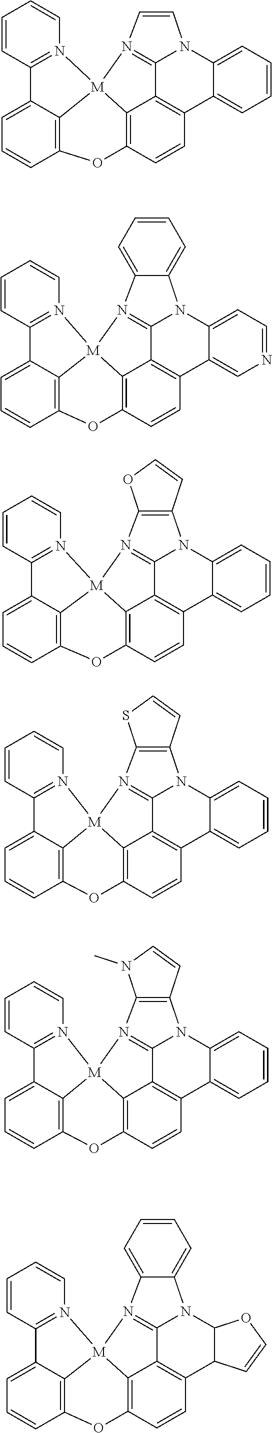

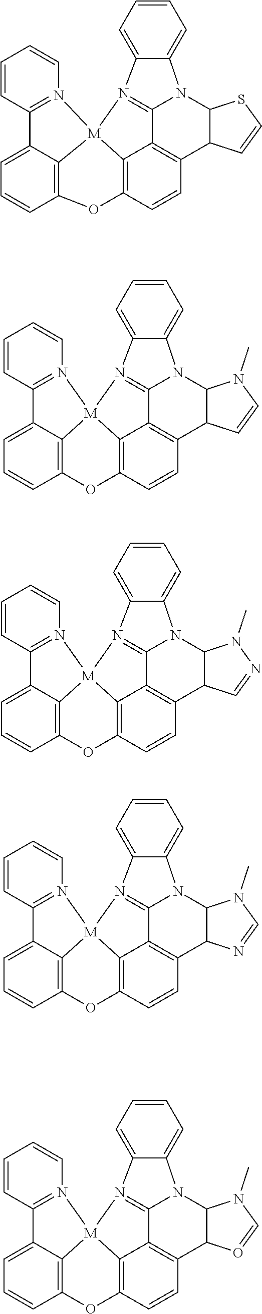

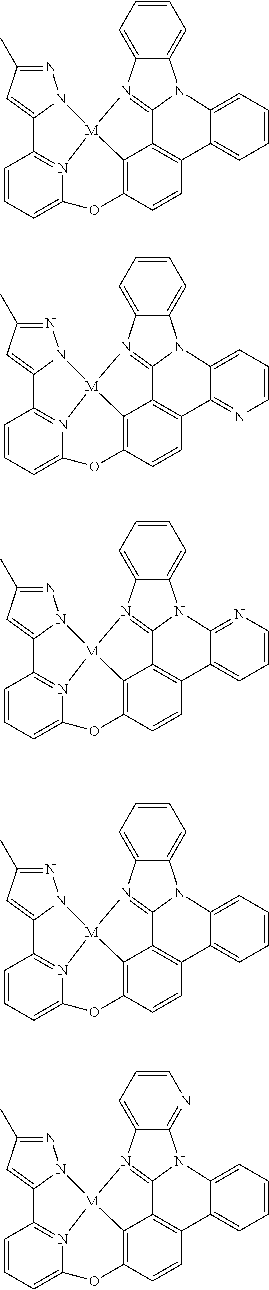

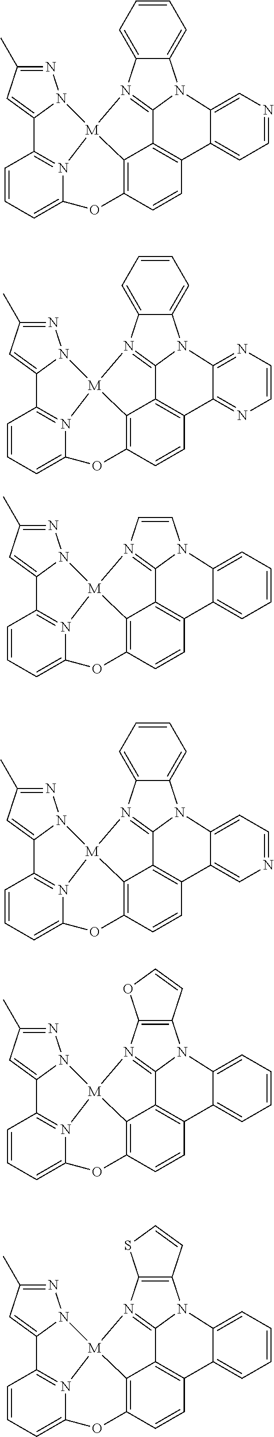

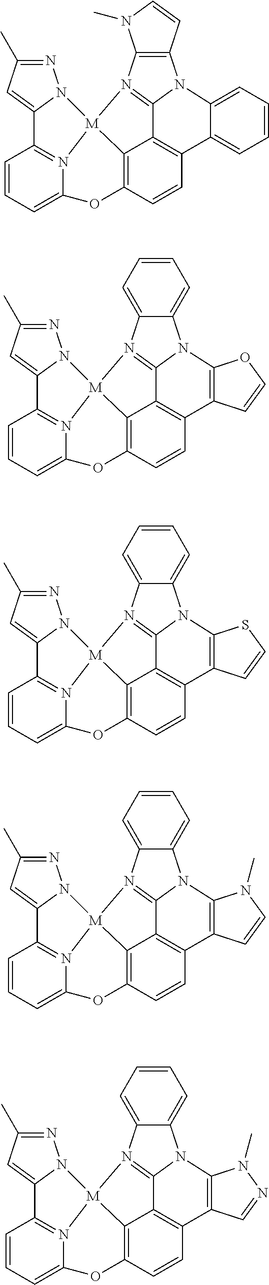

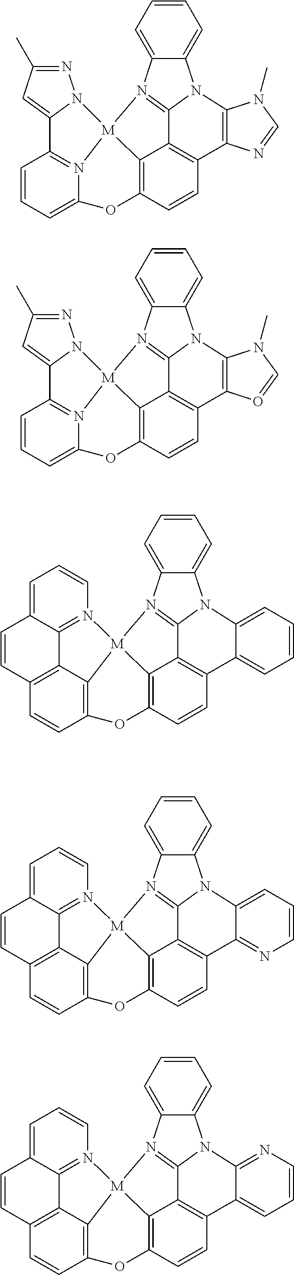

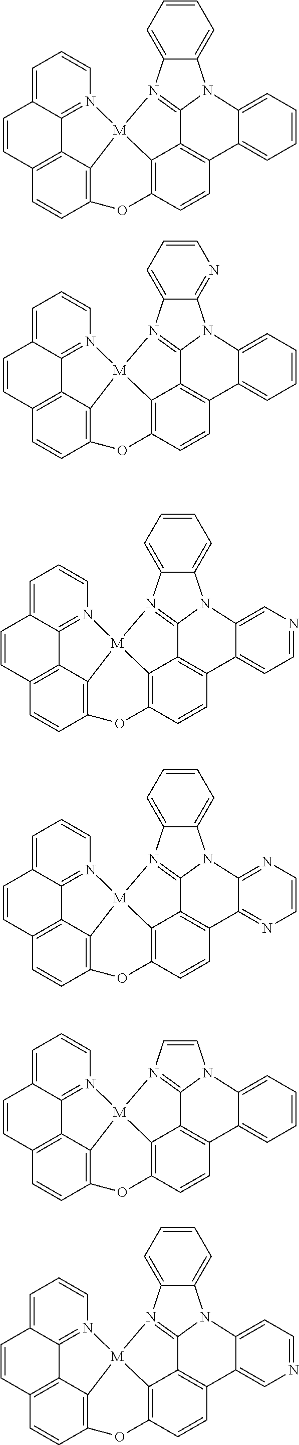

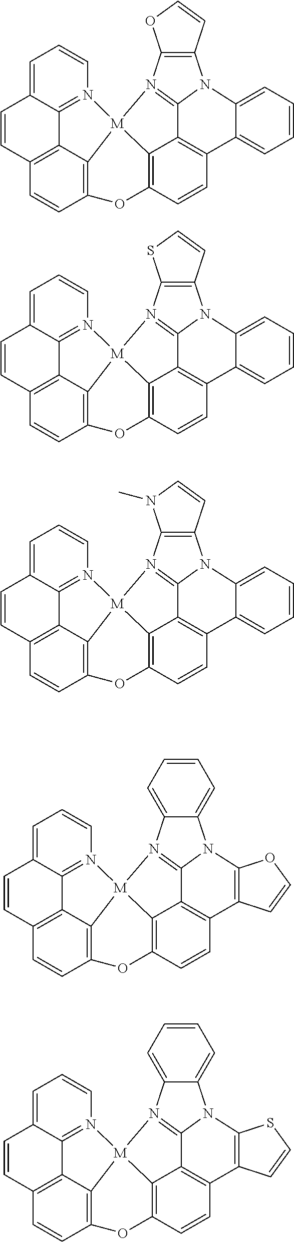

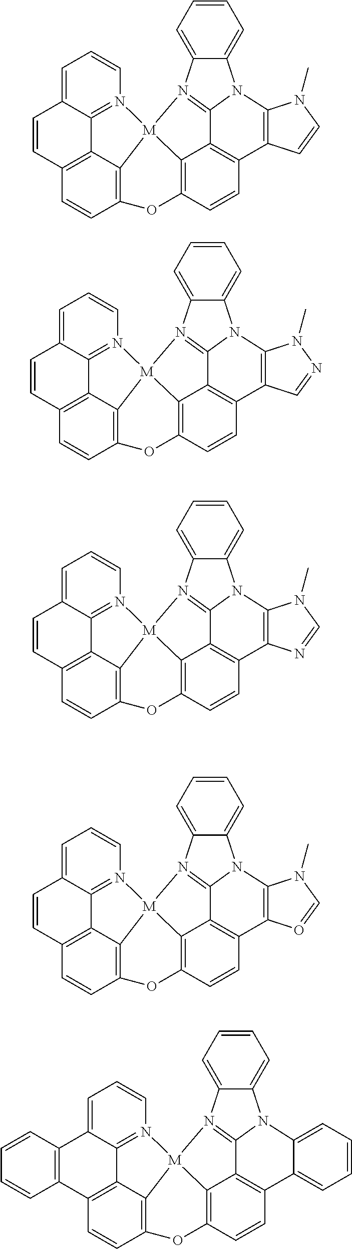

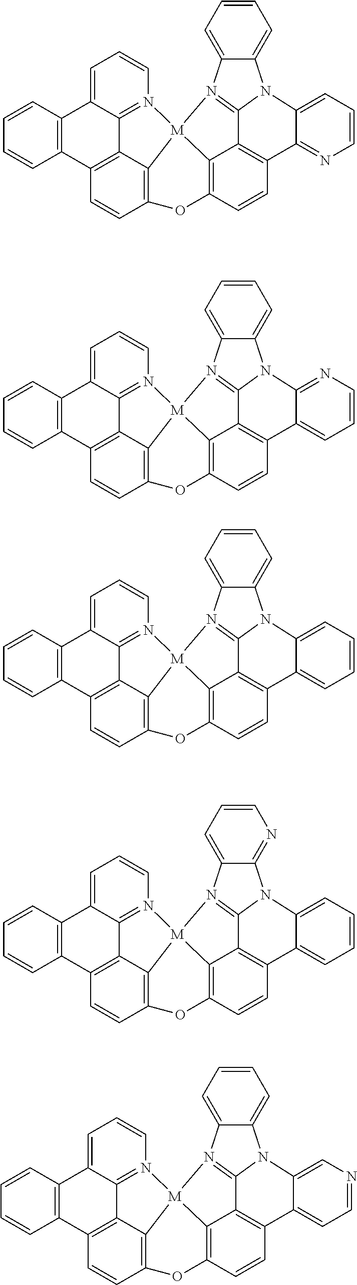

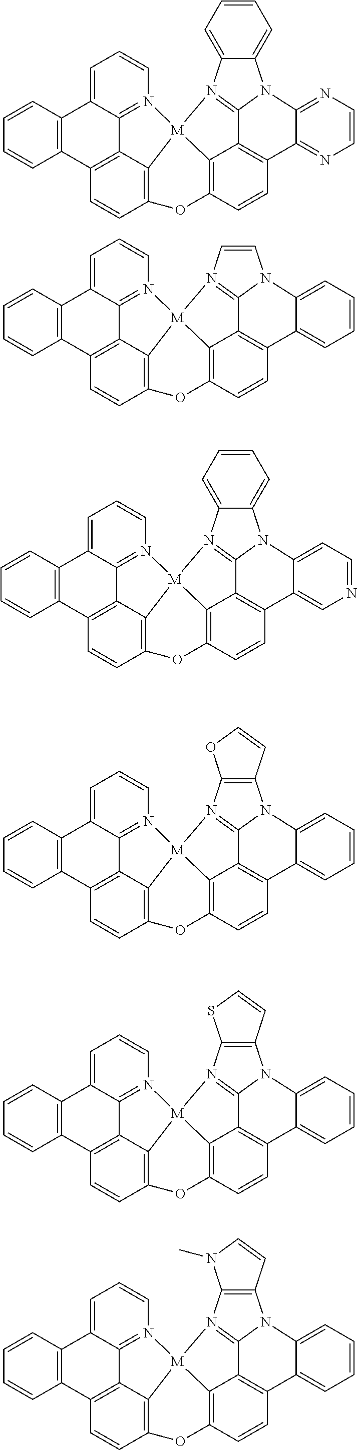

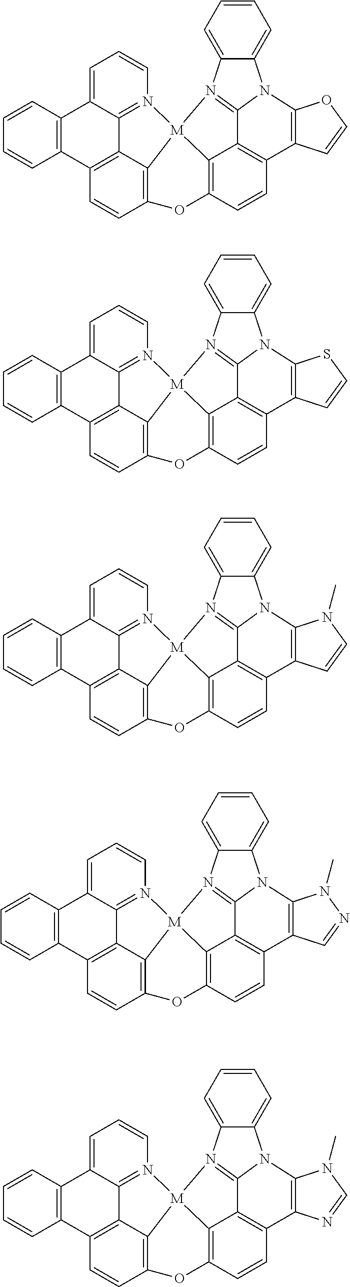

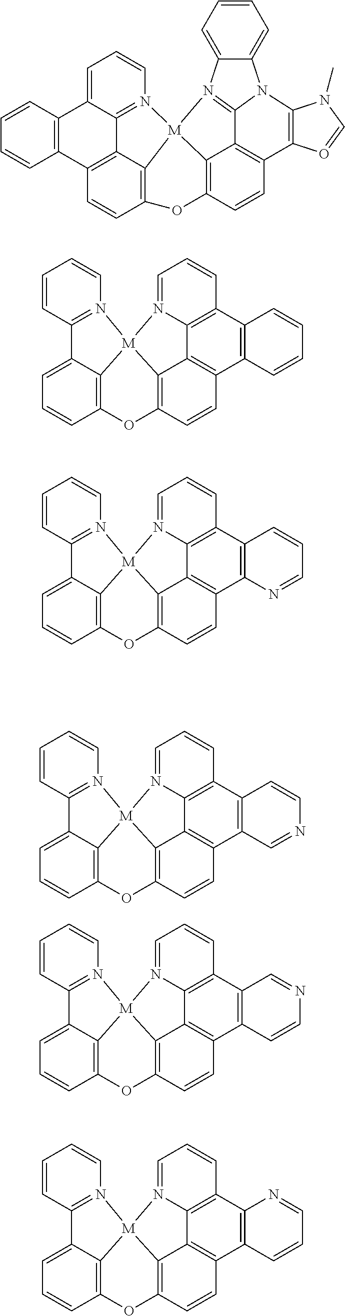

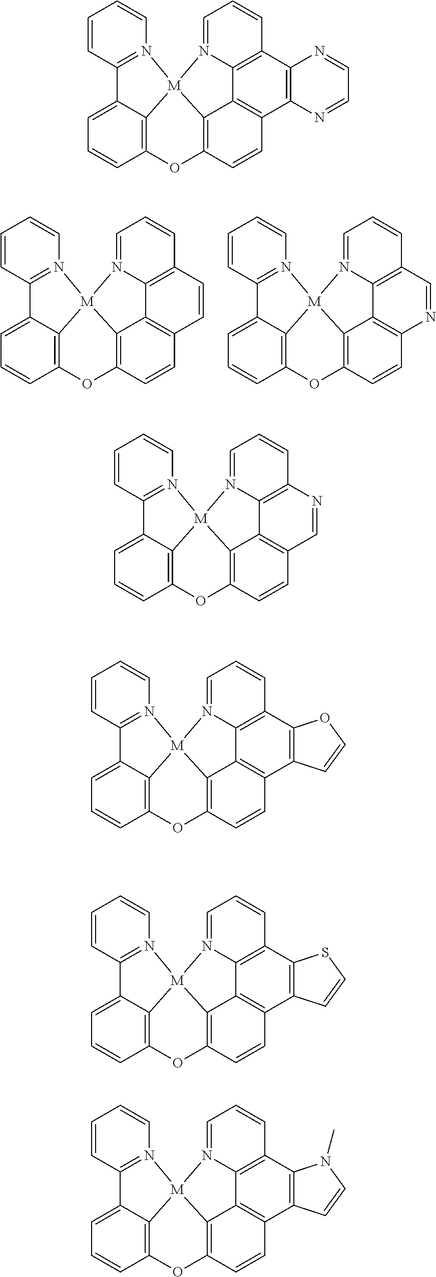

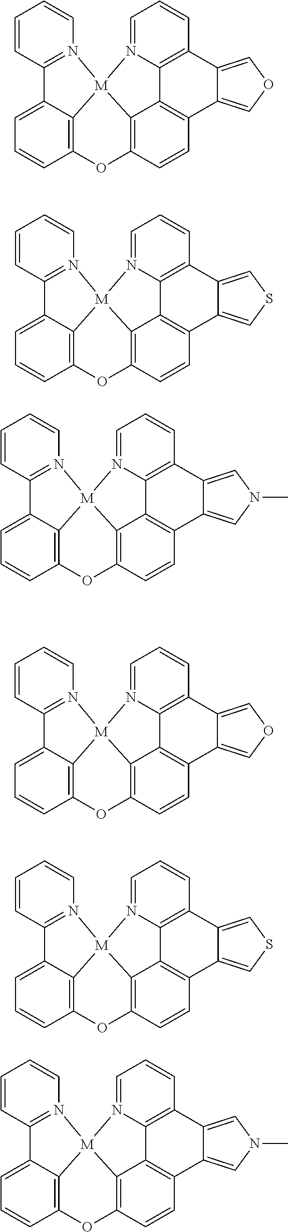

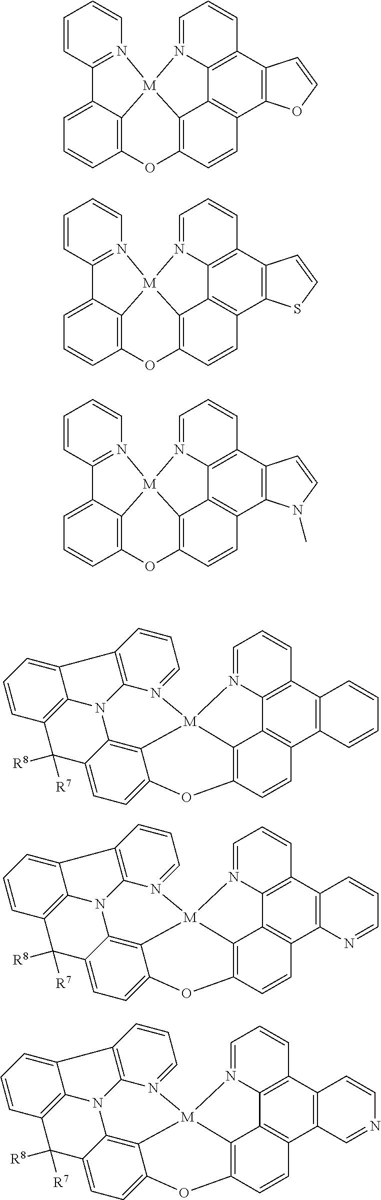

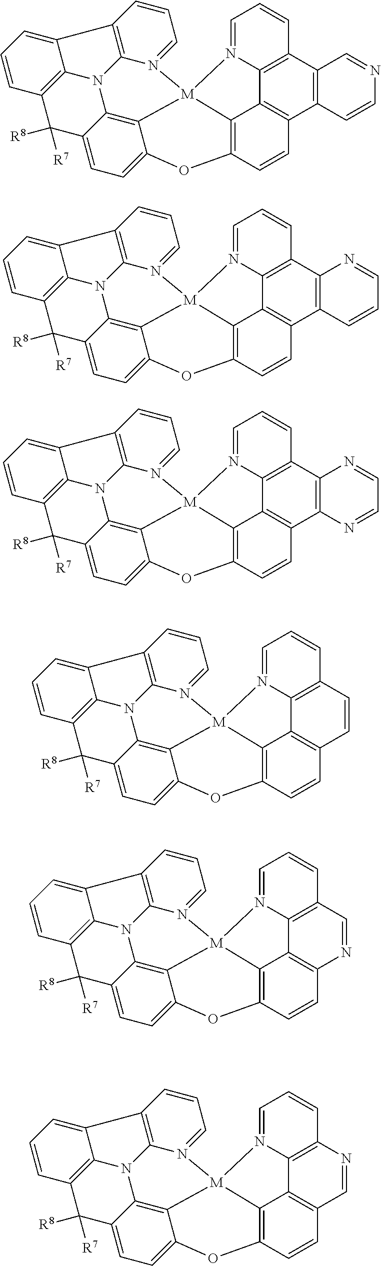

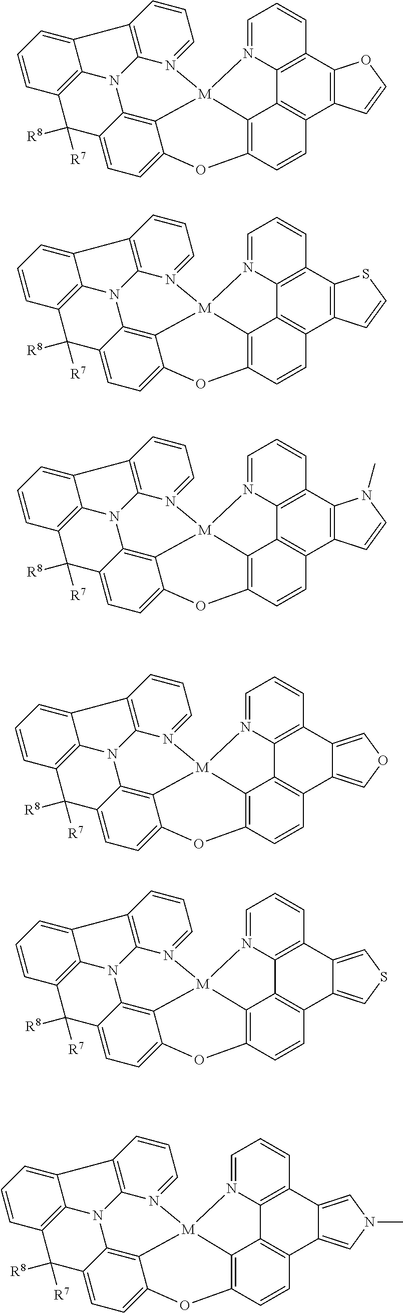

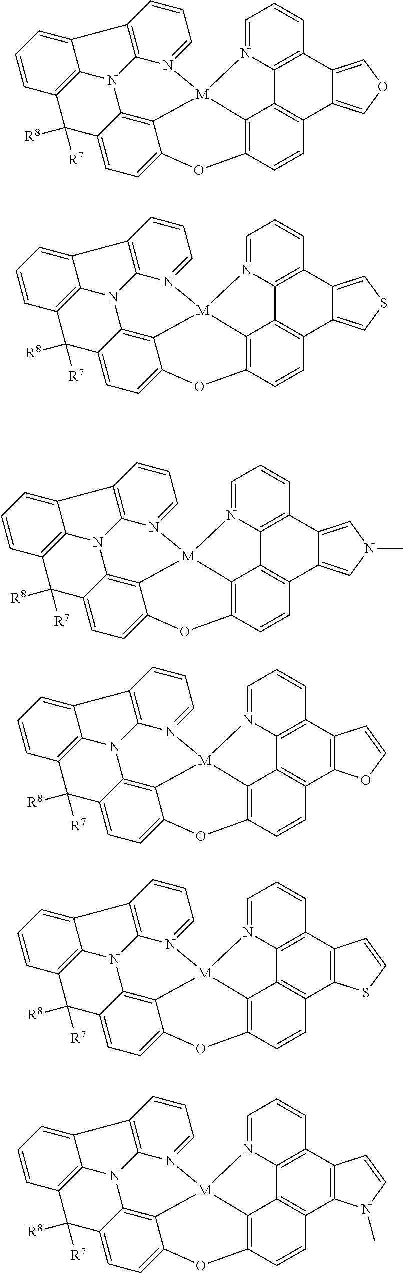

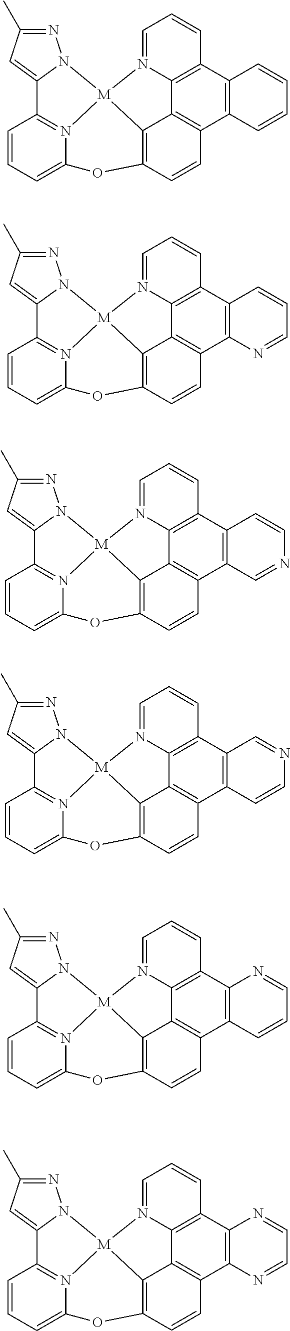

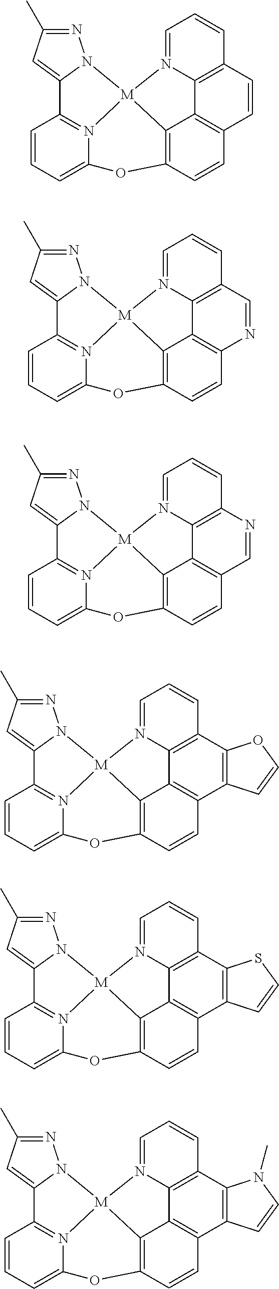

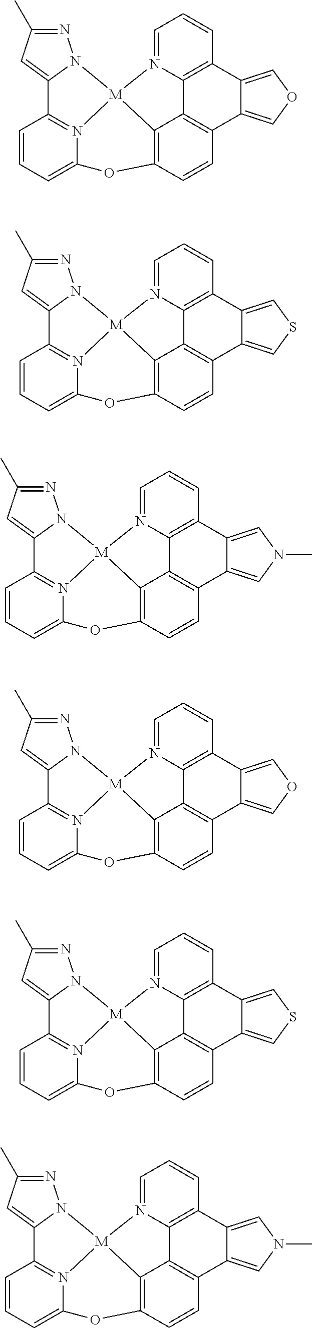

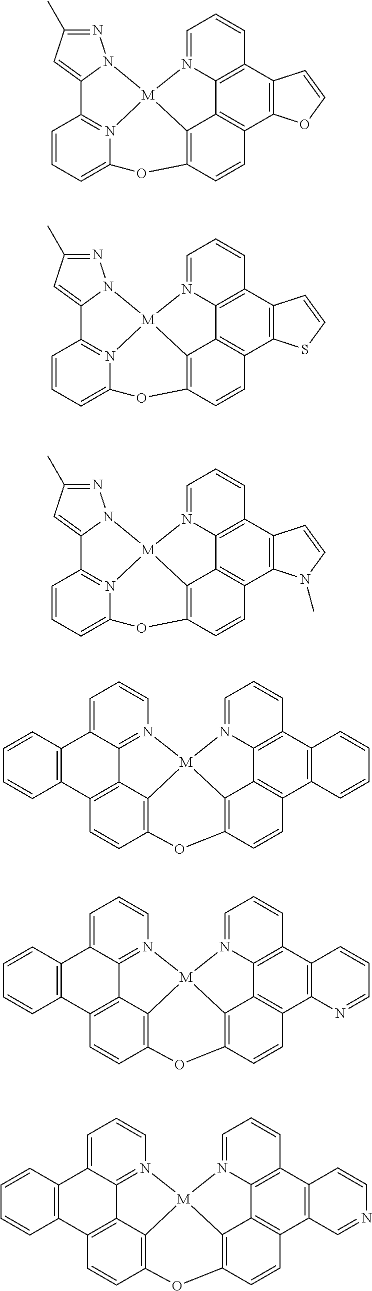

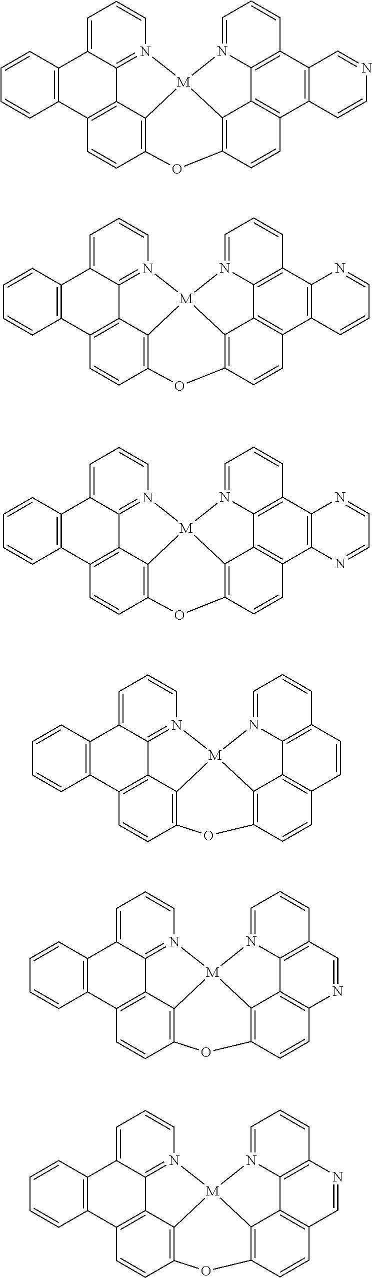

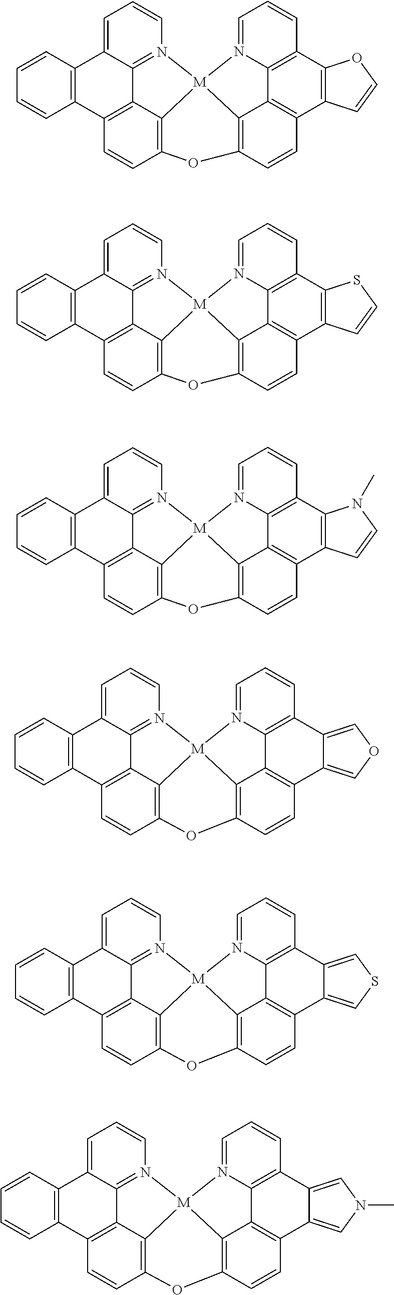

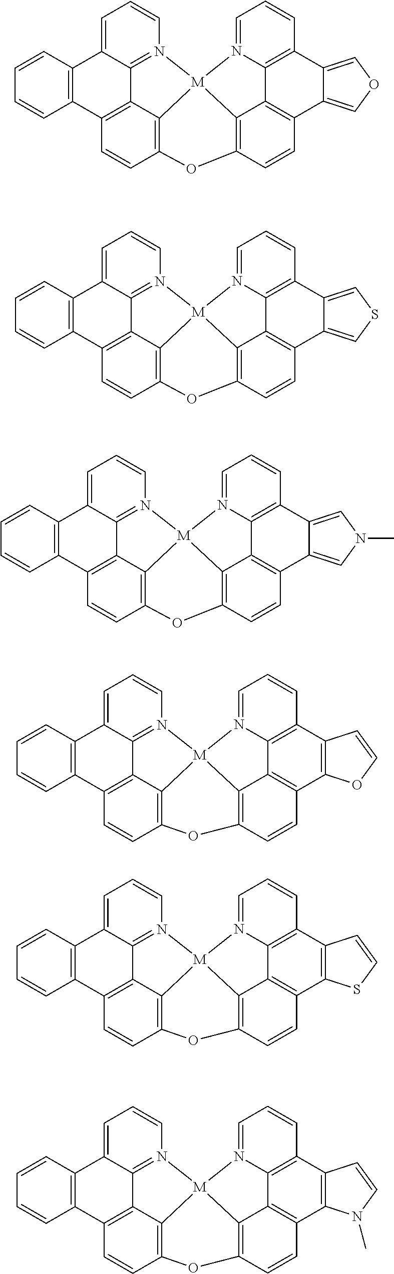

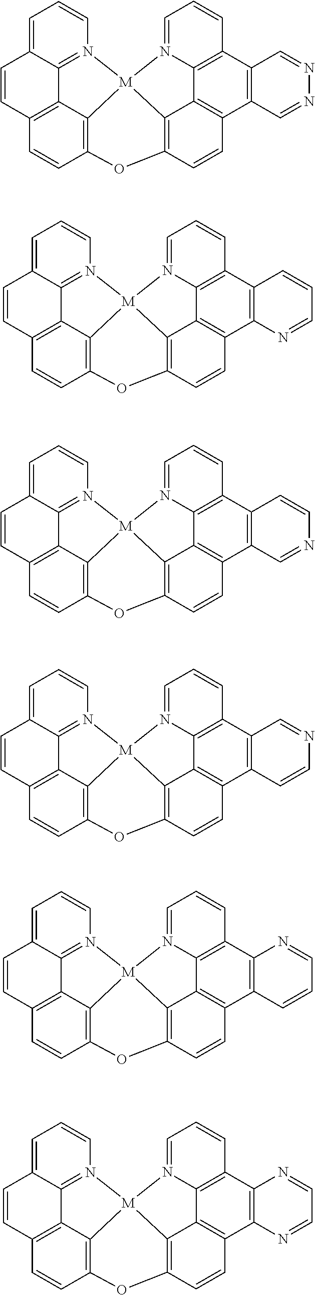

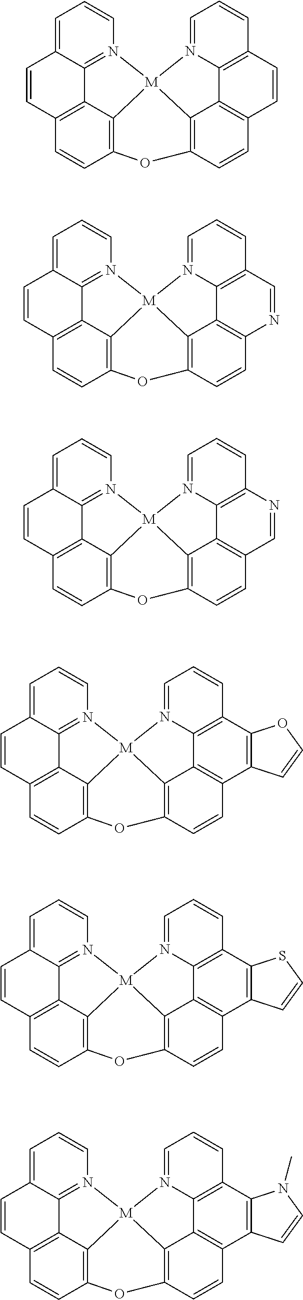

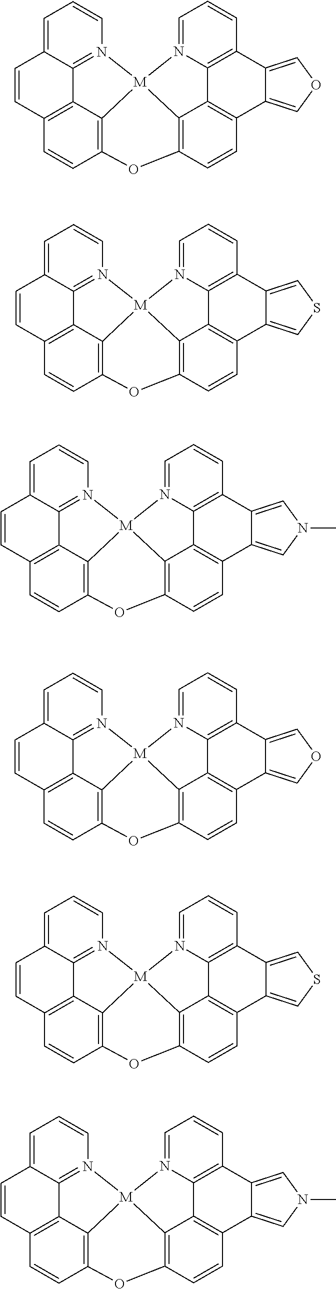

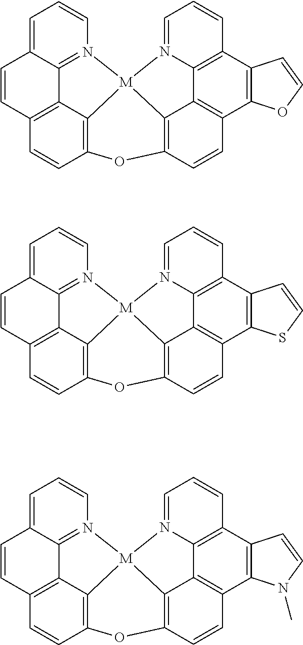

The substituents in these compounds are as defined herein.

Octahedral iridium (III) metal-assisted delayed fluorescent (MADF) emitters employing benzo-imidazo-phenanthridine are represented by General Formulas XIV-XVII:

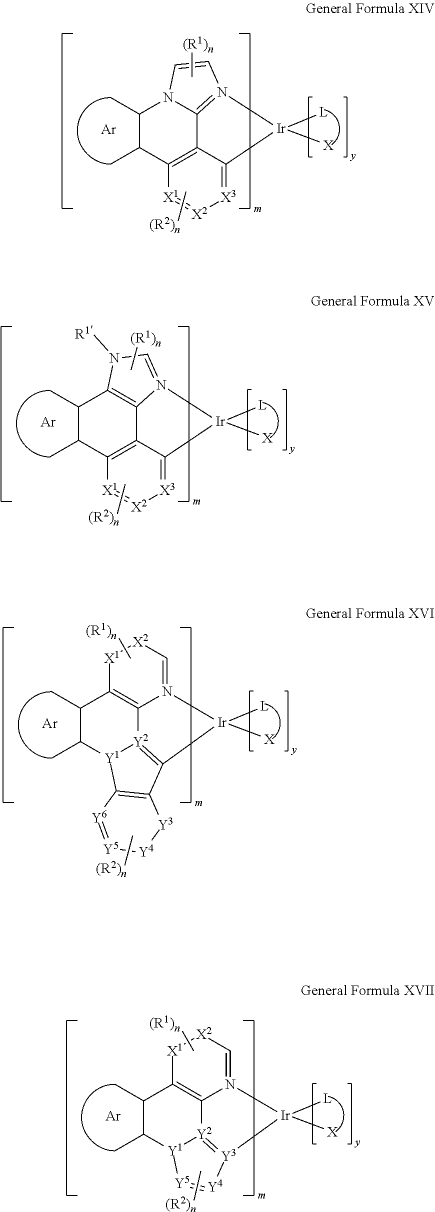

### In General Formulas XIV-XVII,

N is nitrogen,
Ir is iridium,
m+y=3, and when m=3, y=0, when m=2, y=1, when m=1, y=2,
each n is independently an integer, valency permitting,
each

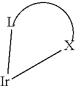

represents one of the following chemical moieties:

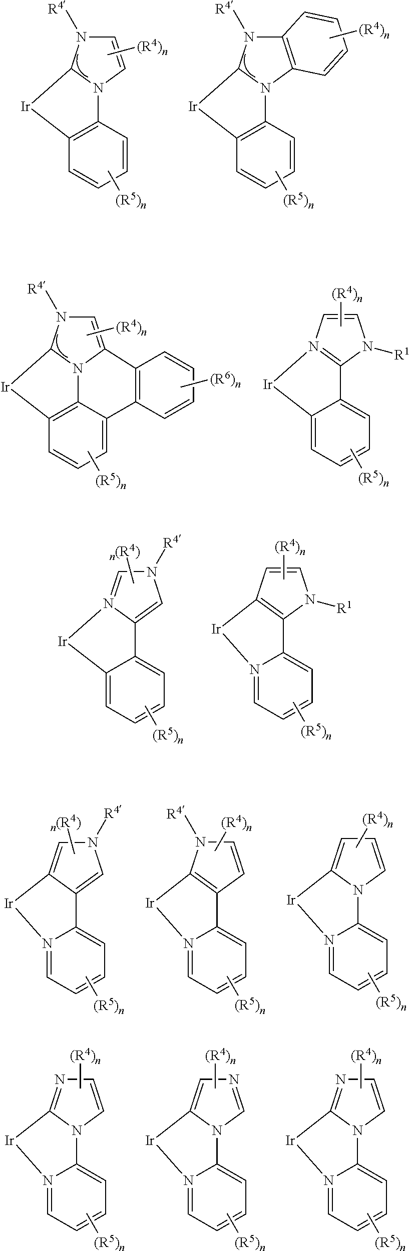

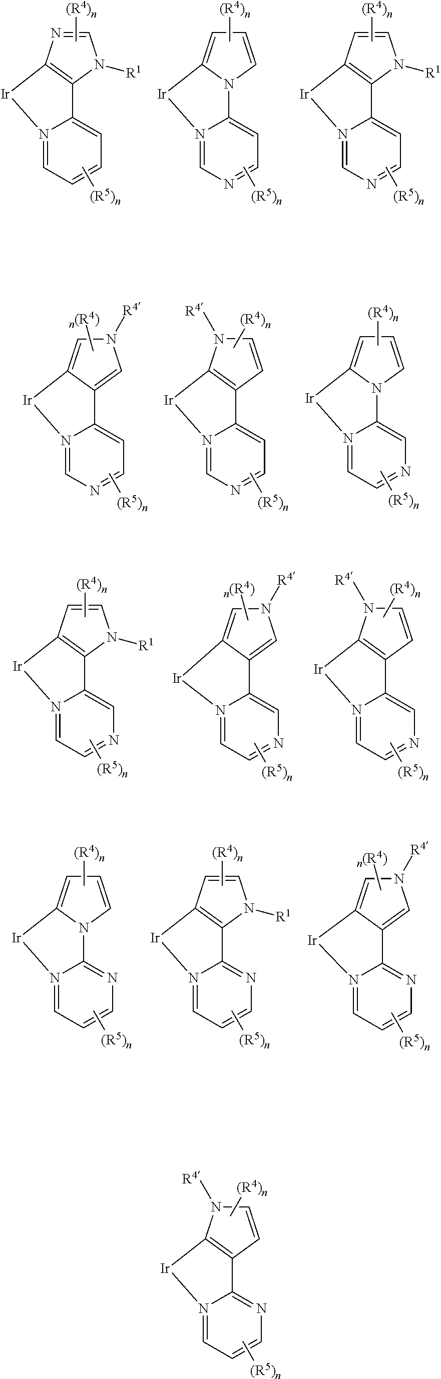

each of R, R¹, R², R³, R⁴, R⁵, R⁶, R^{1′}, and R^{4′} is independently absent or present as a single substituent or multiple substituents, valency permitting, and each R, R¹, R², R³, R⁴, R⁵, R⁶, R^{1′}, and R^{4′} present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, where the following are examples:

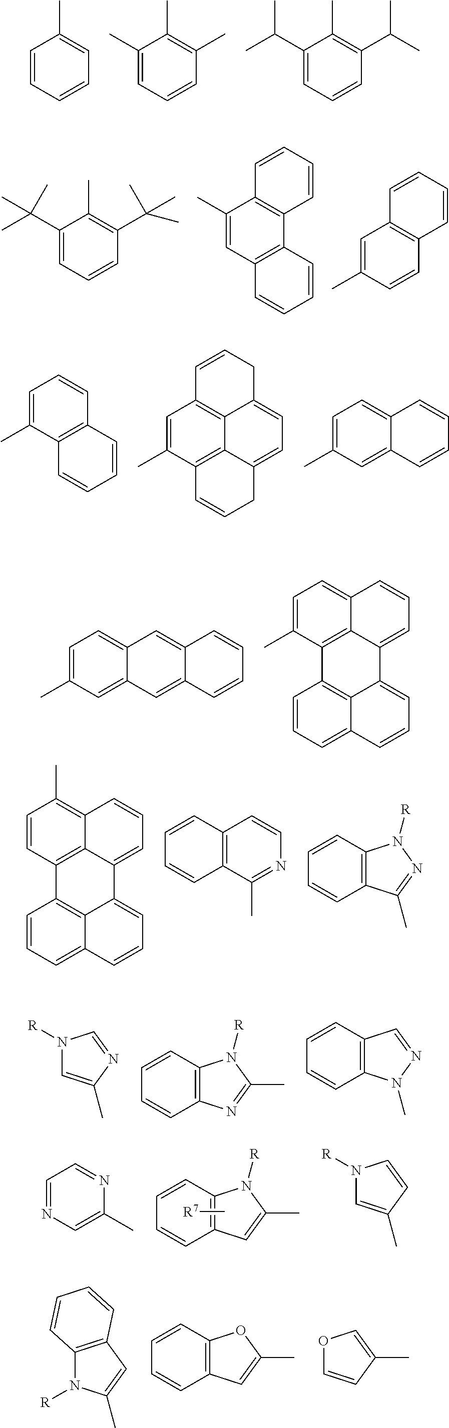

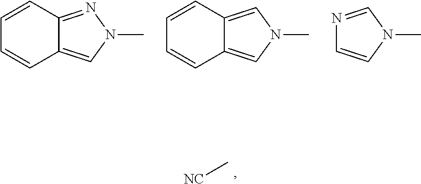

each of X¹, X², X³, X⁴, Y¹, Y², Y³, Y⁴, Y⁵, Y⁶, and Y⁷ is independently present or absent, and each X¹, X², X³, X⁴, Y¹, Y², Y³, Y⁴, Y⁵, Y⁶, and Y⁷ present independently represents C, N, Si, O, S, Ge, P, As, Se, B, Al, or Bi, or, valency permitting, CR⁷, SiR⁷, GeR⁷, NR⁷, P═O, As═O, B, BR⁷, AlR⁷, Bi═O, CR⁷R⁸, C═O, SiR⁷R⁸, GeR⁷R⁸, NR⁷, PR⁷, PR⁷R⁸, R⁷P═O, AsR⁷, R⁷As═O, S═O, SO₂, Se═O, SeO₂, BR⁷, BR⁷R⁸, AiR⁷, AlR⁷R⁸, R⁷Bi═O, or BiR⁷,
each

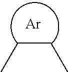

is independently present or absent, and each Ar present independently represents a substituted or unsubstituted aryl, heteroaryl, or N-heterocyclic carbene, and the following chemical moieties:

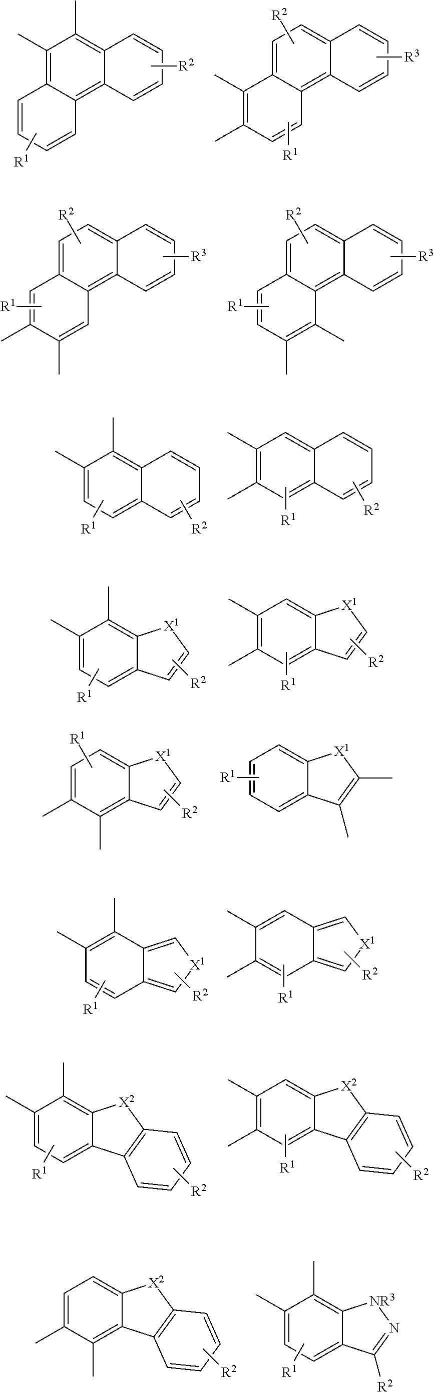

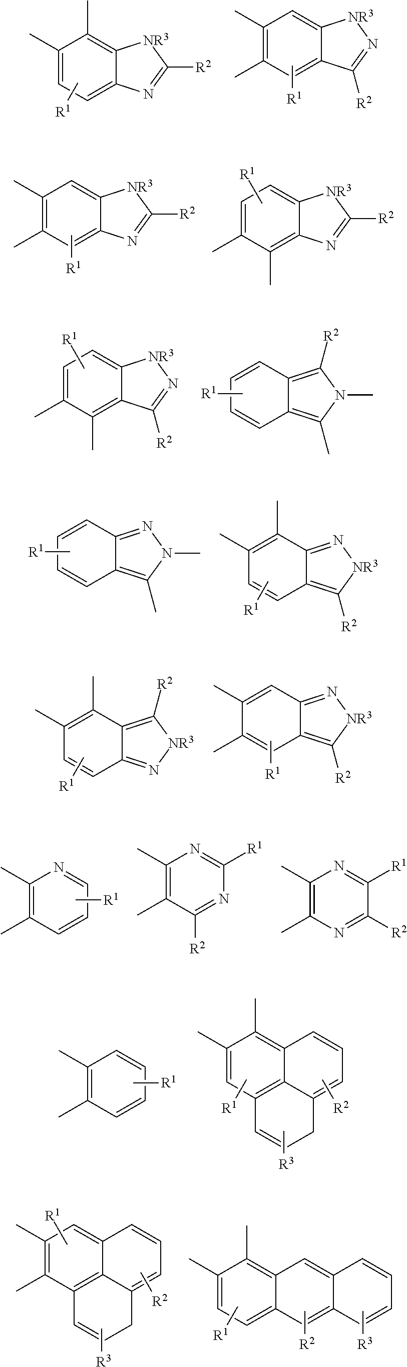

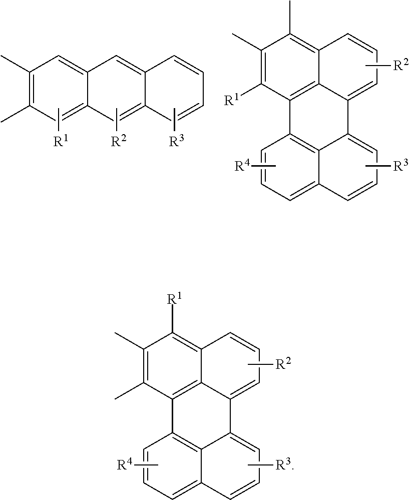

In General Formulas XIV-XVII, for m=3, the moieties can be the same or different. That is, when m=3, the three moieties can be the same, two of the moieties can be the same, or all three of the moieties can be different.

Implementations of General Formulas XIV-XVII include the following:

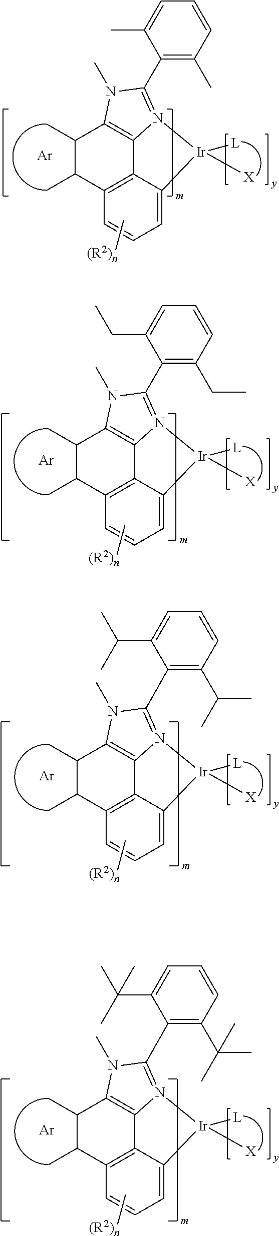

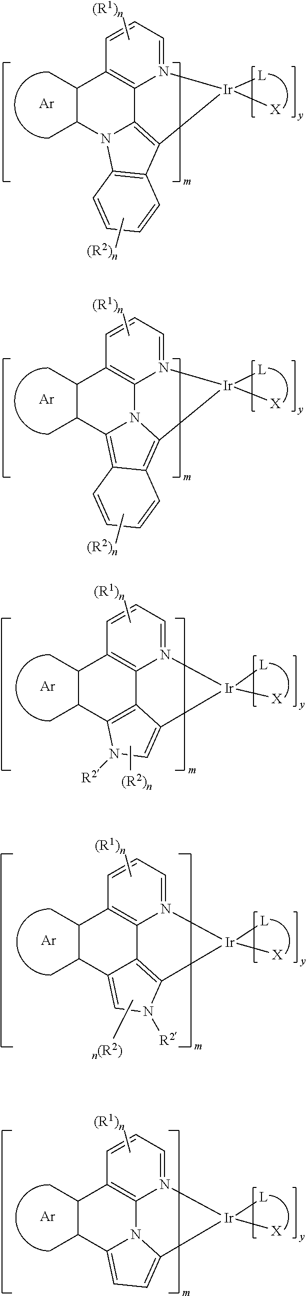

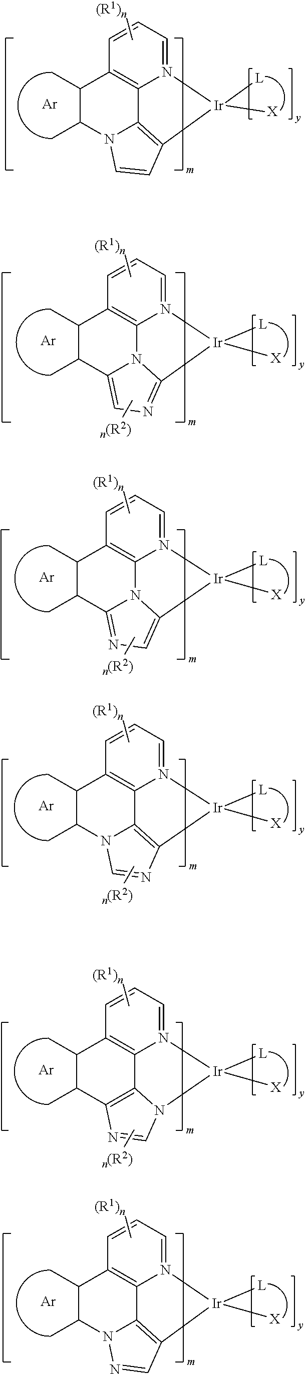

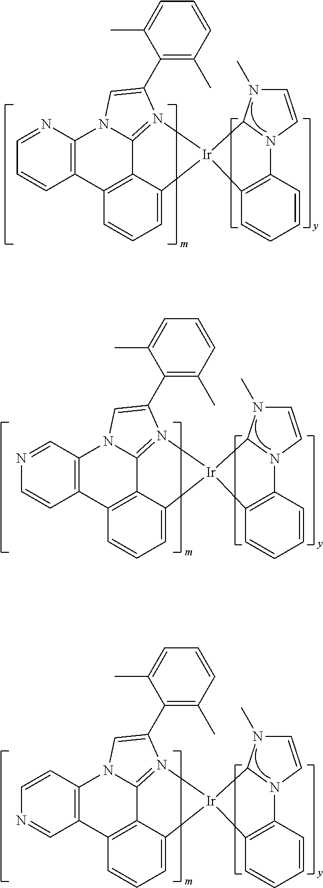

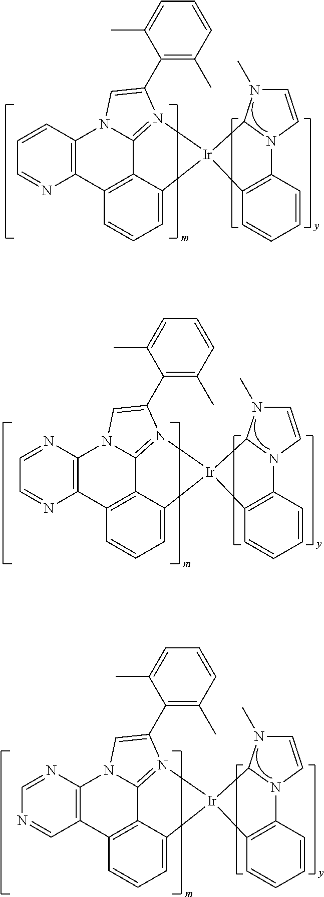

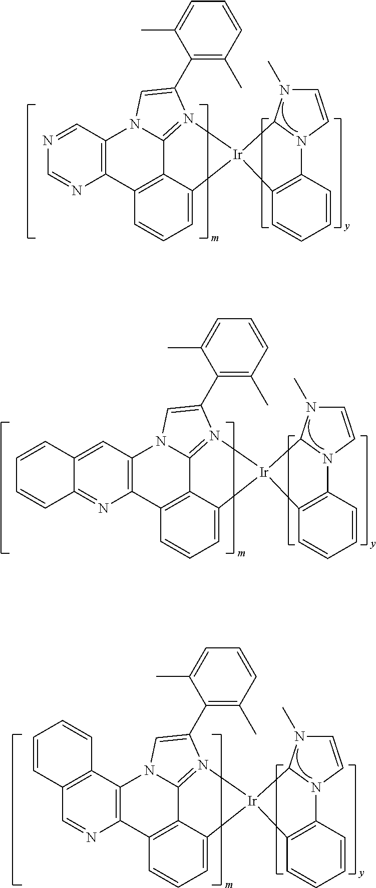

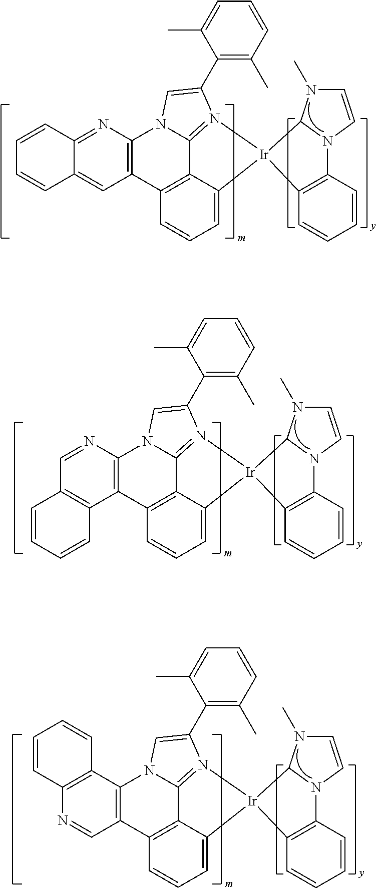

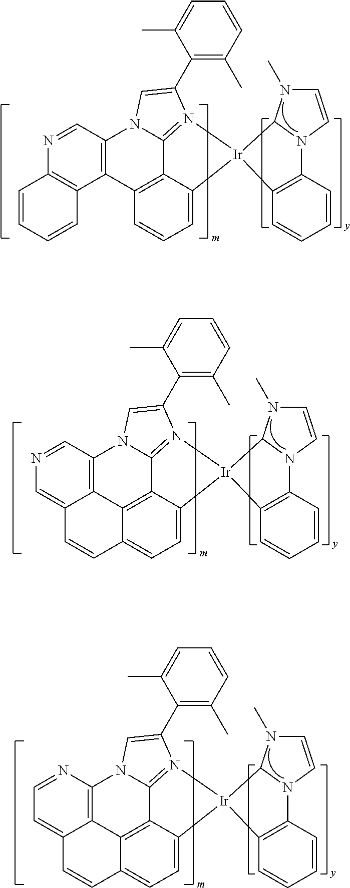

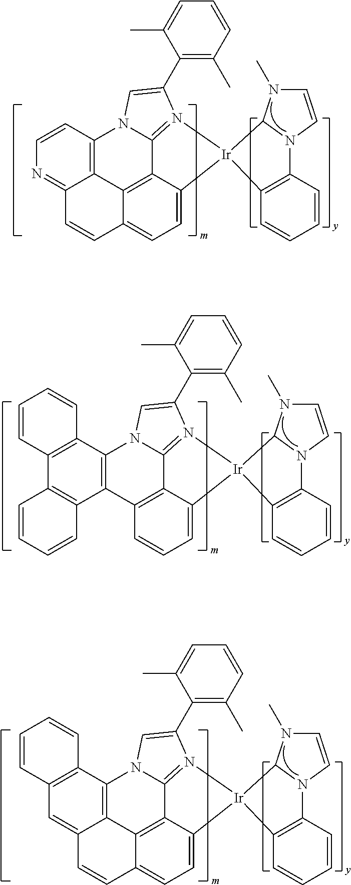

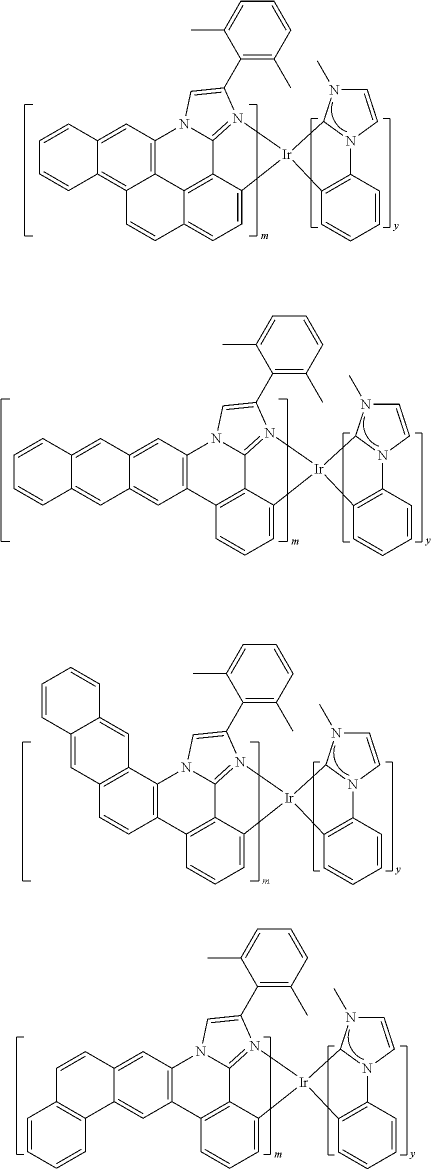

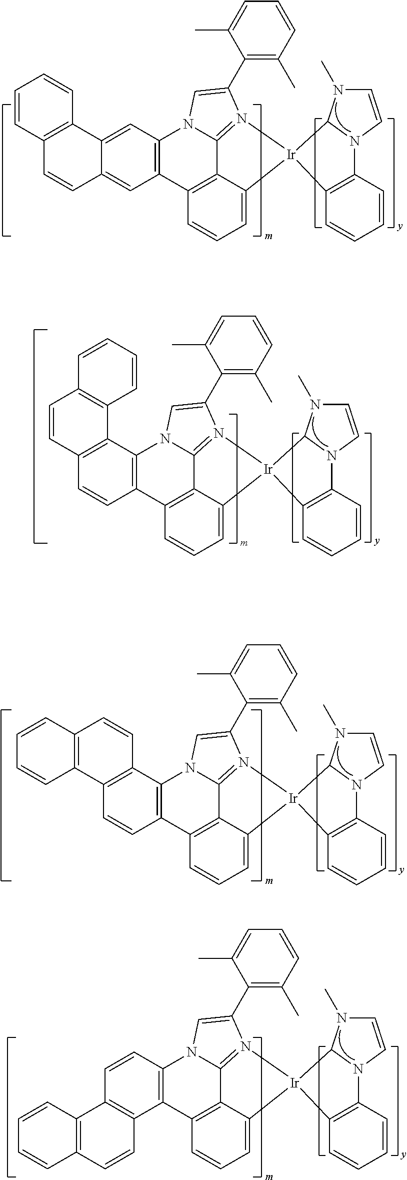

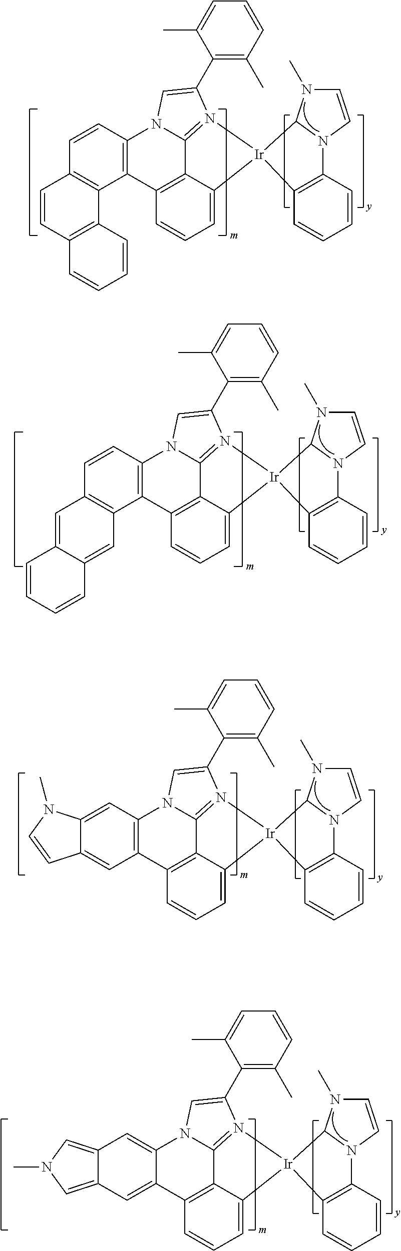

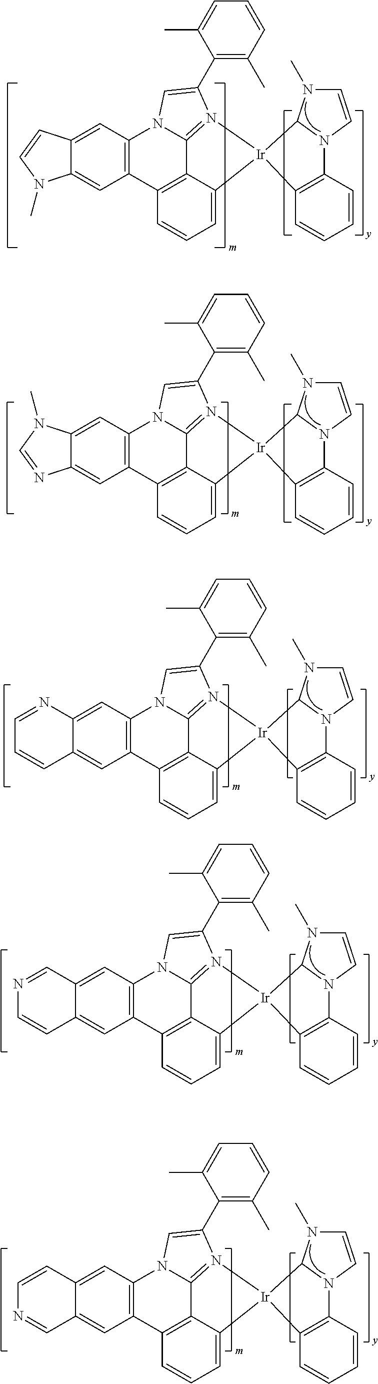

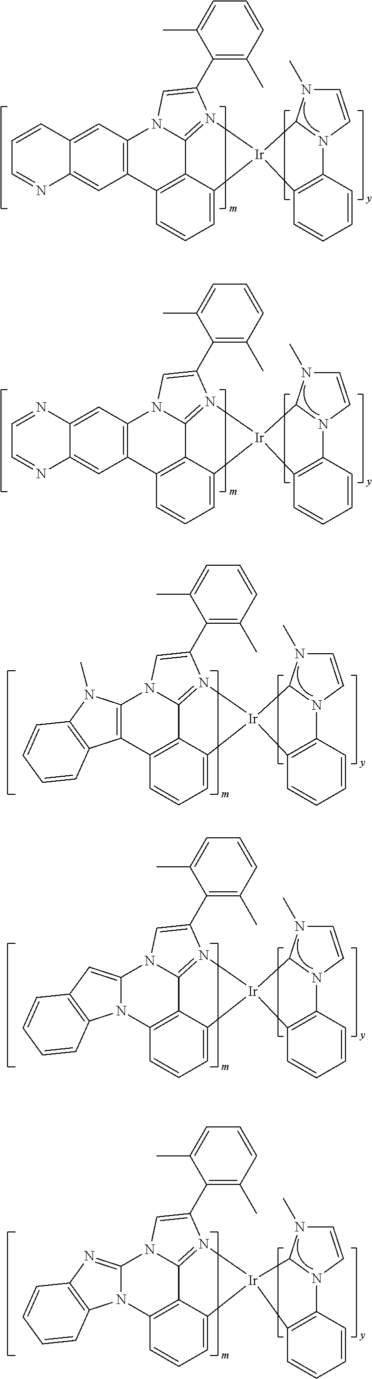

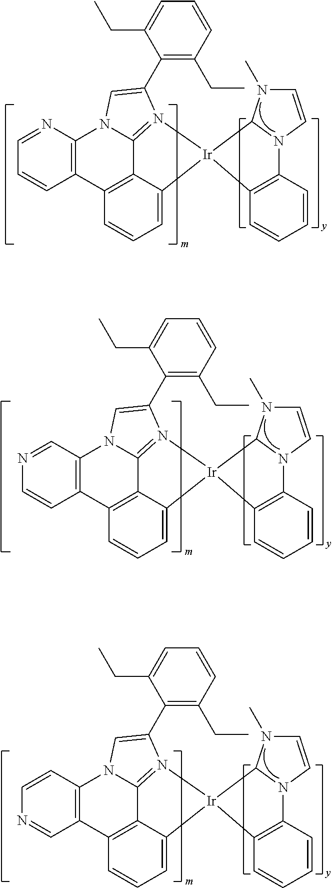

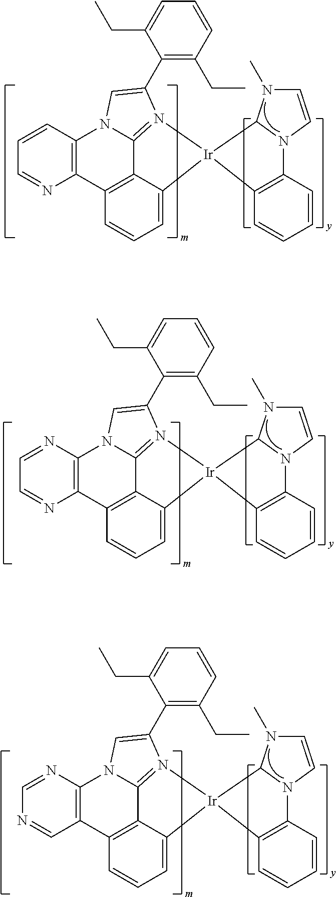

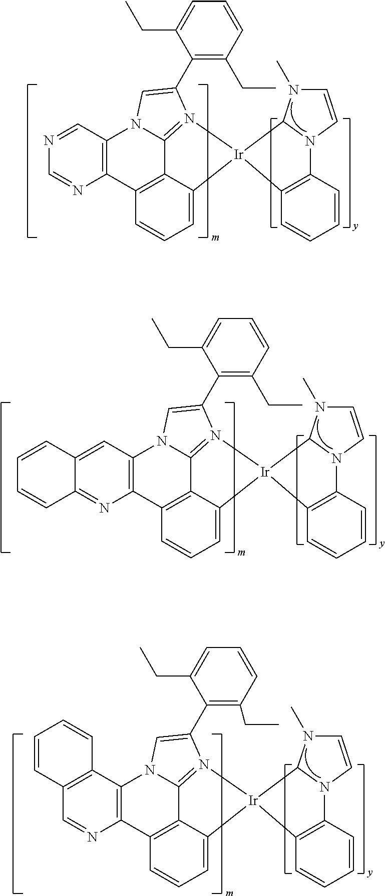

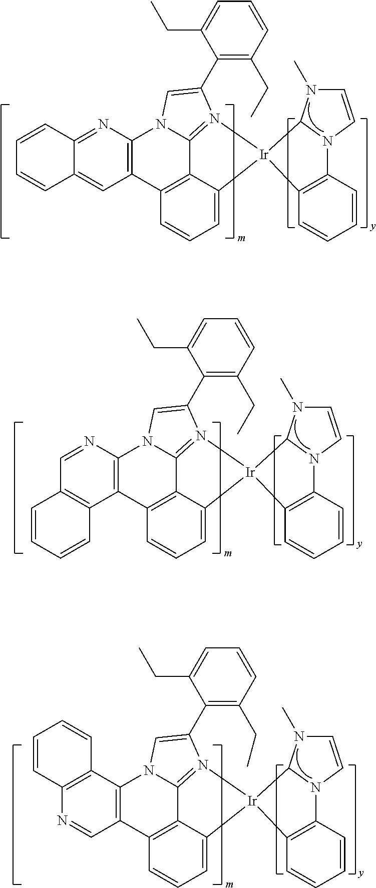

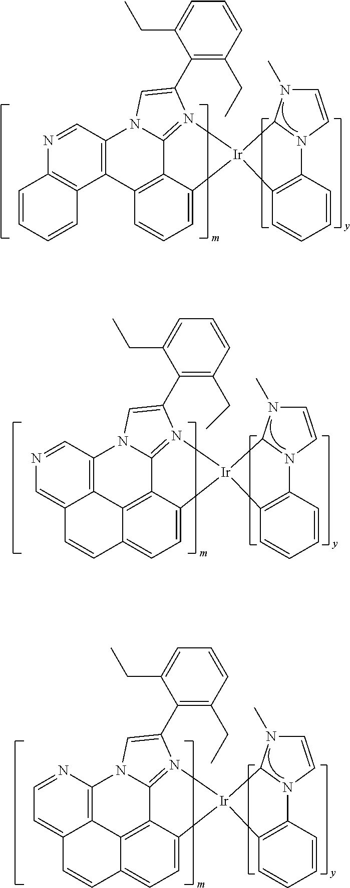

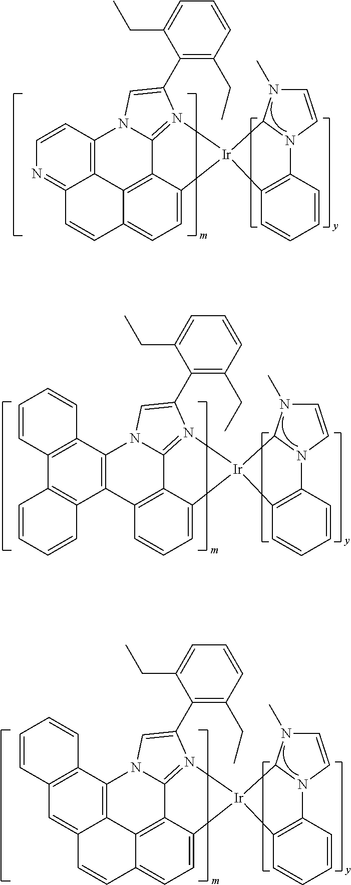

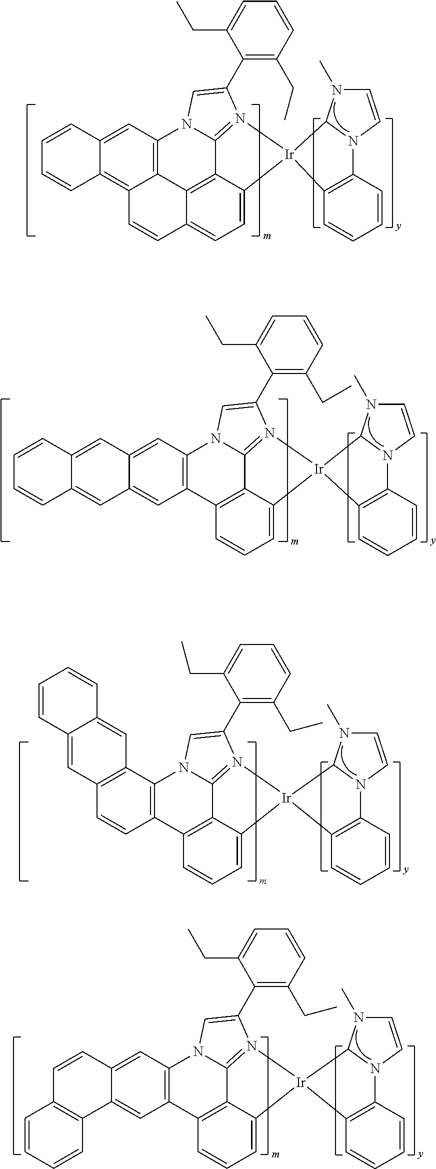

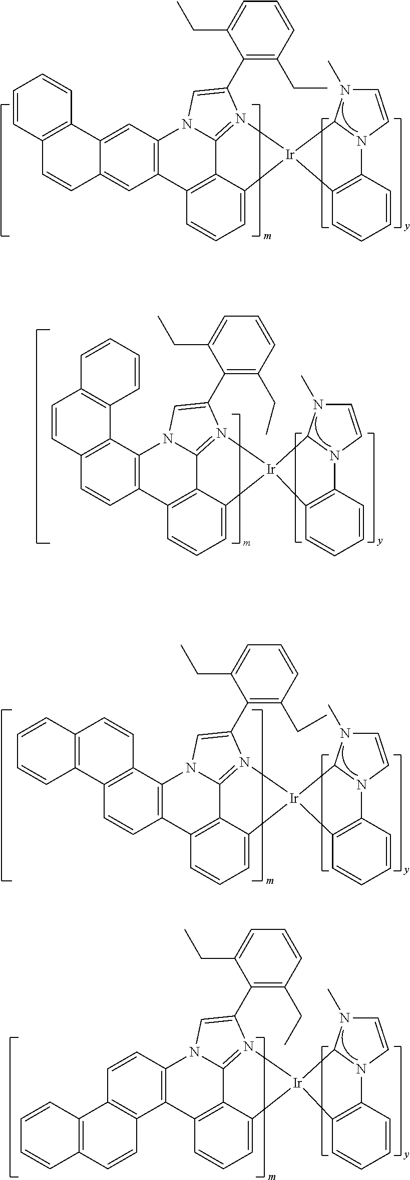

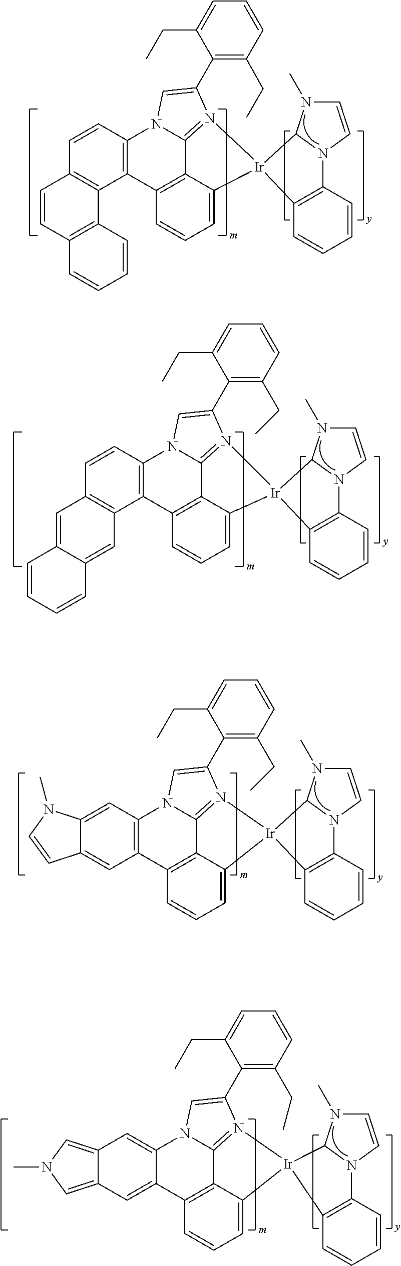

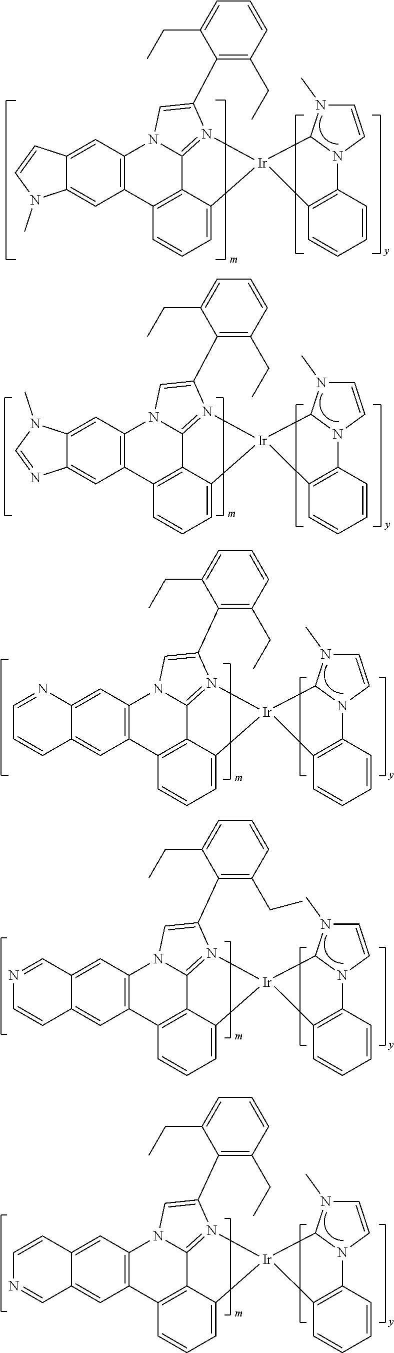

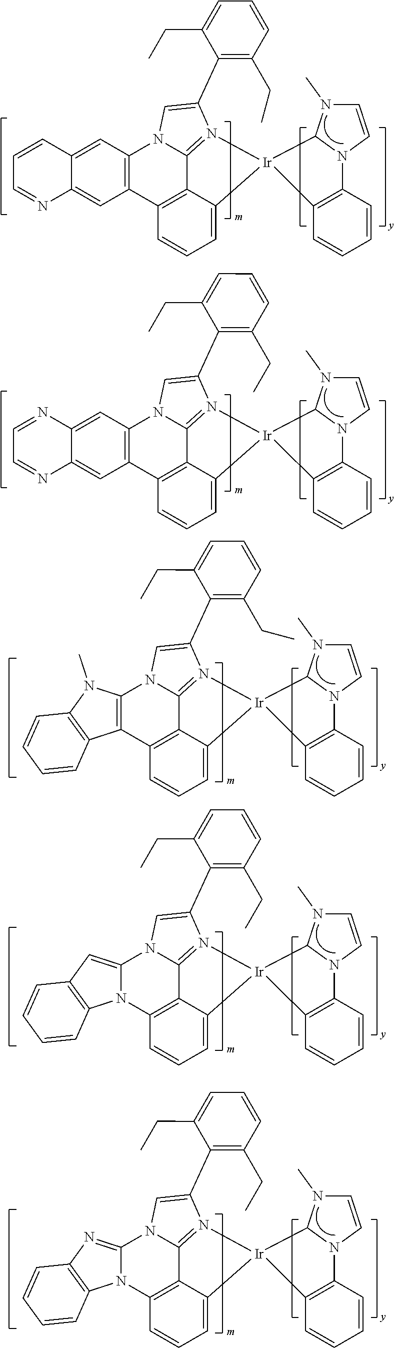

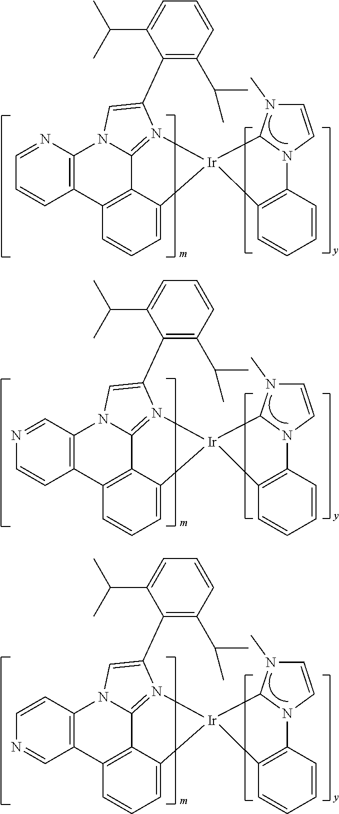

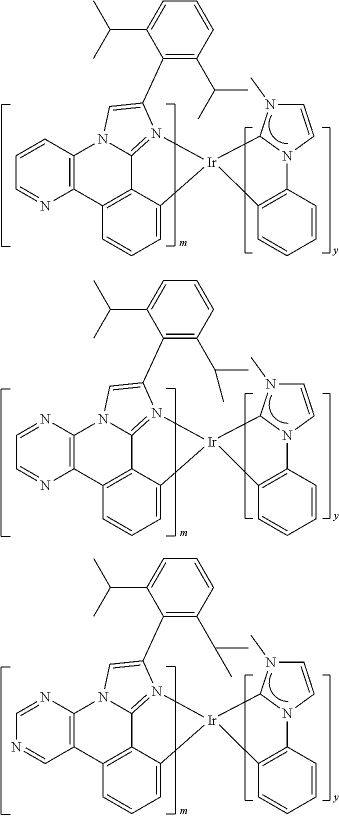

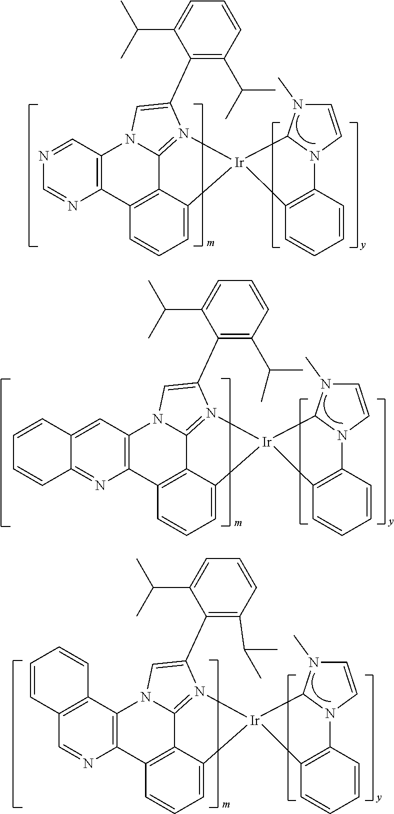

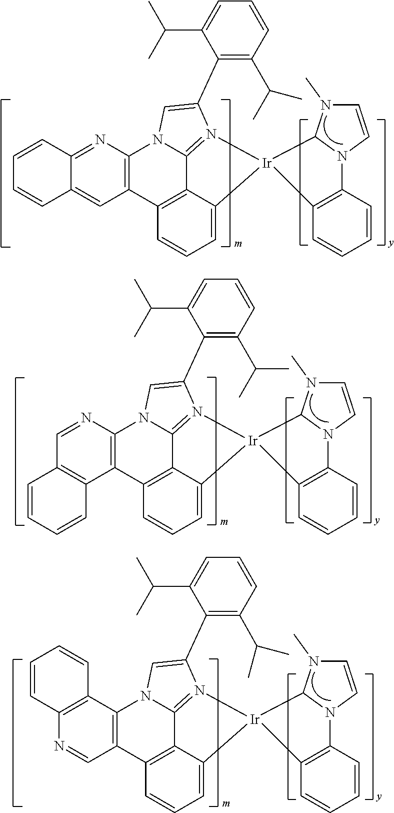

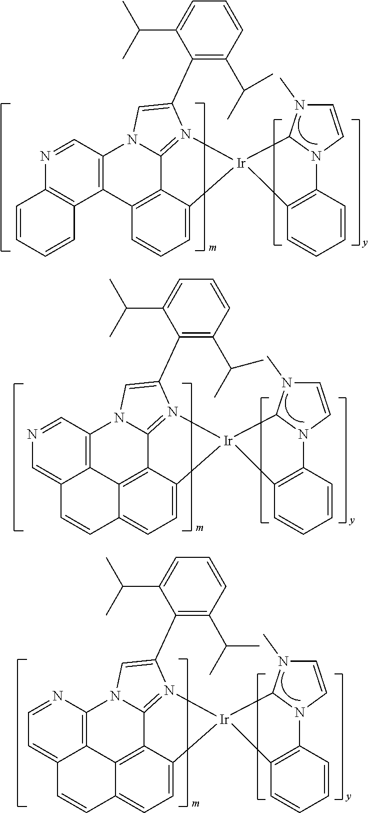

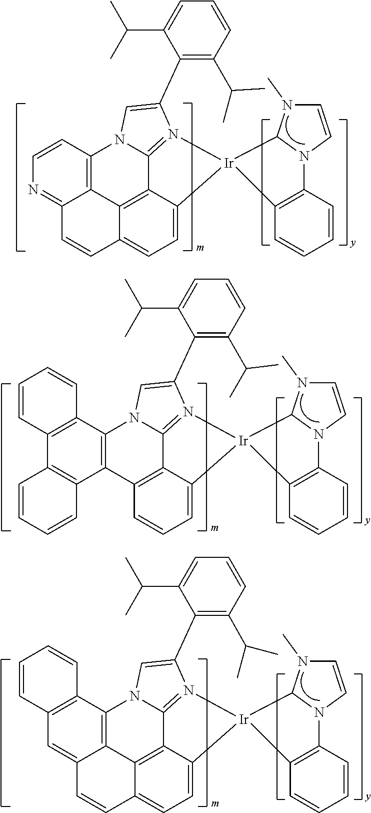

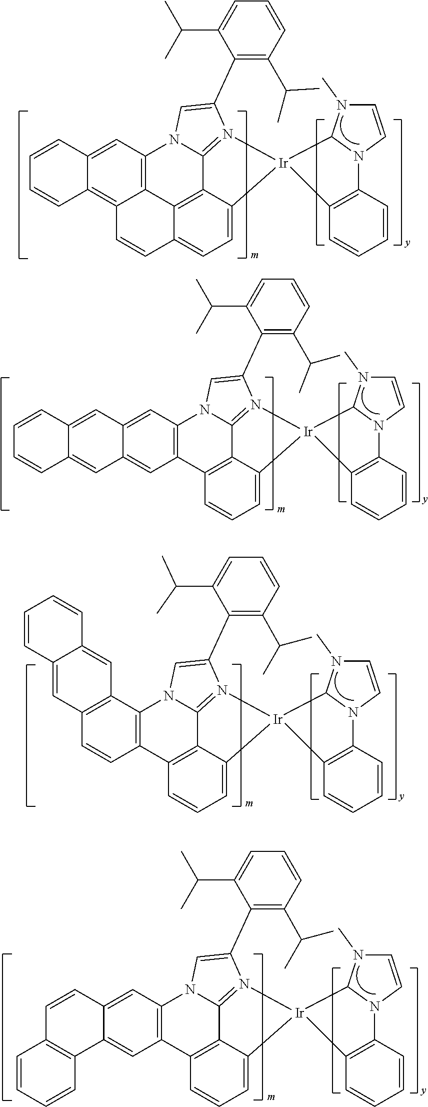

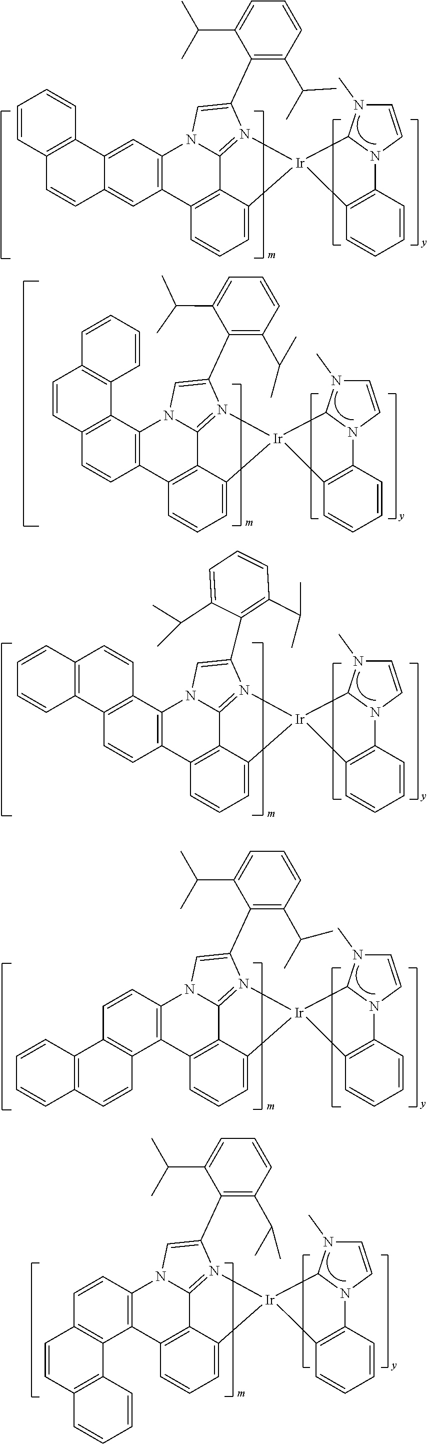

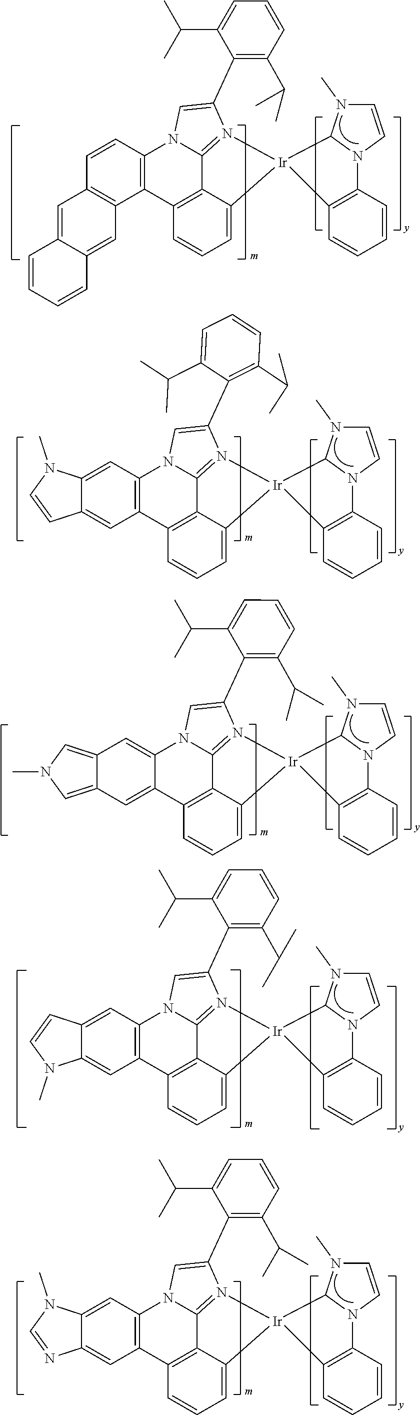

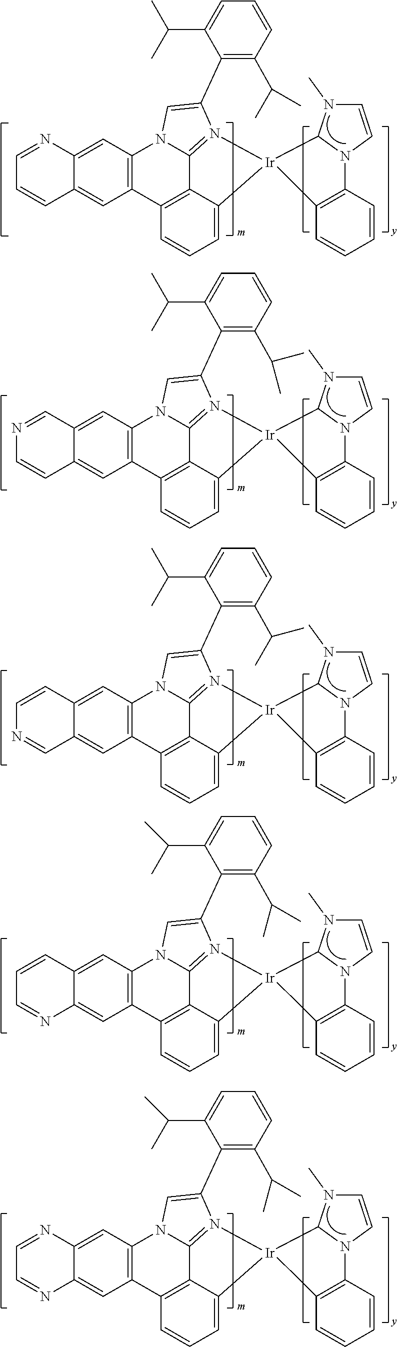

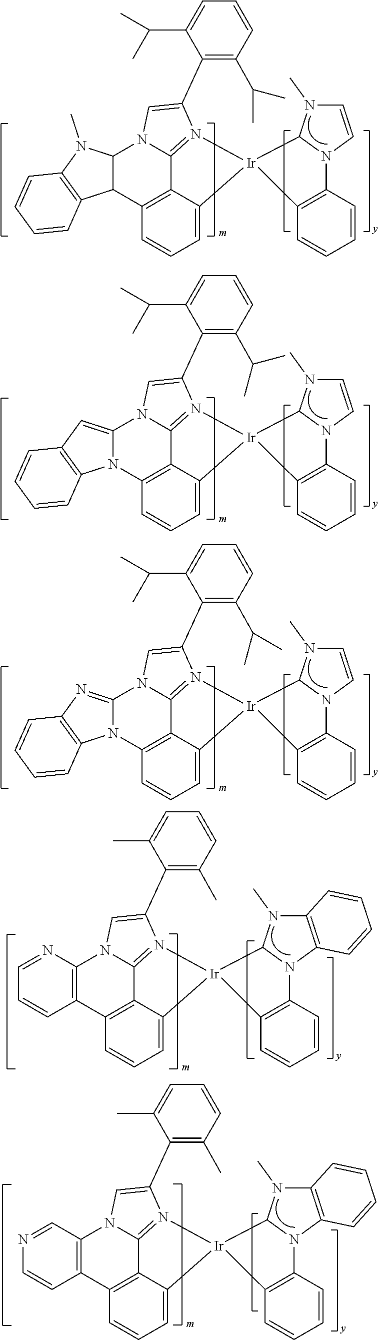

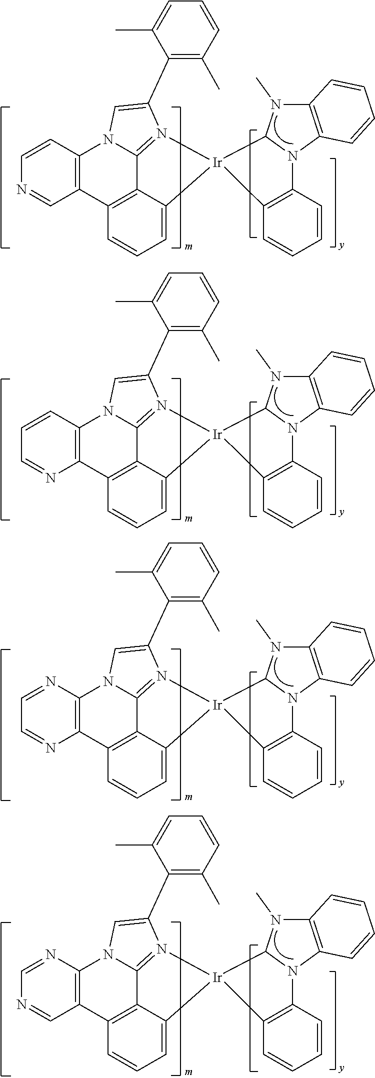

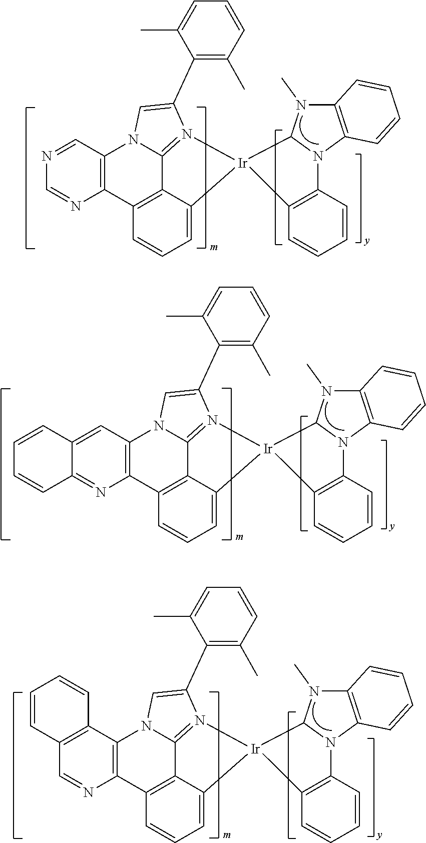

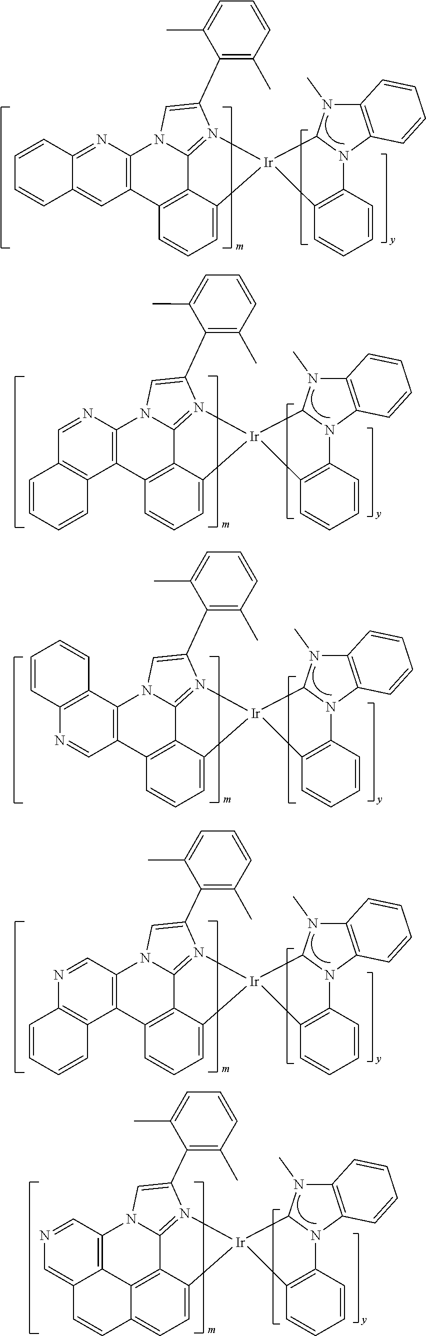

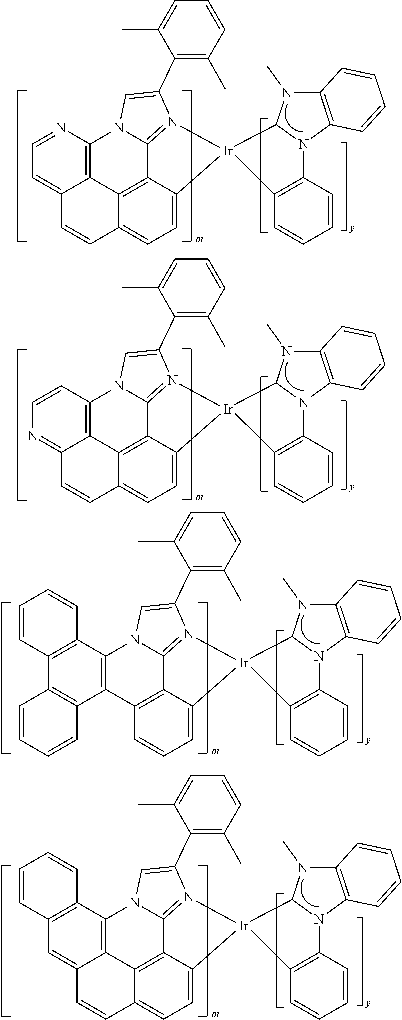

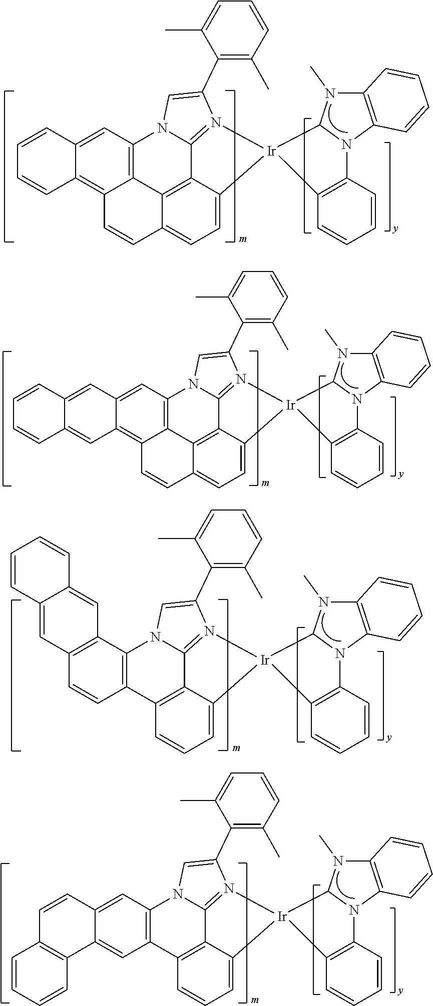

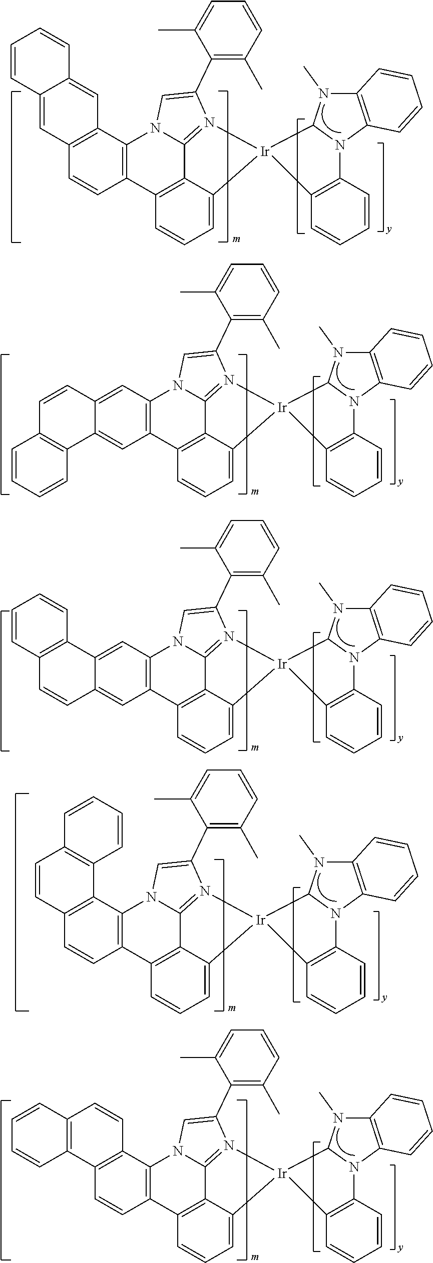

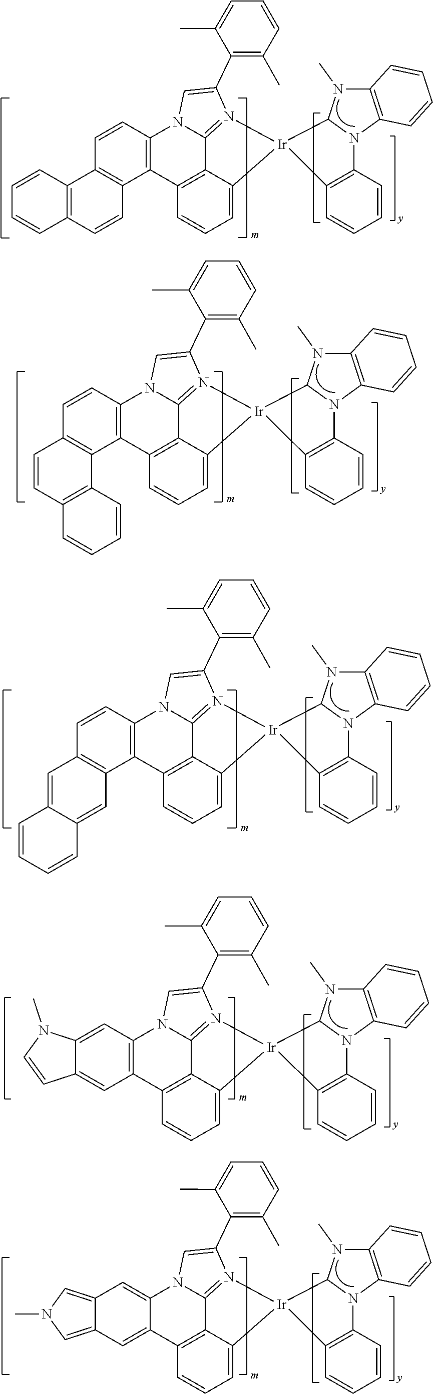

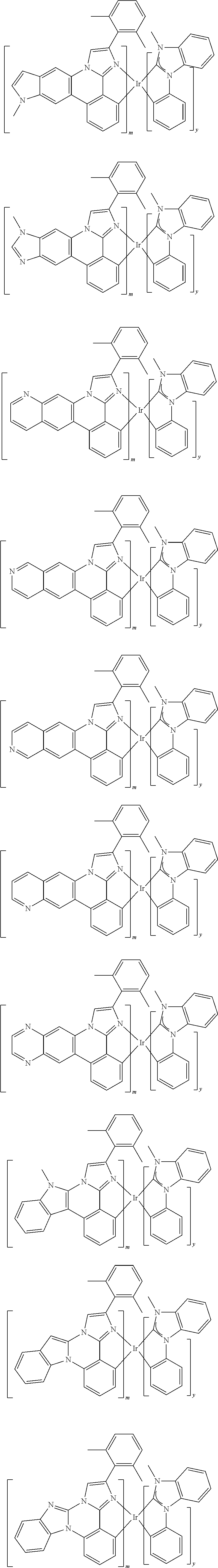

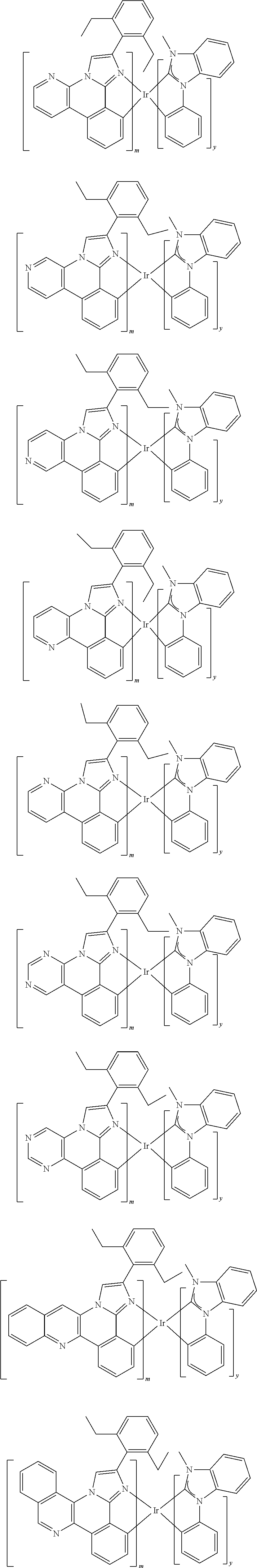

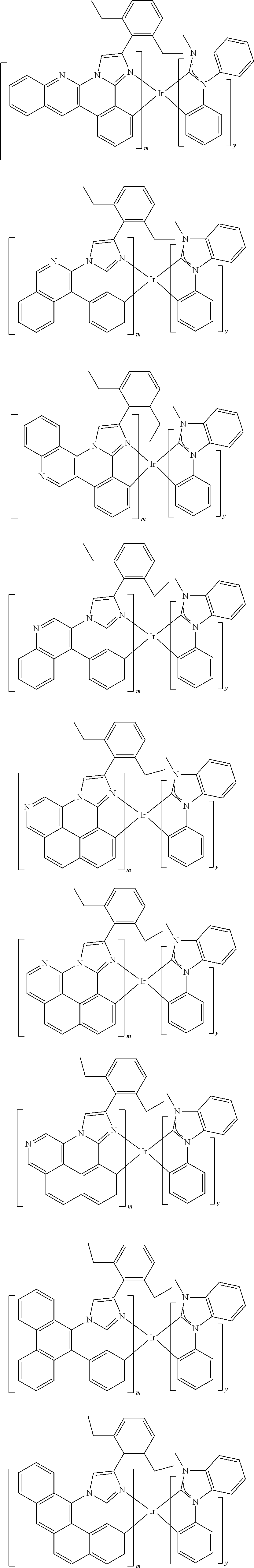

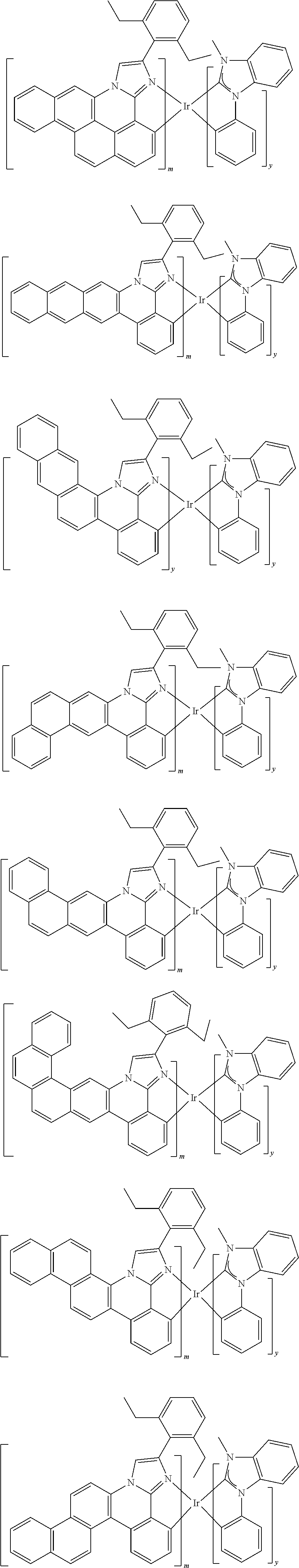

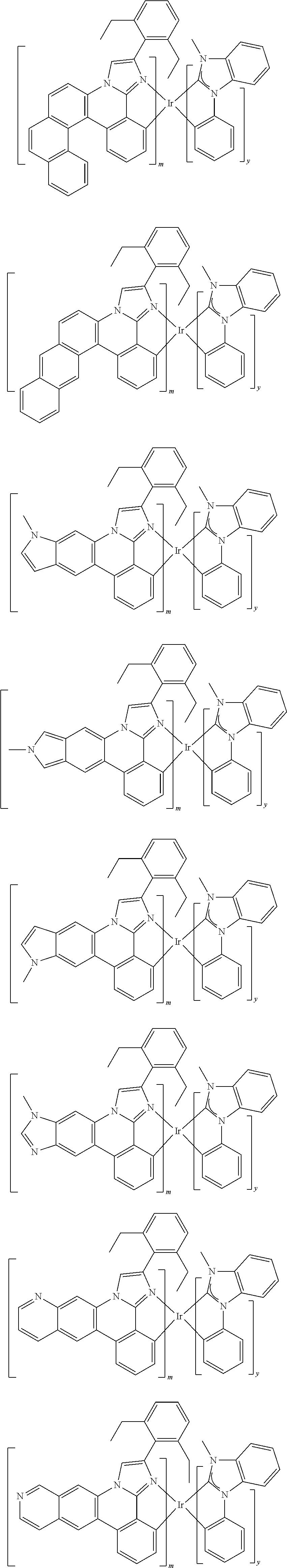

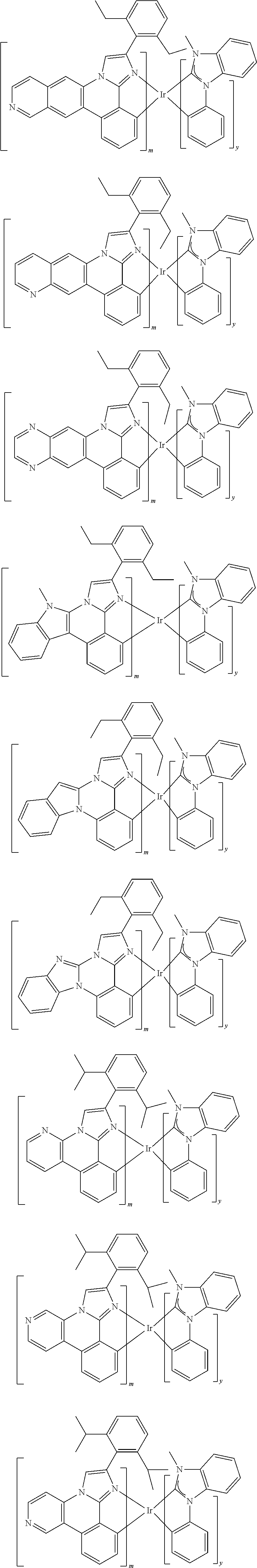

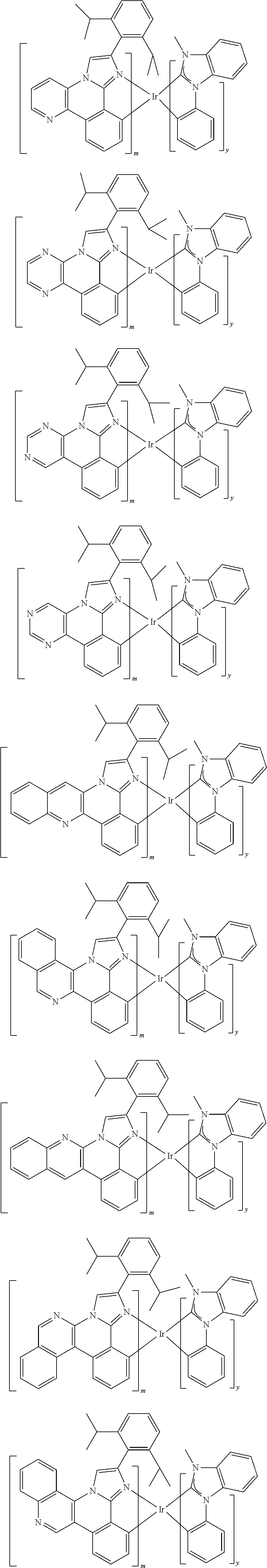

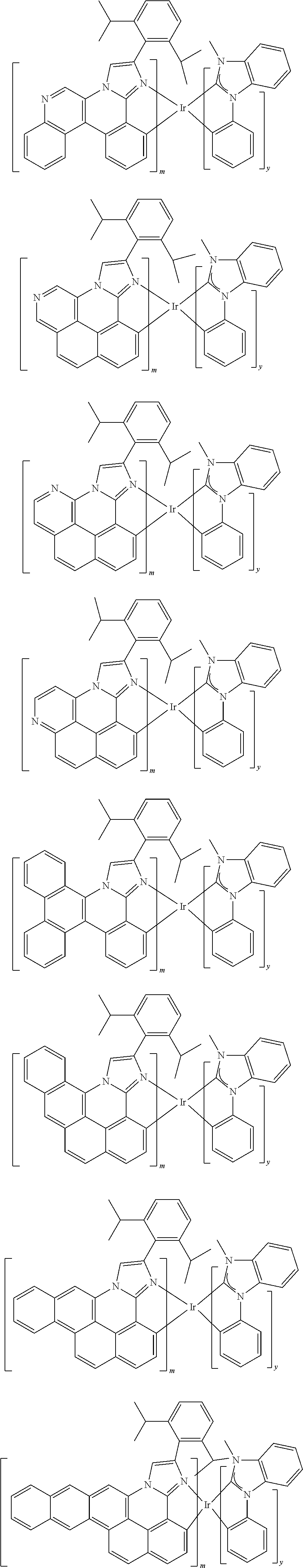

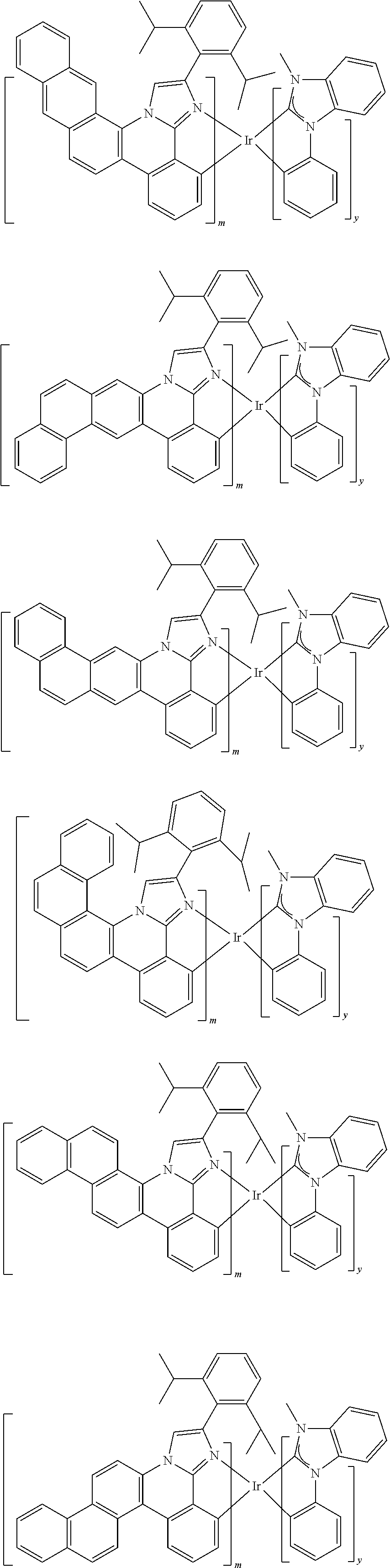

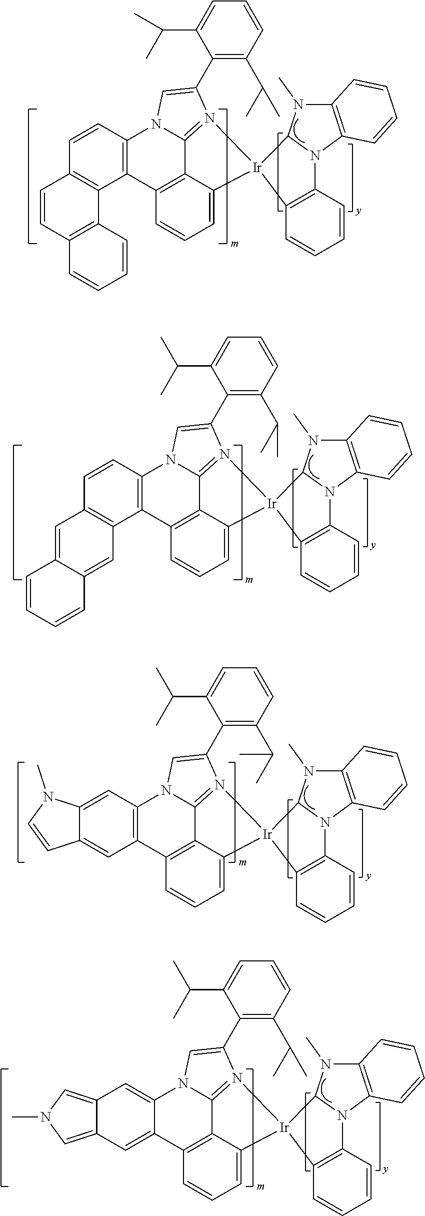

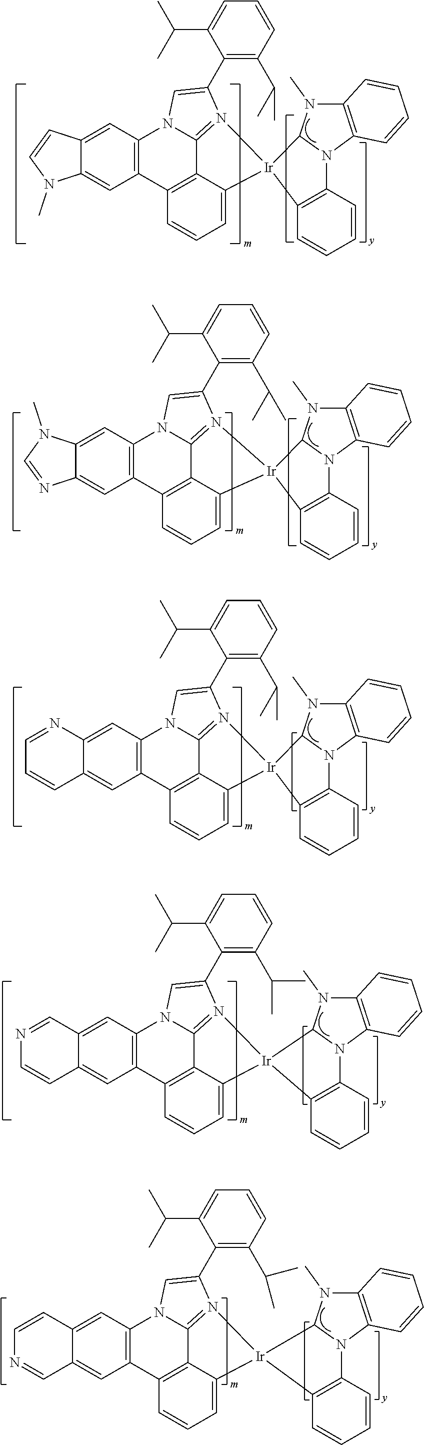

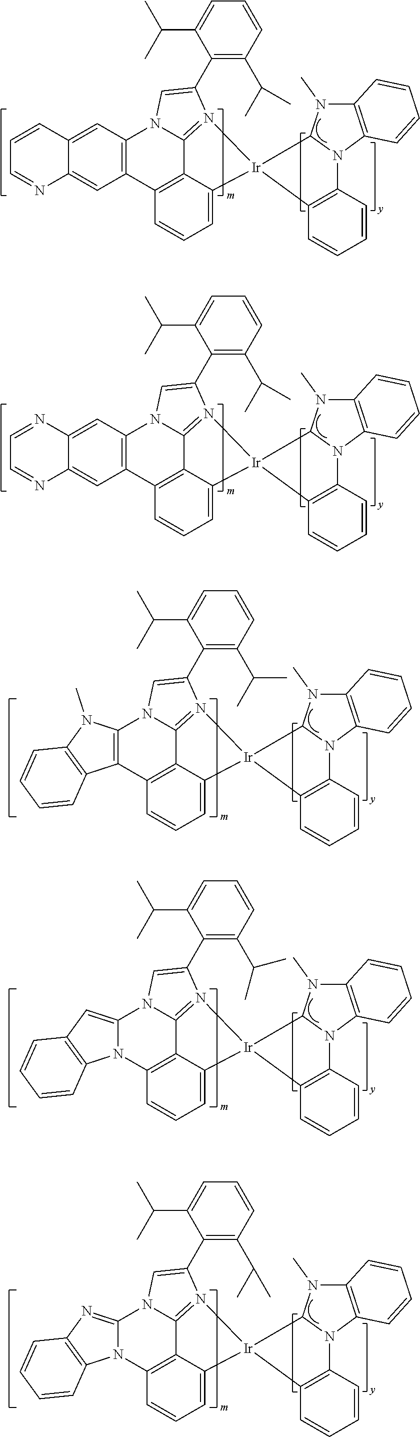

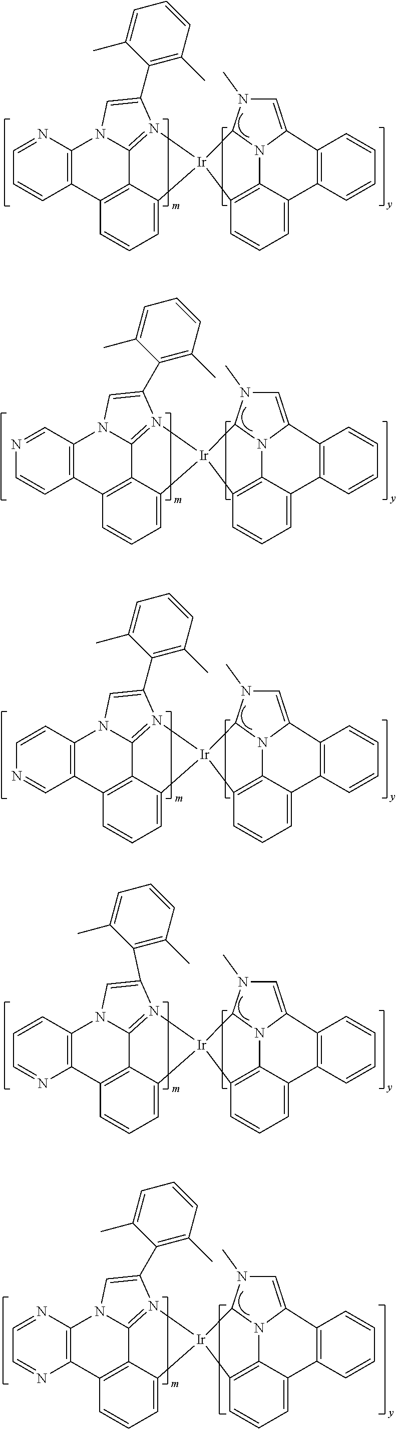

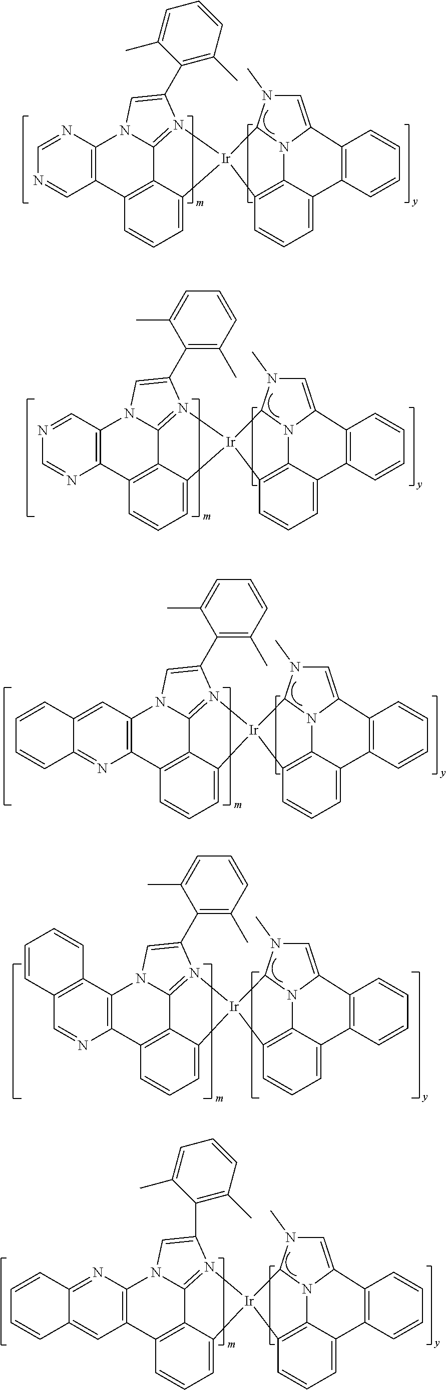

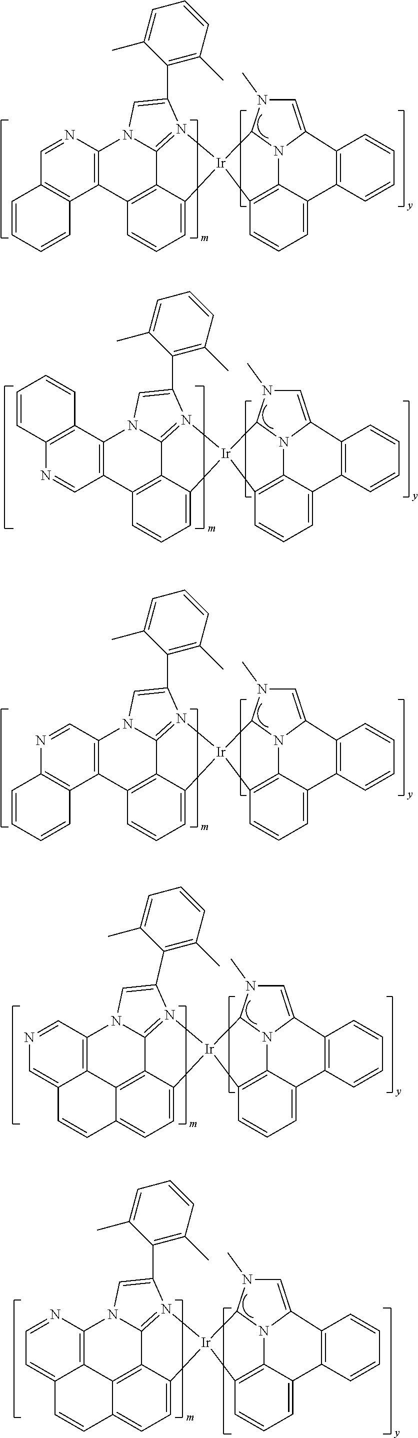

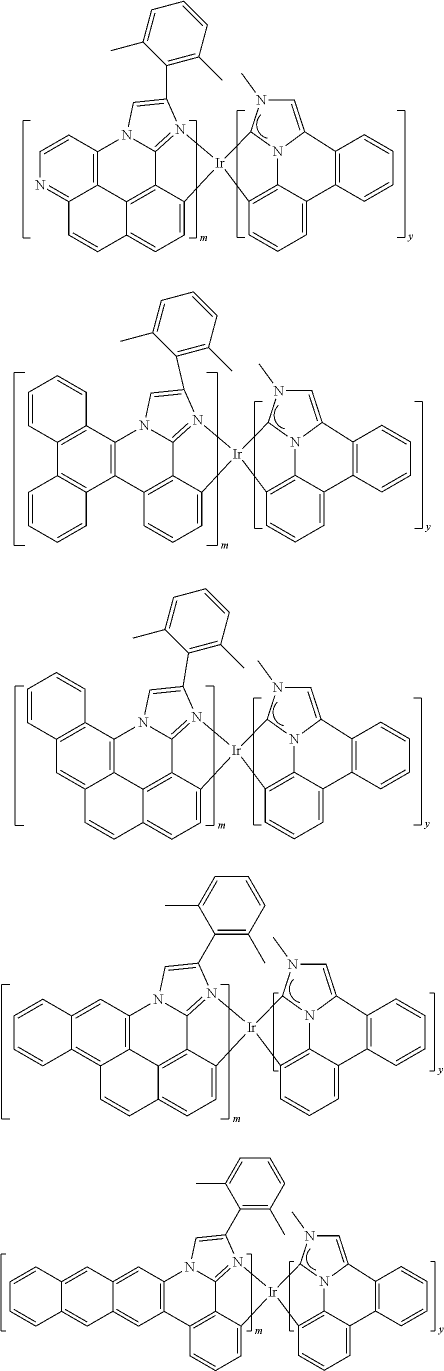

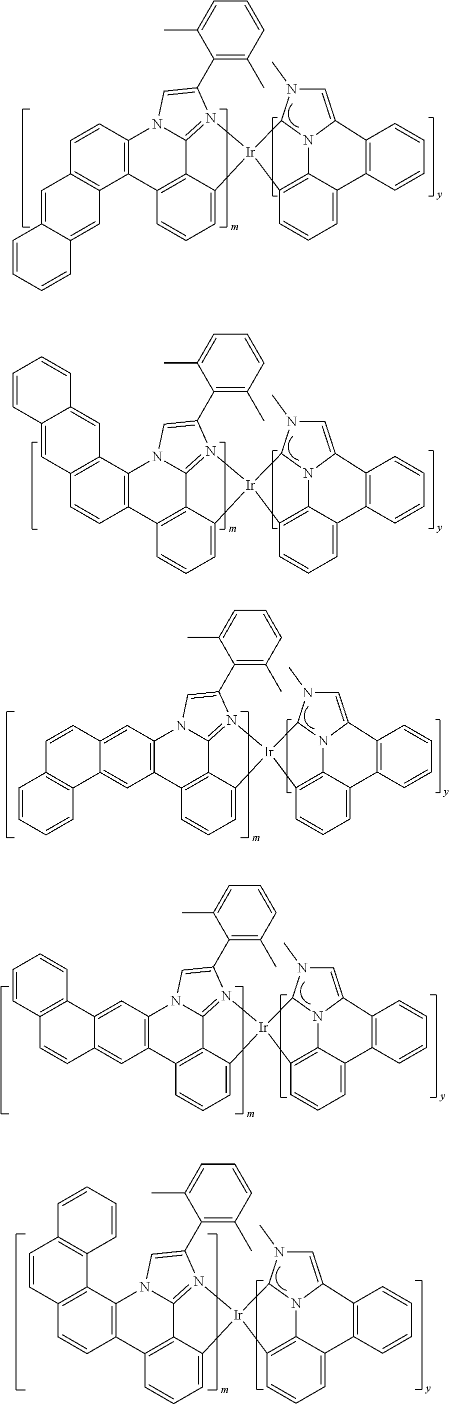

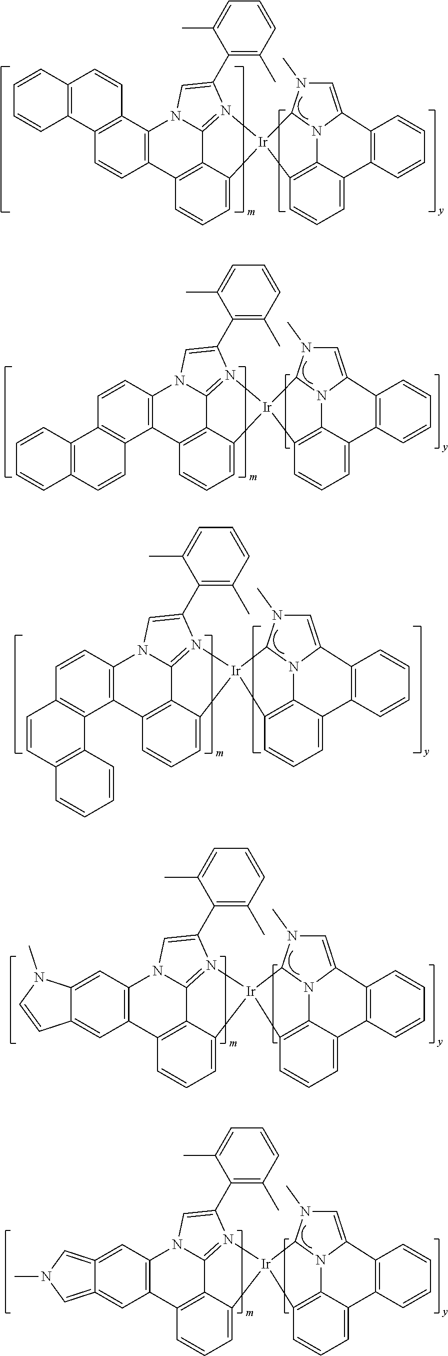

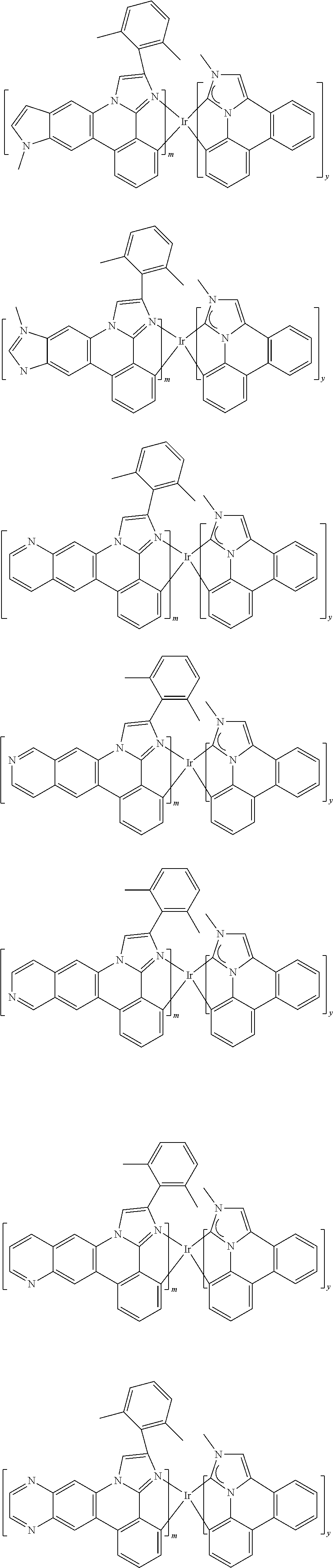

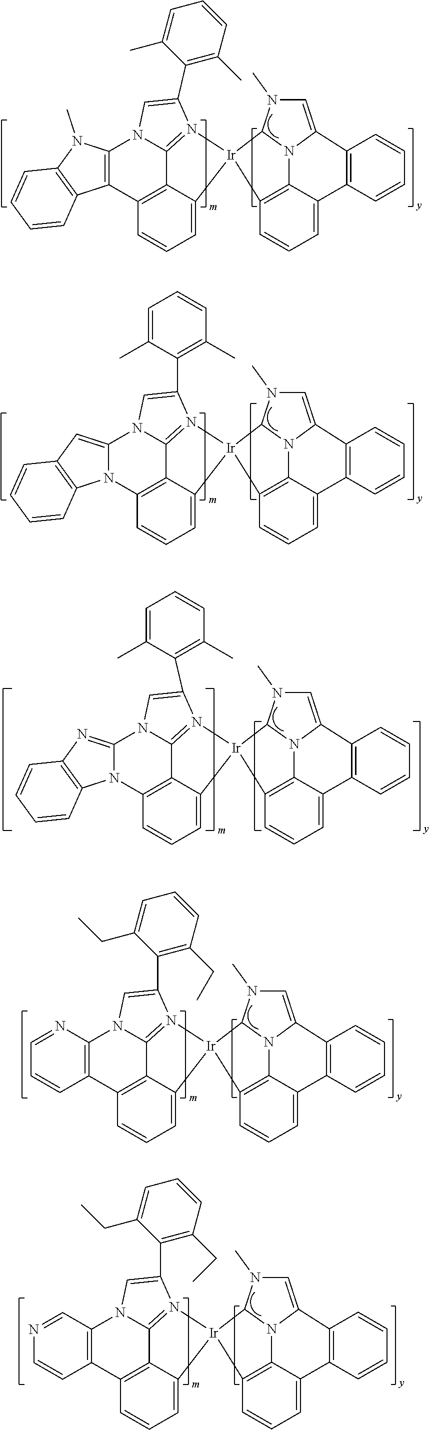

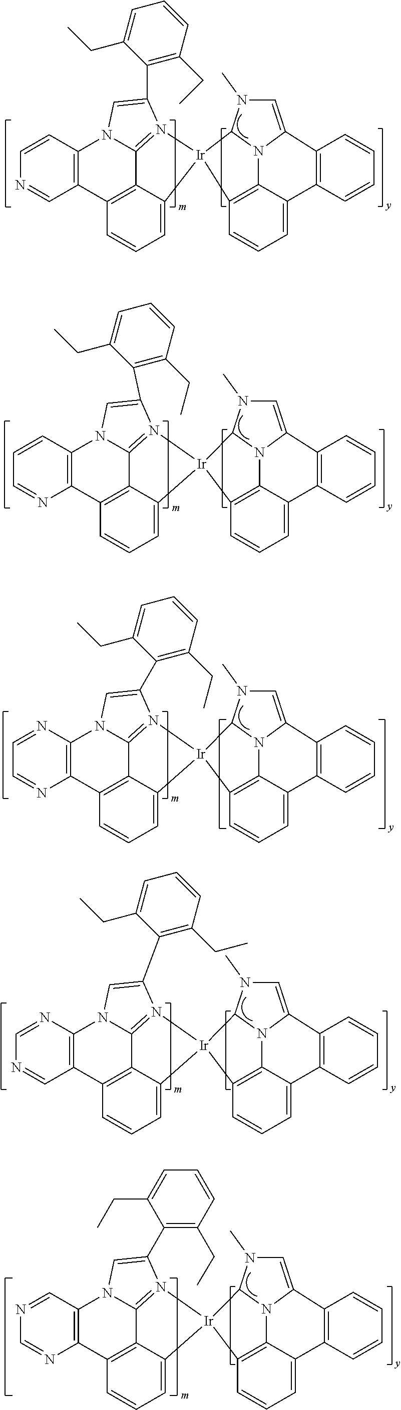

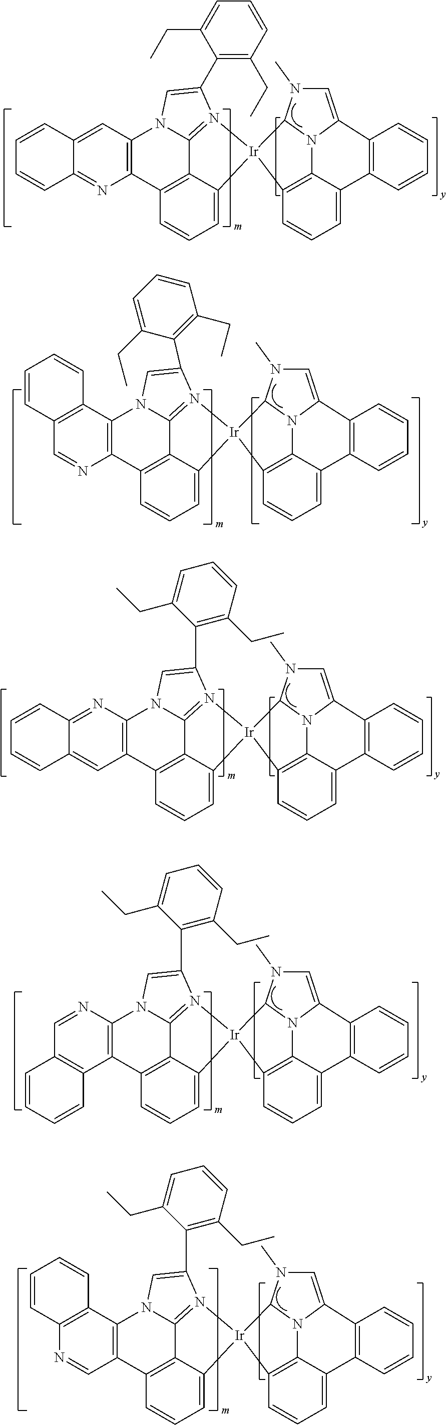

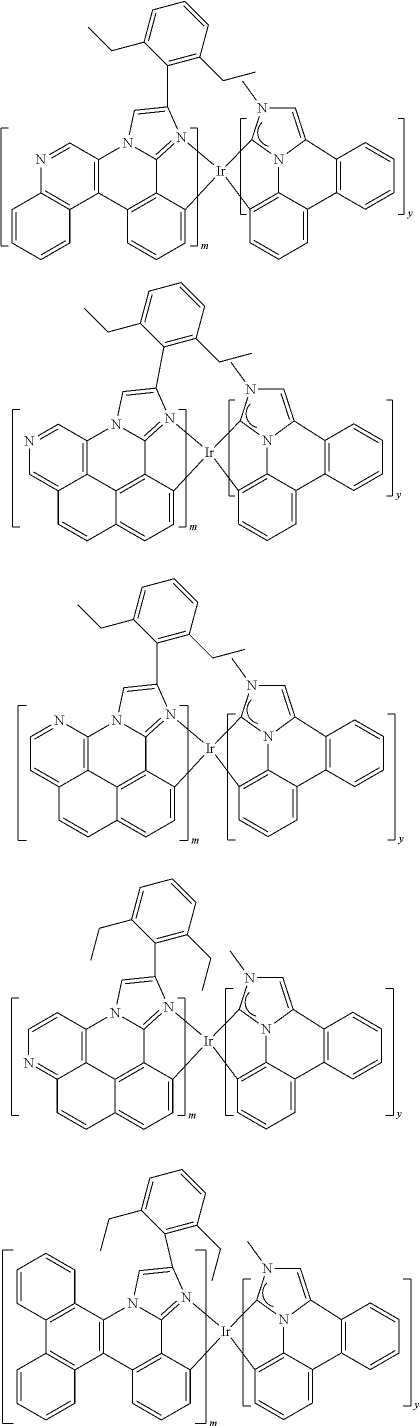

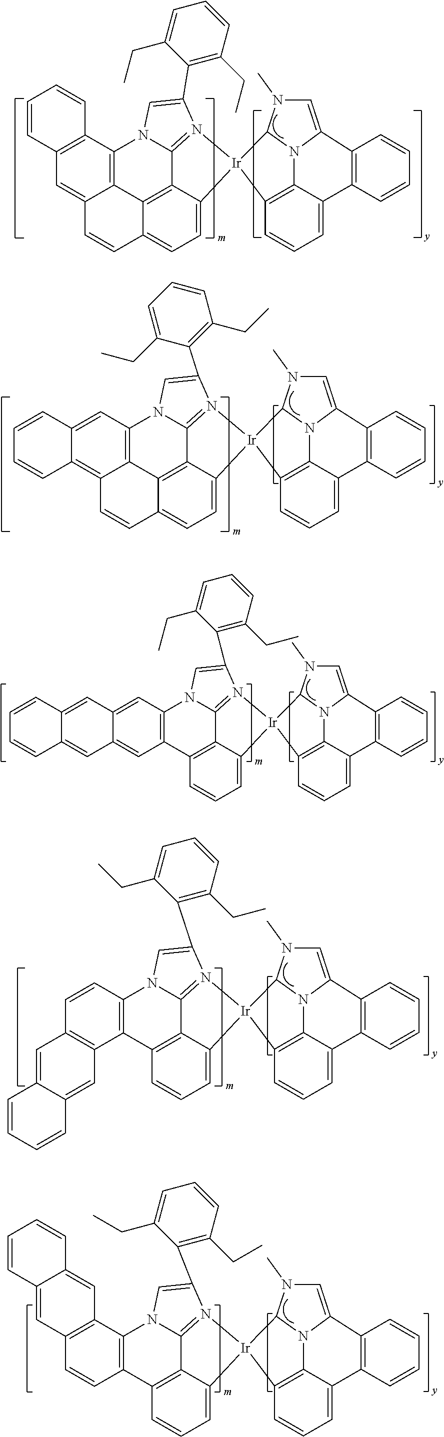

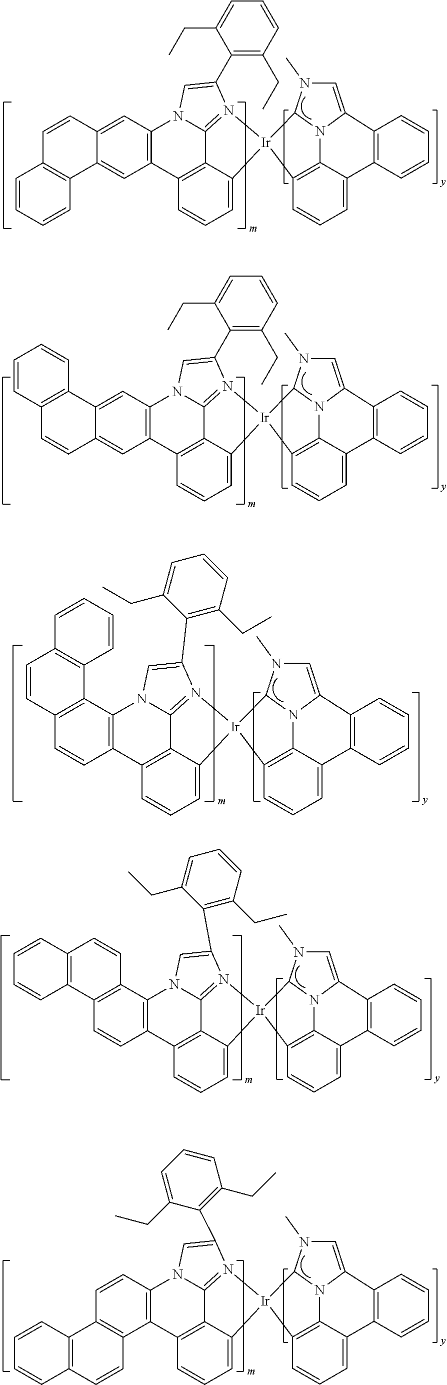

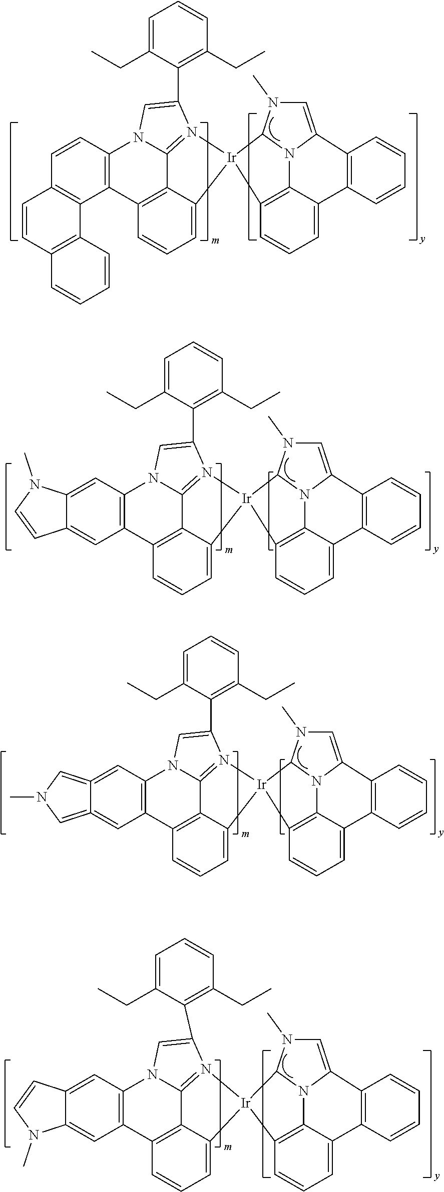

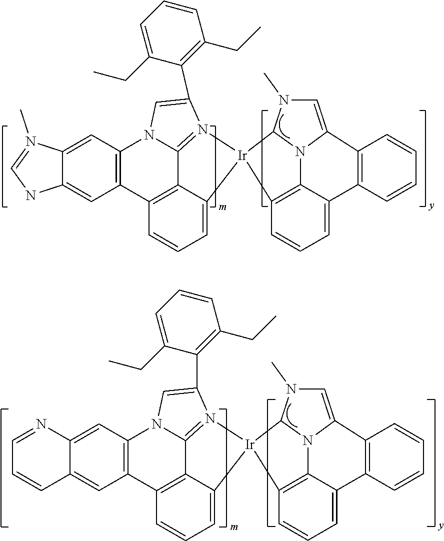

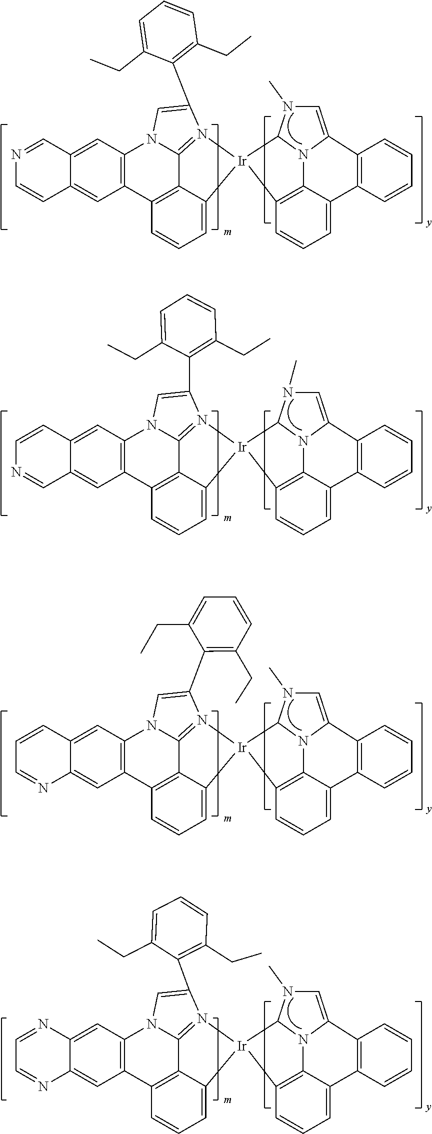

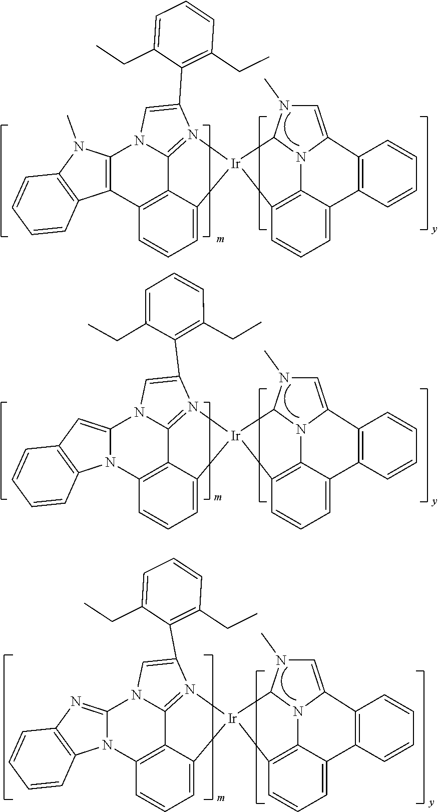

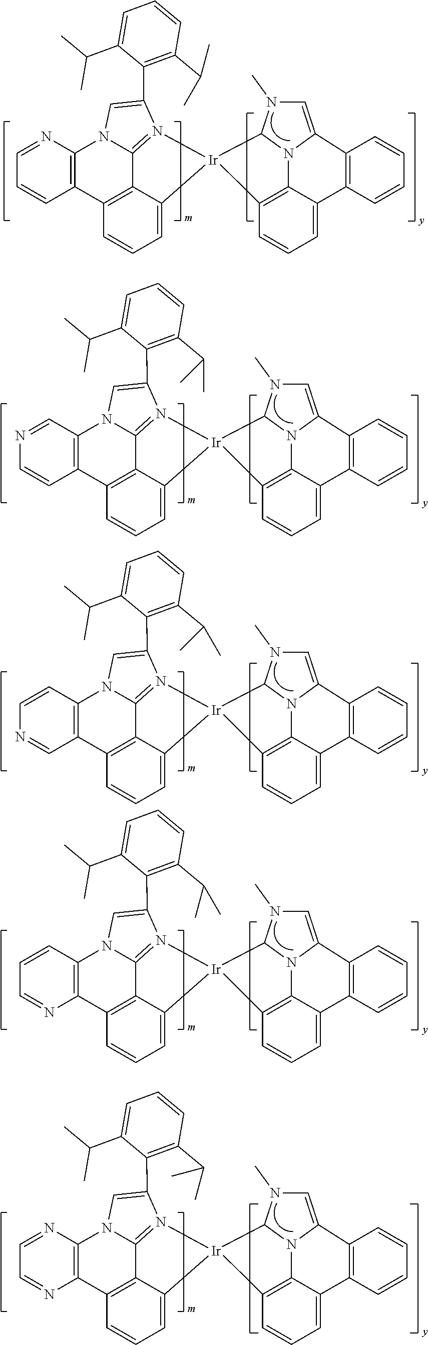

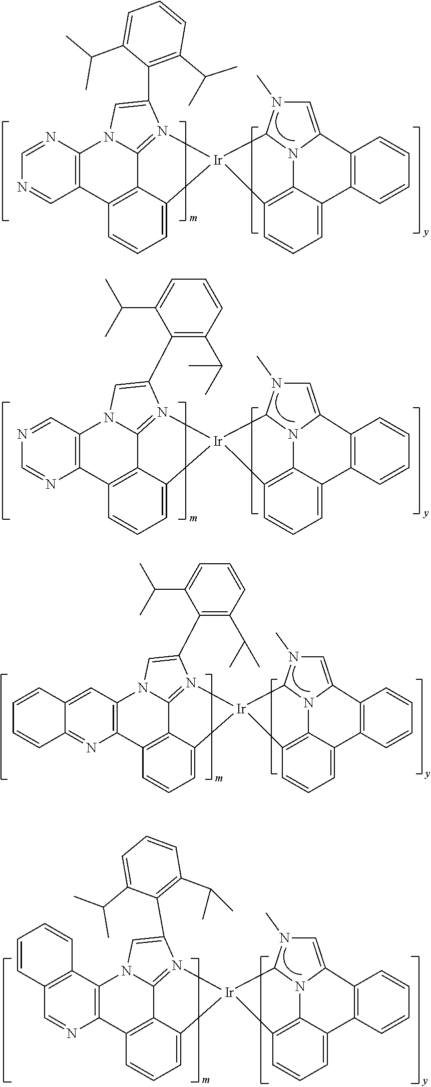

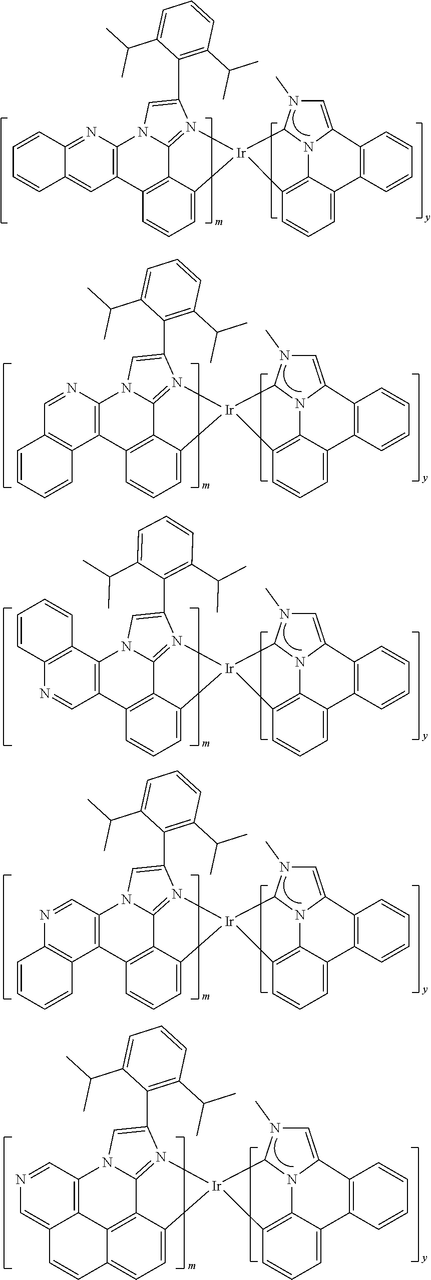

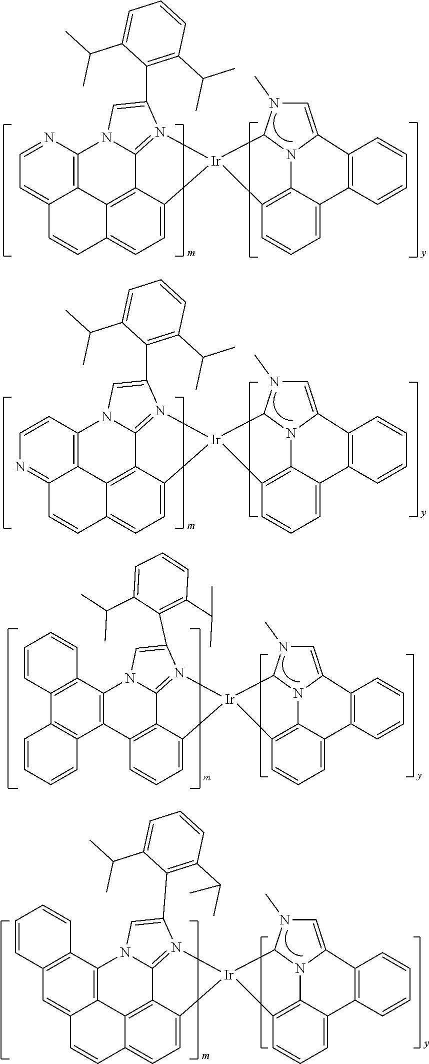

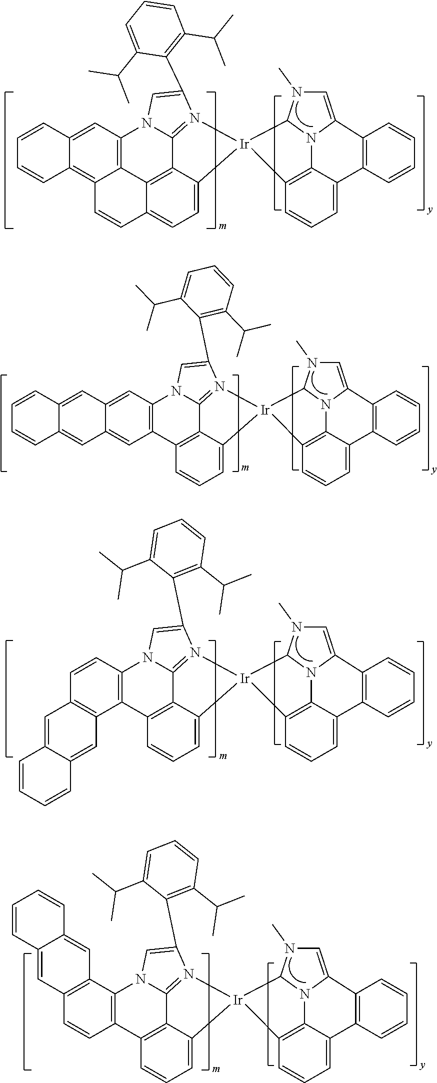

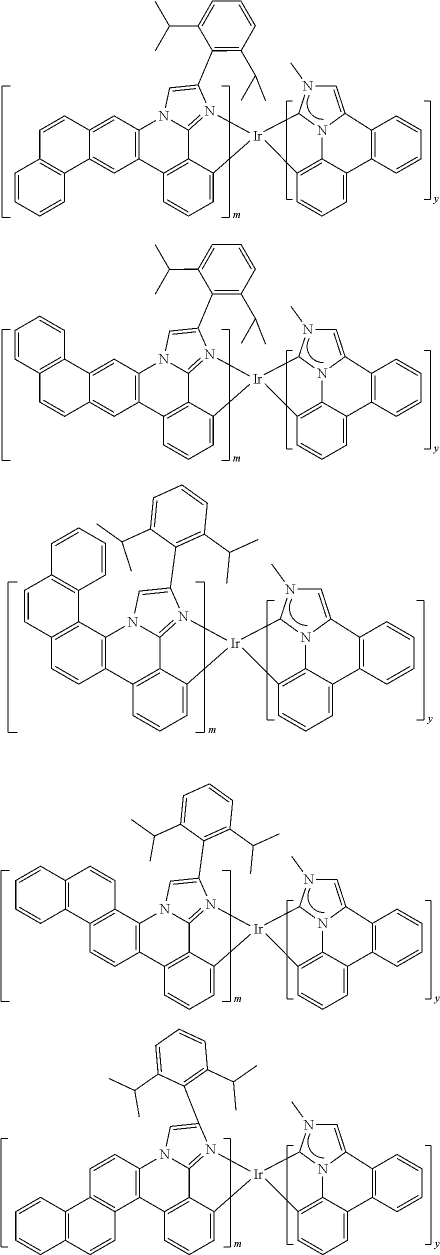

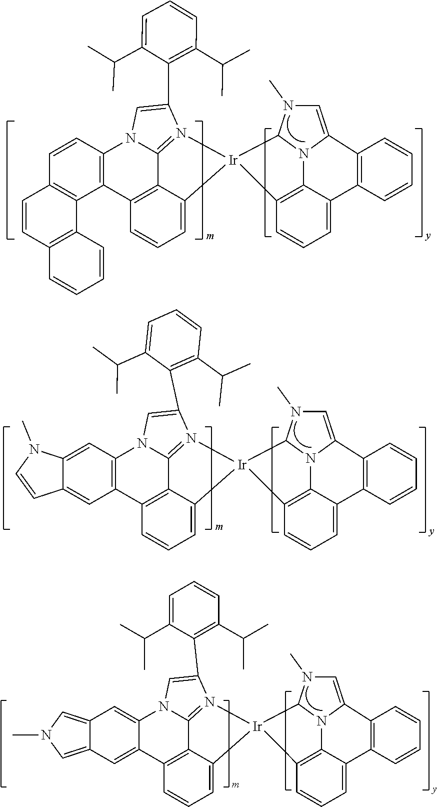

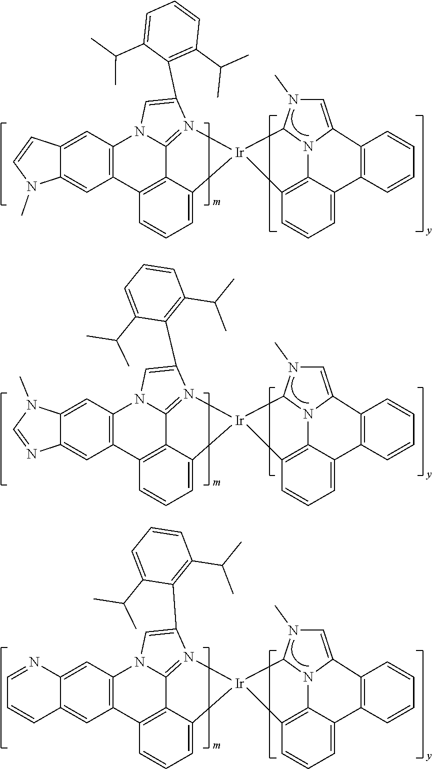

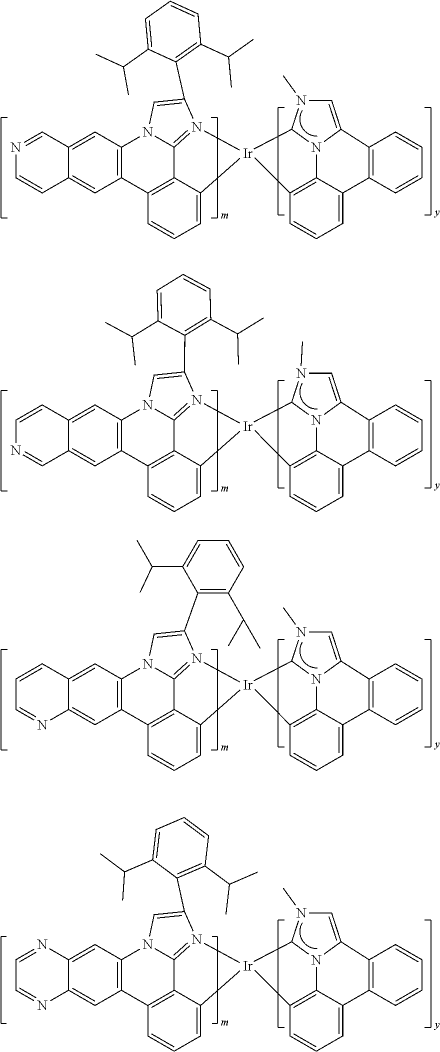

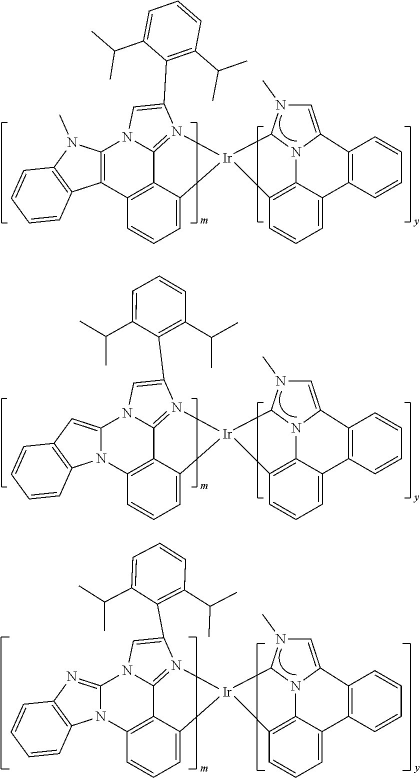

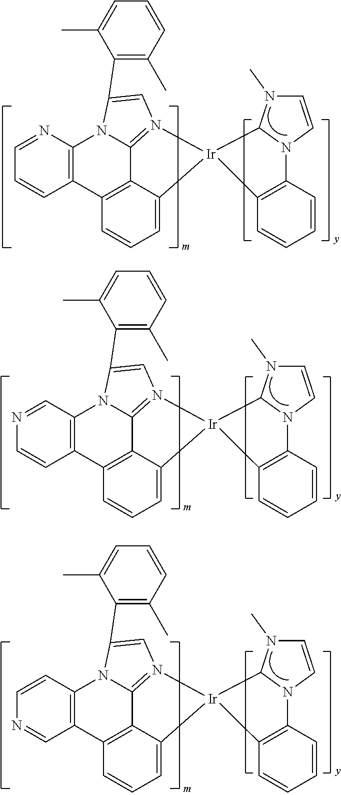

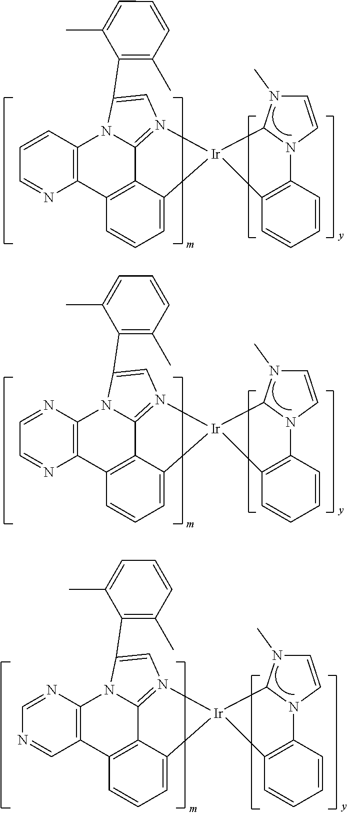

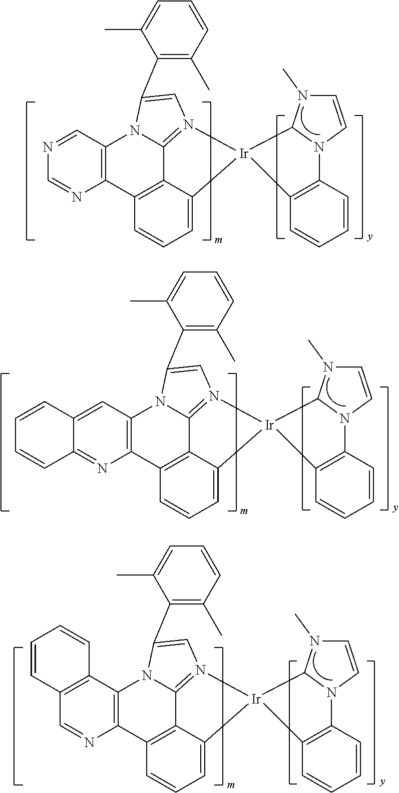

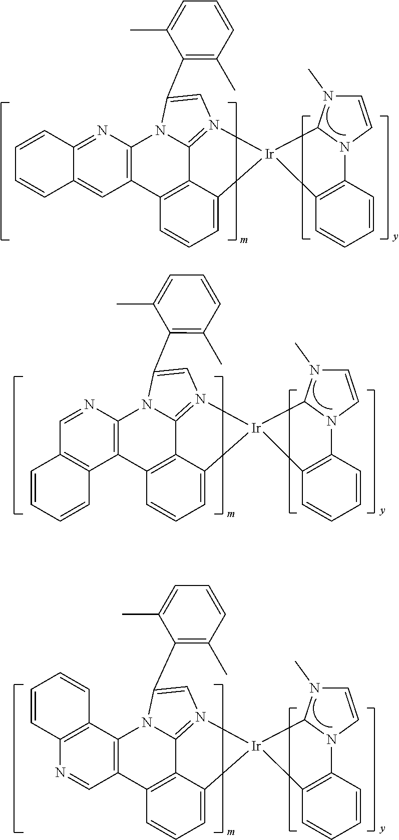

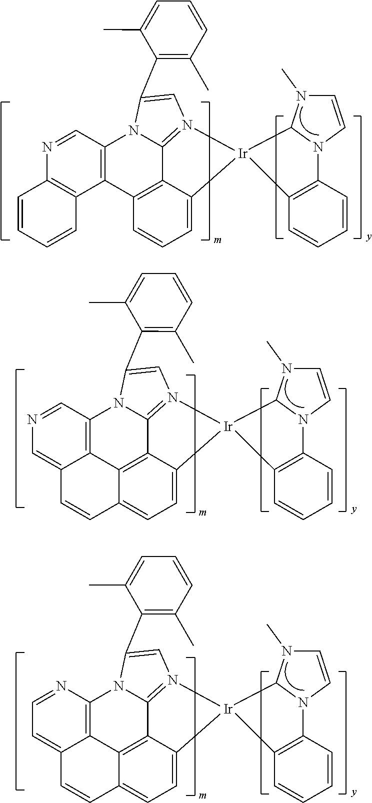

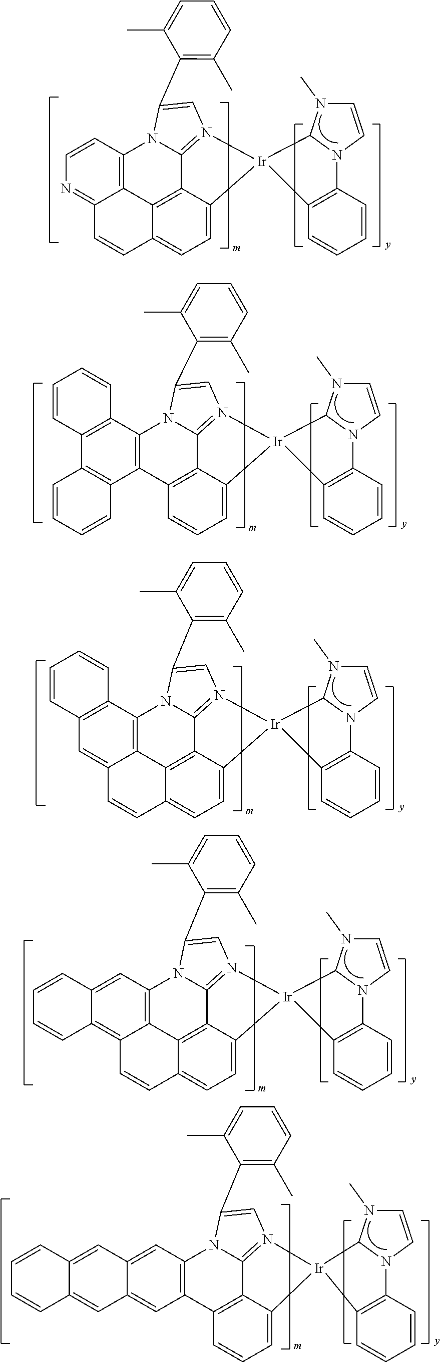

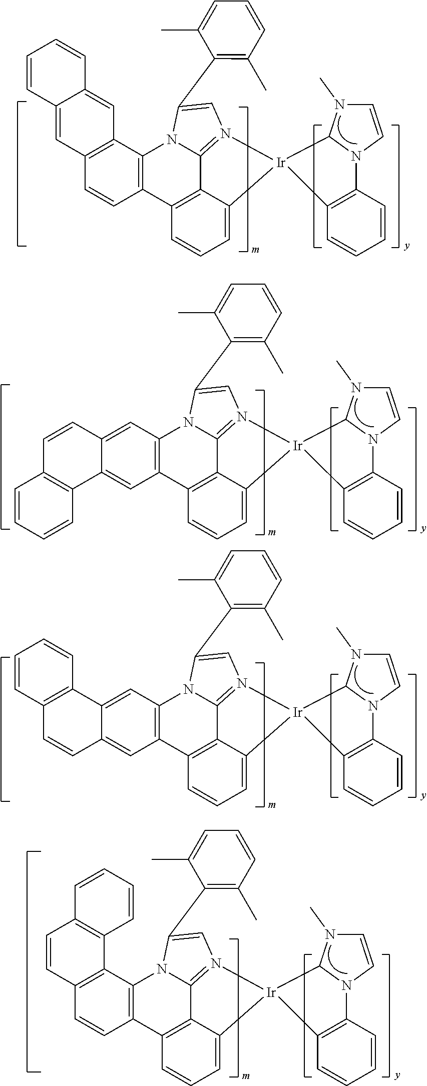

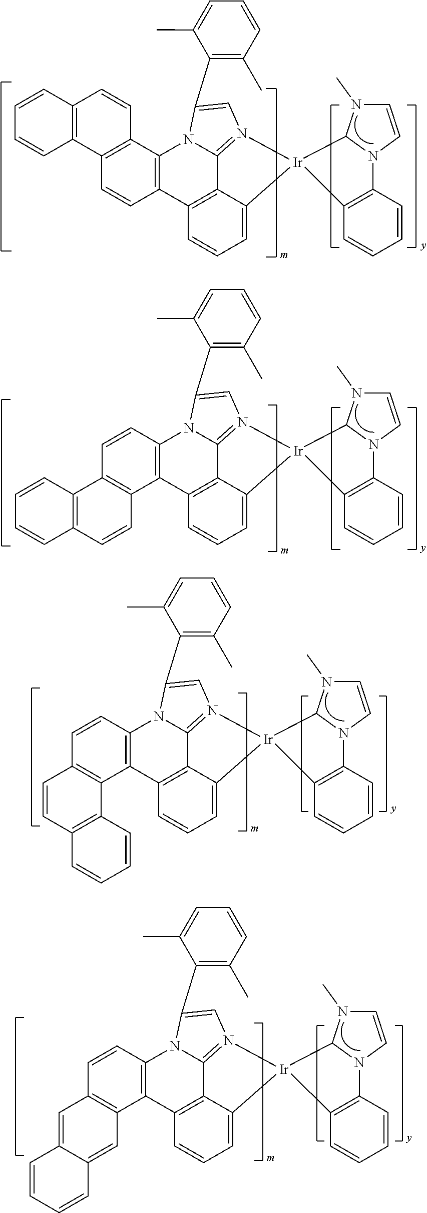

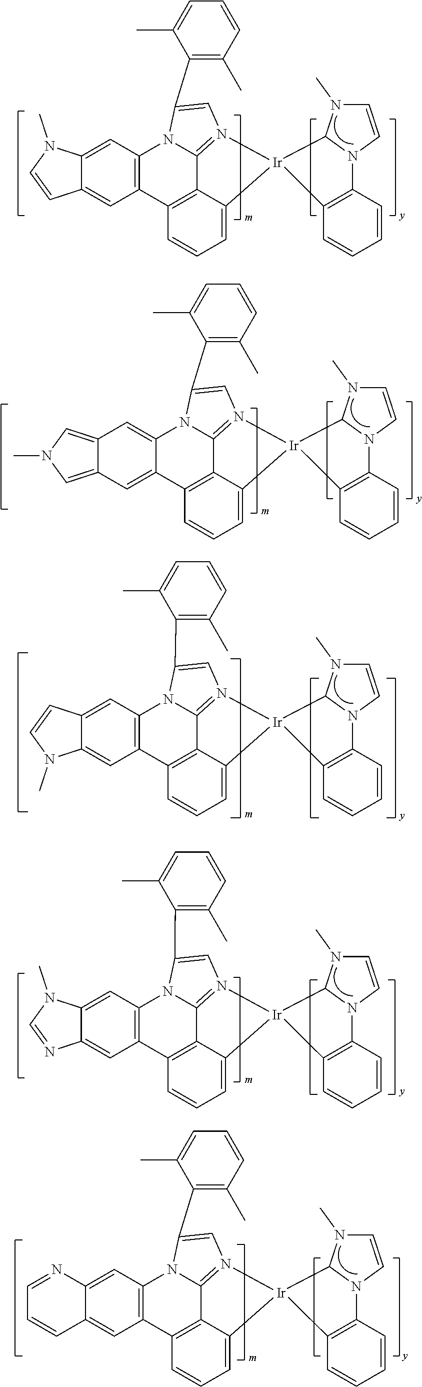

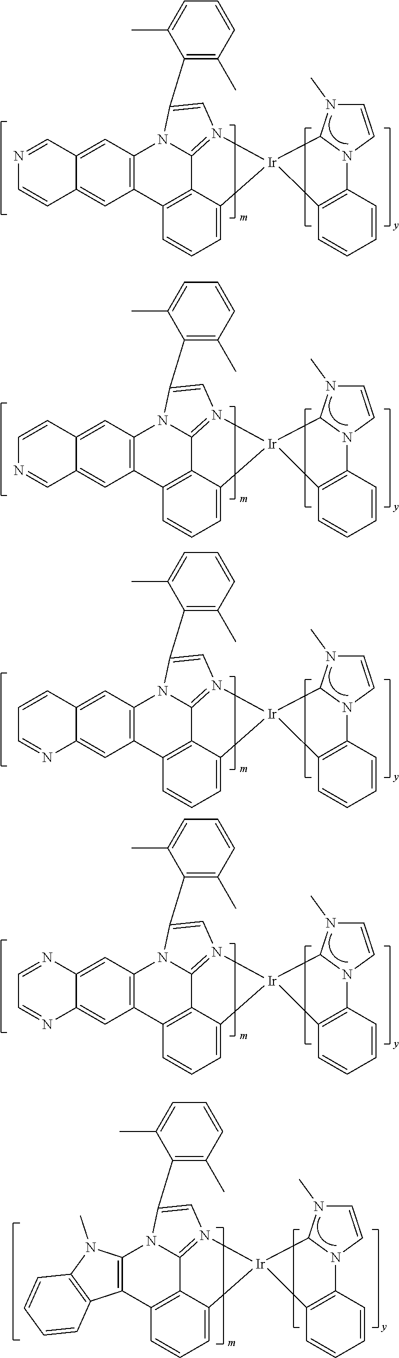

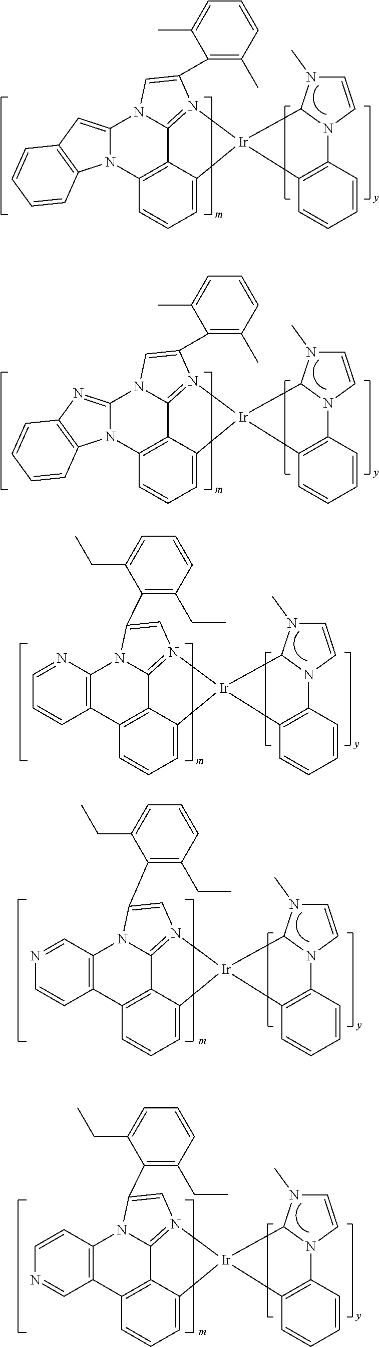

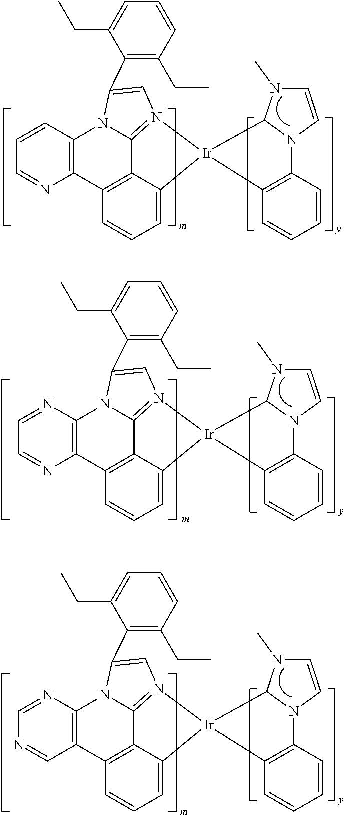

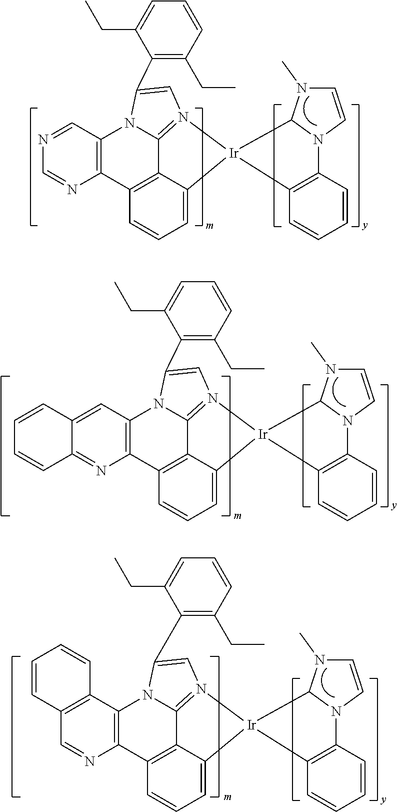

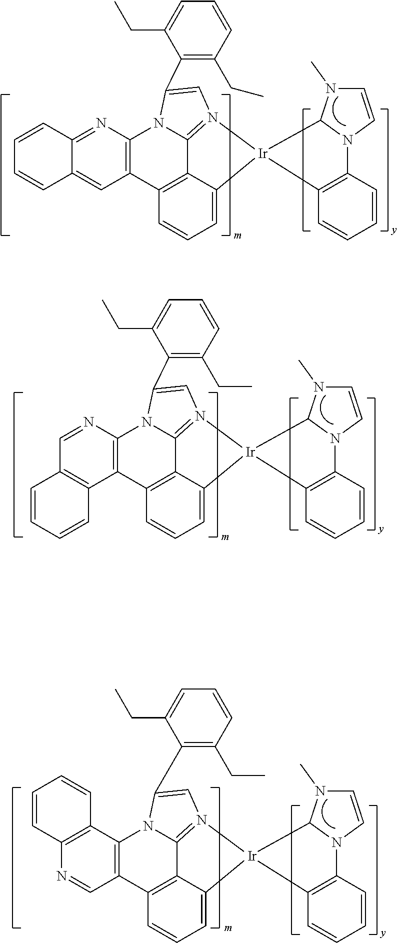

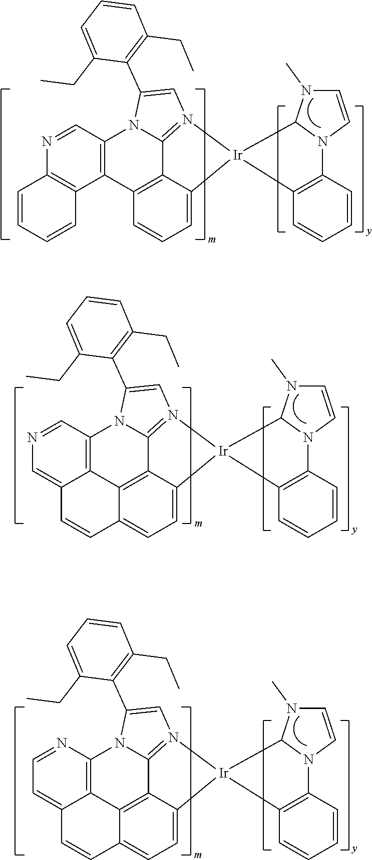

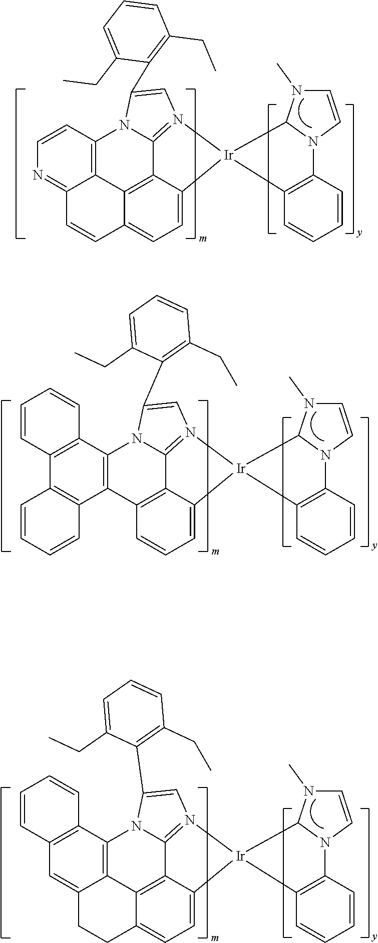

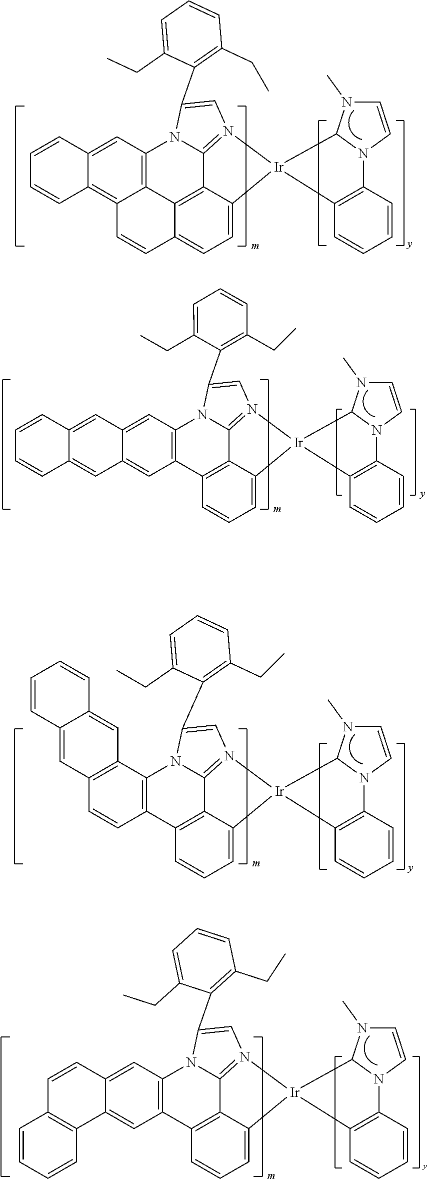

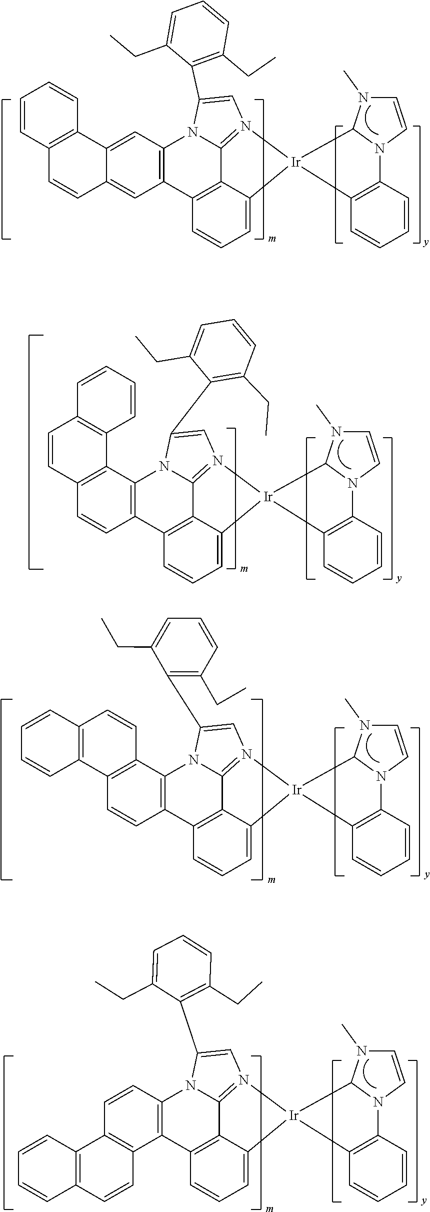

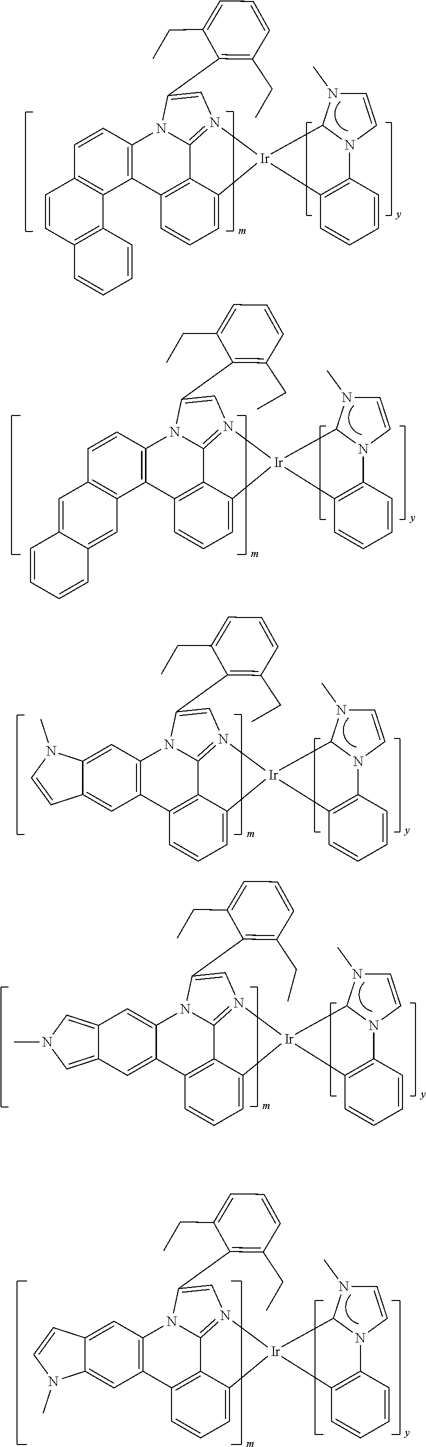

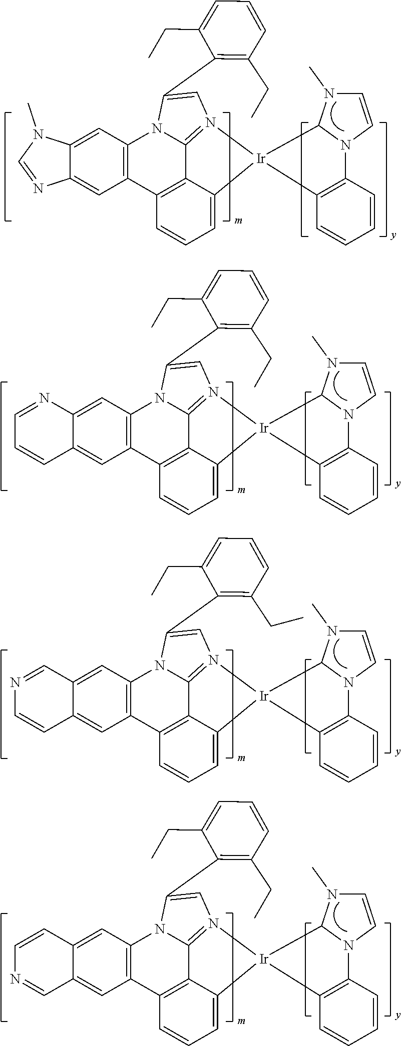

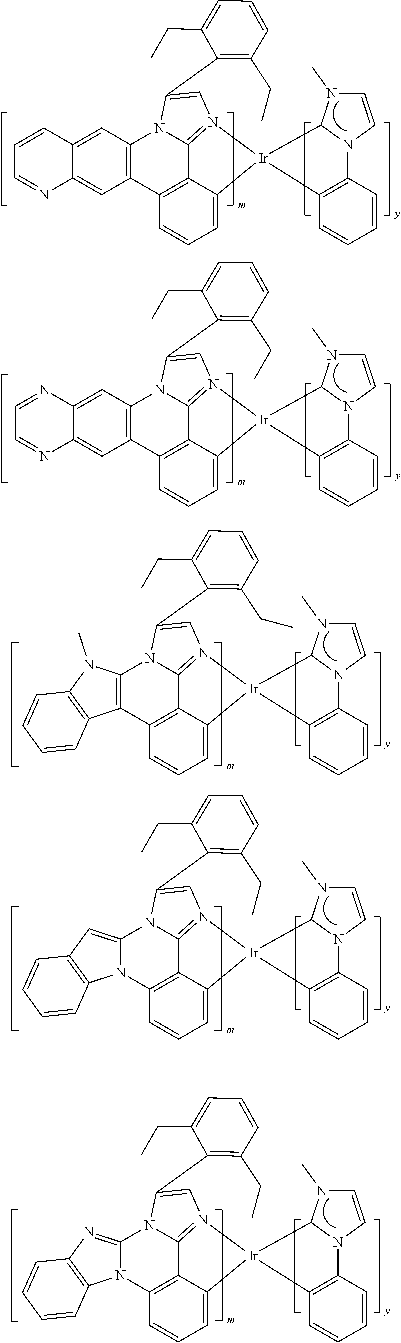

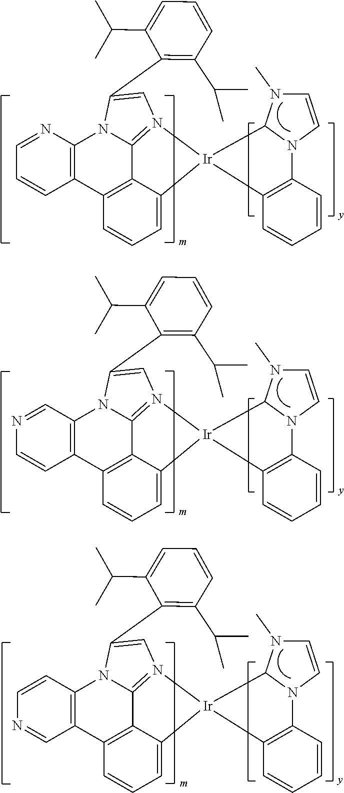

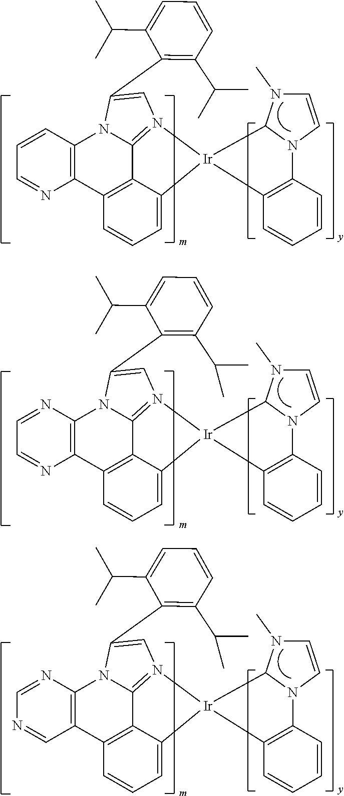

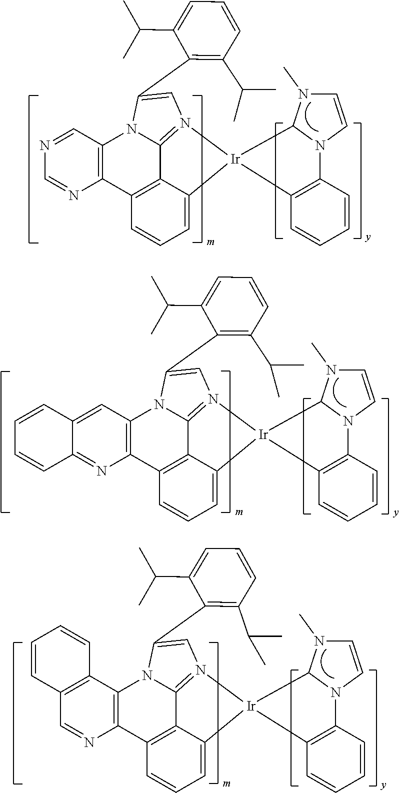

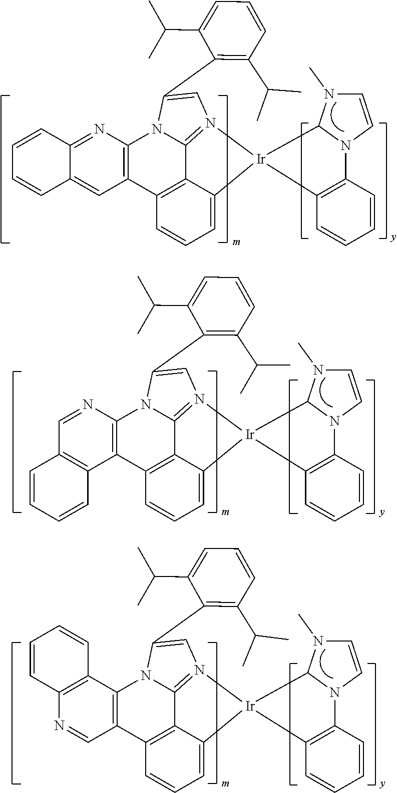

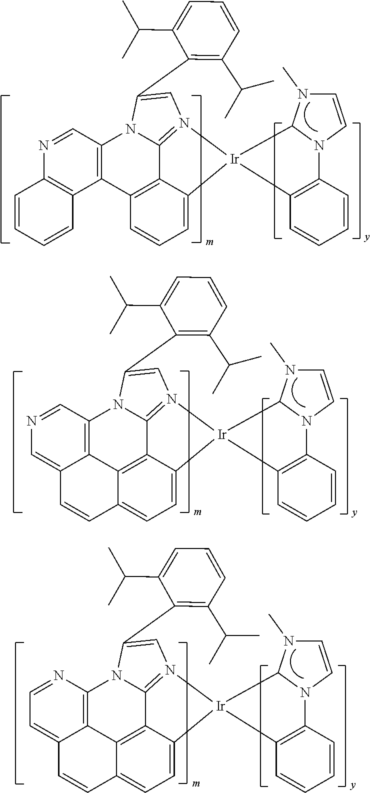

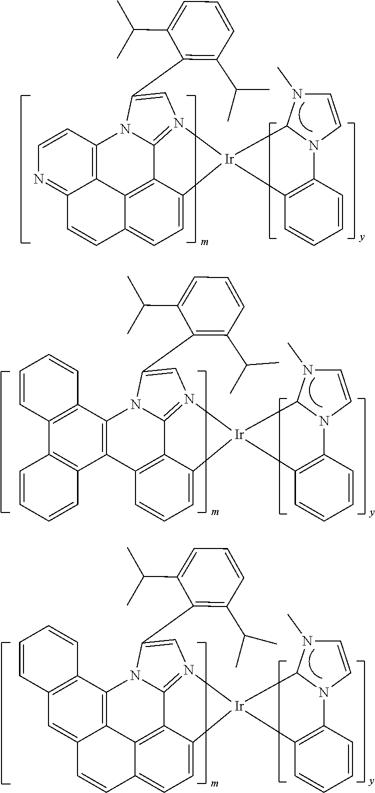

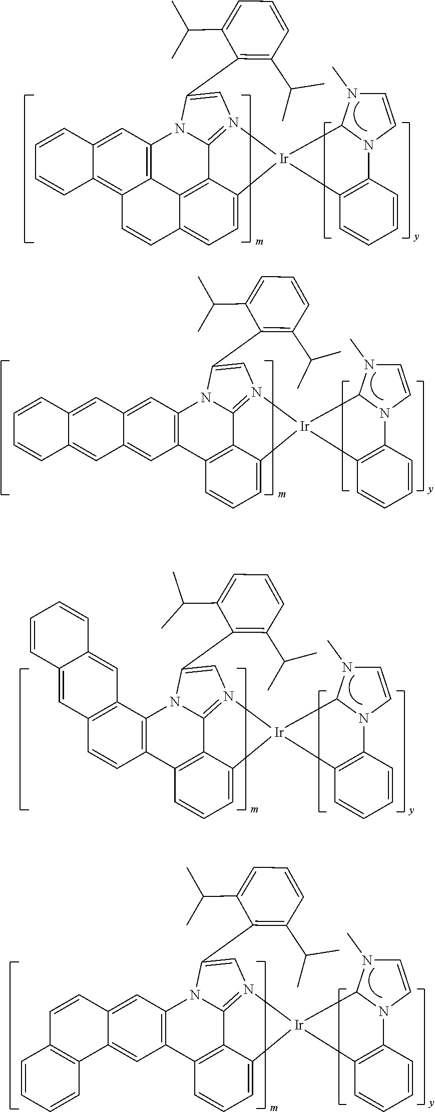

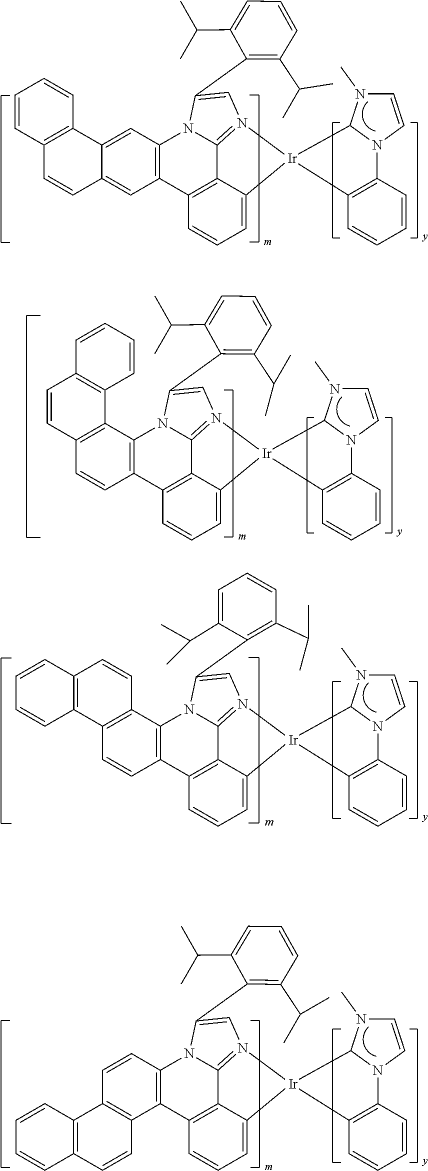

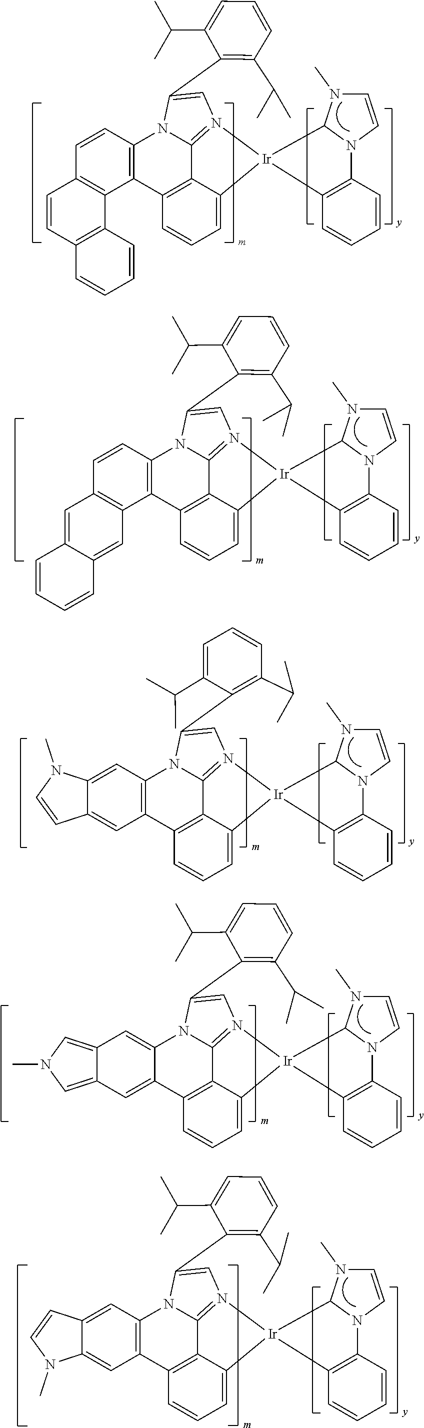

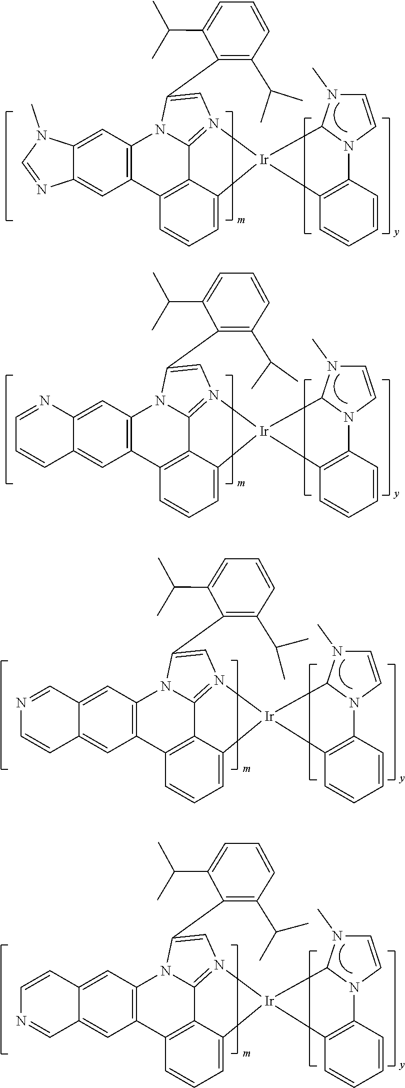

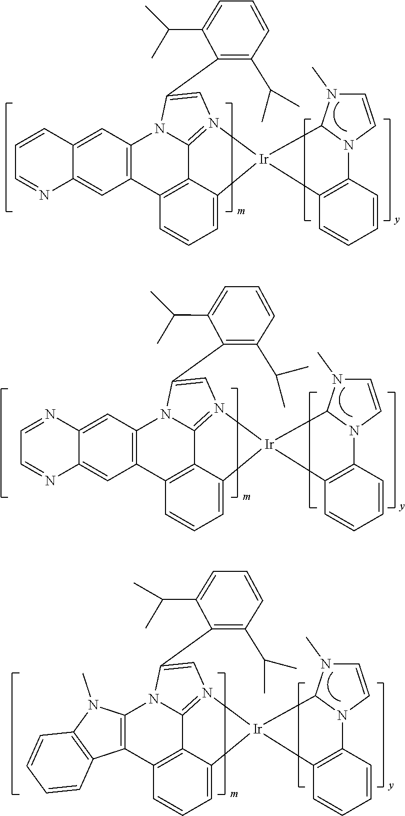

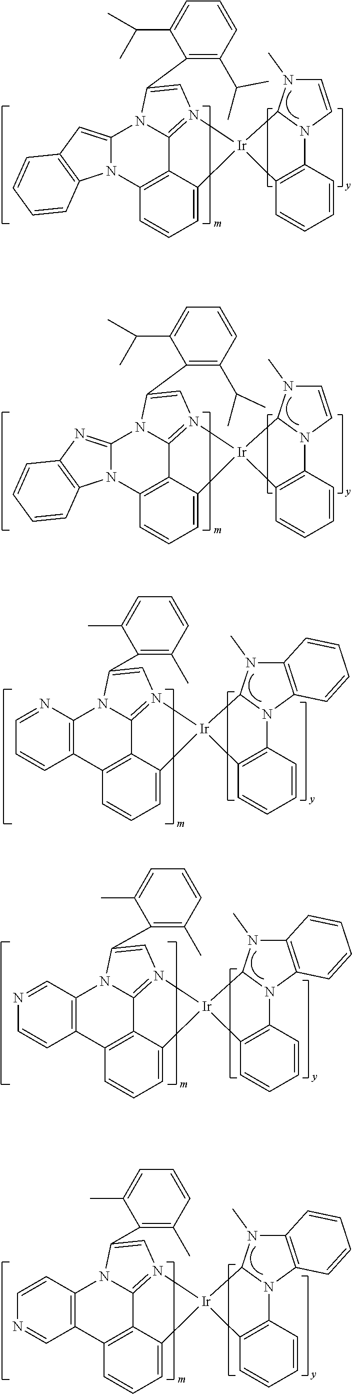

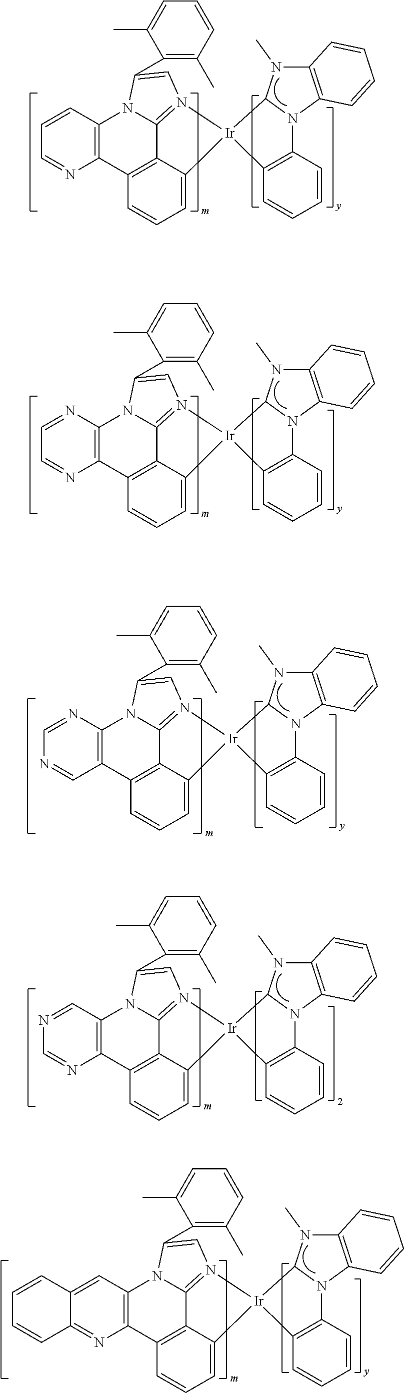

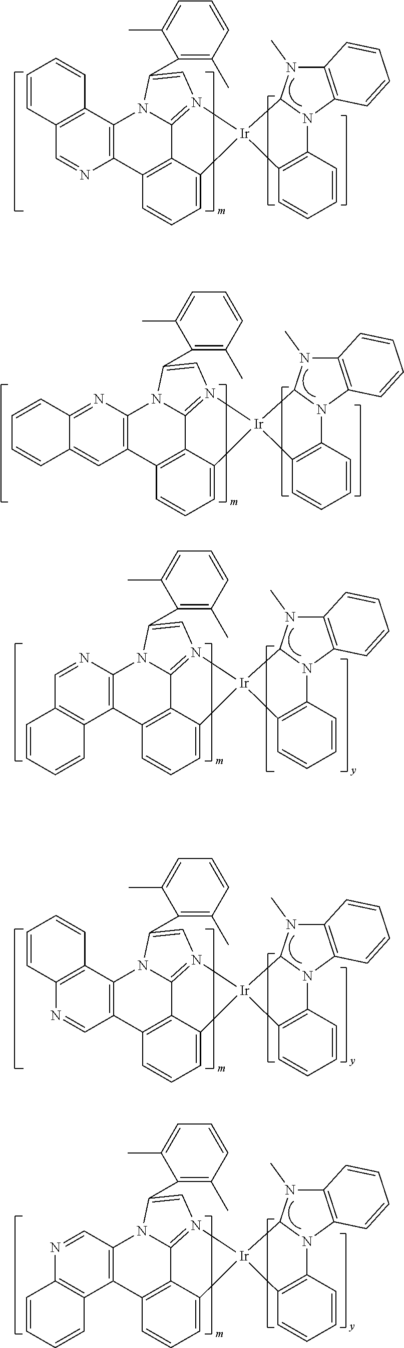

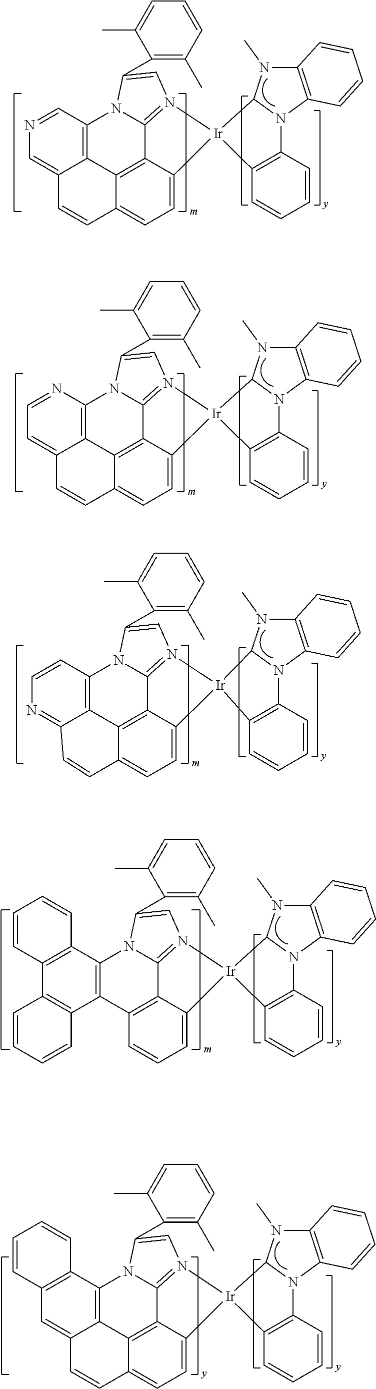

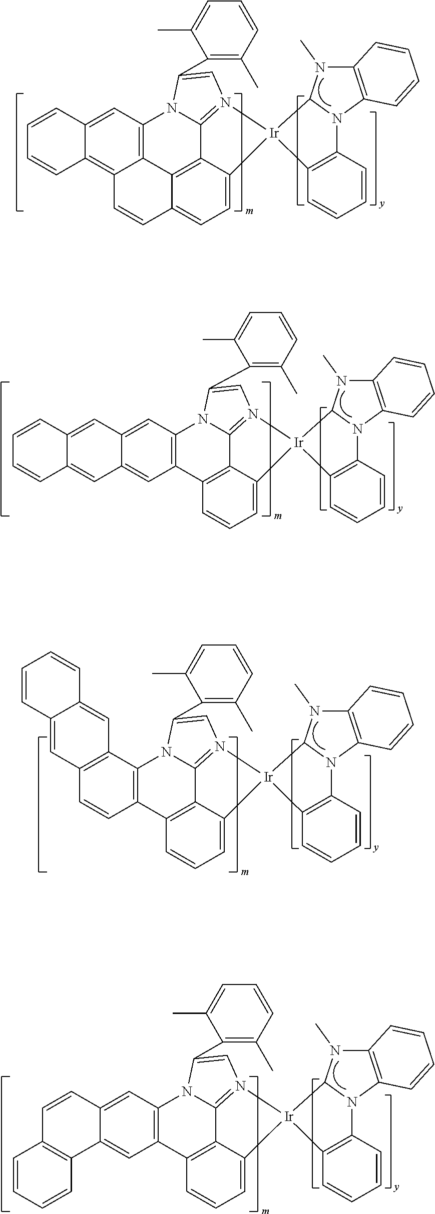

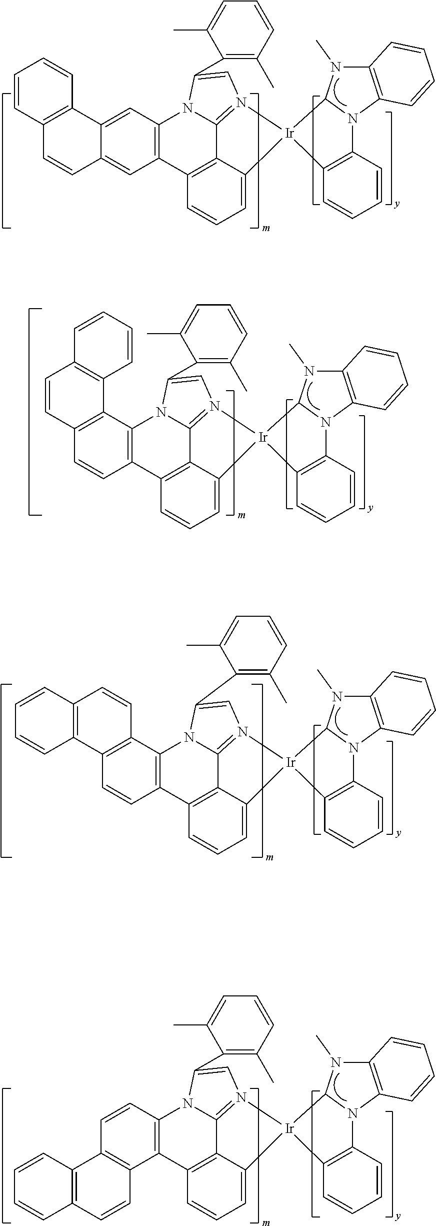

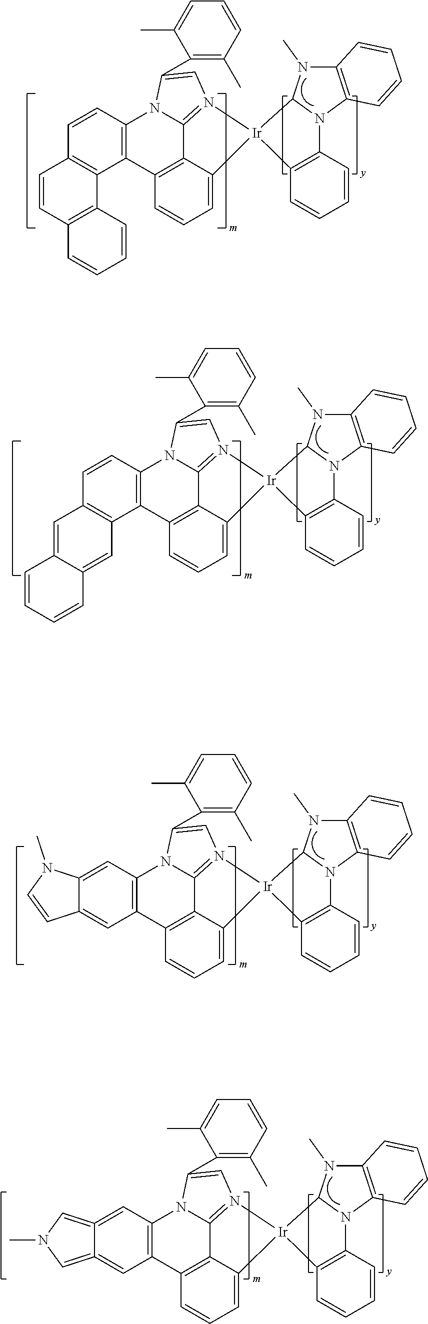

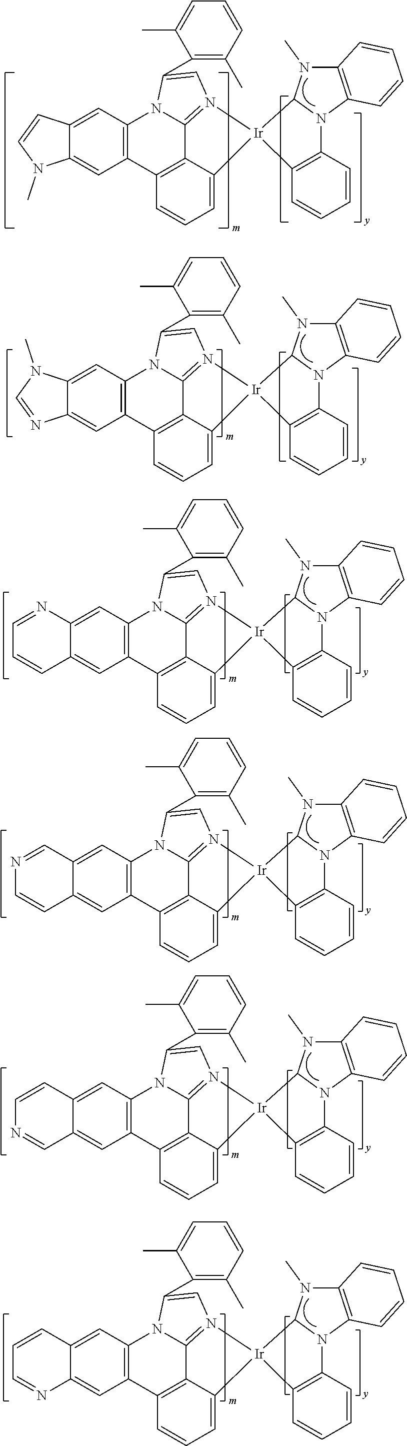

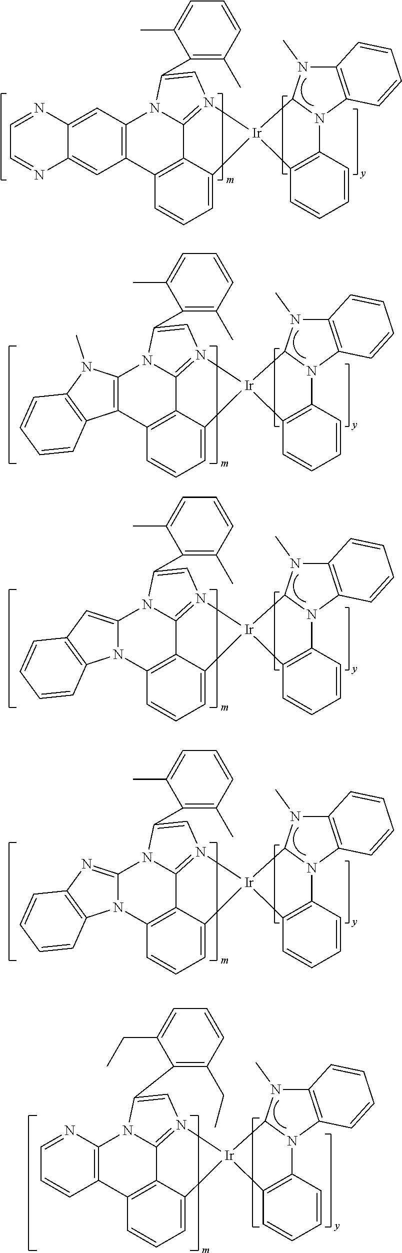

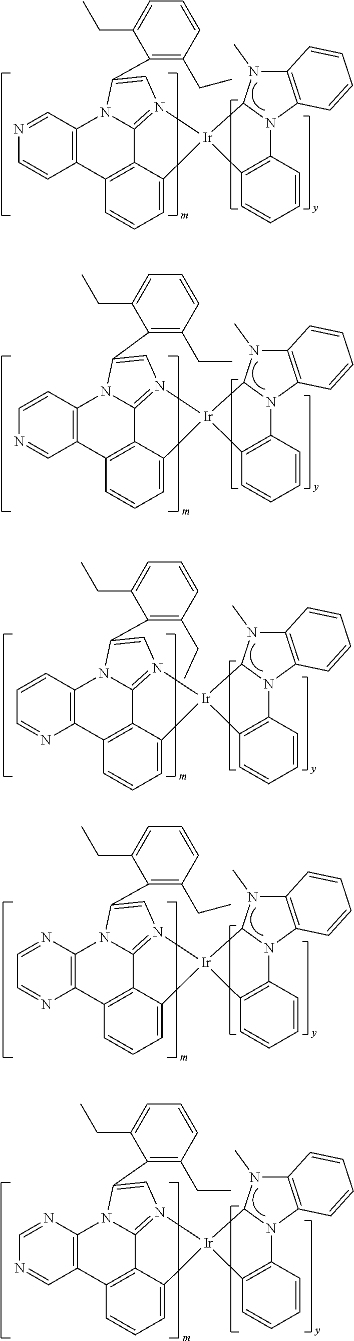

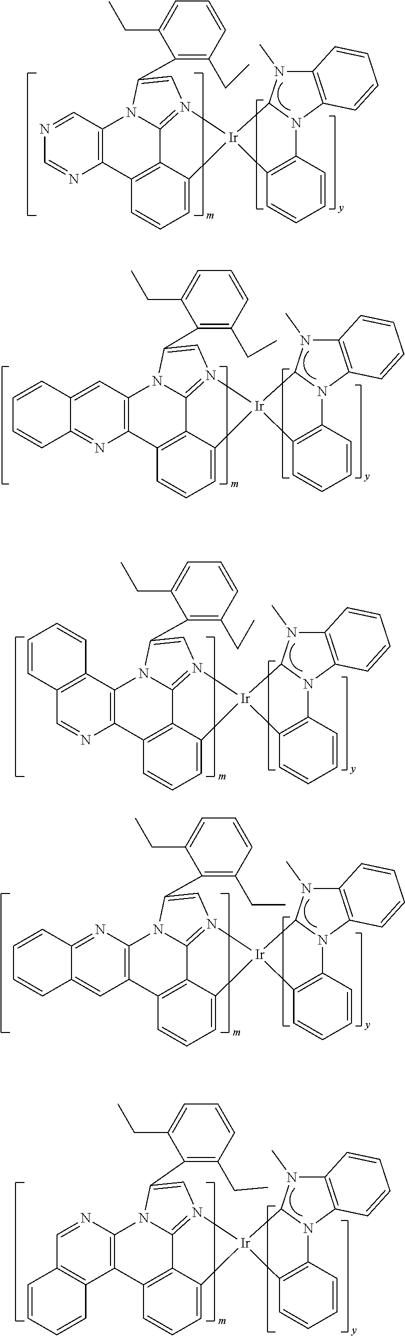

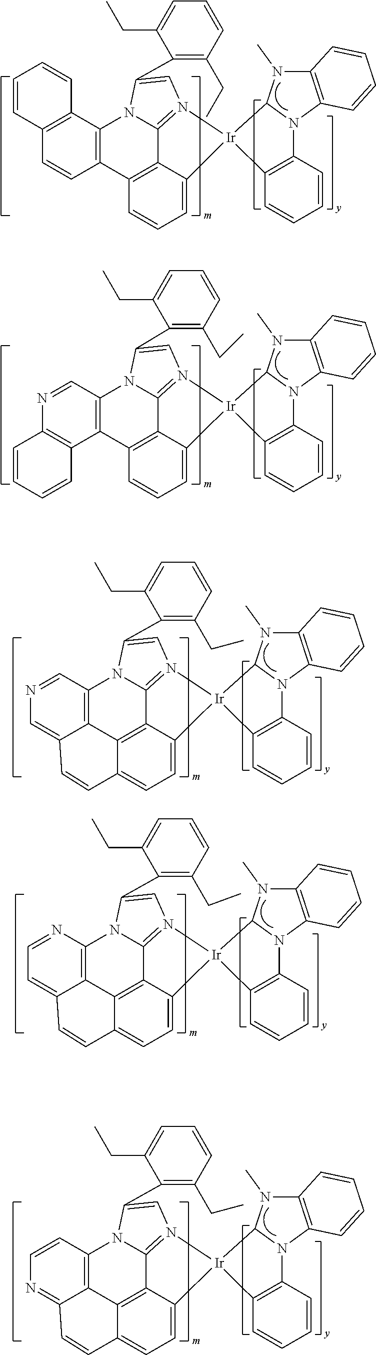

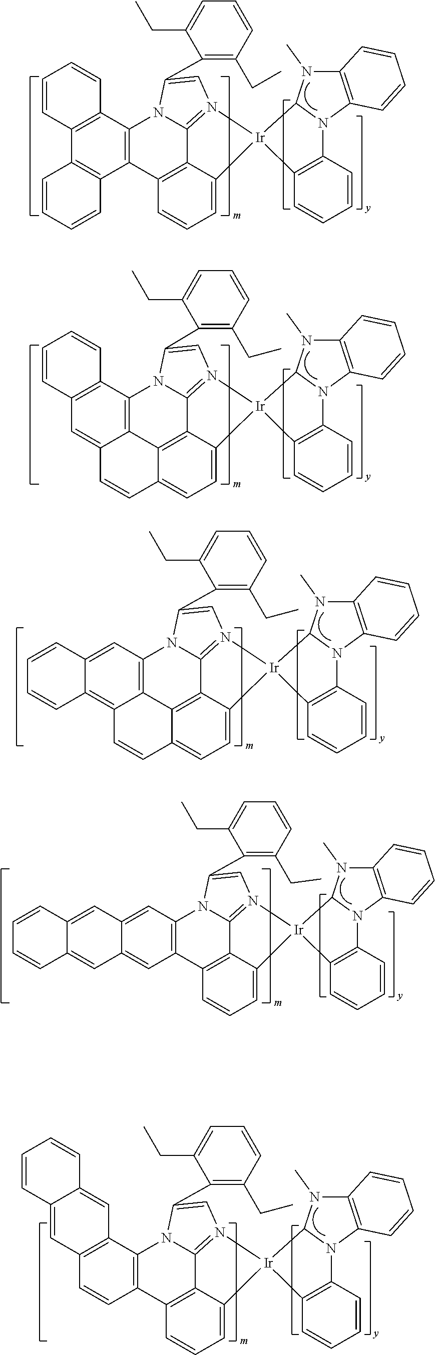

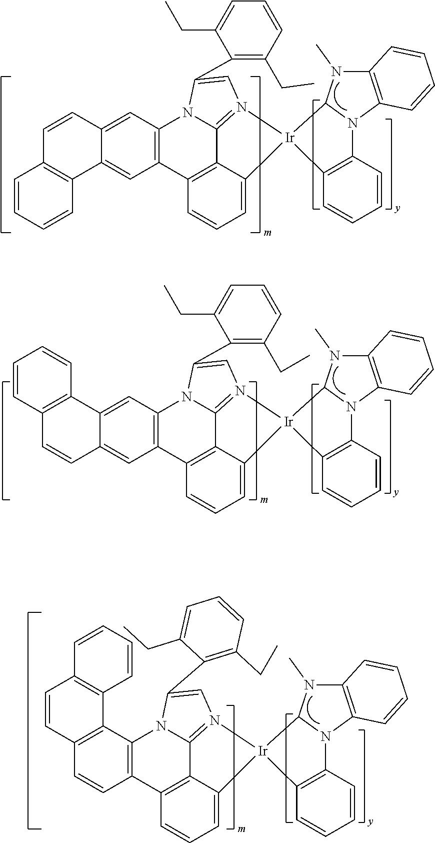

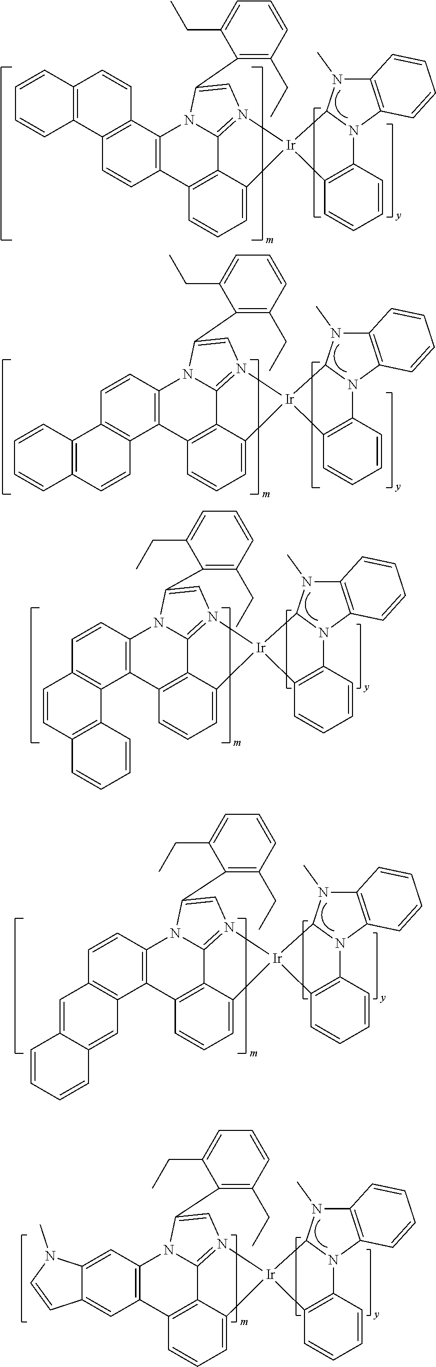

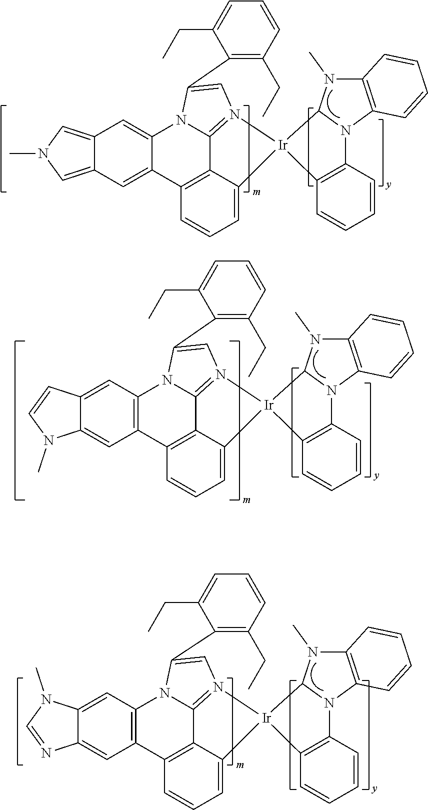

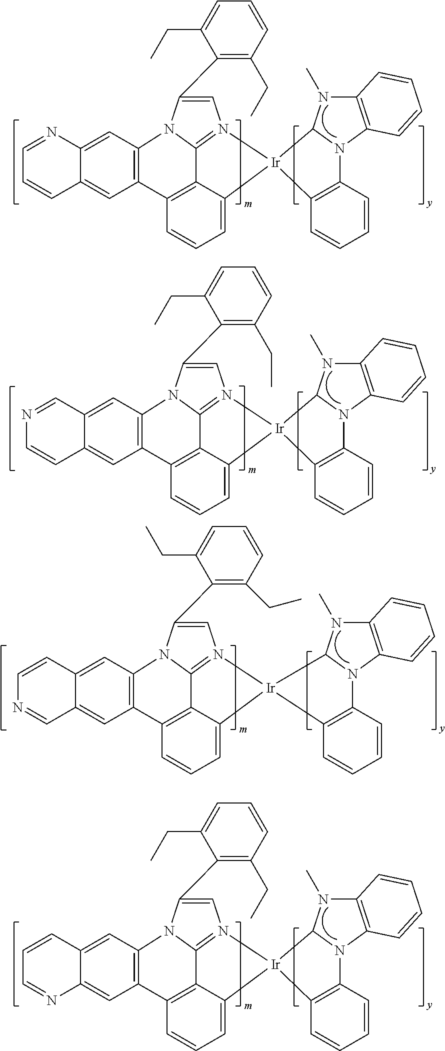

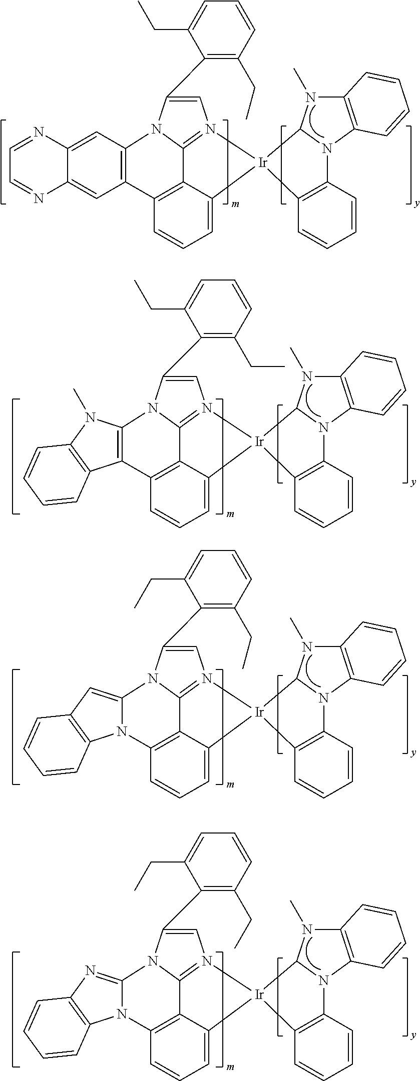

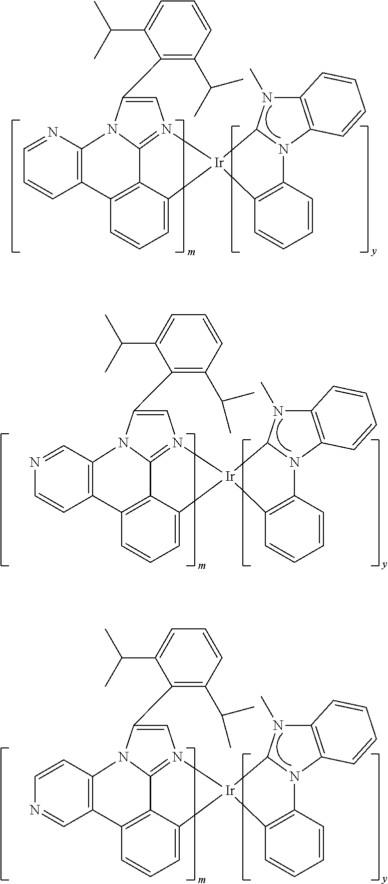

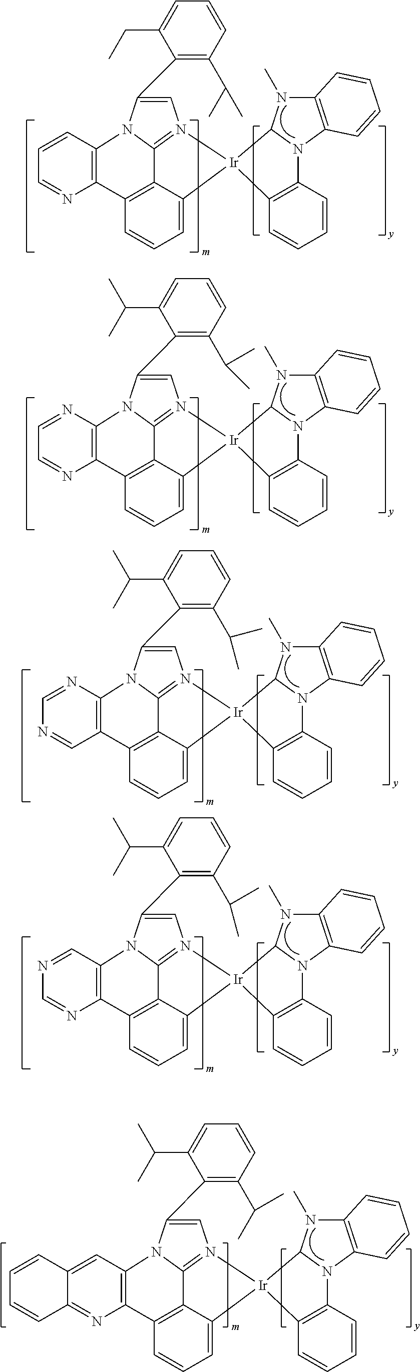

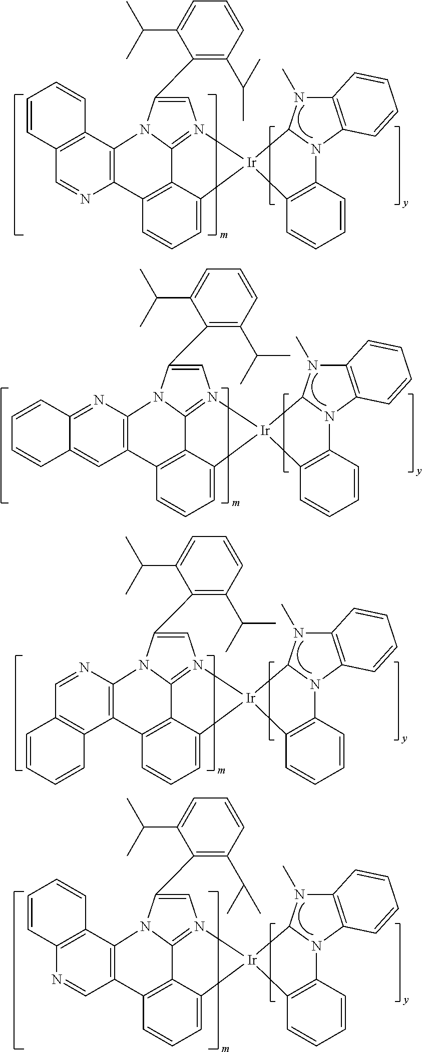

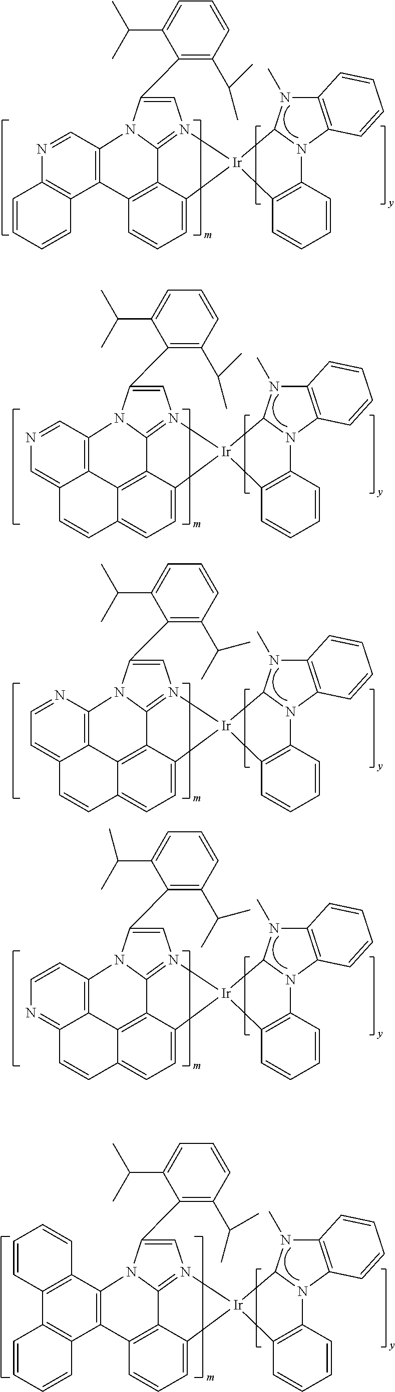

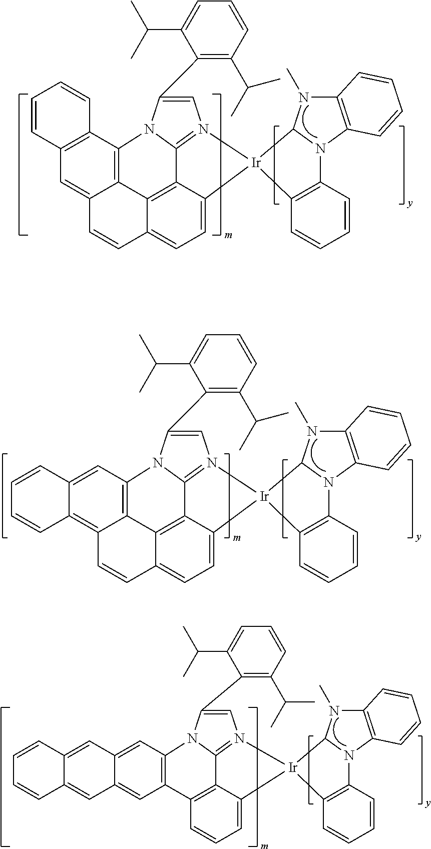

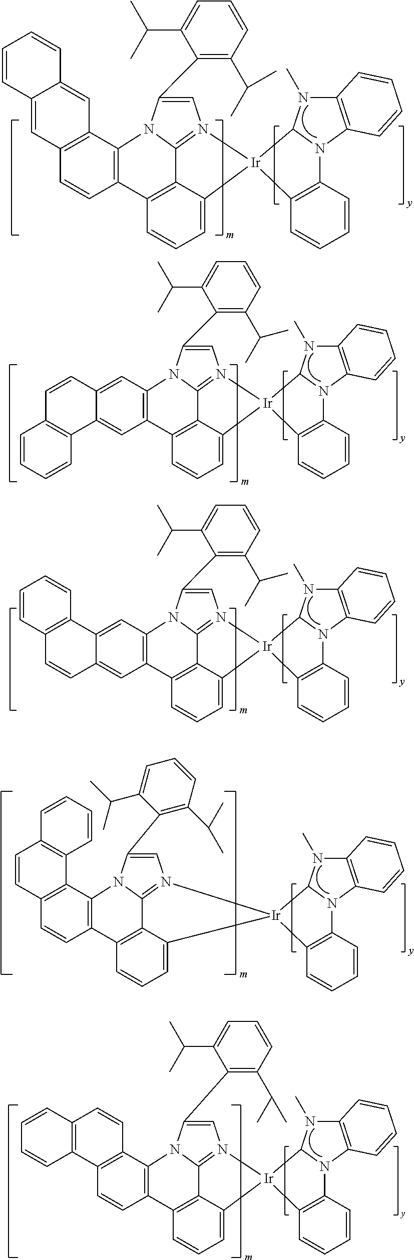

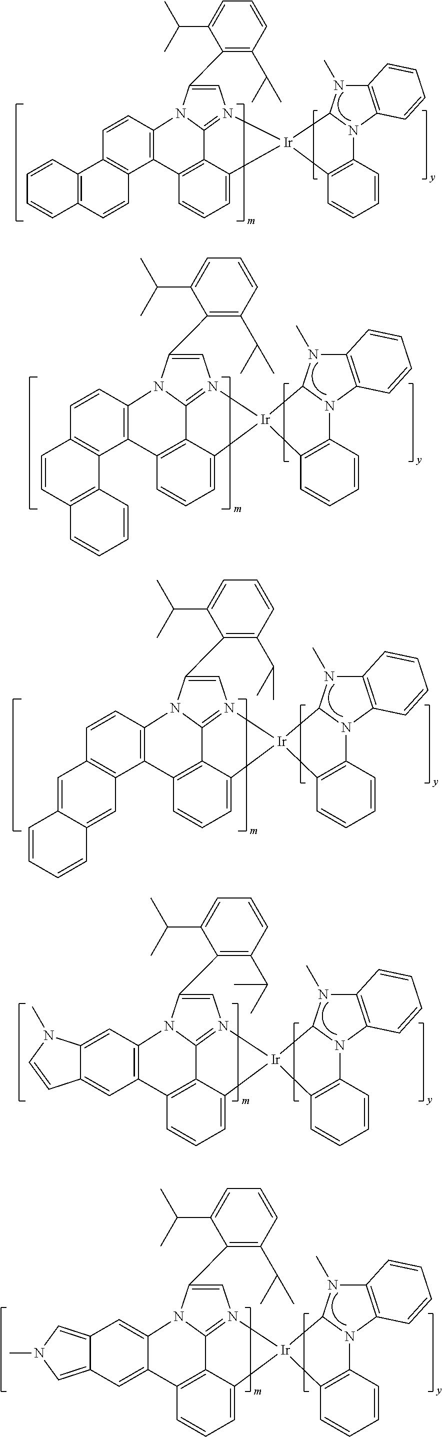

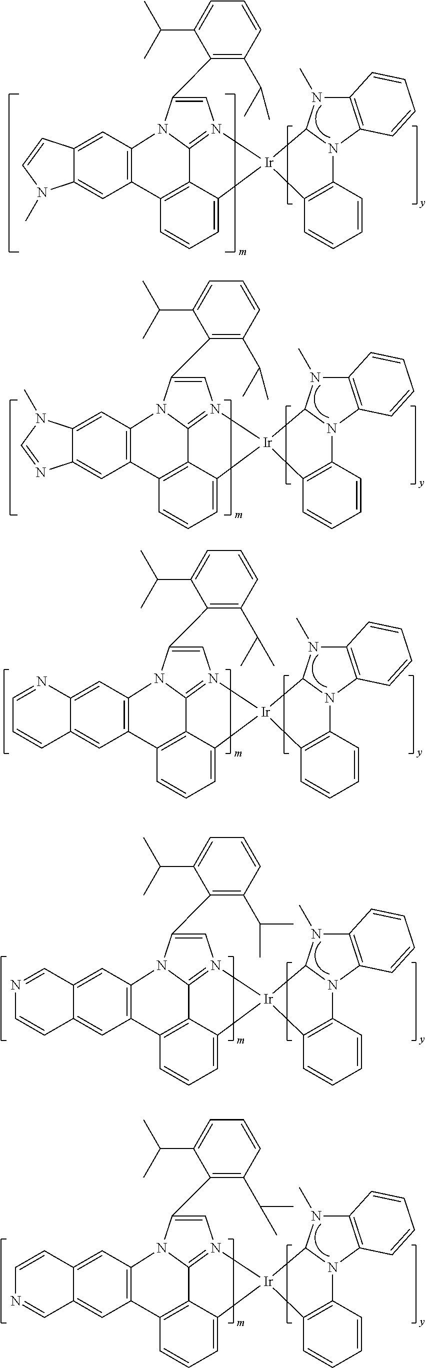

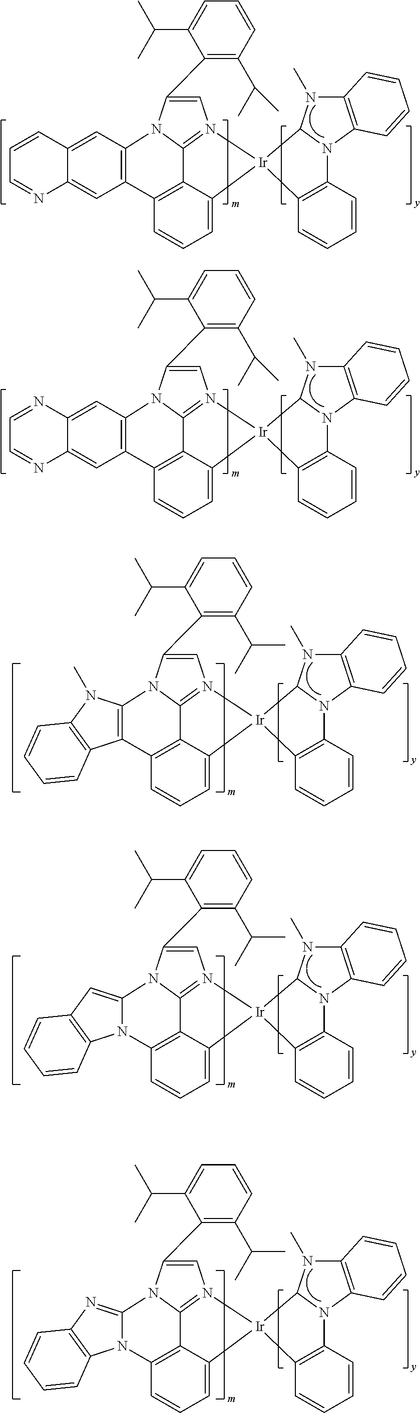

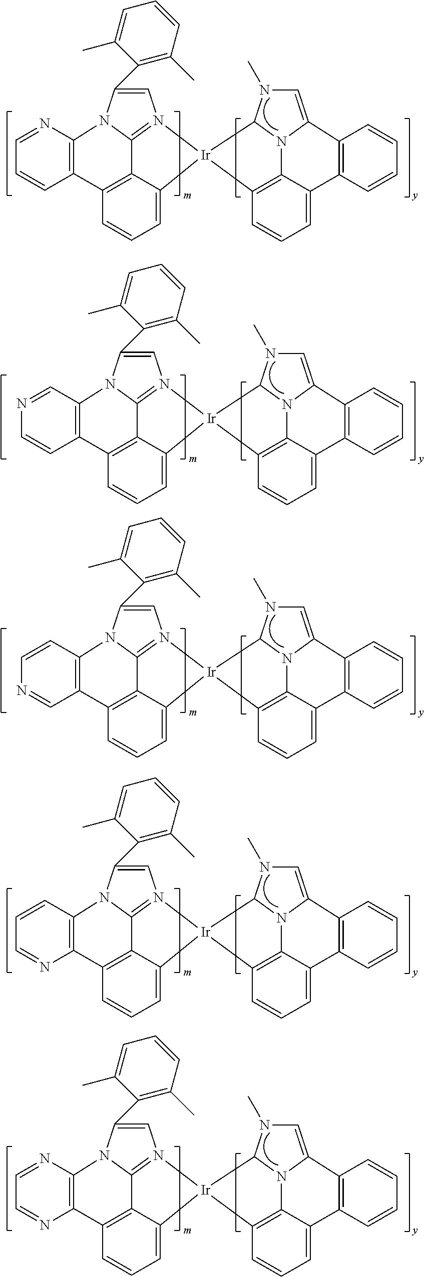

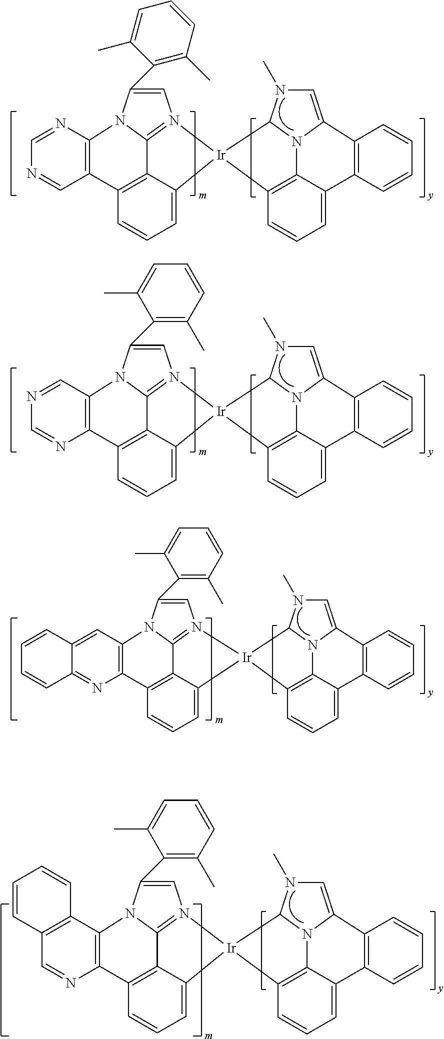

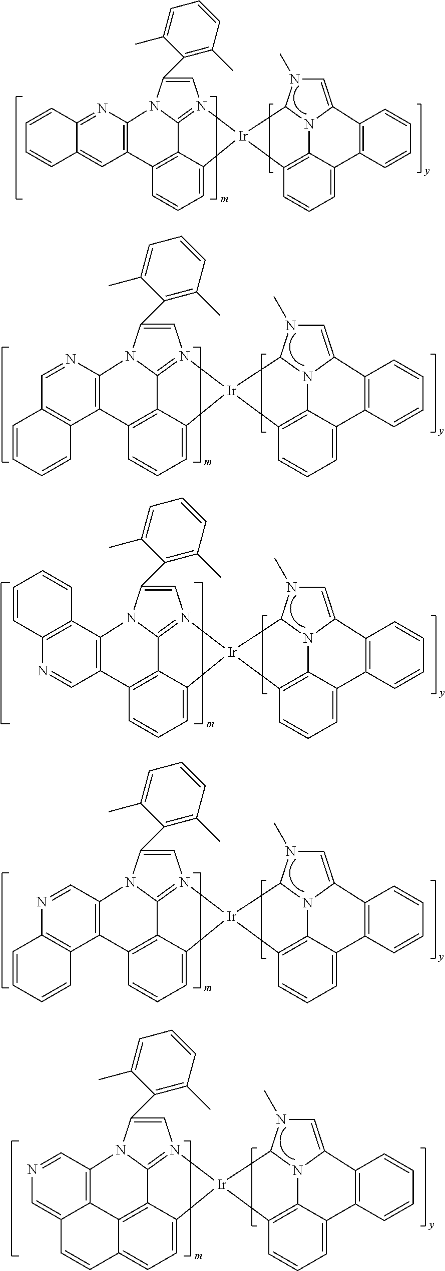

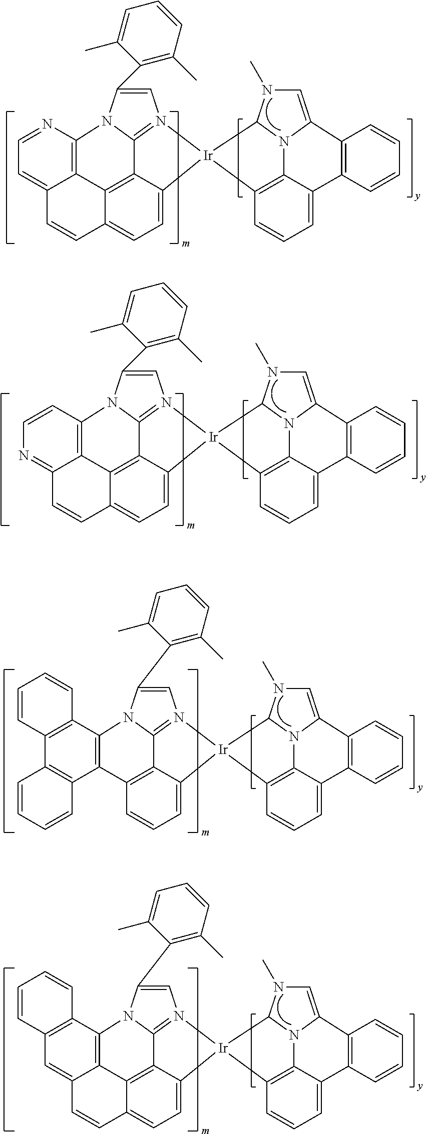

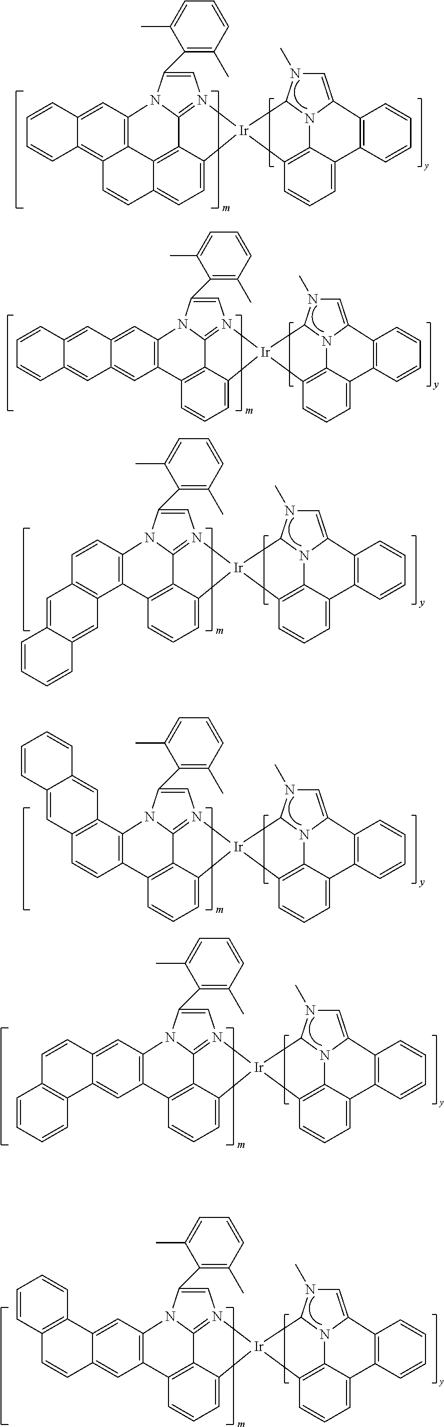

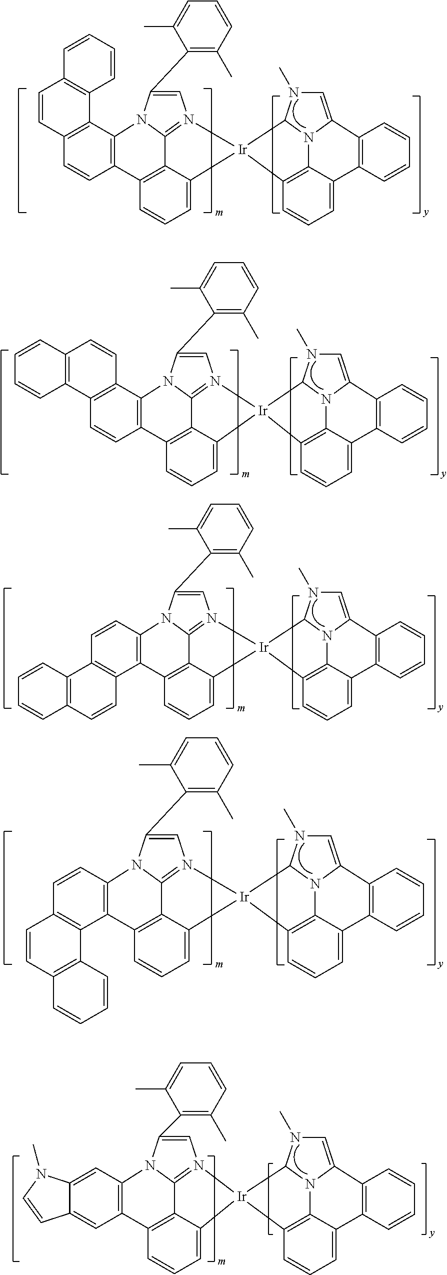

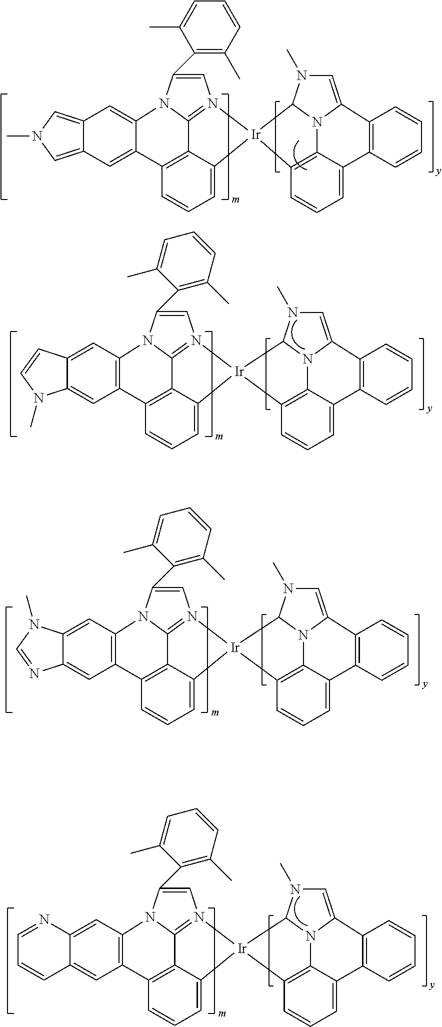

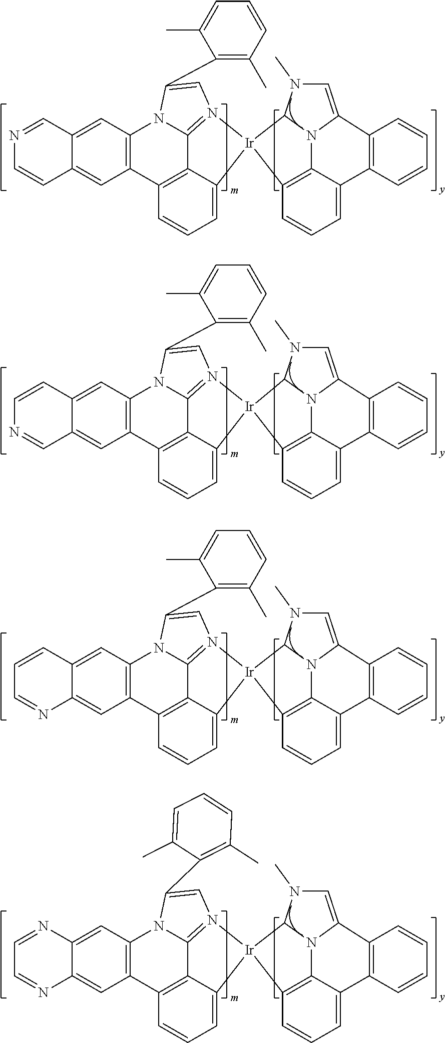

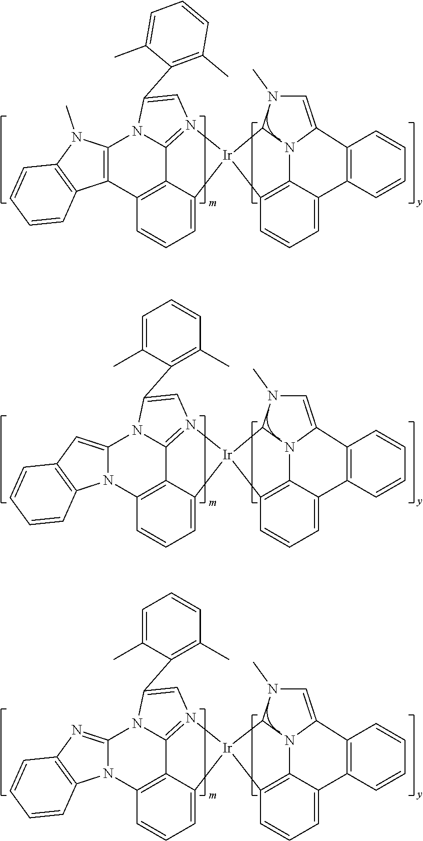

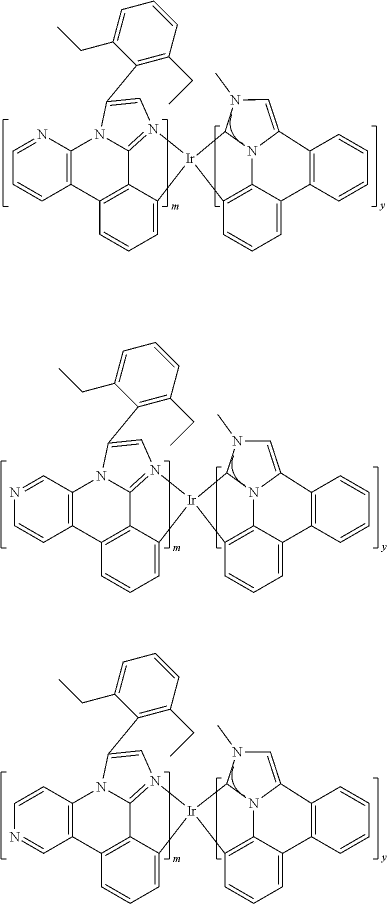

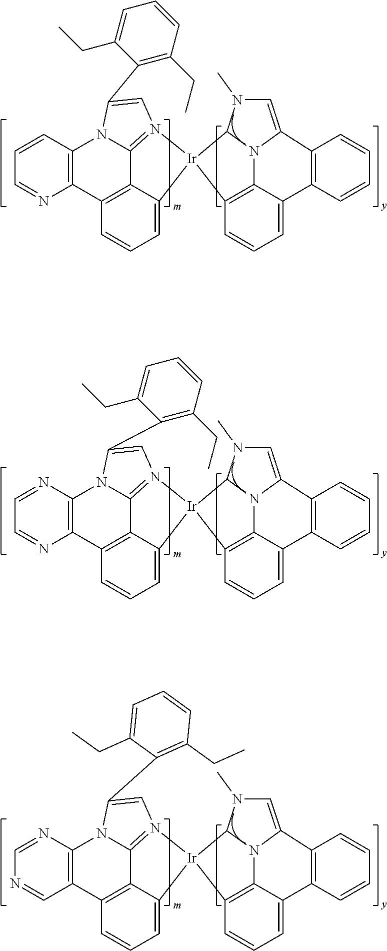

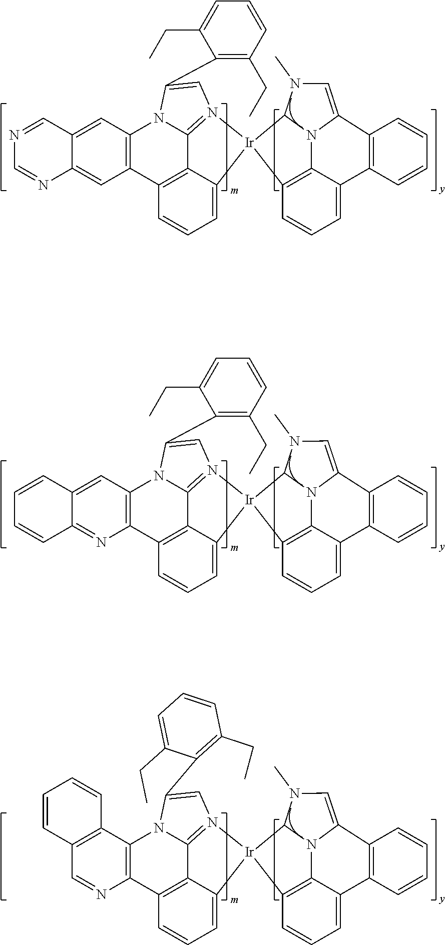

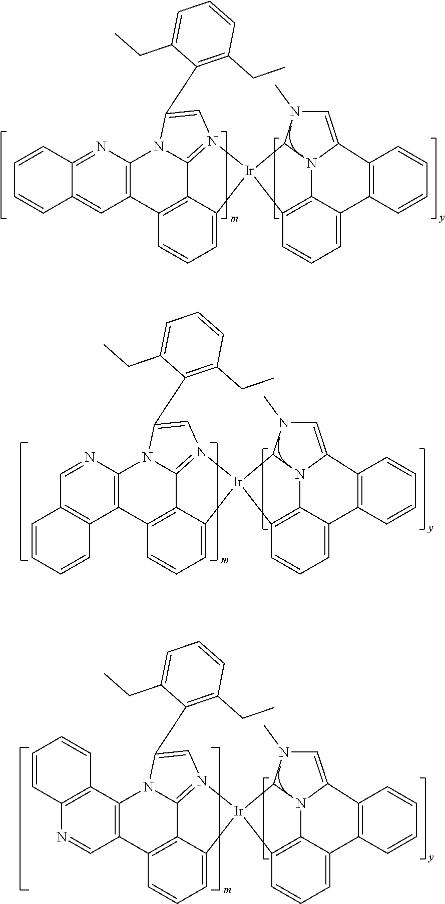

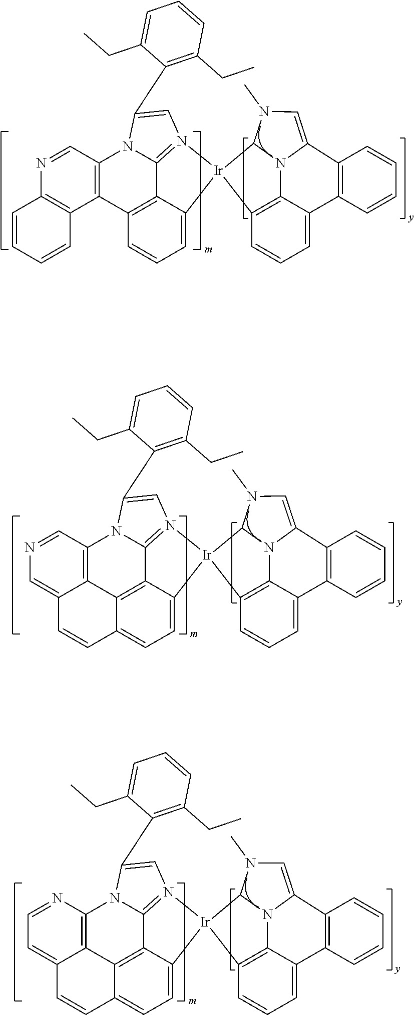

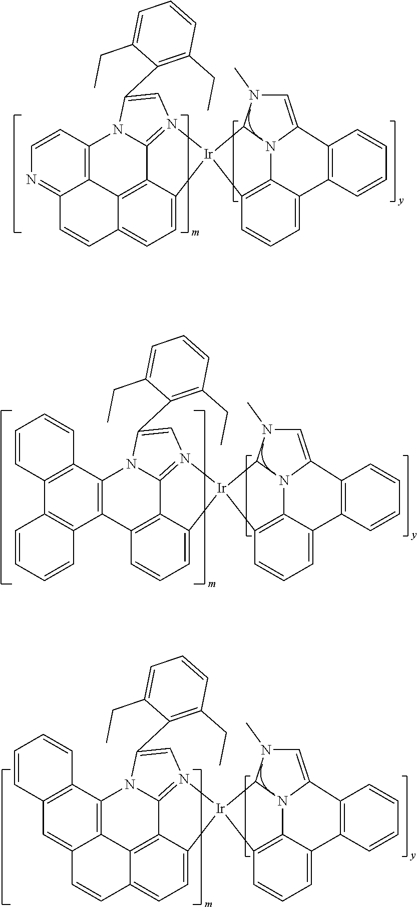

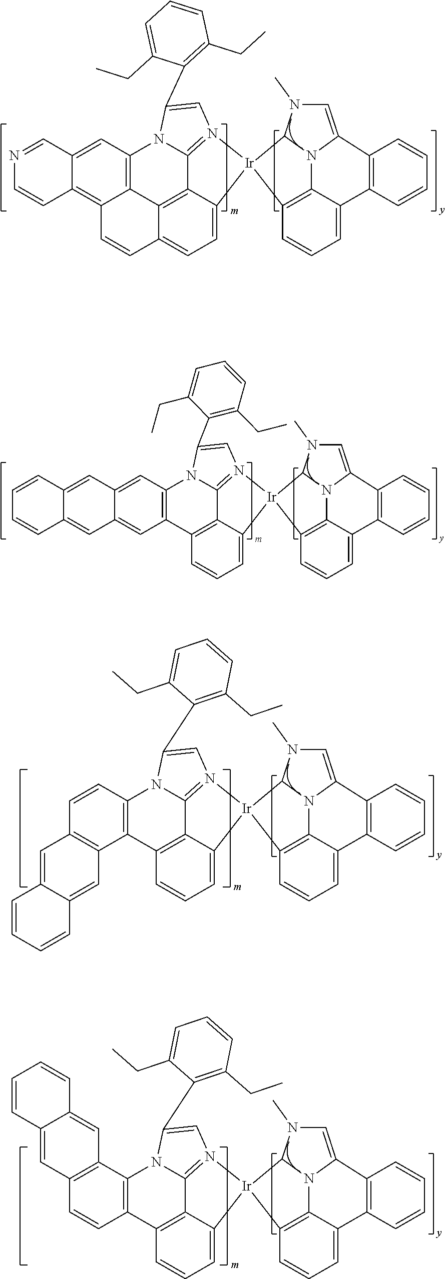

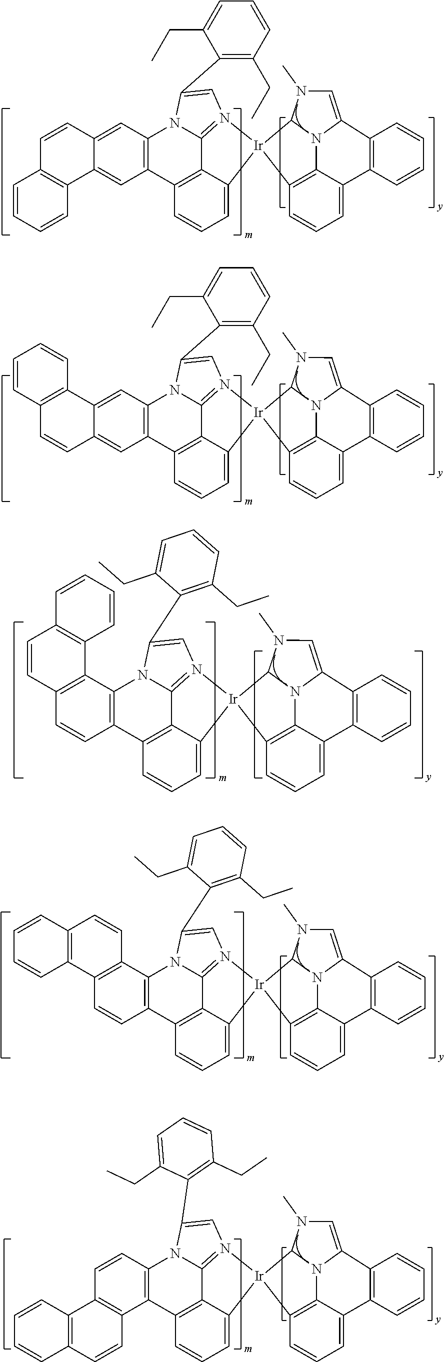

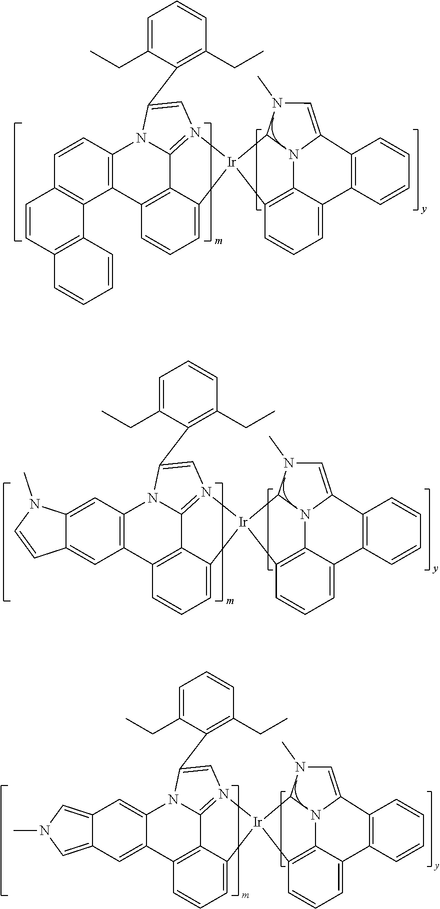

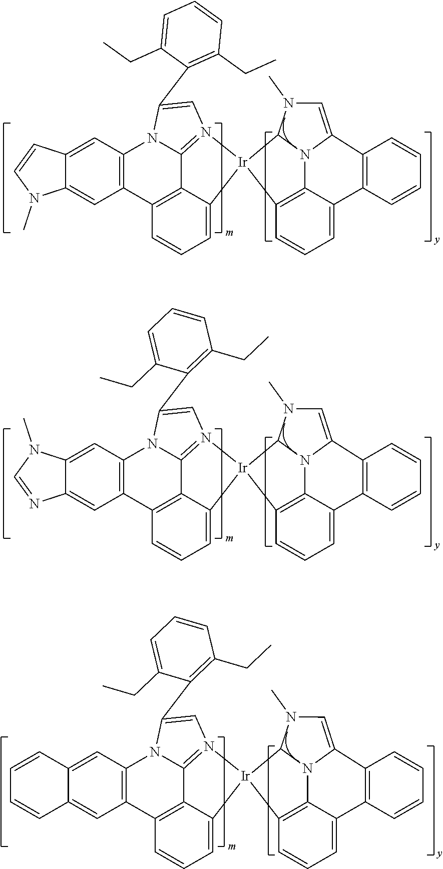

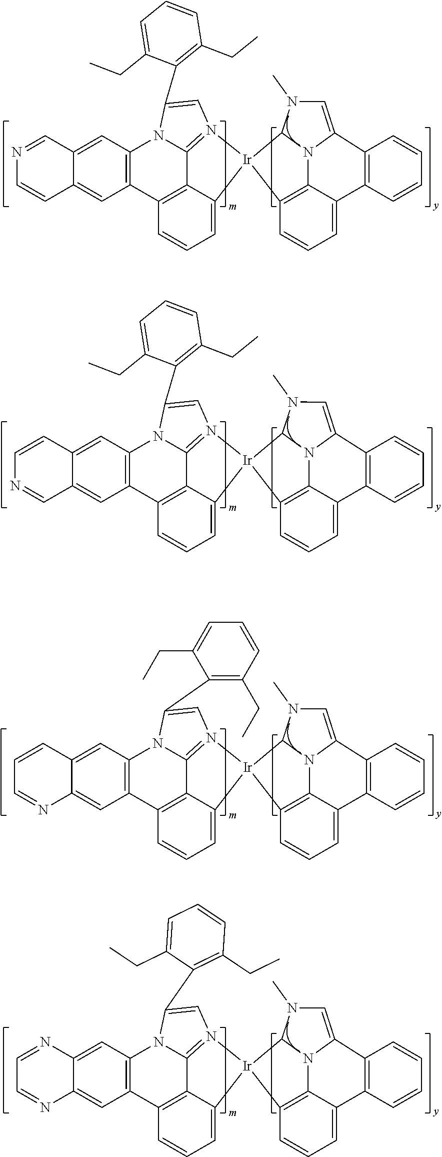

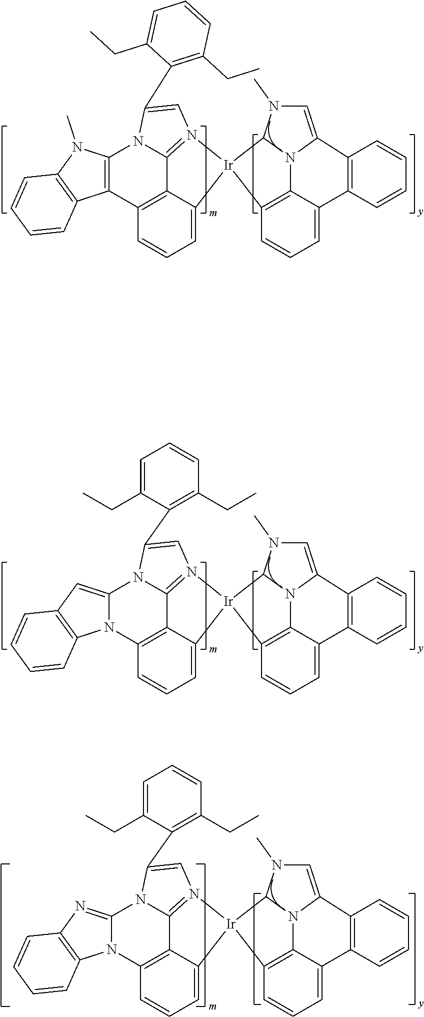

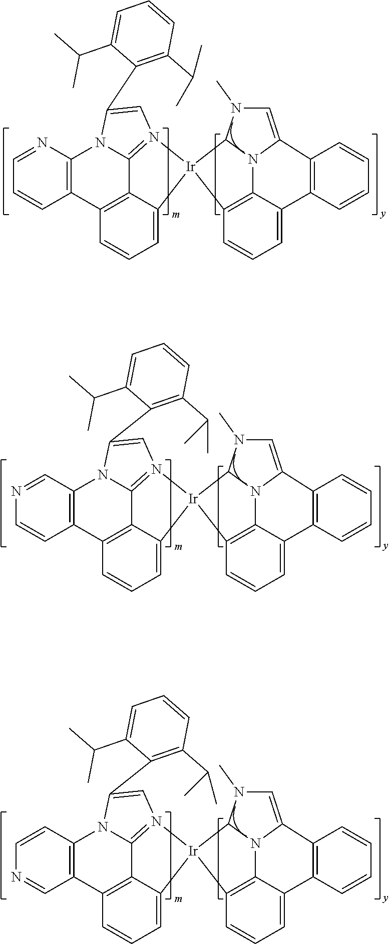

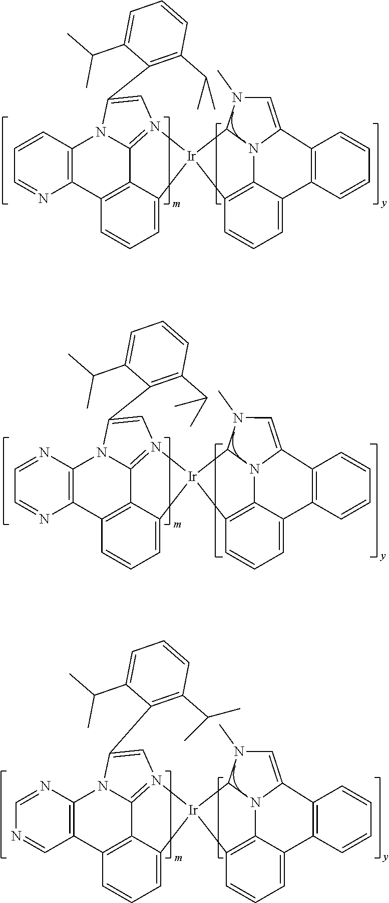

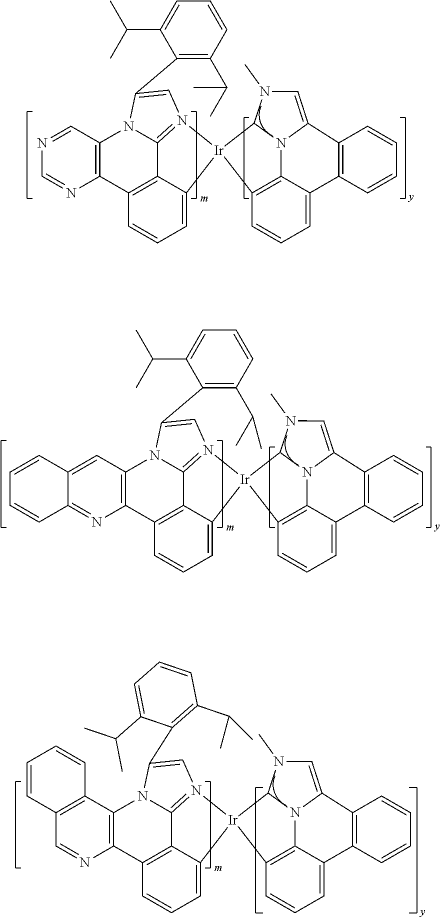

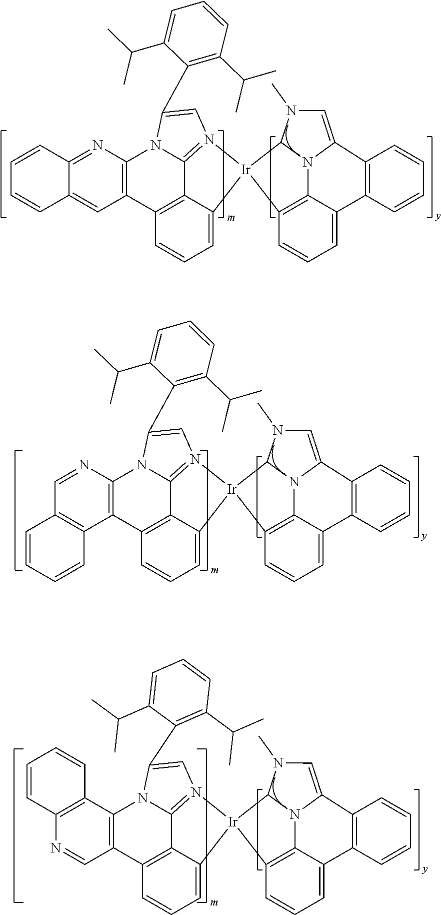

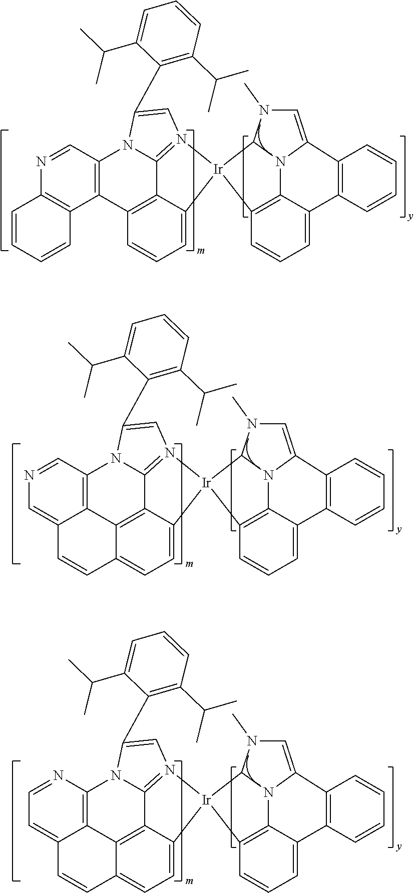

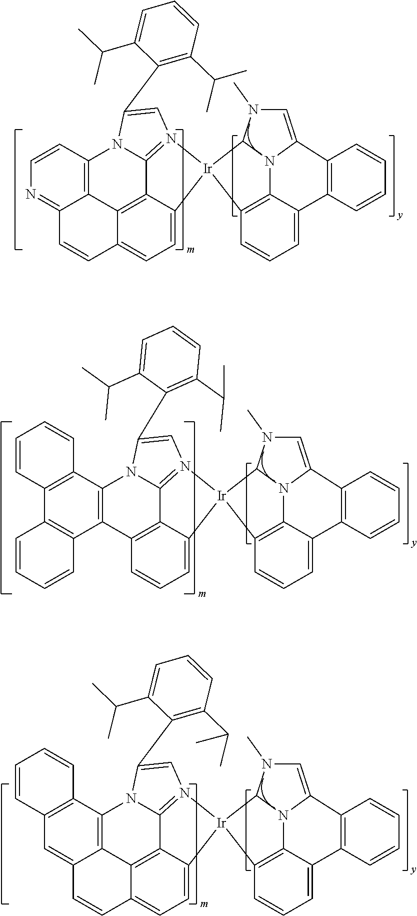

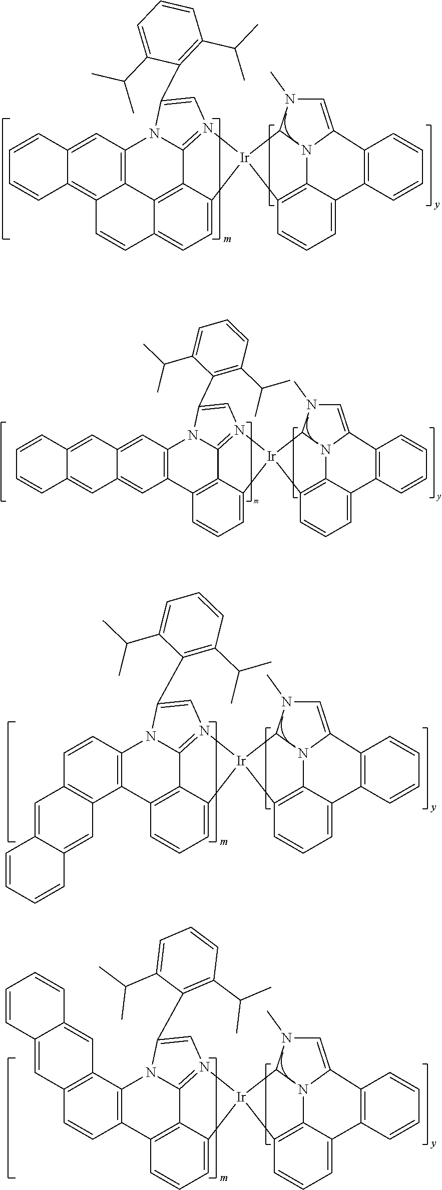

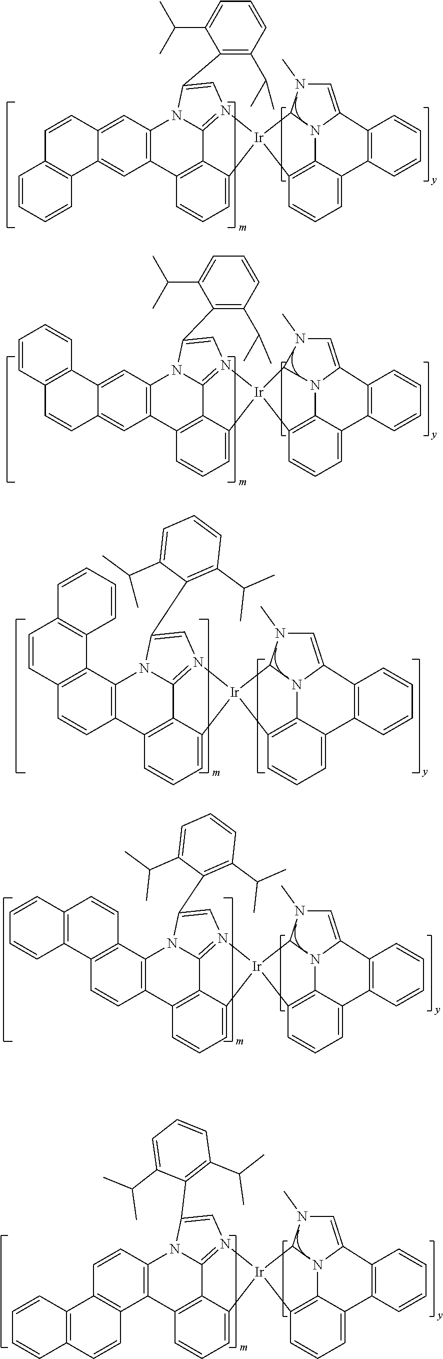

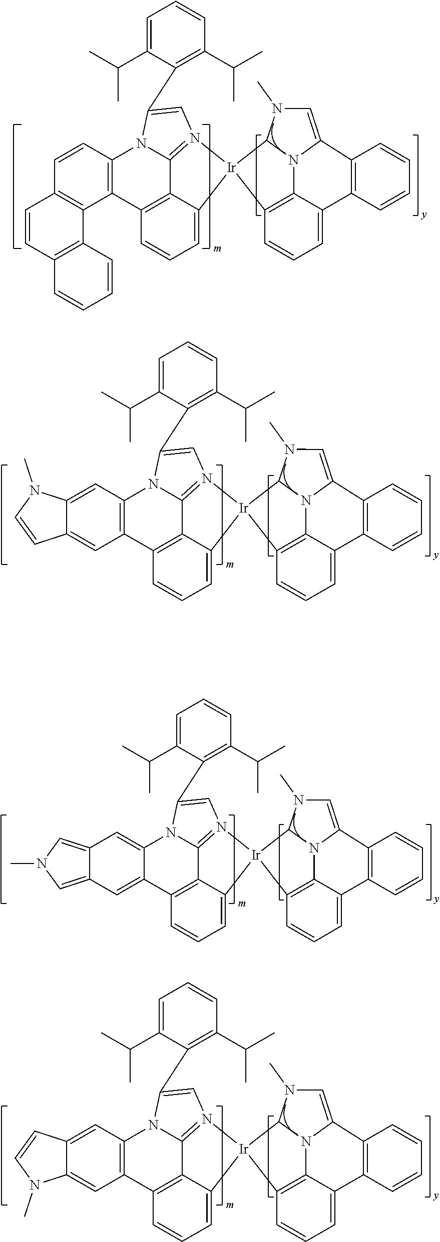

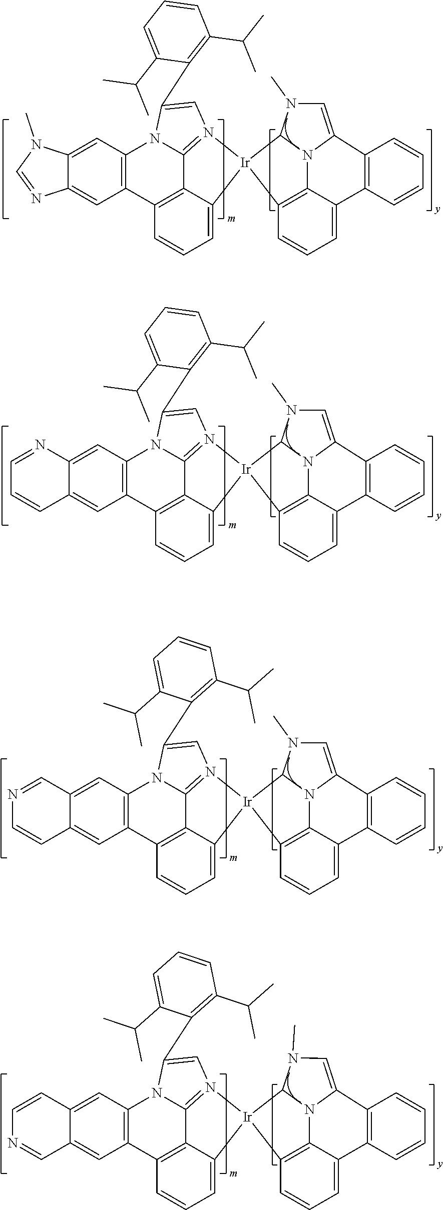

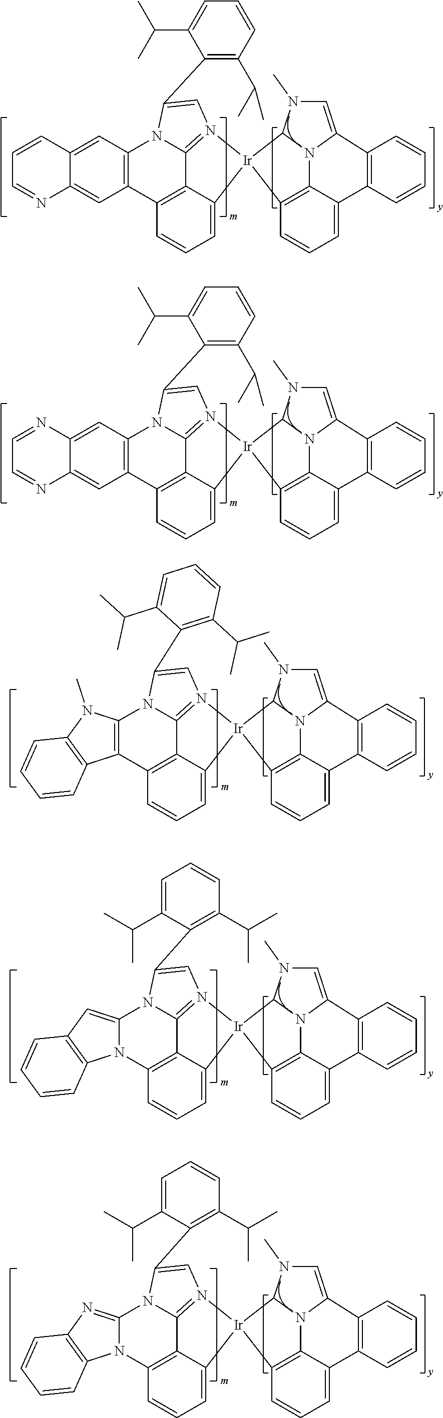

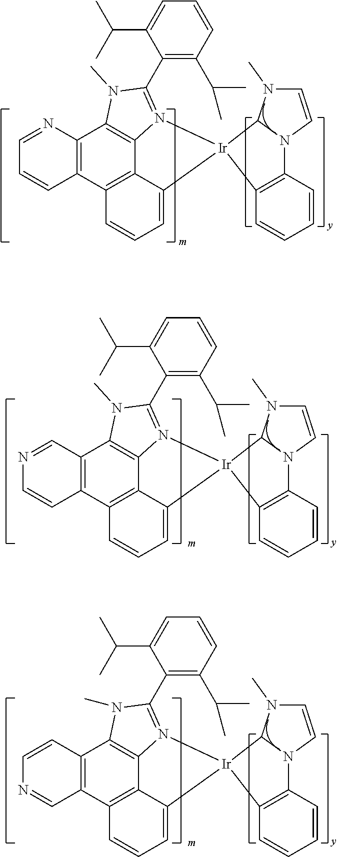

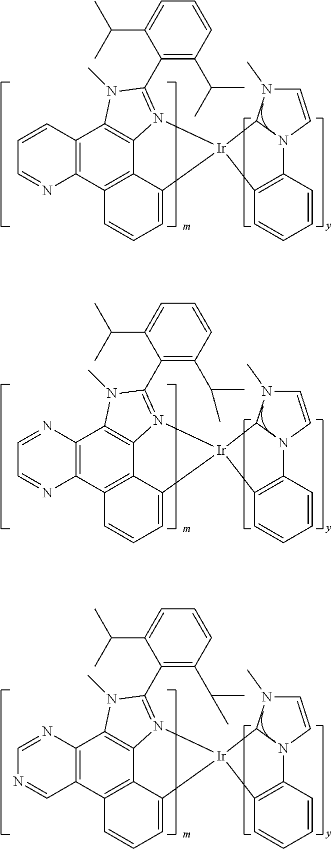

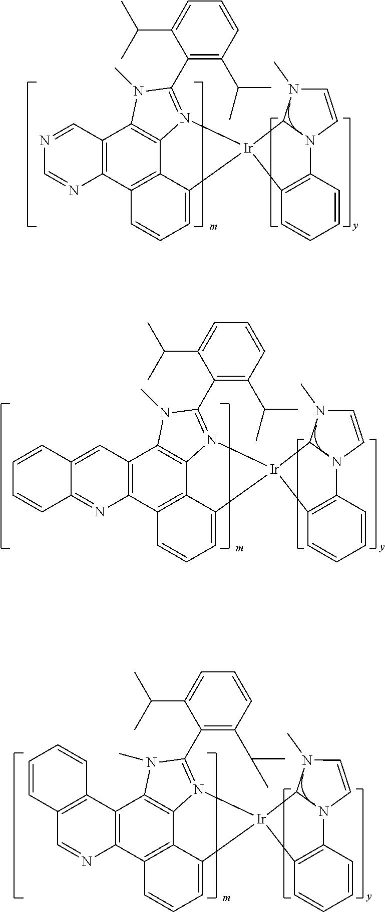

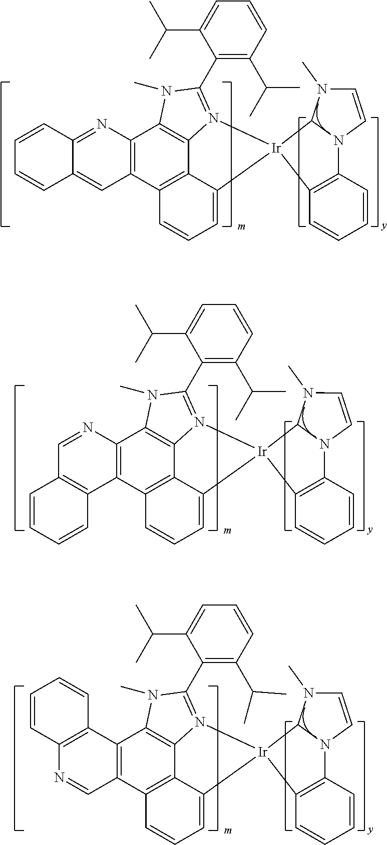

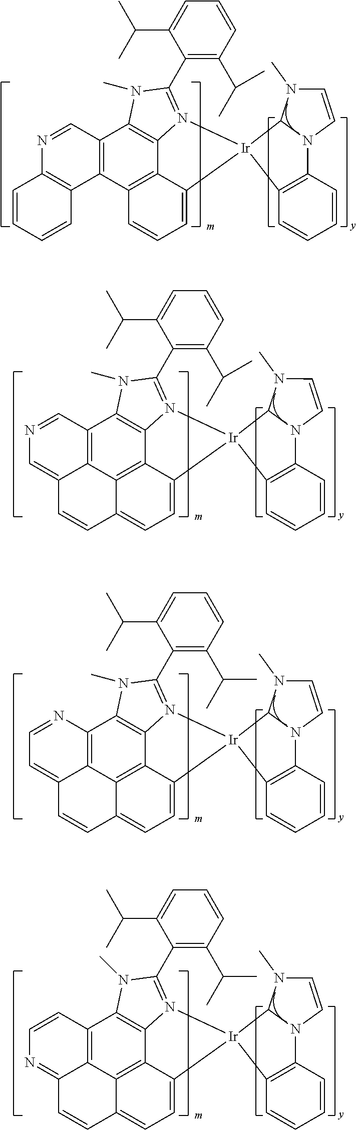

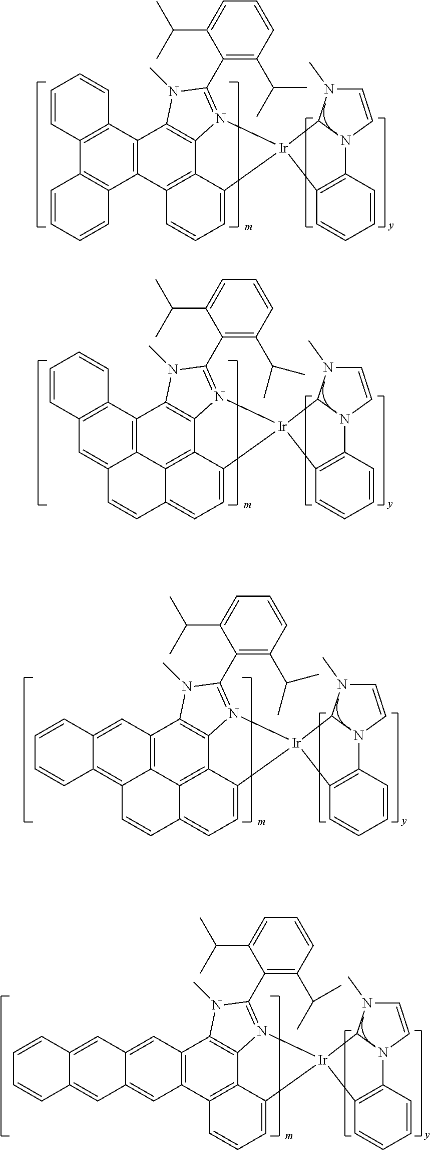

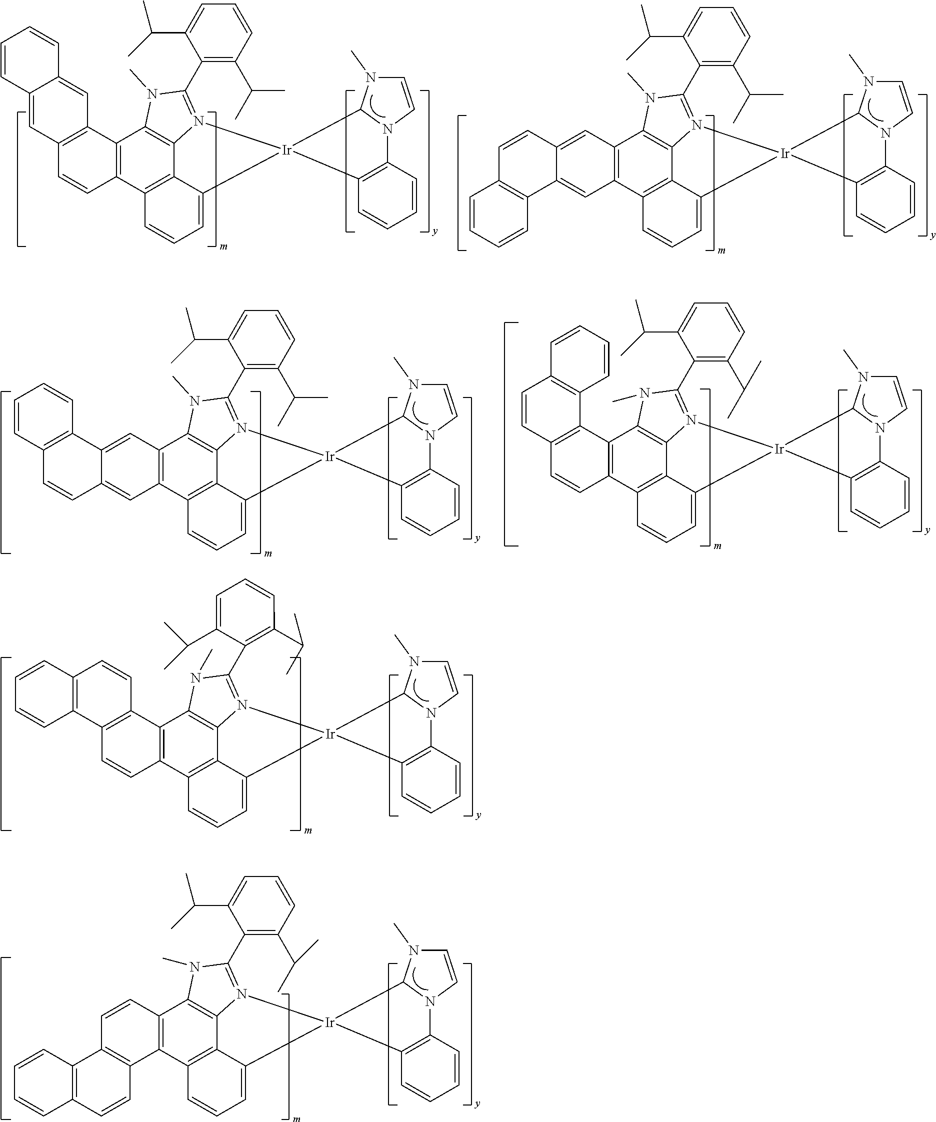

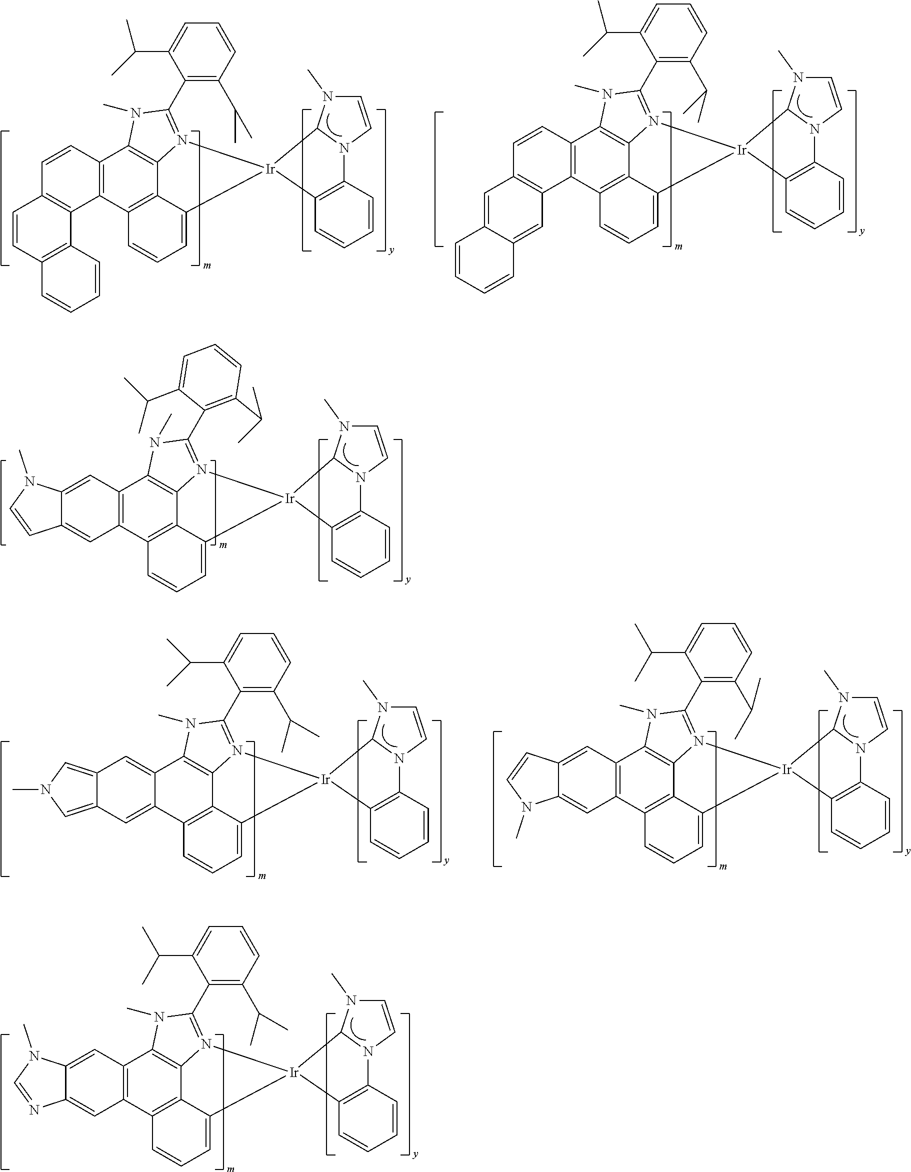

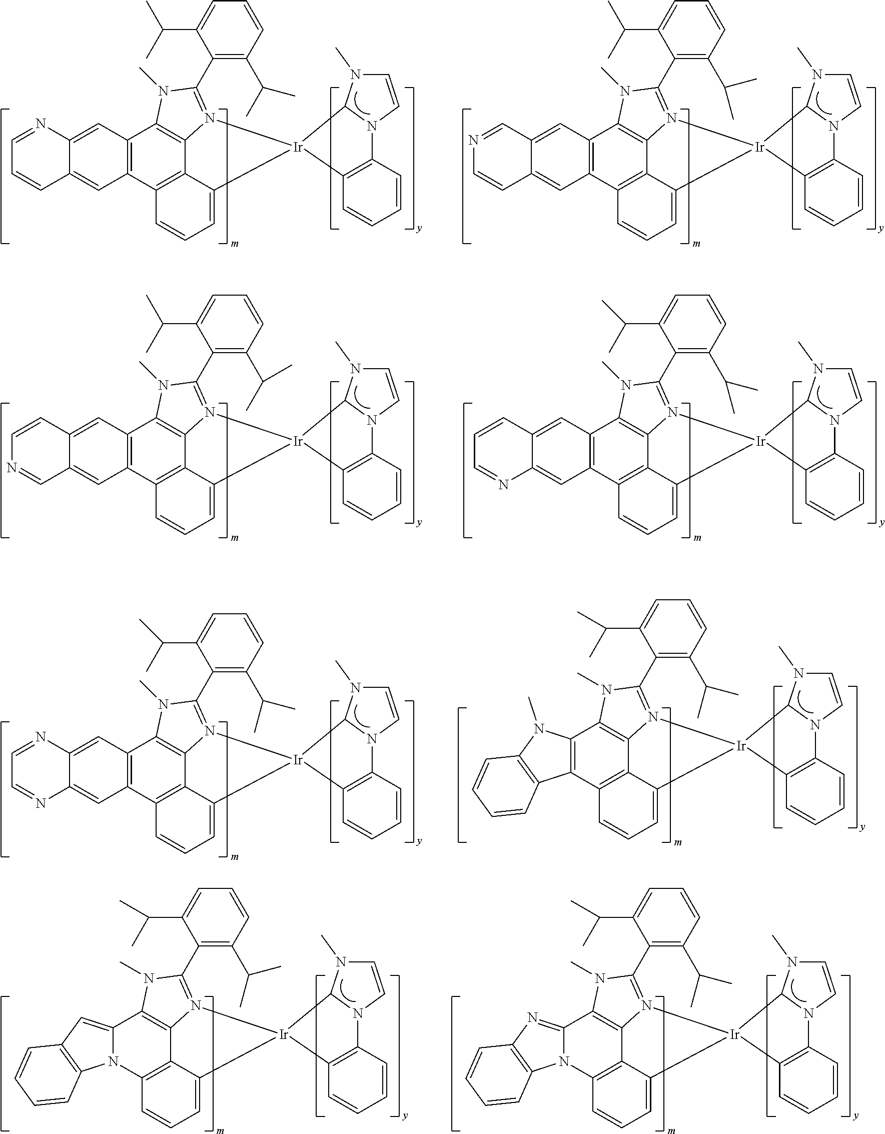

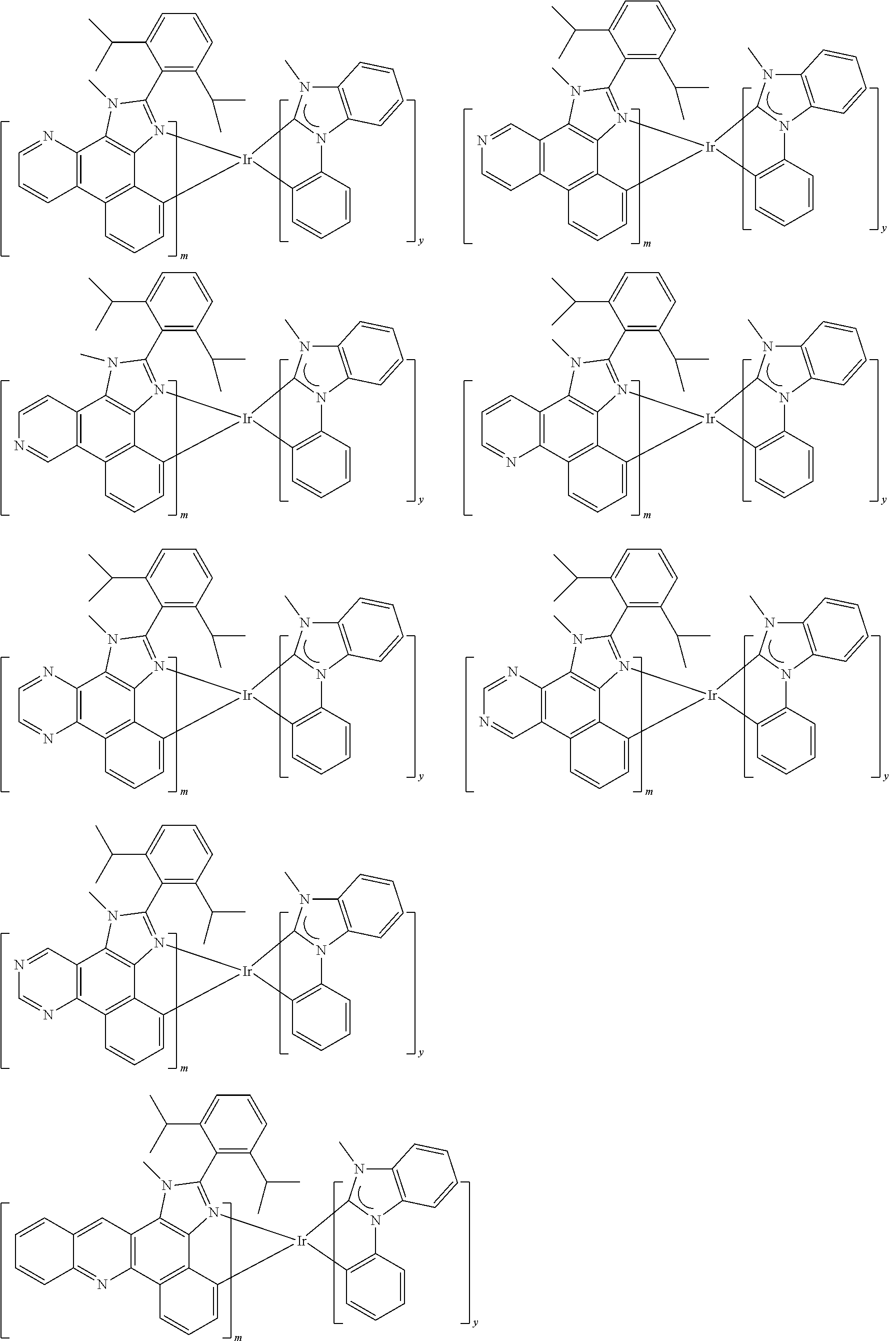

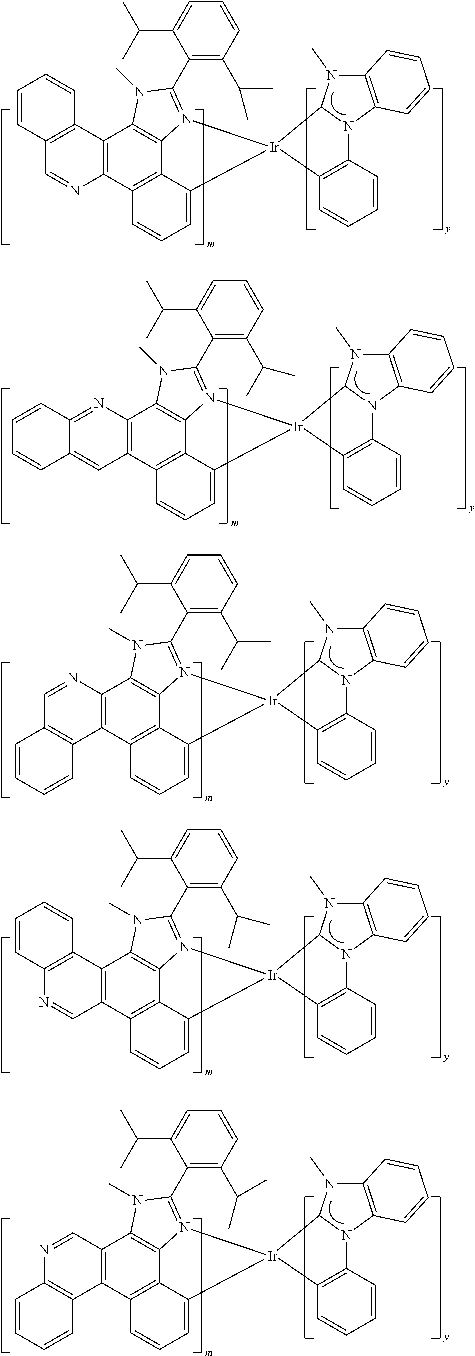

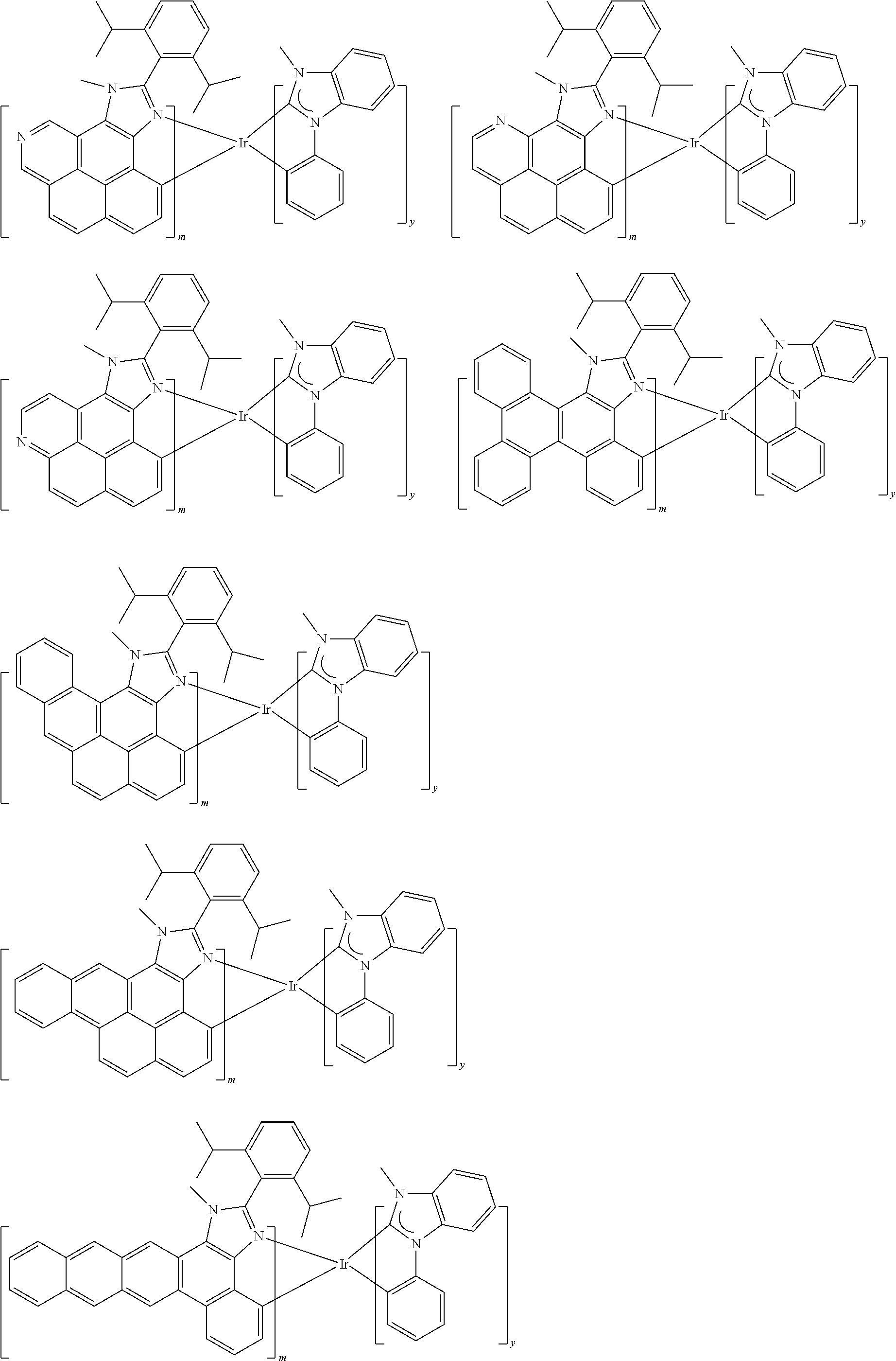

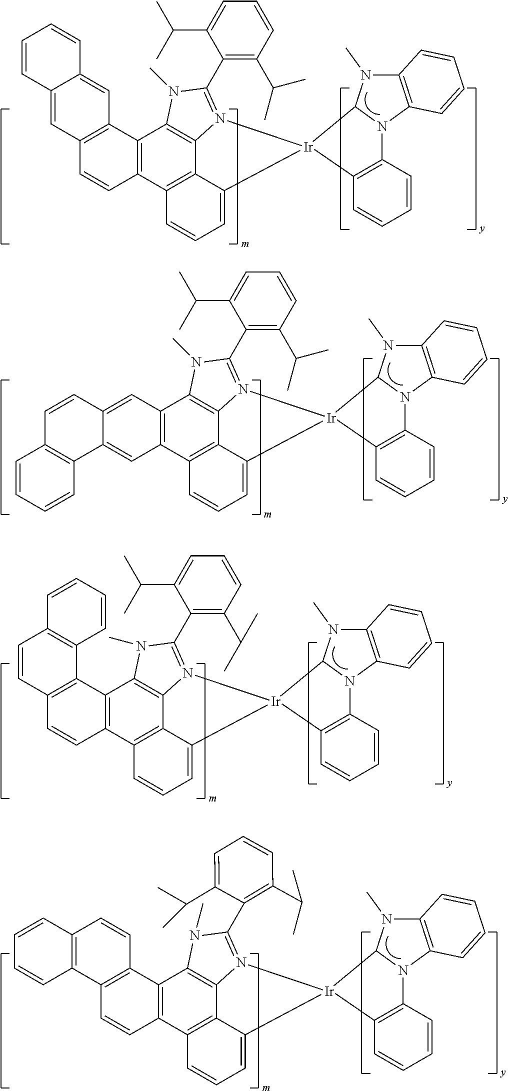

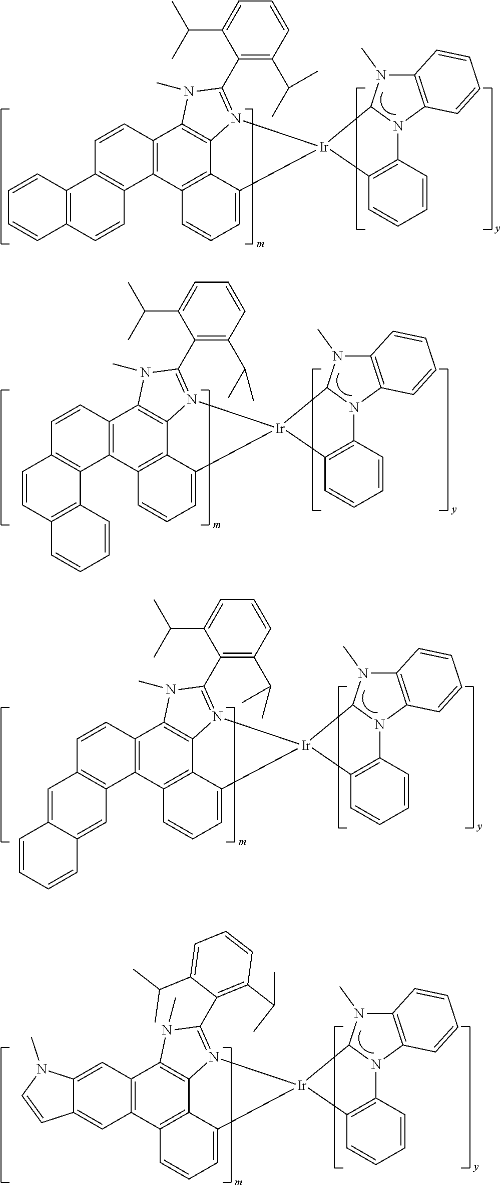

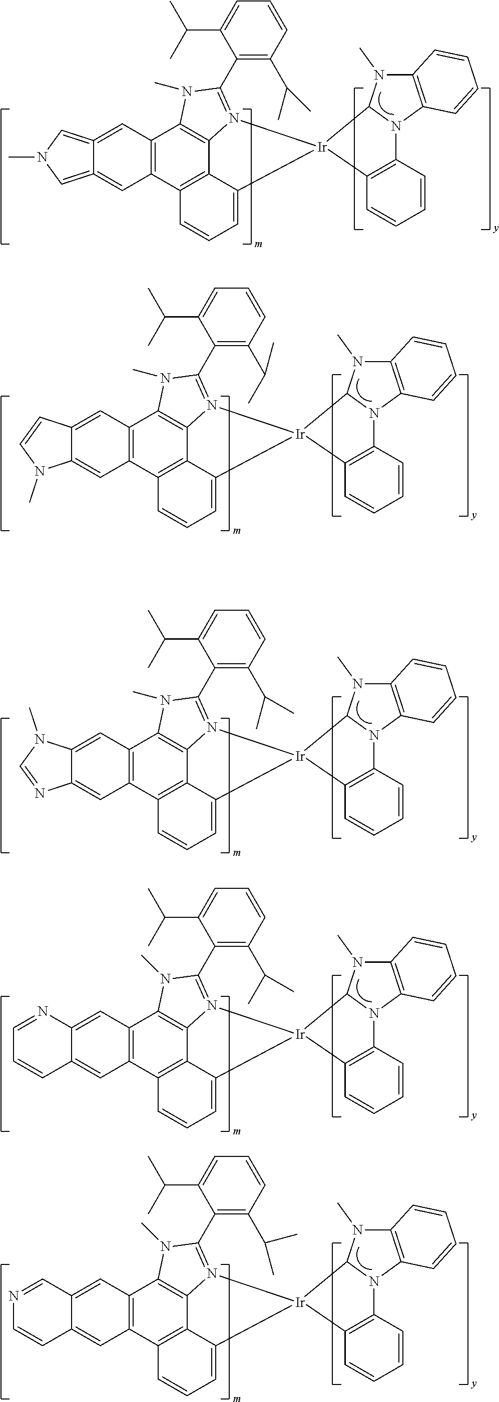

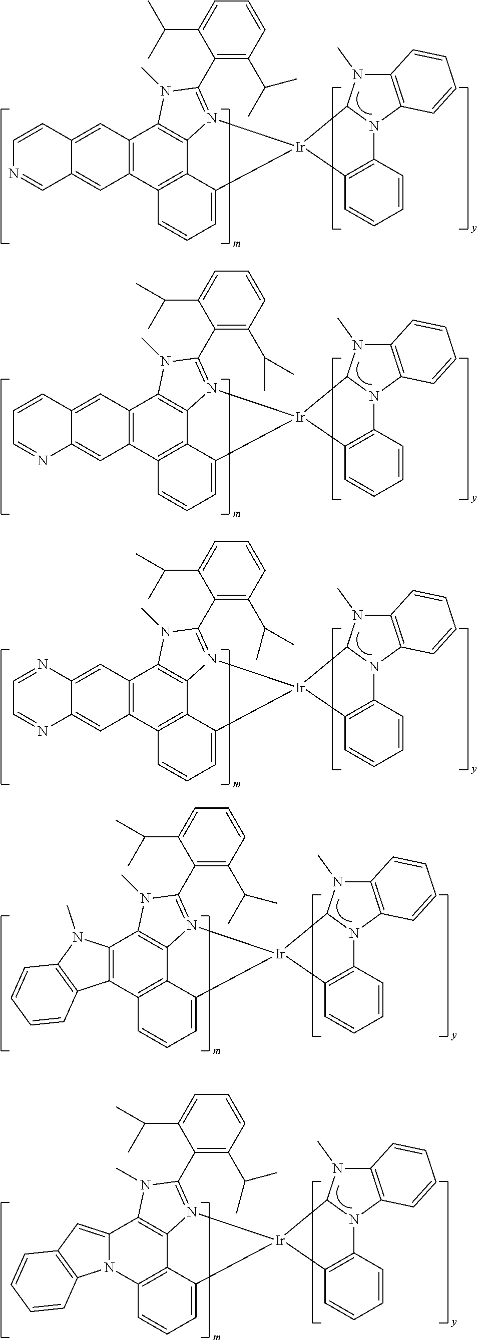

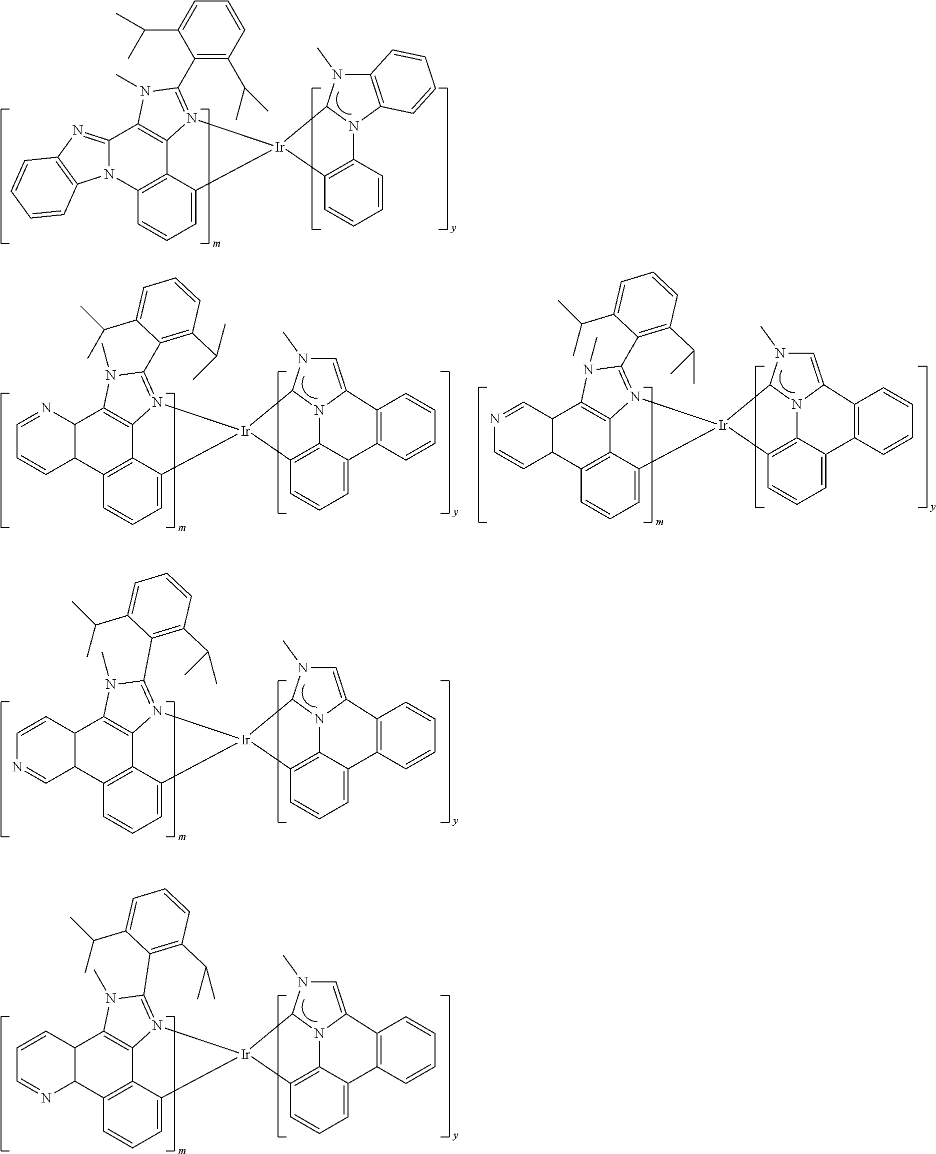

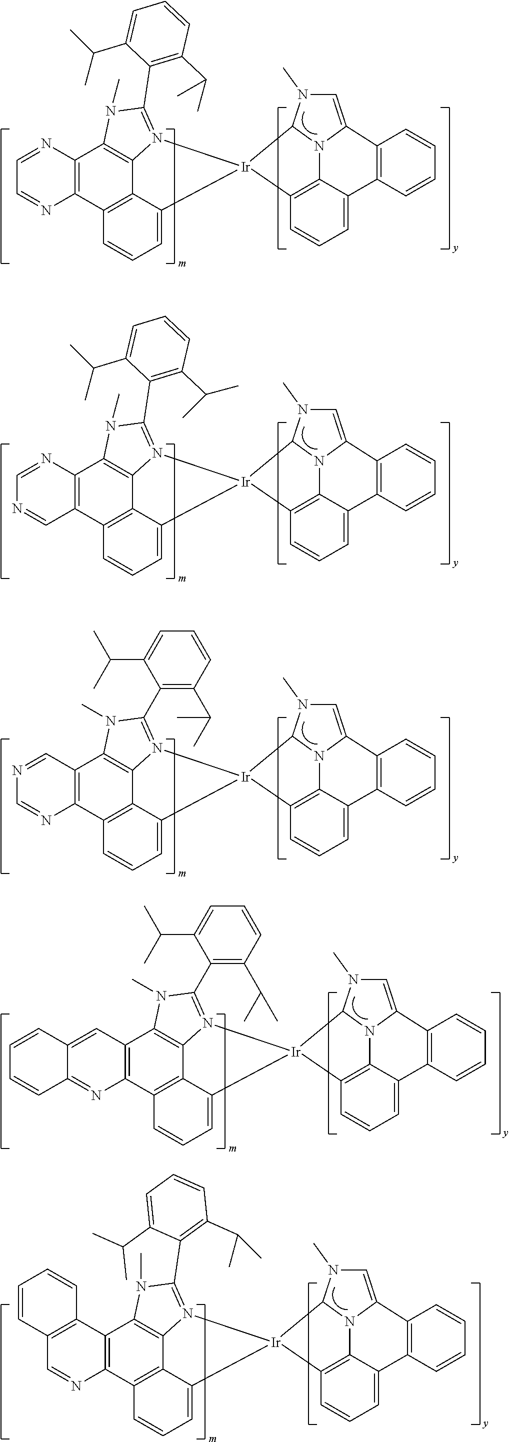

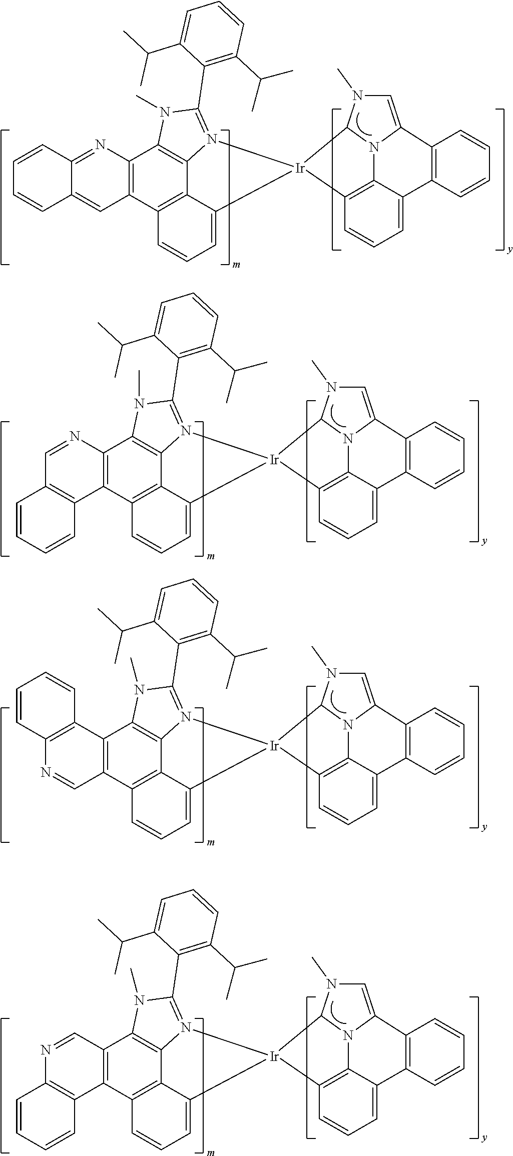

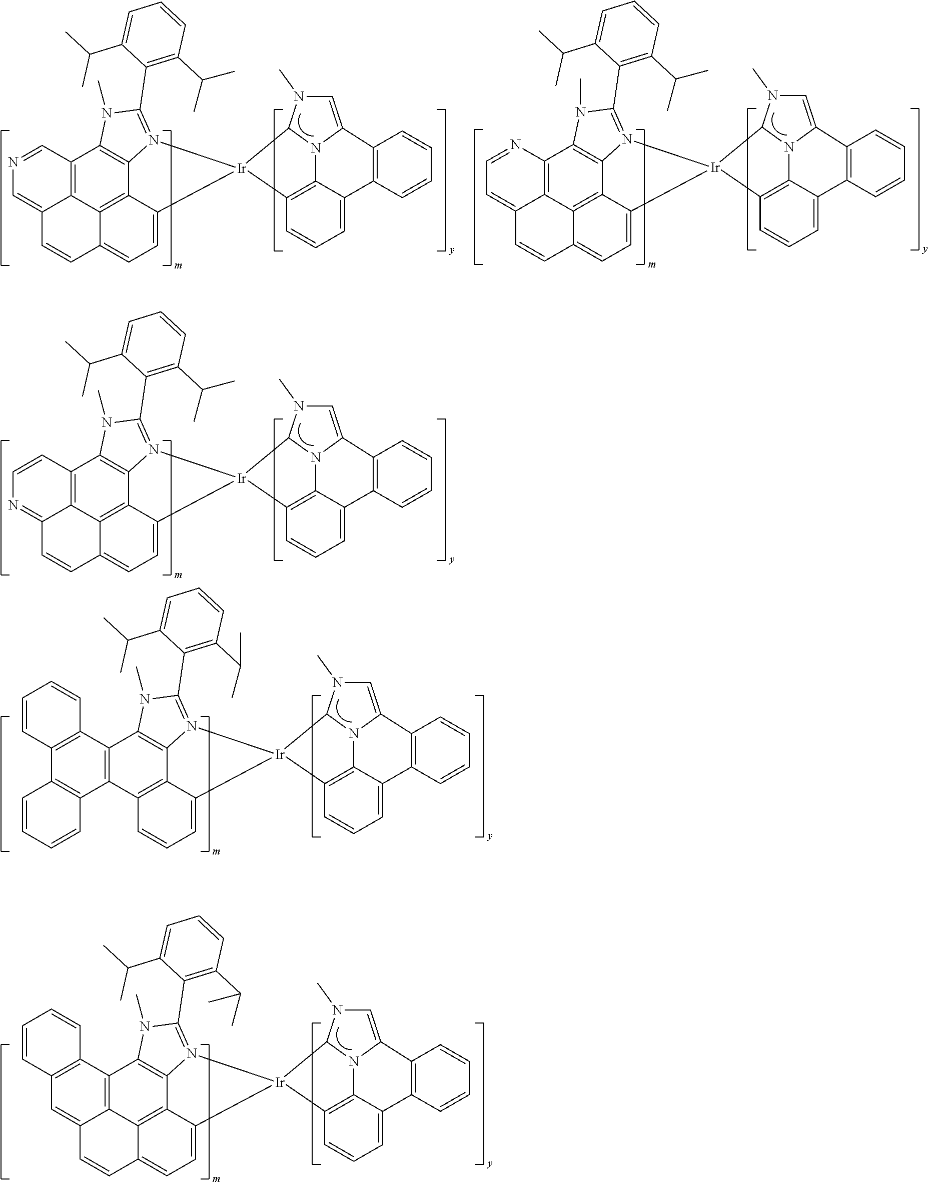

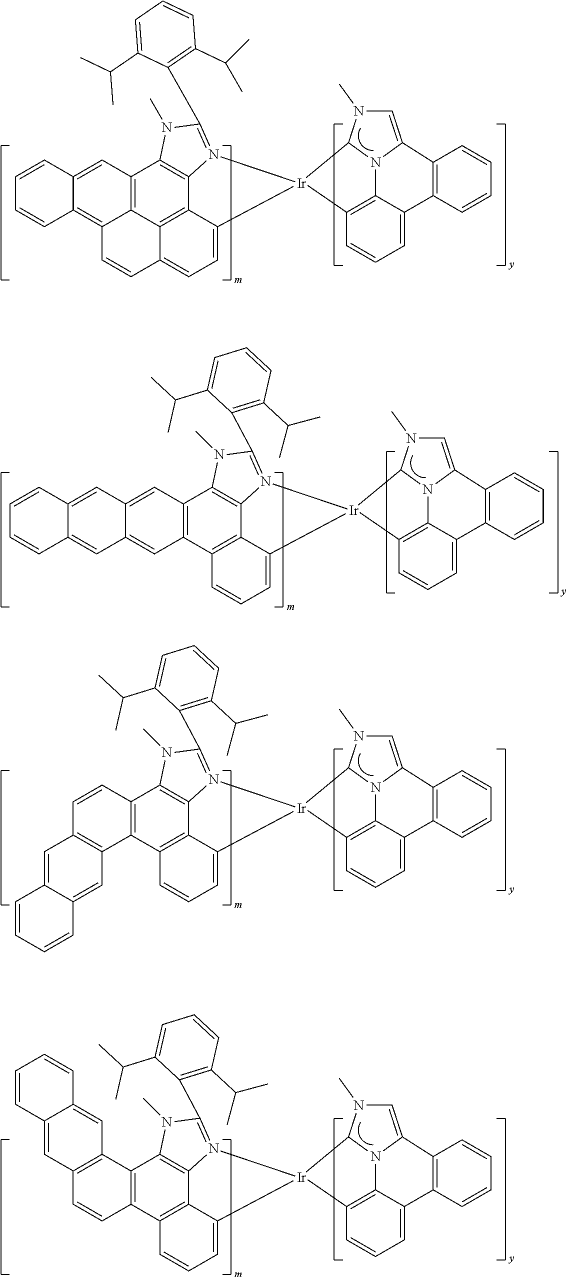

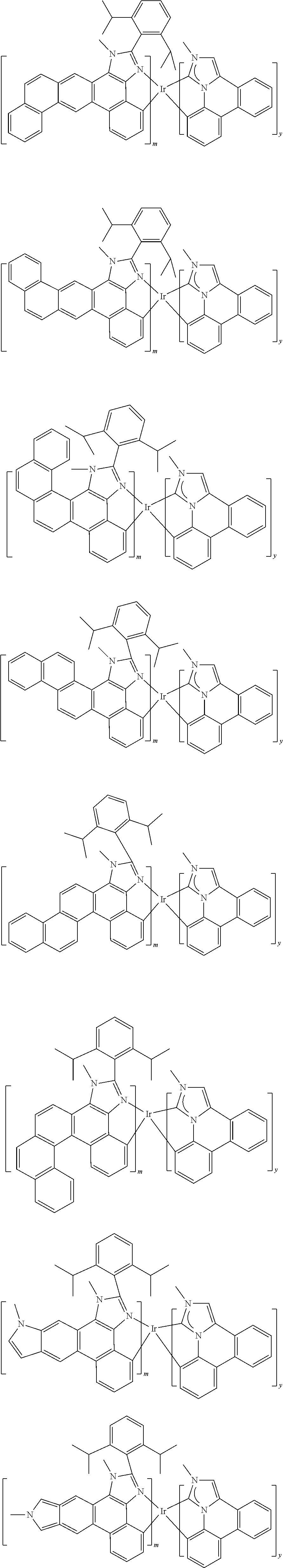

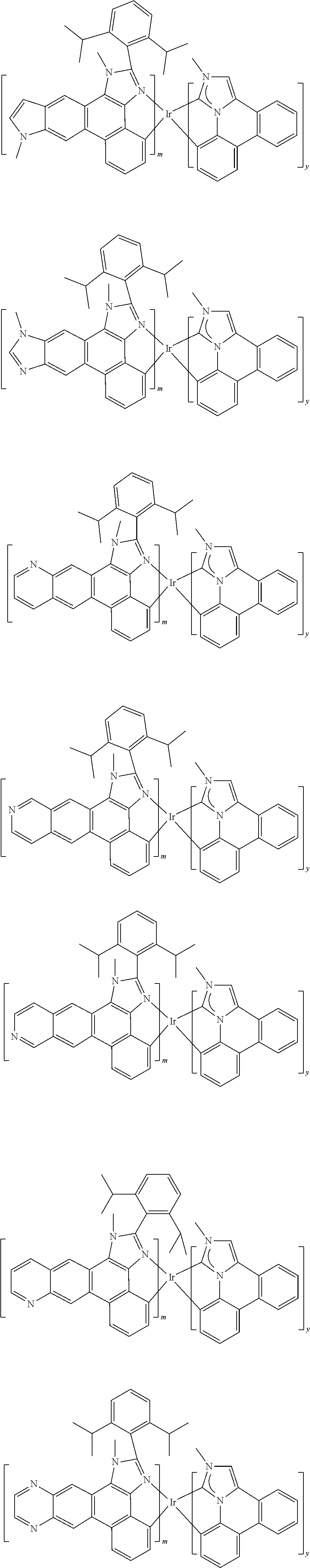

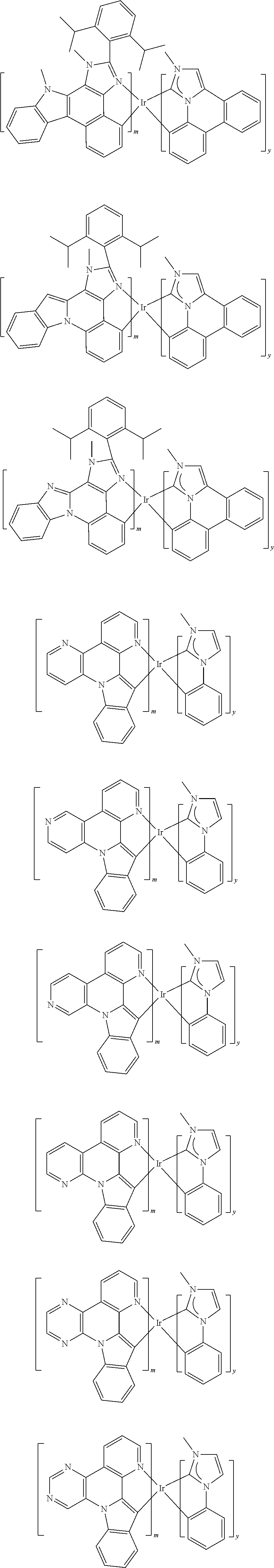

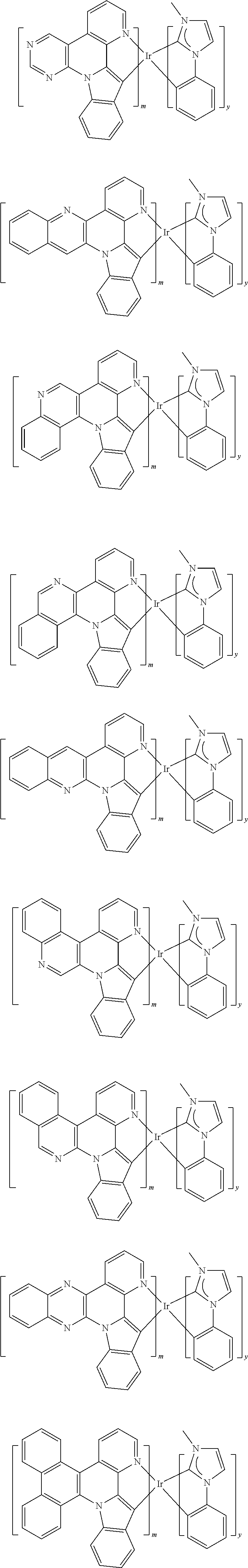

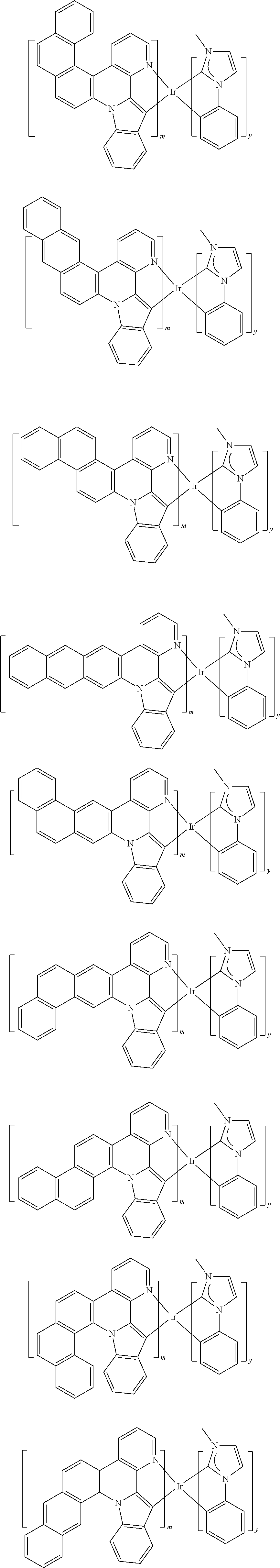

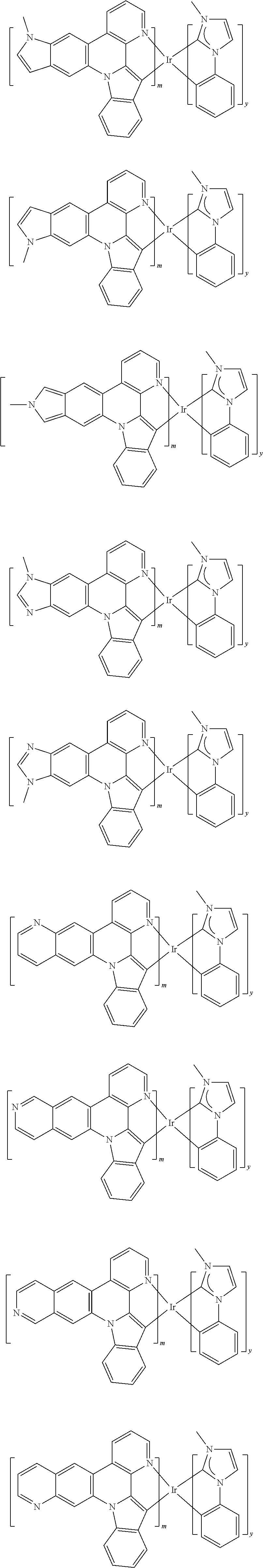

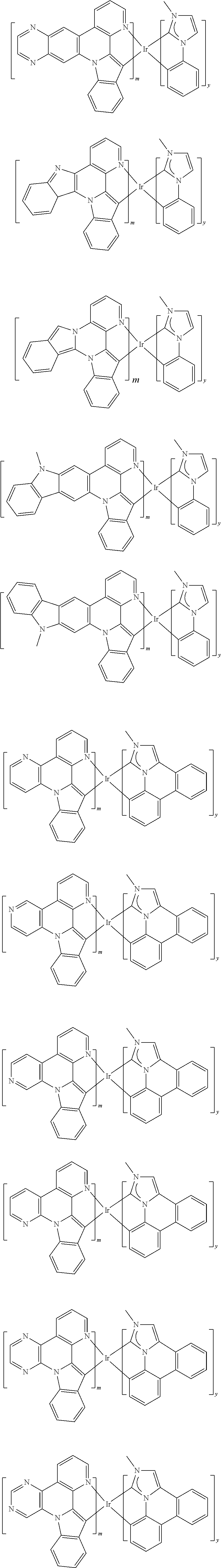

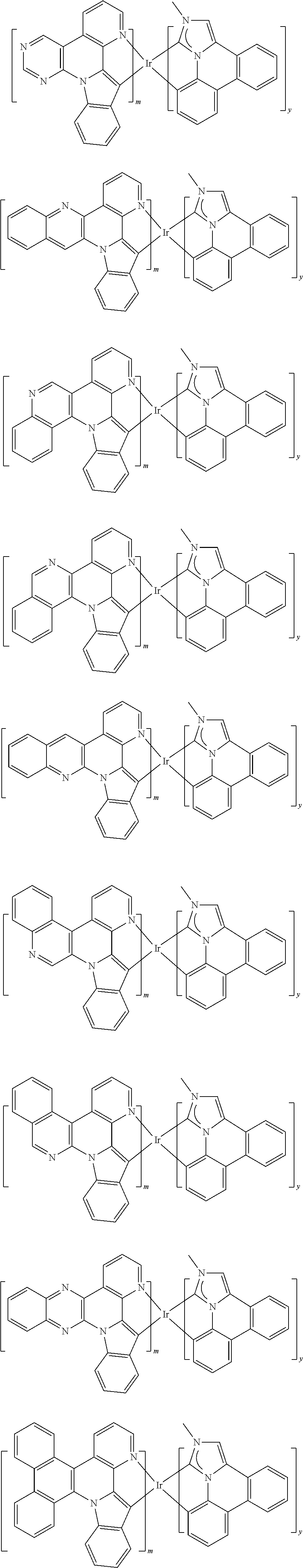

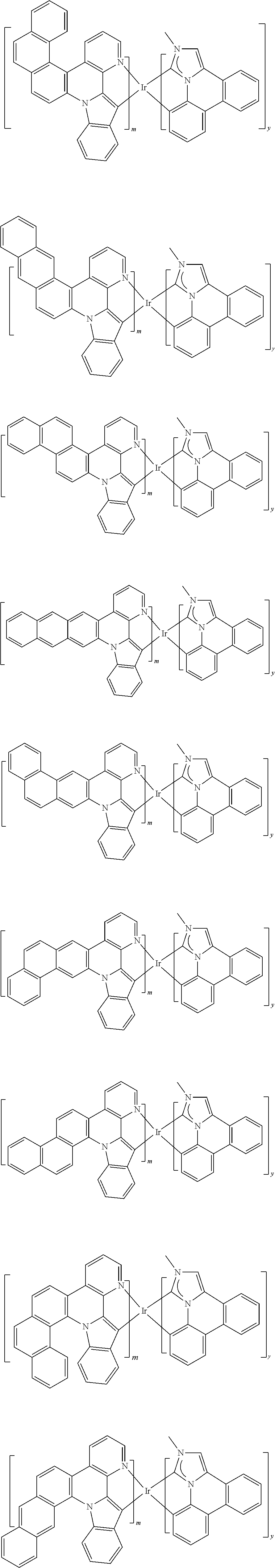

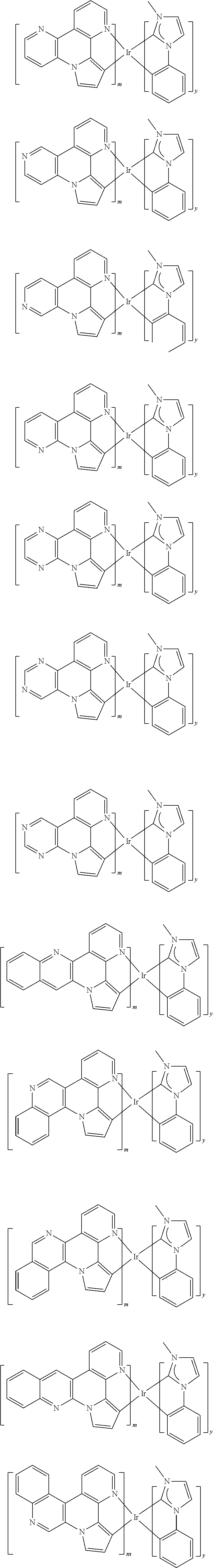

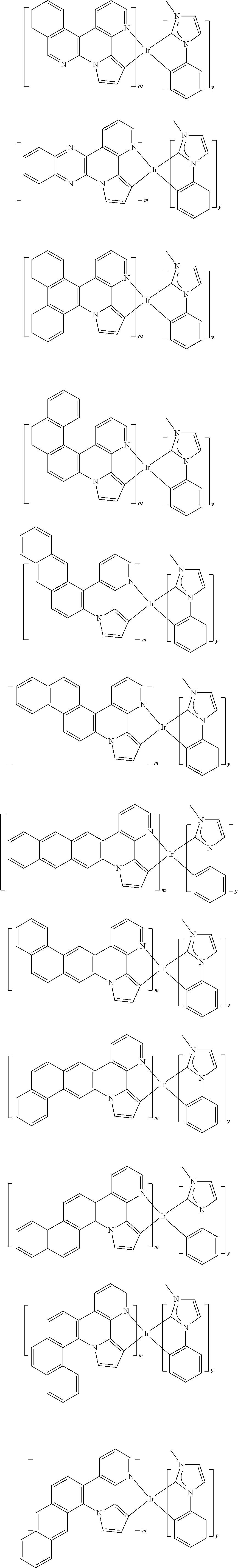

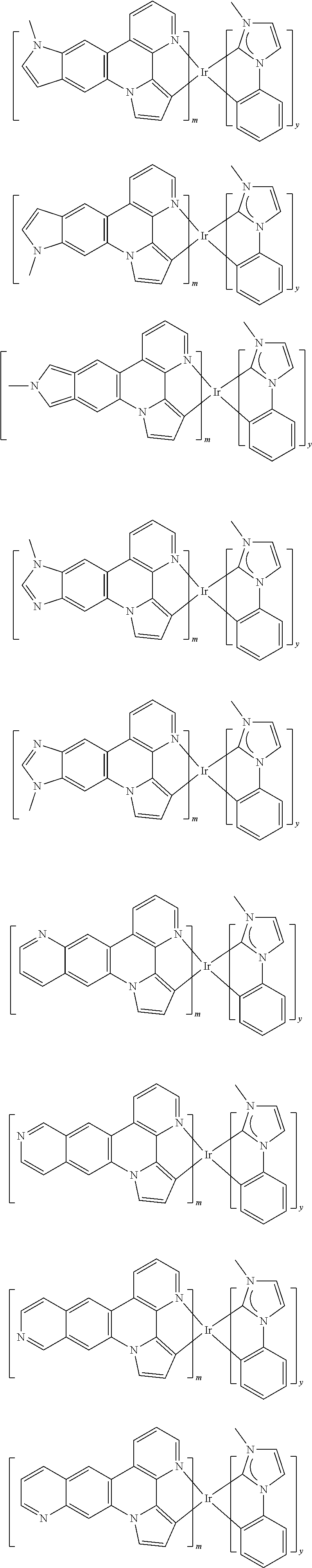

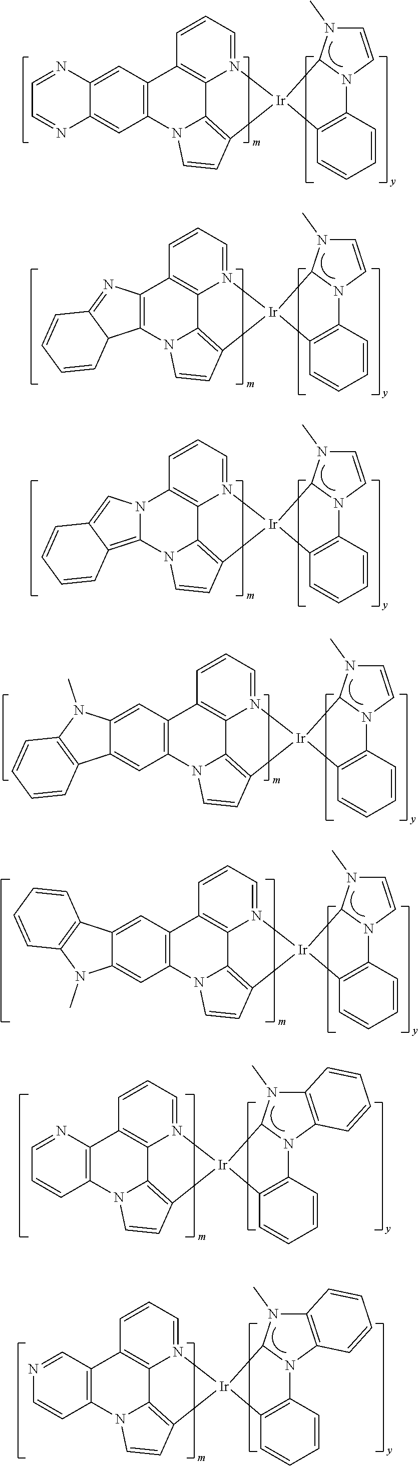

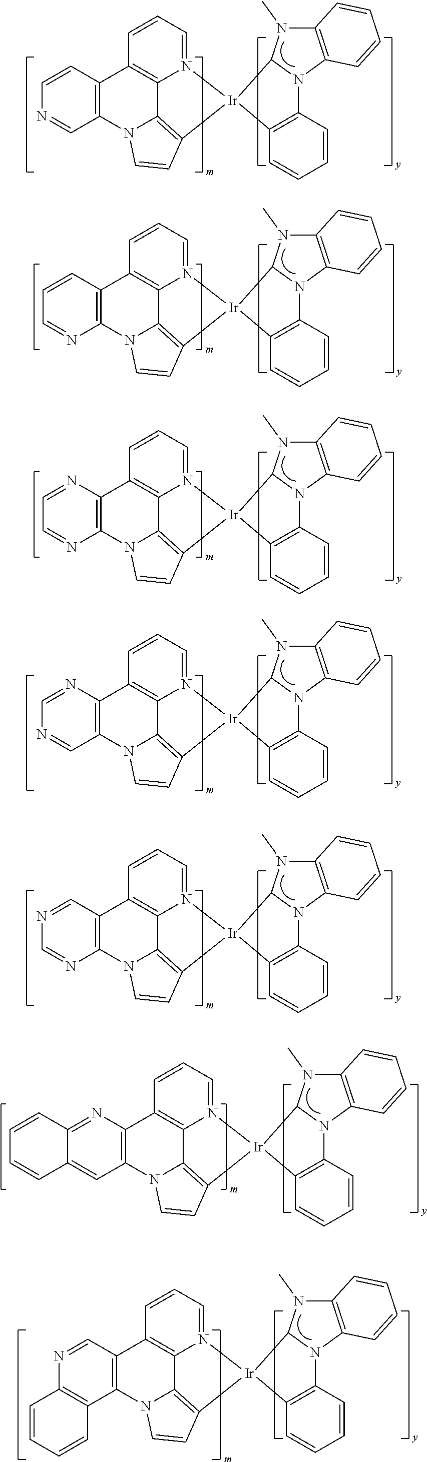

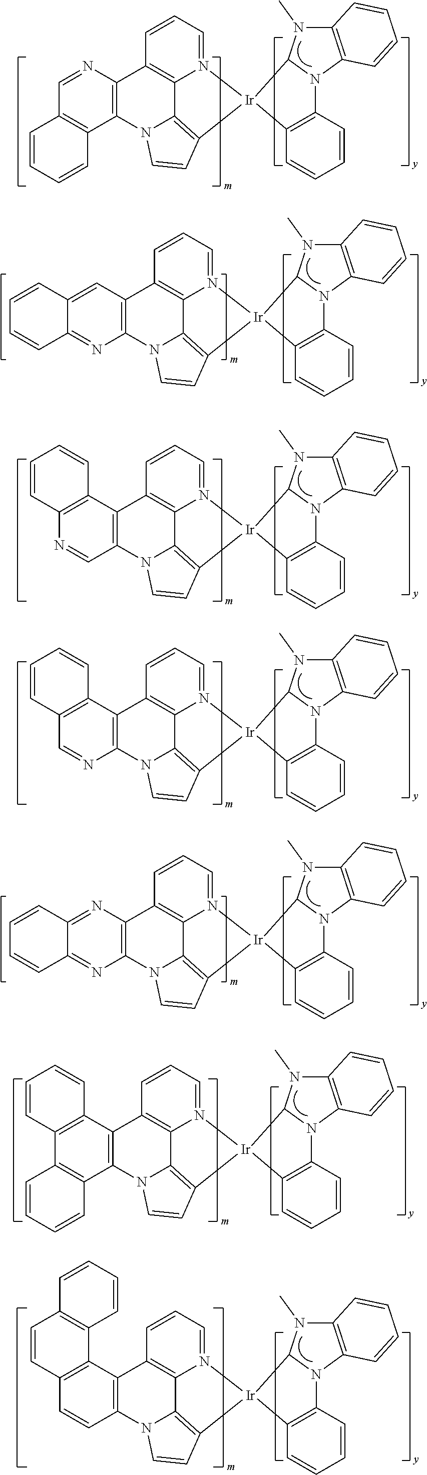

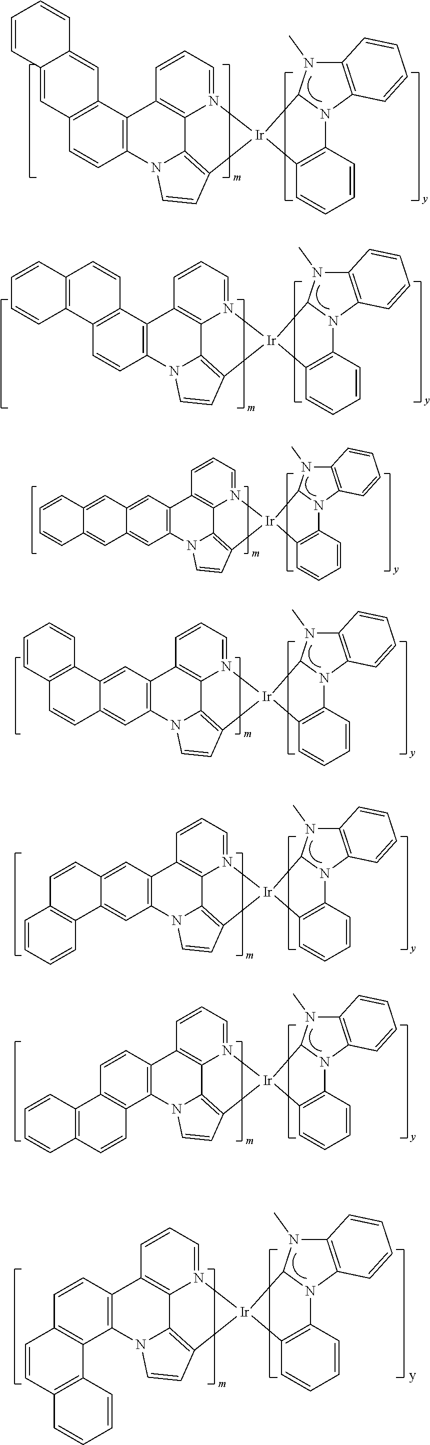

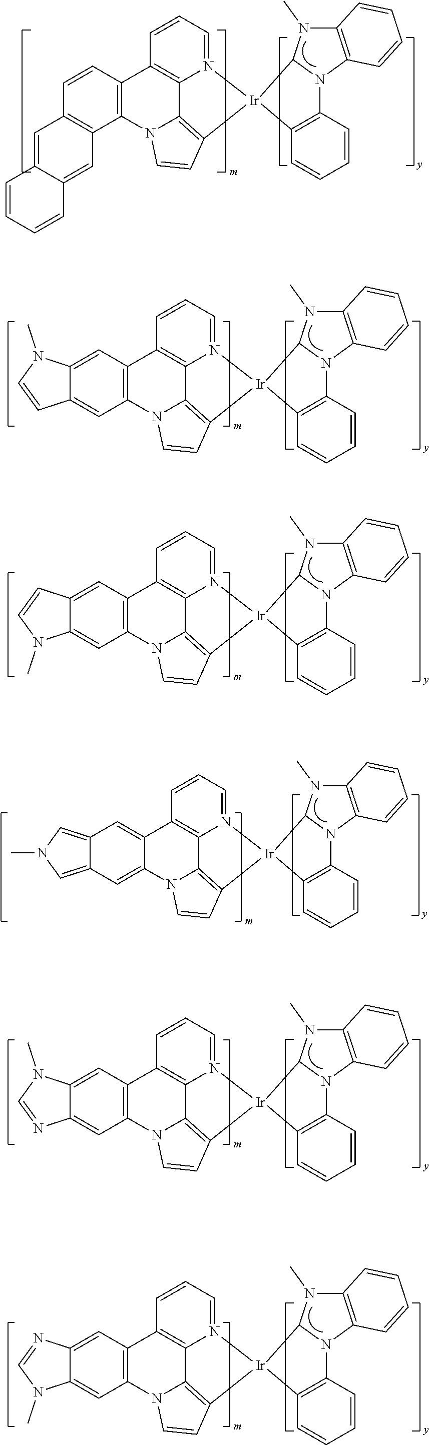

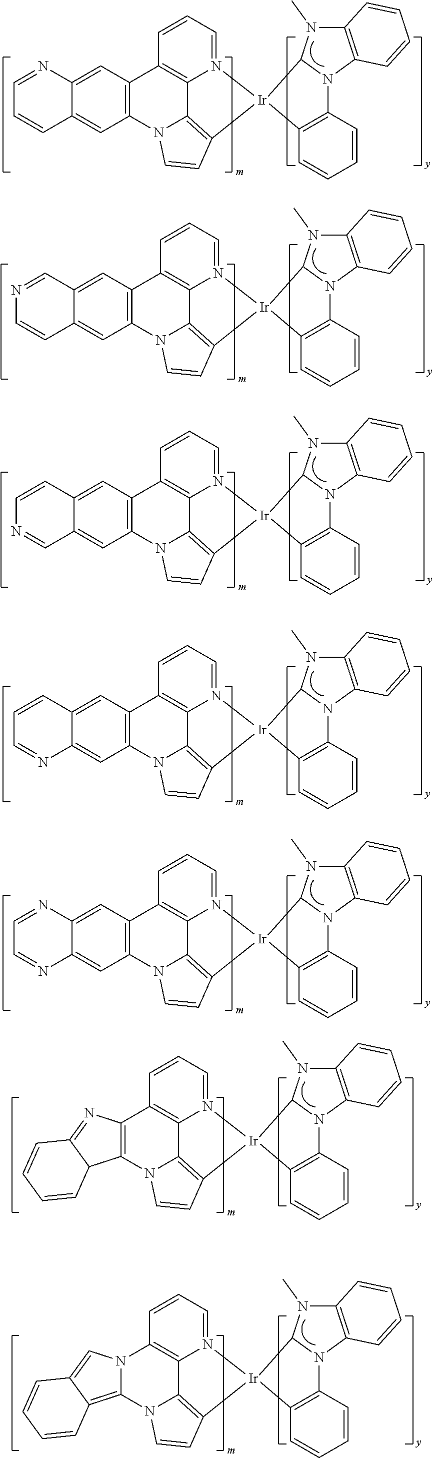

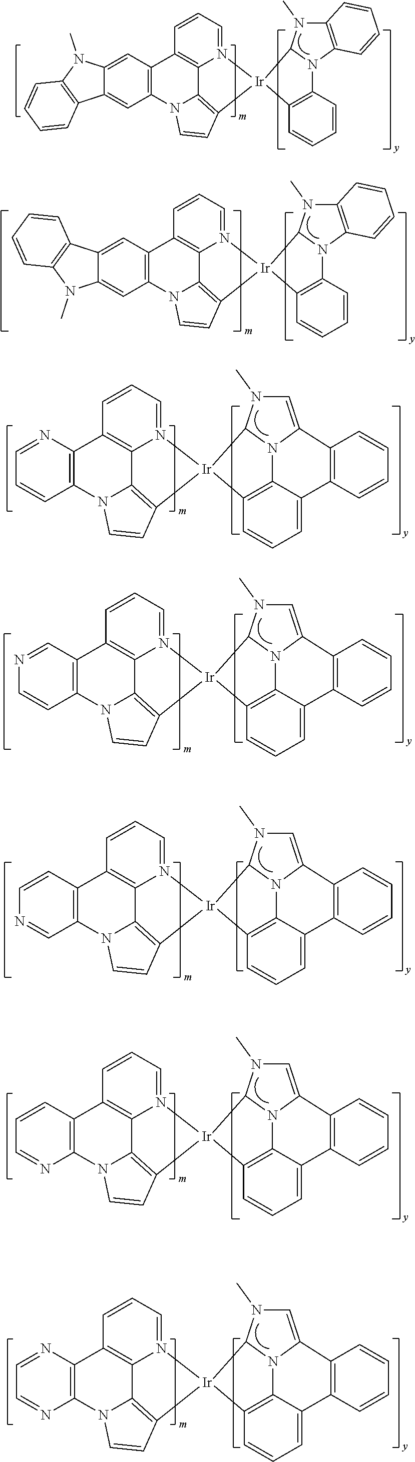

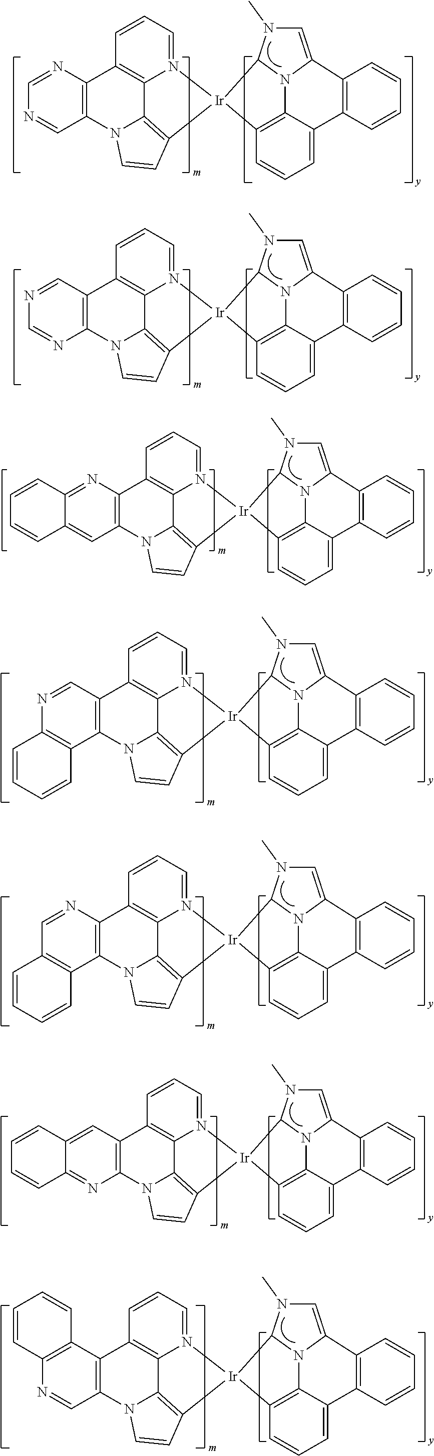

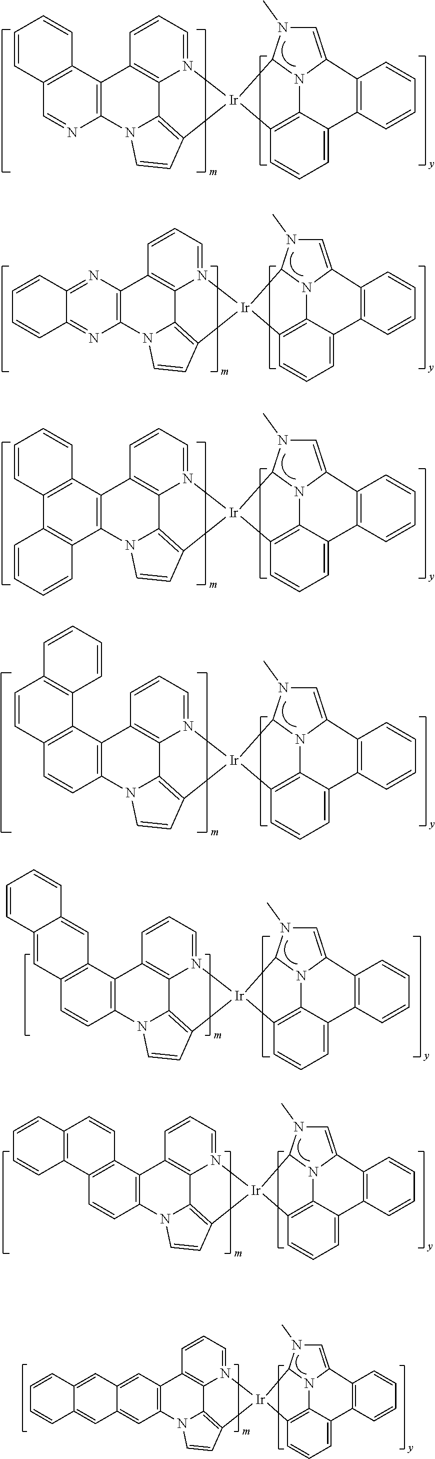

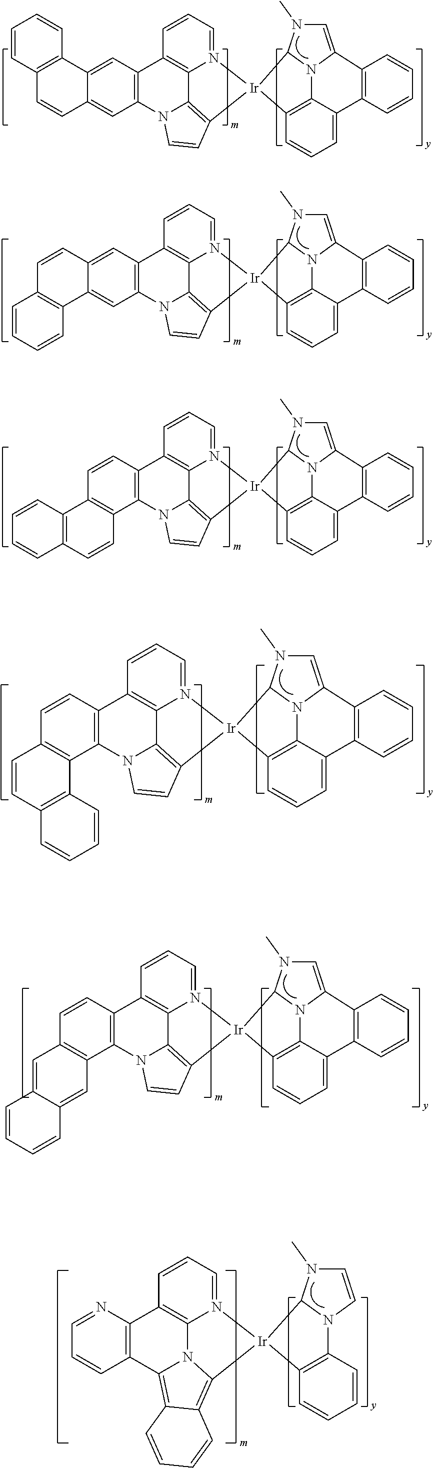

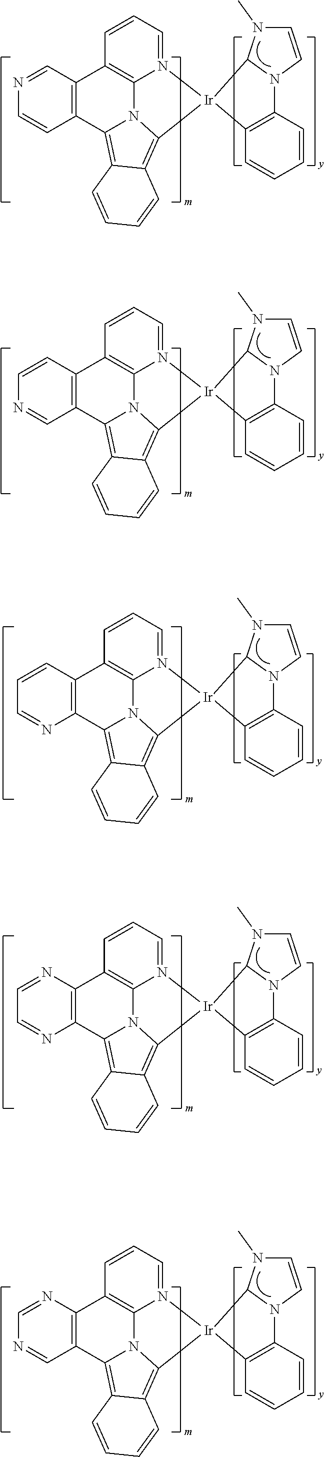

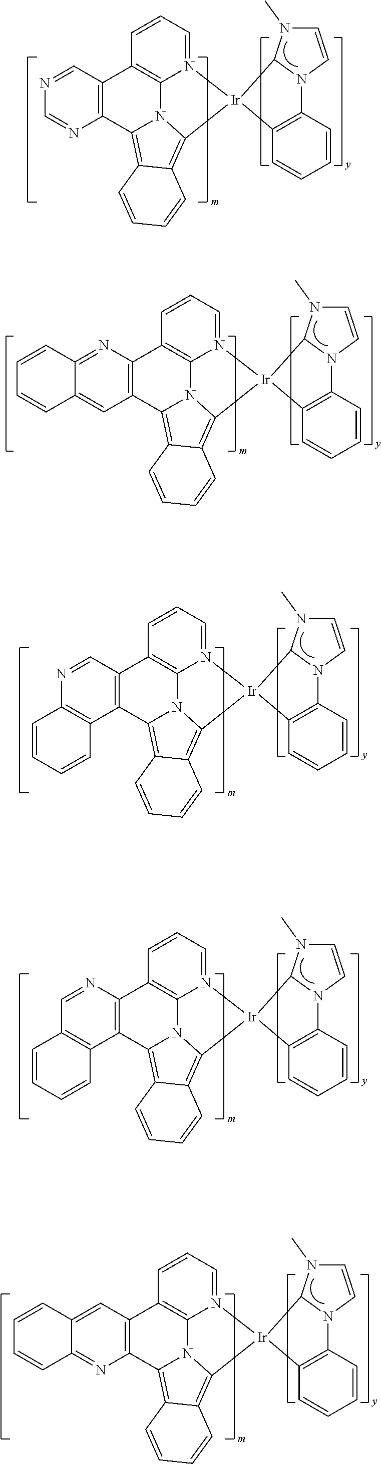

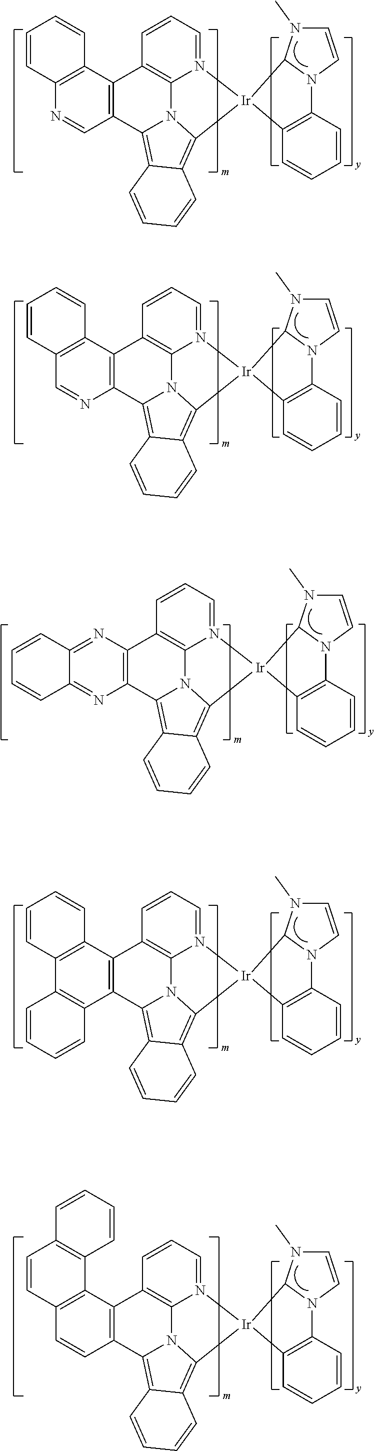

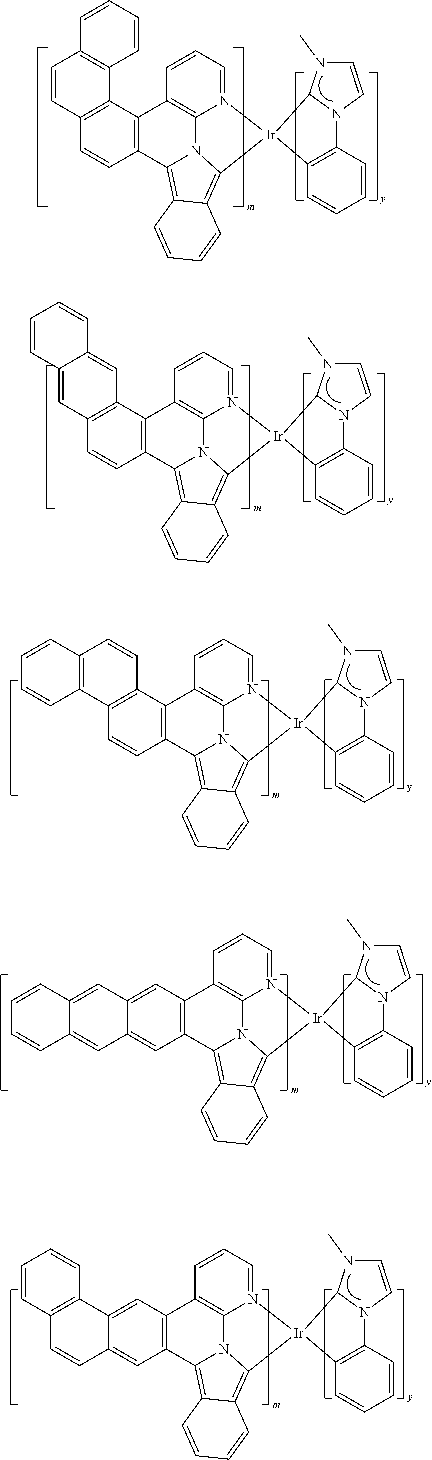

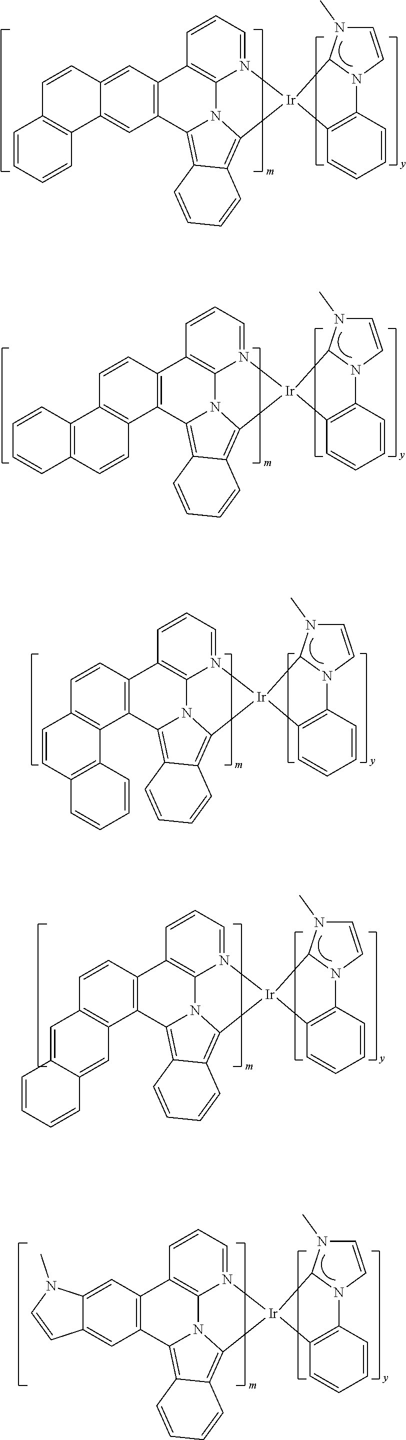

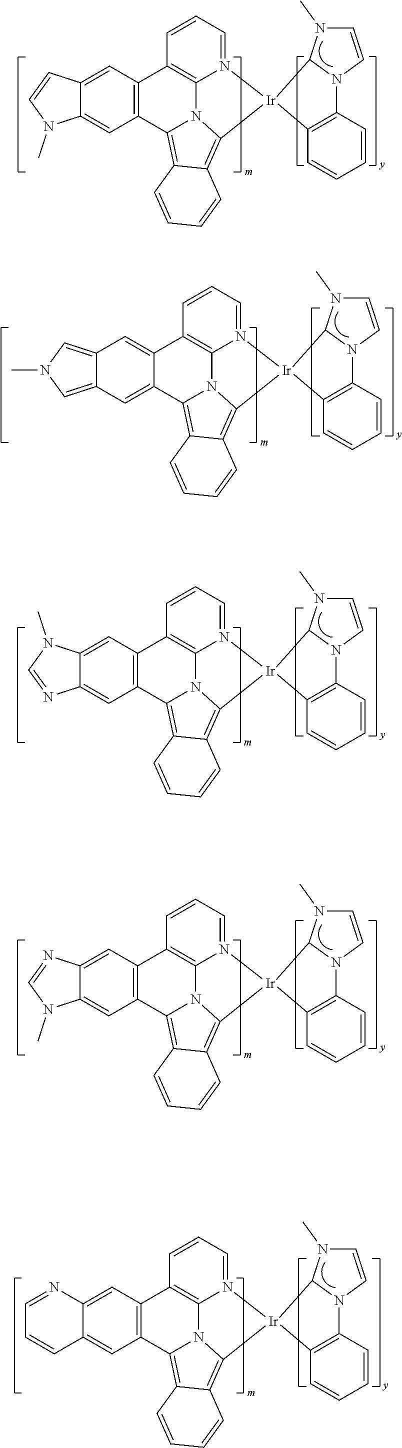

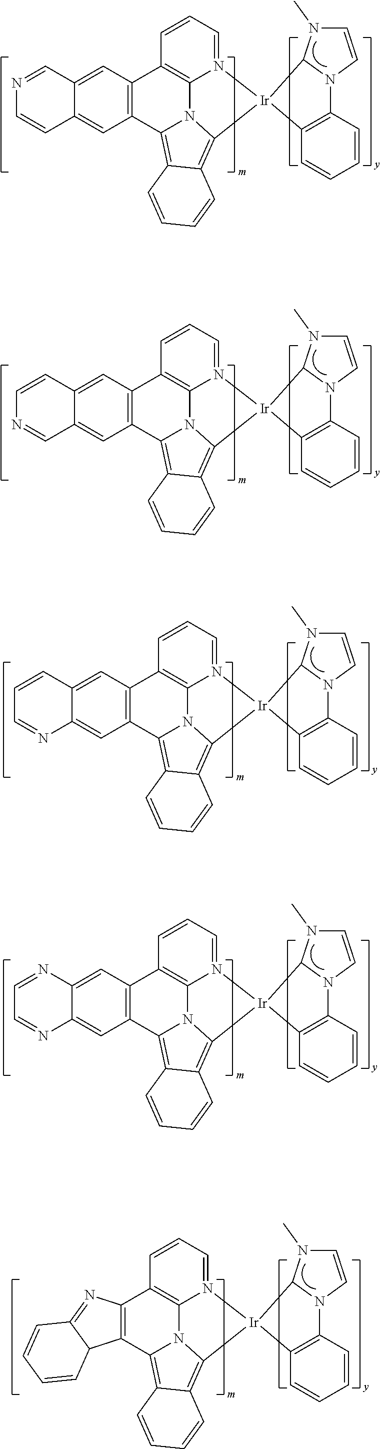

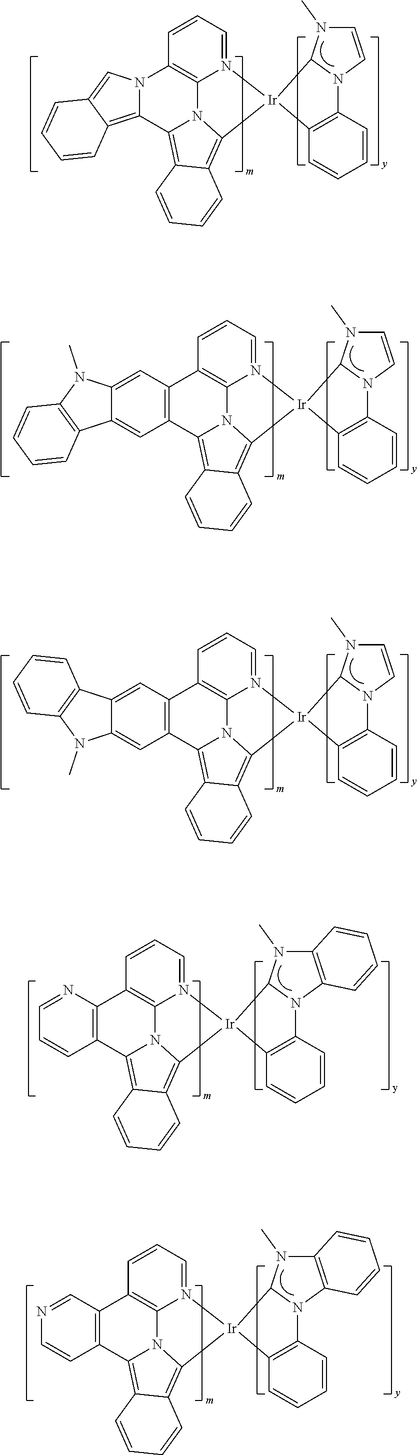

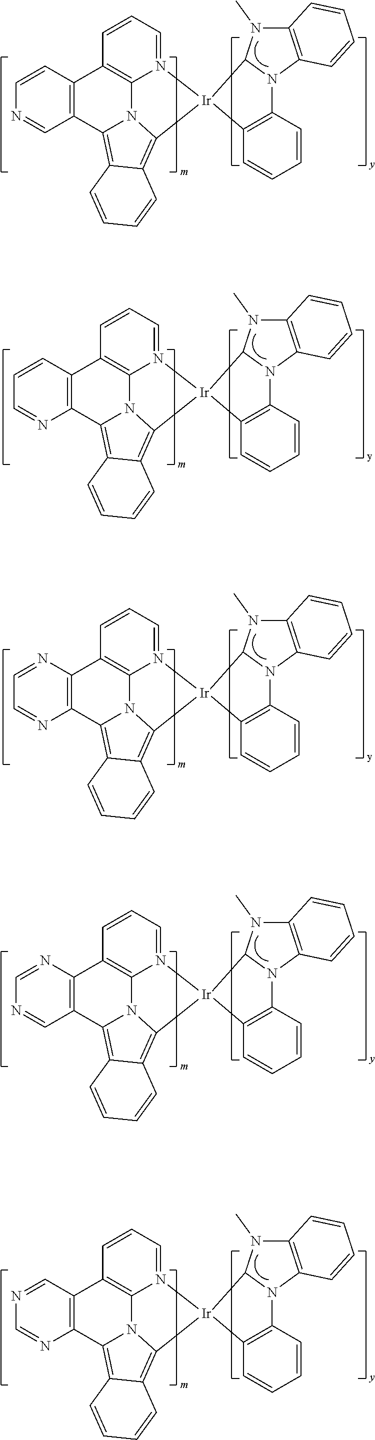

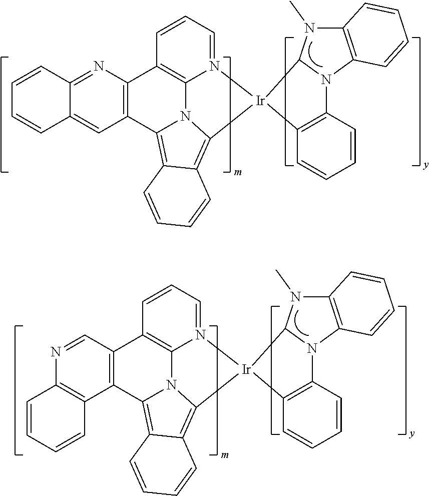

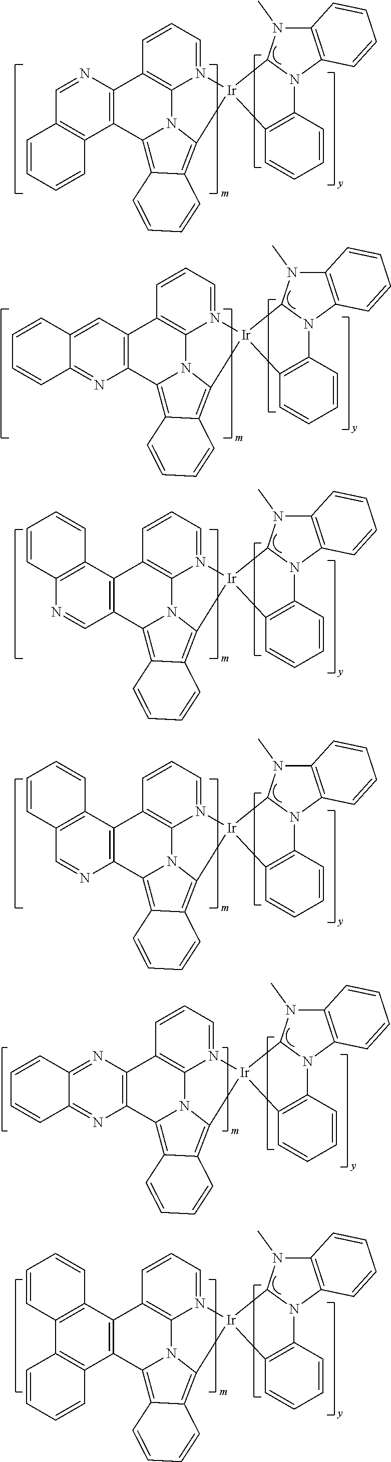

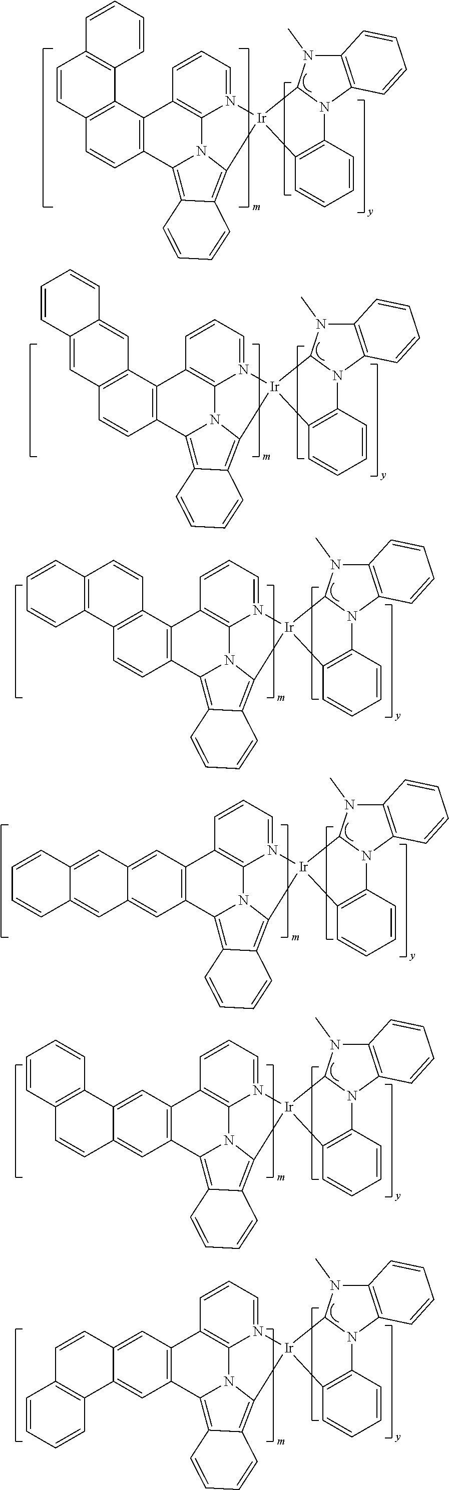

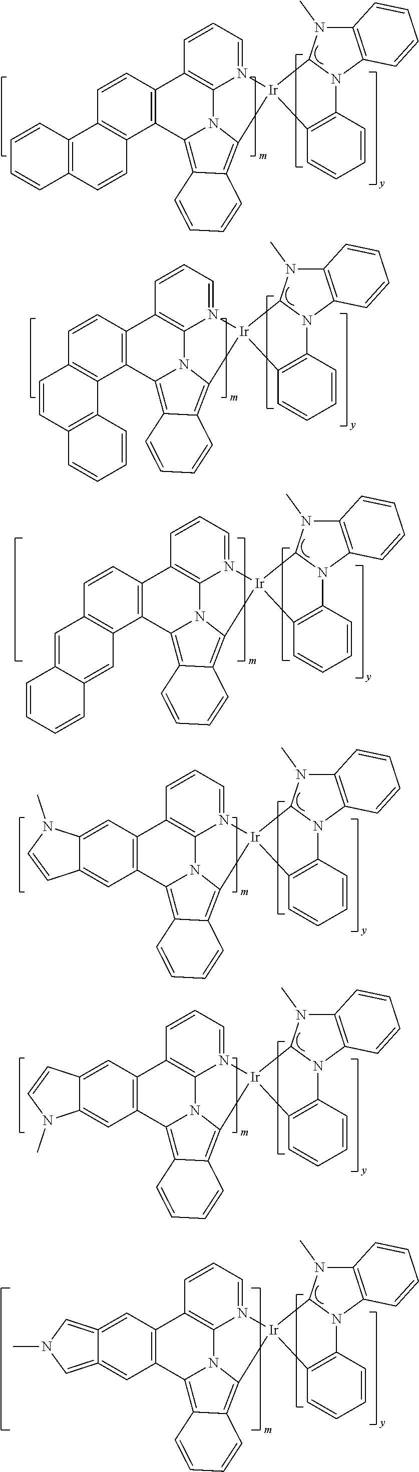

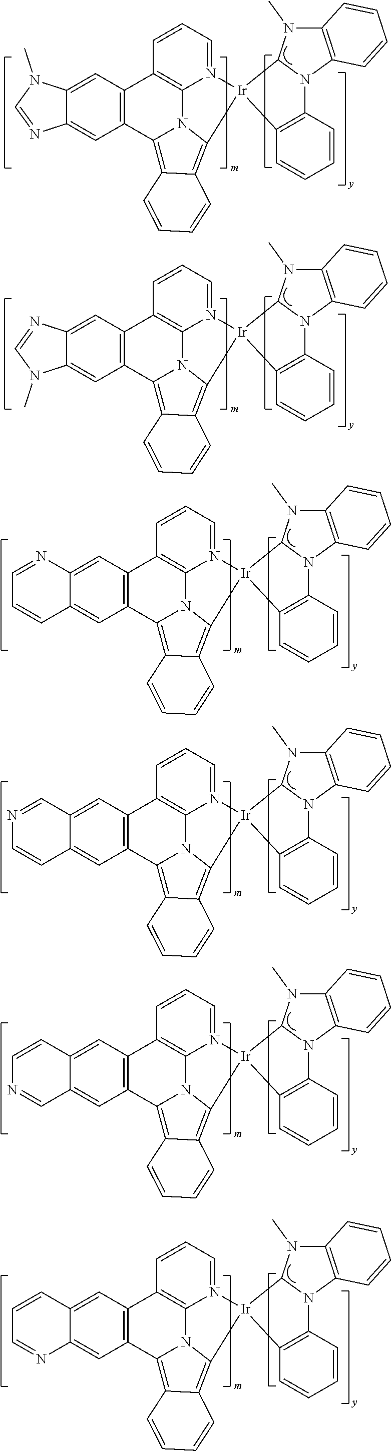

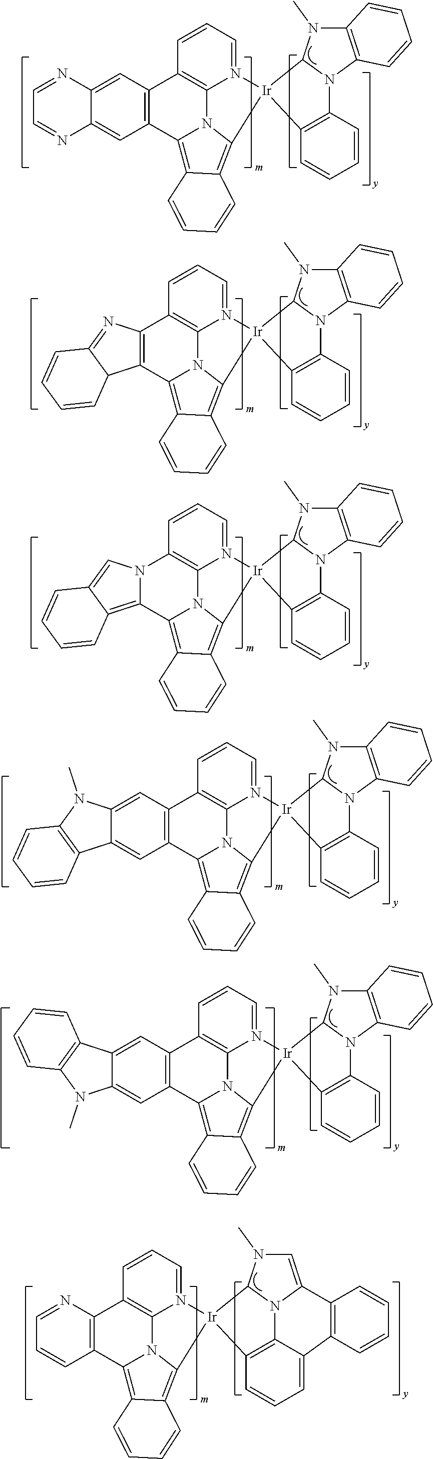

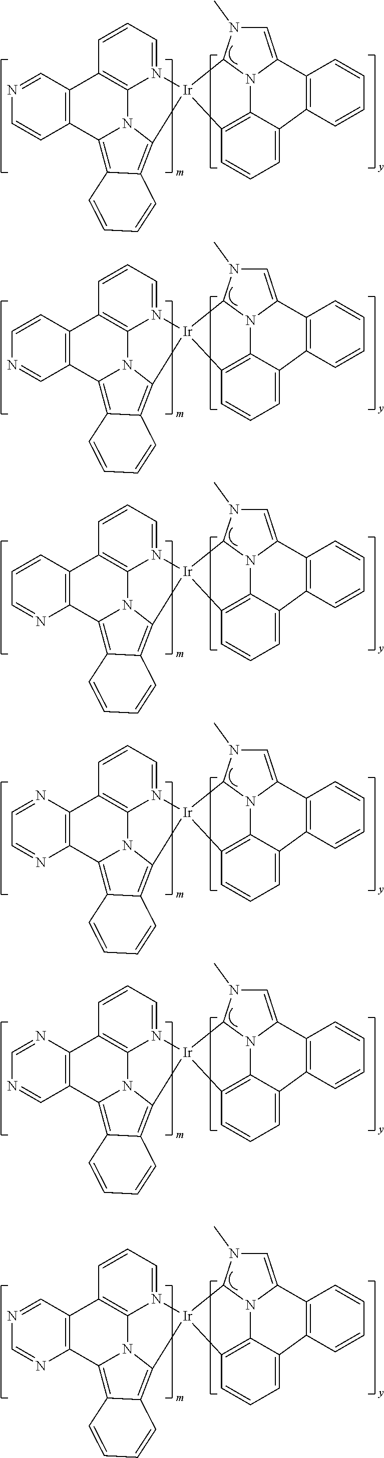

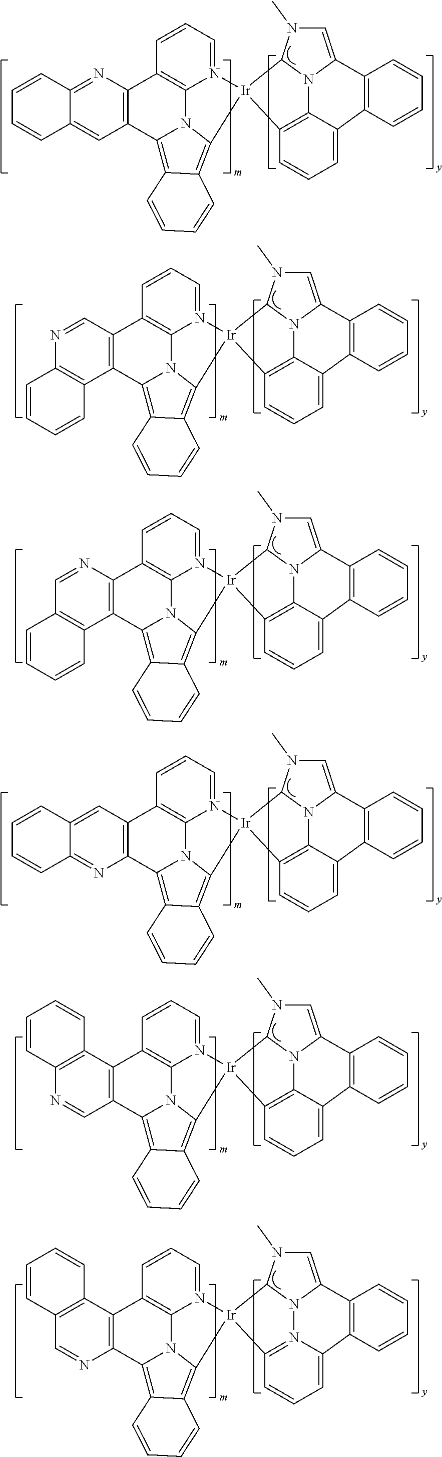

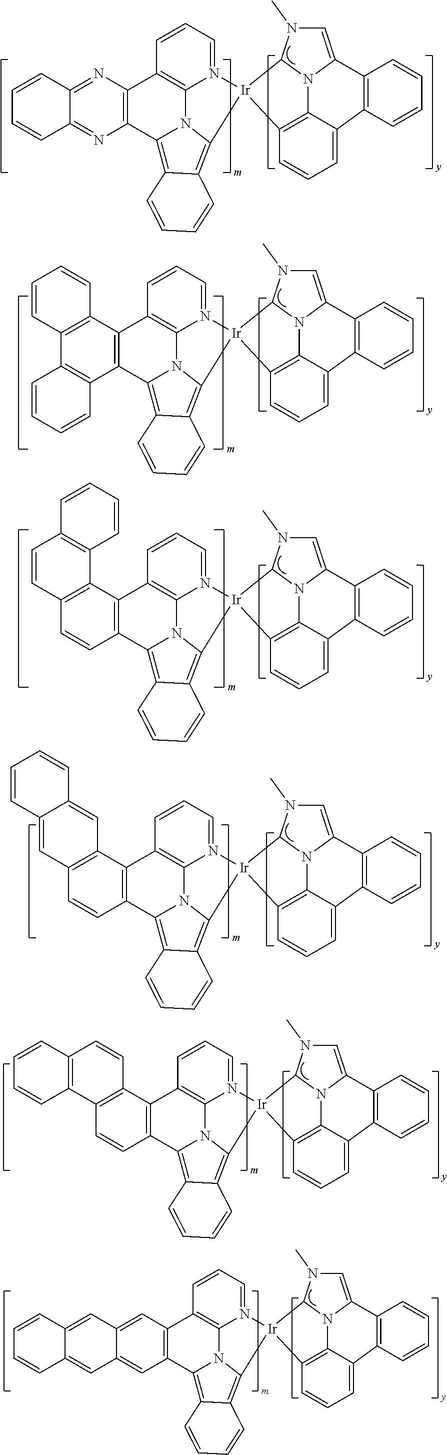

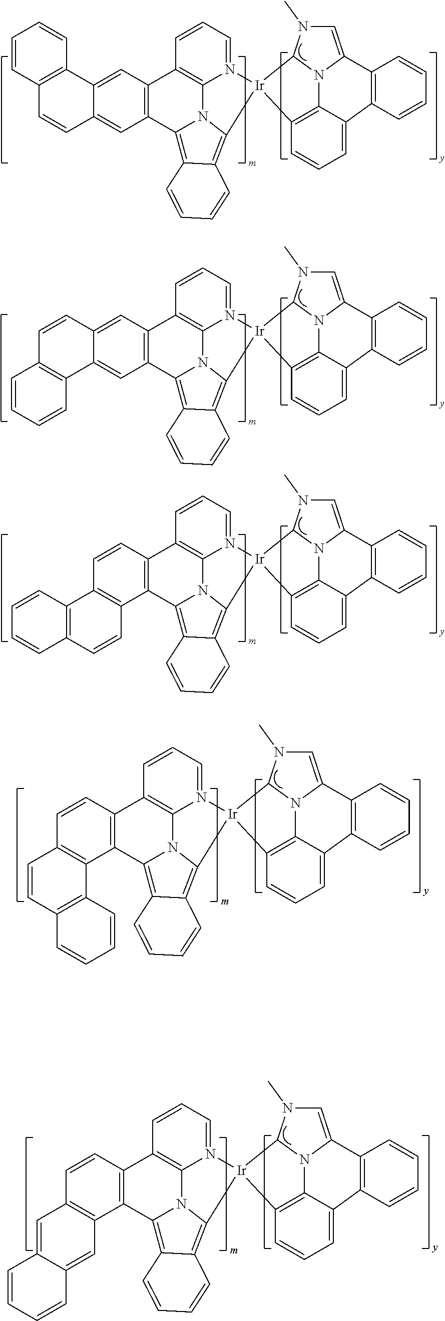

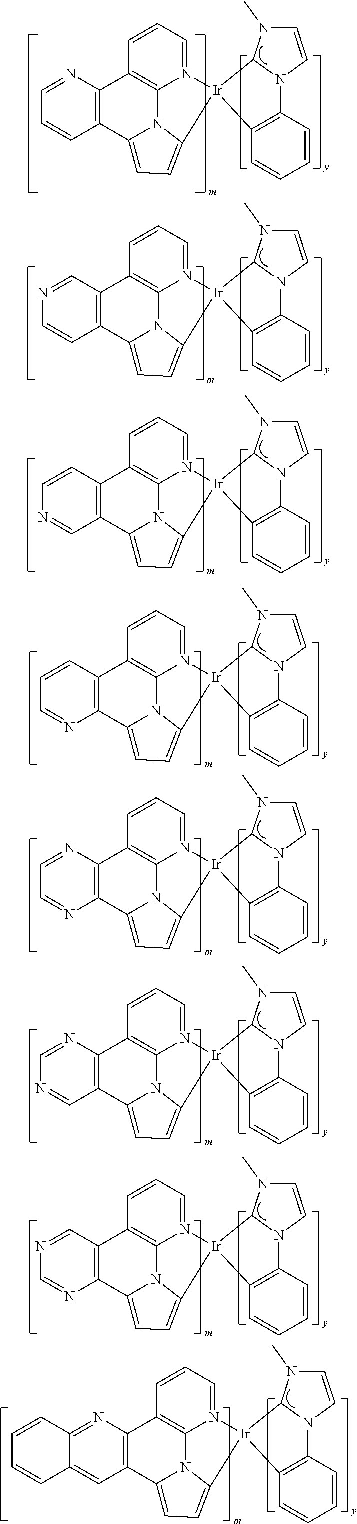

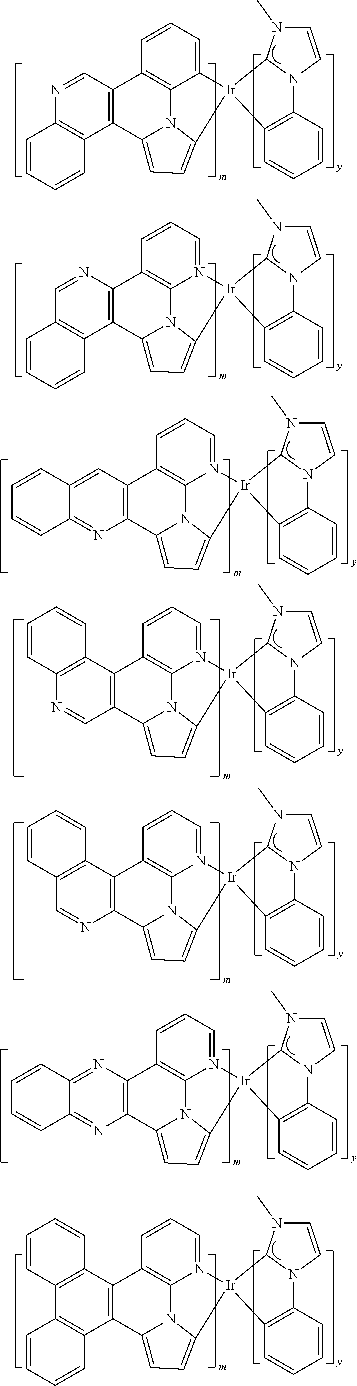

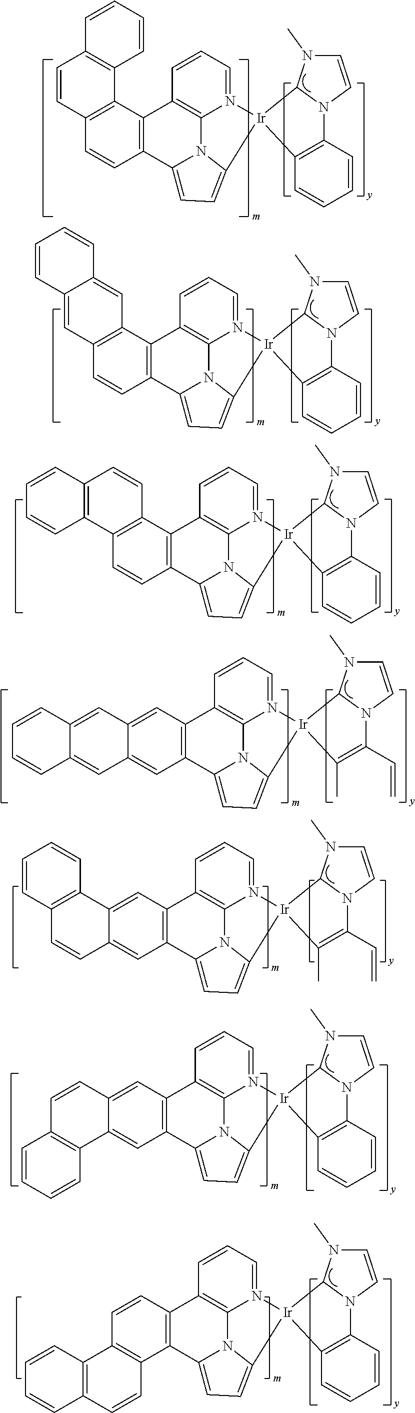

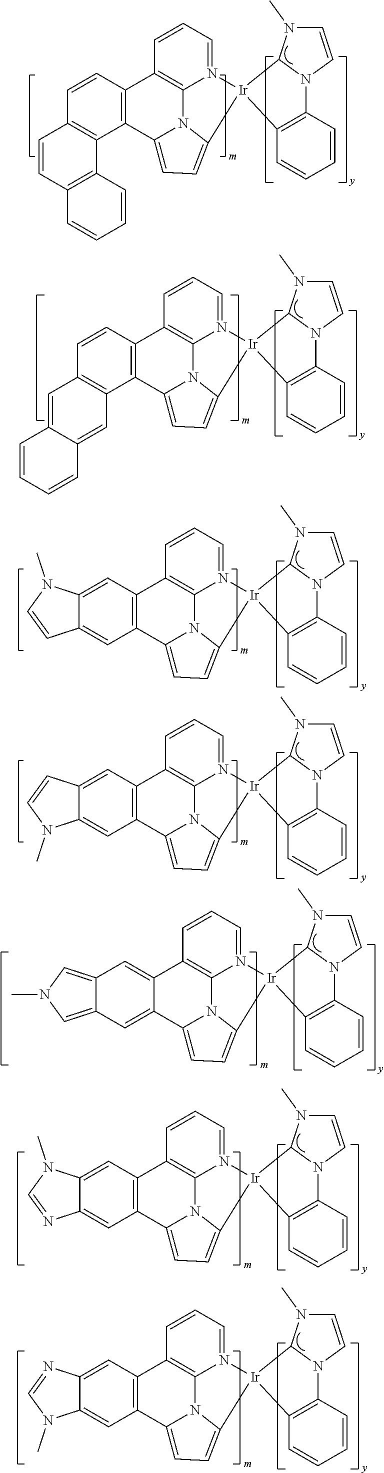

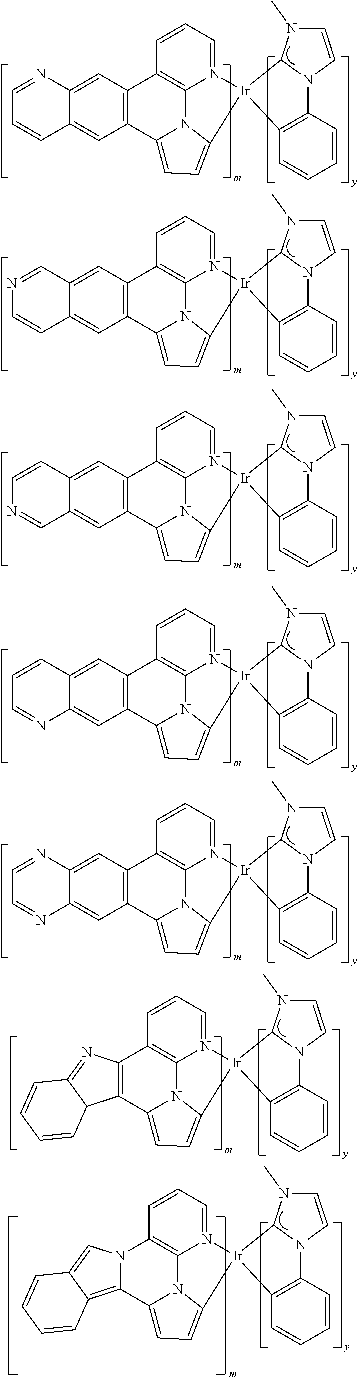

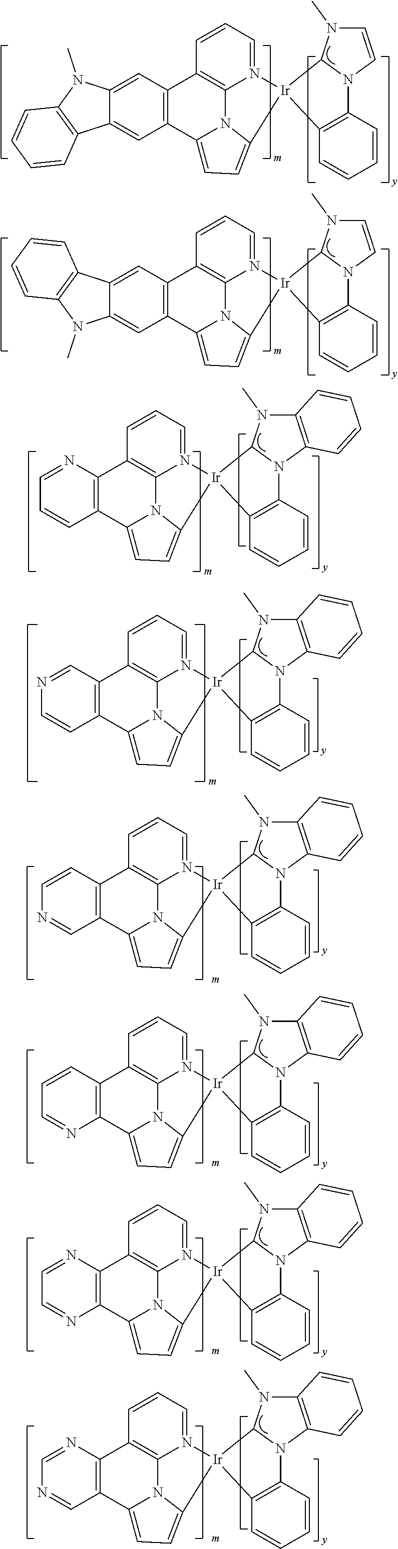

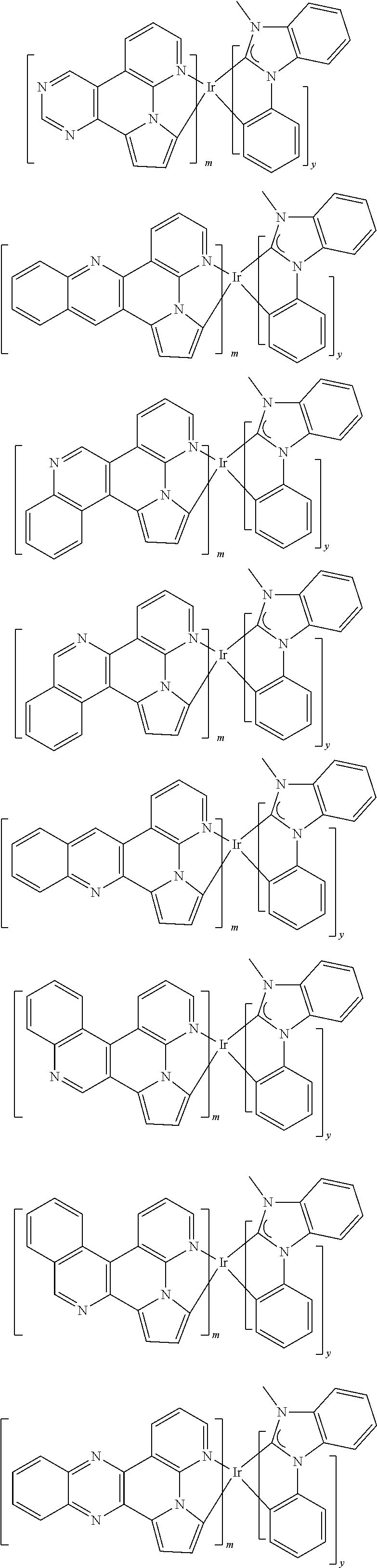

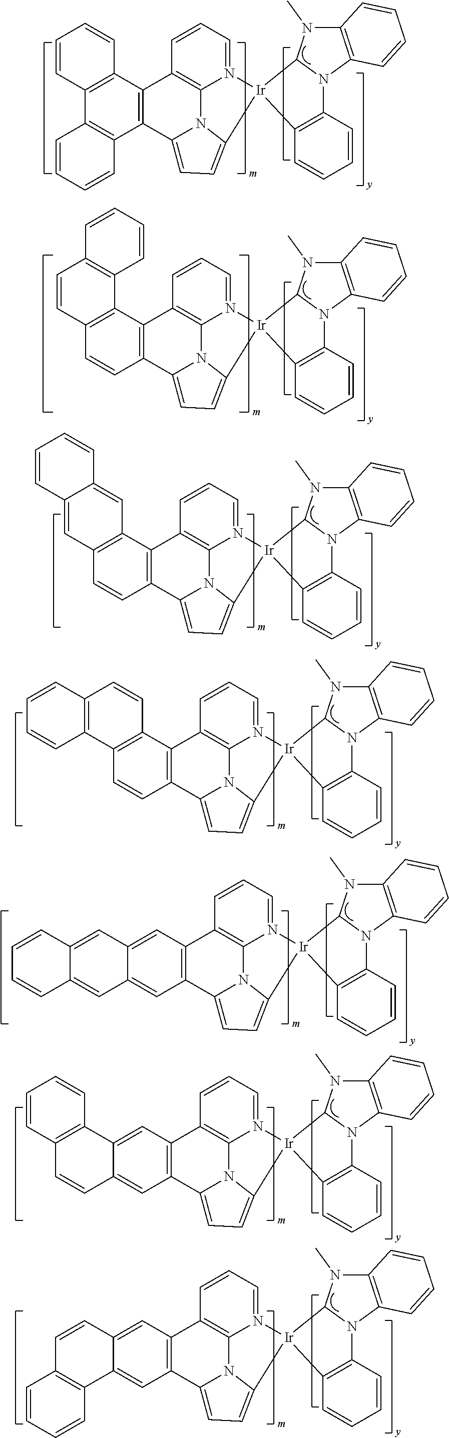

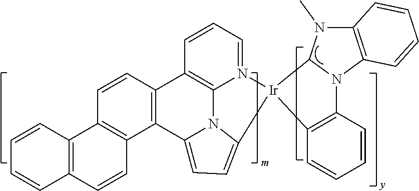

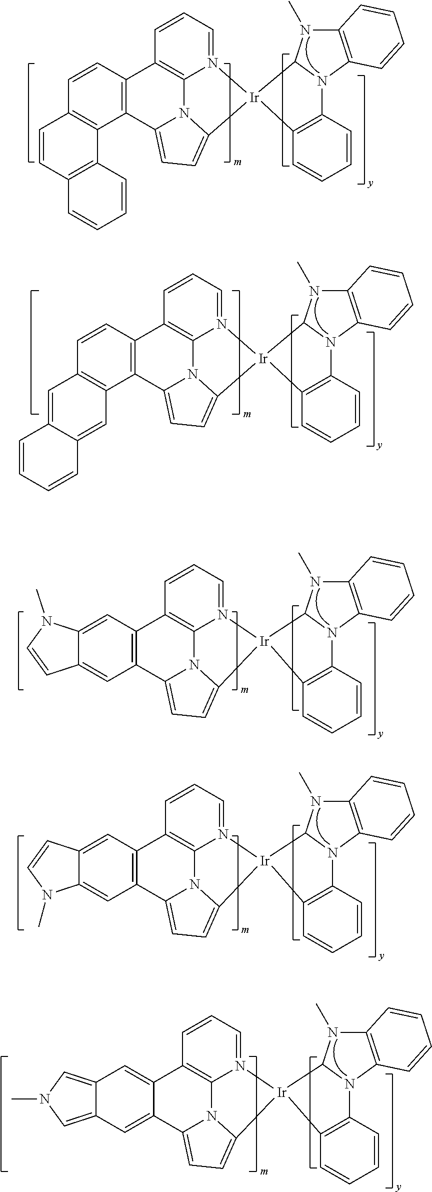

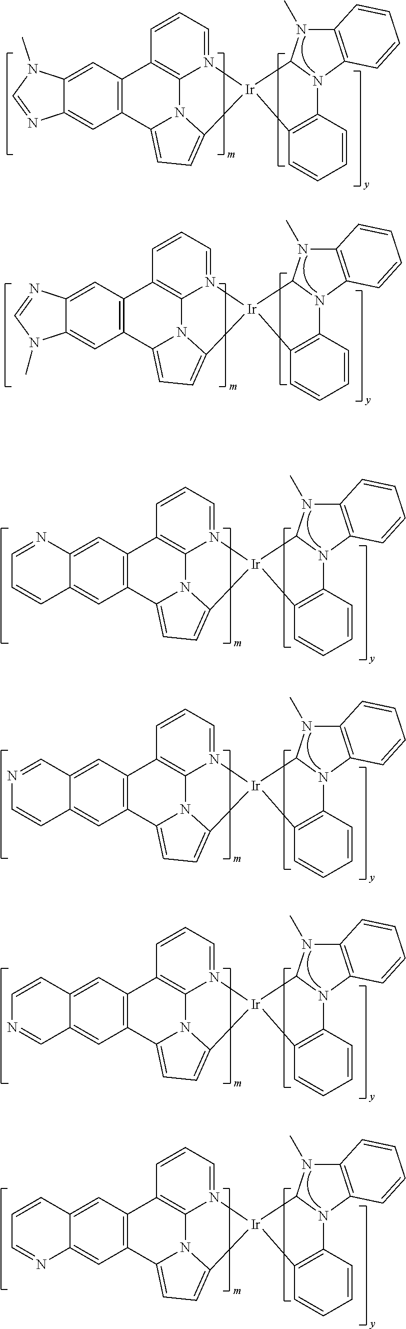

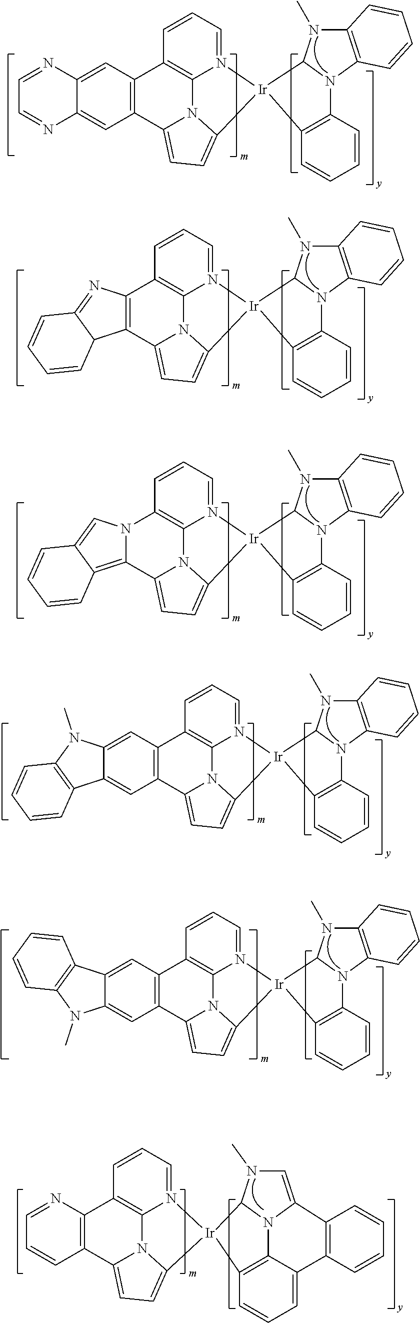

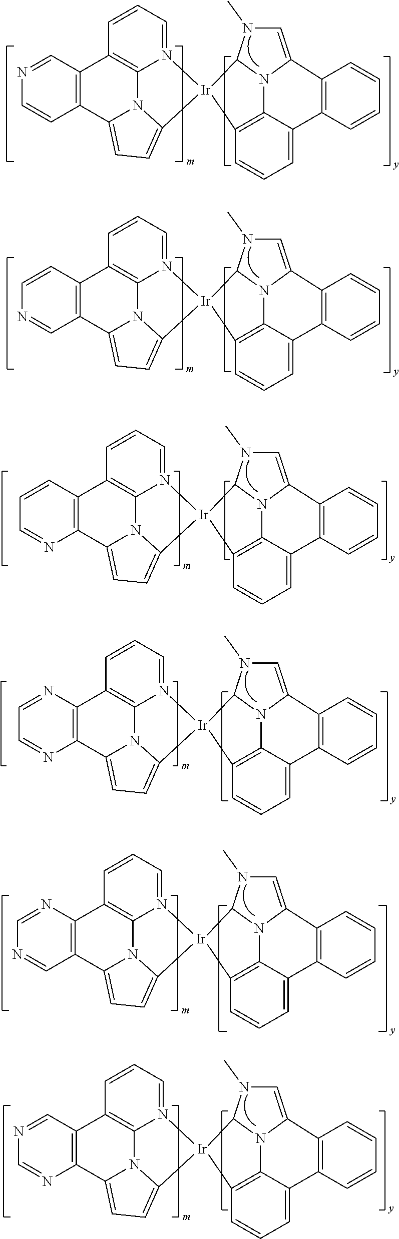

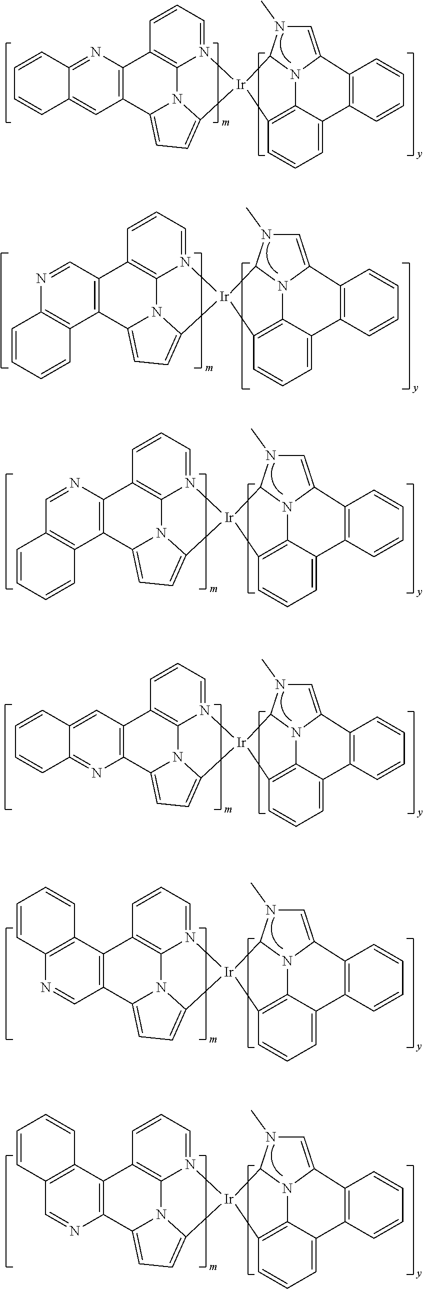

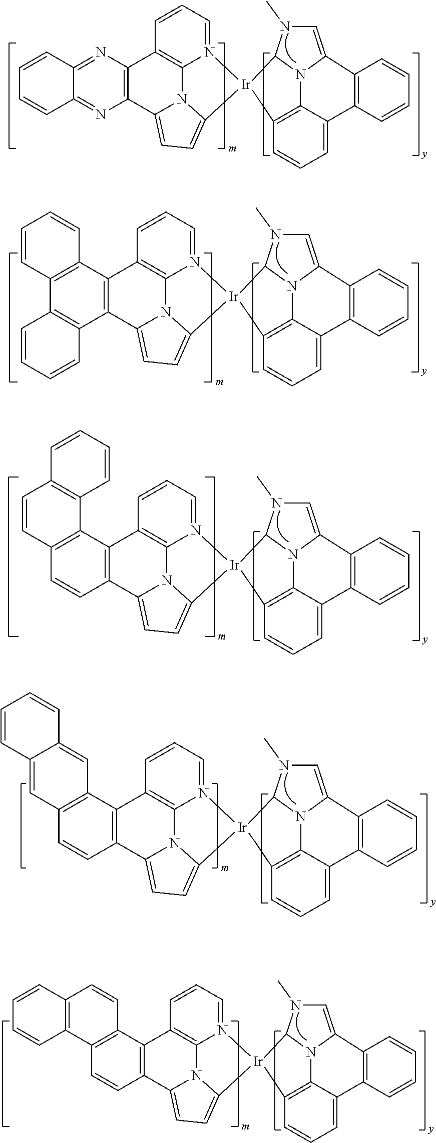

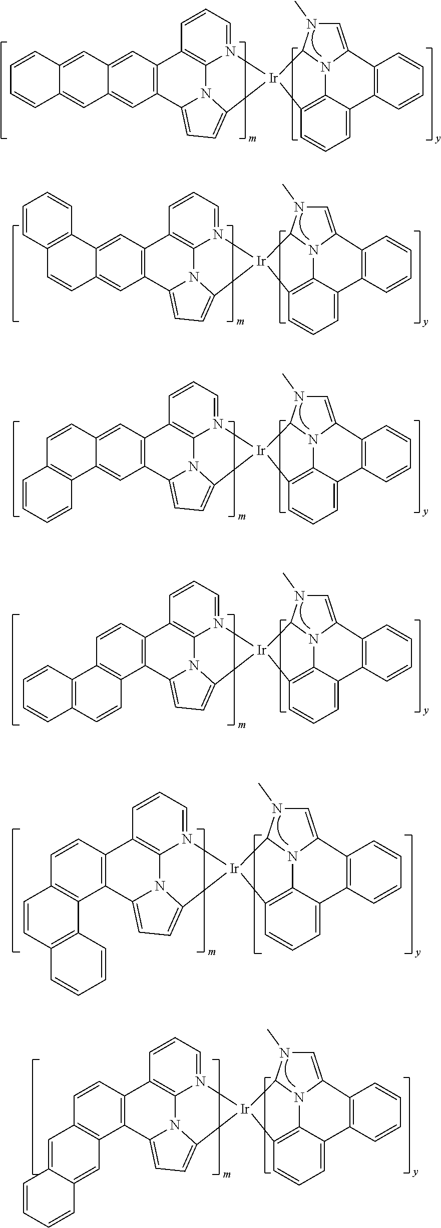

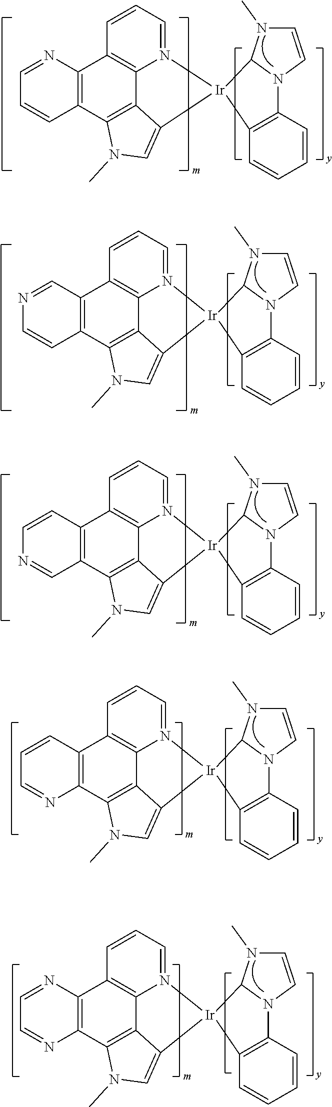

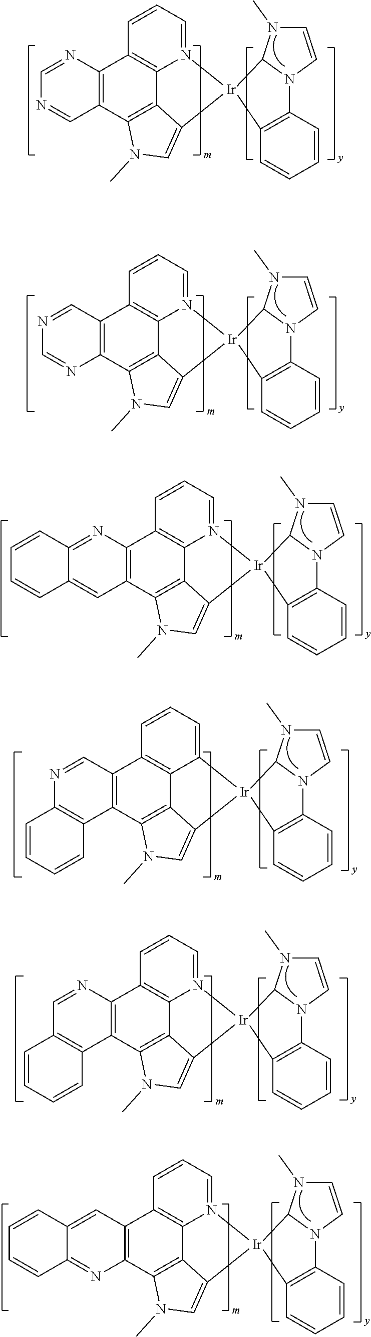

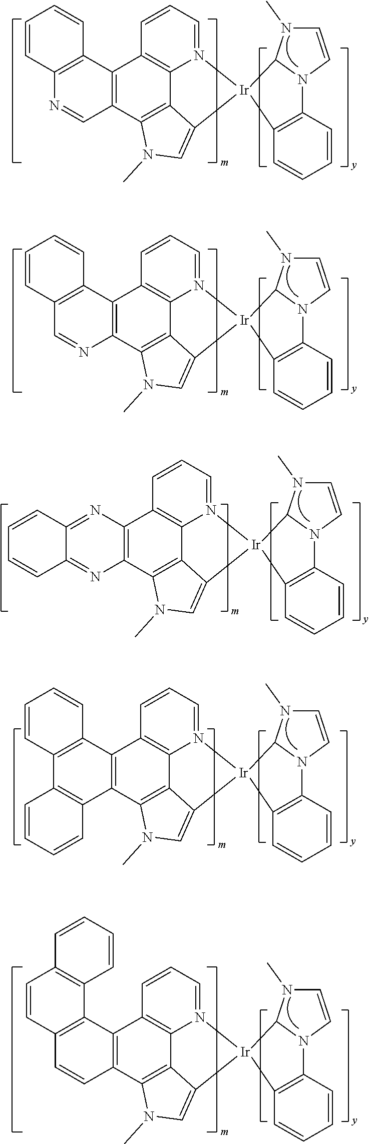

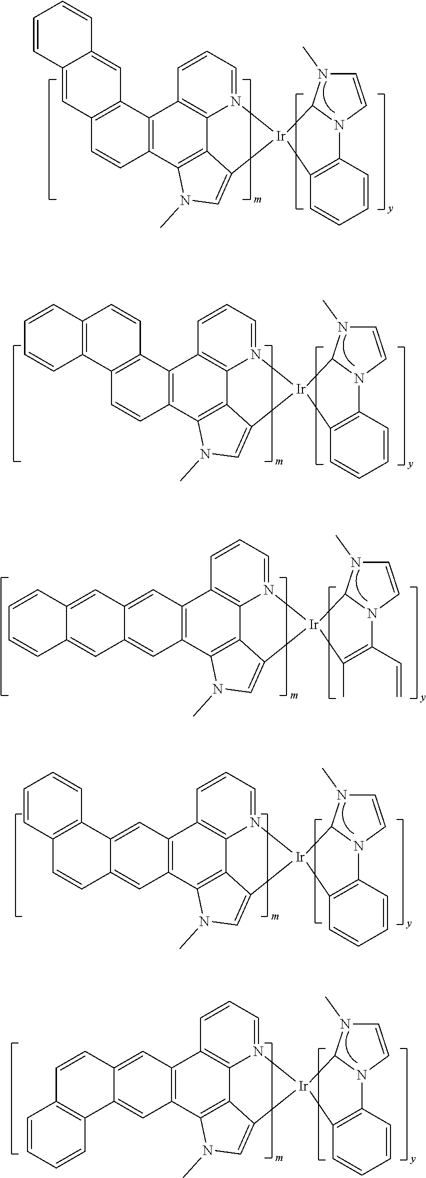

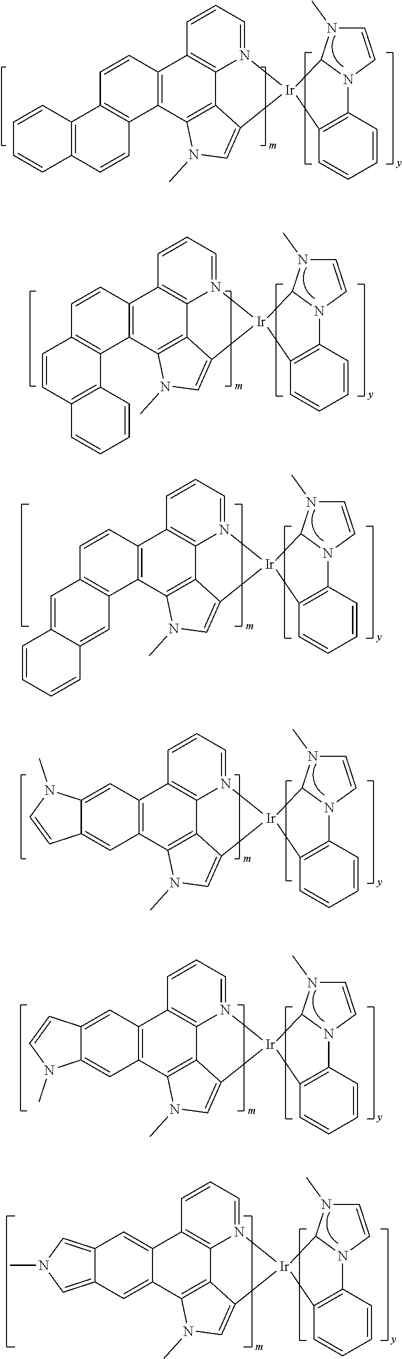

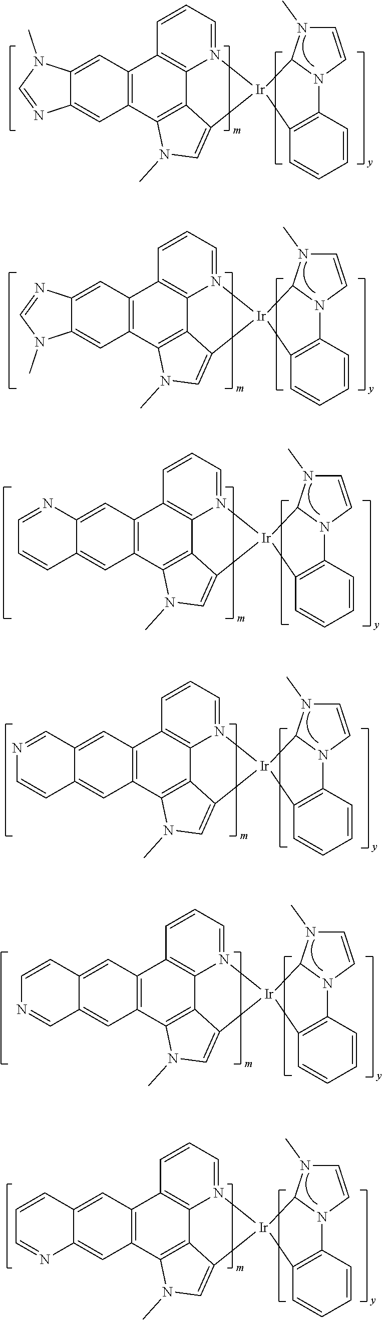

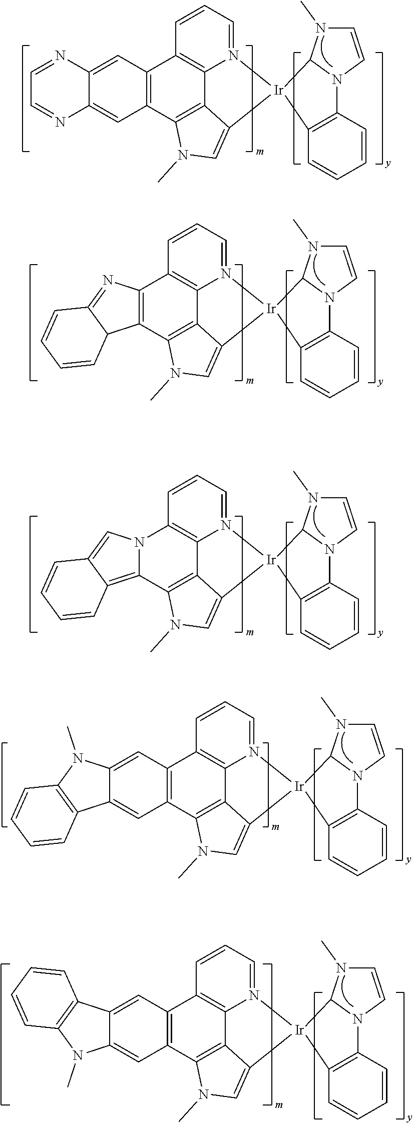

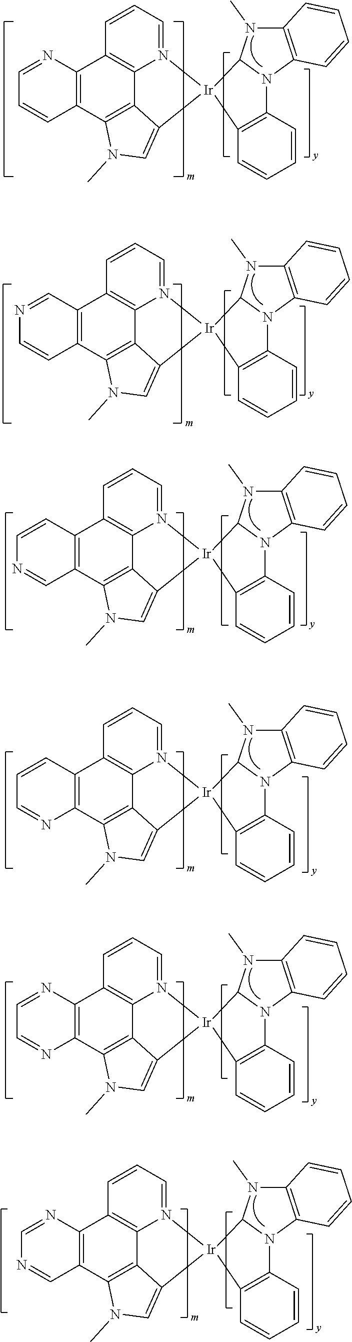

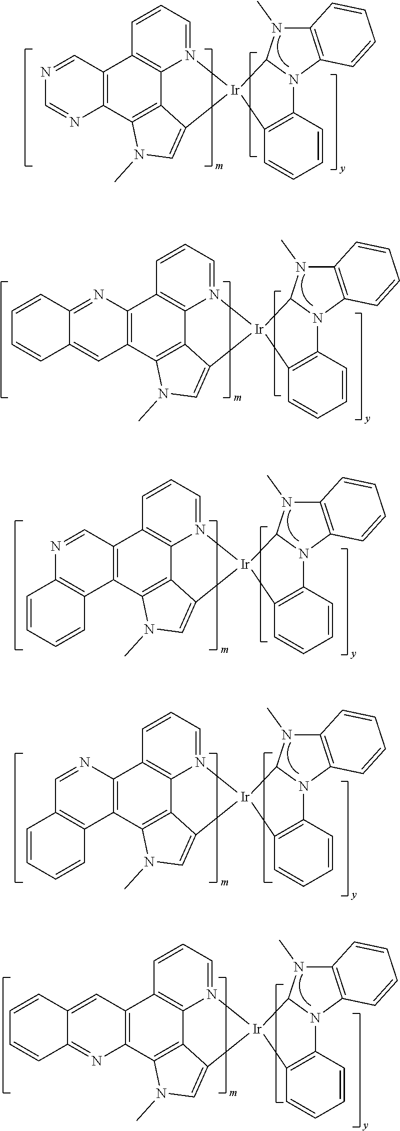

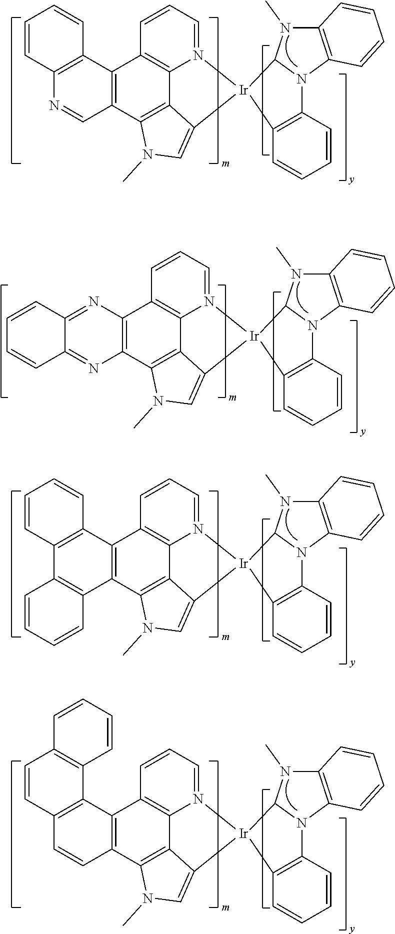

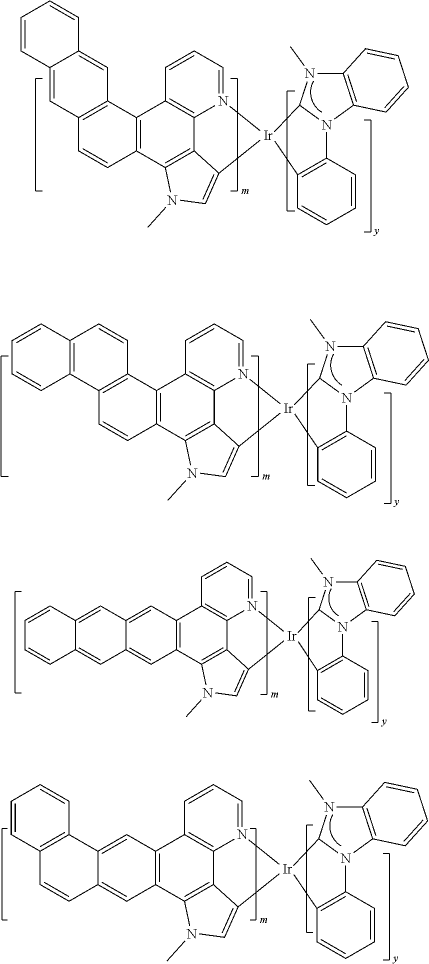

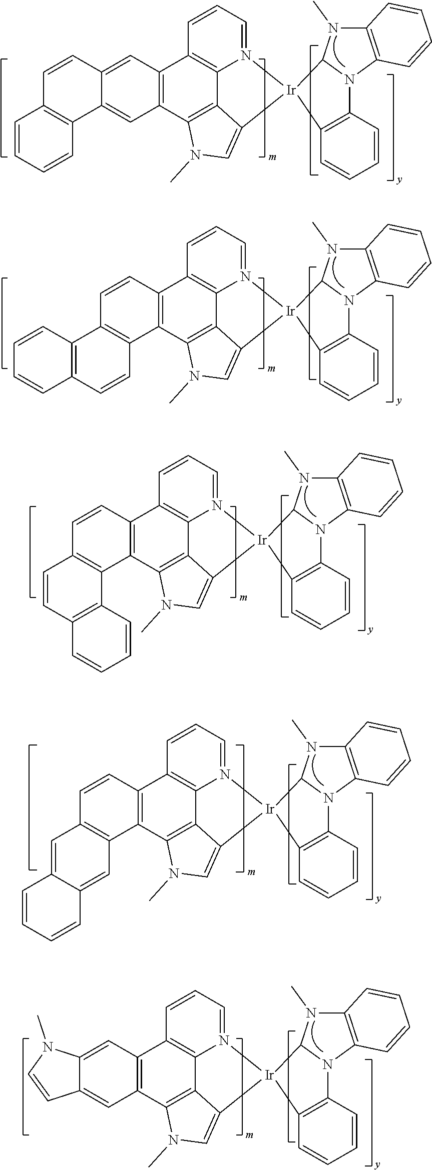

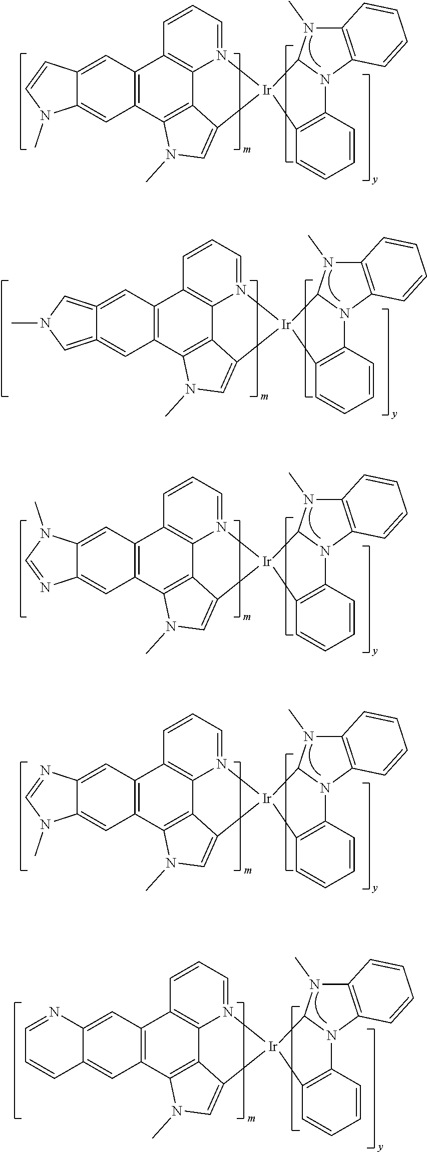

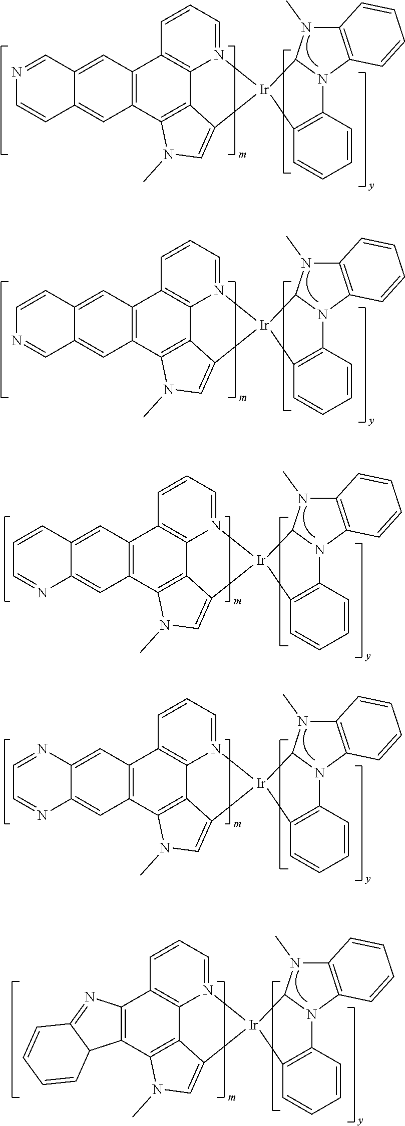

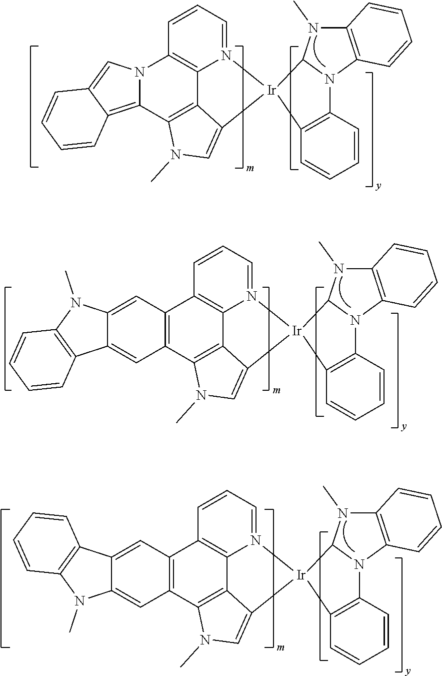

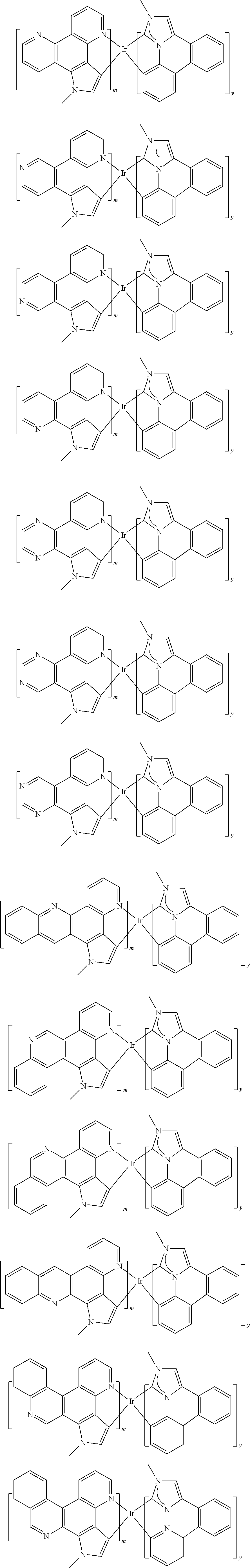

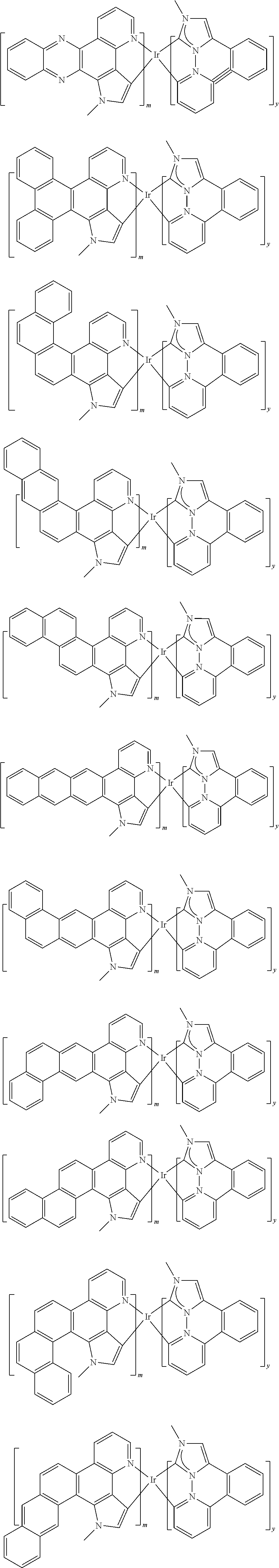

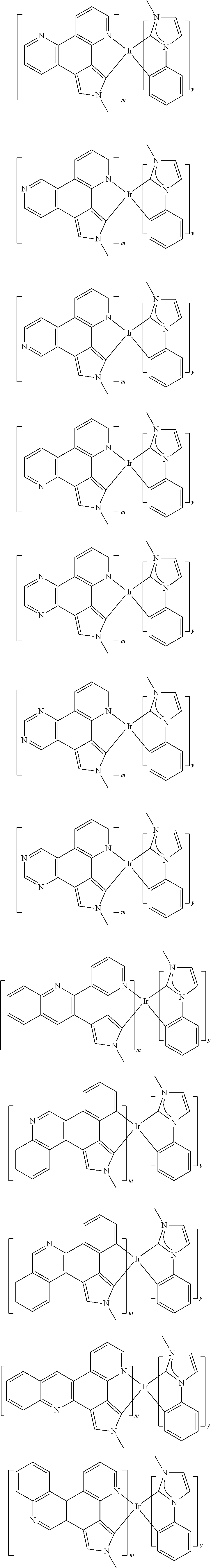

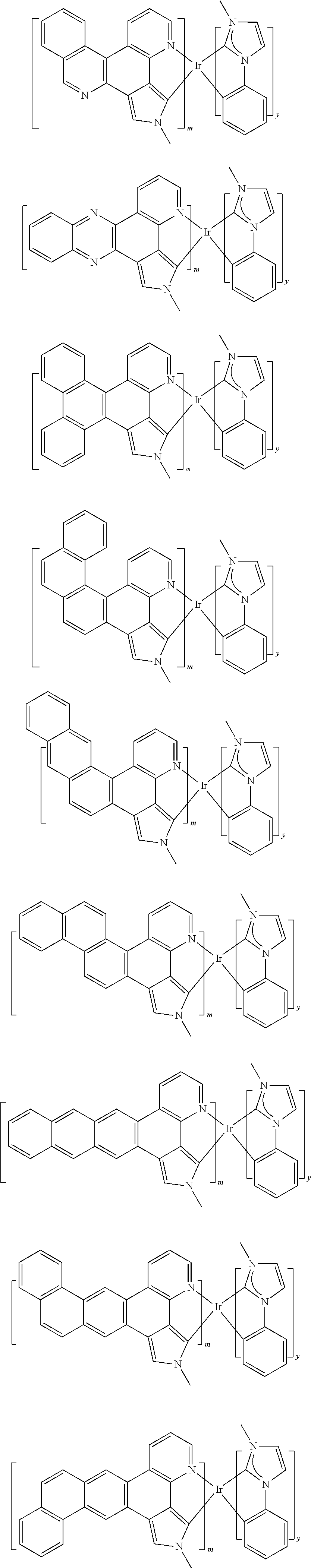

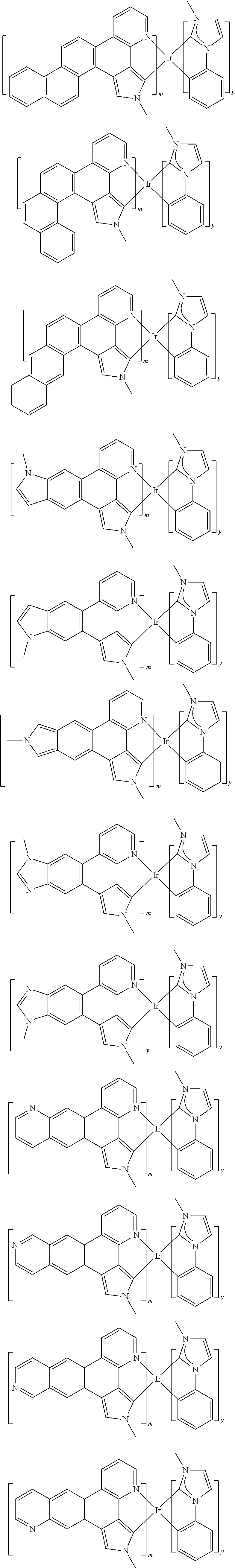

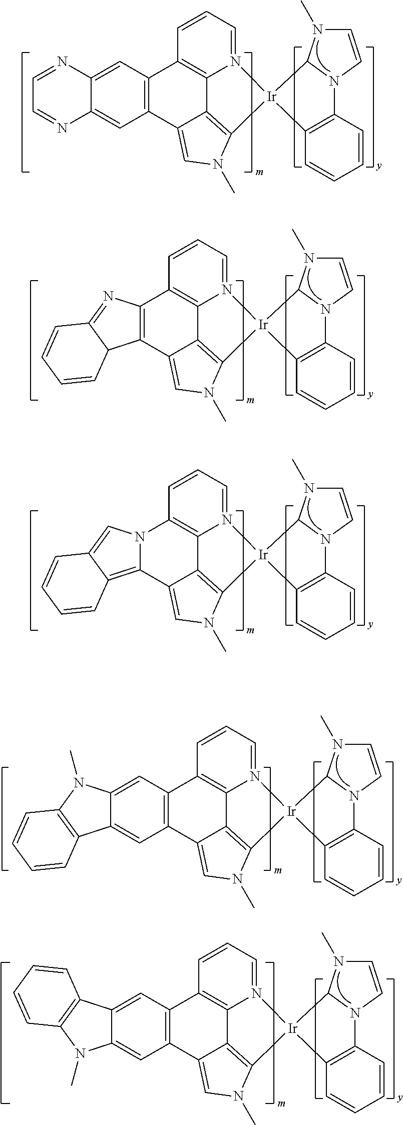

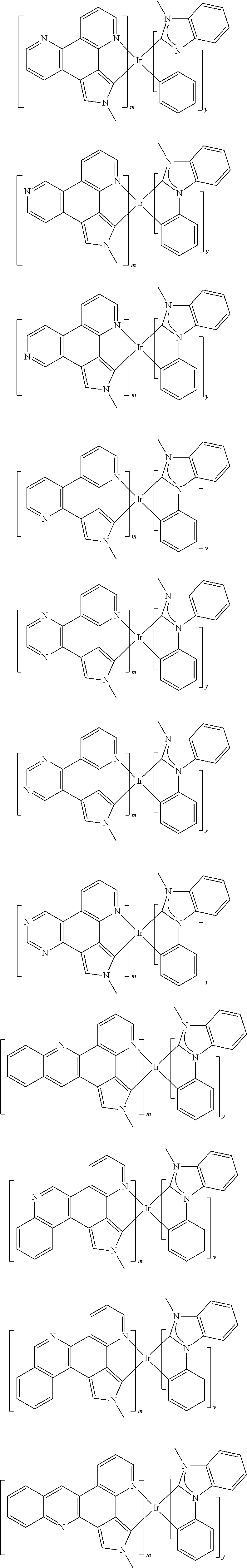

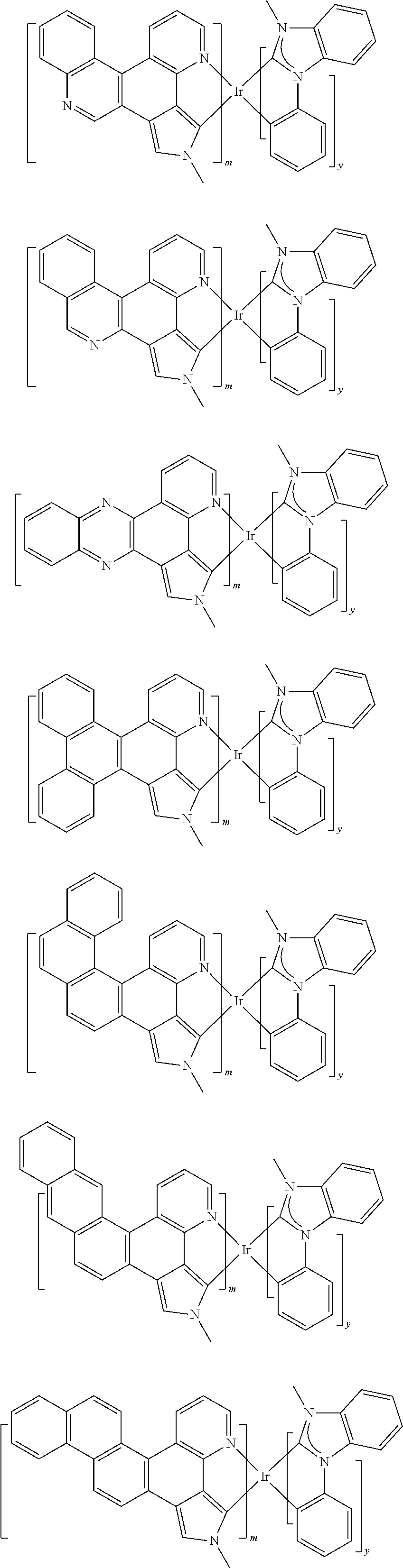

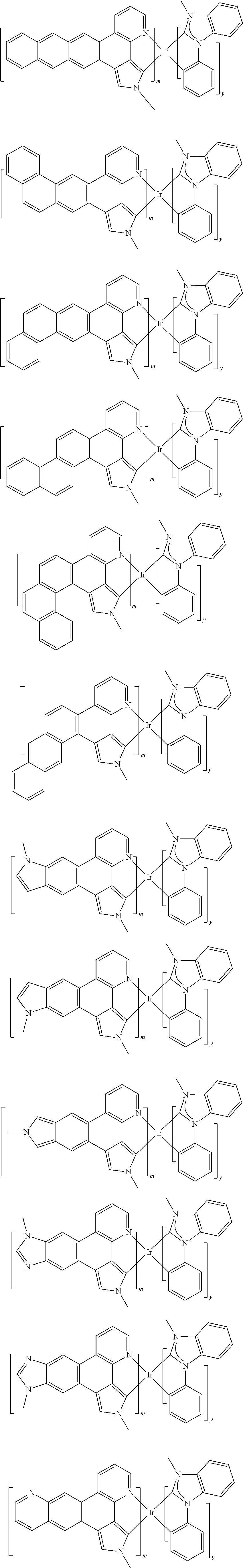

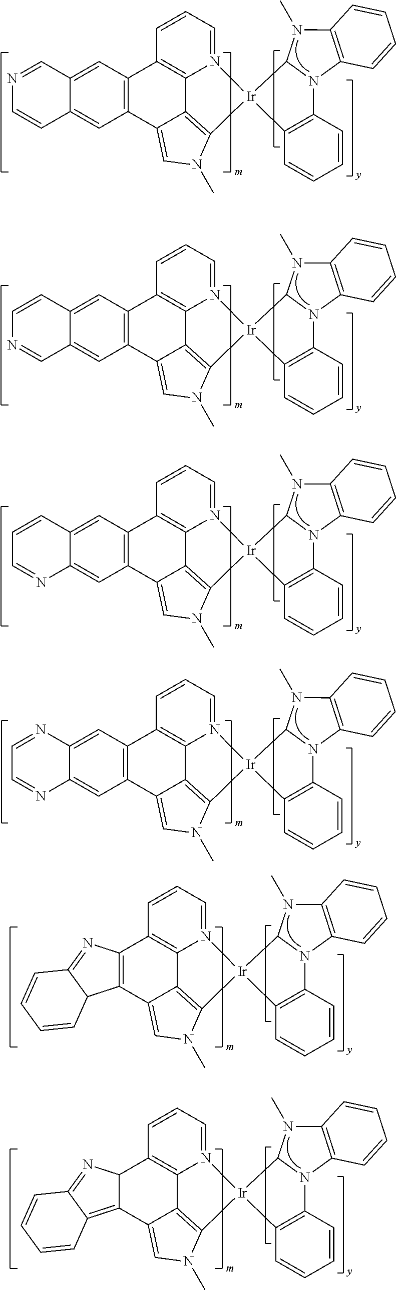

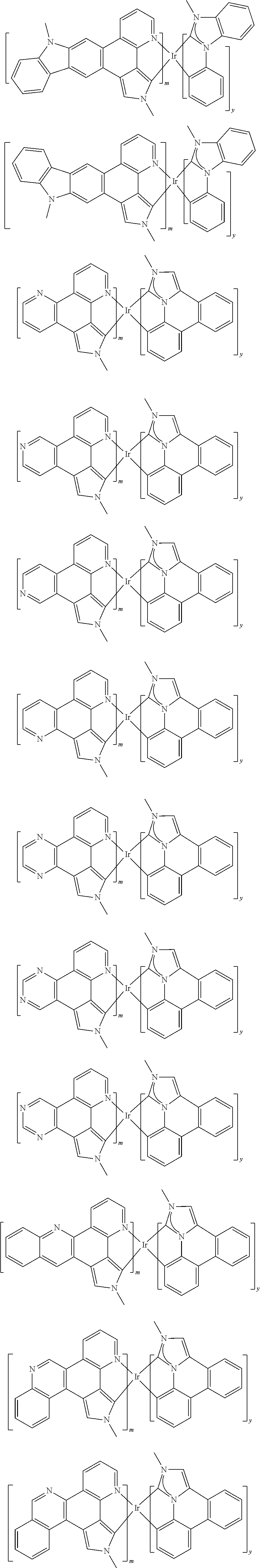

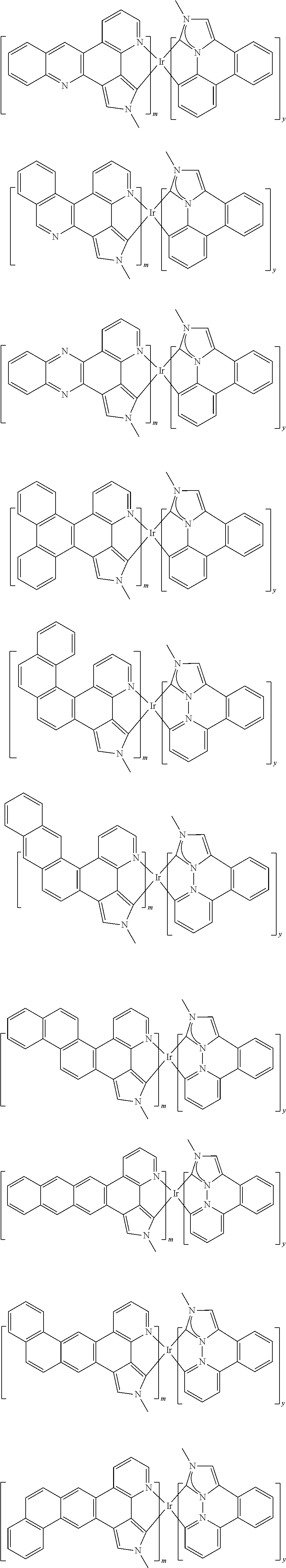

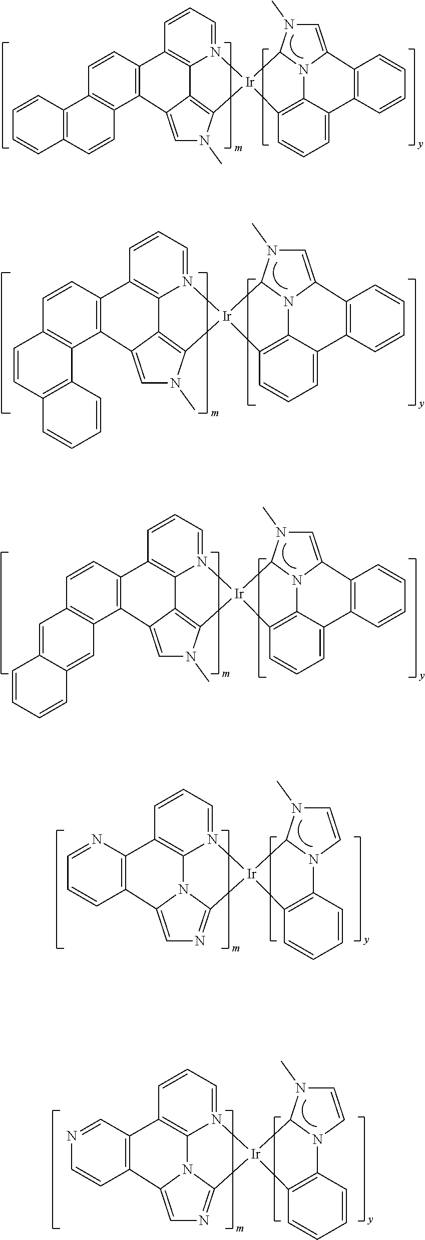

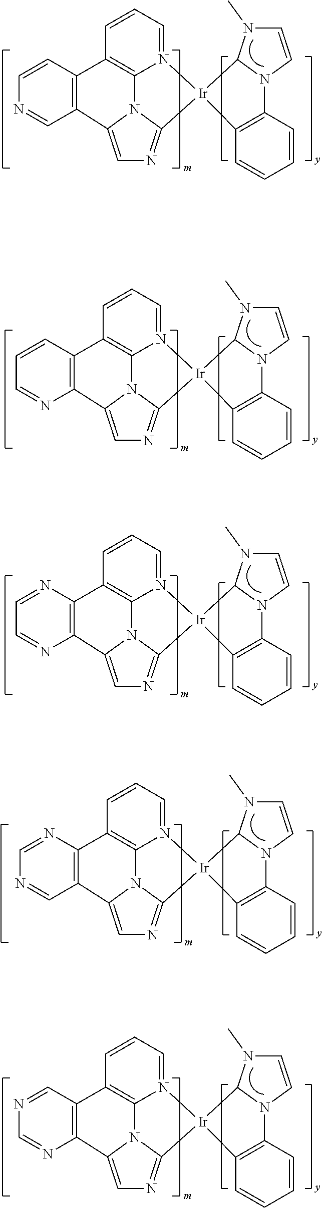

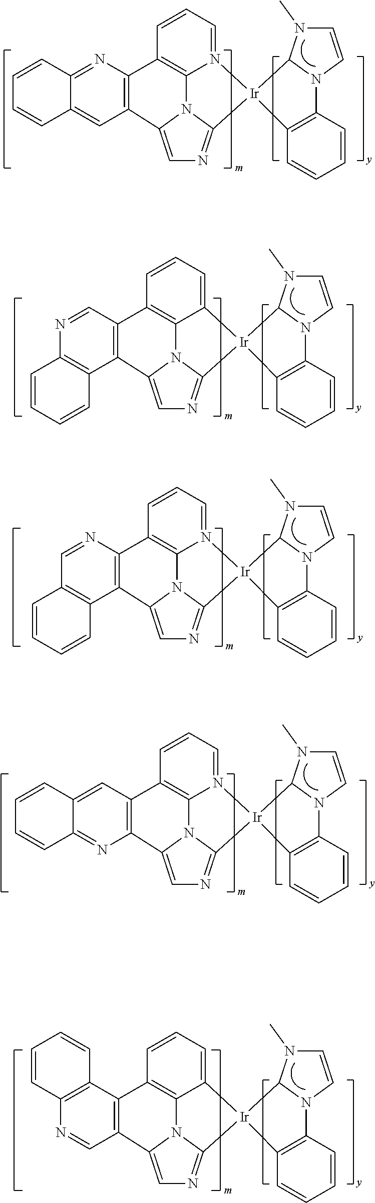

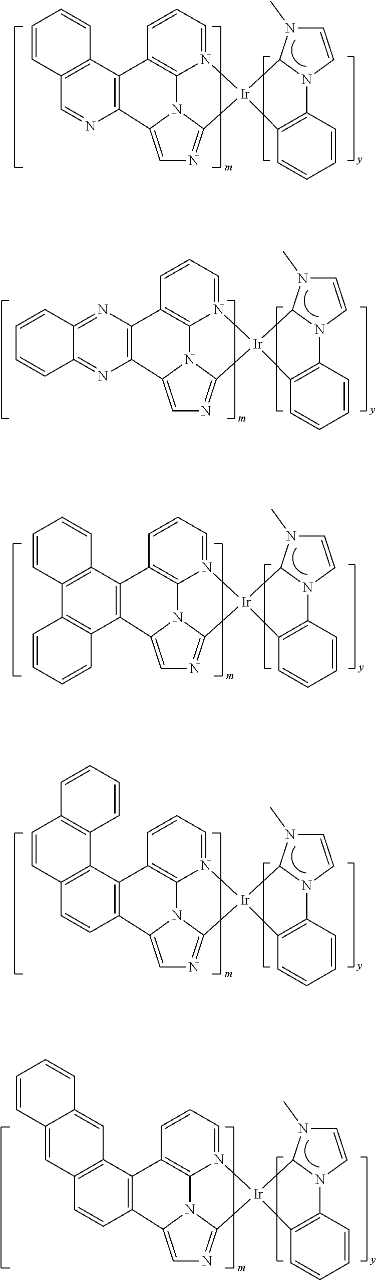

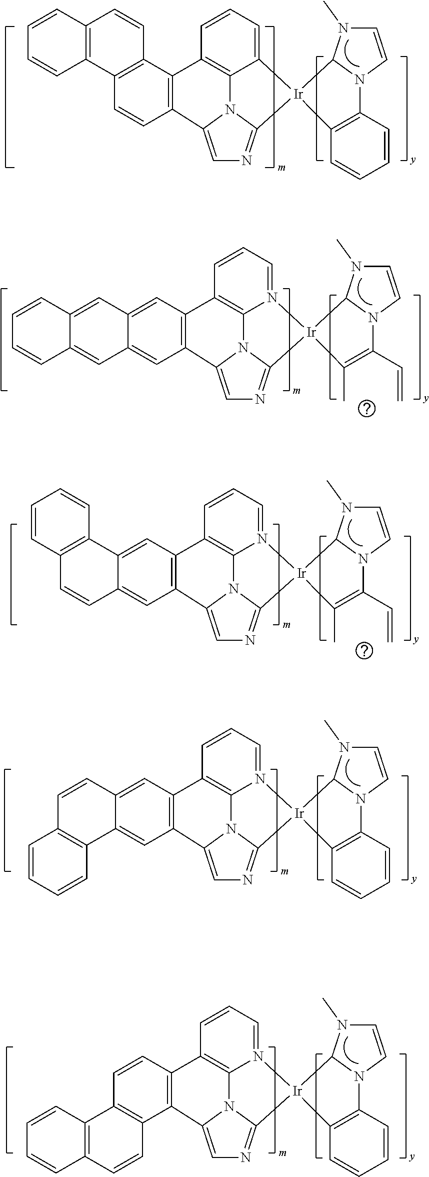

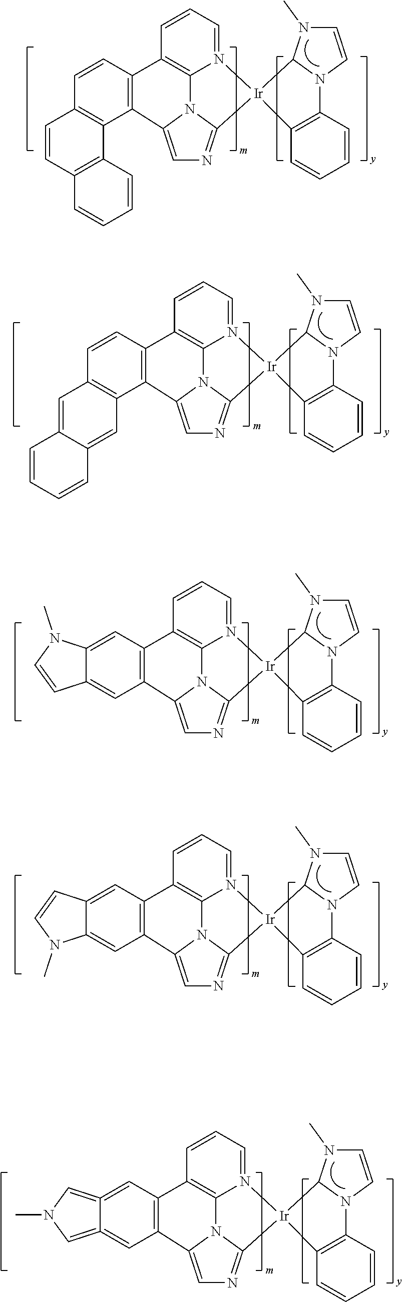

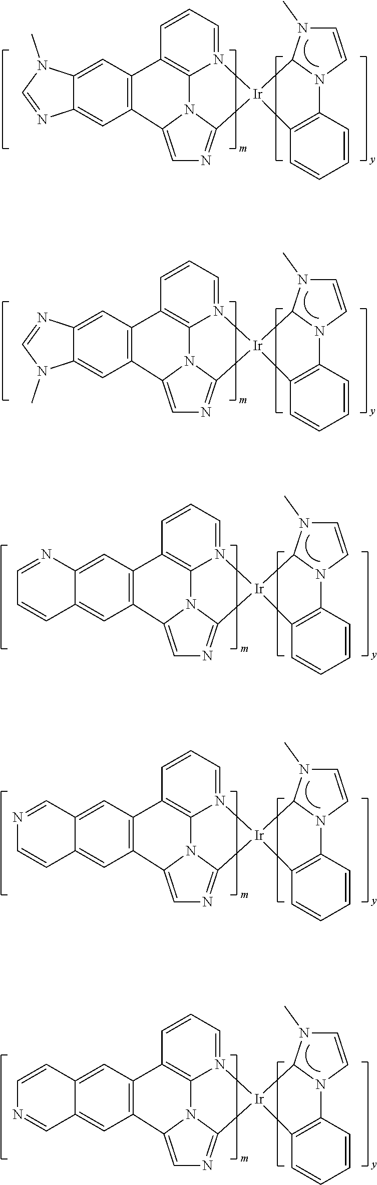

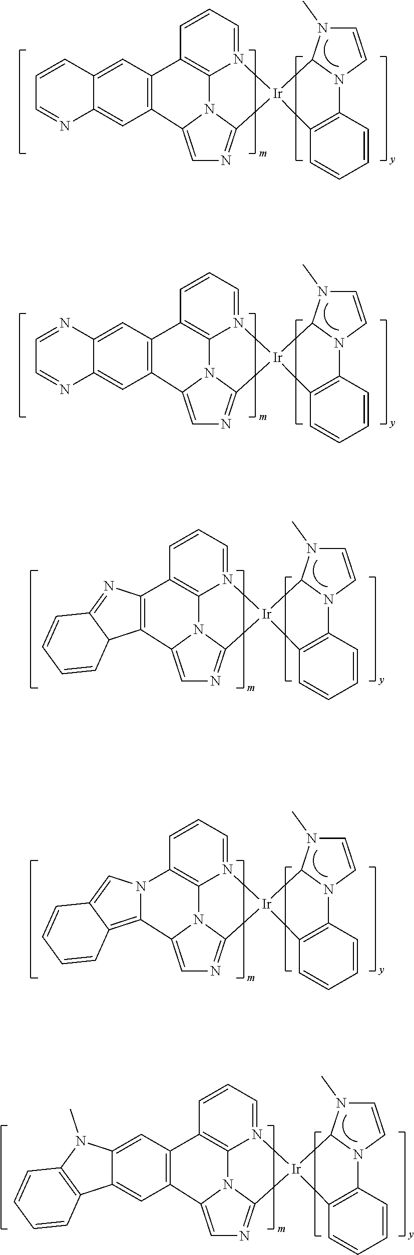

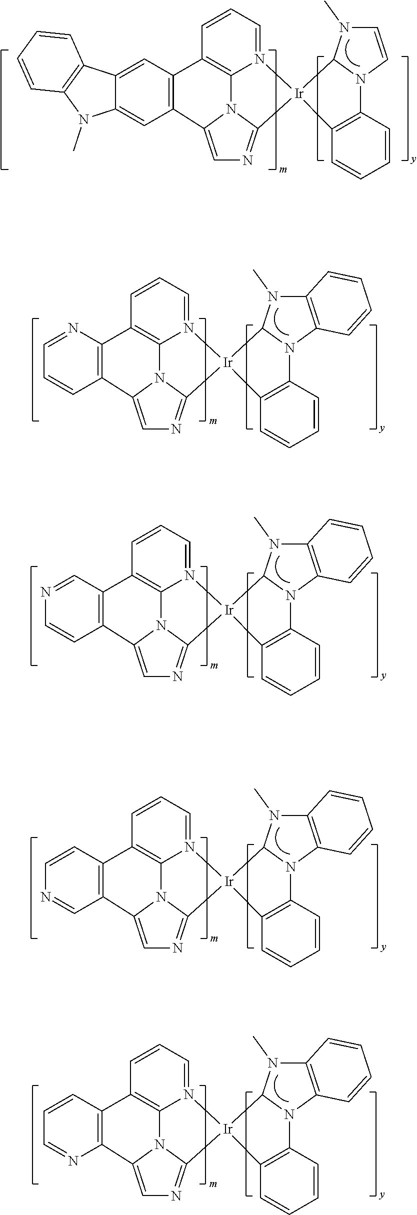

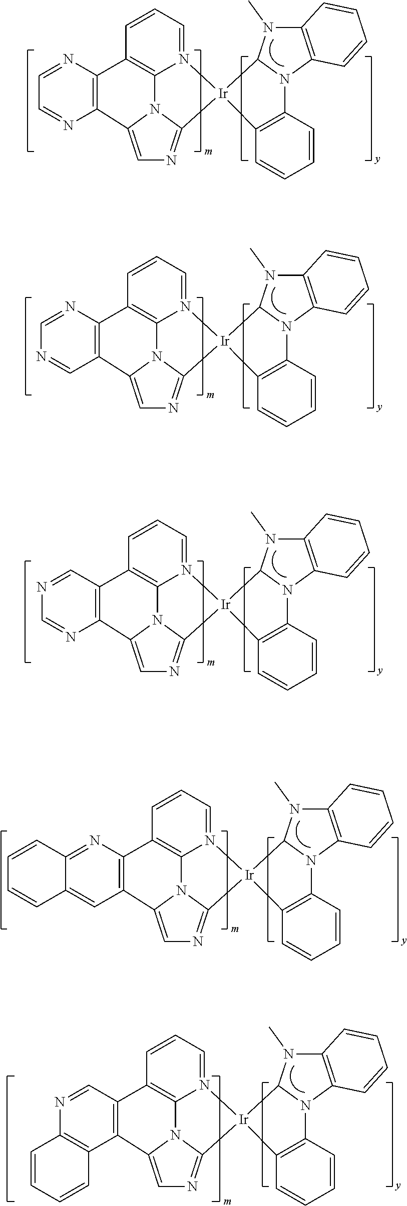

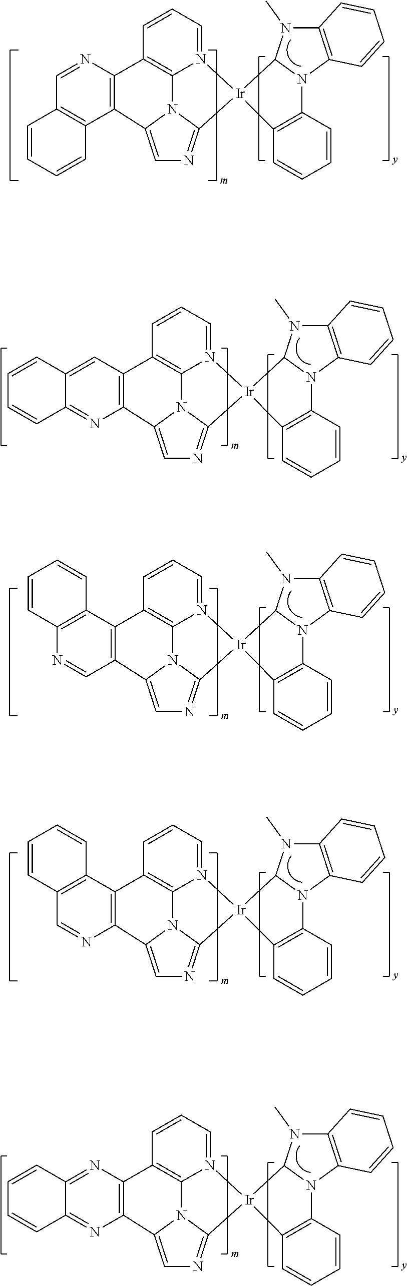

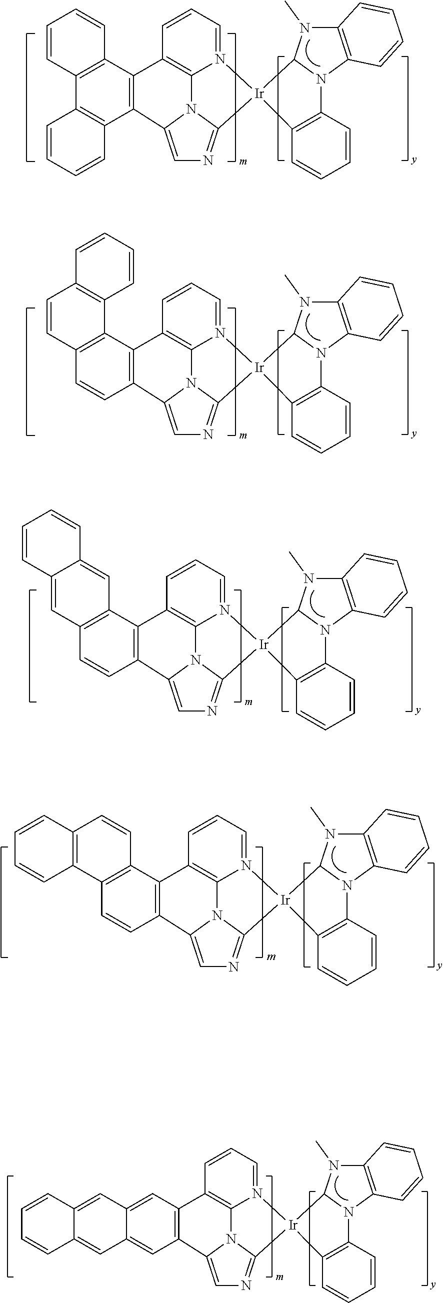

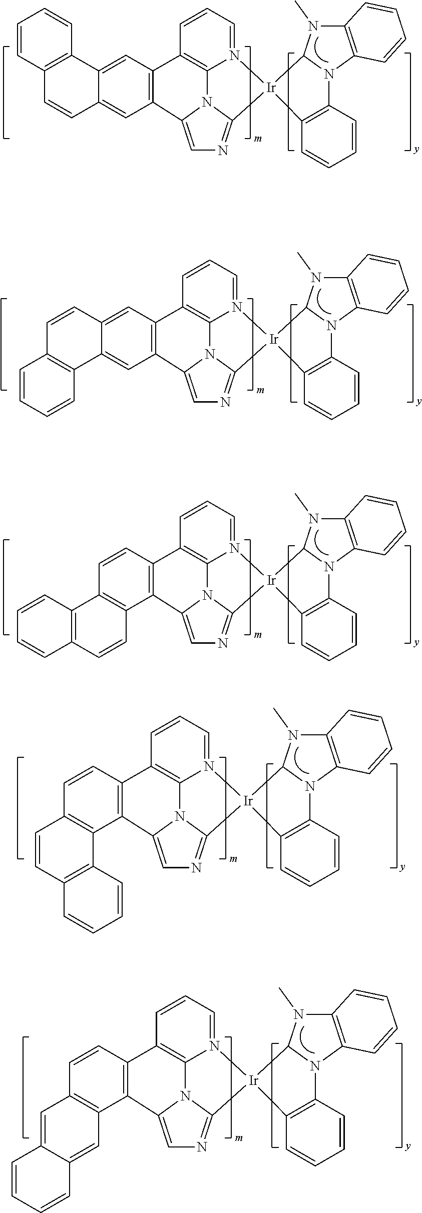

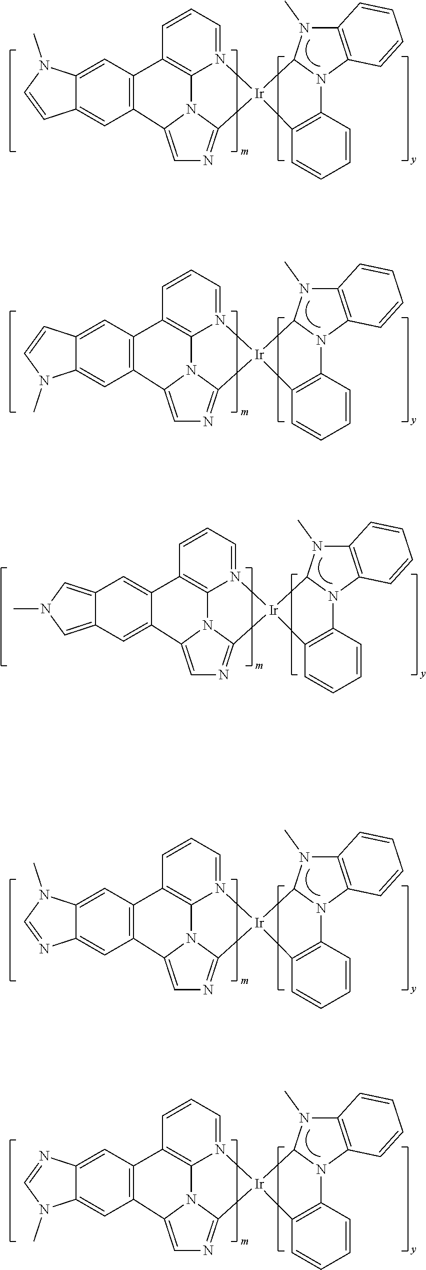

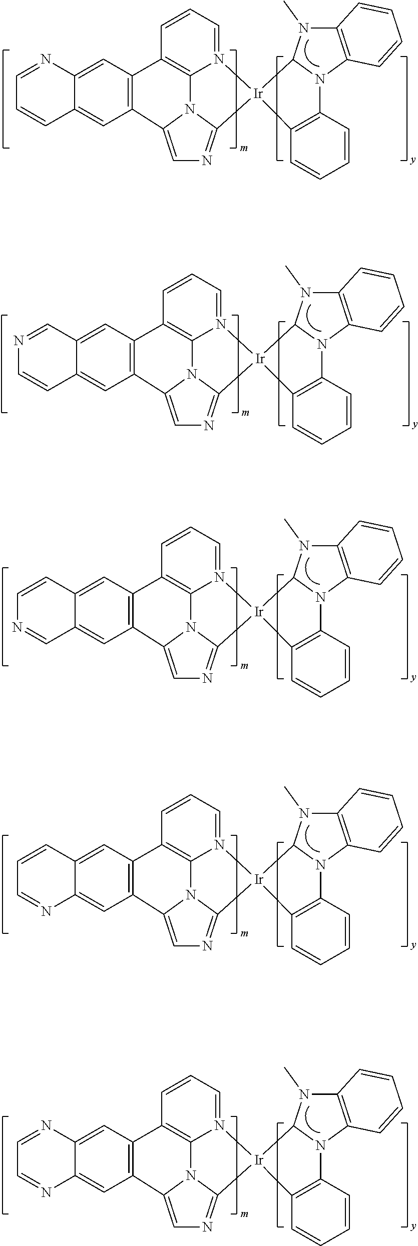

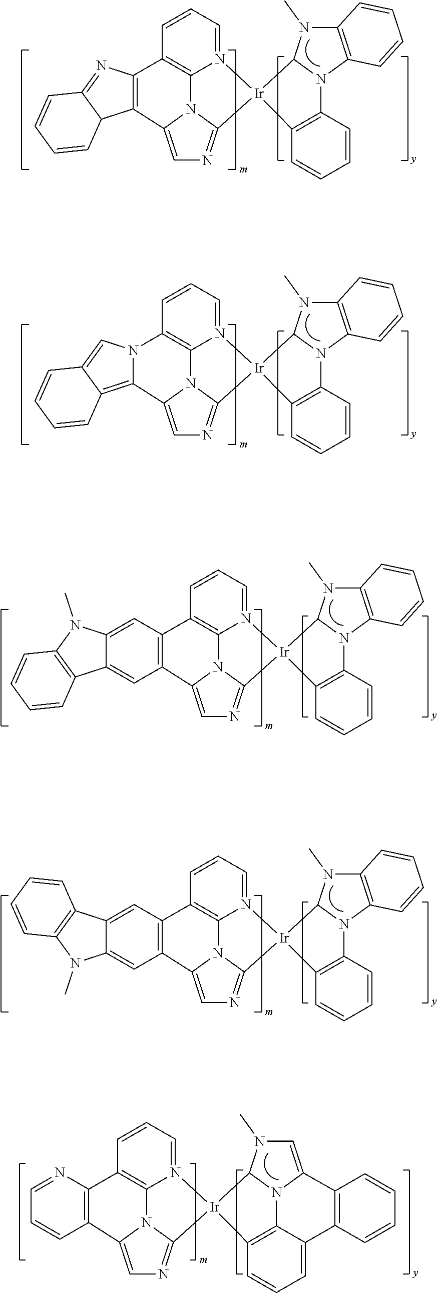

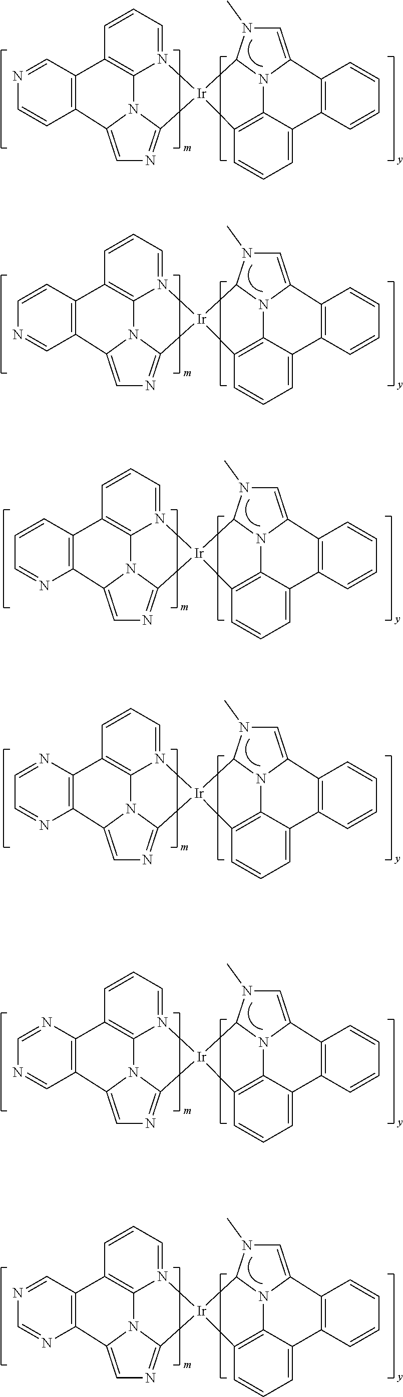

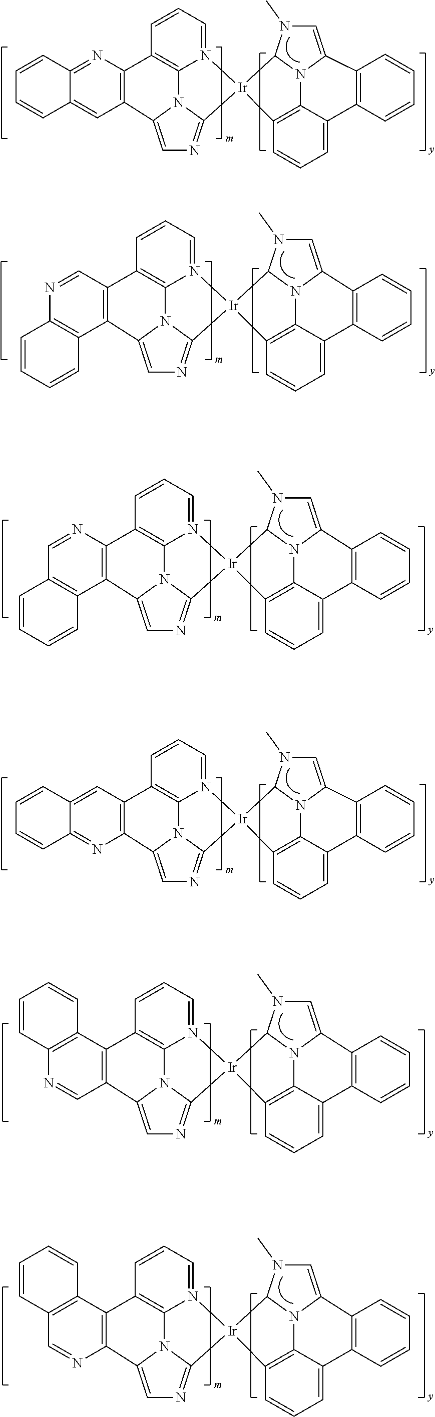

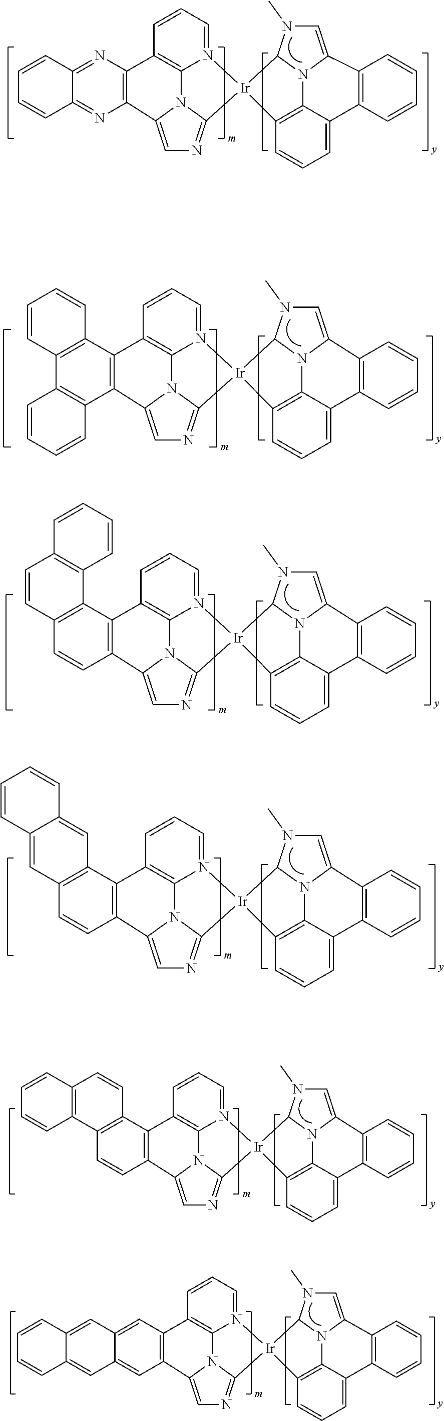

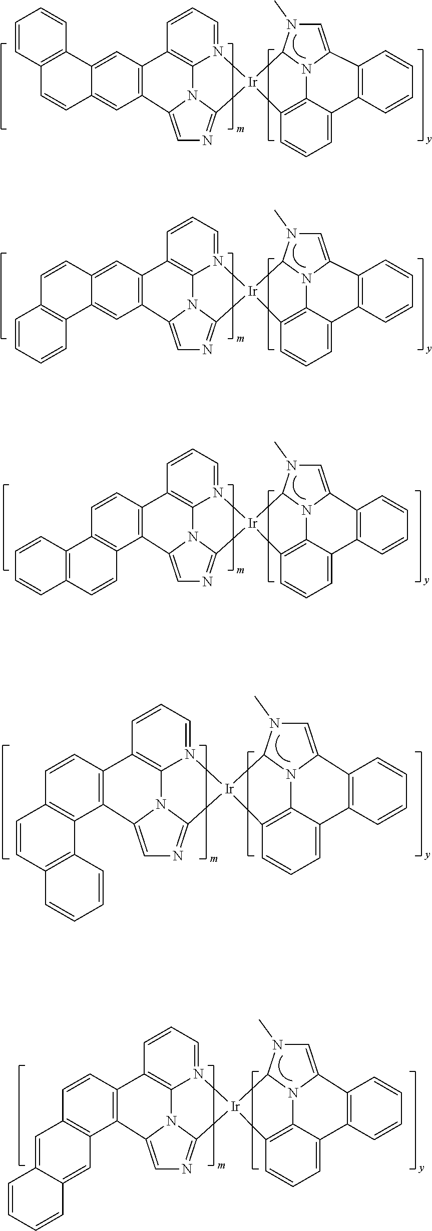

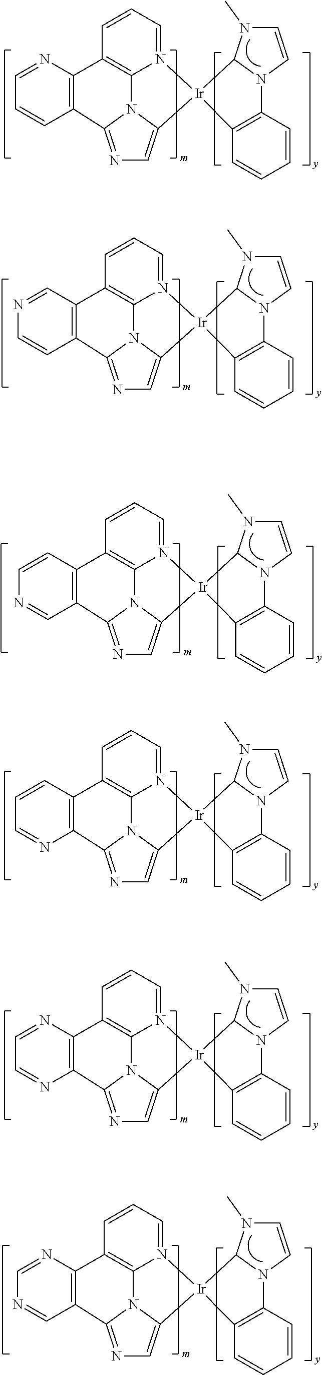

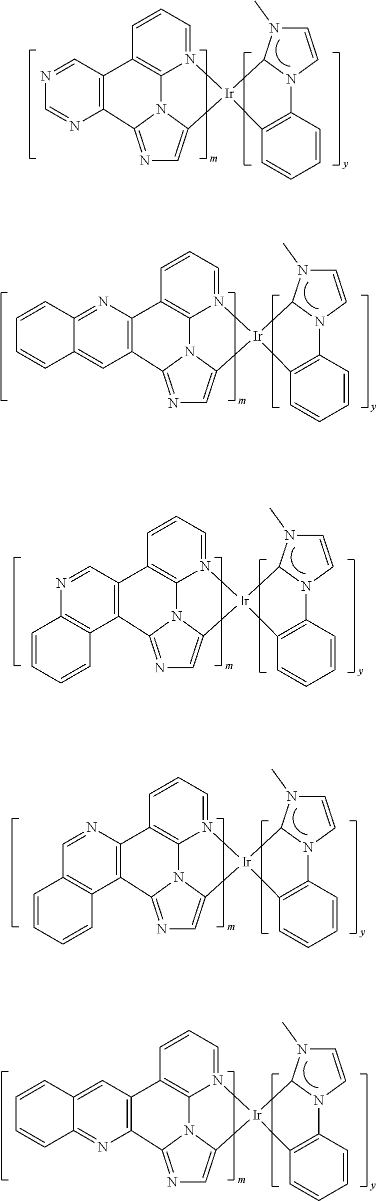

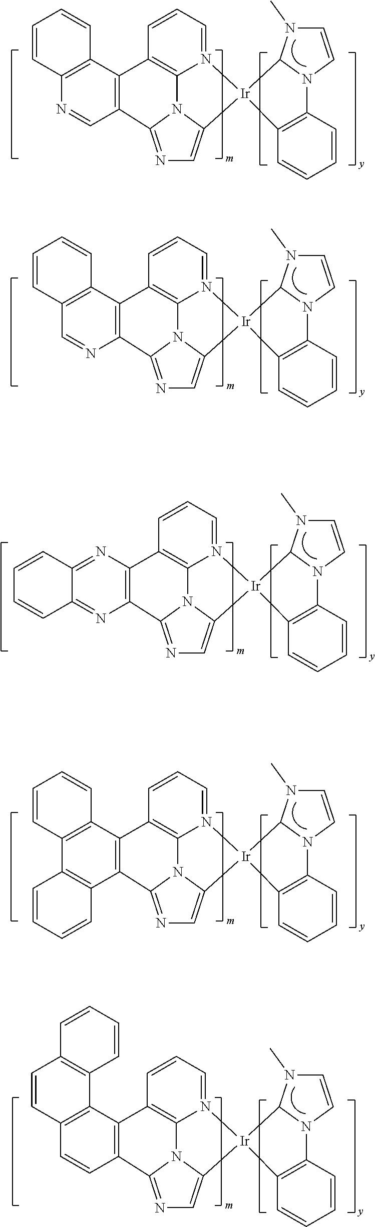

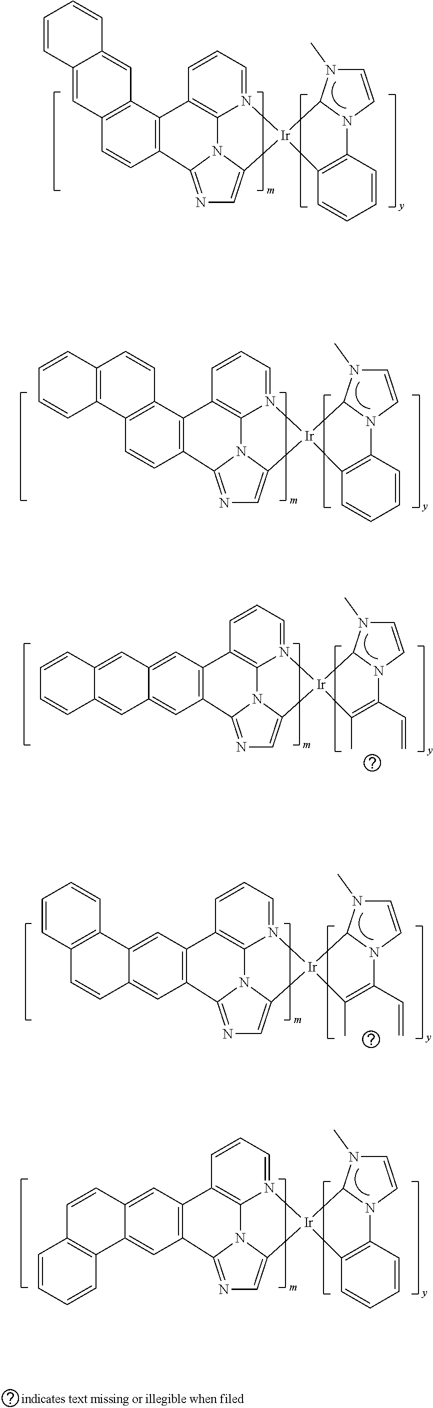

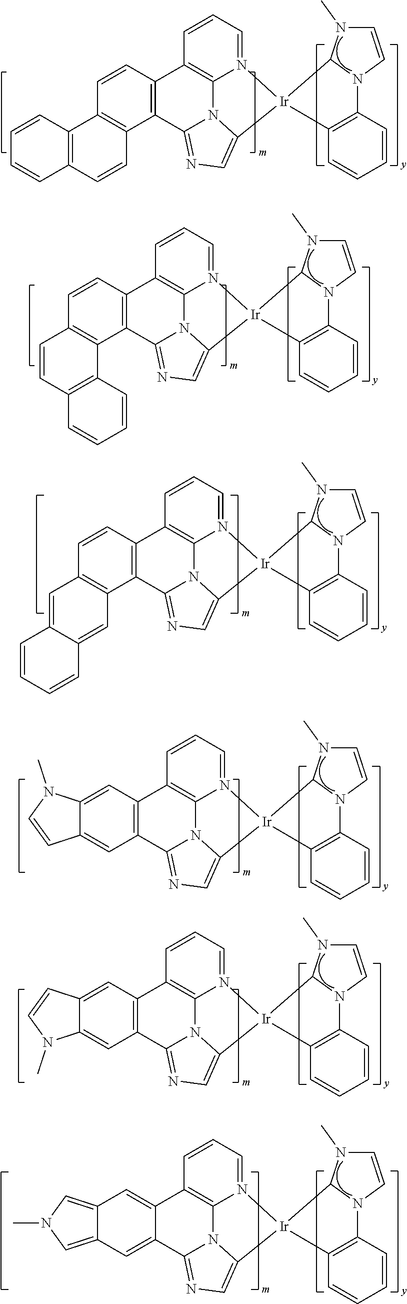

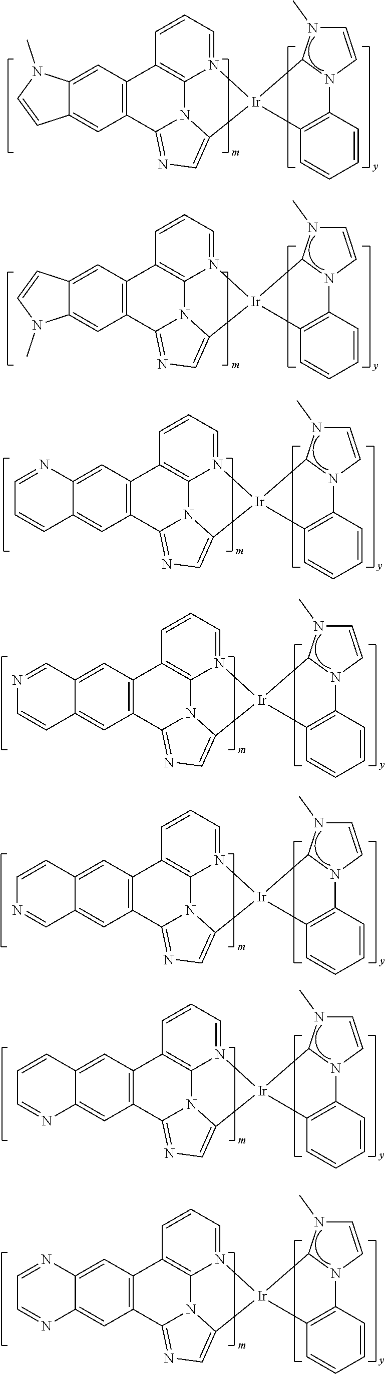

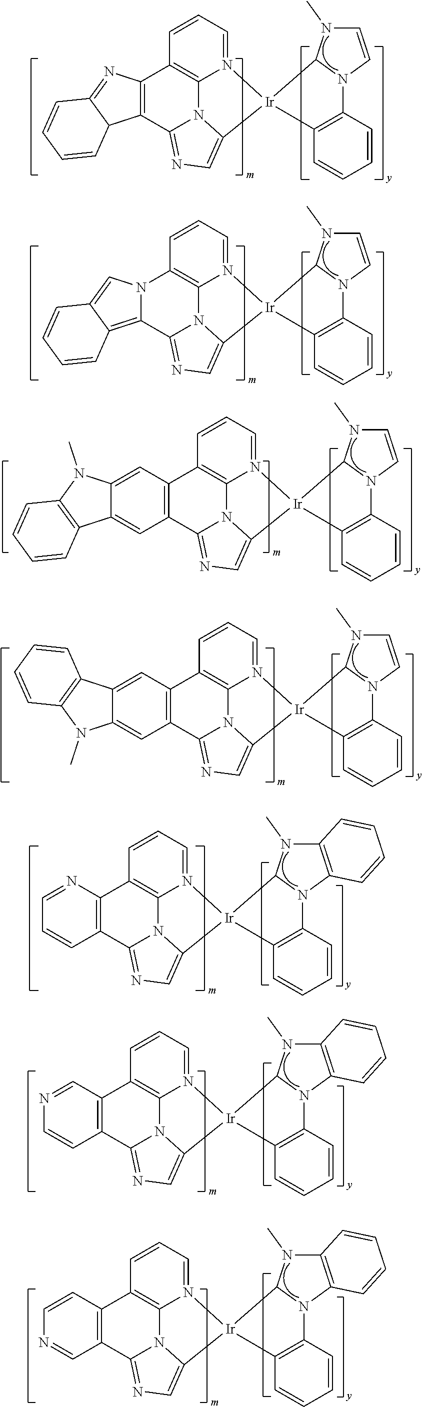

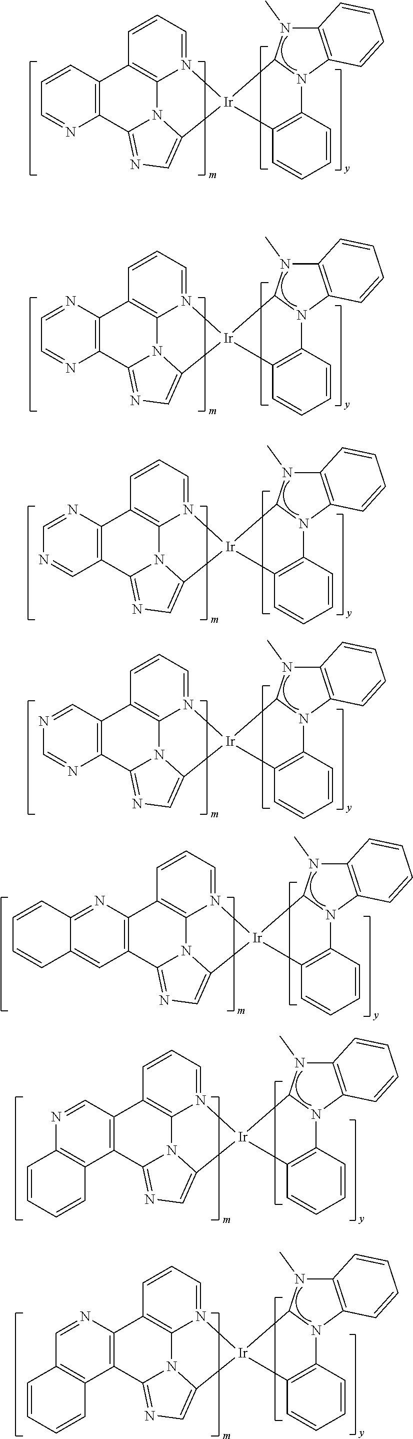

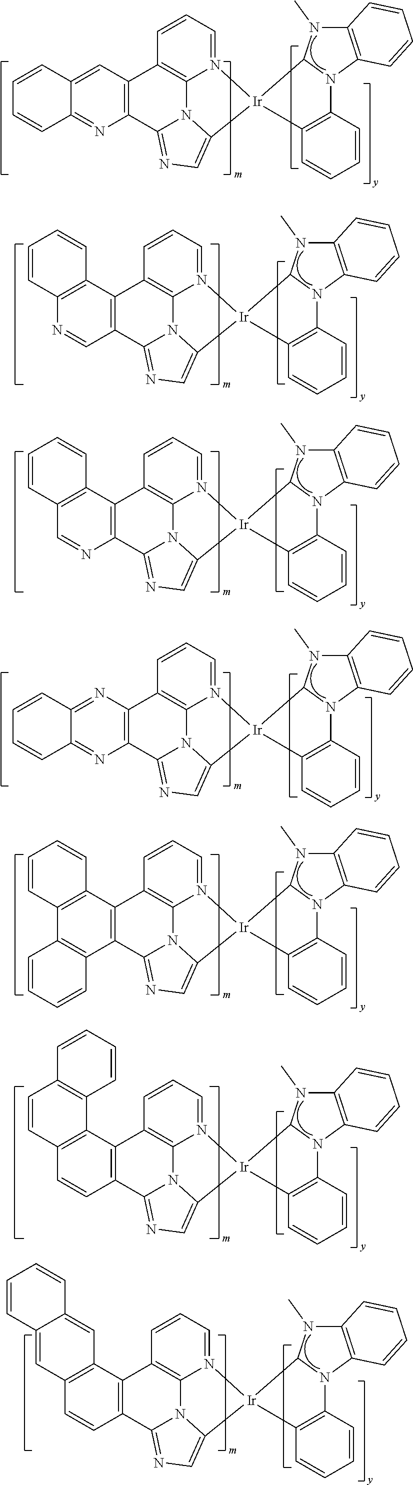

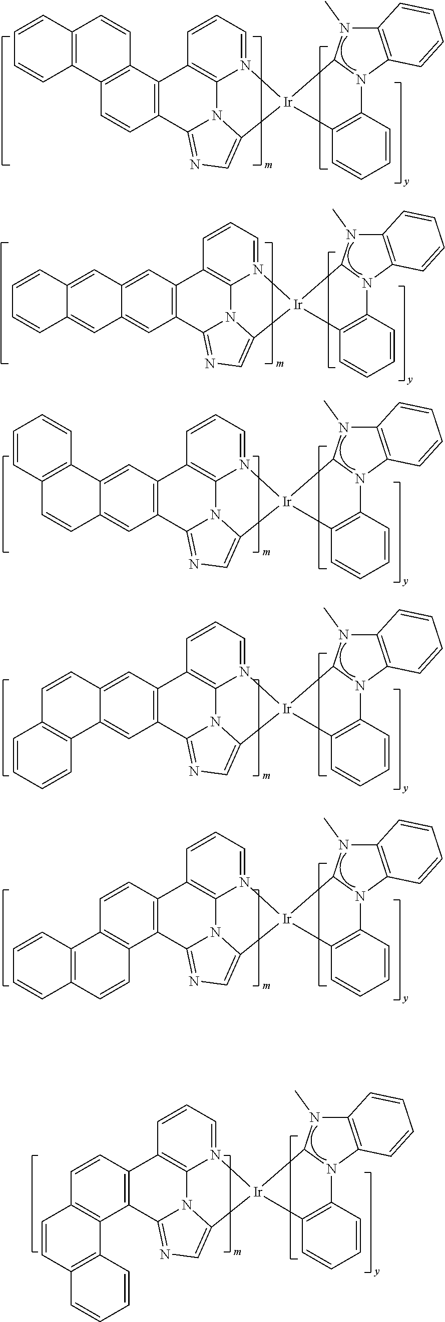

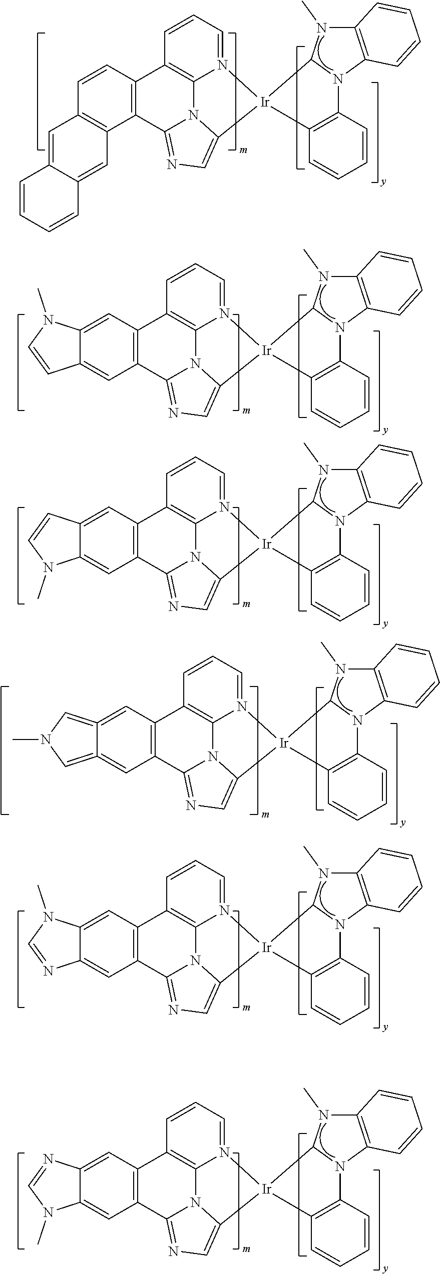

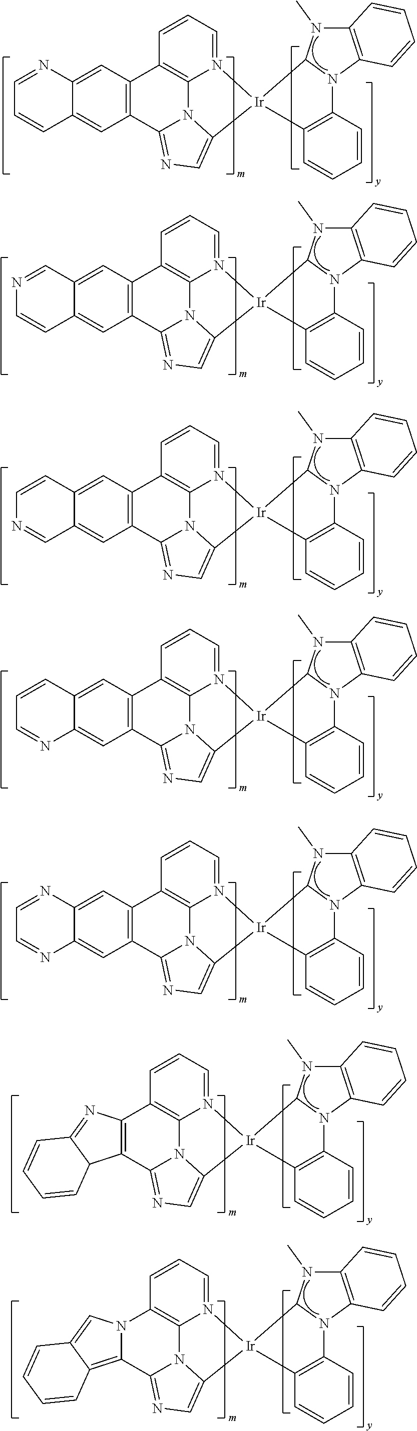

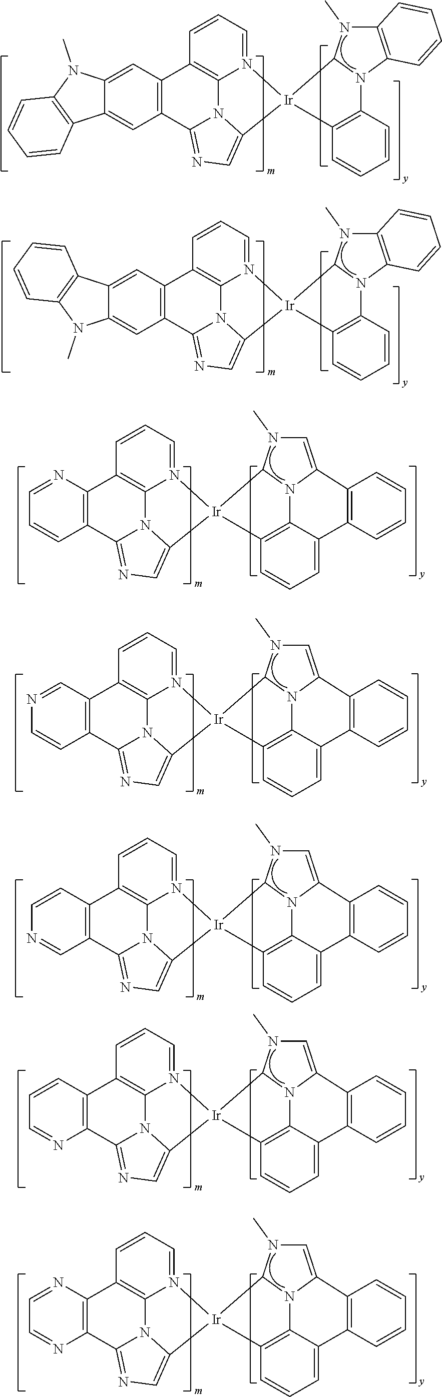

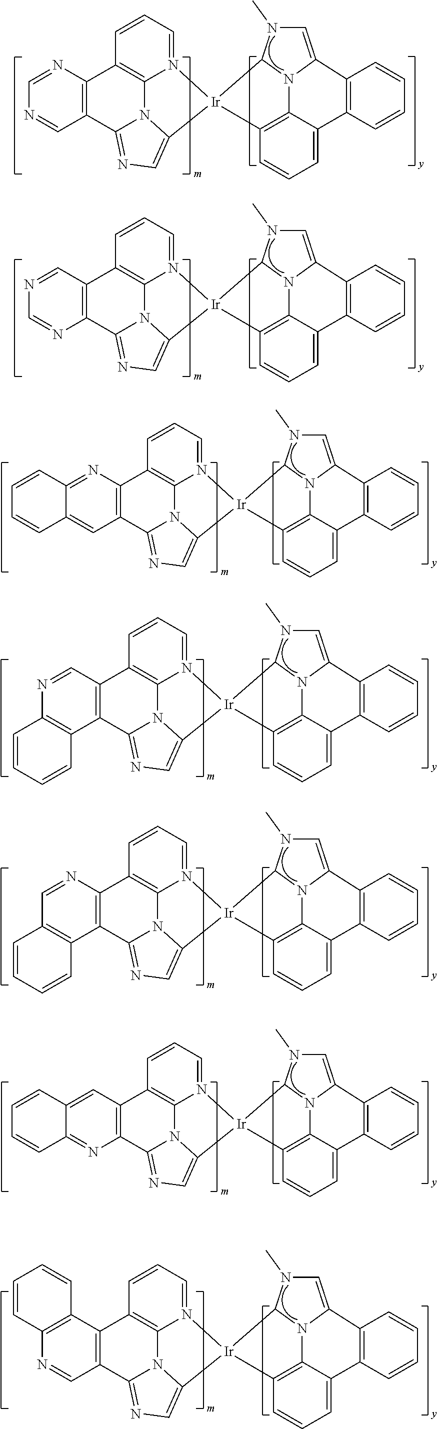

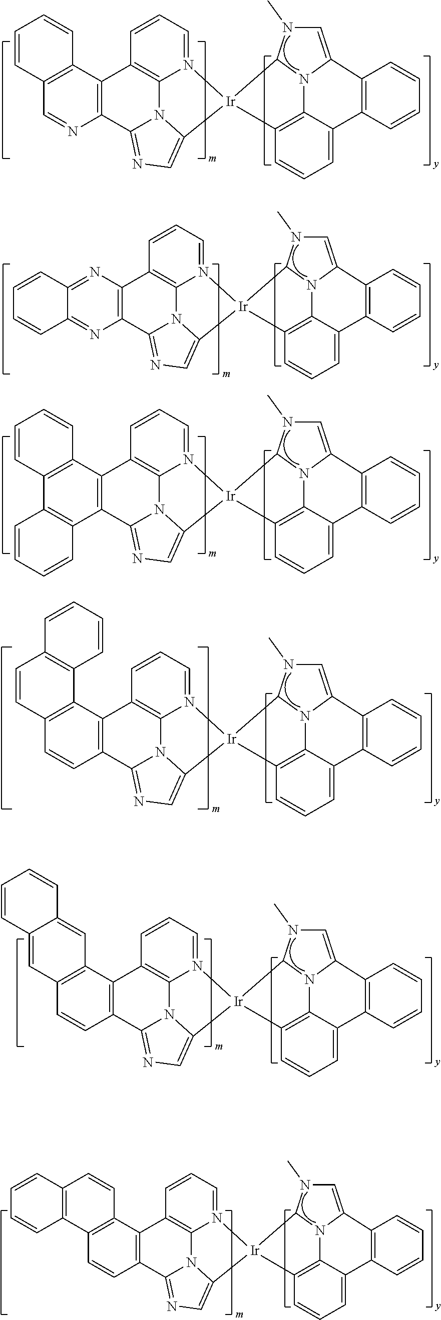

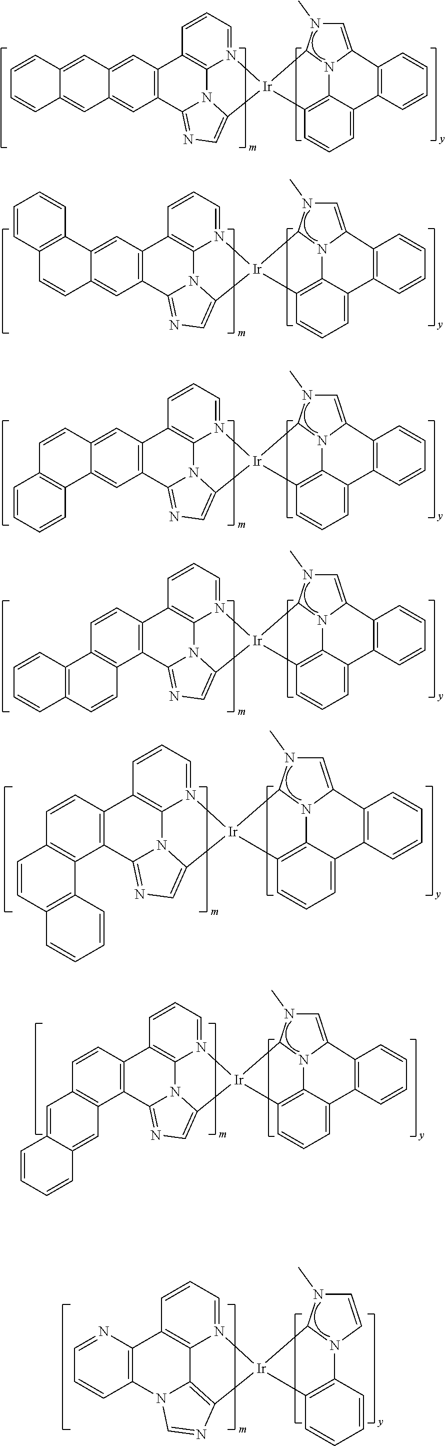

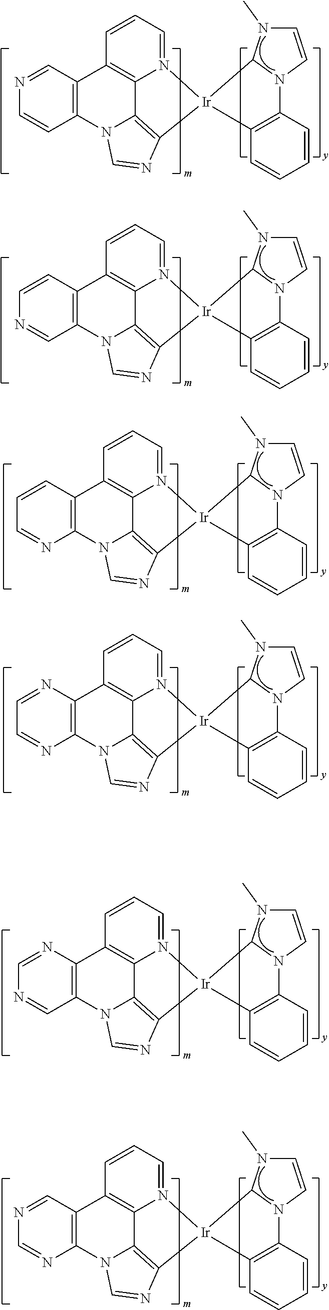

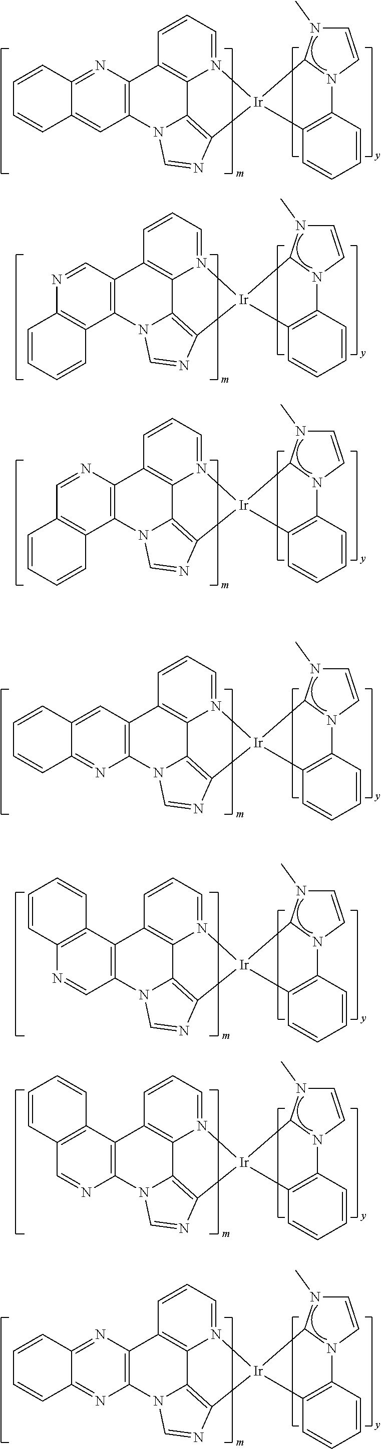

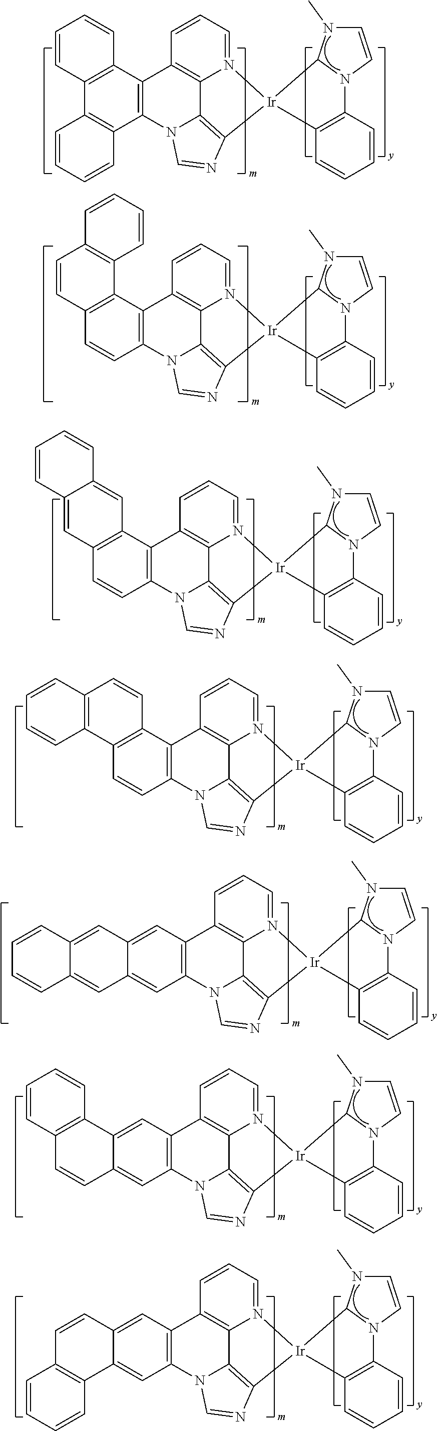

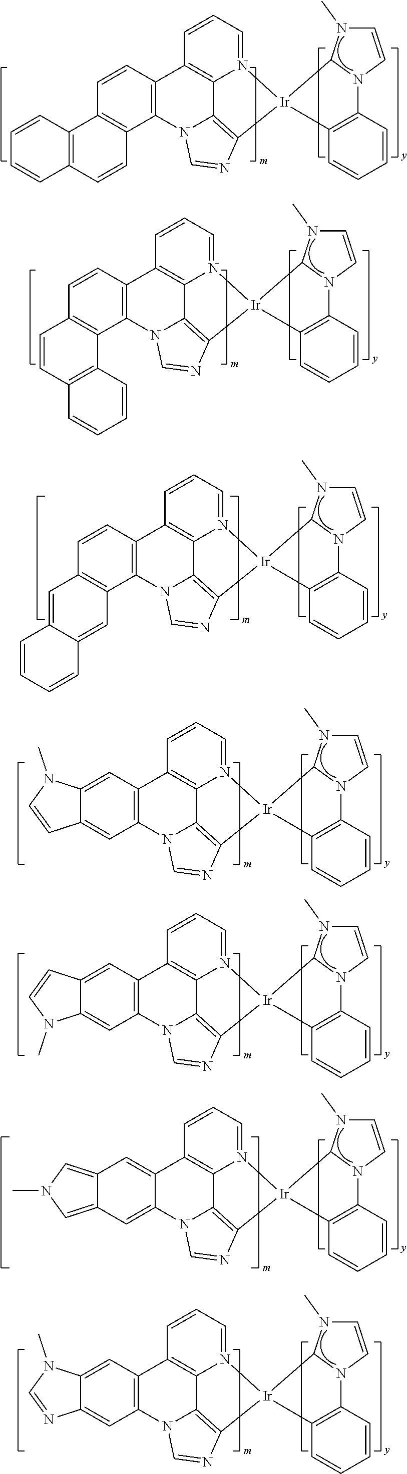

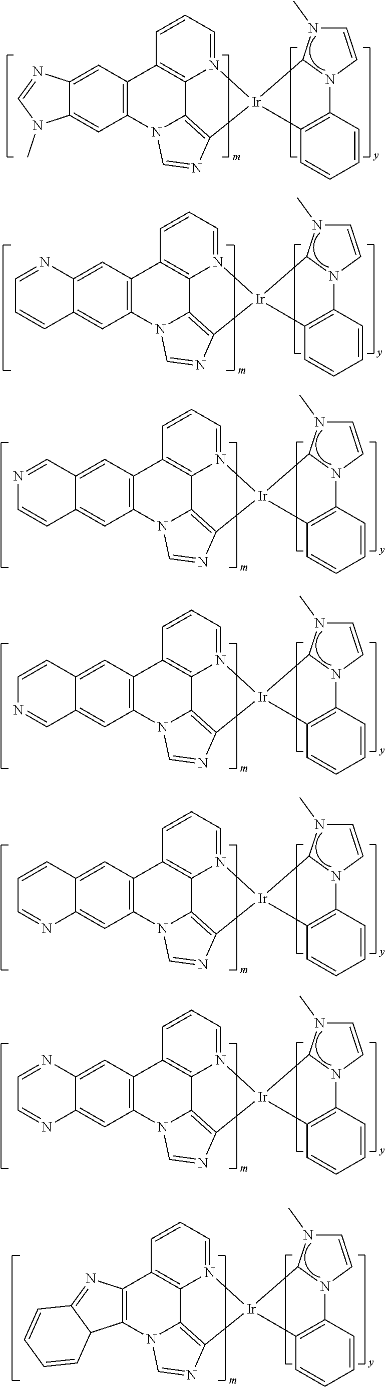

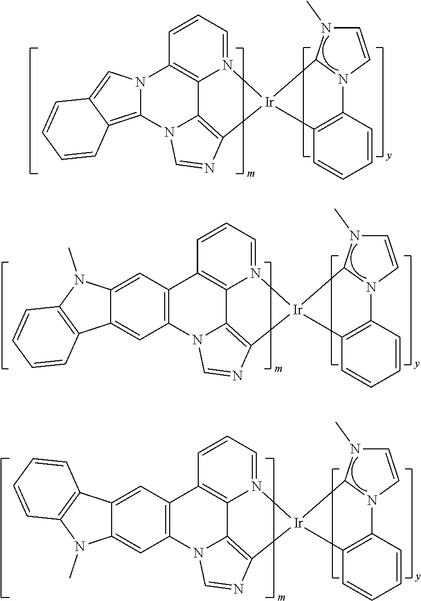

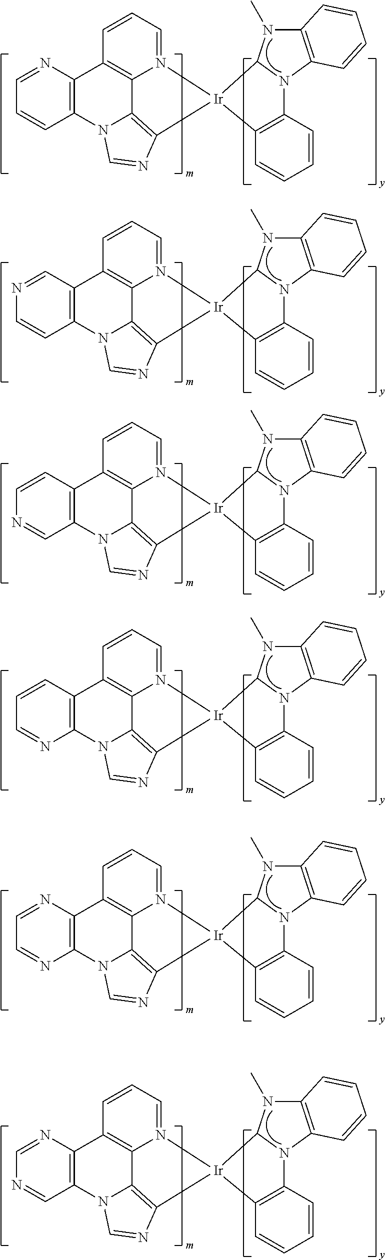

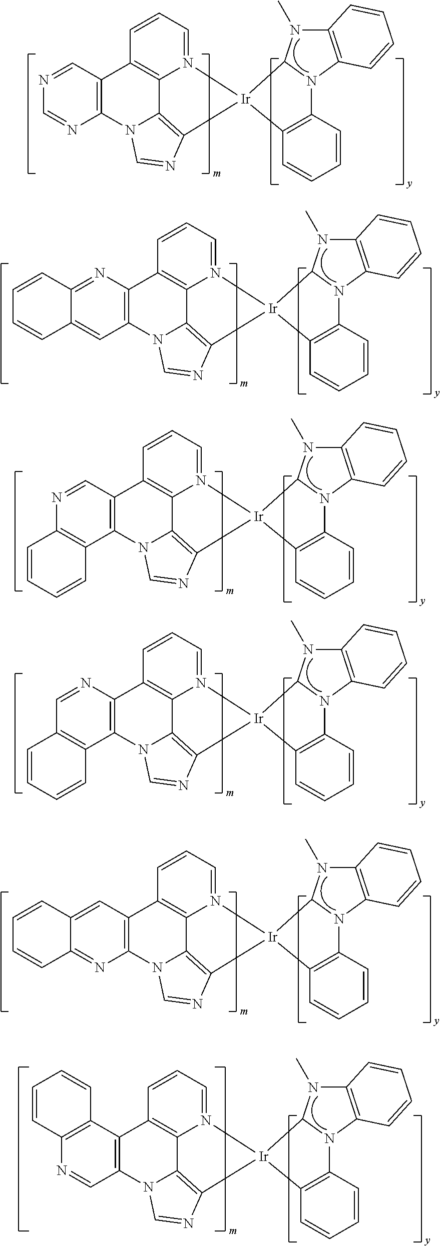

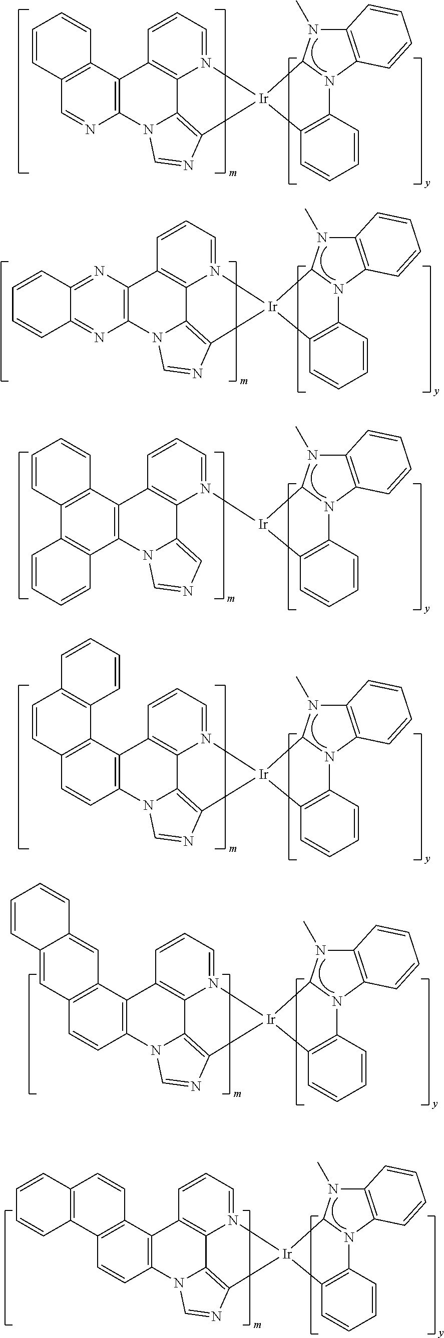

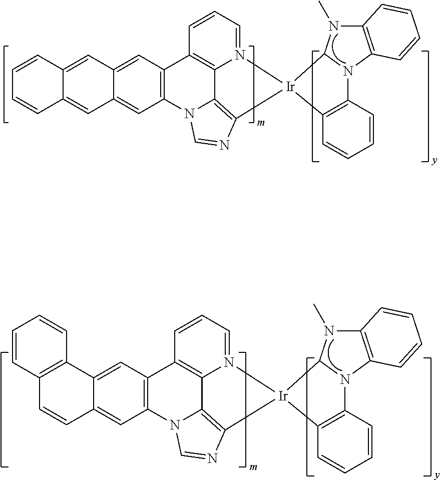

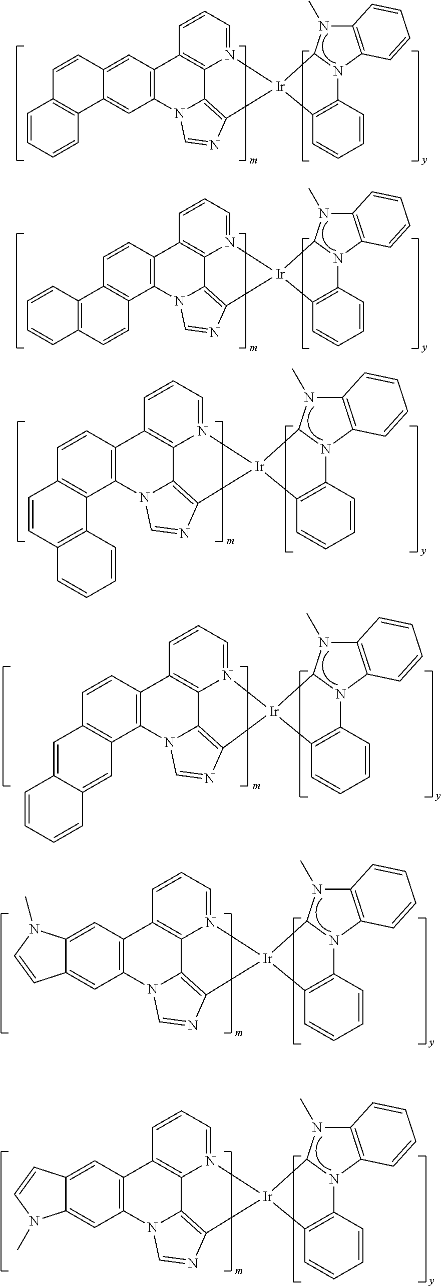

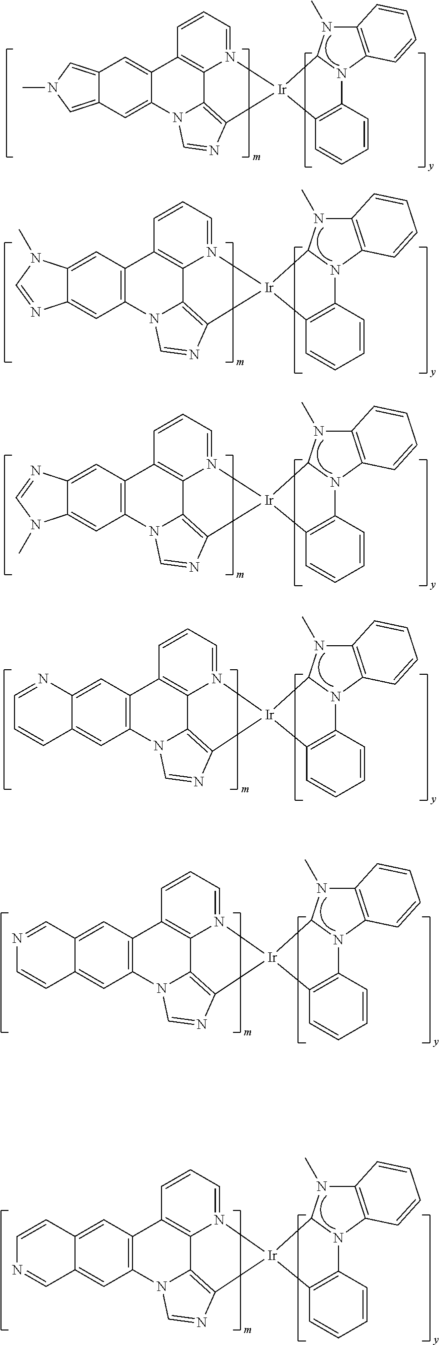

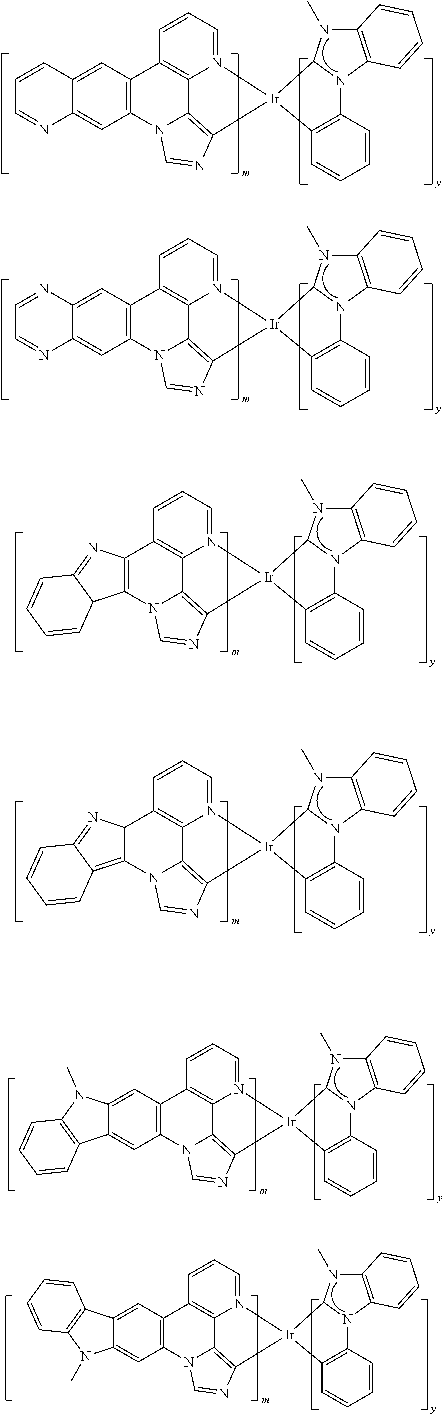

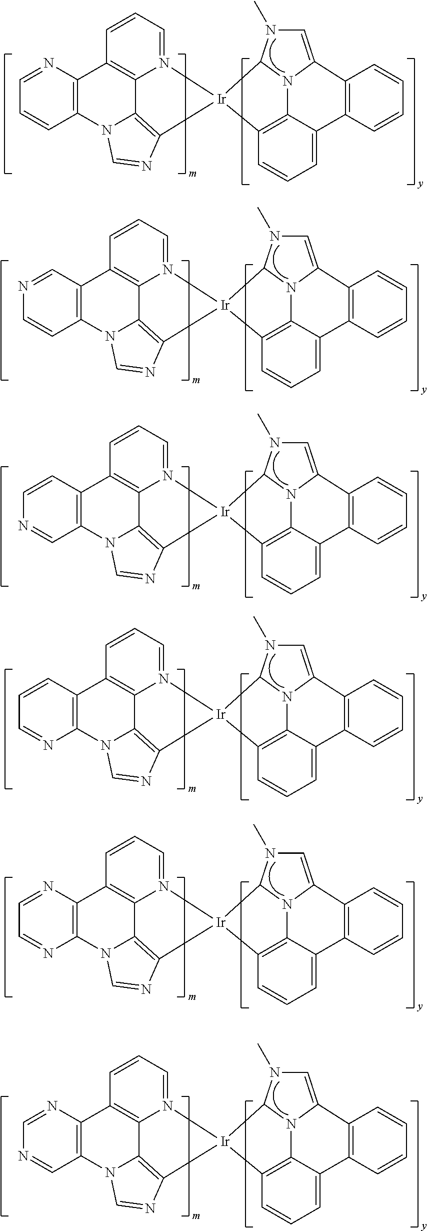

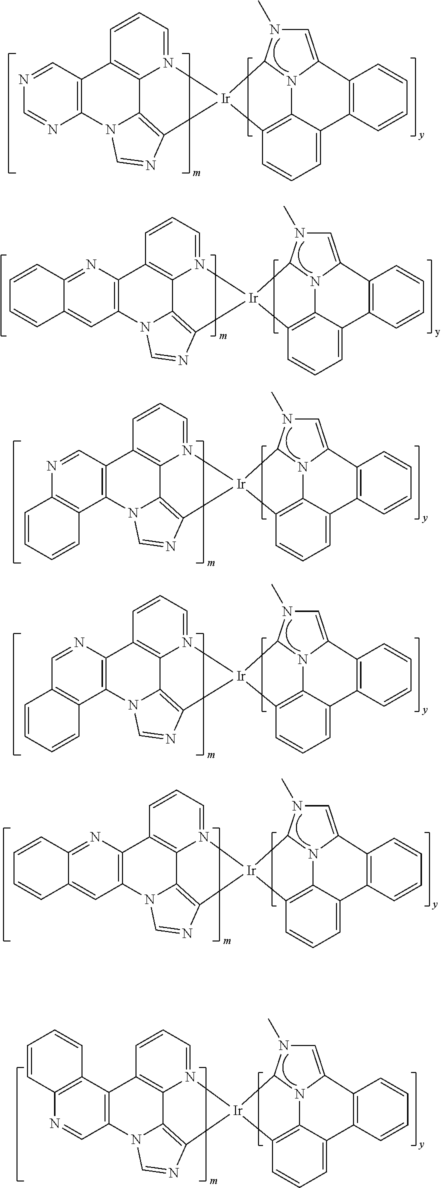

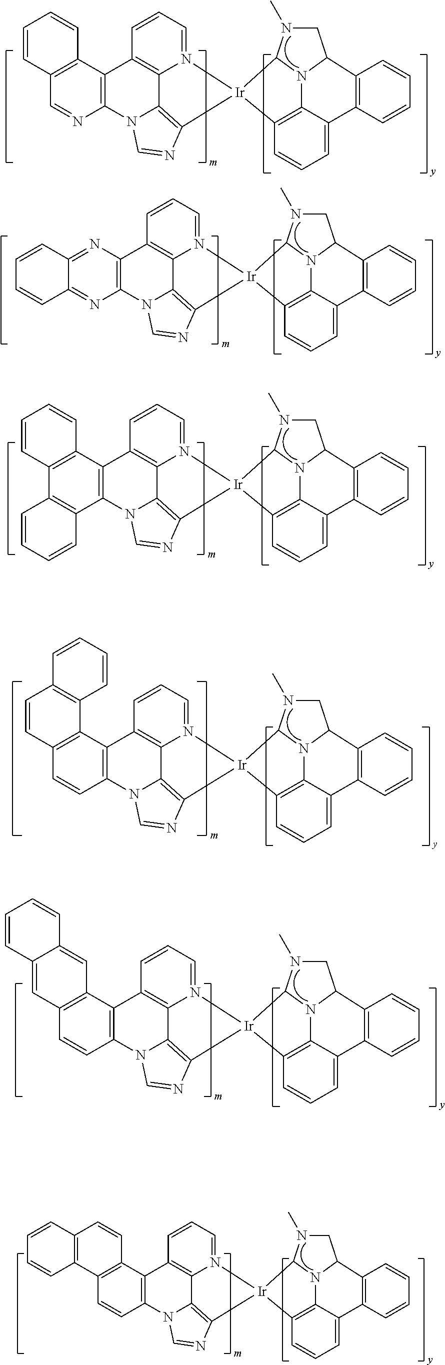

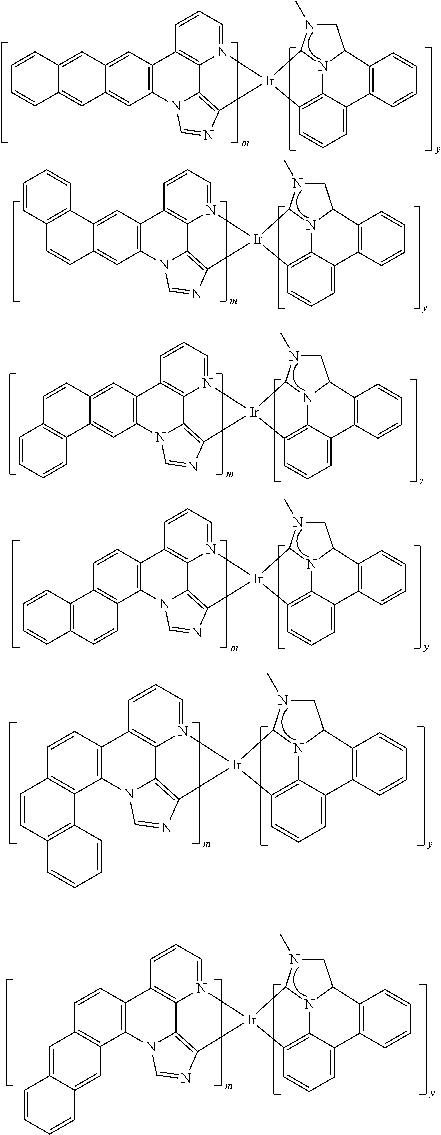

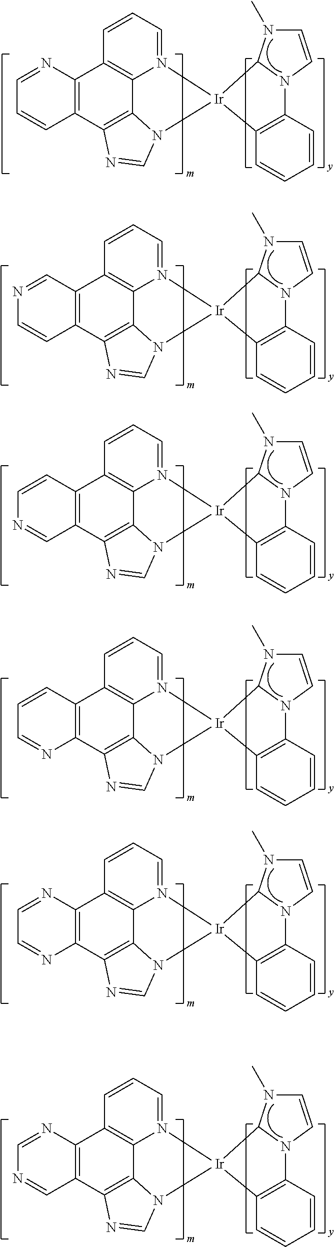

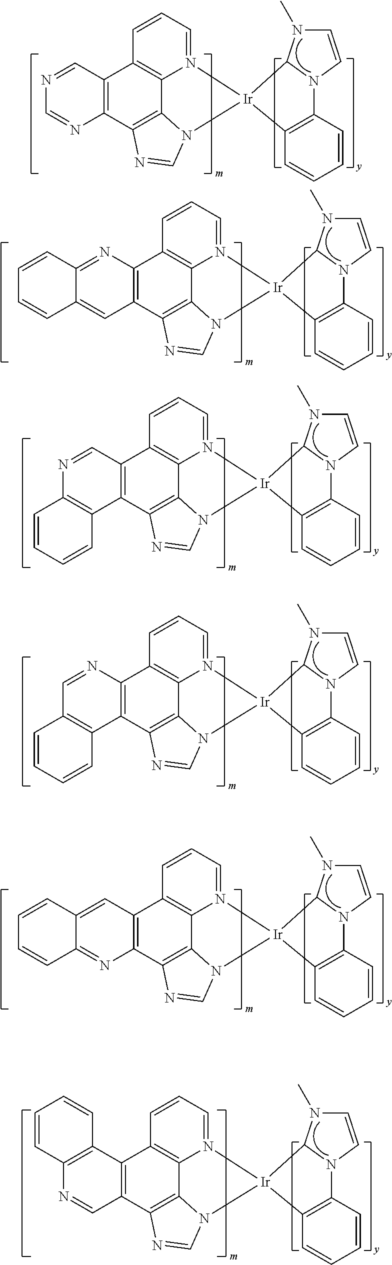

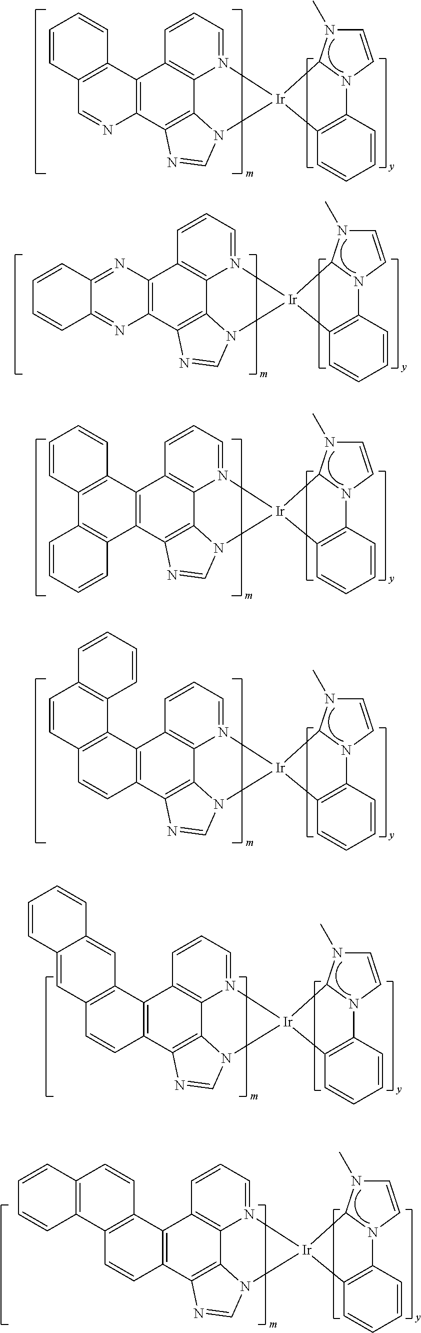

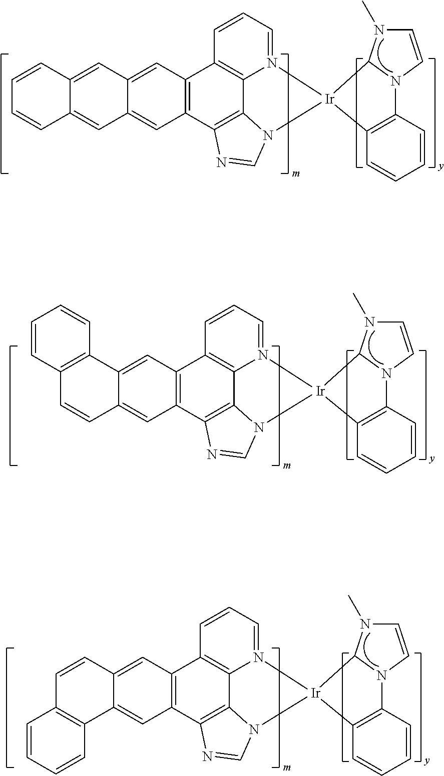

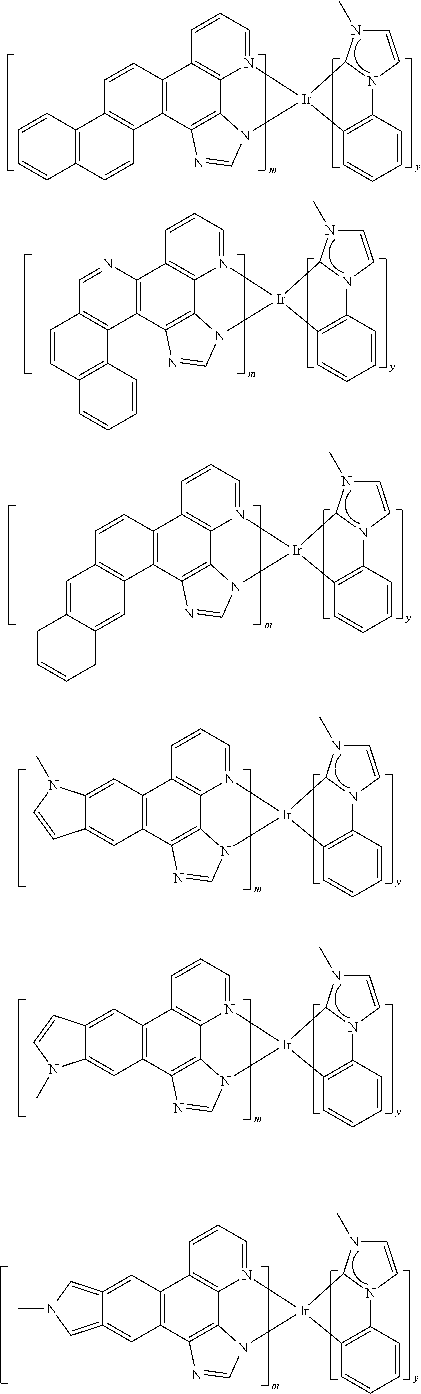

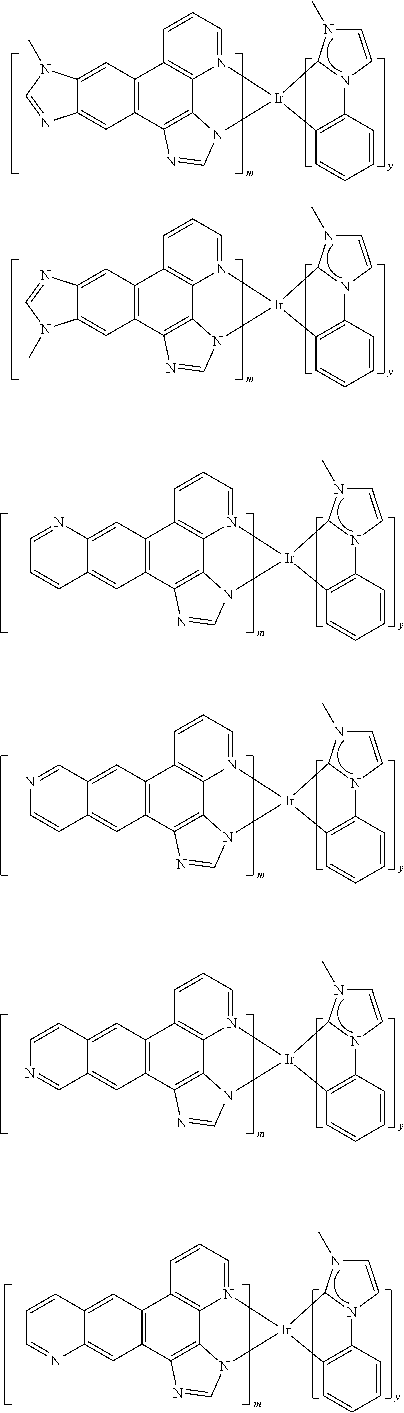

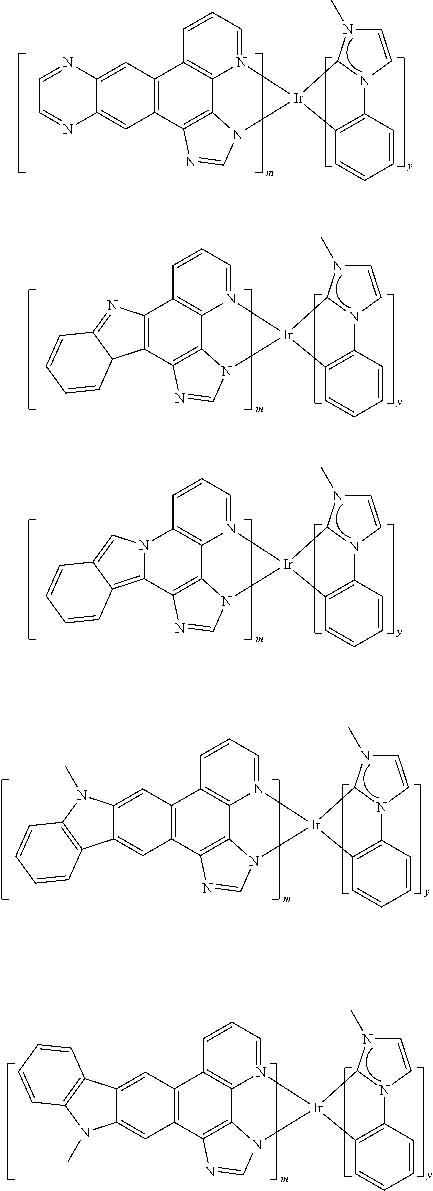

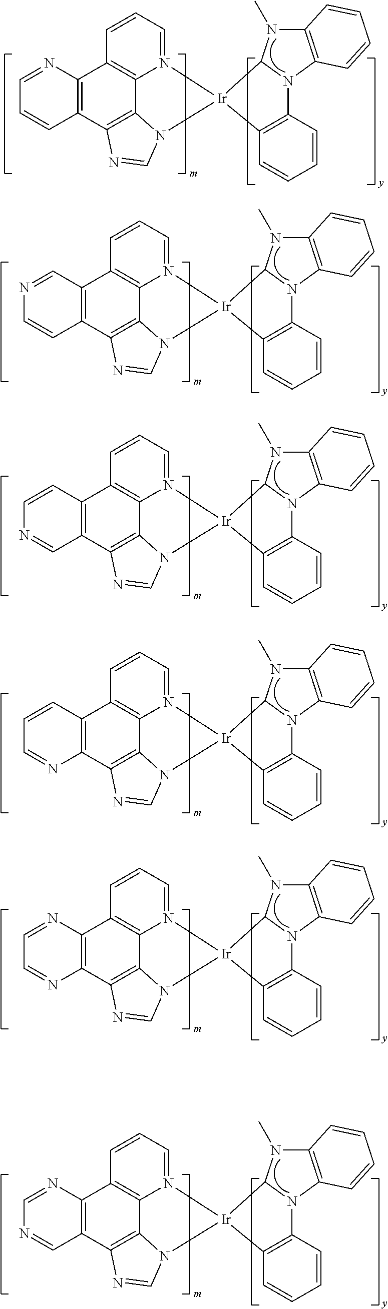

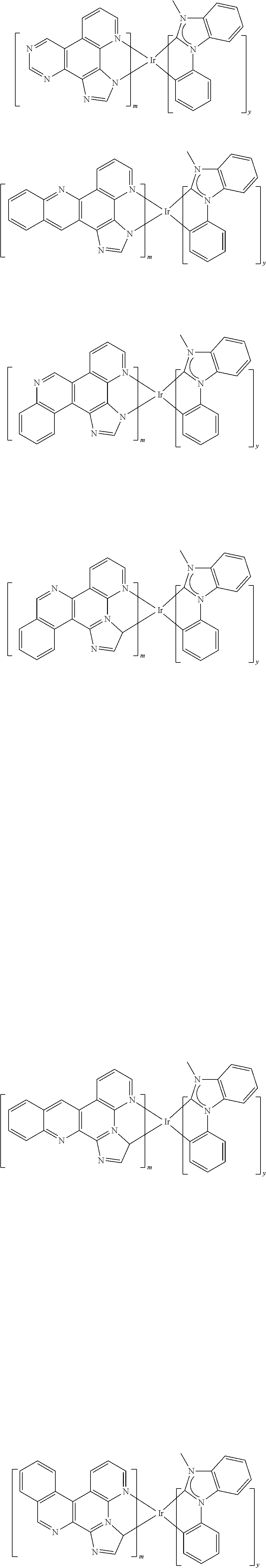

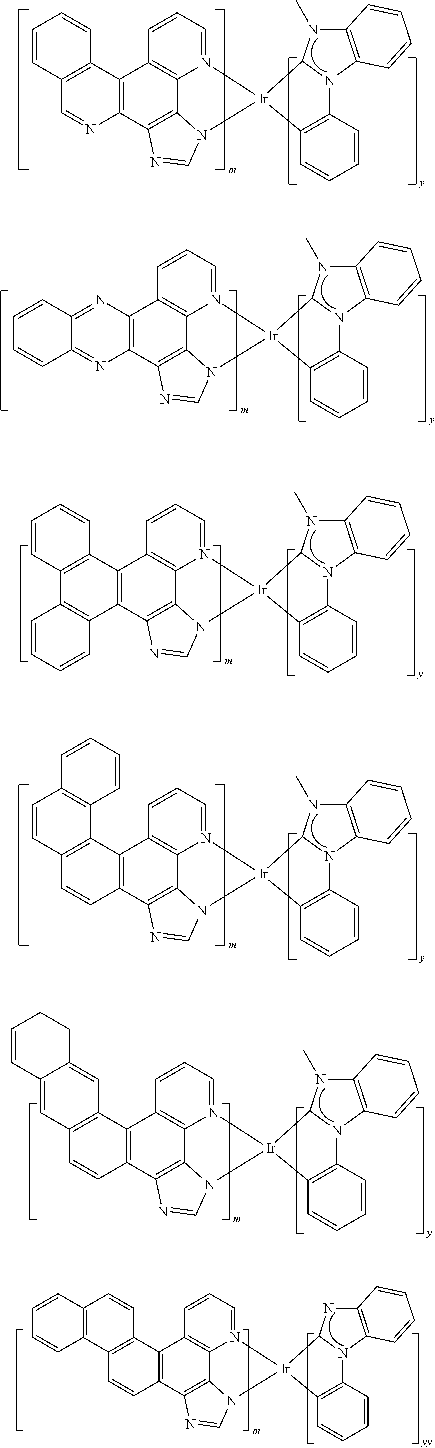

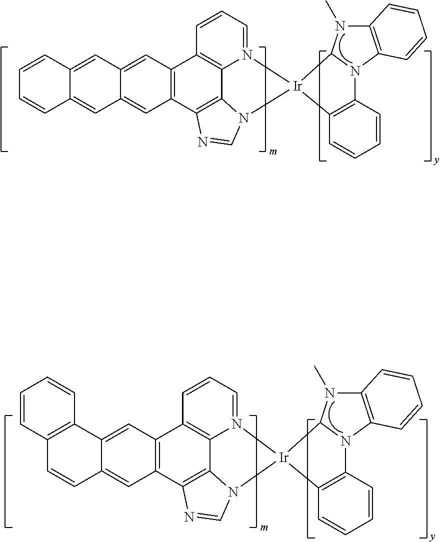

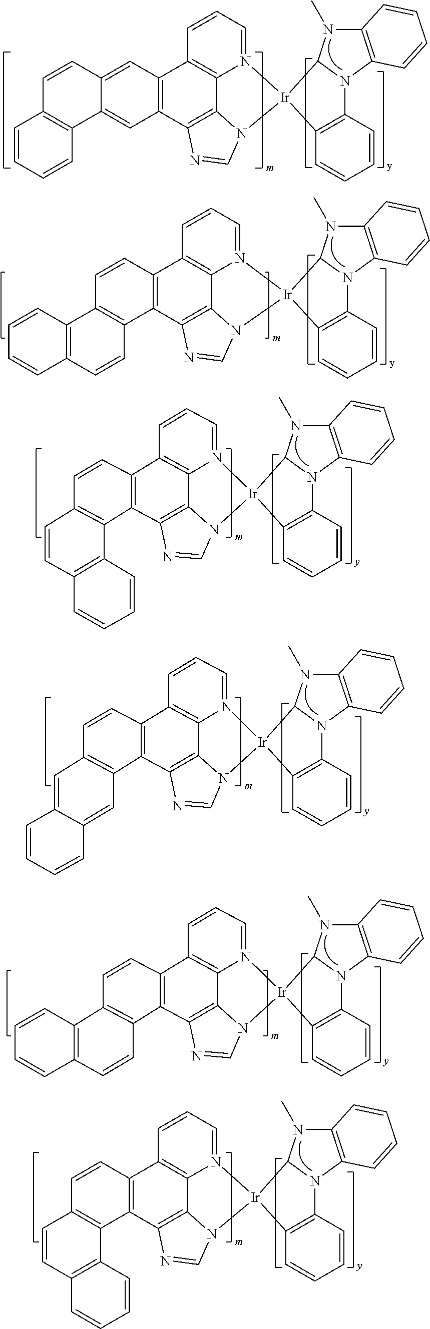

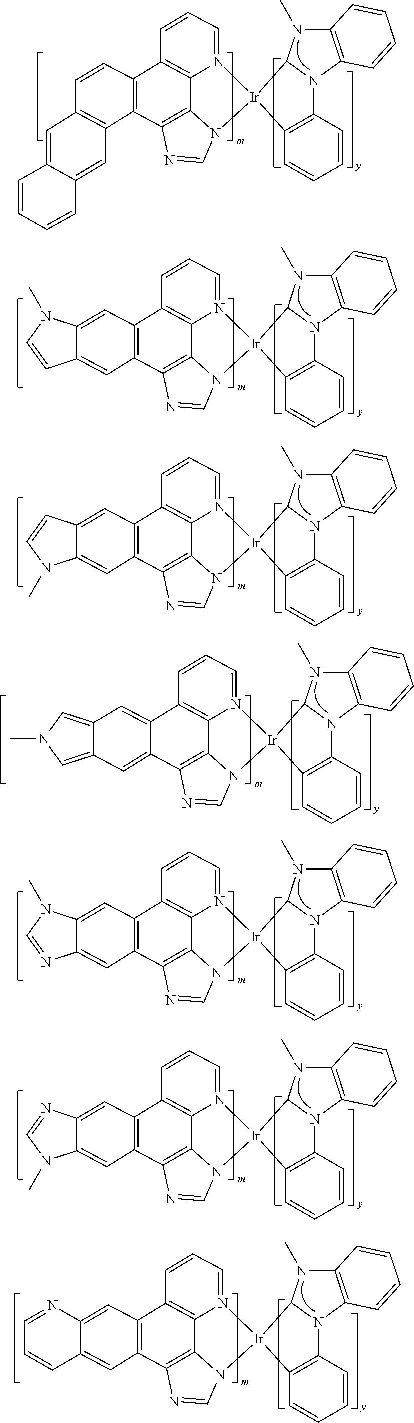

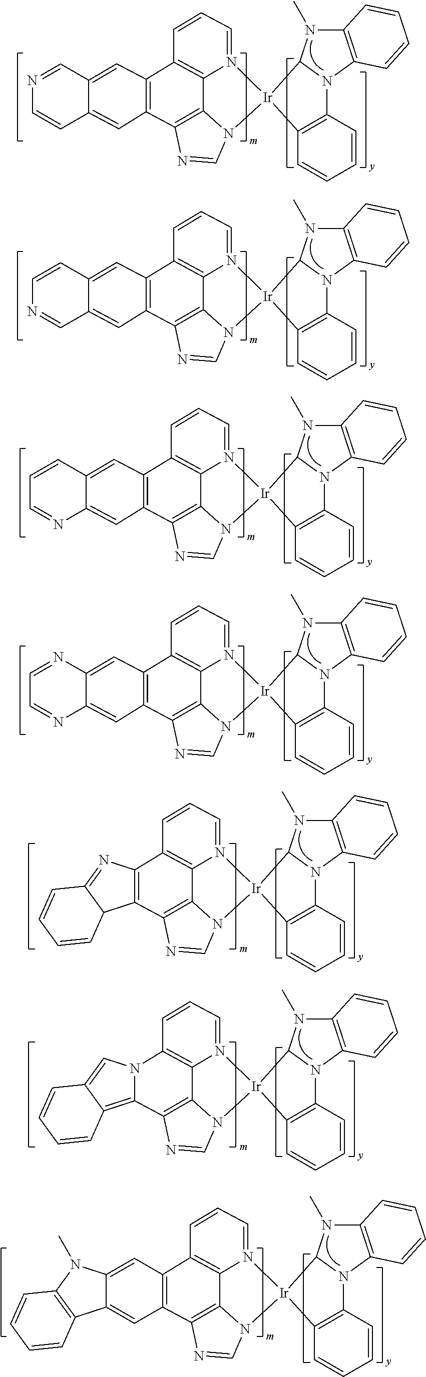

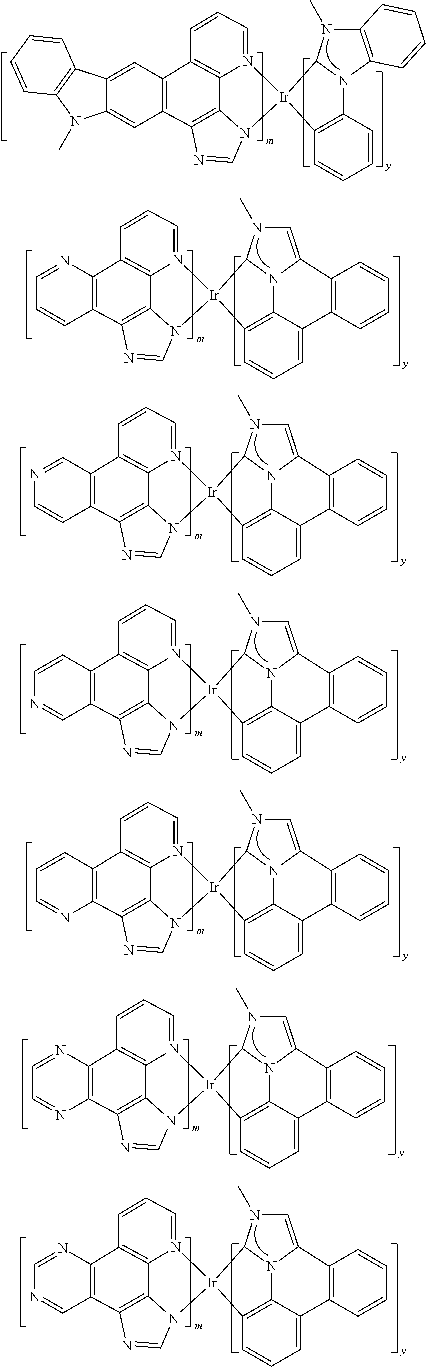

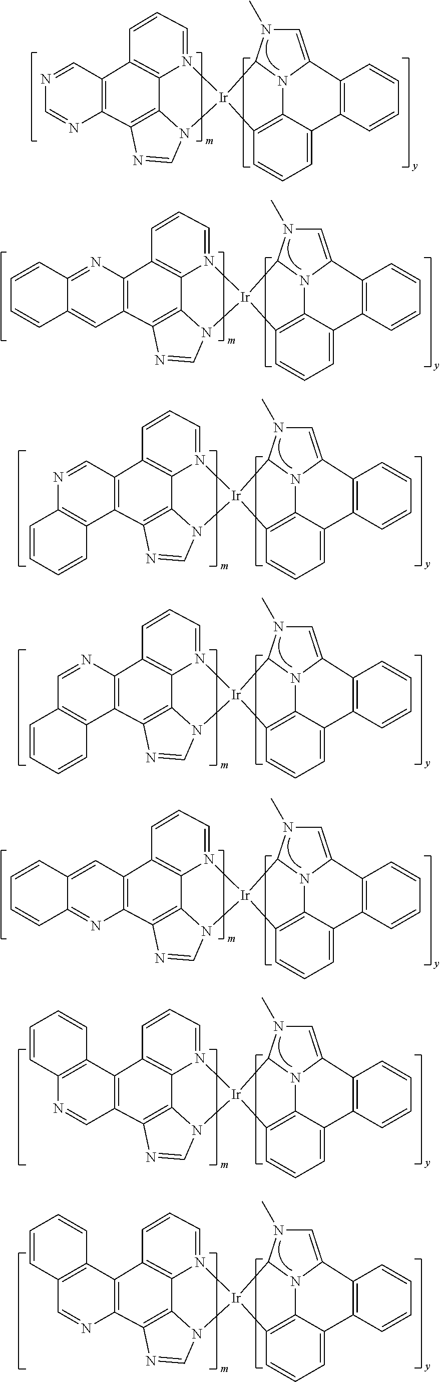

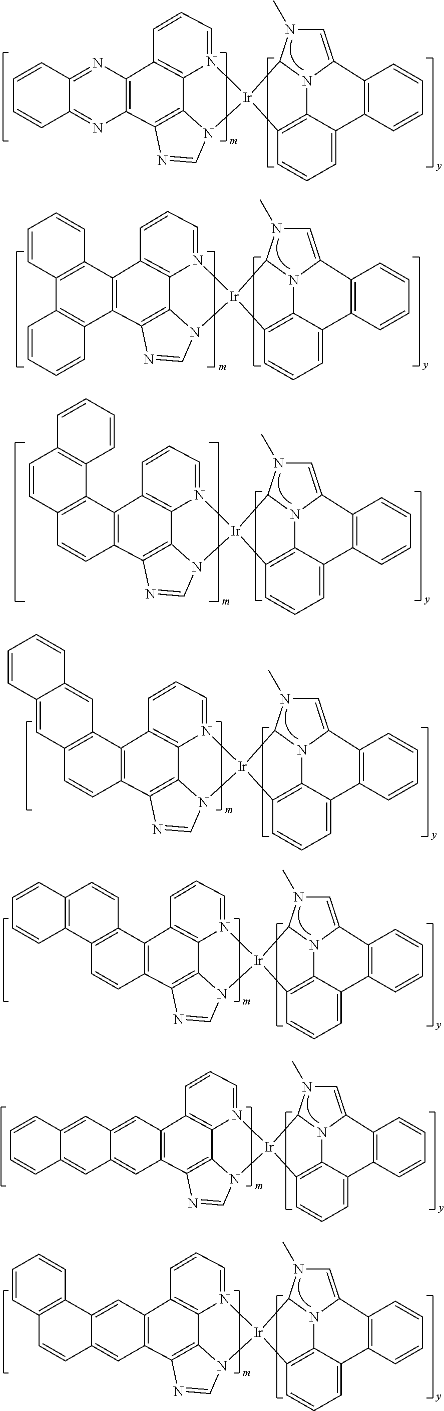

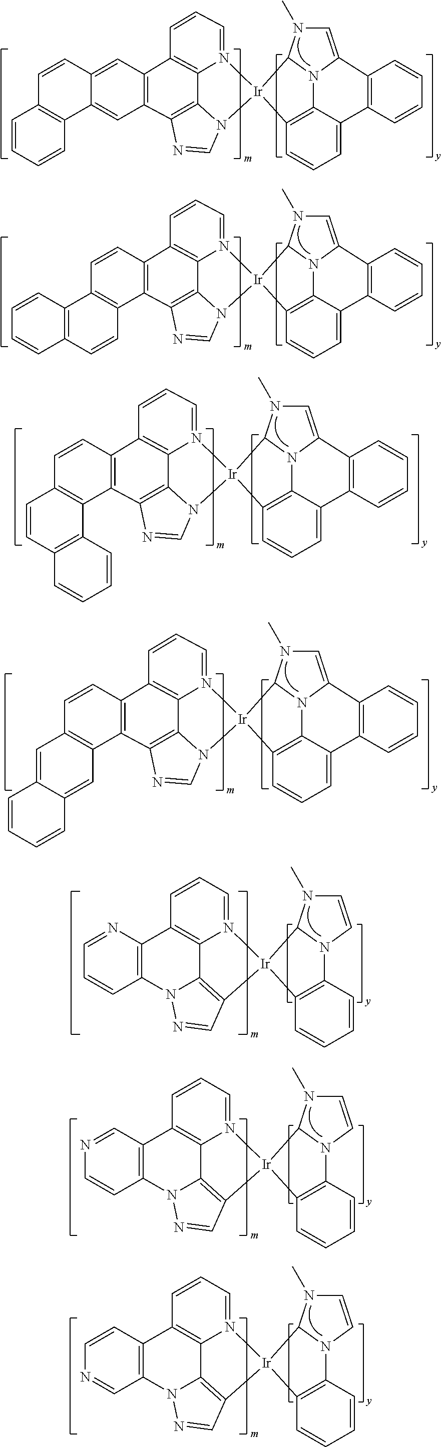

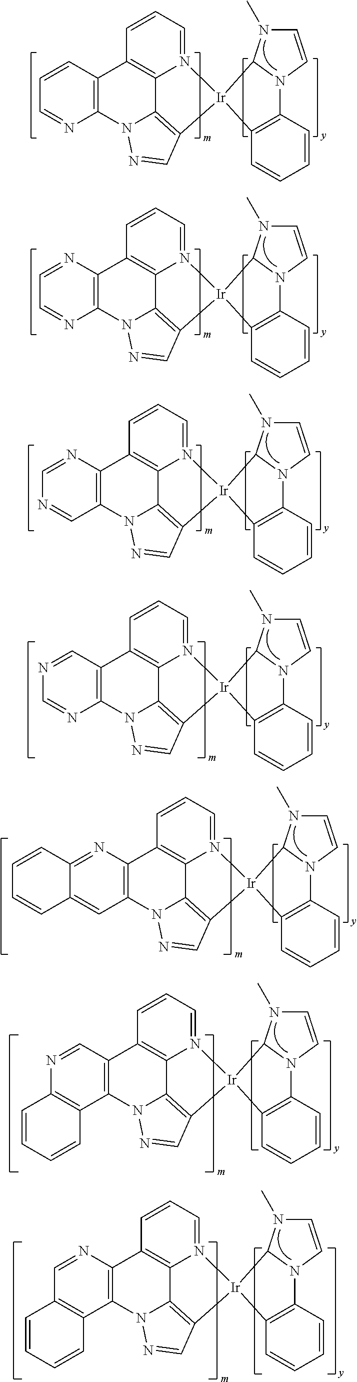

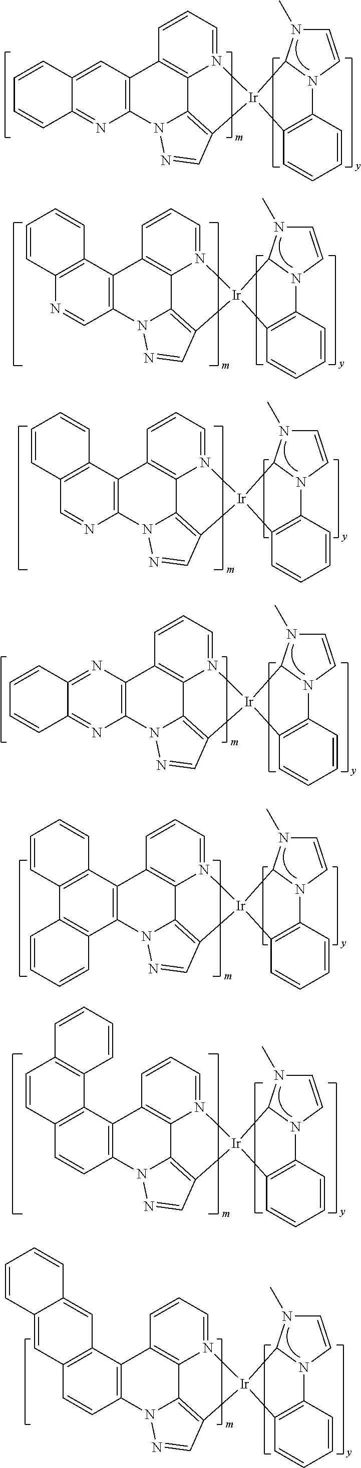

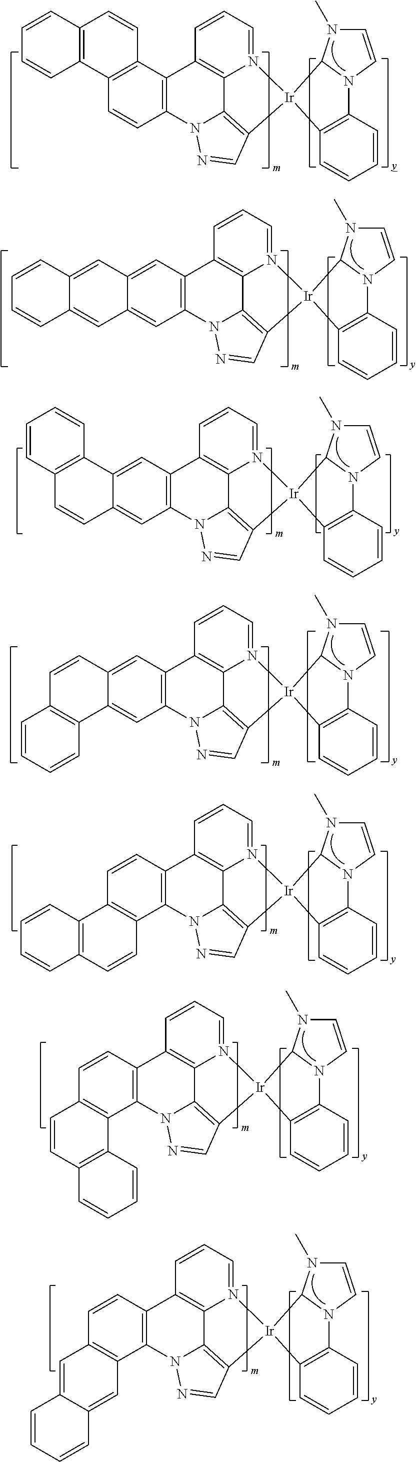

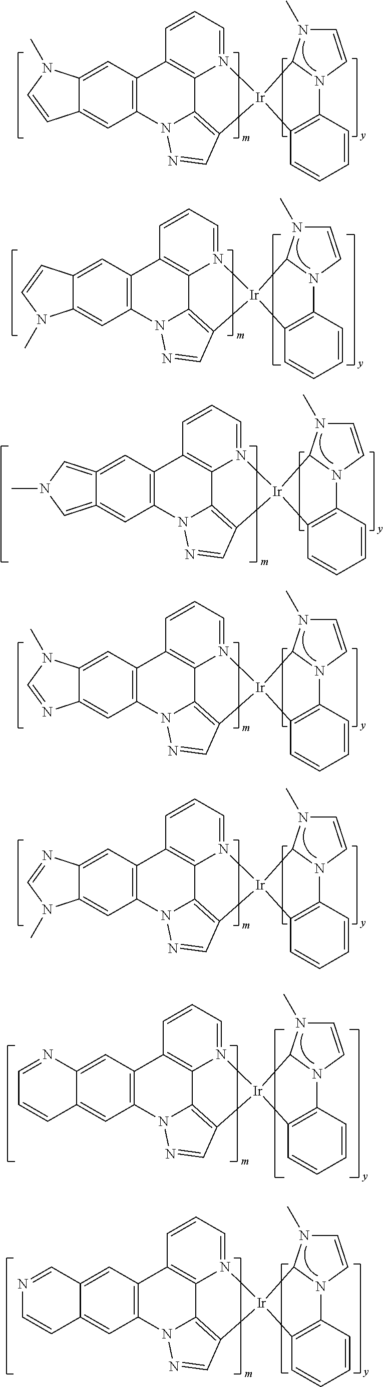

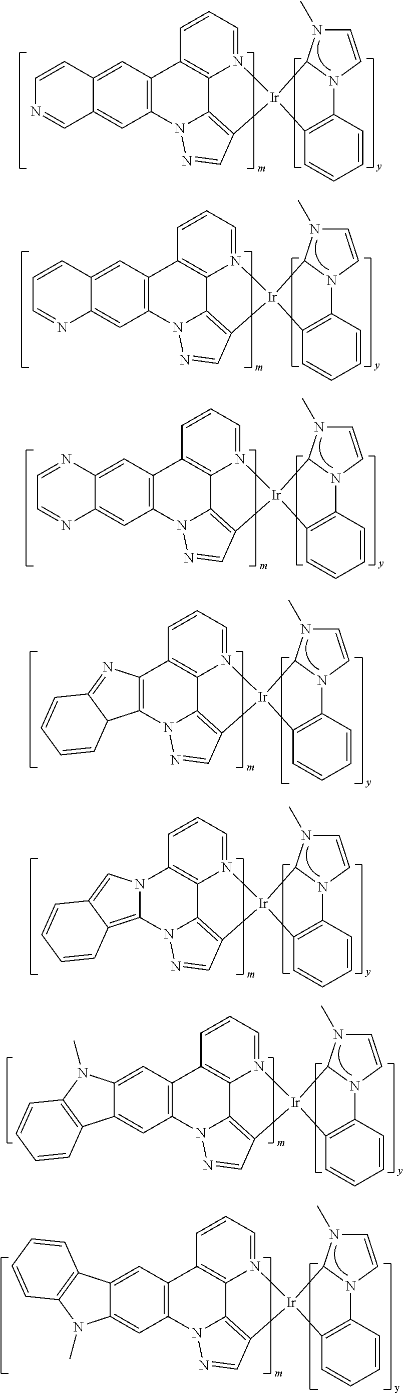

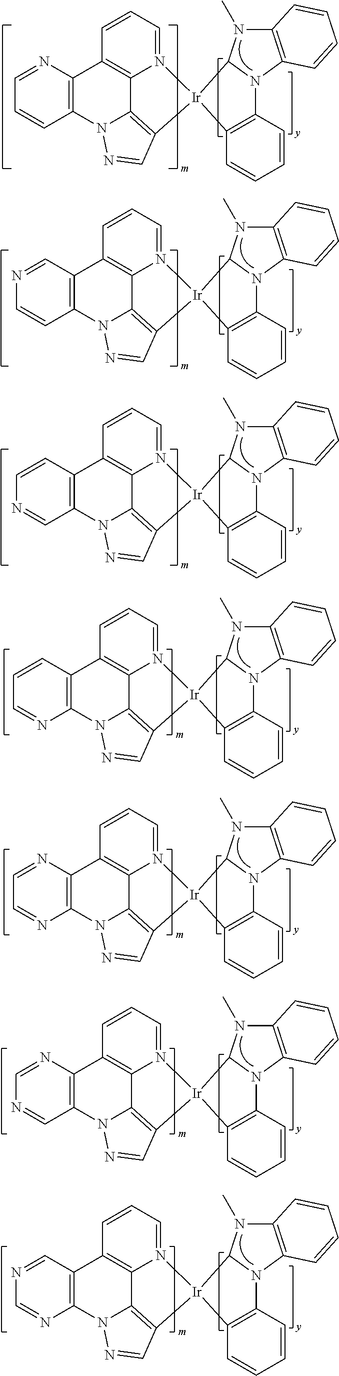

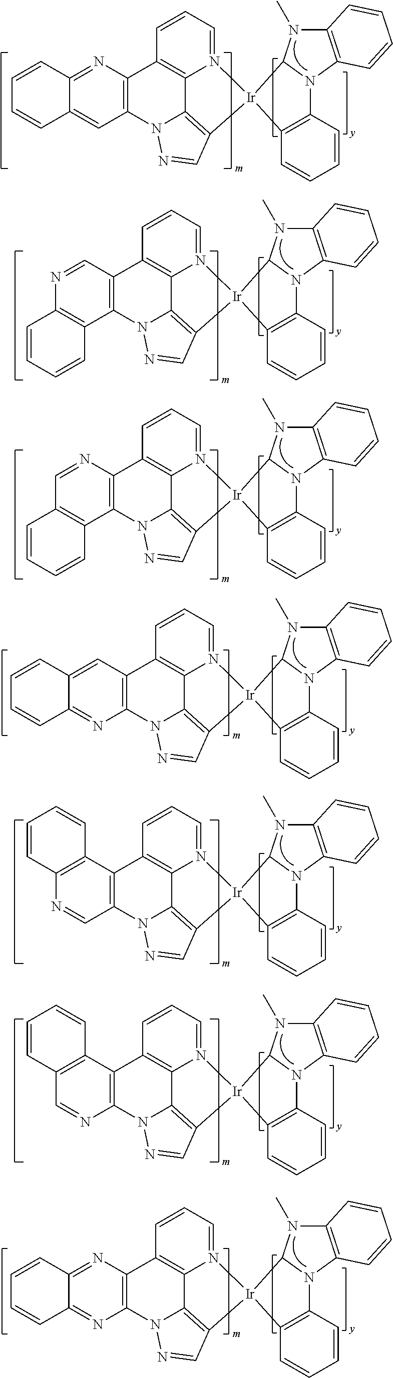

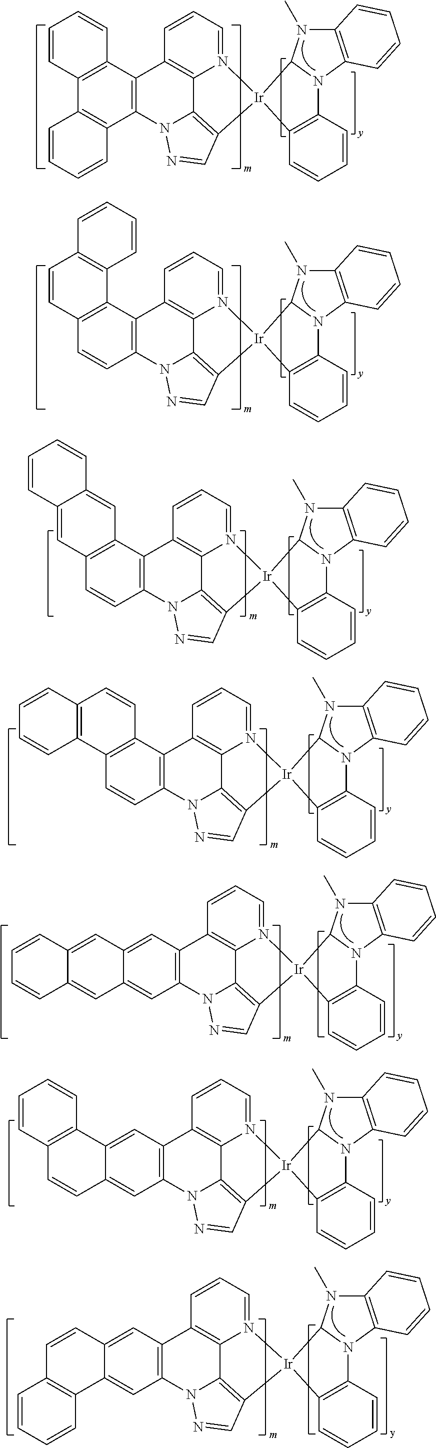

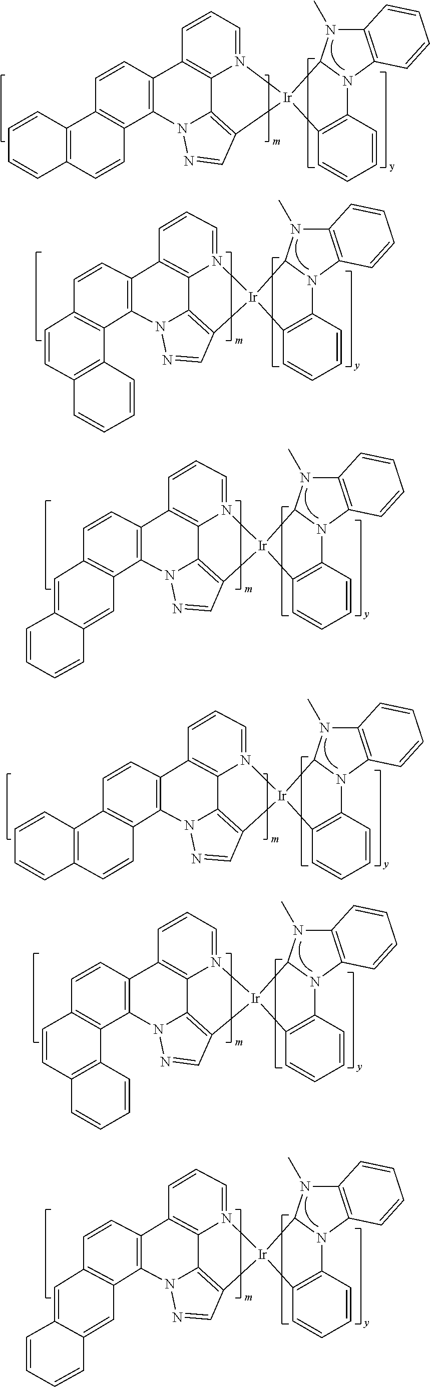

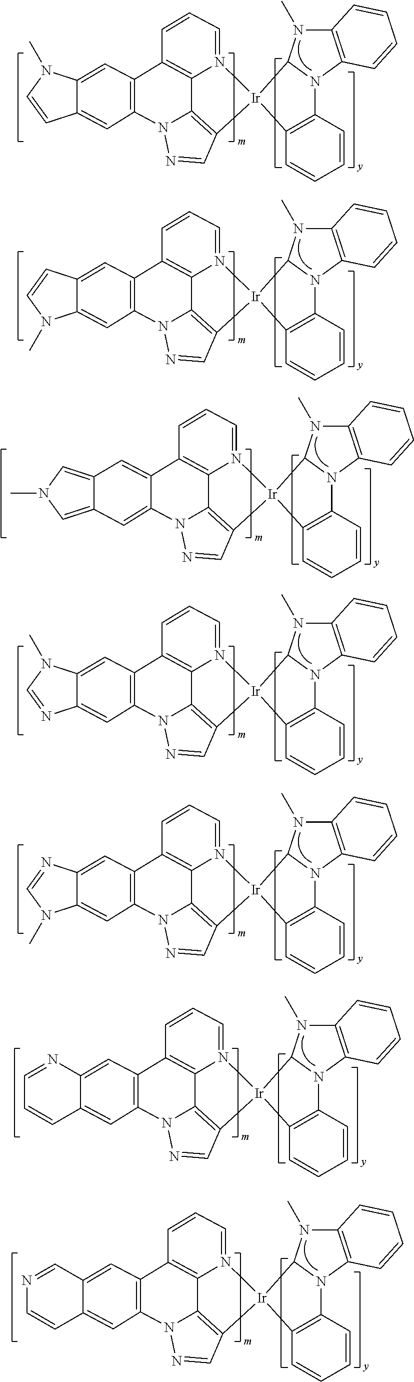

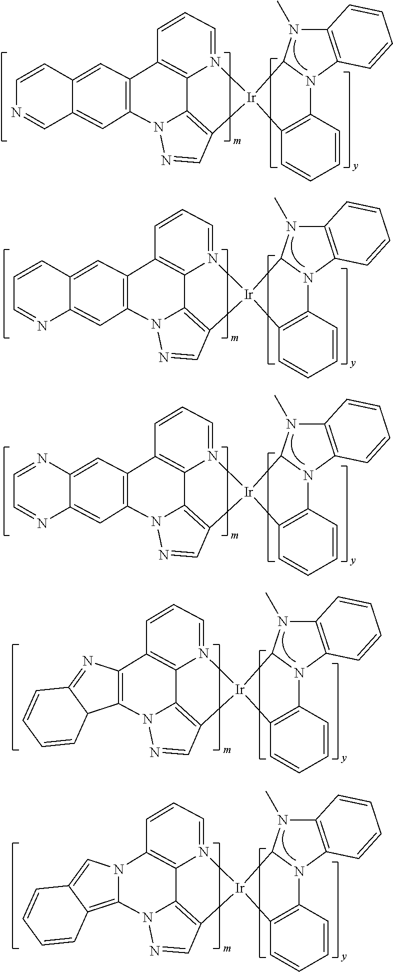

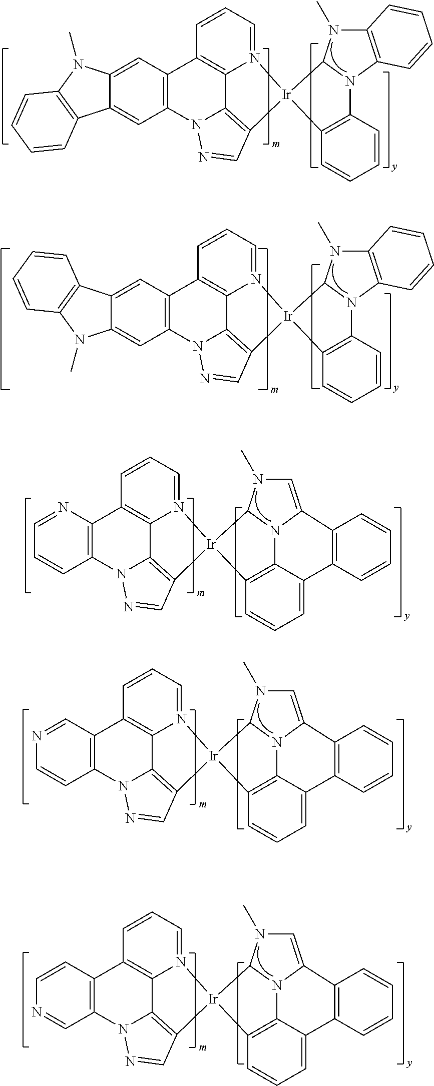

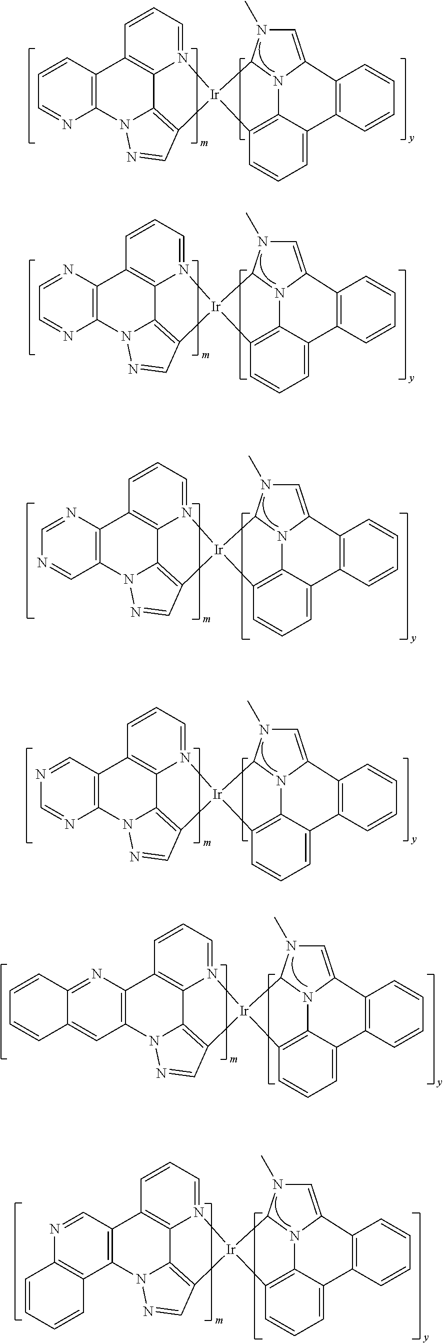

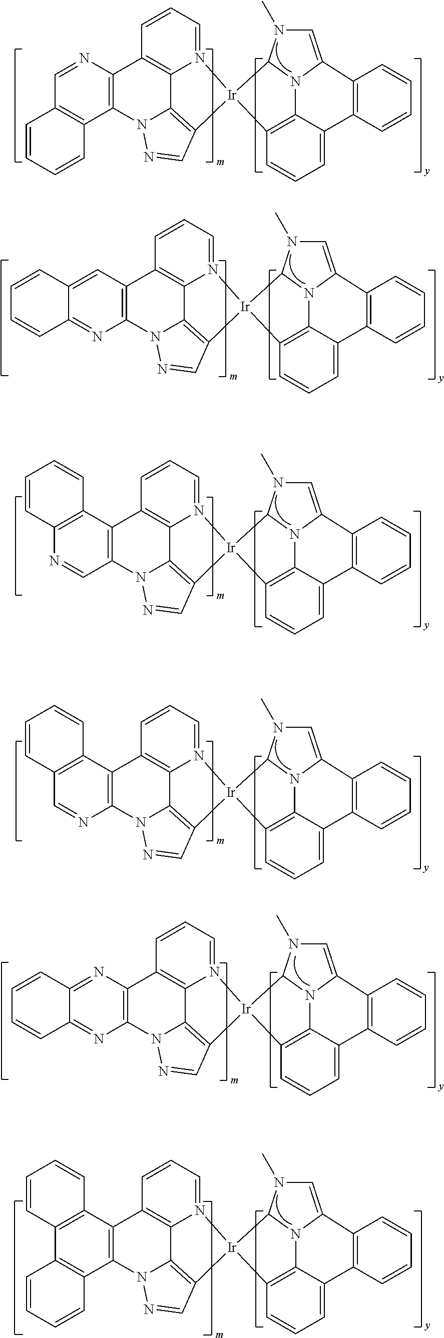

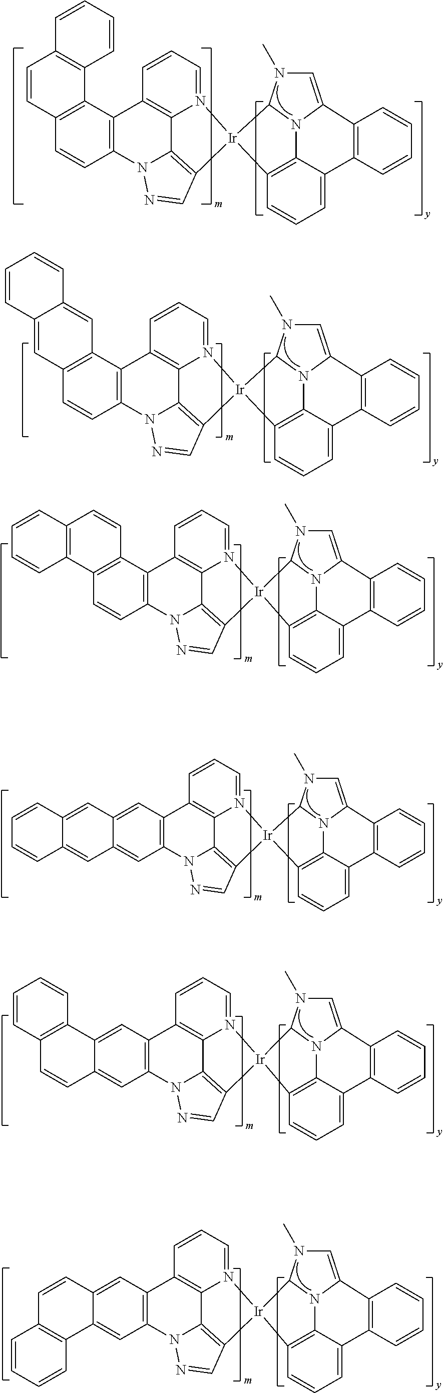

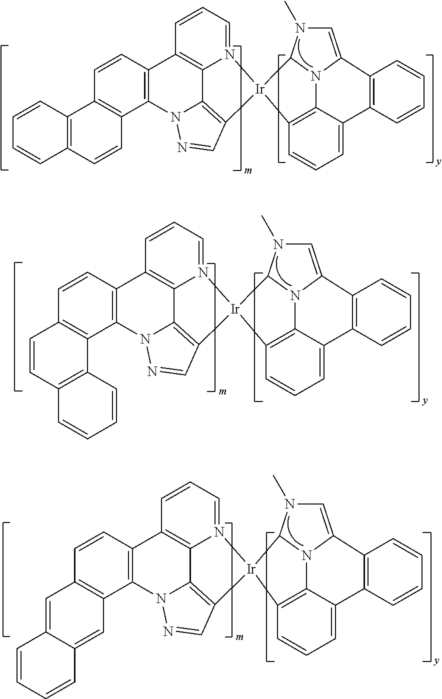

As referred to herein, a linking atom or group connects two atoms such as, for example, an N atom and a C atom. A linking atom or group is in one aspect disclosed as L¹, L², L³, etc. herein. The linking atom can optionally, if valency permits, have other chemical moieties attached. For example, in one aspect, an oxygen would not have any other chemical groups attached as the valency is satisfied once it is bonded to two groups (e.g., N and/or C groups). In another aspect, when carbon is the linking atom, two additional chemical moieties can be attached to the carbon. Suitable chemical moieties include amine, amide, thiol, aryl, heteroaryl, cycloalkyl, and heterocyclyl moieties. The term “cyclic structure” or the like terms used herein refer to any cyclic chemical structure which includes, but is not limited to, aryl, heteroaryl, cycloalkyl, cycloalkenyl, heterocyclyl, carbene, and N-heterocyclic carbene.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

In defining various terms, “A¹”, “A²”, “A³”, “A⁴” and “A⁵” are used herein as generic symbols to represent various specific substituents. These symbols can be any substituent, not limited to those disclosed herein, and when they are defined to be certain substituents in one instance, they can, in another instance, be defined as some other substituents.

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dode cyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenyl alcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbornyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The terms “alkoxy” and “alkoxyl” as used herein to refer to an alkyl or cycloalkyl group bonded through an ether linkage; that is, an “alkoxy” group can be defined as —OA¹ where A¹ is alkyl or cycloalkyl as defined above. “Alkoxy” also includes polymers of alkoxy groups as just described; that is, an alkoxy can be a polyether such as —OA¹-OA² or —OA¹-(OA²)ₐ-OA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “aldehyde” as used herein is represented by the formula —C(O)H. Throughout this specification “C(O)” is a short hand notation for a carbonyl group, i.e., C═O.

The terms “amine” or “amino” as used herein are represented by the formula —NA¹A², where A¹ and A² can be, independently, hydrogen or alkyl, cycloalkyl, alkenyl, cycloalkenyl, alkynyl, cycloalkynyl, aryl, or heteroaryl group as described herein.

The term “alkylamino” as used herein is represented by the formula —NH(-alkyl) where alkyl is a described herein. Representative examples include, but are not limited to, methylamino group, ethylamino group, propylamino group, isopropylamino group, butylamino group, isobutylamino group, (sec-butyl)amino group, (tert-butyl)amino group, pentylamino group, isopentylamino group, (tert-pentyl)amino group, hexylamino group, and the like.

The term “dialkylamino” as used herein is represented by the formula —N(-alkyl)₂ where alkyl is a described herein. Representative examples include, but are not limited to, dimethylamino group, diethylamino group, dipropylamino group, diisopropylamino group, dibutylamino group, diisobutylamino group, di(sec-butyl)amino group, di(tert-butyl)amino group, dipentylamino group, diisopentylamino group, di(tert-pentyl)amino group, dihexylamino group, N-ethyl-N-methylamino group, N-methyl-N-propylamino group, N-ethyl-N-propylamino group and the like.

The term “carboxylic acid” as used herein is represented by the formula —C(O)OH.

The term “ester” as used herein is represented by the formula —OC(O)A¹ or —C(O)OA¹, where A¹ can be alkyl, cycloalkyl, alkenyl, cycloalkenyl, alkynyl, cycloalkynyl, aryl, or heteroaryl group as described herein. The term “polyester” as used herein is represented by the formula -(A¹O(O)C-A²-C(O)O)ₐ— or -(A¹O(O)C-A²-OC(O))ₐ—, where A¹ and A² can be, independently, an alkyl, cycloalkyl, alkenyl, cycloalkenyl, alkynyl, cycloalkynyl, aryl, or heteroaryl group described herein and “a” is an integer from 1 to 500. “Polyester” is as the term used to describe a group that is produced by the reaction between a compound having at least two carboxylic acid groups with a compound having at least two hydroxyl groups.

The term “ether” as used herein is represented by the formula A¹OA², where A¹ and A² can be, independently, an alkyl, cycloalkyl, alkenyl, cycloalkenyl, alkynyl, cycloalkynyl, aryl, or heteroaryl group described herein. The term “polyether” as used herein is represented by the formula -(A¹O-A²O)ₙ—, where A¹ and A² can be, independently, an alkyl, cycloalkyl, alkenyl, cycloalkenyl, alkynyl, cycloalkynyl, aryl, or heteroaryl group described herein and “a” is an integer of from 1 to 500. Examples of polyether groups include polyethylene oxide, polypropylene oxide, and polybutylene oxide.

The term “halide” or “halo” as used herein refers to the halogens fluorine, chlorine, bromine, and iodine.

The term “heterocyclyl,” as used herein refers to single and multi-cyclic non-aromatic ring systems and “heteroaryl as used herein refers to single and multi-cyclic aromatic ring systems: in which at least one of the ring members is other than carbon. The terms includes azetidine, dioxane, furan, imidazole, isothiazole, isoxazole, morpholine, oxazole, oxazole, including, 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine, including 1,2,4,5-tetrazine, tetrazole, including 1,2,3,4-tetrazole and 1,2,4,5-tetrazole, thiadiazole, including, 1,2,3-thiadiazole, 1,2,5-thiadiazole, and 1,3,4-thiadiazole, thiazole, thiophene, triazine, including 1,3,5-triazine and 1,2,4-triazine, triazole, including, 1,2,3-triazole, 1,3,4-triazole, and the like.

The term “hydroxyl” as used herein is represented by the formula —OH.

The term “ketone” as used herein is represented by the formula A¹C(O)A², where A¹ and A² can be, independently, an alkyl, cycloalkyl, alkenyl, cycloalkenyl, alkynyl, cycloalkynyl, aryl, or heteroaryl group as described herein.

The term “azide” as used herein is represented by the formula —N₃.

The term “nitro” as used herein is represented by the formula —NO₂.

The term “cyanide” as used herein is represented by the formula —CN.

The term “silyl” as used herein is represented by the formula —SiA¹A²A³, where A¹, A², and A³ can be, independently, hydrogen or an alkyl, cycloalkyl, alkoxy, alkenyl, cycloalkenyl, alkynyl, cycloalkynyl, aryl, or heteroaryl group as described herein.

The term “sulfo-oxo” as used herein is represented by the formulas —S(O)A¹, —S(O)₂A¹, —OS(O)₂A¹, or —OS(O)₂OA¹, where A¹ can be hydrogen or an alkyl, cycloalkyl, alkenyl, cycloalkenyl, alkynyl, cycloalkynyl, aryl, or heteroaryl group as described herein. Throughout this specification “S(O)” is a short hand notation for S═O. The term “sulfonyl” is used herein to refer to the sulfo-oxo group represented by the formula —S(O)₂A¹, where A¹ can be hydrogen or an alkyl, cycloalkyl, alkenyl, cycloalkenyl, alkynyl, cycloalkynyl, aryl, or heteroaryl group as described herein. The term “sulfone” as used herein is represented by the formula A¹S(O)₂A², where A¹ and A² can be, independently, an alkyl, cycloalkyl, alkenyl, cycloalkenyl, alkynyl, cycloalkynyl, aryl, or heteroaryl group as described herein. The term “sulfoxide” as used herein is represented by the formula A¹S(O)A², where A¹ and A² can be, independently, an alkyl, cycloalkyl, alkenyl, cycloalkenyl, alkynyl, cycloalkynyl, aryl, or heteroaryl group as described herein.

The term “thiol” as used herein is represented by the formula —SH.

“R,” “R¹,” “R²,” “R³,” “Rⁿ,” where n is an integer, as used herein can, independently, possess one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

Compounds described herein may contain “optionally substituted” moieties. In general, the term “substituted,” whether preceded by the term “optionally” or not, means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this disclosure are preferably those that result in the formation of stable or chemically feasible compounds. In is also contemplated that, in certain aspects, unless expressly indicated to the contrary, individual substituents can be further optionally substituted (i.e., further substituted or unsubstituted).

In some aspects, a structure of a compound can be represented by a formula:

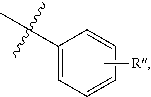

which is understood to be equivalent to a formula:

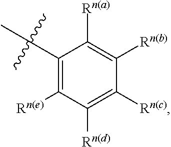

wherein n is typically an integer. That is, Rⁿ is understood to represent five independent substituents, R^{n(a)}, R^{n(b)}, R^{n(c)}, R^{n(d)}, R^{n(e)}. By “independent substituents,” it is meant that each R substituent can be independently defined. For example, if in one instance R^{n(a)} is halogen, then R^{n(b)} is not necessarily halogen in that instance. In a case where there is a single Rⁿ (e.g., only R^{n(a)}), Rⁿ is referred to as a “single substituent.” In a case where there are two or more Rⁿ (e.g., at least R^{n(a)} and R^{n(b)}) Rⁿ is referred to as a “multiple substituents.”

Several references to R, R¹, R², R³, R⁴, R⁵, R⁶, etc. are made in chemical structures and moieties disclosed and described herein. Any description of R, R¹, R², R³, R⁴, R⁵, R⁶, etc. in the specification is applicable to any structure or moiety reciting R, R¹, R², R³, R⁴, R⁵, R⁶, etc. respectively.

The compounds disclosed herein are suited for use in a wide variety of devices, including, for example, organic light emitting diodes (OLEDs) for full color displays and lighting applications.

Also disclosed herein are compositions including one or more compounds disclosed herein. The present disclosure provides light emitting device that include one or more compositions described herein. The present disclosure also provides a photovoltaic device comprising one or more complexes or compositions described herein. Further, the present disclosure also provides a luminescent display device comprising one or more compounds described herein.

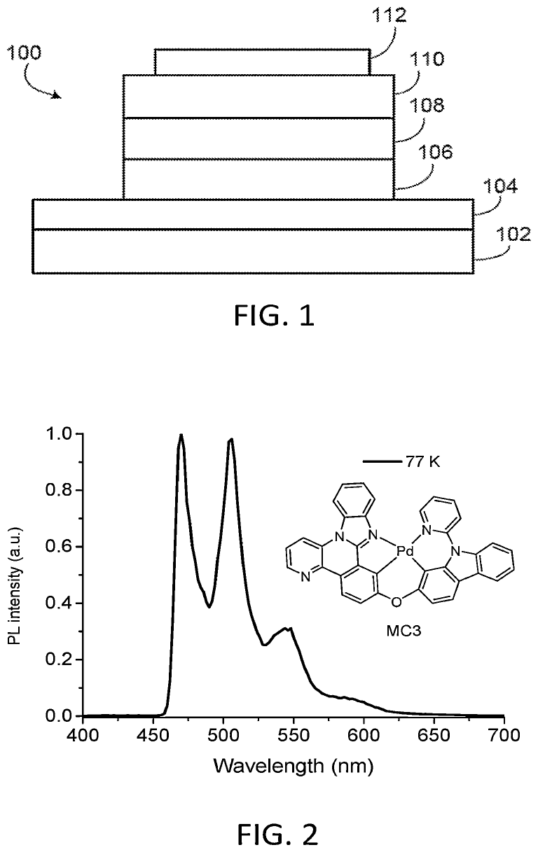

Compounds described herein can be used in a light emitting device such as an OLED. FIG. 1 depicts a cross-sectional view of an OLED 100. OLED 100 includes substrate 102, anode 104, hole-transporting material(s) (HTL) 106, light processing material 108, electron-transporting material(s) (ETL) 110, and a metal cathode layer 112. Anode 104 is typically a transparent material, such as indium tin oxide. Light processing material 108 may be an emissive material (EML) including an emitter and a host.

In various aspects, any of the one or more layers depicted in FIG. 1 may include indium tin oxide (ITO), poly(3,4-ethylenedioxythiophene) (PEDOT), polystyrene sulfonate (PSS), N,N′-di-1-naphthyl-N,N-diphenyl-1,1′-biphenyl-4,4′diamine (NPD), 1,1-bis((di-4-tolylamino)phenyl)cyclohexane (TAPC), 2,6-Bis(N-carbazolyl)pyridine (mCpy), 2,8-bis(diphenylphosphoryl)dibenzothiophene (PO15), LiF, Al, or a combination thereof.

Light processing material 108 may include one or more compounds of the present disclosure optionally together with a host material. The host material can be any suitable host material known in the art. The emission color of an OLED is determined by the emission energy (optical energy gap) of the light processing material 108, which can be tuned by tuning the electronic structure of the emitting compounds, the host material, or both. Both the hole-transporting material in the HTL layer 106 and the electron-transporting material(s) in the ETL layer 110 may include any suitable hole-transporter known in the art.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary and are not intended to be limiting in scope. Some of these synthetic examples have been performed. Others are based on an understanding of related synthetic procedures and are predictive in nature. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

Various methods for the preparation method of the compounds described herein are recited in the examples. These methods are provided to illustrate various methods of preparation, but are not intended to limit any of the methods recited herein. Accordingly, one of skill in the art in possession of this disclosure could readily modify a recited method or utilize a different method to prepare one or more of the compounds described herein. The following aspects are only exemplary and are not intended to be limiting in scope. Temperatures, catalysts, concentrations, reactant compositions, and other process conditions can vary, and one of skill in the art, in possession of this disclosure, could readily select appropriate reactants and conditions for a desired complex.

### EXAMPLES OF GENERAL FORMULAS I-XIII

### Example 1

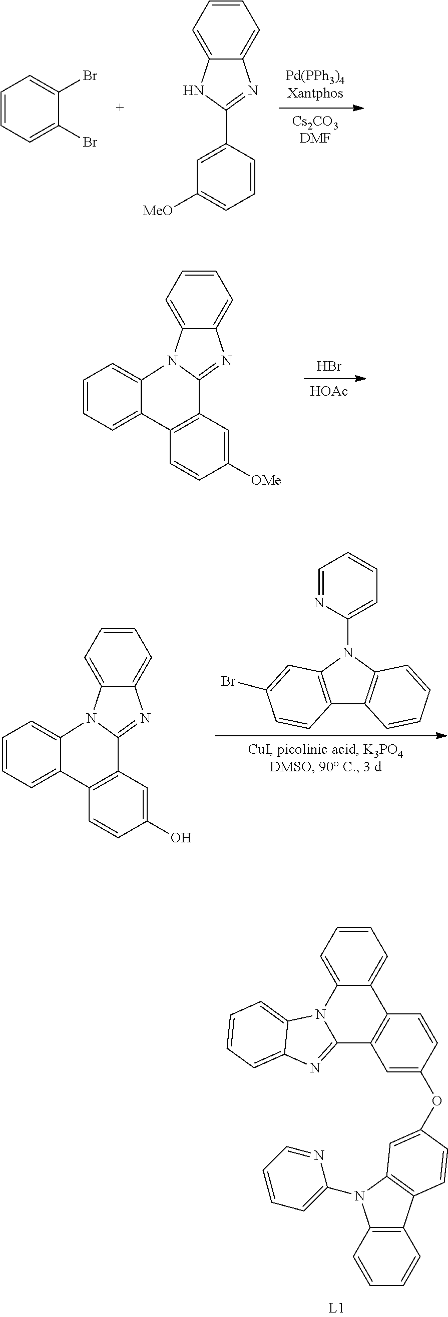

Benzo[4,5]imidazo[1,2-f]phenanthridin-7-ol (284.3 mg, 1 mmol, 1.0 eq), 2-bromo-9-(pyridin-2-yl)-9H-carbazole (388 mg, 1.2 mmol, 1.2 eq), CuI (38 mg, 0.2 mmol, 0.2 eq), picolinic acid (49 mg, 0.4 mmol, 0.4 eq) and K₃PO4 (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L1 in 30%˜70% yield.

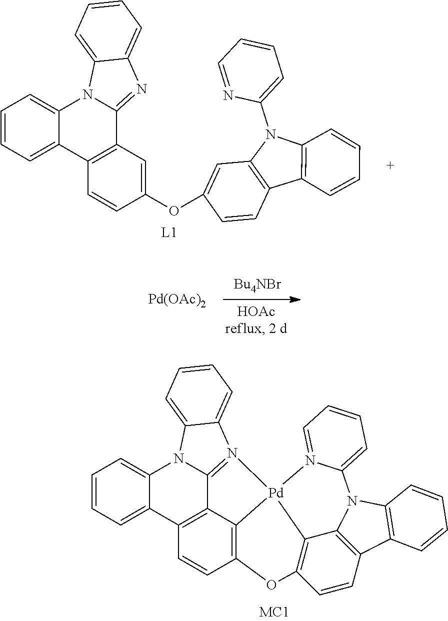

L1 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube, which was taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain to obtain the desired product MC1 in 10%˜50% yield.

### Example 2

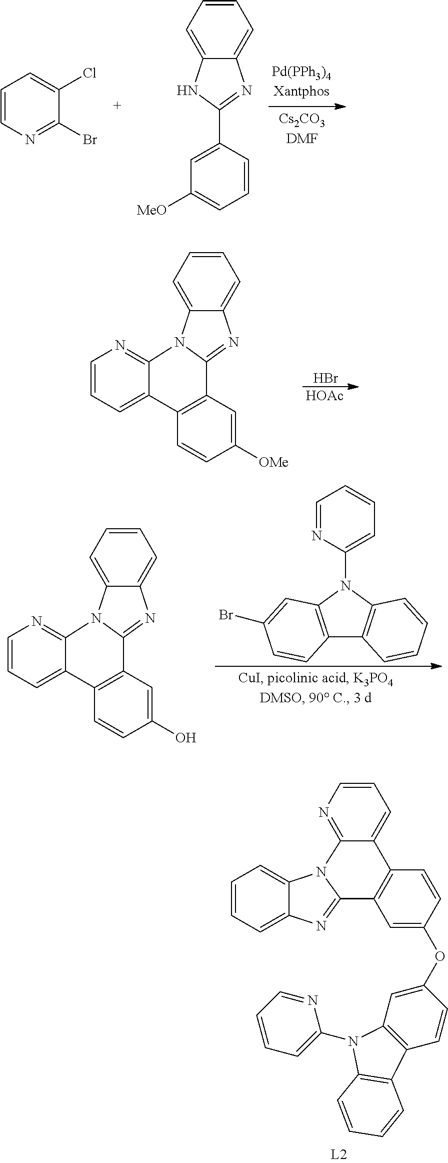

Benzo[c]benzo[4,5]imidazo[1,2-a][1,8]naphthyridin-7-ol (285 mg, 1 mmol, 1.0 eq), 2-bromo-9-(pyridin-2-yl)-9H-carbazole (388 mg, 1.2 mmol, 1.2 eq). CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L2 in 30%˜70% yield.

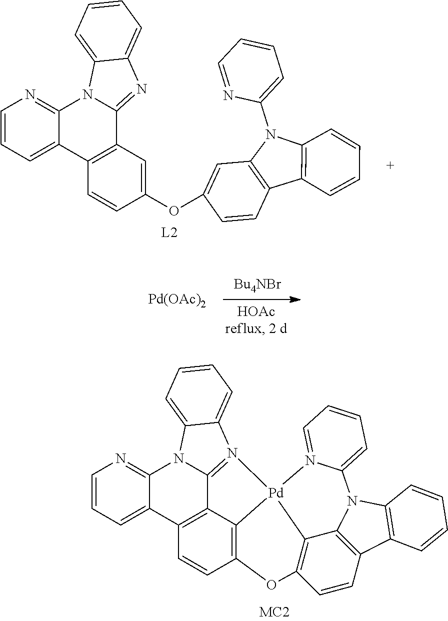

L2 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube, which was taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain to obtain the desired product MC2 in 10%˜50% yield.

### Example 3

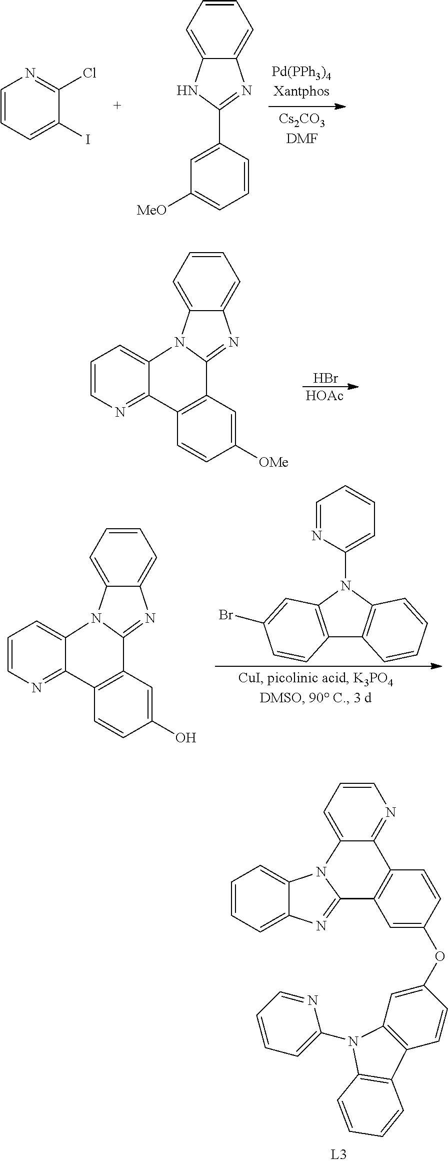

Benzo[c]benzo[4,5]imidazo[1,2-a][1,5]naphthyridin-7-ol (100 mg, 0.35 mmol, 1.0 eq), 2-bromo-9-(pyridin-2-yl)-9H-carbazole (136 mg, 0.42 mmol, 1.2 eq), CuI (13 mg, 0.07 mmol, 0.2 eq), picolinic acid (9 mg, 0.07 mmol, 0.2 eq) and K₃PO₄ (149 mg, 0.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L3 as an orange yellow solid 105 mg in 57% yield.

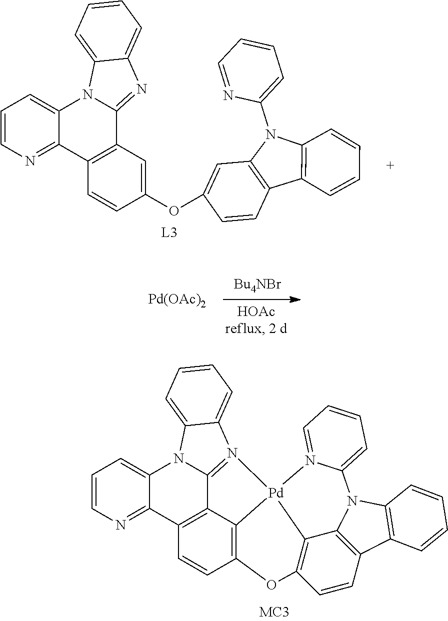

L3 (95 mg, 0.18 mmol, 1.0 eq), Pd(OAc)₂ (43 mg, 0.19 mmol, 1.1 eq) and n-Bu₄NBr (6 mg, 0.018 mmol, 0.1 eq) were added to a dry pressure tube, which was taken into a glove box and acetic acid (11 mL) was added. The mixture was bubbled with nitrogen for 30 minutes and then the tube was scaled. Then the mixture was heated to reflux in an oil bath and stirred for 2 days, cooled to ambient temperature and the solvent removed. Then the solid was purified through column chromatography on silica gel using dichloromethane as eluent to obtain the desired product MC3 as a white solid 100 mg in 86% yield. FIG. 2 shows an emission spectrum of MC3 in tetrahydro-2-methylfuran at 77K.

### Example 4

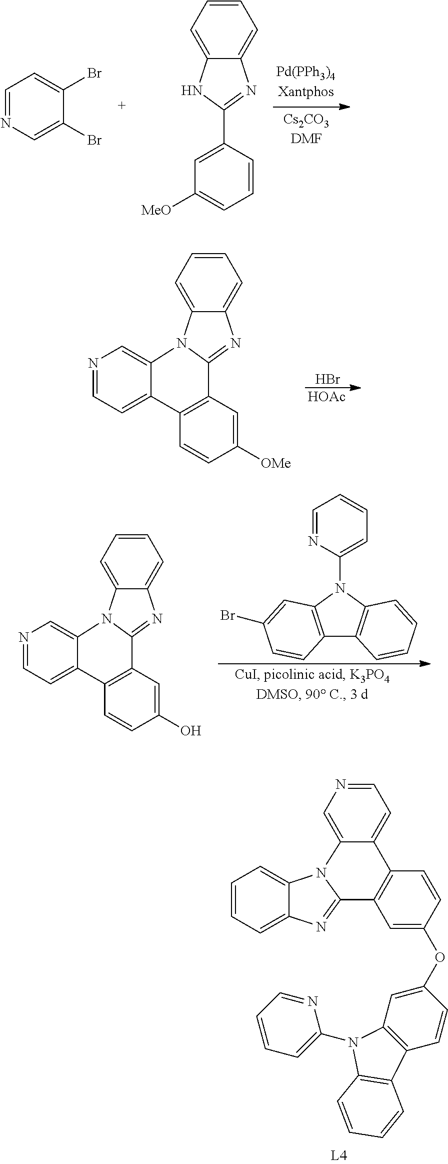

Benzo[c]benzo[4,5]imidazo[1,2-a][1,7]naphthyridin-7-ol (100 mg, 0.35 mmol, 1.0 eq), 2-bromo-9-(pyridin-2-yl)-9H-carbazole (136 mg, 0.42 mmol, 1.2 eq), CuI (13 mg, 0.07 mmol, 0.2 eq), picolinic acid (9 mg, 0.07 mmol, 0.2 eq) and K₃PO4 (149 mg, 0.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L4 in 40%˜70% yield.

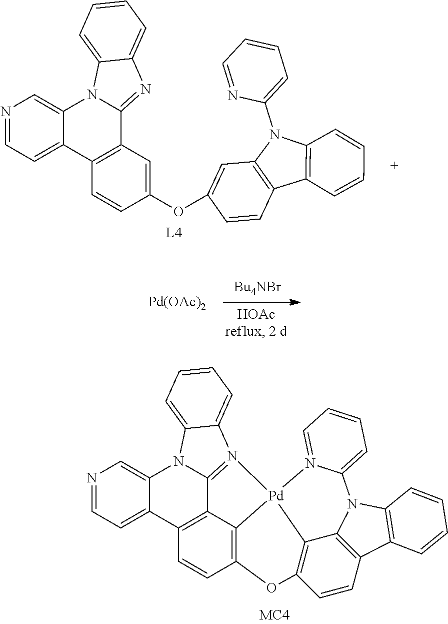

L4 (95 mg, 0.18 mmol, 1.0 eq), Pd(OAc)₂ (43 mg, 0.19 mmol, 1.1 eq) and n-Bu₄NBr (6 mg, 0.018 mmol, 0.1 eq) were added to a dry pressure tube, which was taken into a glove box and acetic acid (11 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC4 in 10%˜50% yield.

### Example 5

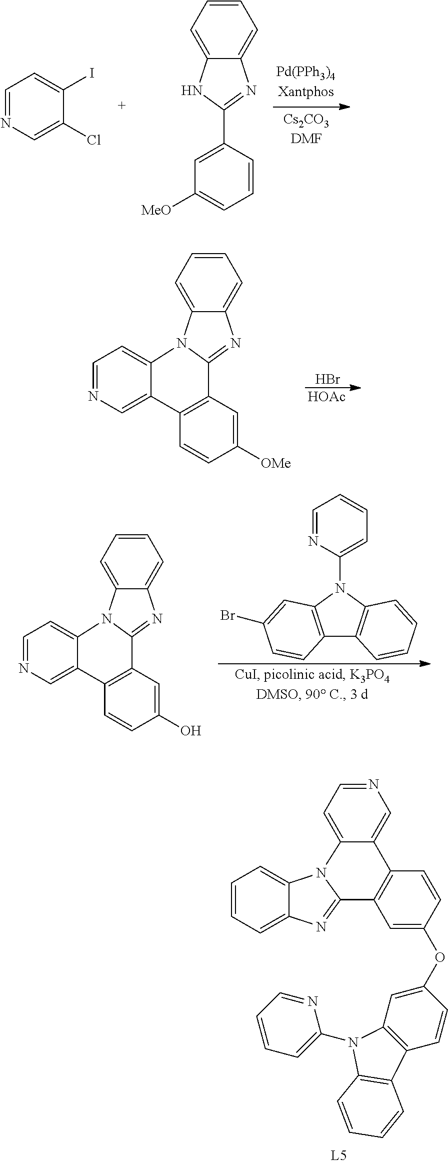

Benzo[c]benzo[4,5]imidazo[1,2-a][1,6]naphthyridin-7-ol (100 mg, 0.35 mmol, 1.0 eq), 2-bromo-9-(pyridin-2-yl)-9H-carbazole (136 mg, 0.42 mmol, 1.2 eq), CuI (13 mg, 0.07 mmol, 0.2 eq), picolinic acid (9 mg, 0.07 mmol, 0.2 eq) and K₃PO₄ (149 mg, 0.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane % ethyl acetate as eluent to obtain the desired product ligand L5 in 40%˜70% yield.

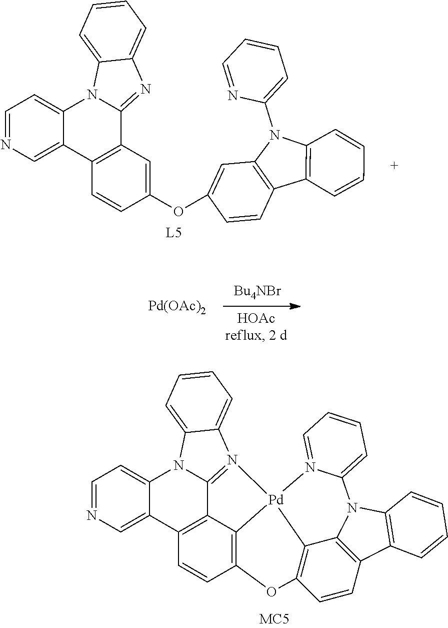

L5 (95 mg, 0.18 mmol, 1.0 eq), Pd(OAc)₂ (43 mg, 0.19 mmol, 1.1 eq) and n-Bu₄NBr (6 mg, 0.018 mmol, 0.1 eq) were added to a dry pressure tube, which was taken into a glove box and acetic acid (11 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC5 in 10%˜50% yield.

### Example 6

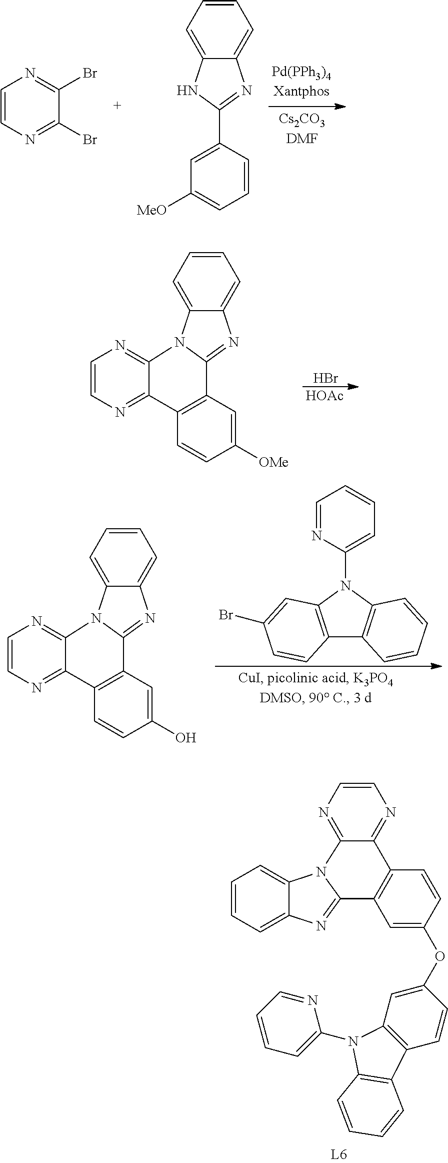

Benzo[4,5]imidazo[2,1-a]pyrazino[2,3-c]isoquinolin-7-ol (286 mg, 1 mmol, 1.0 eq), 2-bromo-9-(pyridin-2-yl)-9H-carbazole (388 mg, 1.2 mmol, 1.2 eq), CuI (38 mg, 0.2 mmol, 0.2 eq), picolinic acid (49 mg, 0.4 mmol, 0.4 eq) and K₃PO4 (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L6 in 30%˜70% yield.

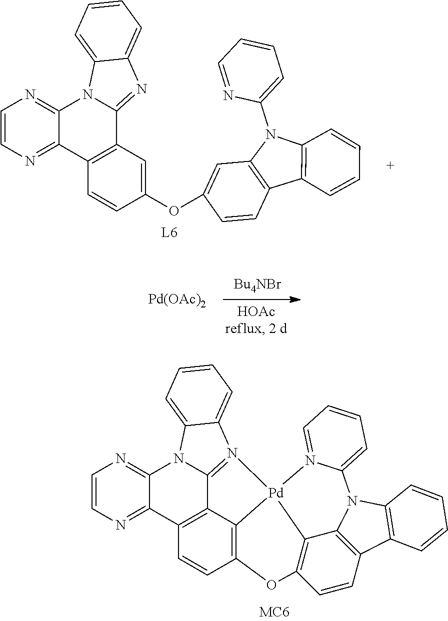

L6 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube, which was taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain to obtain the desired product MC6 in 10%˜50% yield.

### Example 7

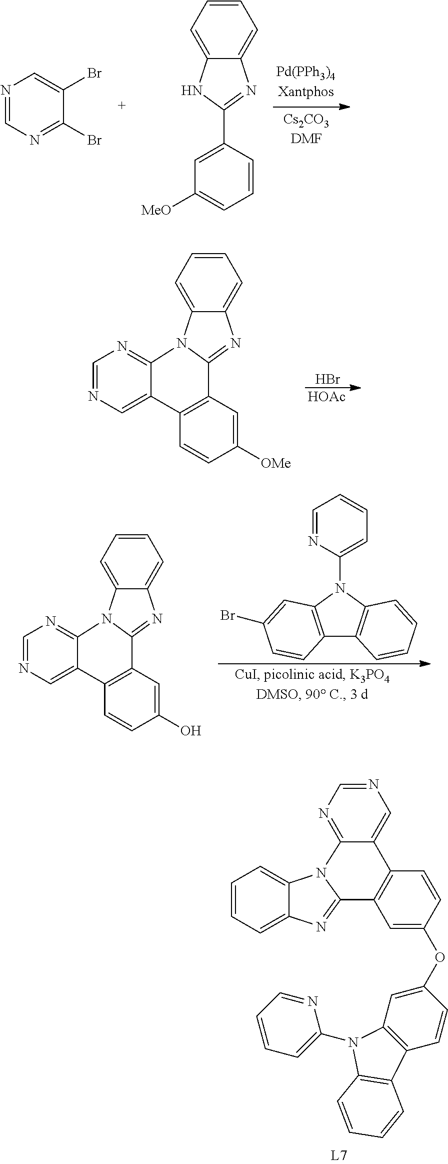

Benzo[4,5]imidazo[2,1-a]pyrimido[4,5-c]isoquinolin-7-ol (286 mg, 1 mmol, 1.0 eq), 2-bromo-9-(pyridin-2-yl)-9H-carbazole (388 mg, 1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L7 in 30%˜70% yield.

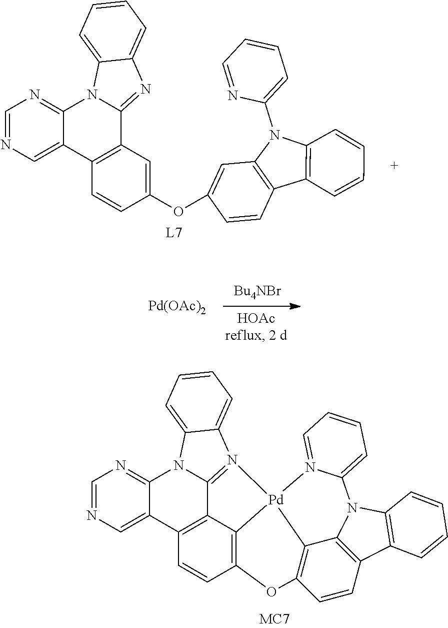

L7 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube, which was taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain to obtain the desired product MC7 in 10%˜50% yield.

### Example 8

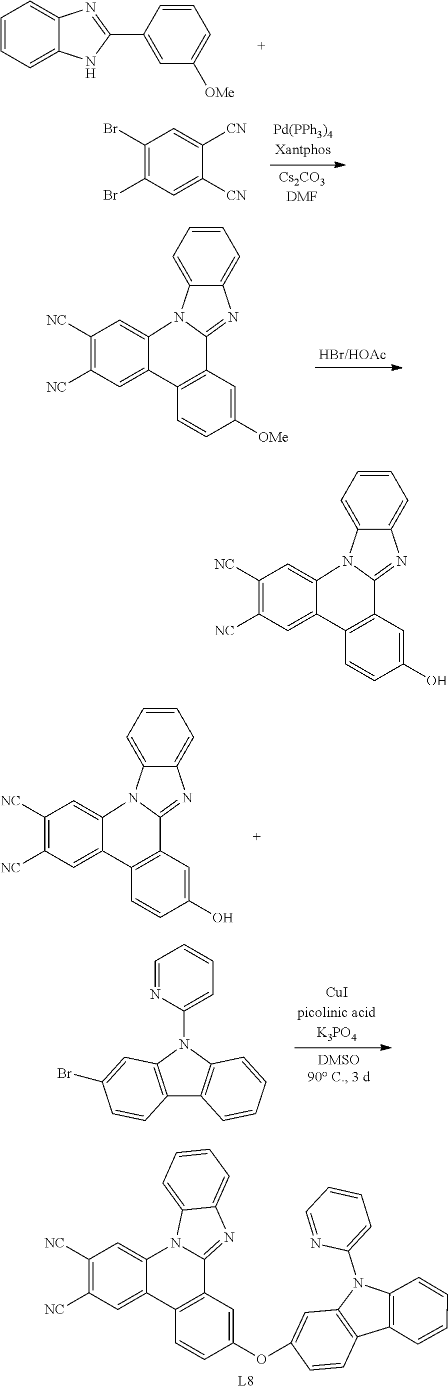

7-hydroxybenzo[4,5]imidazo[1,2-f]phenanthridine-2,3-dicarbonitrile (334 mg, 1 mmol, 1.0 eq), 2-bromo-9-(pyridin-2-yl)-9H-carbazole (388 mg, 1.2 mmol, 1.2 eq), CuI (38 mg, 0.2 mmol, 0.2 eq), picolinic acid (49 mg, 0.4 mmol, 0.4 eq) and K₃PO4 (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L8 in 30%˜70% yield.

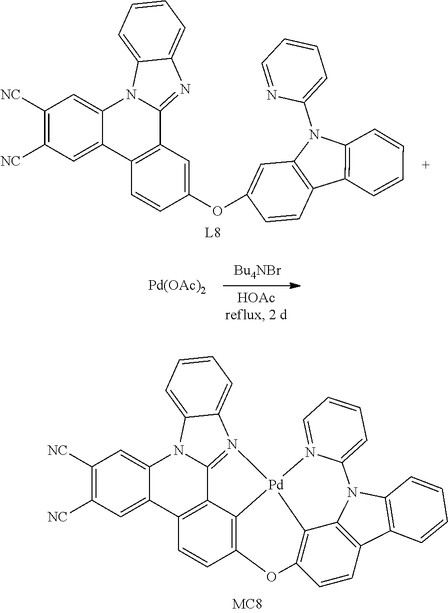

L8 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube, which was taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain to obtain the desired product MC8 in 10%˜50% yield.

### Example 9

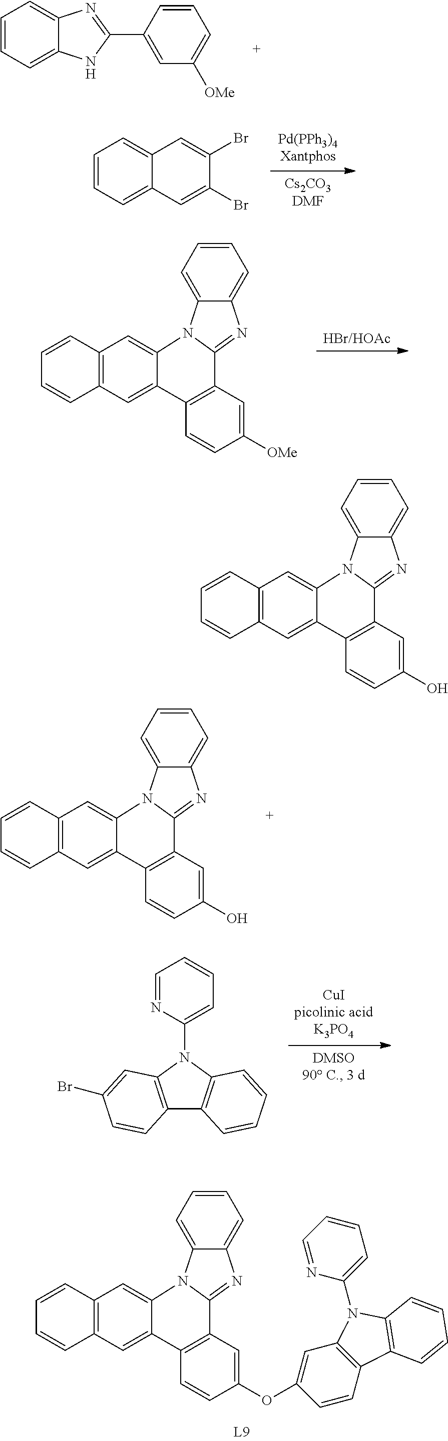

Benzo[b]benzo[4,5]imidazo[1,2-f]phenanthridin-7-ol (217 mg, 0.65 mmol, 1.0 eq), 2-bromo-9-(pyridin-2-yl)-9H-carbazole (252 mg, 0.78 mmol, 1.2 eq), CuI (25 mg, 0.13 mmol, 0.2 eq), picolinic acid (16 mg, 0.13 mmol, 0.2 eq) and K₃PO4 (275 mg, 1.3 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L9 as a white solid 100 mg in 27% yield.

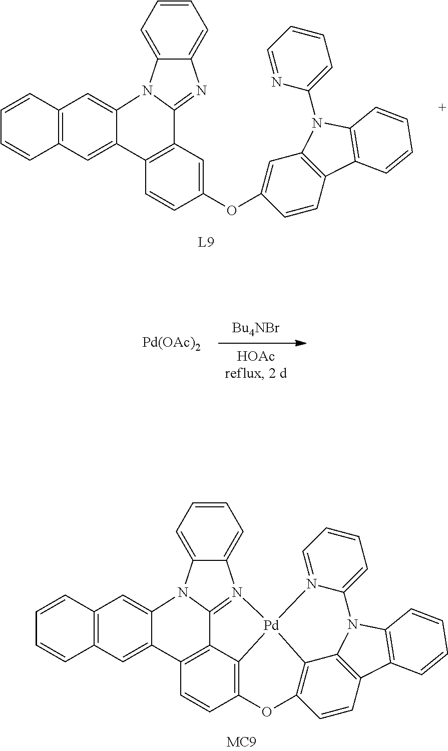

7-((9-(pyridin-2-yl)-9H-carbazol-2-yl)oxy)benzo[b]benzo[4,5]imidazo[1,2-f]phenanthridine (80 mg, 0.14 mmol, 1.0 eq), Pd(OAc)₂ (37 mg, 0.17 mmol, 1.2 eq) and n-Bu₄NBr (5 mg, 0.014 mmol, 0.1 eq) were added to a dry pressure tube, which was taken into a glove box and acetic acid (9 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC9 as a white solid 60 mg in 63% yield.

### Example 10

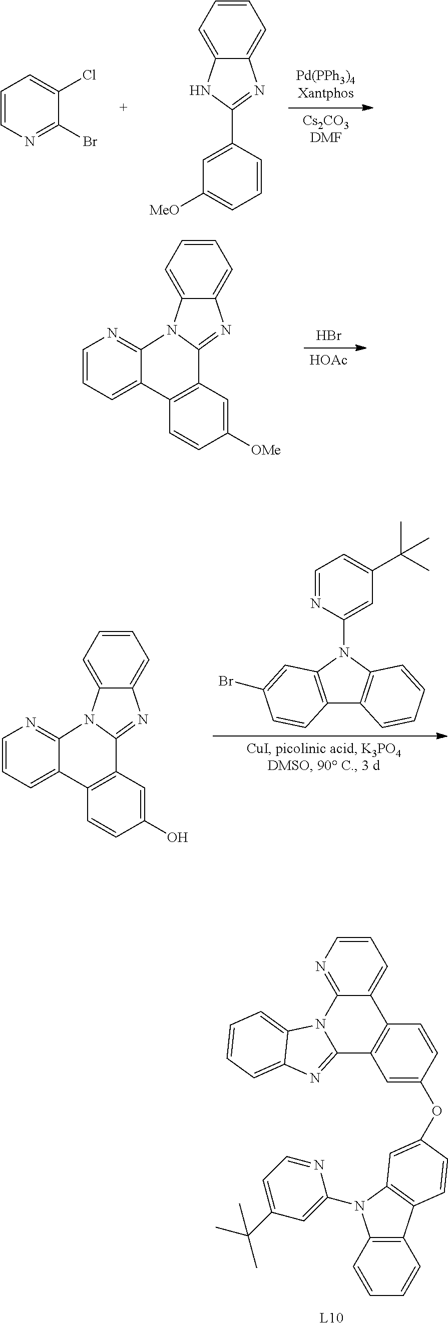

Benzo[c]benzo[4,5]imidazo[1,2-a][1,8]naphthyridin-7-ol (145 mg, 0.51 mmol, 1.0 eq), 2-bromo-9-(4-(tert-butyl)pyridin-2-yl)-9H-carbazole (231 mg, 0.61 mmol, 1.2 eq), CuI (20 mg, 0.10 mmol, 0.2 eq), picolinic acid (13 mg, 0.10 mmol, 0.2 eq) and K₃PO₄ (217 mg, 1.02 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L10 as an orange yellow solid 185 mg in 63% yield.

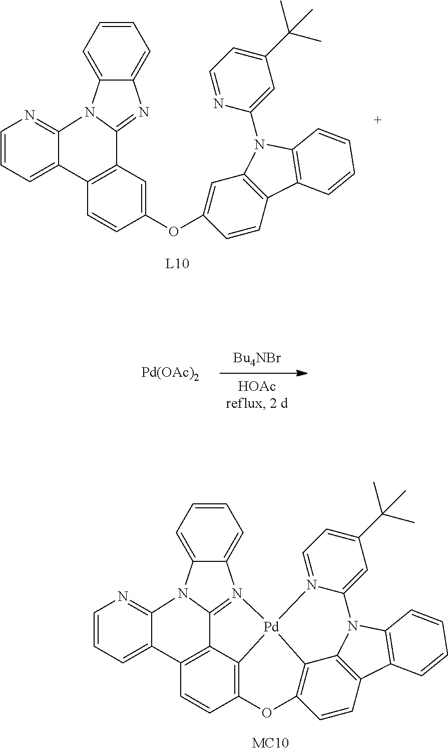

L10 (175 mg, 0.3 mmol, 1.0 eq), Pd(OAc)₂ (74 mg, 0.33 mmol, 1.1 eq) and n-Bu₄NBr (10 mg, 0.03 mmol, 0.1 eq) were added to a dry pressure tube, which was taken into a glove box and acetic acid (19 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC10 in 10%˜50% yield.

### Example 11

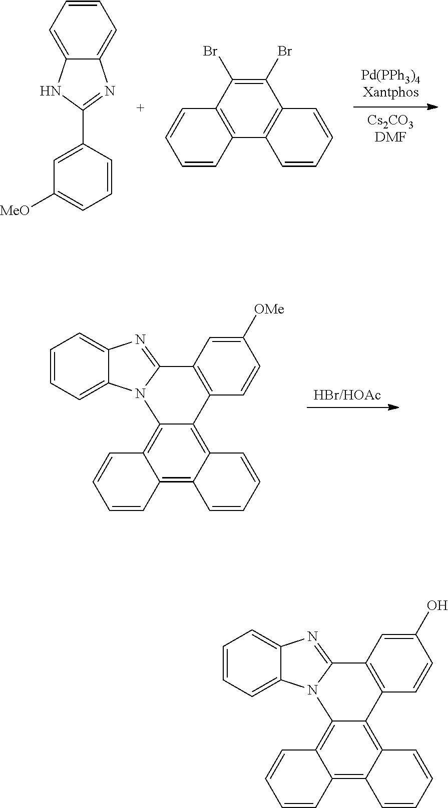

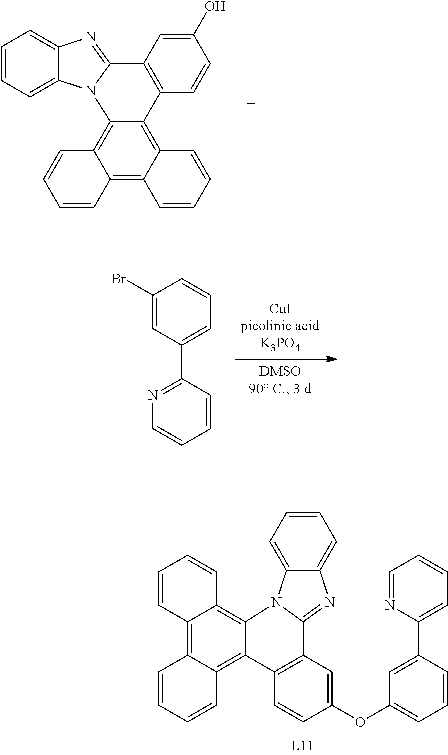 [SMILES: Oc1ccc2c(c1)c1nc3ccccc3n1c1c3ccccc3c3ccccc3c21 ; Brc1cccc(-c2ccccn2)c1 ; "CuIpicolinic acidK3PO4" ; "DMSO90° C., 3 d" ; c1ccc(-c2cccc(Oc3ccc4c(c3)c3nc5ccccc5n3c3c5ccccc5c5ccccc5c43)c2)nc1]

Dibenzo[a,c]benzo[4,5]imidazo[1,2-f]phenanthridin-7-ol (384.4 mg, 1 mmol, 1.0 eq), 2-(3-bromophenyl)pyridine (281 mg, 1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L11 as a white solid 350 mg in 65% yield.

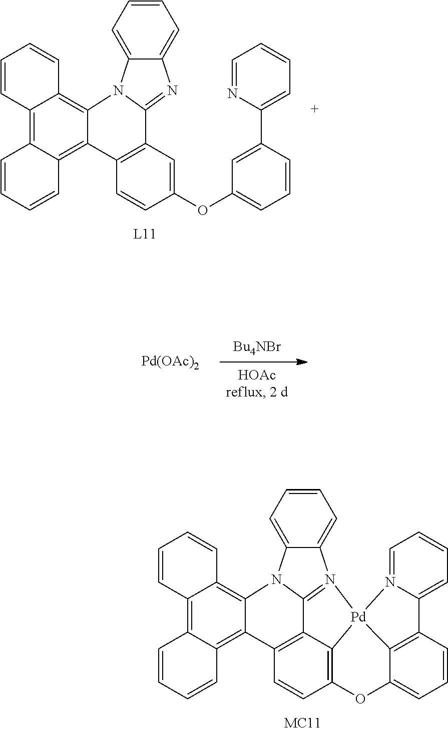

L11 (107.6 mg, 0.20 mmol, 1.0 eq), Pd(OAc)₂ (34 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC11 as a white solid 58 mg in 45% yield.

### Example 12

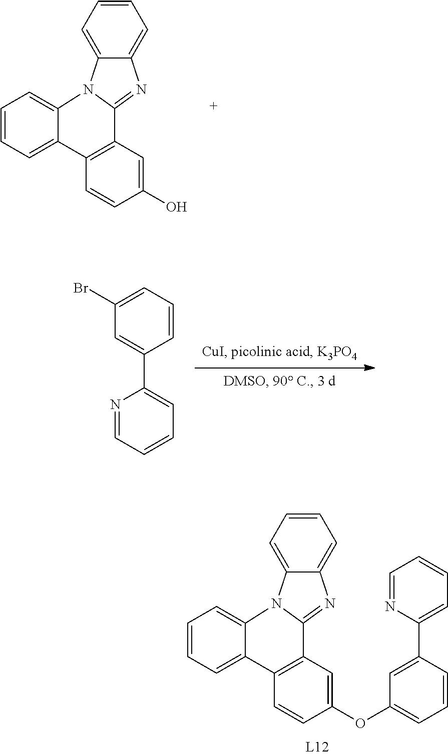 [SMILES: Oc1ccc2c3ccccc3n3c4ccccc4nc3c2c1 ; Brc1cccc(-c2ccccn2)c1 ; "CuI, picolinic acid, K3PO4" ; "DMSO, 90° C., 3 d" ; c1ccc(-c2cccc(Oc3ccc4c5ccccc5n5c6ccccc6nc5c4c3)c2)nc1]

Benzo[4,5]imidazo[1,2-f]phenanthridin-7-ol (284.3 mg, 1 mmol, 1.0 eq), 2-(3-bromophenyl)pyridine (281 mg, 1.2 mmol, 1.2 eq), CuI (38 mg, 0.2 mmol, 0.2 eq), picolinic acid (49 mg, 0.4 mmol, 0.4 eq) and K₃PO4 (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L12 as a white solid 306 mg in 70% yield.

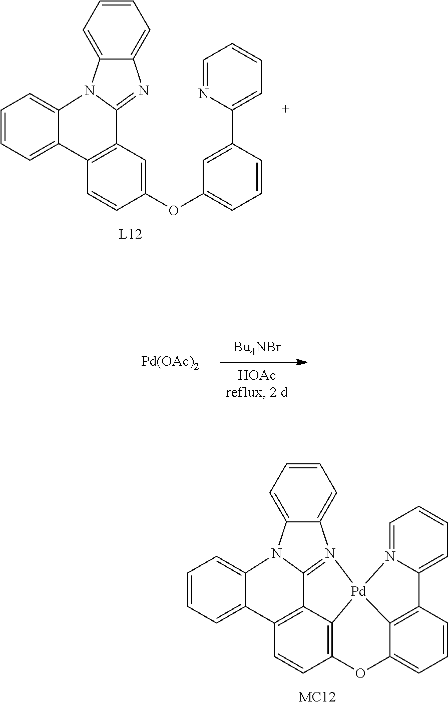

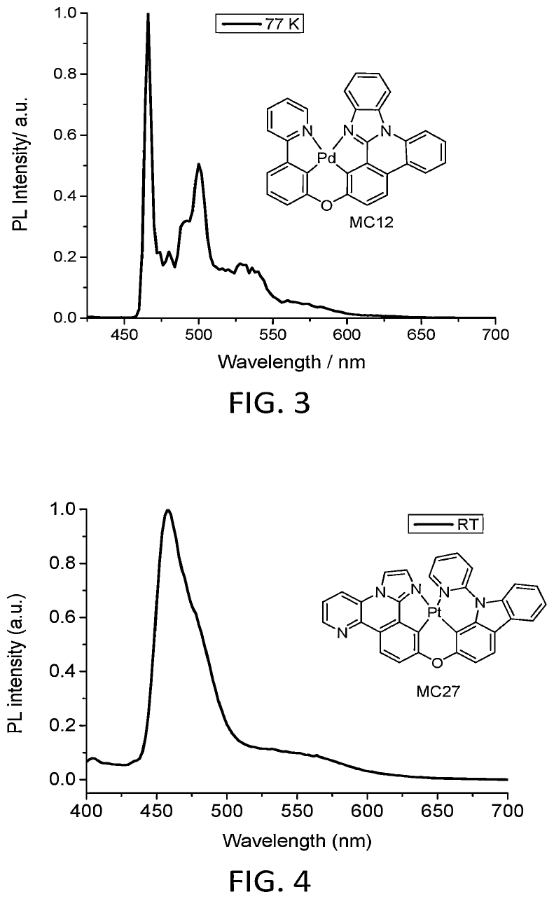

LC12 (87.4 mg, 0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube, which was taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain to obtain the desired product MC12 as a white solid 43 mg in 40% yield. FIG. 3 shows an emission spectrum of MC12 in tetrahydro-2-methylfuran at 77K.

### Example 13

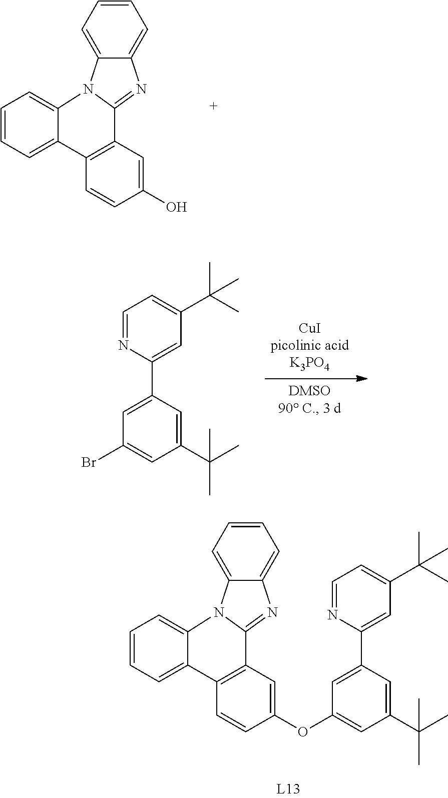

Benzo[4,5]imidazo[1,2-f]phenanthridin-7-ol (355 mg, 1.03 mmol, 1.0 eq), 2-(3-bromo-5-(tert-butyl)phenyl)-4-(tert-butyl)pyridine (350 mg, 1.23 mmol, 1.2 eq), CuI (40 mg, 0.21 mmol, 0.2 eq), picolinic acid (25 mg, 0.21 mmol, 0.2 eq) and K₃PO4 (437 mg, 2.06 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L13 as an orange yellow solid 310 mg in 55% yield.

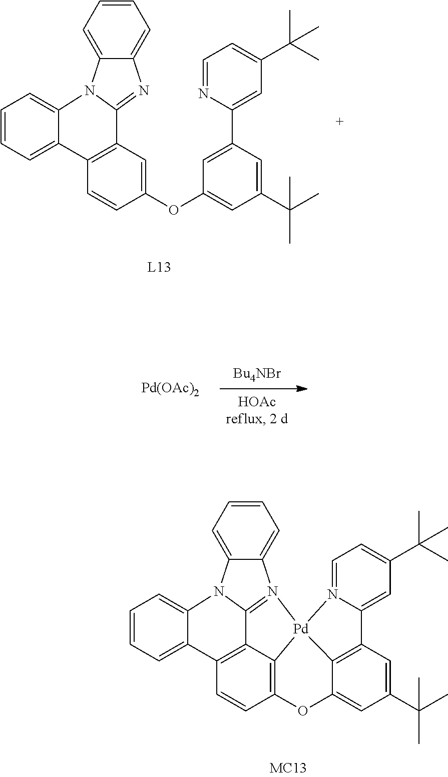

L13 (66 mg, 0.12 mmol, 1.0 eq), Pd(OAc)₂ (32 mg, 0.14 mmol, 1.2 eq) and n-Bu₄NBr (4 mg, 0.012 mmol, 0.1 eq) were added to a dry pressure tube, which was taken into a glove box and acetic acid (8 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC13 in 10%˜50% yield.

### Example 14

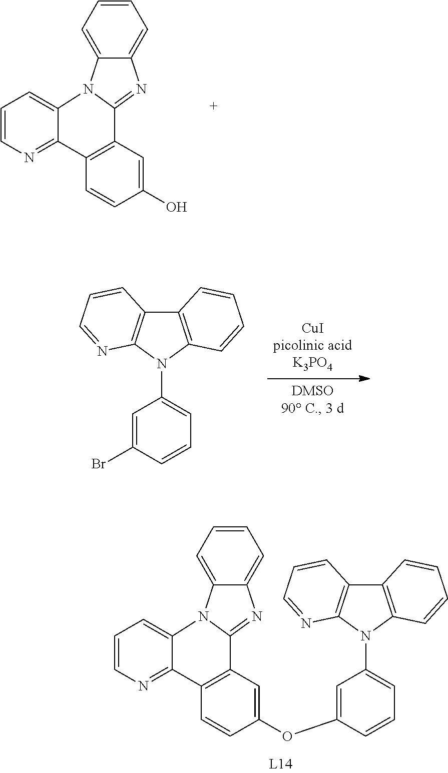 [SMILES: Oc1ccc2c(c1)c1nc3ccccc3n1c1cccnc21 ; Brc1cccc(-n2c3ccccc3c3cccnc32)c1 ; "CuIpicolinic acidK3PO4" ; "DMSO90° C., 3 d" ; c1cc(Oc2ccc3c(c2)c2nc4ccccc4n2c2cccnc32)cc(-n2c3ccccc3c3cccnc32)c1]

Benzo[c]benzo[4,5]imidazo[1,2-a][1,5]naphthyridin-7-ol (100 mg, 0.35 mmol, 1.0 eq), 9-(3-bromophenyl)-9H-pyrido[2,3-b]indole (136 mg, 0.42 mmol, 1.2 eq), CuI (13 mg, 0.07 mmol, 0.2 eq), picolinic acid (9 mg, 0.07 mmol, 0.2 eq) and K₃PO₄ (149 mg, 0.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L14 in 30%˜70% yield.

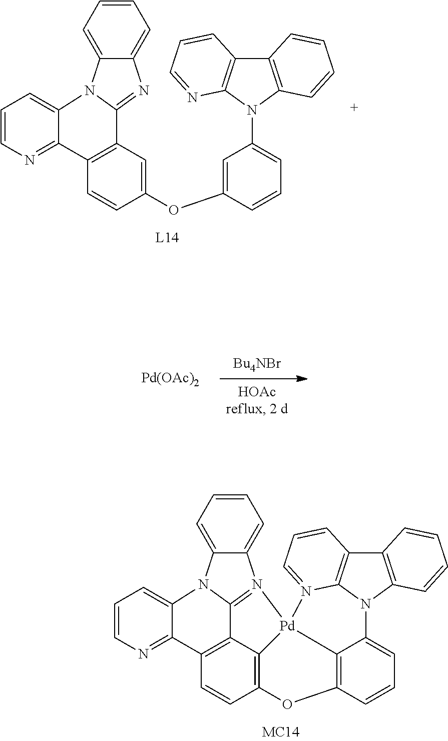

L14 (95 mg, 0.18 mmol, 1.0 eq), Pd(OAc)₂ (43 mg, 0.19 mmol, 1.1 eq) and n-Bu₄NBr (6 mg, 0.018 mmol, 0.1 eq) were added to a dry pressure tube, which was taken into a glove box and acetic acid (11 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC14 in 10%-50% yield.

### Example 15

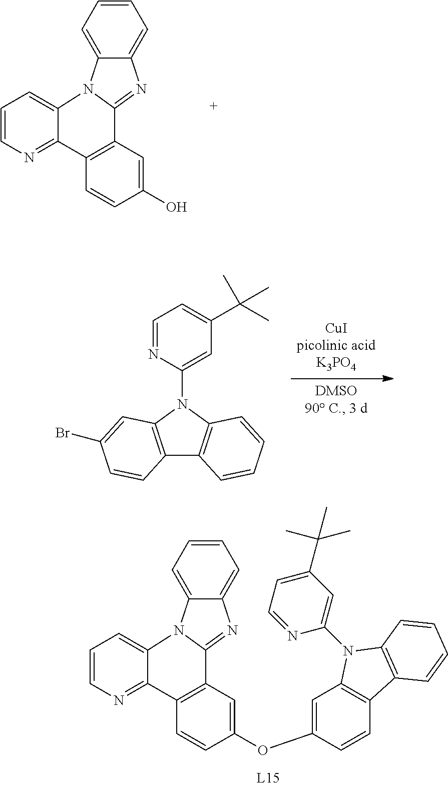 [SMILES: Oc1ccc2c(c1)c1nc3ccccc3n1c1cccnc21 ; CC(C)(C)c1ccnc(-n2c3ccccc3c3ccc(Br)cc32)c1 ; "CuIpicolinic acidK3PO4" ; "DMSO90° C., 3 d" ; CC(C)(C)c1ccnc(-n2c3ccccc3c3ccc(Oc4ccc5c(c4)c4nc6ccccc6n4c4cccnc54)cc32)c1]

Benzo[c]benzo[4,5]imidazo[1,2-a][1,5]naphthyridin-7-ol (100 mg, 0.35 mmol, 1.0 eq), 2-bromo-9-(4-(tert-butyl)pyridin-2-yl)-9H-carbazole (159 mg, 0.42 mmol, 1.2 eq), CuI (13 mg, 0.07 mmol, 0.2 eq), picolinic acid (9 mg, 0.07 mmol, 0.2 eq) and K₃PO4 (149 mg, 0.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L15 in 30%˜70% yield.

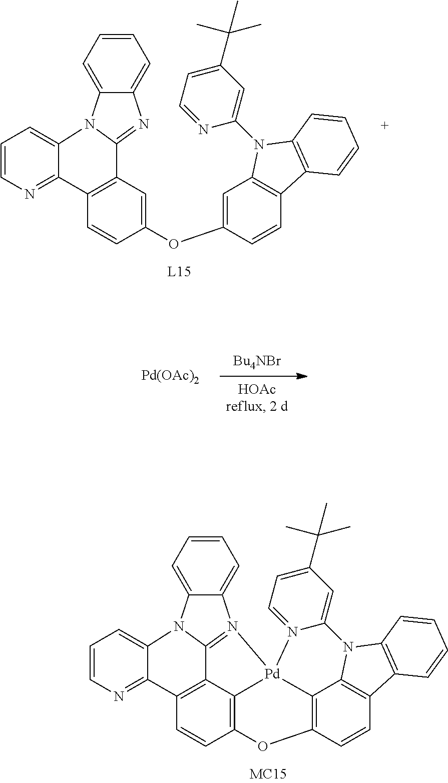

L15 (0.18 mmol, 1.0 eq), Pd(OAc)₂ (43 mg, 0.19 mmol, 1.1 eq) and n-Bu₄NBr (6 mg, 0.018 mmol, 0.1 eq) were added to a dry pressure tube, which was taken into a glove box and acetic acid (11 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC15 in 10%-50% yield.

### Example 16

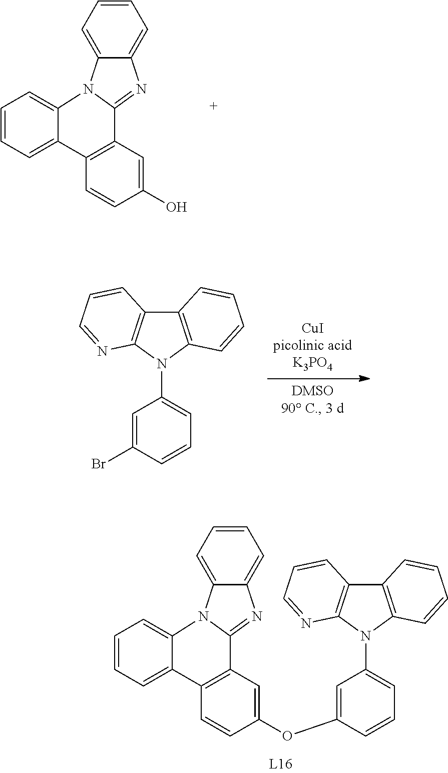 [SMILES: Oc1ccc2c3ccccc3n3c4ccccc4nc3c2c1 ; Brc1cccc(-n2c3ccccc3c3cccnc32)c1 ; "CuIpicolinic acidK3PO4" ; "DMSO90° C., 3 d" ; c1cc(Oc2ccc3c4ccccc4n4c5ccccc5nc4c3c2)cc(-n2c3ccccc3c3cccnc32)c1]

Benzo[4,5]imidazo[1,2-f]phenanthridin-7-ol (284.3 mg, 1 mmol, 1.0 eq), 2-bromo-9-(pyridin-2-yl)-9H-carbazole (388 mg, 1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as and eluent to obtain the desired product ligand L16 as a white solid 316 mg in 60% yield.

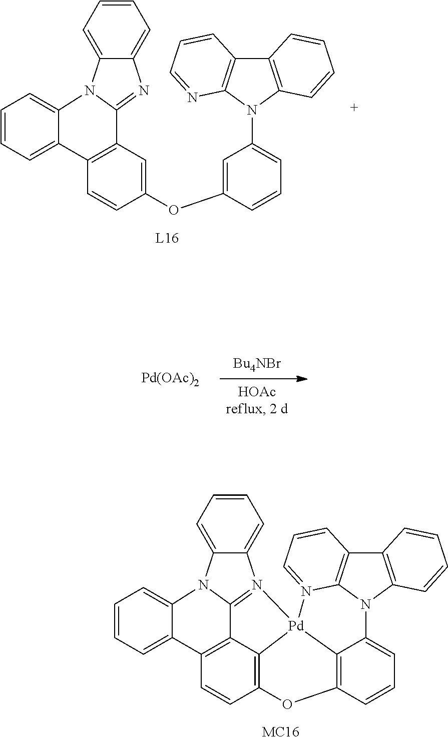

L16 (105.4 mg, 0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC16 as a white solid 52 mg in 40% yield.

### Example 17

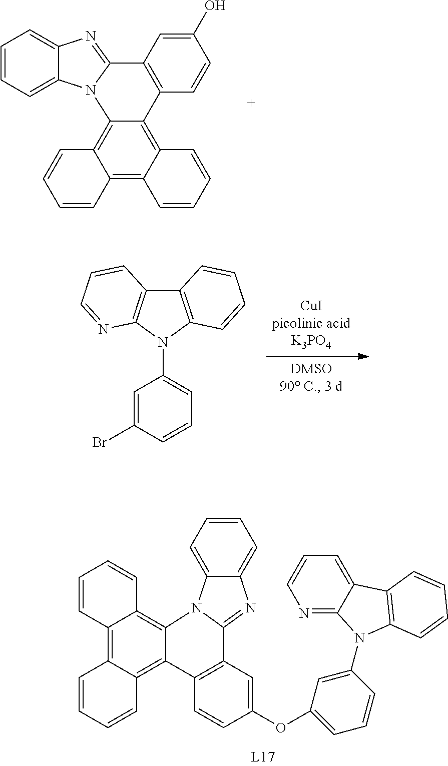 [SMILES: Oc1ccc2c(c1)c1nc3ccccc3n1c1c3ccccc3c3ccccc3c21 ; Brc1cccc(-n2c3ccccc3c3cccnc32)c1 ; "CuIpicolinic acidK3PO4" ; "DMSO90° C., 3 d" ; c1cc(Oc2ccc3c(c2)c2nc4ccccc4n2c2c4ccccc4c4ccccc4c32)cc(-n2c3ccccc3c3cccnc32)c1]

Dibenzo[a,c]benzo[4,5]imidazo[1,2-f]phenanthridin-7-ol (384.3 mg, 1 mmol, 1.0 eq), 9-(3-bromophenyl)-9H-pyrido[2,3-b]indole (388 mg, 1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L17 as a white solid 352 mg in 56% yield.

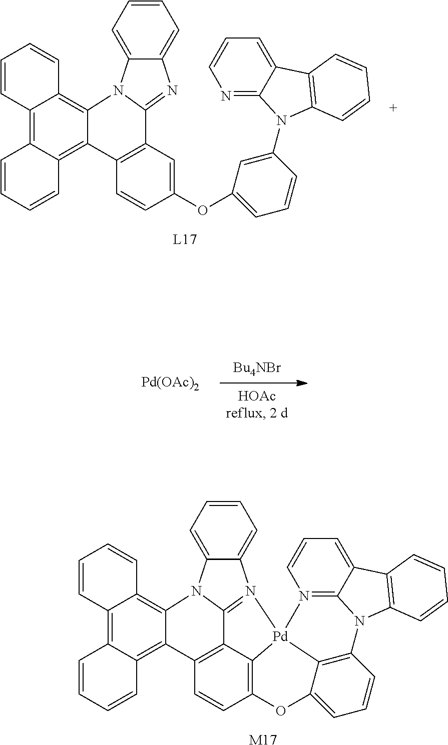

L17 (125.4 mg, 0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC17 as a white solid 66 mg in 45% yield.

### Example 18

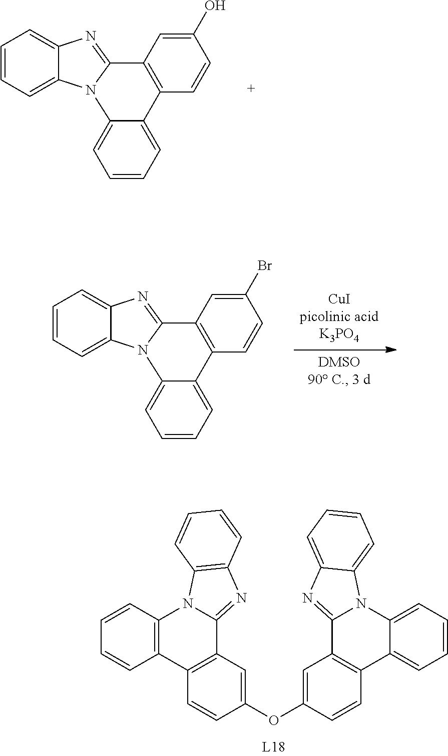 [SMILES: Oc1ccc2c3ccccc3n3c4ccccc4nc3c2c1 ; Brc1ccc2c3ccccc3n3c4ccccc4nc3c2c1 ; "CuIpicolinic acidK3PO4" ; "DMSO90° C., 3 d" ; c1ccc2c(c1)nc1c3cc(Oc4ccc5c6ccccc6n6c7ccccc7nc6c5c4)ccc3c3ccccc3n21]

Benzo[4,5]imidazo[1,2-f]phenanthridin-7-ol (1 mmol, 1.0 eq), 7-bromobenzo[4,5]imidazo[1,2-f]phenanthridine (1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L18 as a white solid in 40%˜70% yield.

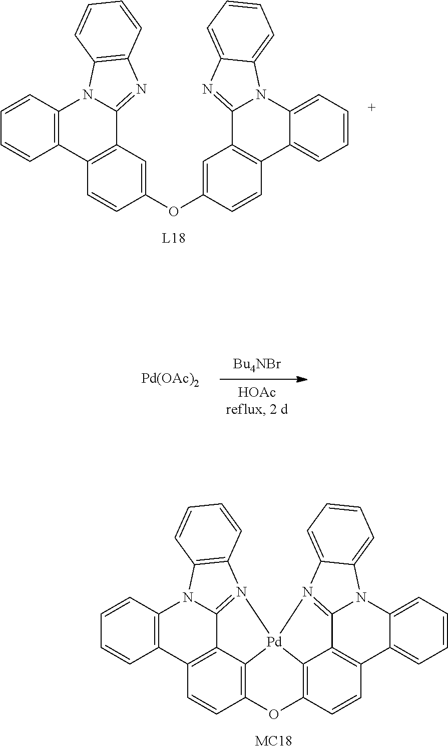

L18 (0.20 mmol, 1.0 eq), Pd(OAc)₂ (0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC18 as a white solid in 10%˜50% yield.

### Example 19

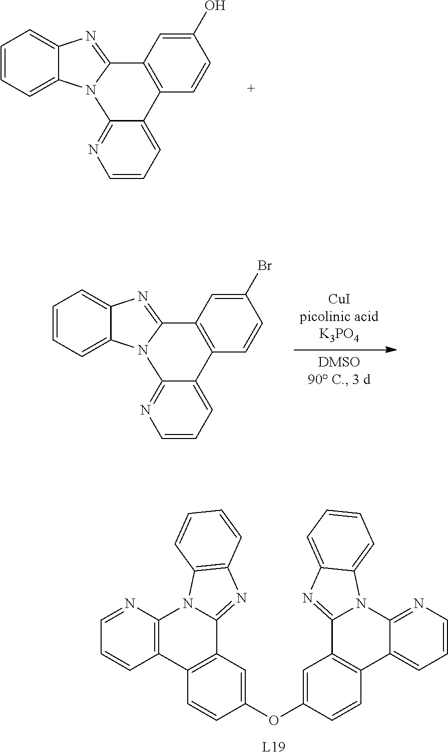 [SMILES: Oc1ccc2c3cccnc3n3c4ccccc4nc3c2c1 ; Brc1ccc2c3cccnc3n3c4ccccc4nc3c2c1 ; "CuIpicolinic acidK3PO4" ; "DMSO90° C., 3 d" ; c1ccc2c(c1)nc1c3cc(Oc4ccc5c6cccnc6n6c7ccccc7nc6c5c4)ccc3c3cccnc3n21]

Benzo[c]benzo[4,5]imidazo[1,2-a][1,8]naphthyridin-7-ol (1 mmol, 1.0 eq), 7-bromobenzo[c]benzo[4,5]imidazo[1,2-a][1,8]naphthyridine (1.2 mmol, 1.2 eq), CuI (38 mg, 0.2 mmol, 0.2 eq), picolinic acid (49 mg, 0.4 mmol, 0.4 eq) and K₃PO4 (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L19 as a white solid in 40%˜70% yield.

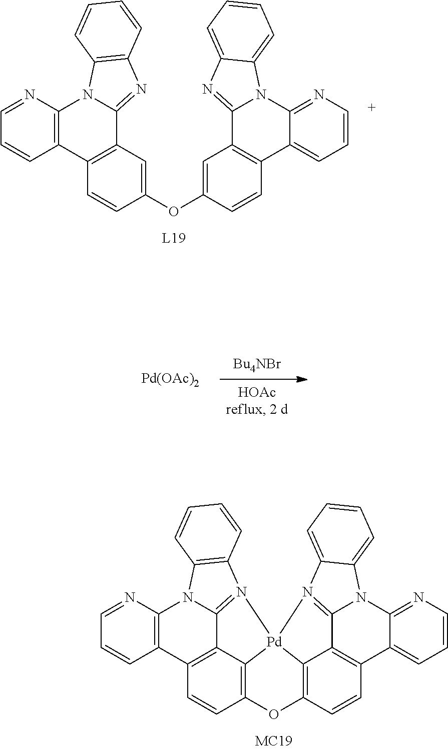

L19 (0.20 mmol, 1.0 eq), Pd(OAc)₂ (0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC19 as a white solid in 10%˜50% yield.

### Example 20

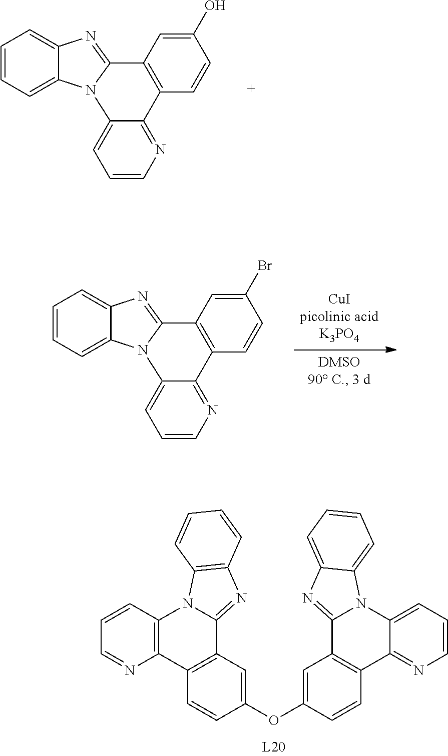 [SMILES: Oc1ccc2c(c1)c1nc3ccccc3n1c1cccnc21 ; Brc1ccc2c(c1)c1nc3ccccc3n1c1cccnc21 ; "CuIpicolinic acidK3PO4" ; "DMSO90° C., 3 d" ; c1ccc2c(c1)nc1c3cc(Oc4ccc5c(c4)c4nc6ccccc6n4c4cccnc54)ccc3c3ncccc3n21]

Benzo[c]benzo[4,5]imidazo[1,2-a][1,5]naphthyridin-7-ol (1 mmol, 1.0 eq), 7-bromobenzo[c]benzo[4,5]imidazo[1,2-a][1,5]naphthyridine (1.2 mmol, 1.2 eq), CuI (38 mg, 0.2 mmol, 0.2 eq), picolinic acid (49 mg, 0.4 mmol, 0.4 eq) and K₃PO4 (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L20 as a white solid in 40%˜70% yield.

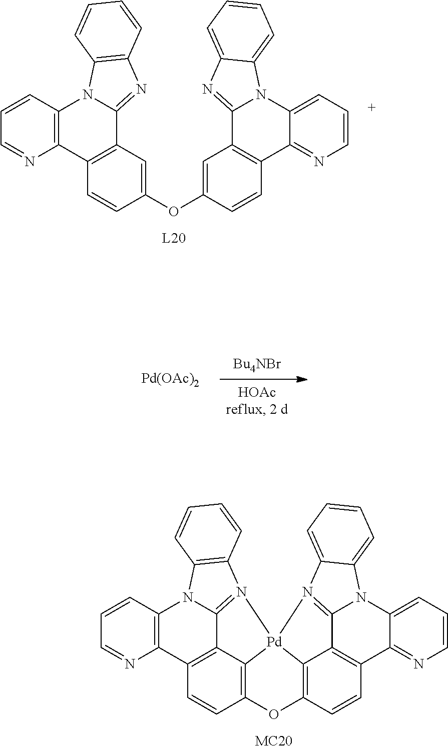

L20 (0.20 mmol, 1.0 eq), Pd(OAc)₂ (0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC20 as a white solid in 10%˜50% yield.

### Example 21

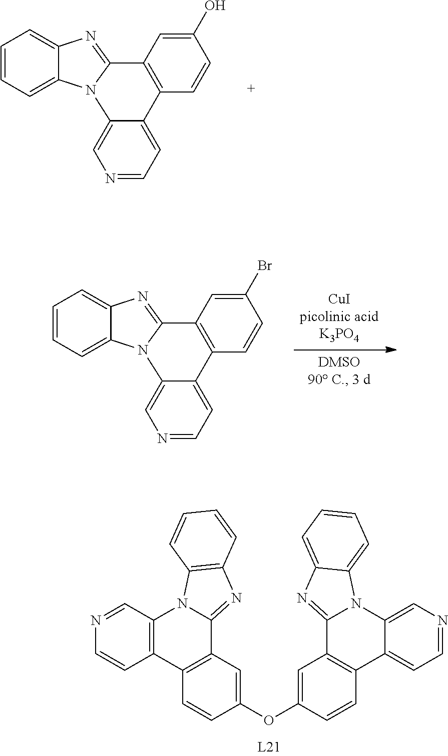 [SMILES: Oc1ccc2c3ccncc3n3c4ccccc4nc3c2c1 ; Brc1ccc2c3ccncc3n3c4ccccc4nc3c2c1 ; "CuIpicolinic acidK3PO4" ; "DMSO90° C., 3 d" ; c1ccc2c(c1)nc1c3cc(Oc4ccc5c6ccncc6n6c7ccccc7nc6c5c4)ccc3c3ccncc3n21]

Benzo[c]benzo[4,5]imidazo[1,2-a][1,7]naphthyridin-7-ol (1 mmol, 1.0 eq), 7-bromobenzo[c]benzo[4,5]imidazo[1,2-a][1,7]naphthyridine (1.2 mmol, 1.2 eq), CuI (38 mg, 0.2 mmol, 0.2 eq), picolinic acid (49 mg, 0.4 mmol, 0.4 eq) and K₃PO4 (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L21 as a white solid in 40%˜70% yield.

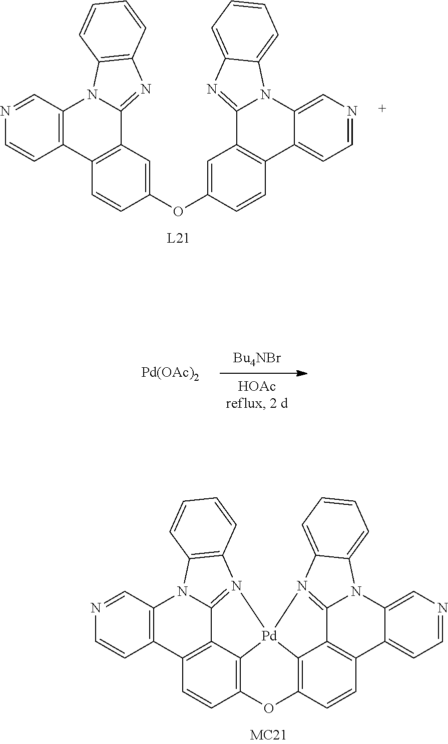

L21 (0.20 mmol, 1.0 eq), Pd(OAc)₂ (0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC21 as a white solid in 10%˜50% yield.

### Example 22

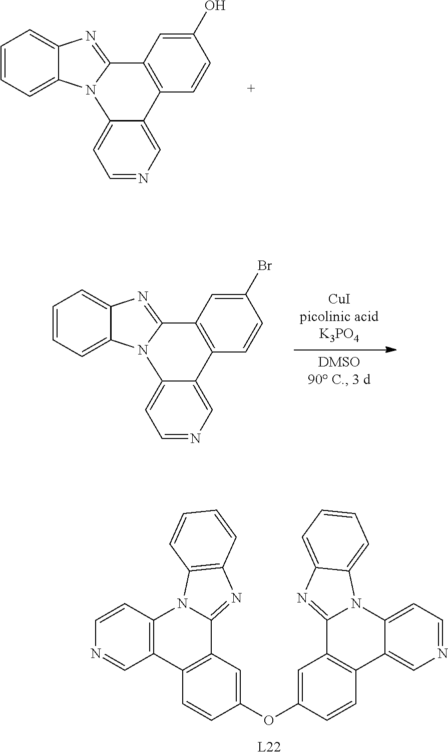 [SMILES: Oc1ccc2c3cnccc3n3c4ccccc4nc3c2c1 ; Brc1ccc2c3cnccc3n3c4ccccc4nc3c2c1 ; "CuIpicolinic acidK3PO4" ; "DMSO90° C., 3 d" ; c1ccc2c(c1)nc1c3cc(Oc4ccc5c6cnccc6n6c7ccccc7nc6c5c4)ccc3c3cnccc3n21]

Benzo[c]benzo[4,5]imidazo[1,2-a][1,6]naphthyridin-7-ol (1 mmol, 1.0 eq), 7-bromobenzo[c]benzo[4,5]imidazo[1,2-a][1,6]naphthyridine (1.2 mmol, 1.2 eq), CuI (38 mg, 0.2 mmol, 0.2 eq), picolinic acid (49 mg, 0.4 mmol, 0.4 eq) and K₃PO4 (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L22 as a white solid in 40%˜70% yield.

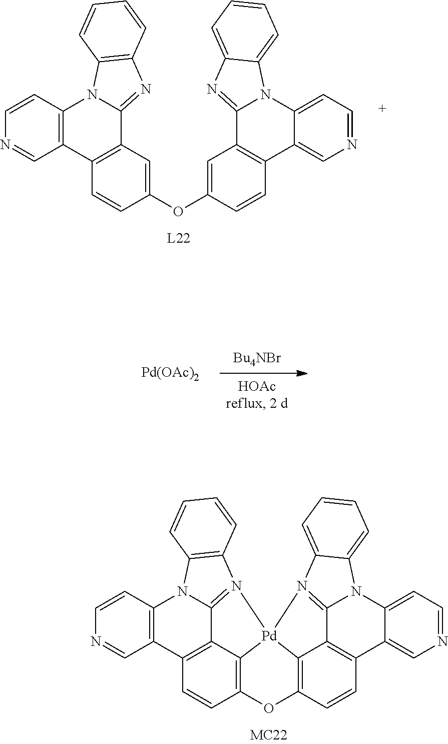

L22 (0.20 mmol, 1.0 eq), Pd(OAc)₂ (0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC22 as a white solid in 10%˜50% yield.

### Example 23

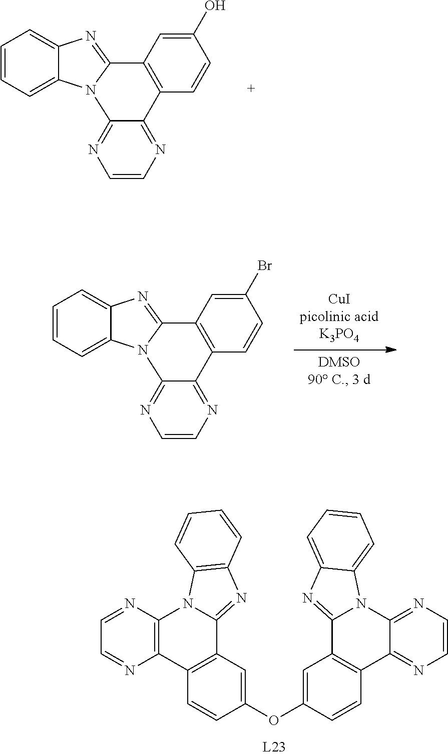 [SMILES: Oc1ccc2c(c1)c1nc3ccccc3n1c1nccnc21 ; Brc1ccc2c(c1)c1nc3ccccc3n1c1nccnc21 ; "CuIpicolinic acidK3PO4" ; "DMSO90° C., 3 d" ; c1ccc2c(c1)nc1c3cc(Oc4ccc5c(c4)c4nc6ccccc6n4c4nccnc54)ccc3c3nccnc3n21]

Benzo[4,5]imidazo[2,1-a]pyrazino[2,3-c]isoquinolin-7-ol (1 mmol, 1.0 eq), 7-bromobenzo[4,5]imidazo[2,1-a]pyrazino[2,3-c]isoquinoline (1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L23 as a white solid in 40%˜70% yield.

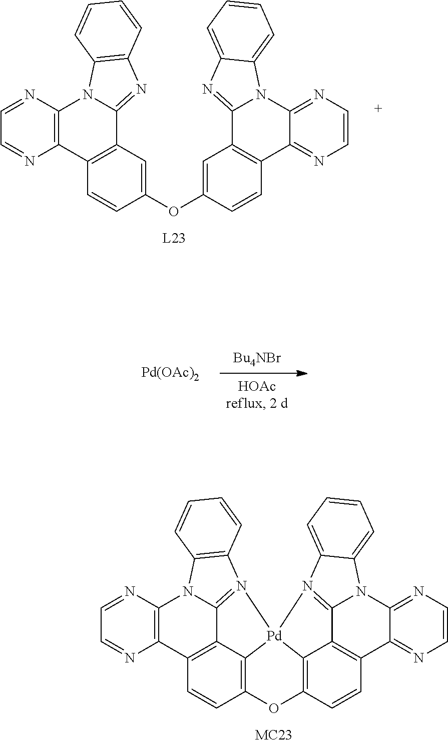

L23 (0.20 mmol, 1.0 eq), Pd(OAc)₂ (0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC23 as a white solid in 10%˜50% yield.

### Example 24

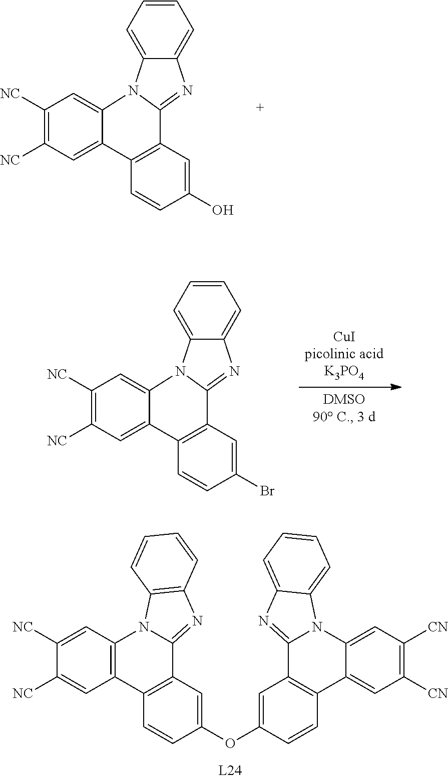

7-hydroxybenzo[4,5]imidazo[1,2-f]phenanthridine-2,3-dicarbonitrile (1 mmol, 1.0 eq), 7-bromobenzo[4,5]imidazo[1,2-f]phenanthridine-2,3-dicarbonitrile (1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L24 as a white solid in 40%˜70% yield.

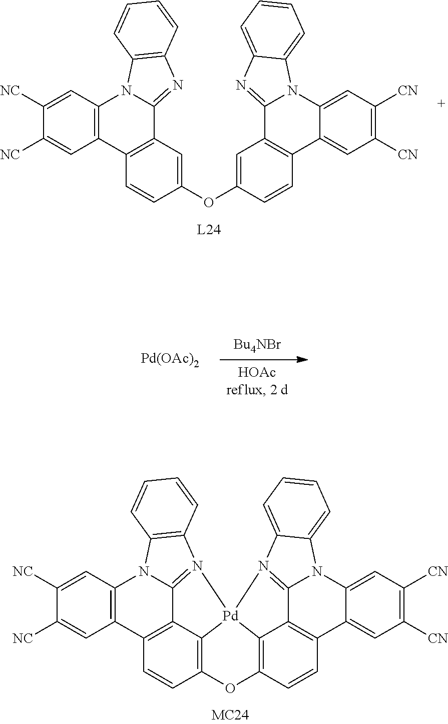

L24 (0.20 mmol, 1.0 eq), Pd(OAc)₂ (0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC24 as a white solid in 10%˜50% yield.

### Example 25

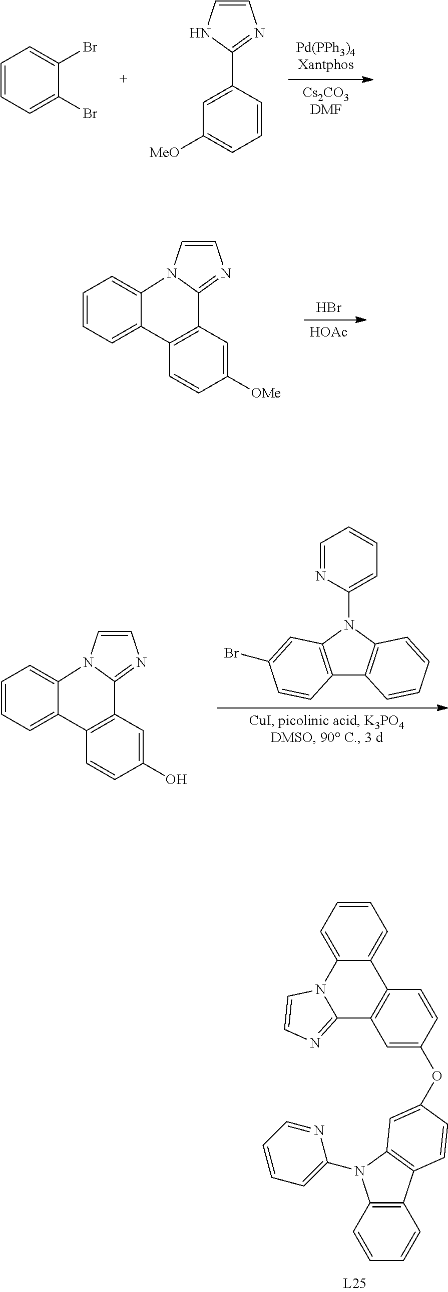

Imidazo[1,2-f]phenanthridin-11-ol (200 mg, 0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen.

The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L25 as a light orange solid 350 mg in 86% yield.

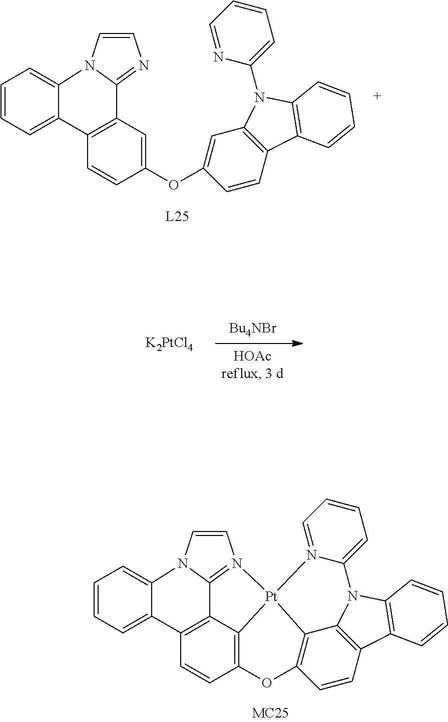

L25 (50 mg, 0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC25 as a white solid 15 mg in 21% yield.

### Example 26

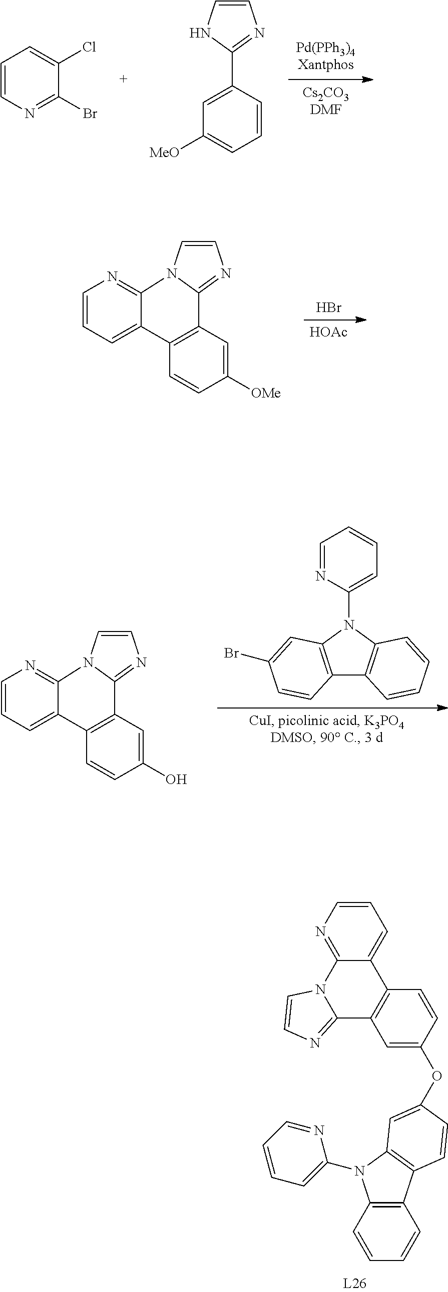

11-bromobenzo[c]imidazo[1,2-a][1,8]naphthyridine (250 mg, 0.84 mmol, 1.0 eq), 9-(pyridin-2-yl)-9H-carbazol-2-ol (262 mg, 1.01 mmol, 1.2 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L26 as a light orange solid 200 mg in 50% yield.

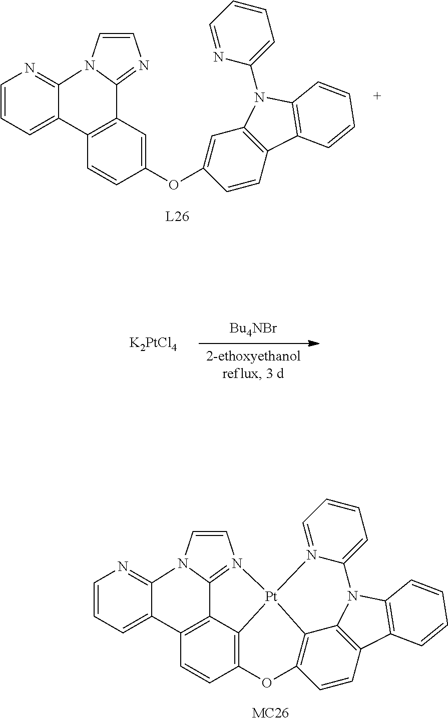

L26 (140 mg, 0.29 mmol, 1.0 eq), K₂PtCl₄ (134 mg, 0.32 mmol, 1.1 eq) and n-Bu₄NBr (9 mg, 0.030 mmol, 0.1 eq) were added to a dry pressure tube, which was taken into a glove box and acetic acid (20 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC26 as a white solid 65 mg in 33% yield.

### Example 27

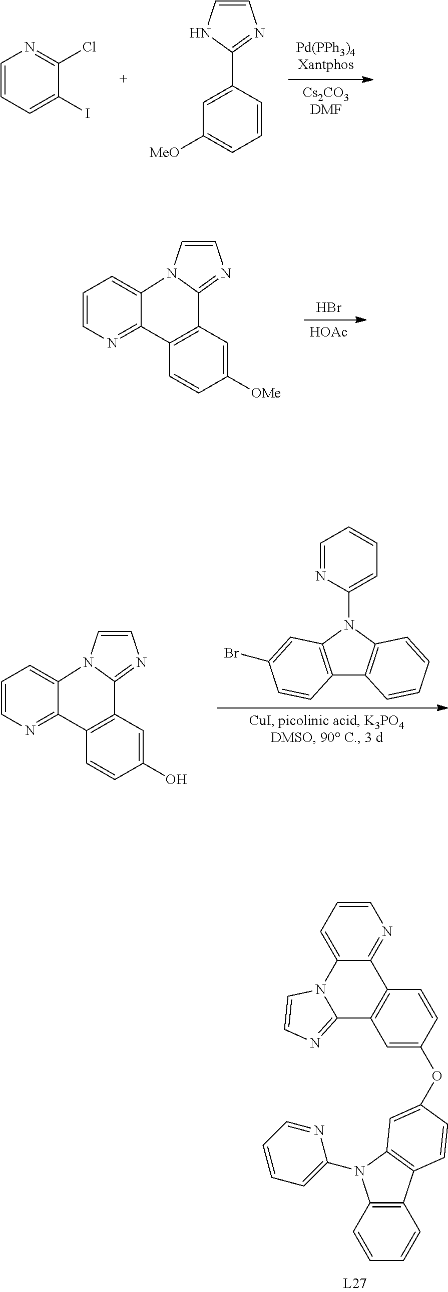

Benzo[c]imidazo[1,2-a][1,5]naphthyridin-11-ol (305 mg, 1.30 mmol, 1.0 eq), 2-bromo-9-(pyridin-2-yl)-9H-carbazole (494 mg, 1.56 mmol, 1.2 eq), CuI (50 mg, 0.26 mmol, 0.2 eq), picolinic acid (32 mg, 0.26 mmol, 0.2 eq) and K₃PO₄ (552 mg, 2.6 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L27 as a white solid 485 mg in 78% yield.

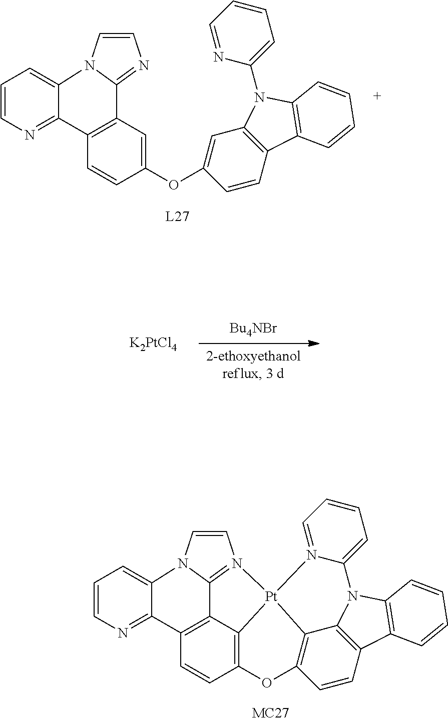

L27 (485 mg, 1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC27 as a white solid 268 mg in 40% yield. FIG. 4 shows an emission spectrum of MC27 in methylene chloride at room temperature.

### Example 28

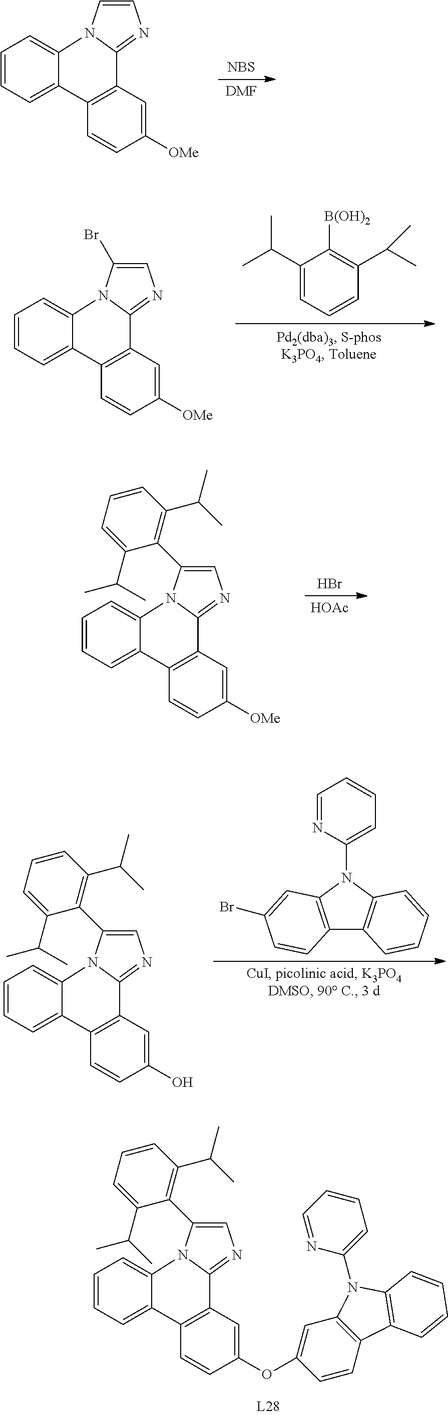

3-(2,6-diisopropylphenyl)imidazo[1,2-f]phenanthridin-11-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L28 in 50%˜80% yield.

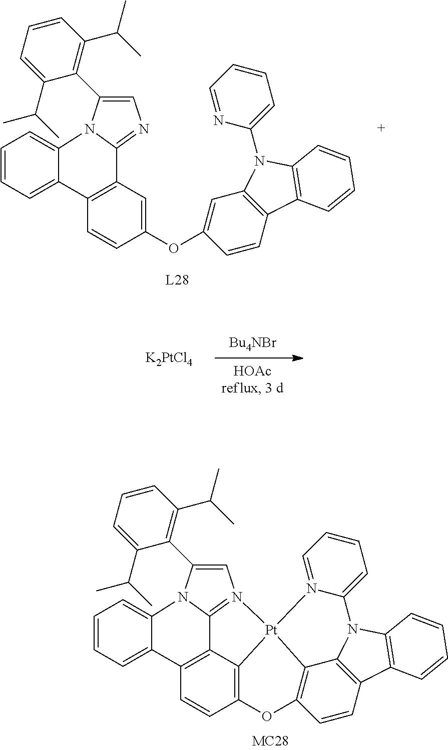

L28 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC28 in 10%-50% yield.

### Example 29

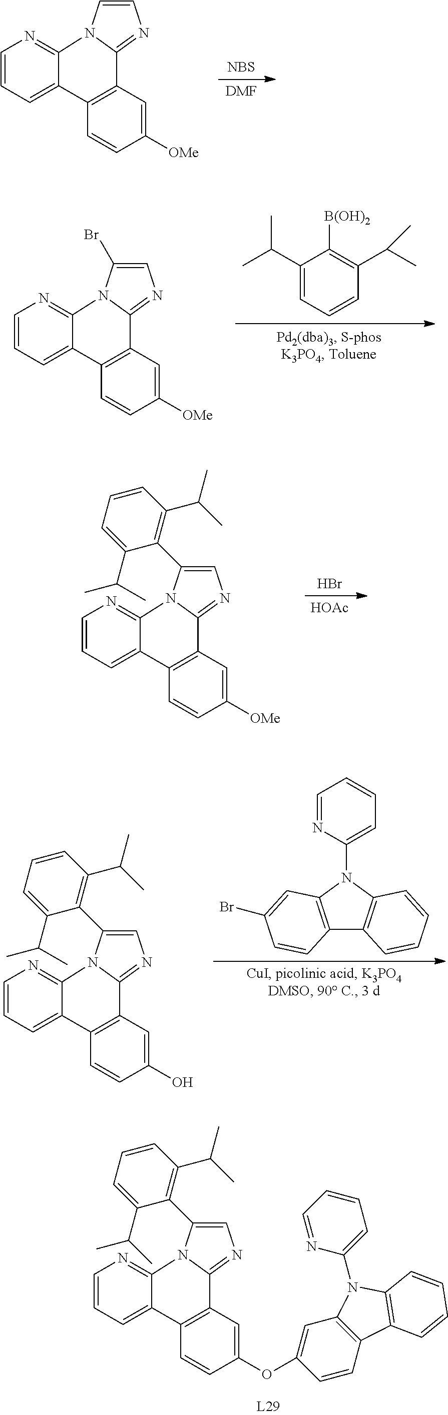

3-(2,6-diisopropylphenyl)benzo[c]imidazo[1,2-a][1,8]naphthyridin-11-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L29 in 50%˜80%

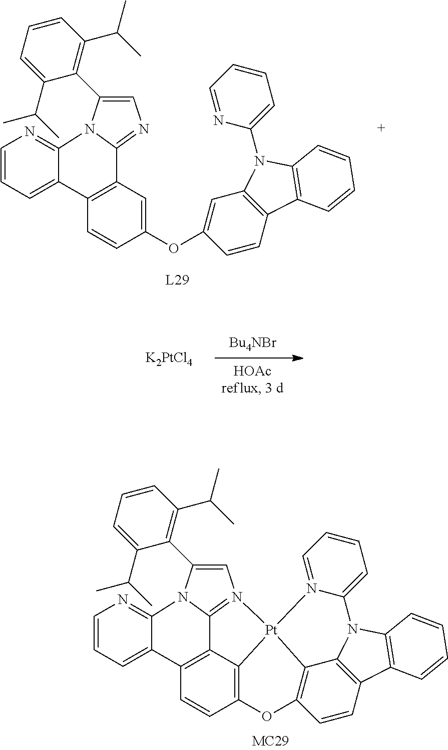

L29 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC29 in 10%˜50% yield.

### Example 30

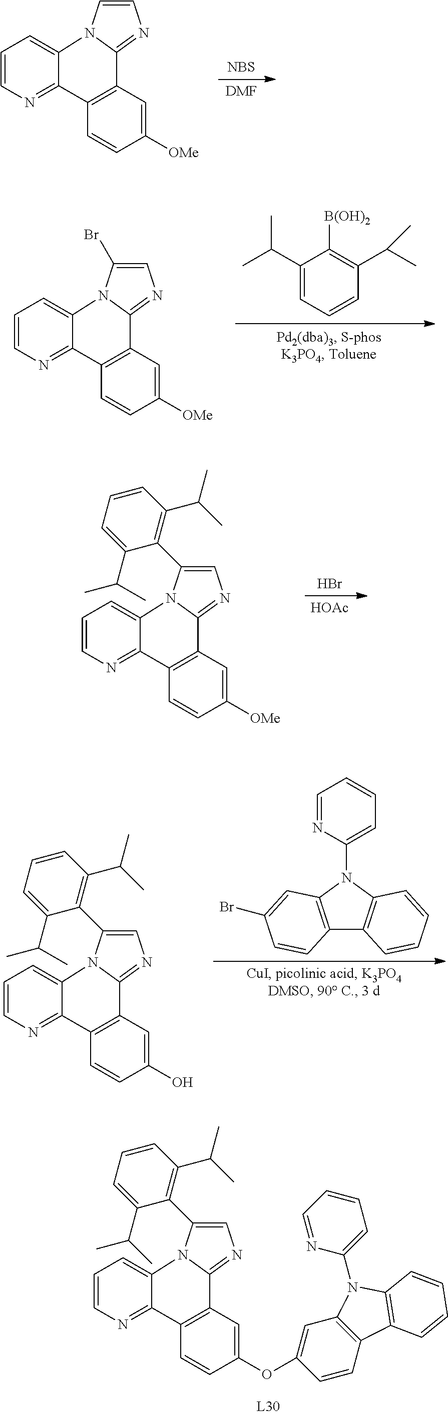

3-(2,6-diisopropylphenyl)benzo[c]imidazo[1,2-a][1,5]naphthyridin-11-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L30 in 50%˜80% yield.

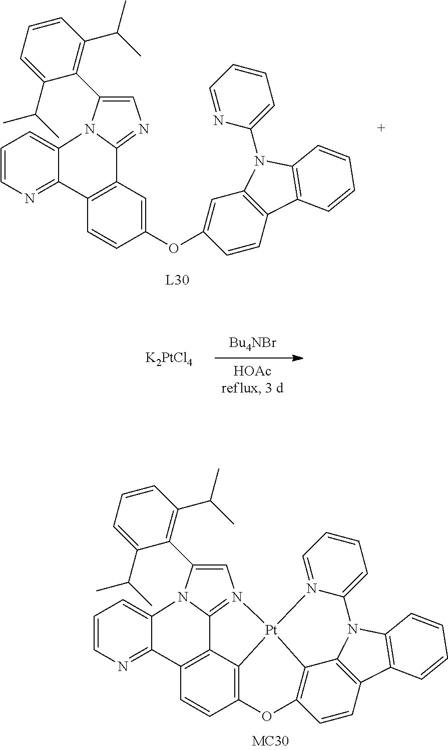

L30 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC30 in 10%-50% yield.

### Example 31

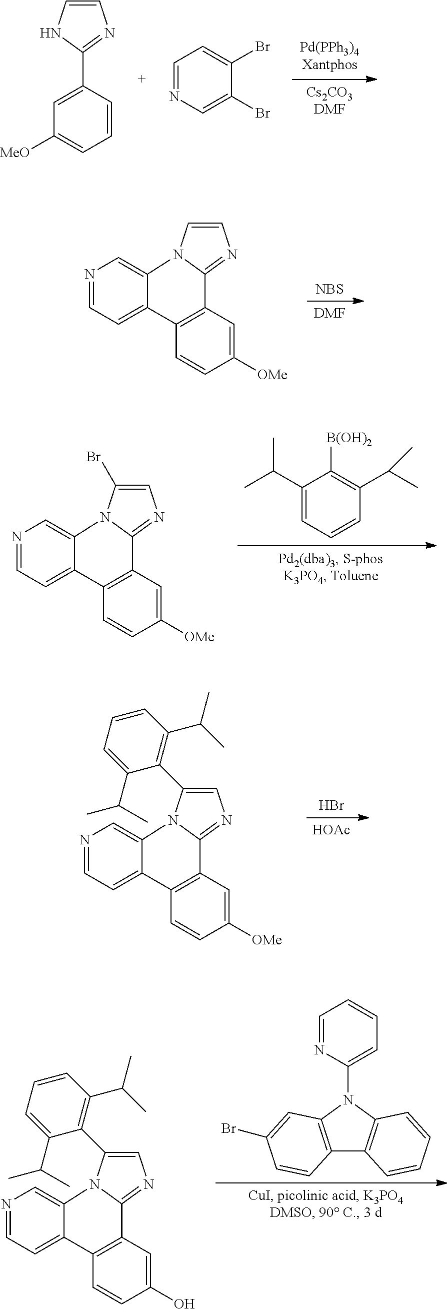

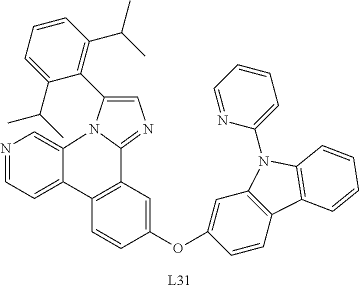 [SMILES: CC(C)c1cccc(C(C)C)c1-c1cnc2c3cc(Oc4ccc5c6ccccc6n(-c6ccccn6)c5c4)ccc3c3ccncc3n12]

3-(2,6-diisopropylphenyl)benzo[c]imidazo[1,2-a][1,7]naphthyridin-11-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L31 in 50%˜80%

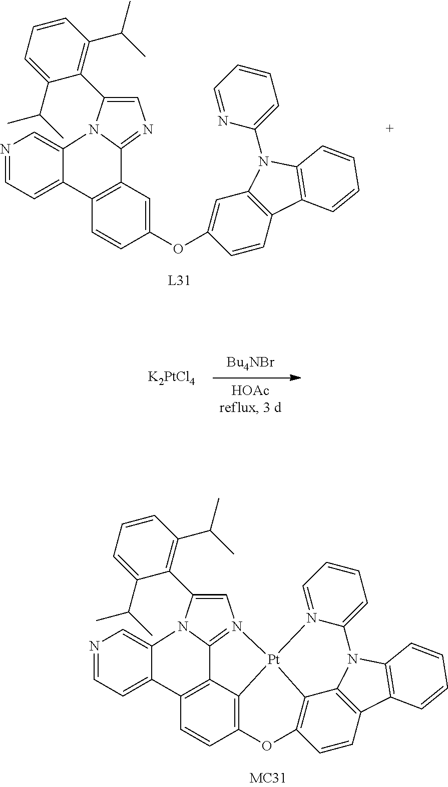

L31 (1.02 mmol, 1.0 eq), K₂PtC14 (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC31 in 10%-50% yield.

### Example 32

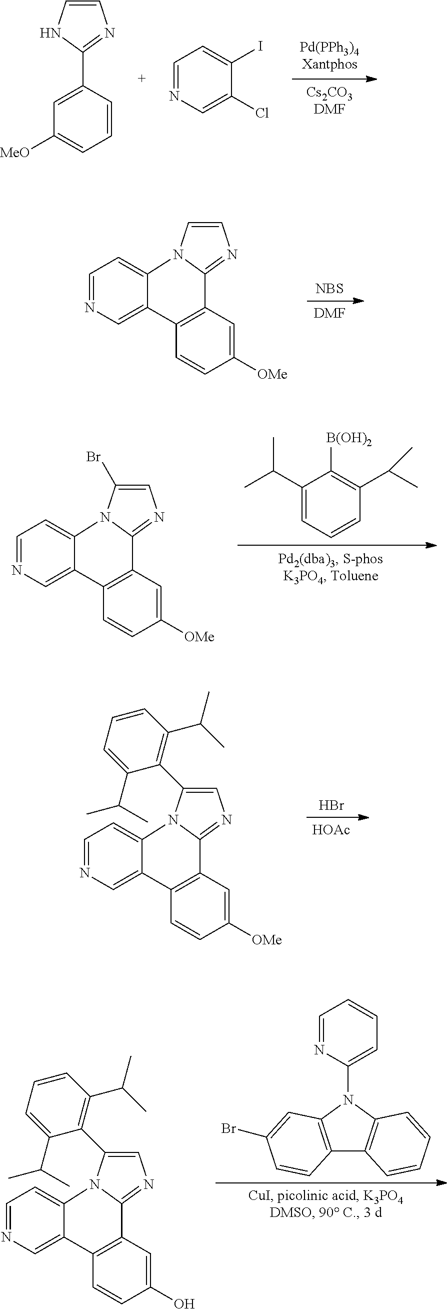

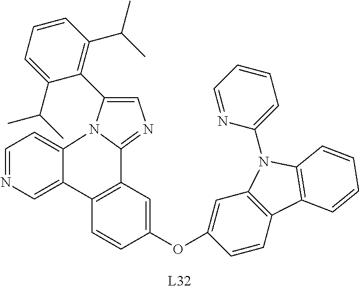 [SMILES: CC(C)c1cccc(C(C)C)c1-c1cnc2c3cc(Oc4ccc5c6ccccc6n(-c6ccccn6)c5c4)ccc3c3cnccc3n12]

3-(2,6-diisopropylphenyl)benzo[c]imidazo[1,2-a][1,6]naphthyridin-11-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L32 in 50%˜80% yield.

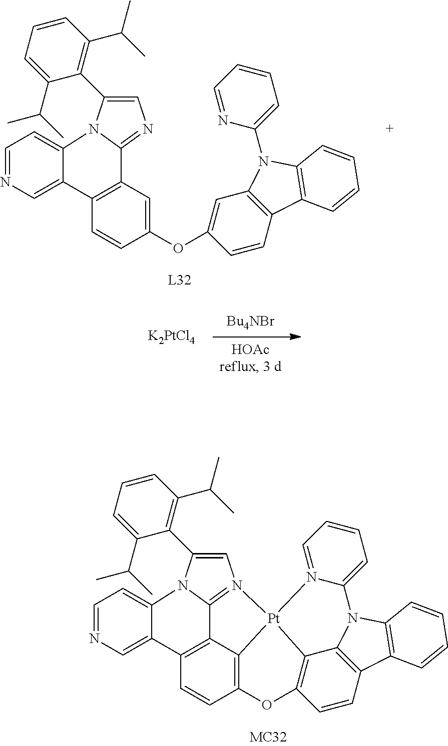

L32 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC32 in 1%-50% yield.

### Example 33

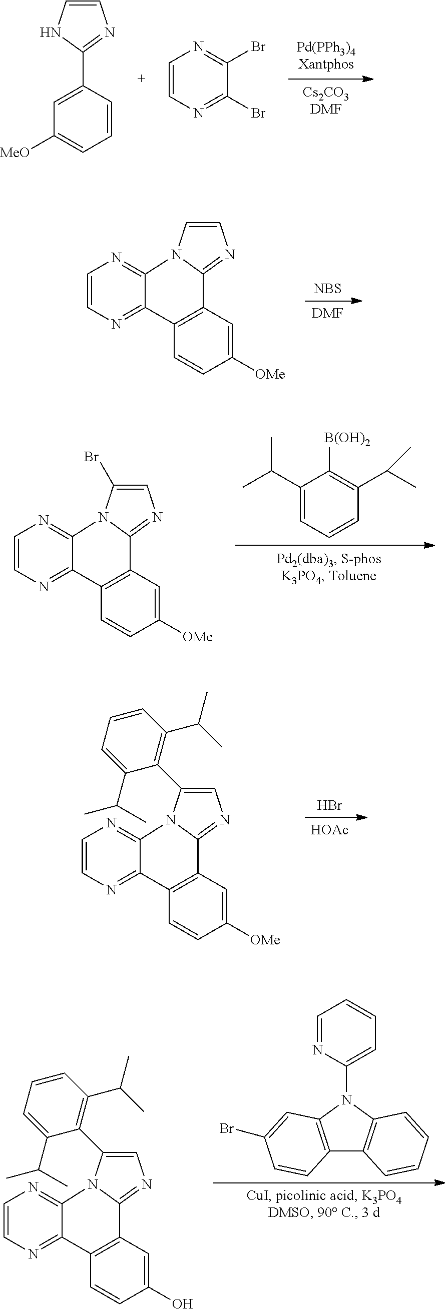

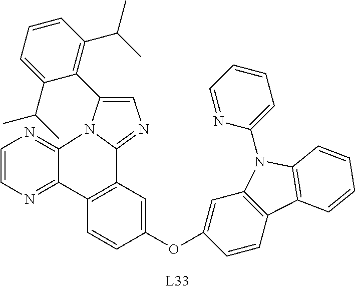 [SMILES: CC(C)c1cccc(C(C)C)c1-c1cnc2c3cc(Oc4ccc5c6ccccc6n(-c6ccccn6)c5c4)ccc3c3nccnc3n12]

3-(2,6-diisopropylphenyl)imidazo[2,1-a]pyrazino[2,3-c]isoquinolin-11-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L33 in 50%˜80% yield.

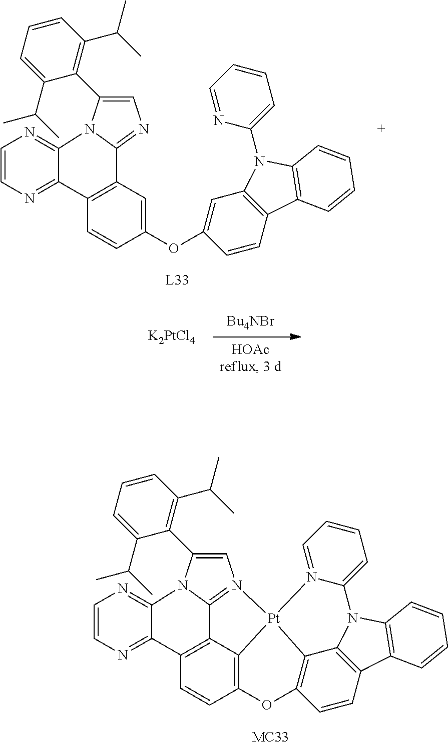

L33 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC33 in 10%-50% yield.

### Example 34

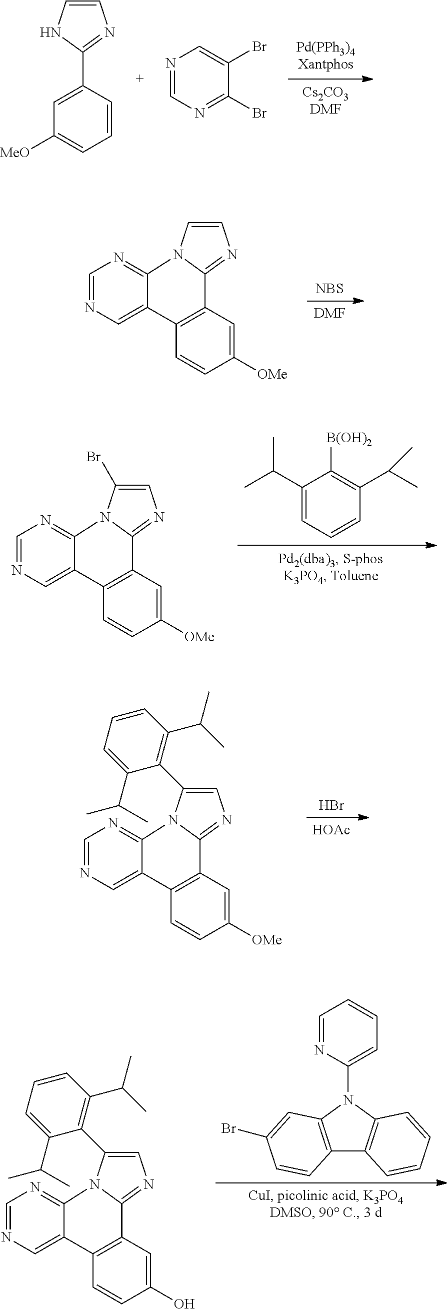

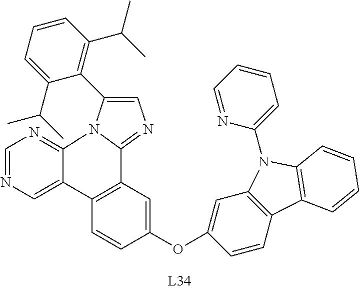 [SMILES: CC(C)c1cccc(C(C)C)c1-c1cnc2c3cc(Oc4ccc5c6ccccc6n(-c6ccccn6)c5c4)ccc3c3cncnc3n12]

11-(2,6-diisopropylphenyl)imidazo[2,1-a]pyrimido[4,5-c]isoquinolin-7-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L34 in 50%˜80%

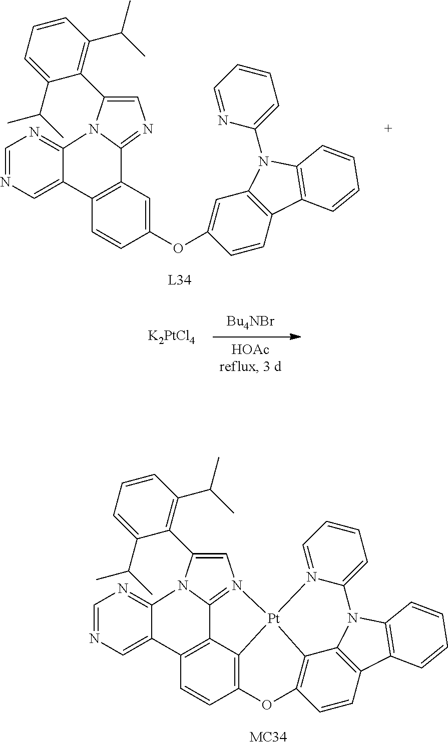

L34 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC34 in 10%-50% yield.

### Example 35

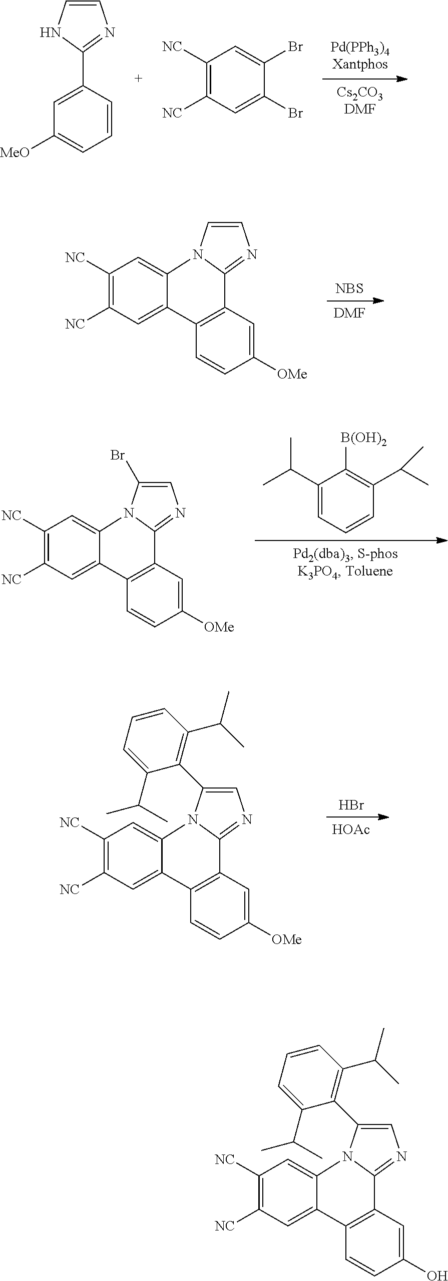

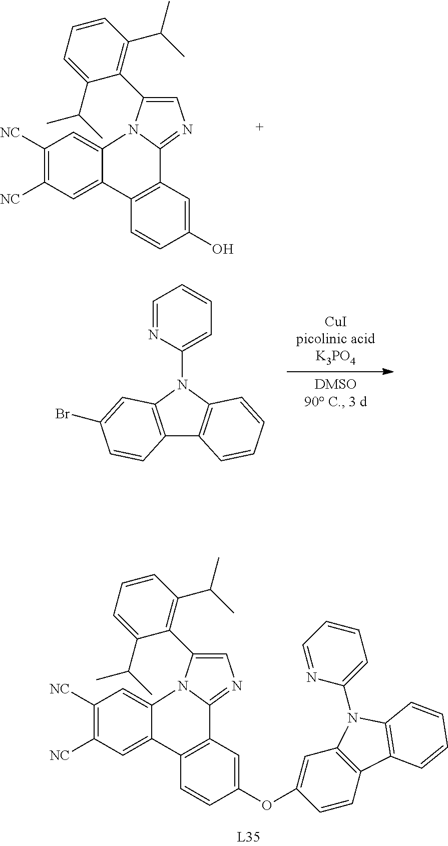

3-(2,6-diisopropylphenyl)-11-hydroxyimidazo[1,2-f]phenanthridine-6,7-dicarbonitrile (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L35 in 50%˜80% yield.

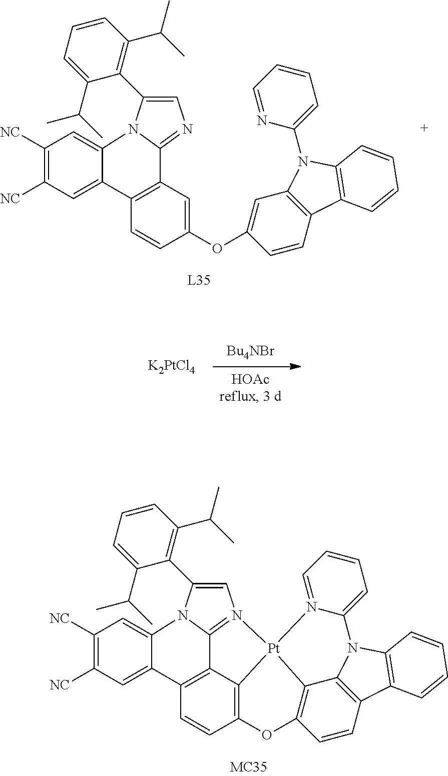

L35 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC35 in 10%-50% yield.

### Example 36

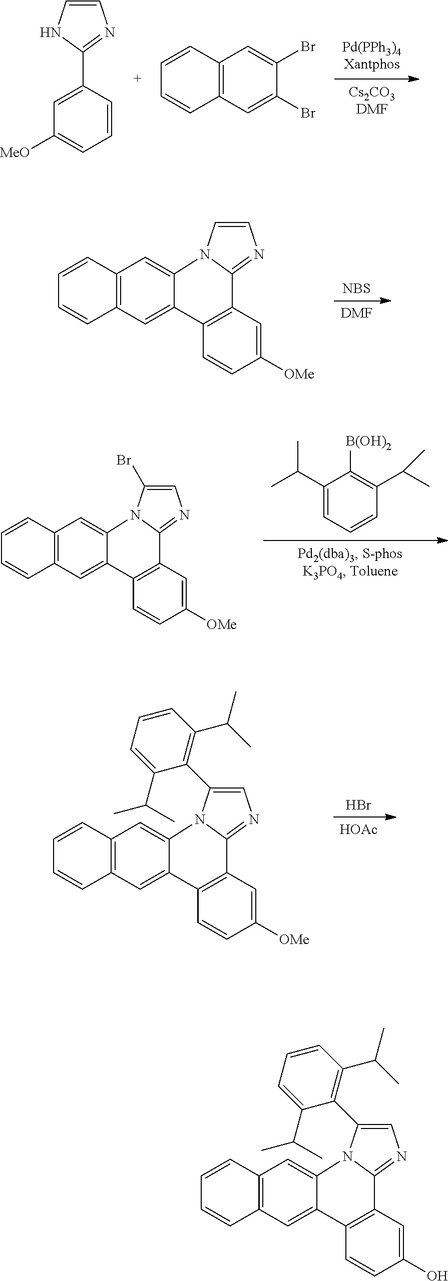

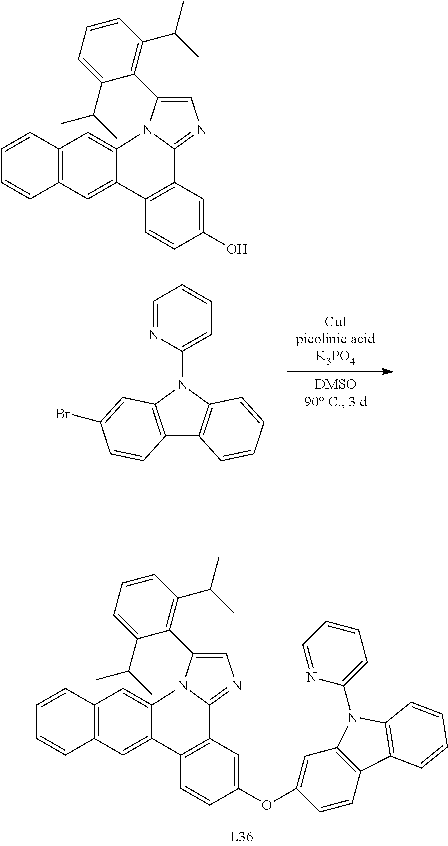

1-(2,6-diisopropylphenyl)benzo[b]imidazo[1,2-f]phenanthridin-5-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L36 in 50%˜80% yield.

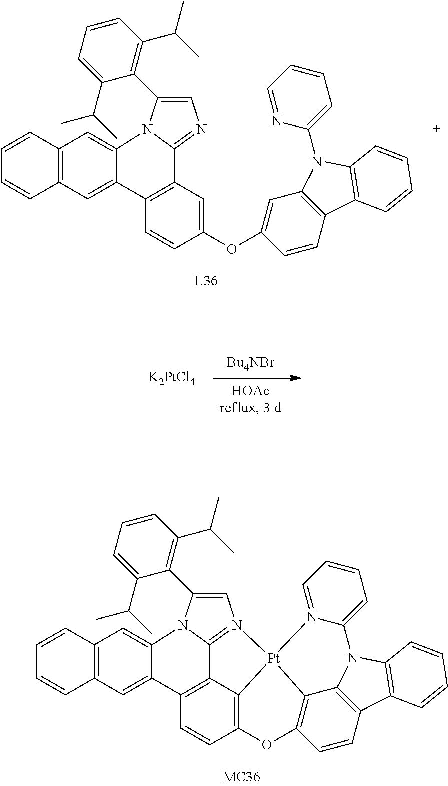

L36 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC36 in 10%-50% yield.

### Example 37

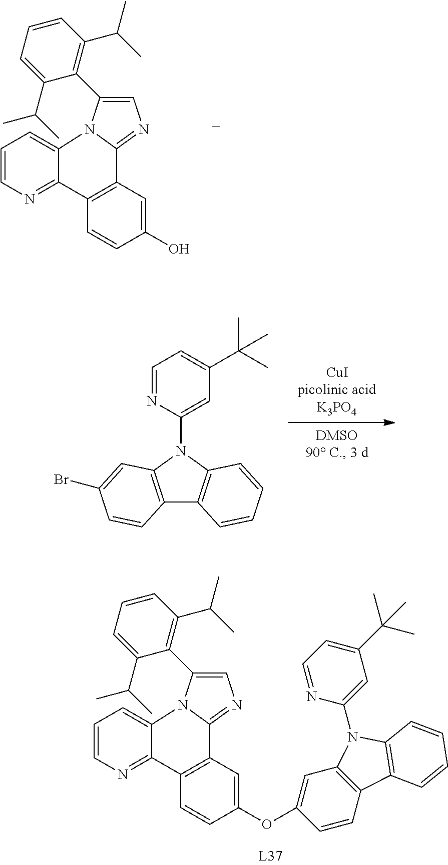 [SMILES: CC(C)c1cccc(C(C)C)c1-c1cnc2c3cc(O)ccc3c3ncccc3n12 ; CC(C)(C)c1ccnc(-n2c3ccccc3c3ccc(Br)cc32)c1 ; "CuIpicolinic acidK3PO4" ; "DMSO90° C., 3 d" ; CC(C)c1cccc(C(C)C)c1-c1cnc2c3cc(Oc4ccc5c6ccccc6n(-c6cc(C(C)(C)C)ccn6)c5c4)ccc3c3ncccc3n12]

3-(2,6-diisopropylphenyl)benzo[c]imidazo[1,2-a][1,5]naphthyridin-11-ol (0.85 mmol, 1.0 eq), 2-bromo-9-(4-(tert-butyl)pyridin-2-yl)-9H-carbazole (417 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L37 in 50%˜80% yield.

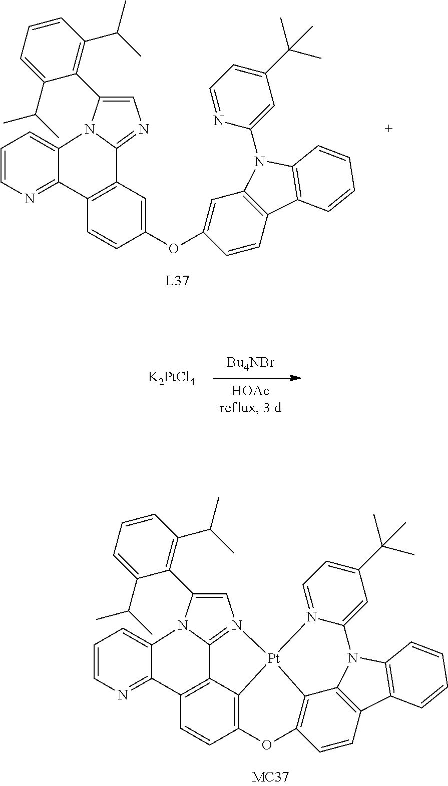

L37 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC37 in 10%-50% yield.

### Example 38

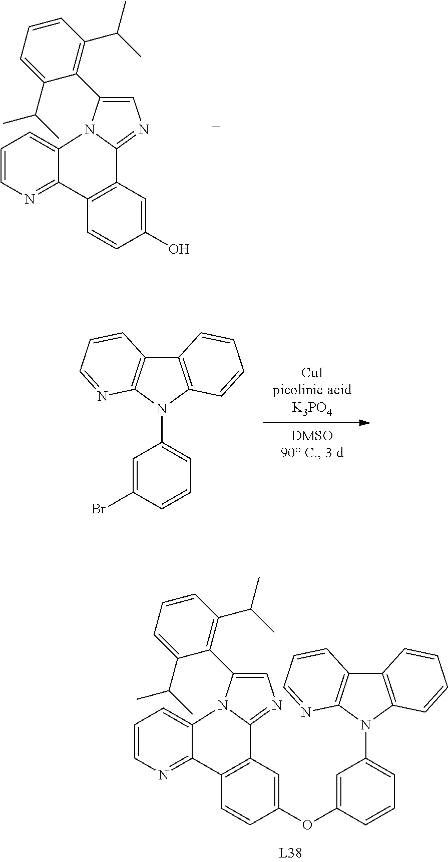 [SMILES: CC(C)c1cccc(C(C)C)c1-c1cnc2c3cc(O)ccc3c3ncccc3n12 ; Brc1cccc(-n2c3ccccc3c3cccnc32)c1 ; "CuIpicolinic acidK3PO4" ; "DMSO90° C., 3 d" ; CC(C)c1cccc(C(C)C)c1-c1cnc2c3cc(Oc4cccc(-n5c6ccccc6c6cccnc65)c4)ccc3c3ncccc3n12]

3-(2,6-diisopropylphenyl)benzo[c]imidazo[1,2-a][1,5]naphthyridin-11-ol (0.85 mmol, 1.0 eq), 9-(3-bromophenyl)-9H-pyrido[2,3-b]indole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L38 in 50%˜80% yield.

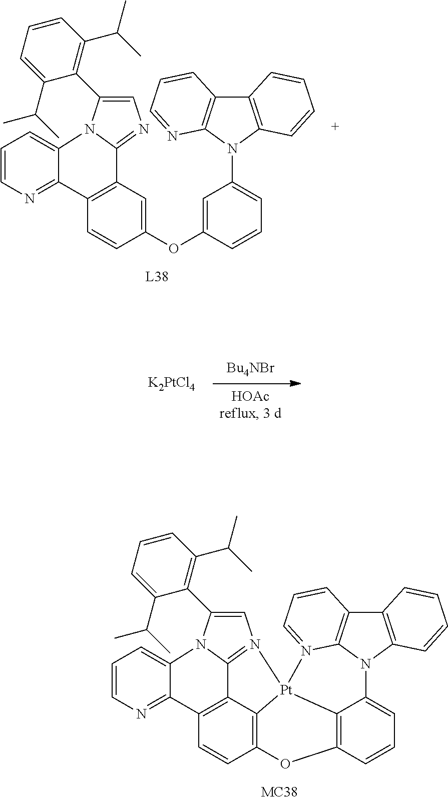

L38 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC38 in 10%-50% yield.

### Example 39

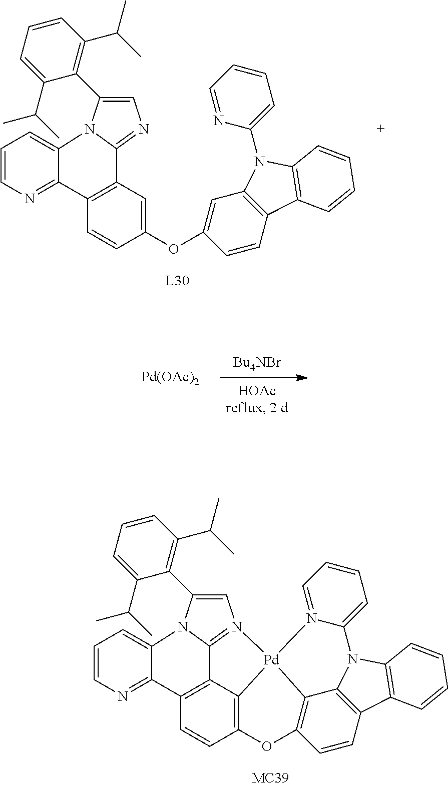

L30 (1.02 mmol, 1.0 eq), Pd(OAc)₂ (239 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC39 in 10%-50% yield.

### Example 40

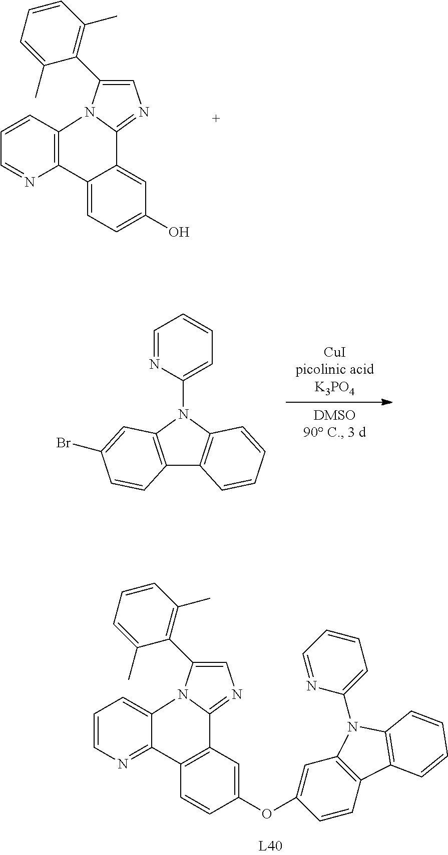 [SMILES: Cc1cccc(C)c1-c1cnc2c3cc(O)ccc3c3ncccc3n12 ; Brc1ccc2c3ccccc3n(-c3ccccn3)c2c1 ; "CuIpicolinic acidK3PO4" ; "DMSO90° C., 3 d" ; Cc1cccc(C)c1-c1cnc2c3cc(Oc4ccc5c6ccccc6n(-c6ccccn6)c5c4)ccc3c3ncccc3n12]

3-(2,6-dimethylphenyl)benzo[c]imidazo[1,2-a][1,5]naphthyridin-11-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L40 in 50%-80% yield.

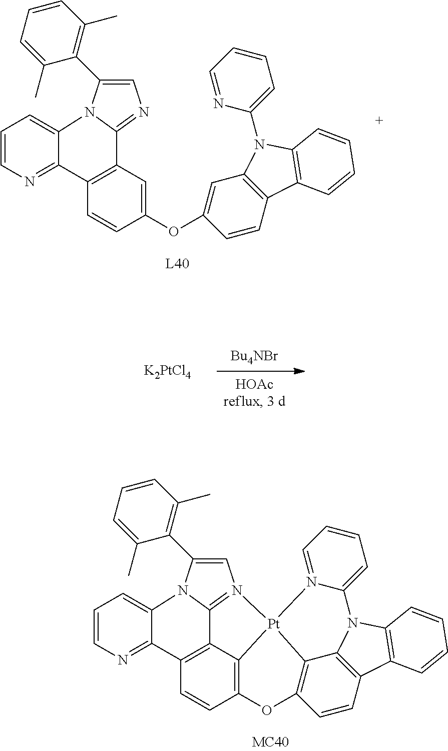

L40 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC40 in 10%-50% yield.

### Example 41

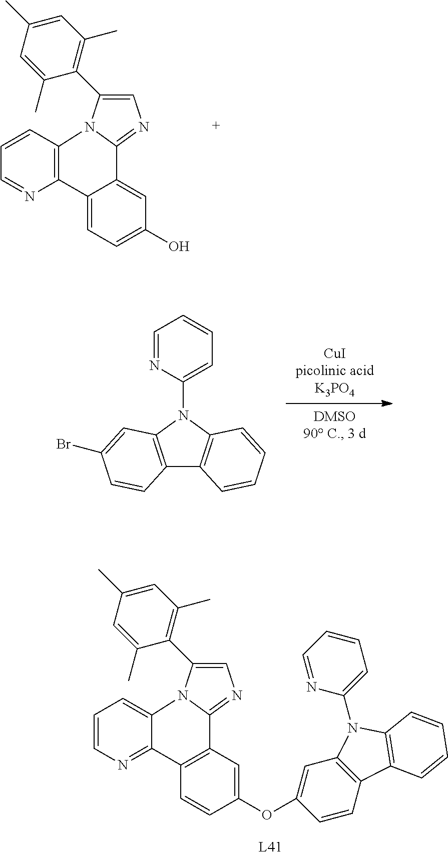 [SMILES: Cc1cc(C)c(-c2cnc3c4cc(O)ccc4c4ncccc4n23)c(C)c1 ; Brc1ccc2c3ccccc3n(-c3ccccn3)c2c1 ; "CuIpicolinic acidK3PO4" ; "DMSO90° C., 3 d" ; Cc1cc(C)c(-c2cnc3c4cc(Oc5ccc6c7ccccc7n(-c7ccccn7)c6c5)ccc4c4ncccc4n23)c(C)c1]

3-mesitylbenzo[c]imidazo[1,2-a][1,5]naphthyridin-11-ol (300 mg, 0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L41 in 75% yield.

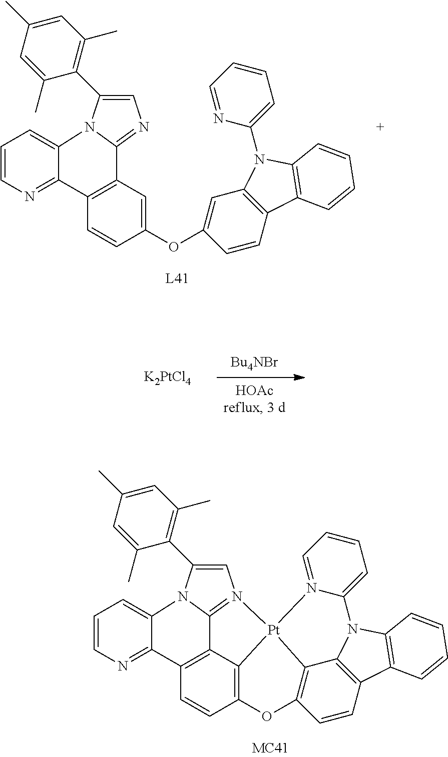

L41 (238 mg, 0.4 mmol, 1.0 eq), K₂PtCl₄ (174 mg, 0.42 mmol, 1.05 eq) and n-Bu₄NBr (13 mg, 0.04 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC41 in 72% yield.

### Example 42

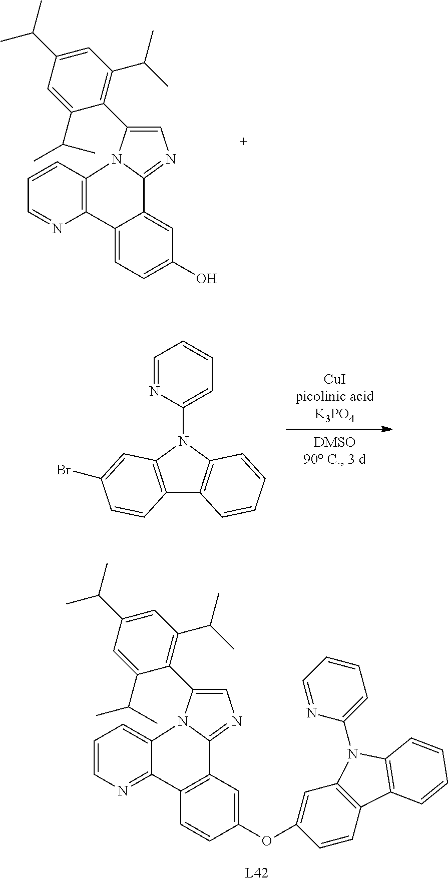 [SMILES: CC(C)c1cc(C(C)C)c(-c2cnc3c4cc(O)ccc4c4ncccc4n23)c(C(C)C)c1 ; Brc1ccc2c3ccccc3n(-c3ccccn3)c2c1 ; "CuIpicolinic acidK3PO4" ; "DMSO90° C., 3 d" ; CC(C)c1cc(C(C)C)c(-c2cnc3c4cc(Oc5ccc6c7ccccc7n(-c7ccccn7)c6c5)ccc4c4ncccc4n23)c(C(C)C)c1]

3-(2,4,6-triisopropylphenyl)benzo[c]imidazo[1,2-a][1,5]naphthyridin-11-ol (0.85 mmol, 1.0 eq), 2-bromo-9-(pyridin-2-yl)-9H-carbazole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L42 in 50%˜80% yield.

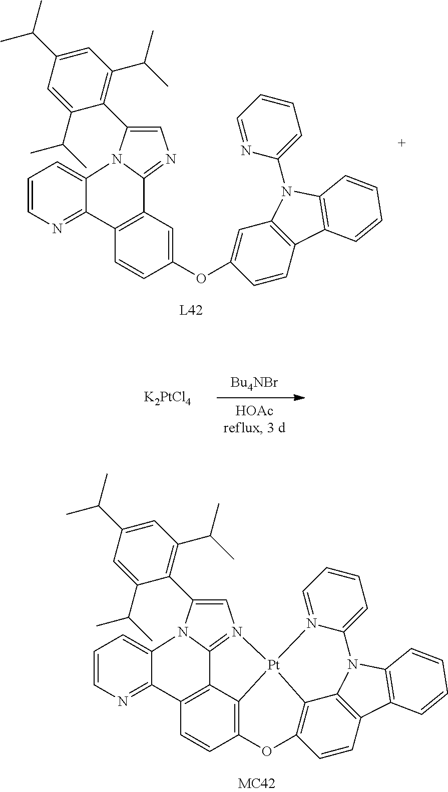

L42 (1.02 mmol, 1.0 eq), K₂PtCl₄ (443 mg, 1.07 mmol, 1.05 eq) and n-Bu₄NBr (33 mg, 0.102 mmol, 0.1 eq) were added to a dry pressure tube, which was taken into a glove box and acetic acid (60 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC42 in 10%-50% yield.

### Example 43

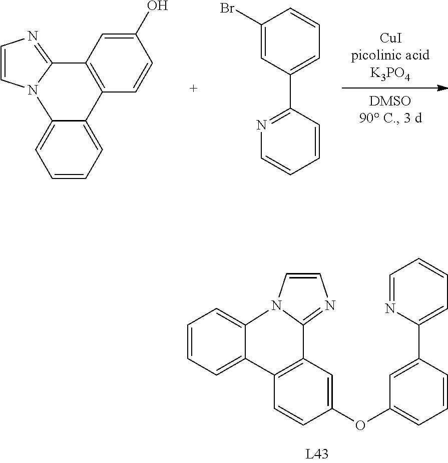 [SMILES: Oc1ccc2c3ccccc3n3ccnc3c2c1 ; Brc1cccc(-c2ccccn2)c1 ; "CuIpicolinic acidK3PO4" ; "DMSO90° C., 3 d" ; c1ccc(-c2cccc(Oc3ccc4c5ccccc5n5ccnc5c4c3)c2)nc1]

Imidazo[1,2-f]phenanthridin-11-ol (1 mmol, 1.0 eq), 2-(3-bromophenyl)pyridine (281 mg, 1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L43 as a white solid in 72% yield.

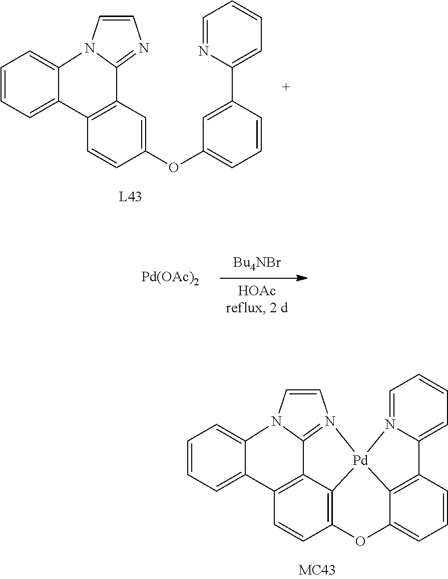

L43 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC43 as a white solid in 53% yield.

### Example 44

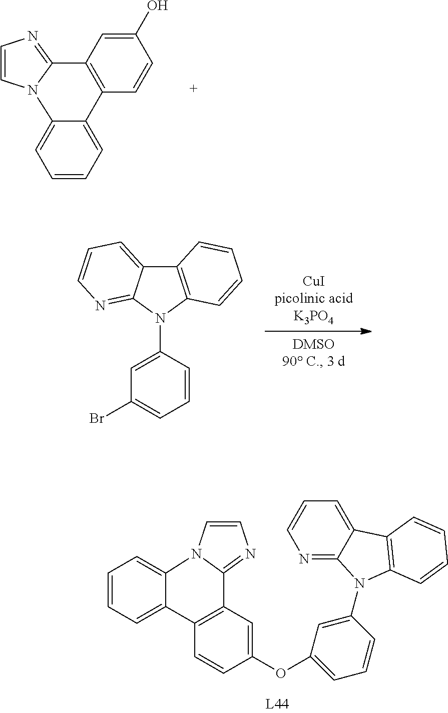 [SMILES: Oc1ccc2c3ccccc3n3ccnc3c2c1 ; Brc1cccc(-n2c3ccccc3c3cccnc32)c1 ; "CuIpicolinic acidK3PO4" ; "DMSO90° C., 3 d" ; c1cc(Oc2ccc3c4ccccc4n4ccnc4c3c2)cc(-n2c3ccccc3c3cccnc32)c1]

Imidazo[1,2-f]phenanthridin-11-ol (1 mmol, 1.0 eq), 9-(3-bromophenyl)-9H-pyrido[2,3-b]indole (388 mg, 1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L44 as a white solid in 66% yield.

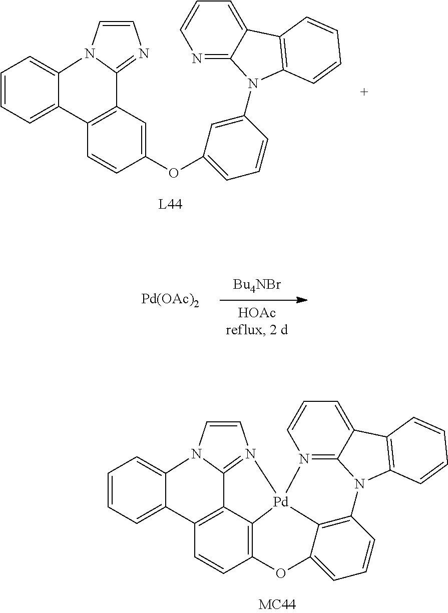

L44 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC44 as a white solid in 45% yield.

### Example 45

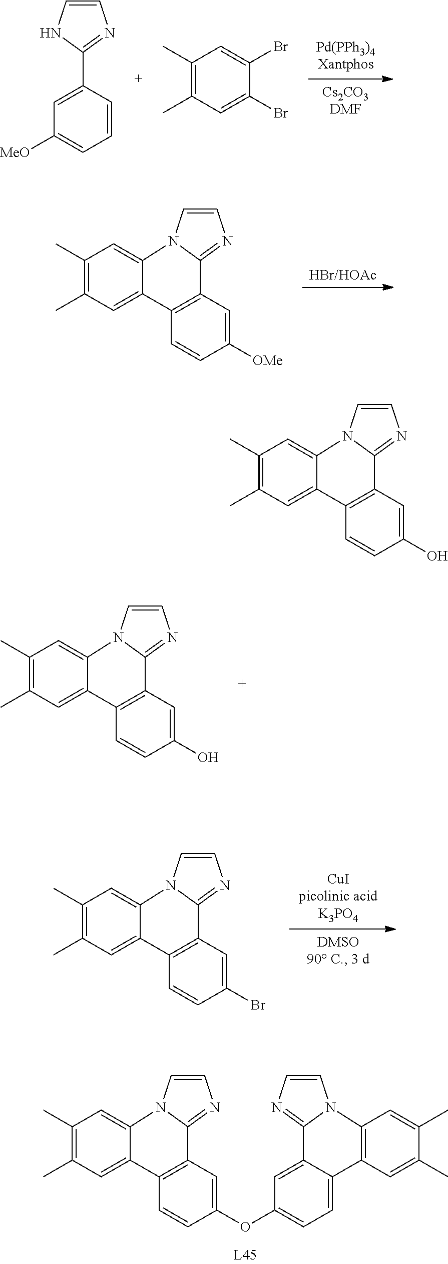

6,7-dimethylimidazo[1,2-f]phenanthridin-11-ol (0.85 mmol, 1.0 eq), 11-bromo-6,7-dimethylimidazo[1,2-f]phenanthridine (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times.

Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L45 in 30%˜70% yield.

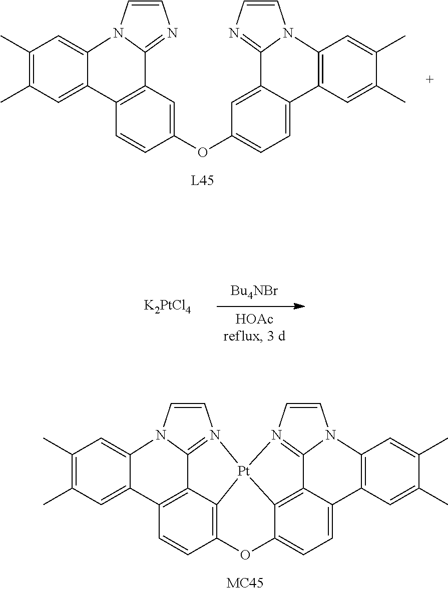

L45 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC45 in 10%˜50% yield.

### Example 46

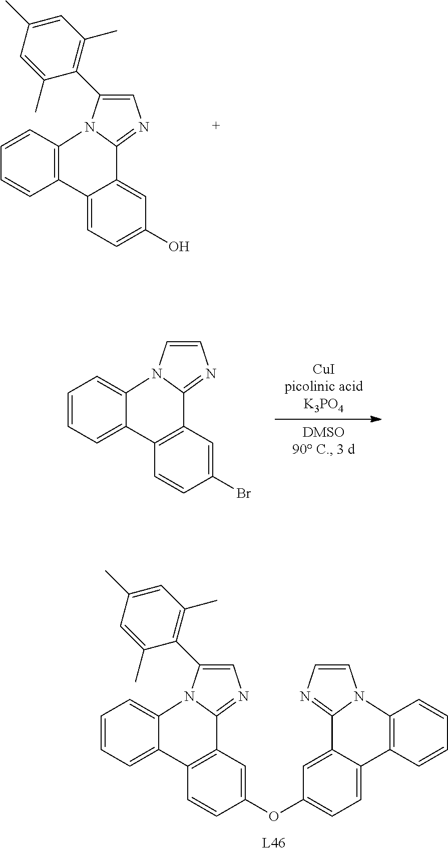 [SMILES: Cc1cc(C)c(-c2cnc3c4cc(O)ccc4c4ccccc4n23)c(C)c1 ; Brc1ccc2c3ccccc3n3ccnc3c2c1 ; "CuIpicolinic acidK3PO4" ; "DMSO90° C., 3 d" ; Cc1cc(C)c(-c2cnc3c4cc(Oc5ccc6c7ccccc7n7ccnc7c6c5)ccc4c4ccccc4n23)c(C)c1]

3-mesitylimidazo[1,2-f]phenanthridin-11-ol (270 mg, 0.76 mmol, 1.0 eq), 11-bromoimidazo[1,2-f]phenanthridine (250 mg, 1.10 mmol, 1.3 eq), CuI (29 mg, 0.15 mmol, 0.2 eq), picolinic acid (19 mg, 0.15 mmol, 0.2 eq) and K₃PO₄ (323 mg, 1.5 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L46 as a white solid of 300 mg in 70% yield.

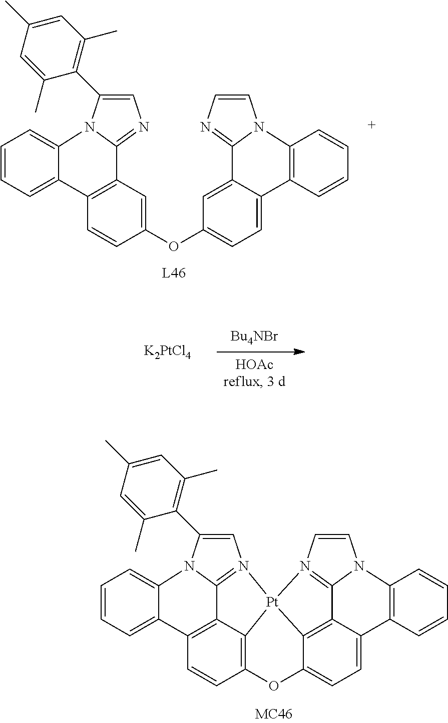

L46 (220 mg, 0.39 mmol, 1.0 eq), K₂PtCl₄ (190 mg, 0.46 mmol, 1.2 eq) and n-Bu₄NBr (13 mg, 0.039 mmol, 0.1 eq) were added to a dry pressure tube, which was taken into a glove box and acetic acid (25 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC46 of 100 mg in 33% yield.

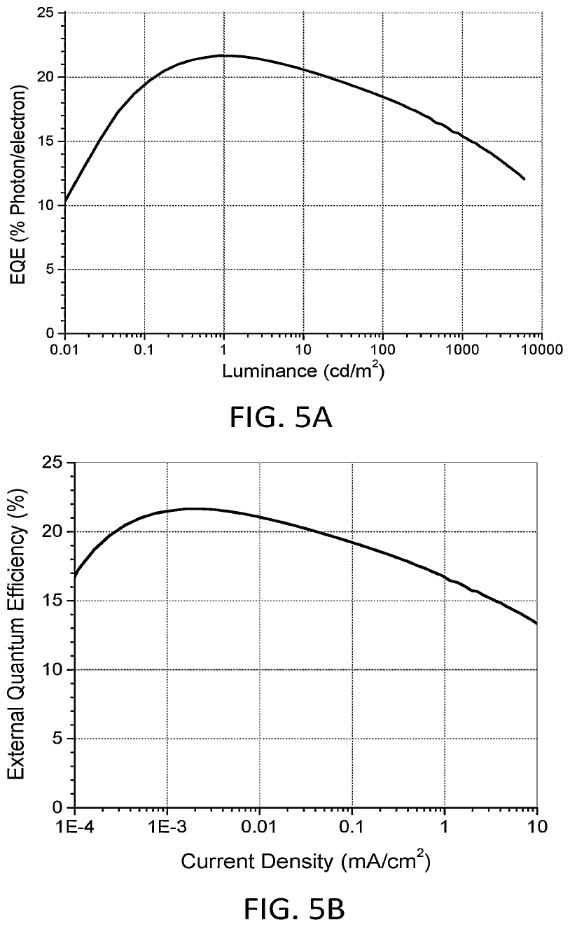

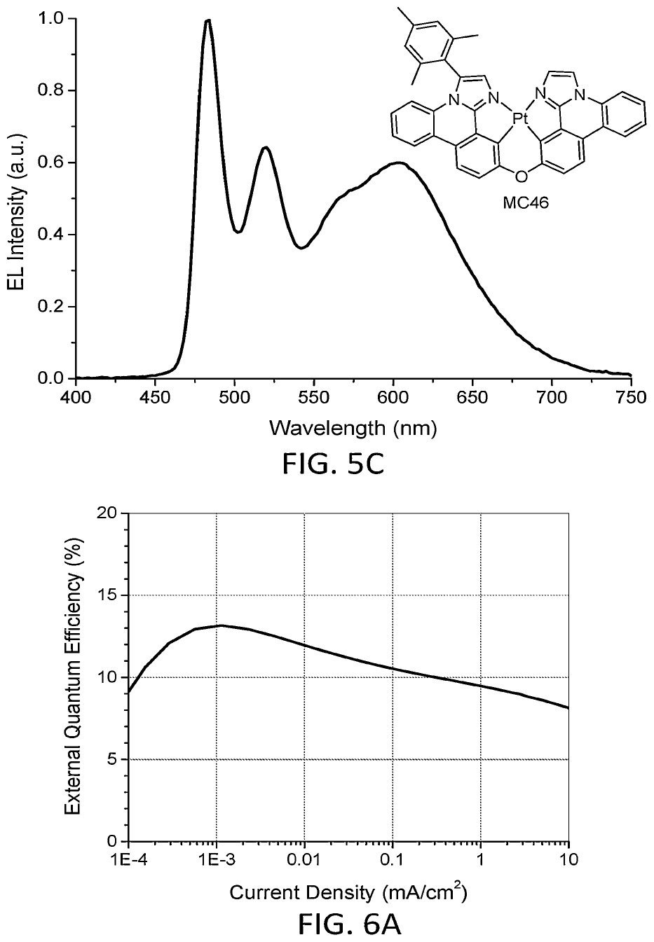

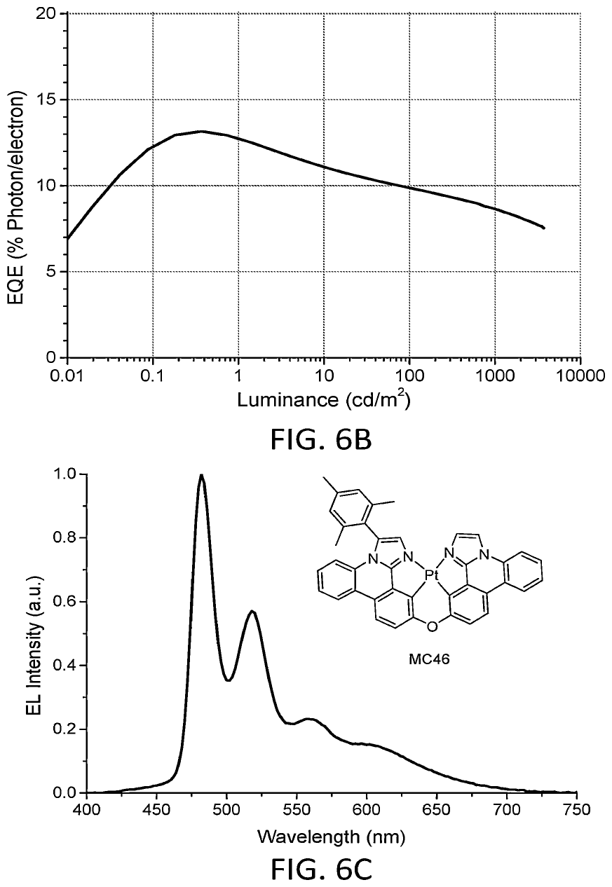

FIGS. 5A-5C show external quantum efficiency (EQE) versus luminance. EQE versus current density, and electroluminescent spectrum, respectively, for Device type 1 with MC46. Device type 1: ITO (100 nm)/HATCN (10 nm)/NPD (40 nm)/BCN34 (10 nm)/20% Pt2O2-P2M:mCBP (10 nm)/10% Pt2O2-P2M:mCBP (20 nm)/Balq (10 nm)/BPyTP (40 nm)/Liq (2 nm)/Al (100 nm). FIGS. 6A-6C show external quantum efficiency (EQE) versus luminance, EQE versus current density, and electroluminescent spectrum, respectively, for Device type 1 with MC46. Device type 2: ITO (100 nm)/HATCN (10 nm)/NPD (40 nm)/BCN34 (10 nm)/10% % Pt2O2-P2M:mCBP (20 nm)/Balq (10 nm)/BPyTP (40 nm)/Liq (2 nm)/AL (100 nm). In Device types 1 and 2: ITO:Indium tin oxide; HATCN: 1,4,5,8,9,11-hexaazatriphenylenehexacarbonitrile; HatCN:NPD: N,N′-diphenyl-N,N′-bis(1-naphthyl)-1,1′-biphenyl-4,4″-diamine; BCN34: 5,12-diphenyl-5,12-dihydroindolo[3,2-a]carbazole; Pt2O2-P2M: MC46; mCBP: 3,3-Di(9H-carbazol-9-yl)biphenyl; Balq: bis(2-methyl-8-quinolinolato)(biphenyl-4-olato)aluminum; BPyTP: (2,7-di(2,2′-bipyridin-5-yl)triphenylene); Liq: 8-Quinolinolato lithium; Al: aluminum.

### Example 47

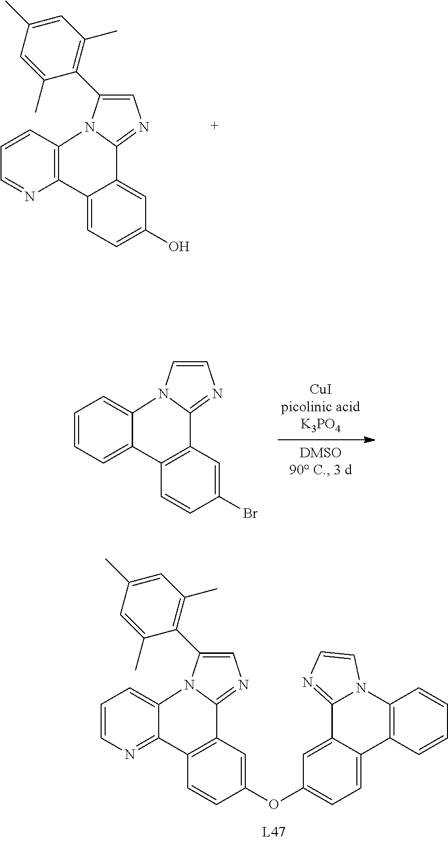 [SMILES: Cc1cc(C)c(-c2cnc3c4cc(O)ccc4c4ncccc4n23)c(C)c1 ; Brc1ccc2c3ccccc3n3ccnc3c2c1 ; "CuIpicolinic acidK3PO4" ; "DMSO90° C., 3 d" ; Cc1cc(C)c(-c2cnc3c4cc(Oc5ccc6c7ccccc7n7ccnc7c6c5)ccc4c4ncccc4n23)c(C)c1]

3-mesitylbenzo[c]imidazo[1,2-a][1,5]naphthyridin-11-ol (0.85 mmol, 1.0 eq), 11-bromoimidazo[1,2-f]phenanthridine (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L47 in 30%˜70% yield.

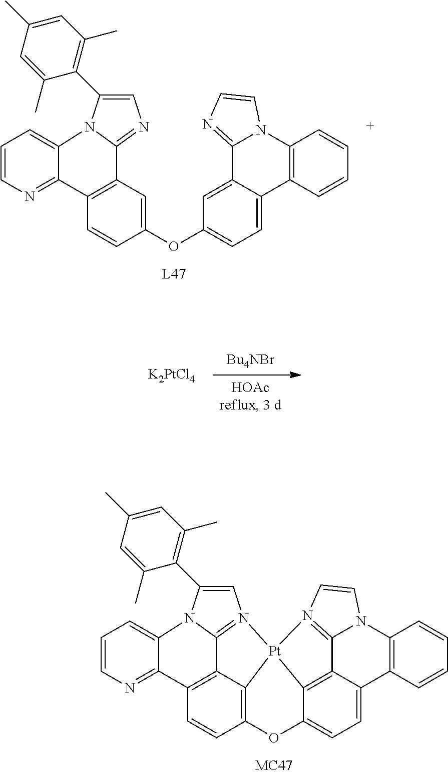

L47 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC47 in 10%˜50% yield.

### Example 48

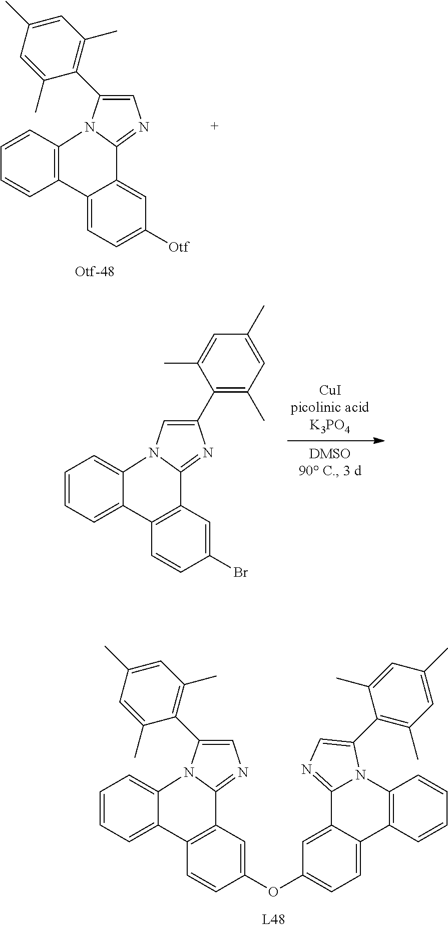

Otf-48 (0.85 mmol, 1.0 eq), 11-bromo-2-mesitylimidazo[1,2-f]phenanthridine (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L48 in 30%˜70% yield.

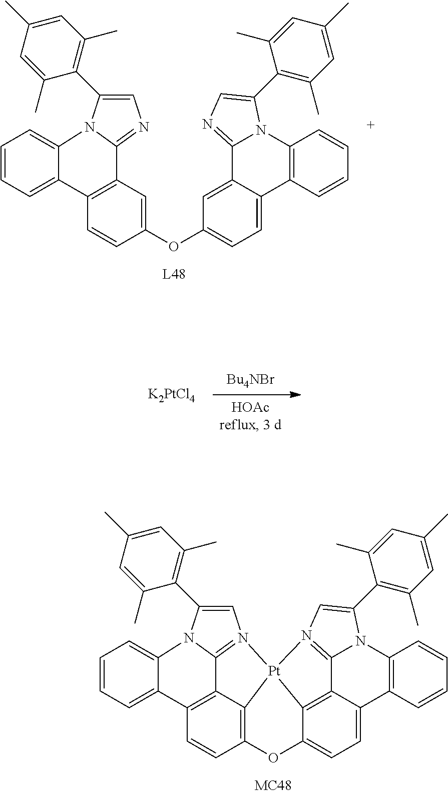

L48 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC48 in 10%˜50% yield.

### Example 49

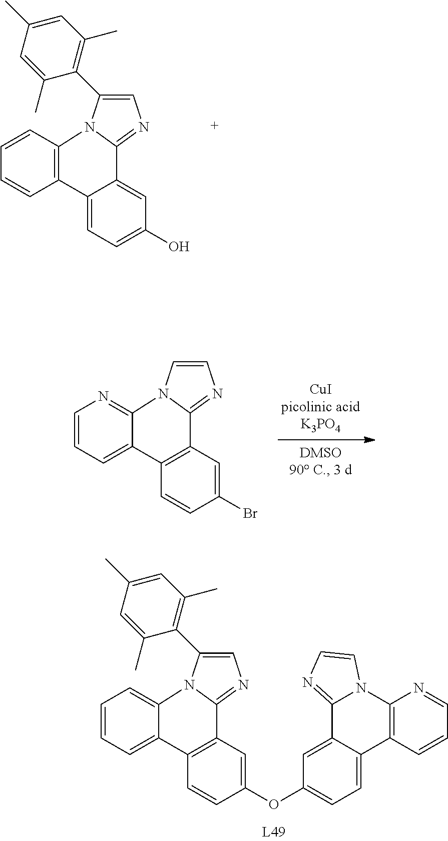 [SMILES: Cc1cc(C)c(-c2cnc3c4cc(O)ccc4c4ccccc4n23)c(C)c1 ; Brc1ccc2c3cccnc3n3ccnc3c2c1 ; "CuIpicolinic acidK3PO4" ; "DMSO90° C., 3 d" ; Cc1cc(C)c(-c2cnc3c4cc(Oc5ccc6c7cccnc7n7ccnc7c6c5)ccc4c4ccccc4n23)c(C)c1]

3-mesitylimidazo[1,2-f]phenanthridin-11-ol (0.85 mmol, 1.0 eq), 11-bromobenzo[c]imidazo[1,2-a][1,8]naphthyridine (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L49 in 30%˜70% yield.

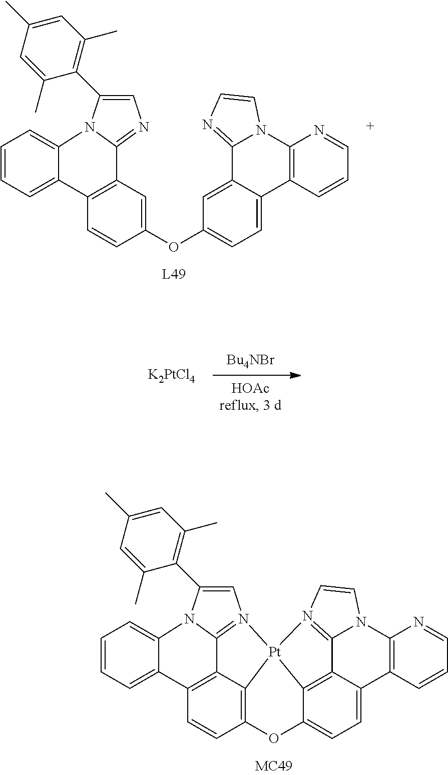

L49 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC49 in 10%˜50% yield.

### Example 50

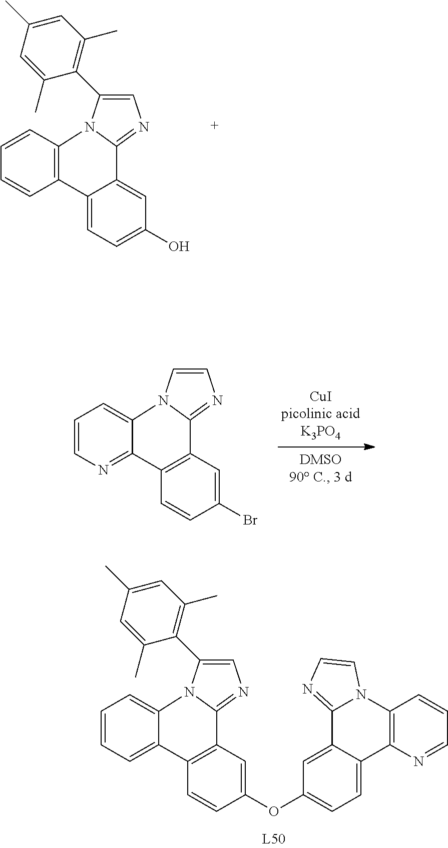 [SMILES: Cc1cc(C)c(-c2cnc3c4cc(O)ccc4c4ccccc4n23)c(C)c1 ; Brc1ccc2c(c1)c1nccn1c1cccnc21 ; "CuIpicolinic acidK3PO4" ; "DMSO90° C., 3 d" ; Cc1cc(C)c(-c2cnc3c4cc(Oc5ccc6c(c5)c5nccn5c5cccnc65)ccc4c4ccccc4n23)c(C)c1]

3-mesitylimidazo[1,2-f]phenanthridin-11-ol (0.85 mmol, 1.0 eq), 11-bromobenzo[c]imidazo[1,2-a][1,5]naphthyridine (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L50 in 30%˜70% yield.

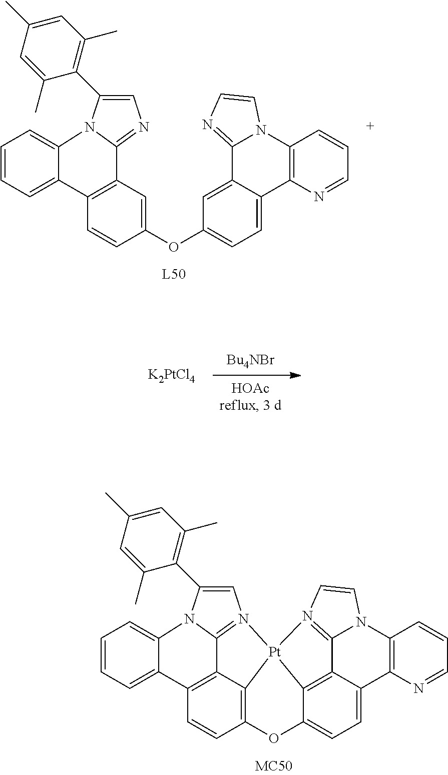

L50 (0.11 mmol, 1.0 eq), K₂PtCl4 (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC50 in 10%˜50% yield.

### Example 51

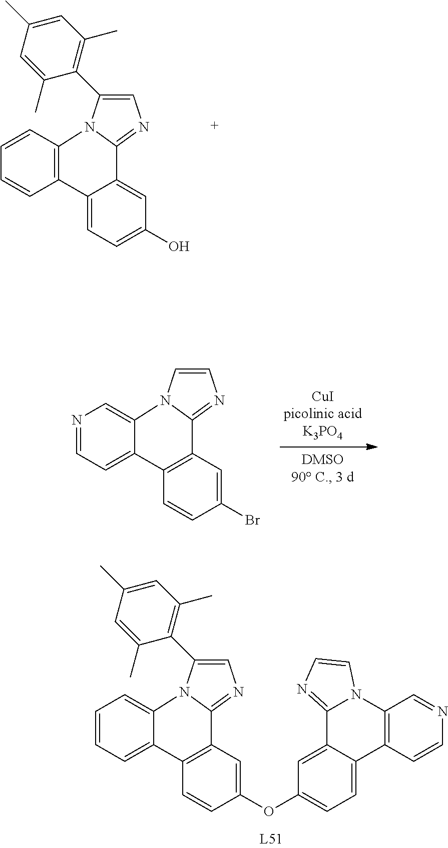 [SMILES: Cc1cc(C)c(-c2cnc3c4cc(O)ccc4c4ccccc4n23)c(C)c1 ; Brc1ccc2c3ccncc3n3ccnc3c2c1 ; "CuIpicolinic acidK3PO4" ; "DMSO90° C., 3 d" ; Cc1cc(C)c(-c2cnc3c4cc(Oc5ccc6c7ccncc7n7ccnc7c6c5)ccc4c4ccccc4n23)c(C)c1]

3-mesitylimidazo[1,2-f]phenanthridin-11-ol (0.85 mmol, 1.0 eq), 11-bromobenzo[c]imidazo[1,2-a][1,7]naphthyridine (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L51 in 30%˜70% yield.

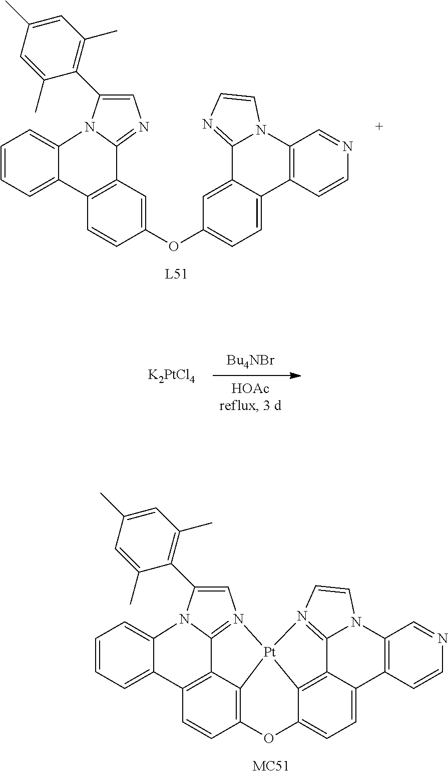

L51 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC51 in 10%˜50% yield.

### Example 52

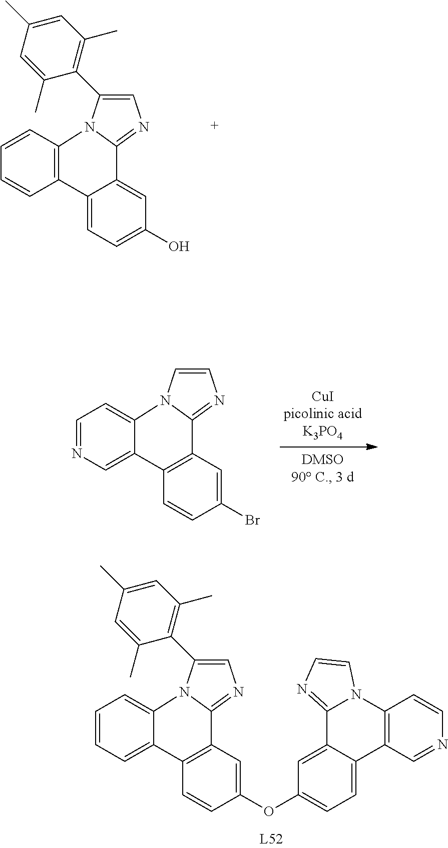 [SMILES: Cc1cc(C)c(-c2cnc3c4cc(O)ccc4c4ccccc4n23)c(C)c1 ; Brc1ccc2c3cnccc3n3ccnc3c2c1 ; "CuIpicolinic acidK3PO4" ; "DMSO90° C., 3 d" ; Cc1cc(C)c(-c2cnc3c4cc(Oc5ccc6c7cnccc7n7ccnc7c6c5)ccc4c4ccccc4n23)c(C)c1]

3-mesitylimidazo[1,2-f]phenanthridin-11-ol (0.85 mmol, 1.0 eq), 11-bromobenzo[c]imidazo[1,2-a][1,6]naphthyridine (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L52 in 30%˜70% yield.

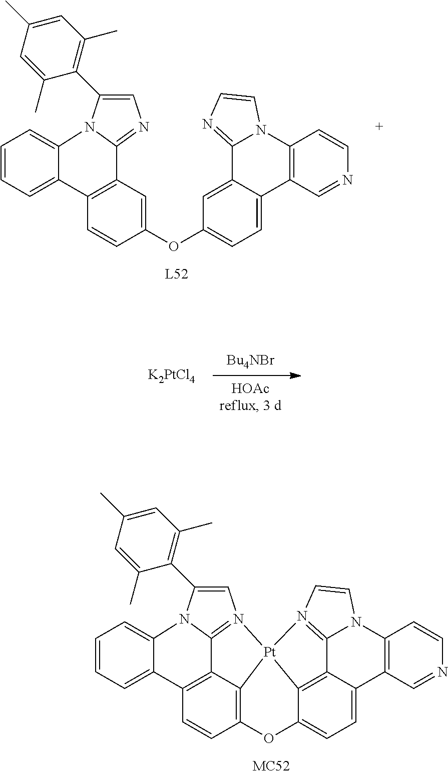

L52 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC52 in 10%˜50% yield.

### Example 53

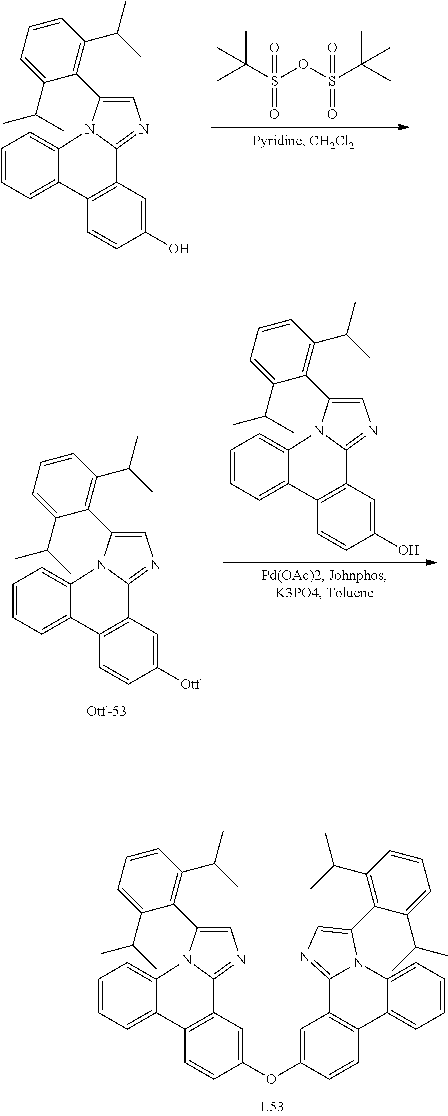

Otf-53 (0.85 mmol, 1.0 eq), 3-(2,6-diisopropylphenyl)imidazo[1,2-f]phenanthridin-11-ol (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L53 in 30%˜70% yield.

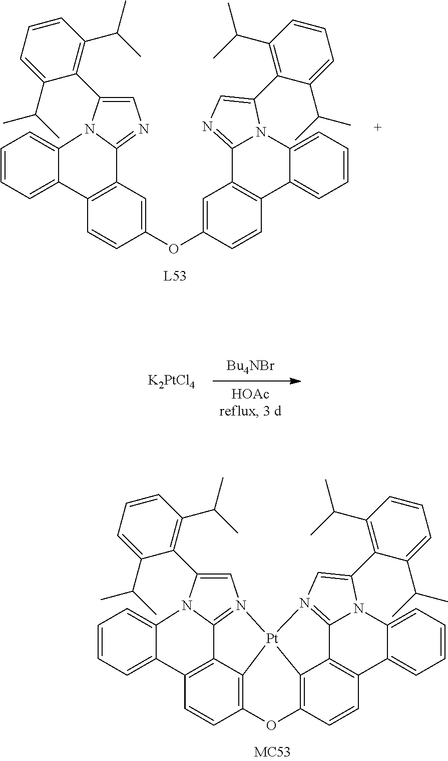

L53 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC53 in 10%˜50% yield.

### Example 54

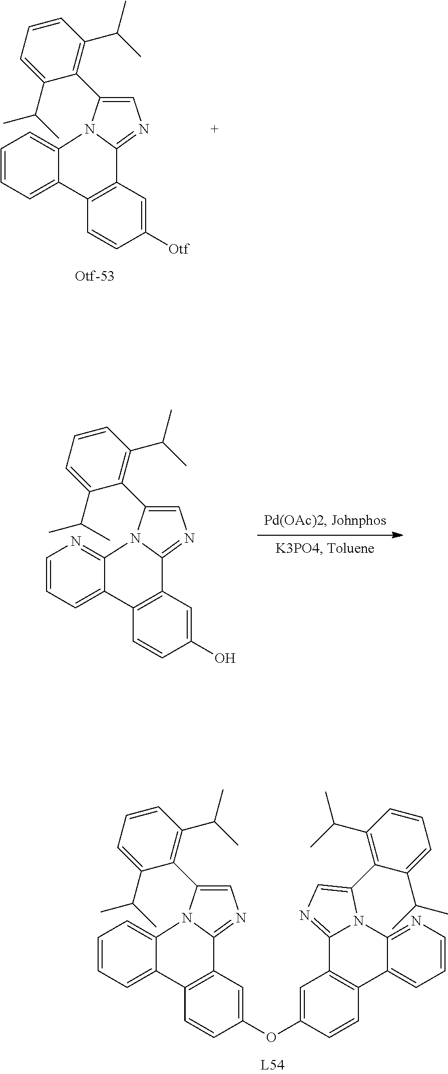

Otf-53 (0.85 mmol, 1.0 eq), 3-(2,6-diisopropylphenyl)benzo[c]imidazo[1,2-a][1,8]naphthyridin-11-ol (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L54 in 30%˜70% yield.

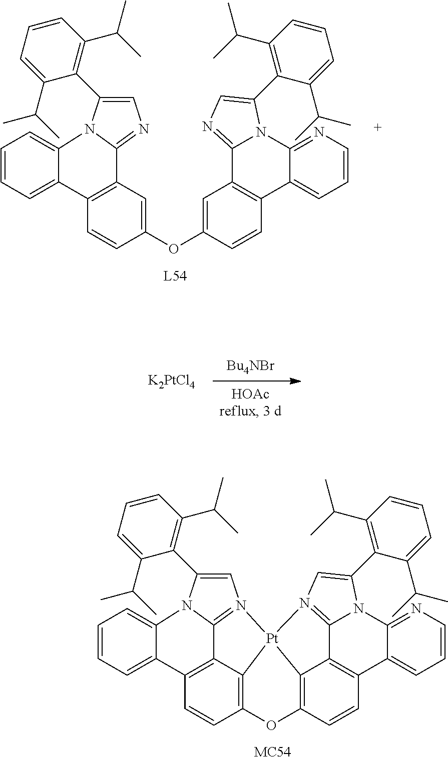

L54 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC54 in 10%˜50% yield.

### Example 55

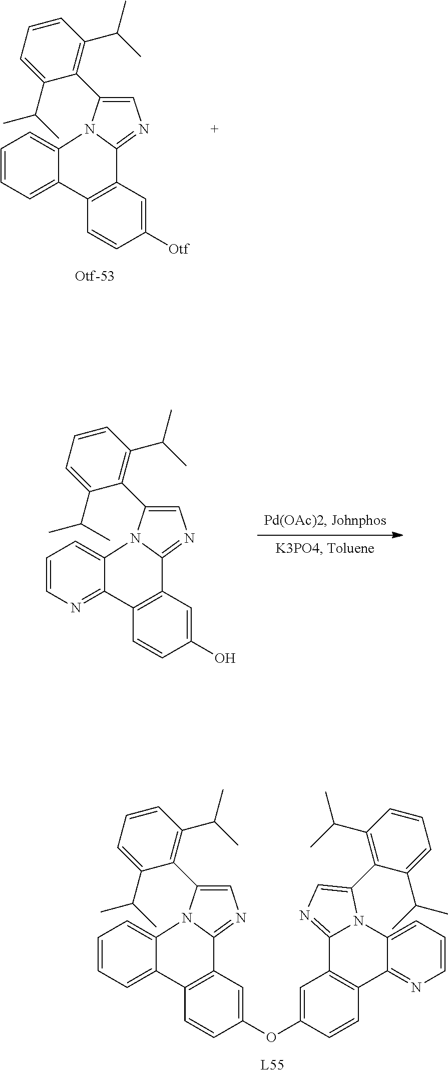

Otf-53 (0.85 mmol, 1.0 eq), 3-(2,6-diisopropylphenyl)benzo[c]imidazo[1,2-a][1,5]naphthyridin-11-ol (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L55 in 30%˜70% yield.

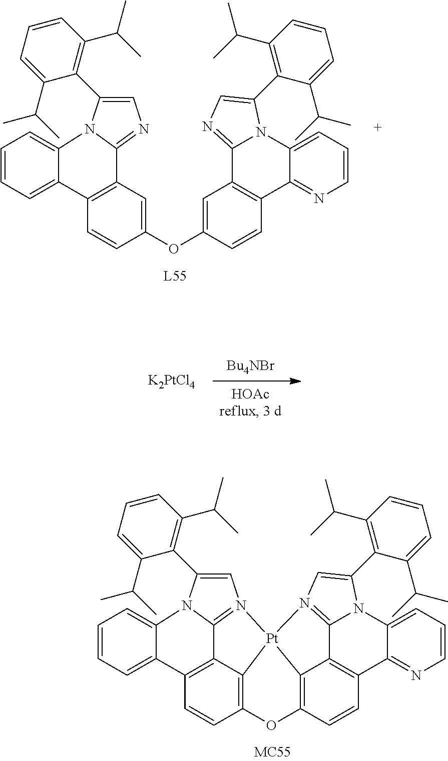

L55 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC55 in 10%˜50% yield.

### Example 56

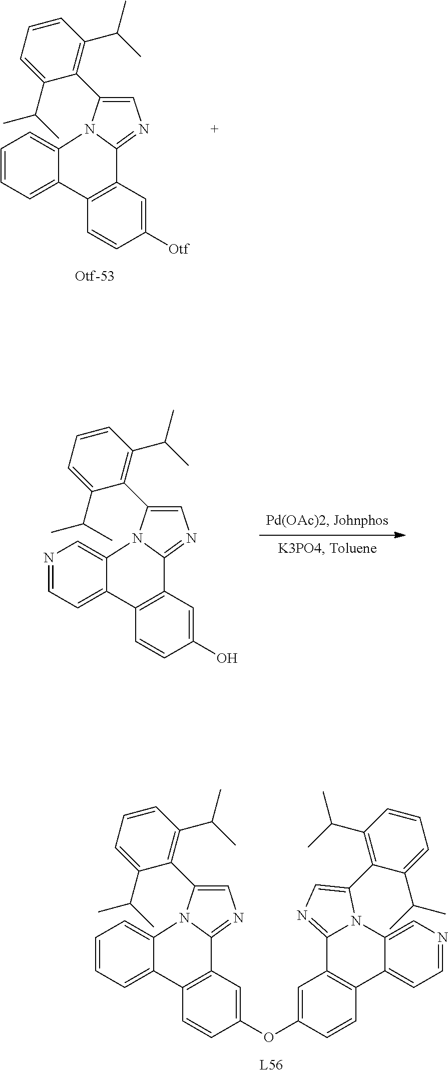

Otf-53 (0.85 mmol, 1.0 eq), 3-(2,6-diisopropylphenyl)benzo[c]imidazo[1,2-a][1,7]naphthyridin-11-ol (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L56 in 30%˜70% yield.

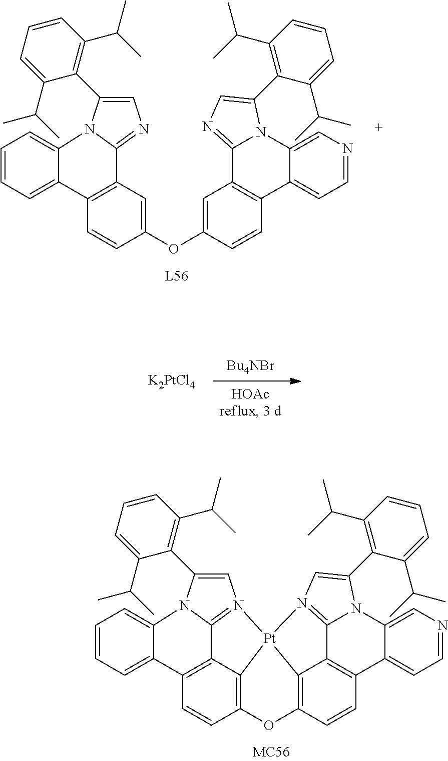

L56 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC56 in 10%˜50% yield.

### Example 57

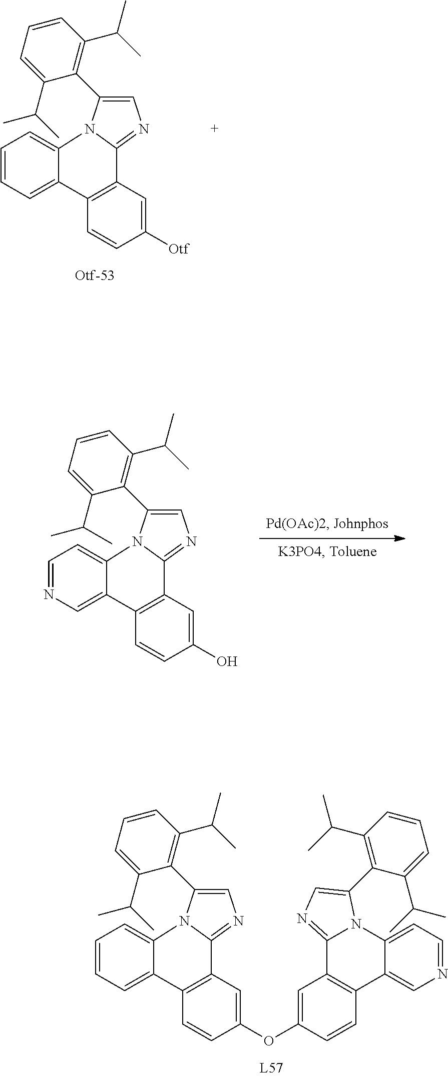

Otf-53 (0.85 mmol, 1.0 eq), 3-(2,6-diisopropylphenyl)benzo[c]imidazo[1,2-a][1,6]naphthyridin-11-ol (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L57 in 30%˜70% yield.

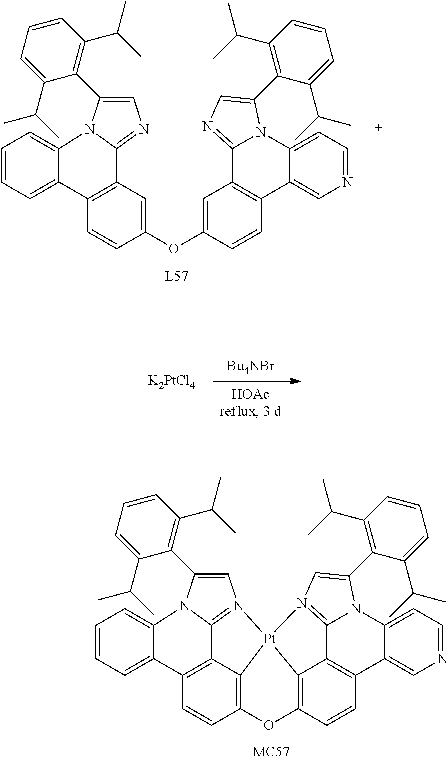

L57 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC57 in 10%˜50% yield.

### Example 58

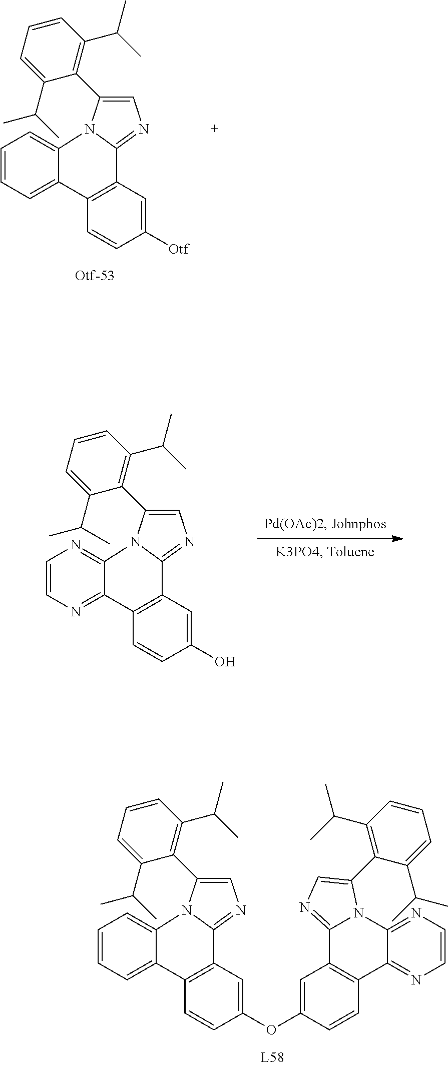

Otf-53 (0.85 mmol, 1.0 eq), 3-(2,6-diisopropylphenyl)imidazo[2,1-a]pyrazino[2,3-c]isoquinolin-11-ol (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L58 in 30%˜70% yield.

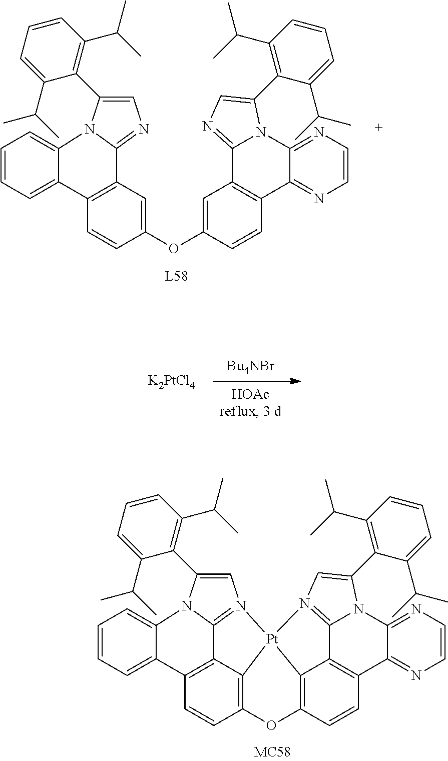

L58 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC58 in 10%˜50% yield.

### Example 59

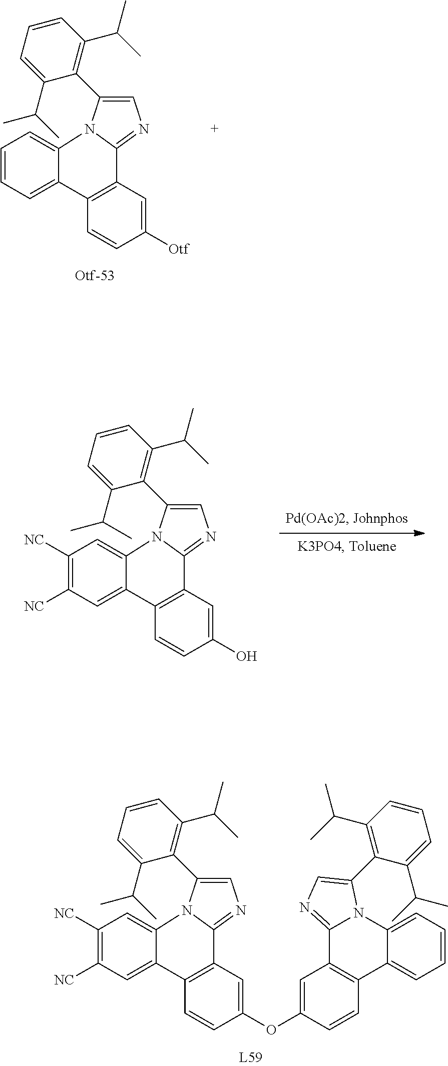

Otf-53 (0.85 mmol, 1.0 eq), 3-(2,6-diisopropylphenyl)-11-hydroxyimidazo[1,2-f]phenanthridine-6,7-dicarbonitrile (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L59 in 30%˜70% yield.

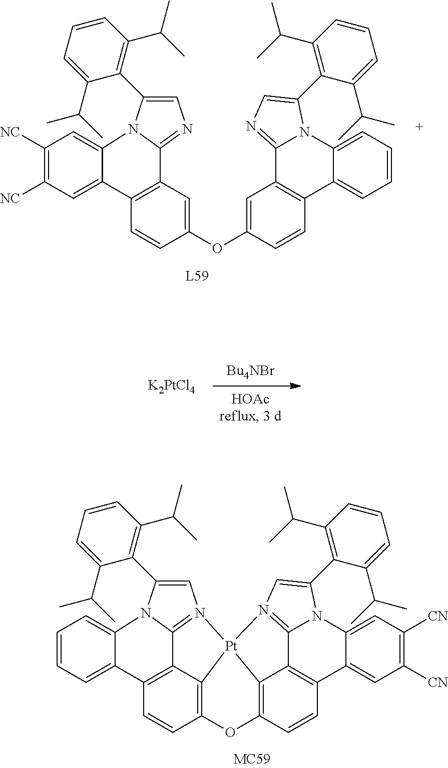

L59 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC59 in 10%˜50% yield.

### Example 60

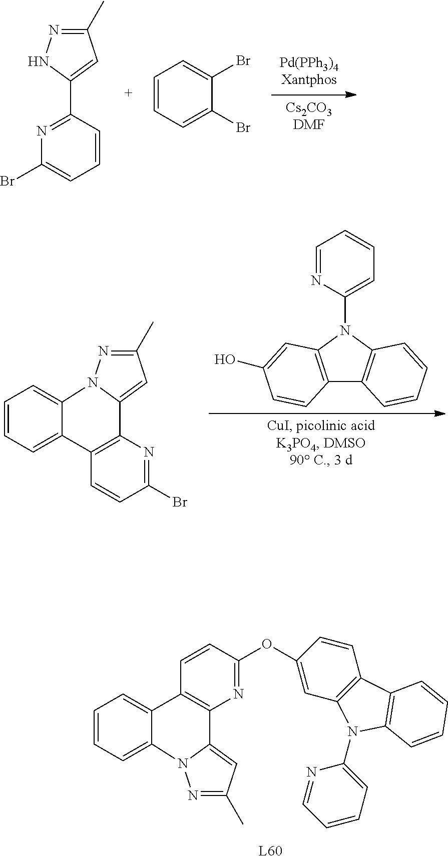

5-bromo-2-methylbenzo[f]pyrazolo[1,5-h][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L60 in 20%-70% yield.

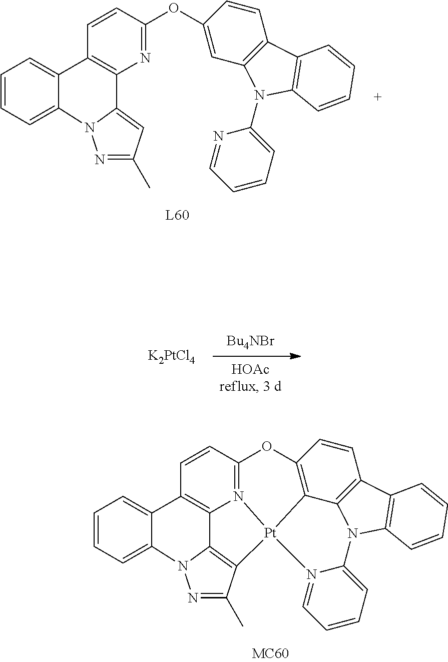

L60 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC60 in 10%˜50% yield.

### Example 61

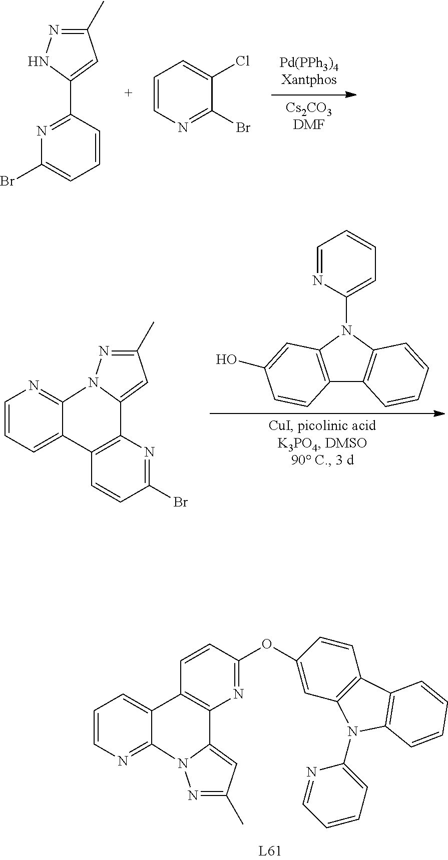

5-bromo-2-methylpyrazolo[1,5-h]pyrido[3,2-f][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L61 in 20%-70% yield.

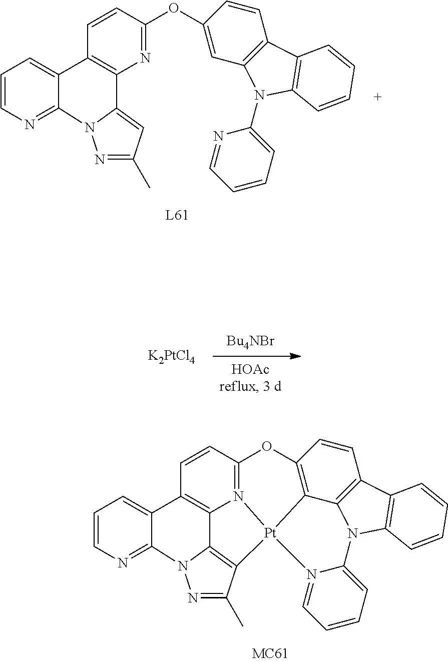

L61 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC61 in 10%˜50% yield.

### Example 62

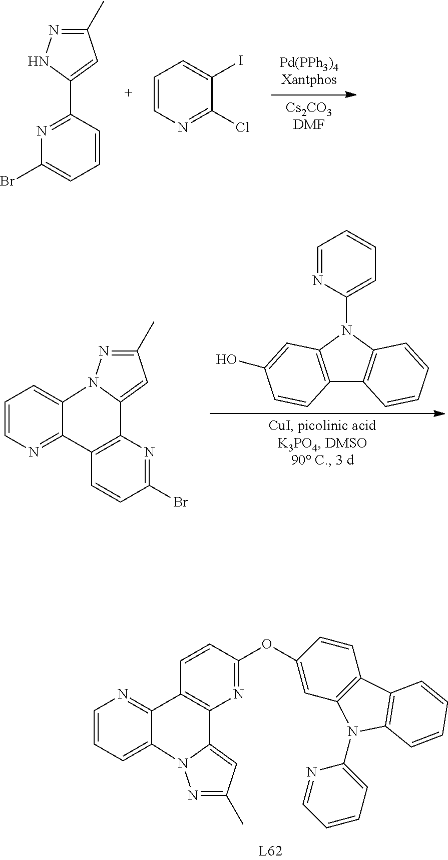

5-bromo-2-methylpyrazolo[1,5-a]pyrido[2,3-c][1,5]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L62 in 20%-70% yield.

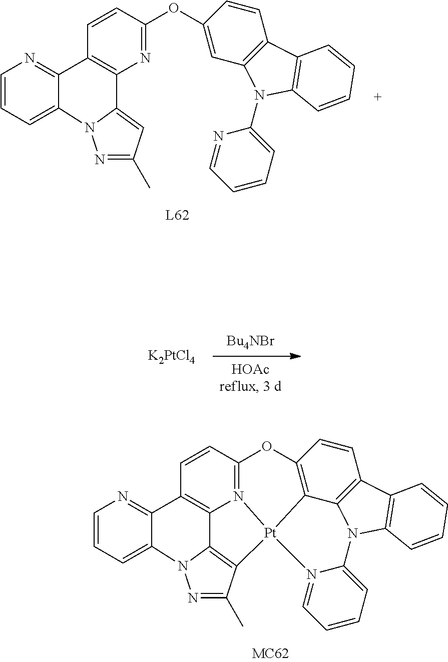

L62 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC62 in 10%˜50% yield.

### Example 63

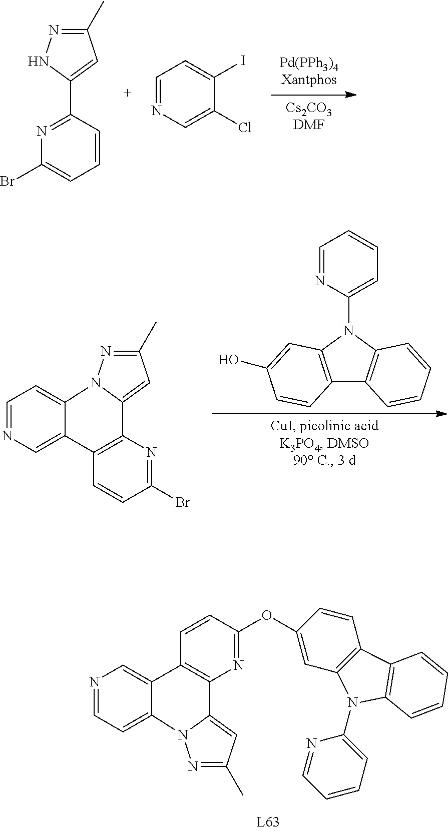

5-bromo-2-methylpyrazolo[1,5-a]pyrido[2,3-c][1,6]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L63 in 20%-70% yield.

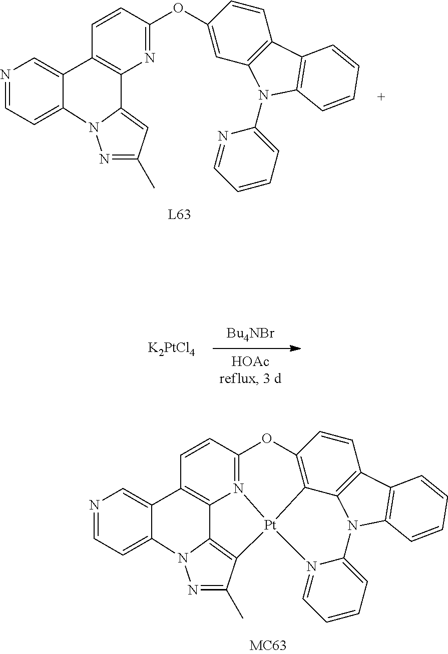

L63 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC63 in 10%˜50% yield.

### Example 64

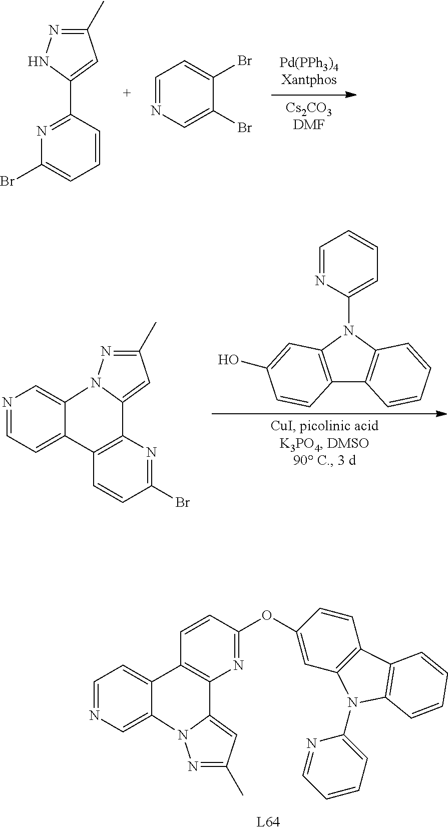

5-bromo-2-methylpyrazolo[1,5-a]pyrido[2,3-c][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L64 in 20%-70% yield.

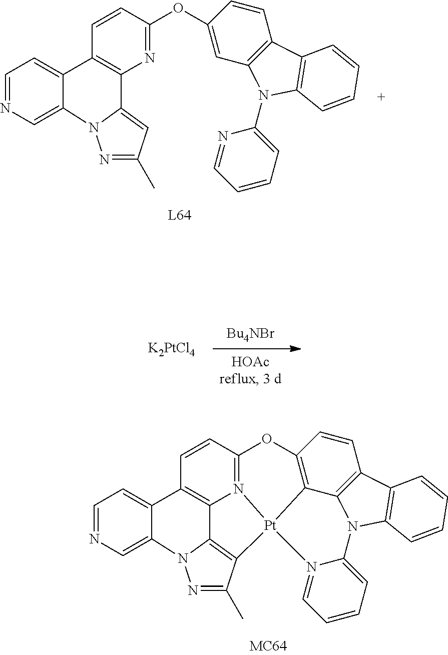

L64 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC64 in 10%˜50% yield.

### Example 65

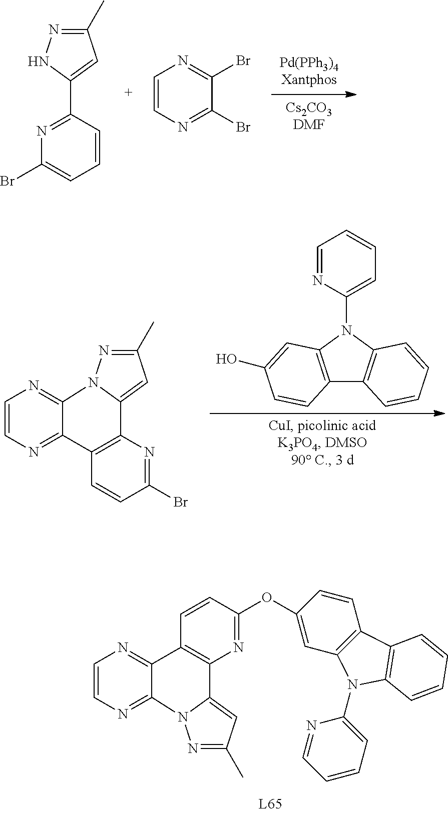

10-bromo-7-methylpyrazino[2,3-f]pyrazolo[1,5-h][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L65 in 20%-70% yield.

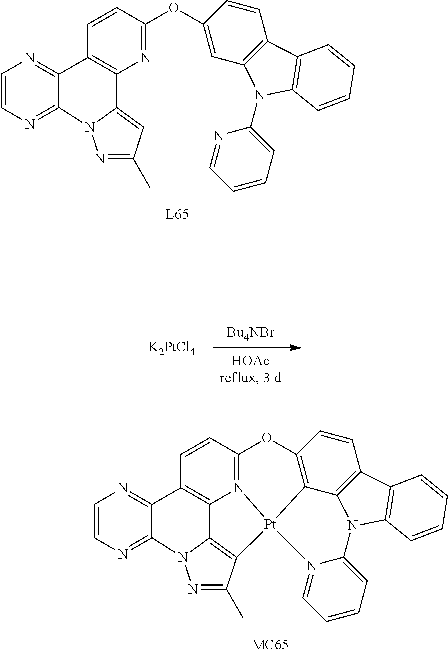

L65 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC65 in 10%˜50% yield.

### Example 66

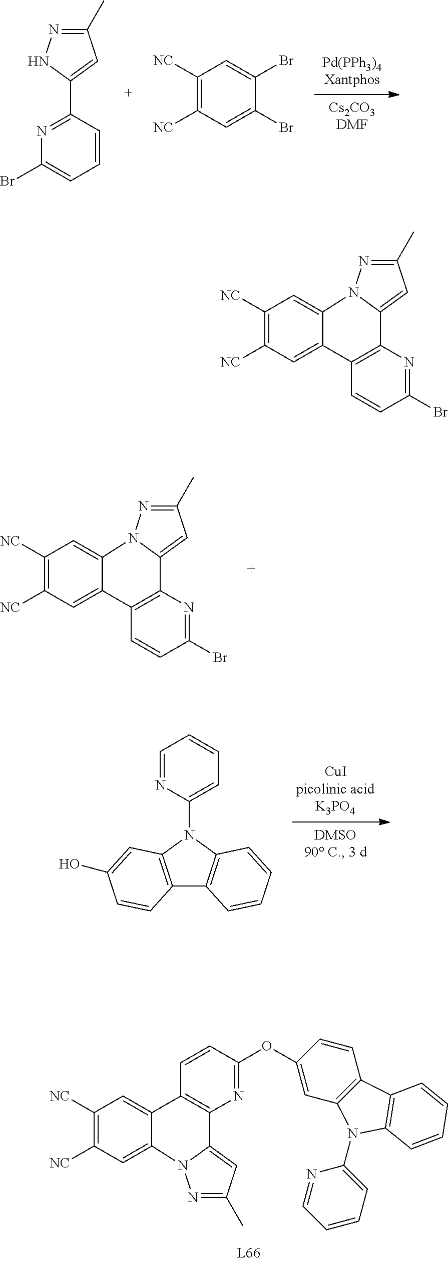

5-bromo-2-methylbenzo[f]pyrazolo[1,5-h][1,7]naphthyridine-9,10-dicarbonitrile (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L66 in 20%-70% yield.

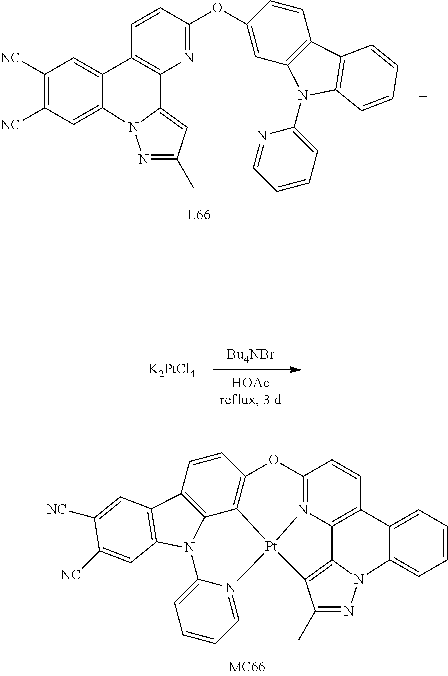

L66 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC66 in 10%˜50% yield.

### Example 6

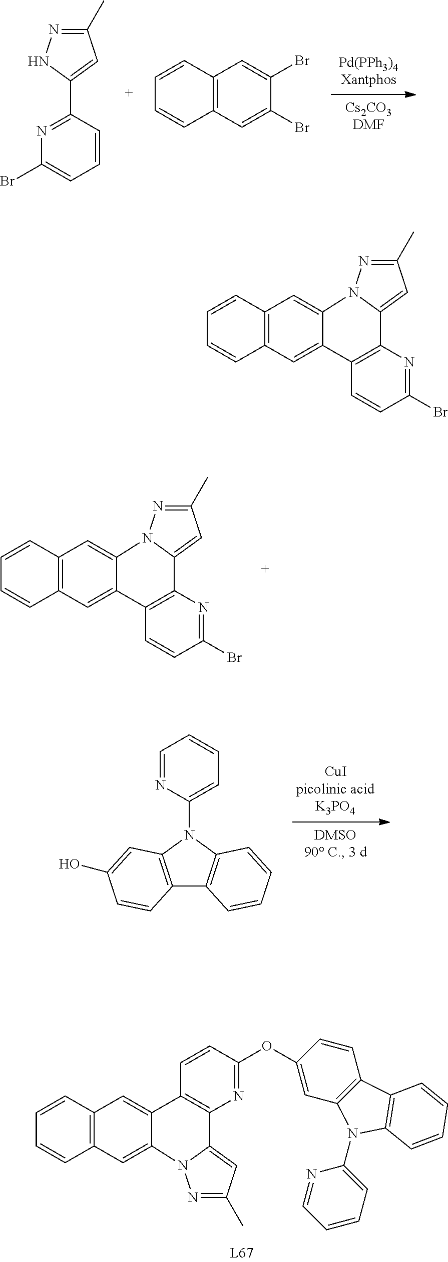

5-bromo-2-methylnaphtho[2,3-f]pyrazolo[1,5-h][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L67 in 20%-70% yield.

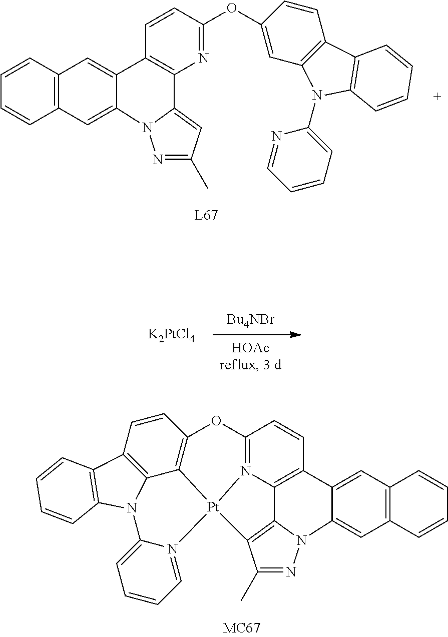

L67 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC67 in 10%˜50% yield.

### Example 68

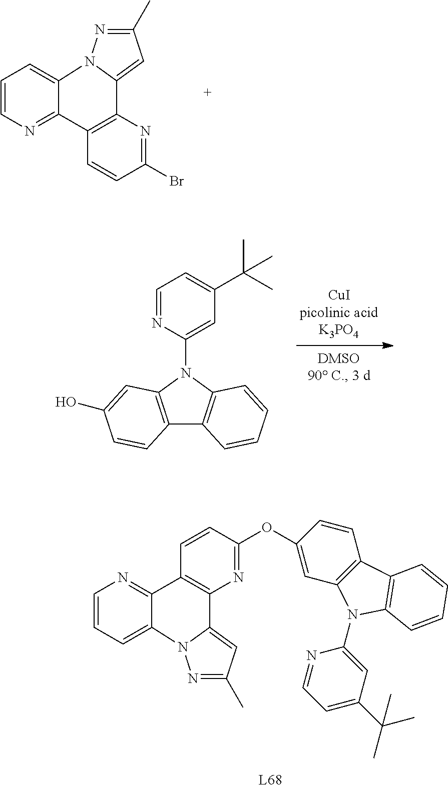 [SMILES: Cc1cc2c3nc(Br)ccc3c3ncccc3n2n1 ; CC(C)(C)c1ccnc(-n2c3ccccc3c3ccc(O)cc32)c1 ; "CuIpicolinic acidK3PO4" ; "DMSO90° C., 3 d" ; Cc1cc2c3nc(Oc4ccc5c6ccccc6n(-c6cc(C(C)(C)C)ccn6)c5c4)ccc3c3ncccc3n2n1]

5-bromo-2-methylpyrazolo[1,5-a]pyrido[2,3-c][1,5]naphthyridine (0.35 mmol, 1.0 eq), 2-bromo-9-(4-(tert-butyl)pyridin-2-yl)-9H-carbazole (159 mg, 0.42 mmol, 1.2 eq), CuI (13 mg, 0.07 mmol, 0.2 eq), picolinic acid (9 mg, 0.07 mmol, 0.2 eq) and K₃PO₄ (149 mg, 0.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L68 in 30%˜70% yield.

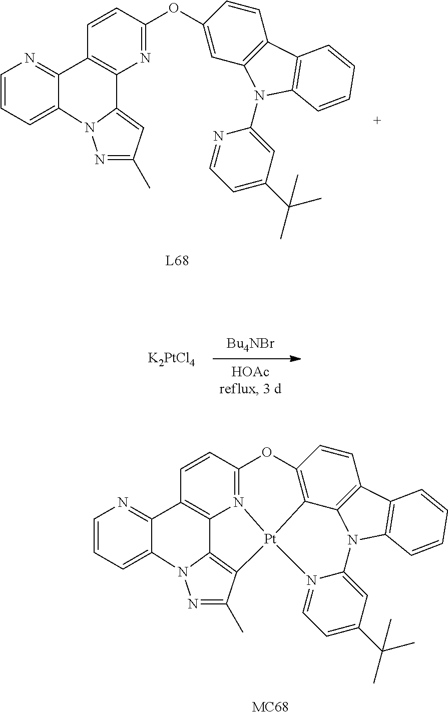

L68 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC68 in 10%˜50% yield.

### Example 69

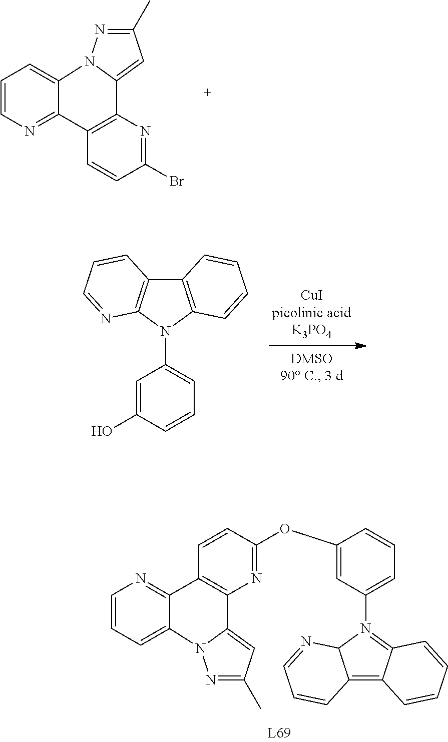

5-bromo-2-methylpyrazolo[1,5-a]pyrido[2,3-c][1,5]naphthyridine (0.85 mmol, 1.0 eq), 3-(9H-pyrido[2,3-b]indol-9-yl)phenol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L69 in 20%-70% yield.

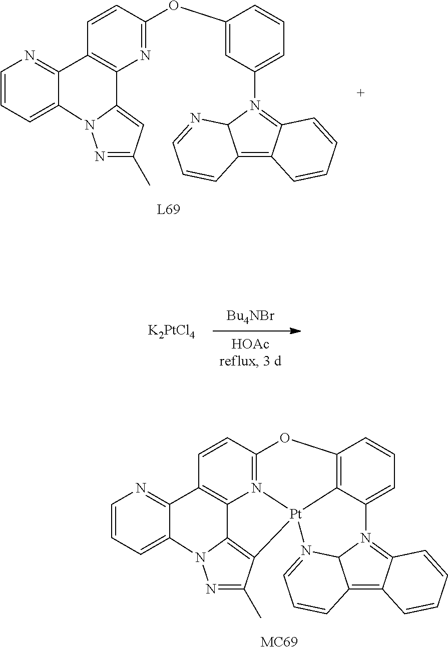

L69 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC69 in 10%˜50% yield.

### Example 70

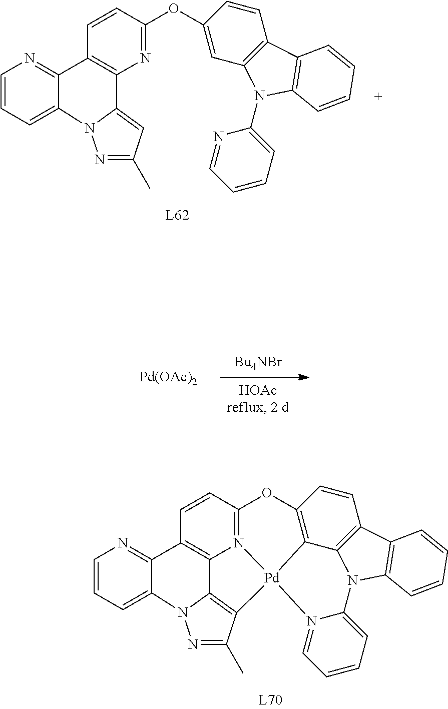

L62 (0.11 mmol, 1.0 eq), Pd(OAc)₂ (27 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC70 in 10%˜50% yield.

### Example 71

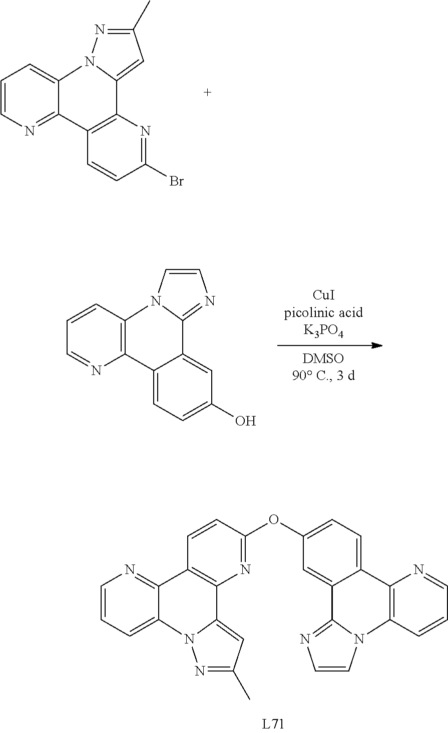 [SMILES: Cc1cc2c3nc(Br)ccc3c3ncccc3n2n1 ; Oc1ccc2c(c1)c1nccn1c1cccnc21 ; "CuIpicolinic acidK3PO4" ; "DMSO90° C., 3 d" ; Cc1cc2c3nc(Oc4ccc5c(c4)c4nccn4c4cccnc54)ccc3c3ncccc3n2n1]

5-bromo-2-methylpyrazolo[1,5-a]pyrido[2,3-c][1,5]naphthyridine (0.85 mmol, 1.0 eq), benzo[c]imidazo[1,2-a][1,5]naphthyridin-11-ol (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L71 in 20%˜70% yield.

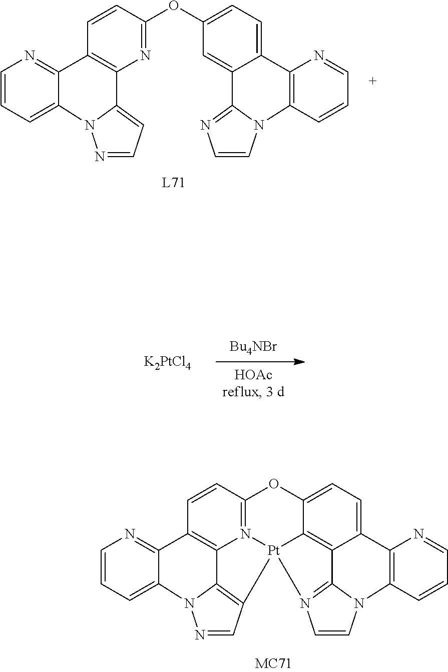

L71 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC71 in 10%˜50% yield.

### Example 72

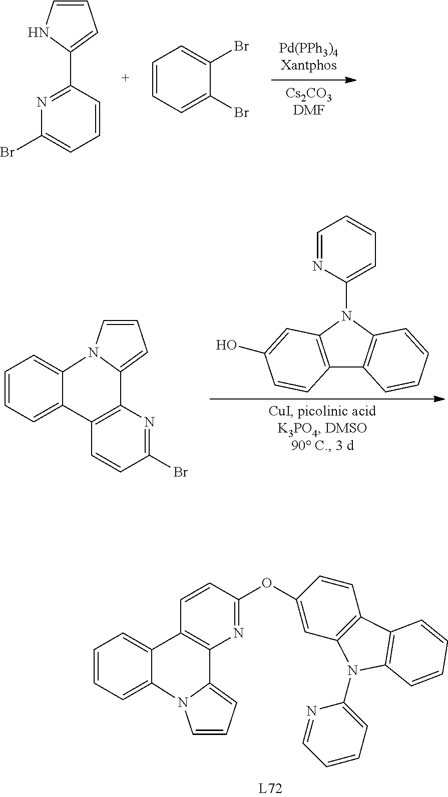

2-bromobenzo[f]pyrrolo[1,2-h][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃P04 (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L72 in 20%-70% yield.

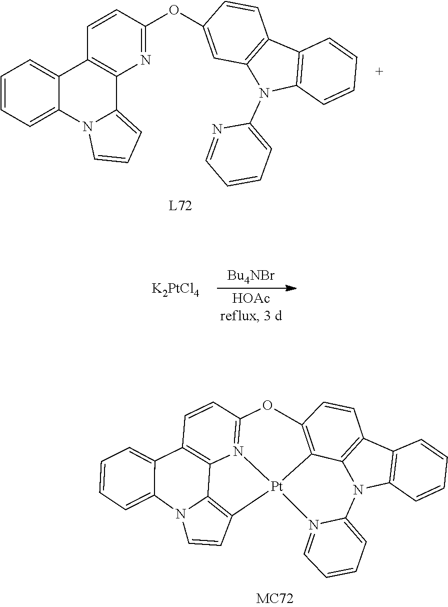

L72 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC72 in 10%˜50% yield.

### Example 73

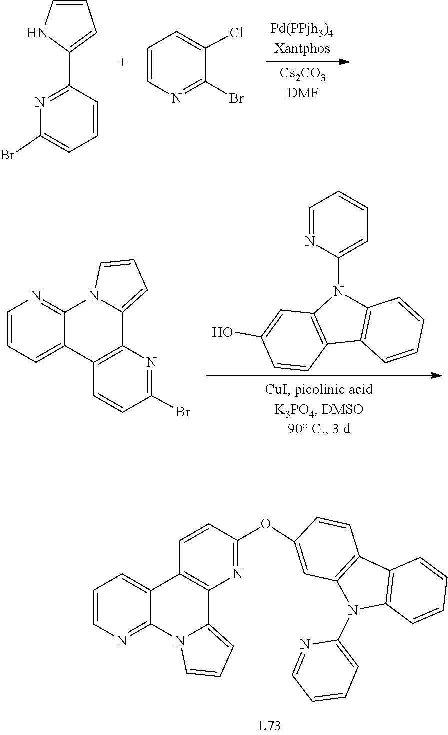 [SMILES: Brc1cccc(-c2ccc[nH]2)n1 ; Clc1cccnc1Br ; Brc1ccc2c3cccnc3n3cccc3c2n1 ; Oc1ccc2c3ccccc3n(-c3ccccn3)c2c1 ; c1ccc(-n2c3ccccc3c3ccc(Oc4ccc5c6cccnc6n6cccc6c5n4)cc32)nc1]

2-bromopyrido[3,2-f]pyrrolo[1,2-h][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L73 in 20%-70% yield.

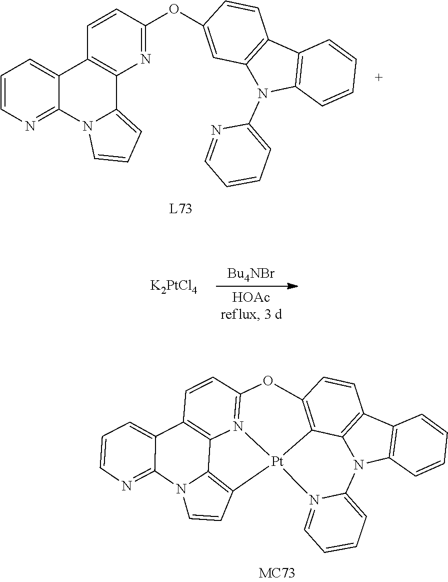

L73 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC73 in 10%˜50% yield.

### Example 74

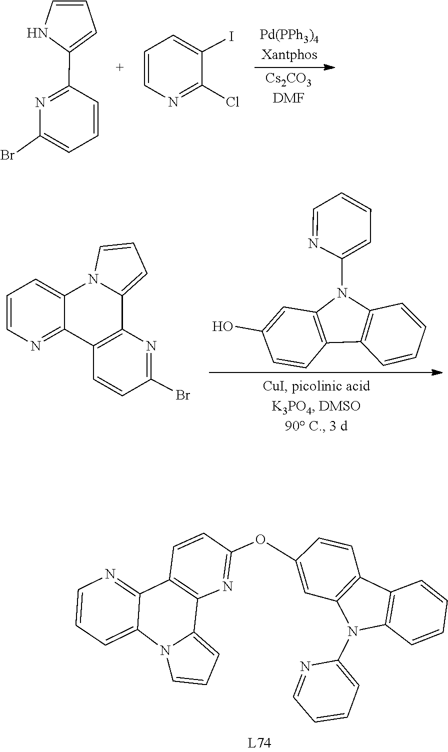 [SMILES: Brc1cccc(-c2ccc[nH]2)n1 ; Clc1ncccc1I ; Brc1ccc2c3ncccc3n3cccc3c2n1 ; Oc1ccc2c3ccccc3n(-c3ccccn3)c2c1 ; c1ccc(-n2c3ccccc3c3ccc(Oc4ccc5c6ncccc6n6cccc6c5n4)cc32)nc1]

2-bromopyrido[2,3-c]pyrrolo[1,2-a][1,5]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L74 in 20%-70% yield.

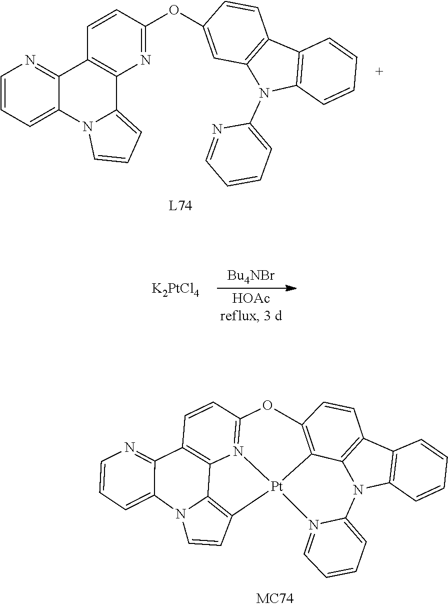

L74 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC74 in 10%˜50% yield.

### Example 75

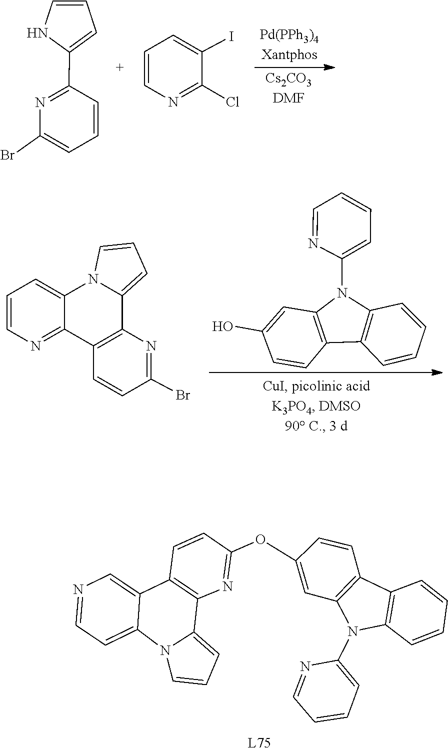 [SMILES: Brc1cccc(-c2ccc[nH]2)n1 ; Clc1ncccc1I ; Brc1ccc2c3ncccc3n3cccc3c2n1 ; Oc1ccc2c3ccccc3n(-c3ccccn3)c2c1 ; c1ccc(-n2c3ccccc3c3ccc(Oc4ccc5c6cnccc6n6cccc6c5n4)cc32)nc1]

2-bromopyrido[2,3-c]pyrrolo[1,2-a][1,6]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L75 in 20%-70% yield.

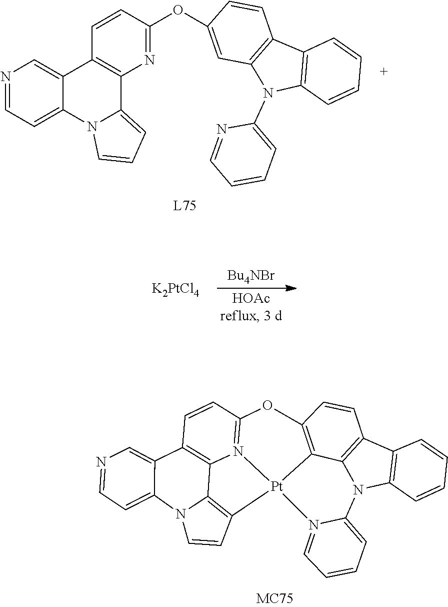

L75 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC75 in 10%˜50% yield.

### Example 76

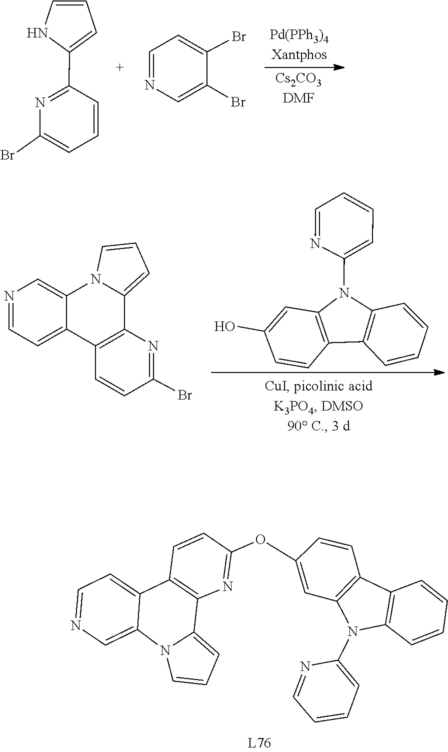 [SMILES: Brc1cccc(-c2ccc[nH]2)n1 ; Brc1ccncc1Br ; Brc1ccc2c3ccncc3n3cccc3c2n1 ; Oc1ccc2c3ccccc3n(-c3ccccn3)c2c1 ; c1ccc(-n2c3ccccc3c3ccc(Oc4ccc5c6ccncc6n6cccc6c5n4)cc32)nc1]

2-bromopyrido[2,3-c]pyrrolo[1,2-a][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L76 in 20%-70% yield.

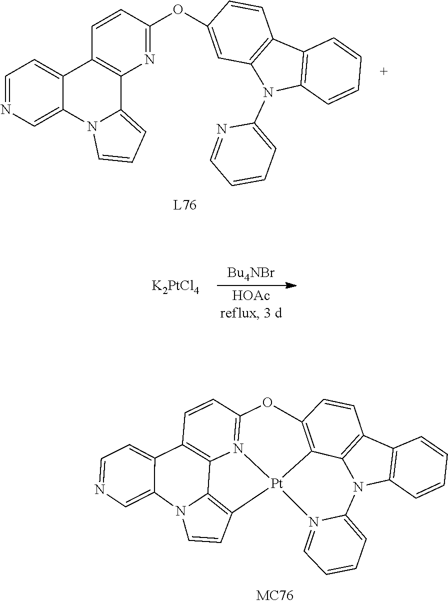

L76 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC76 in 10%-50% yield.

### Example 77

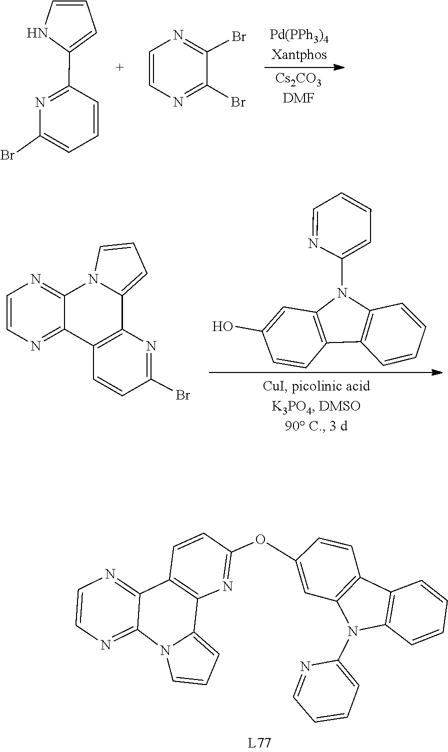 [SMILES: Brc1cccc(-c2ccc[nH]2)n1 ; Brc1nccnc1Br ; Brc1ccc2c(n1)c1cccn1c1nccnc21 ; Oc1ccc2c3ccccc3n(-c3ccccn3)c2c1 ; c1ccc(-n2c3ccccc3c3ccc(Oc4ccc5c(n4)c4cccn4c4nccnc54)cc32)nc1]

10-bromopyrazino[2,3-f]pyrrolo[1,2-h][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L77 in 20%-70% yield.

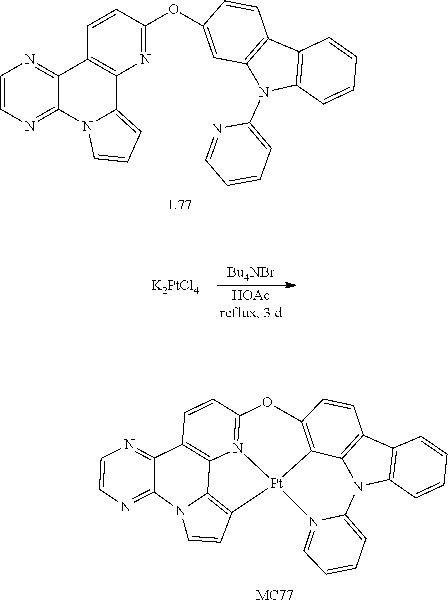

L77 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC77 in 10%˜50% yield.

### Example 78

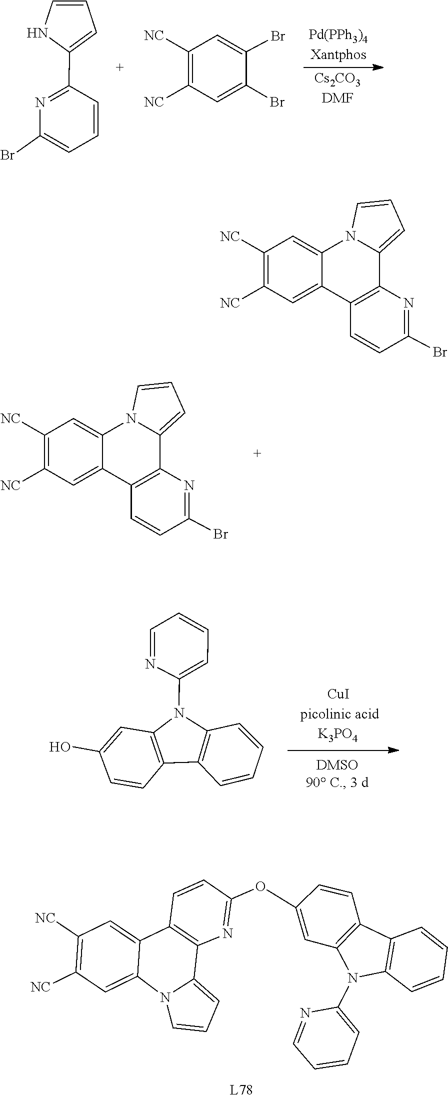 [SMILES: Brc1cccc(-c2ccc[nH]2)n1 ; N#Cc1cc(Br)c(Br)cc1C#N ; N#Cc1cc2c3ccc(Br)nc3c3cccn3c2cc1C#N ; N#Cc1cc2c3ccc(Br)nc3c3cccn3c2cc1C#N ; Oc1ccc2c3ccccc3n(-c3ccccn3)c2c1 ; N#Cc1cc2c3ccc(Oc4ccc5c6ccccc6n(-c6ccccn6)c5c4)nc3c3cccn3c2cc1C#N]

2-bromobenzo[f]pyrrolo[1,2-h][1,7]naphthyridine-6,7-dicarbonitrile (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L78 in 20%-70% yield.

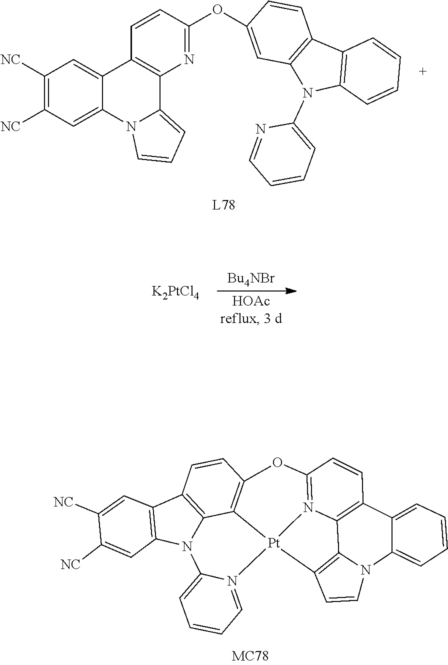

L78 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC78 in 10%˜50% yield.

### Example 79

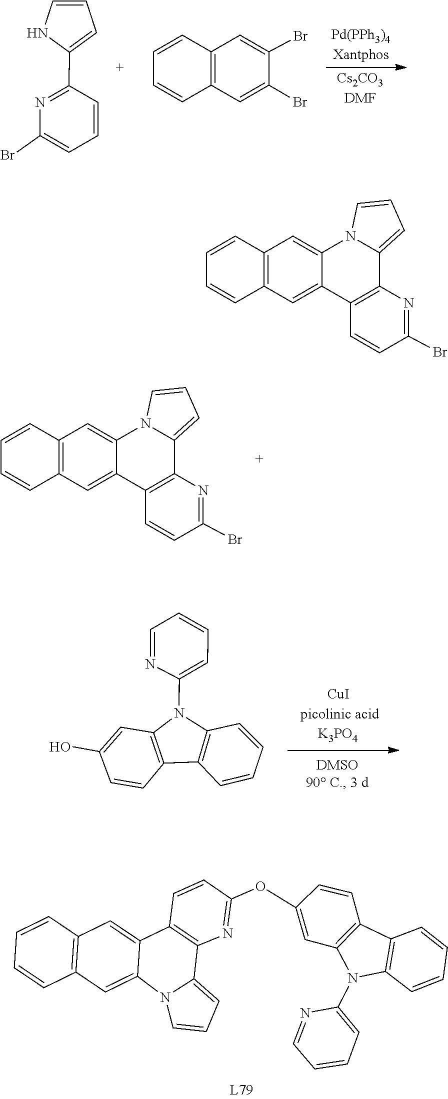 [SMILES: Brc1cccc(-c2ccc[nH]2)n1 ; Brc1cc2ccccc2cc1Br ; Brc1ccc2c3cc4ccccc4cc3n3cccc3c2n1 ; Brc1ccc2c3cc4ccccc4cc3n3cccc3c2n1 ; Oc1ccc2c3ccccc3n(-c3ccccn3)c2c1 ; c1ccc(-n2c3ccccc3c3ccc(Oc4ccc5c6cc7ccccc7cc6n6cccc6c5n4)cc32)nc1]

3-bromonaphtho[2,3-f]pyrrolo[1,2-h][1,7]naphthyridine (0.85 mmol, 1.0 eq), 9-(pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L79 in 20%-70% yield.

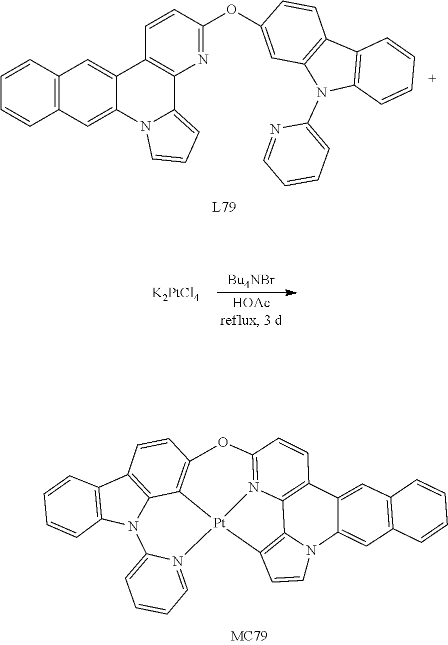

L79 (0.11 mmol, 1.0 eq), K₂PtCL₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC79 in 10%˜50% yield.

### Example 80

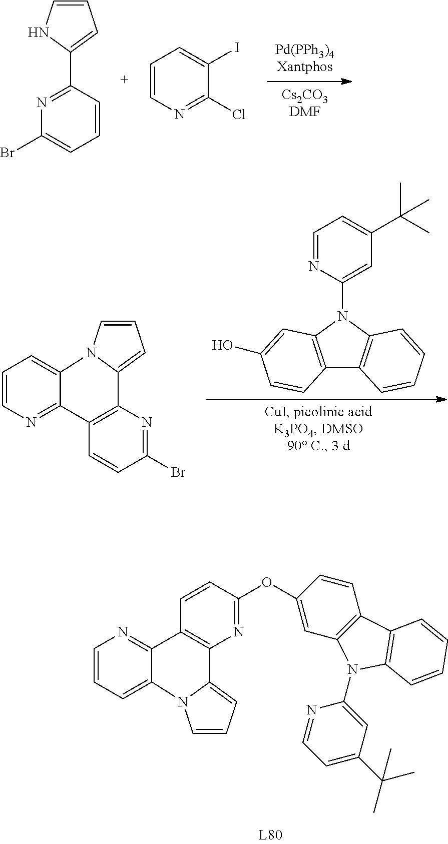

2-bromopyrido[2,3-c]pyrrolo[1,2-a][1,5]naphthyridine (0.85 mmol, 1.0 eq), 9-(4-(tert-butyl)pyridin-2-yl)-9H-carbazol-2-ol (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L80 in 20%-70% yield.

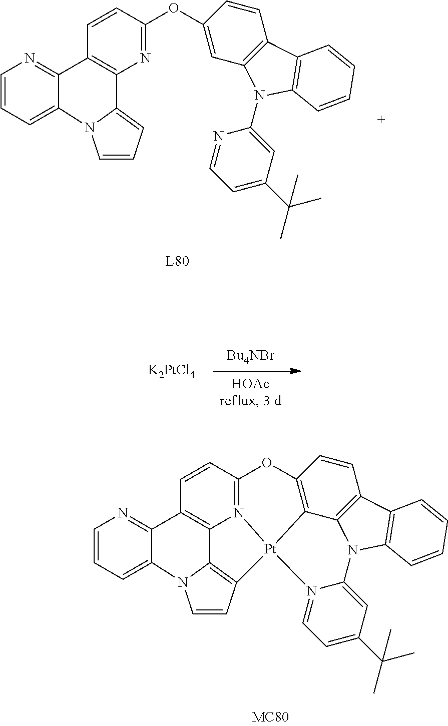

L80 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC80 in 10%˜50% yield.

### Example 81

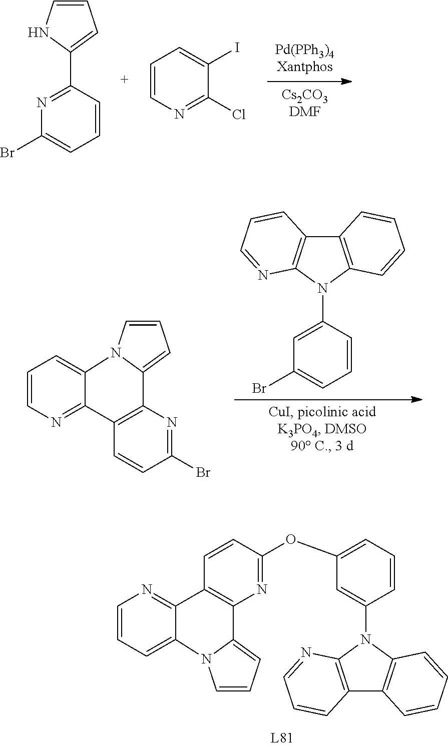

2-bromopyrido[2,3-c]pyrrolo[1,2-a][1,5]naphthyridine (0.85 mmol, 1.0 eq), 9-(3-bromophenyl)-9H-pyrido[2,3-b]indole (359 mg, 1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 100° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L81 in 20%-70% yield.

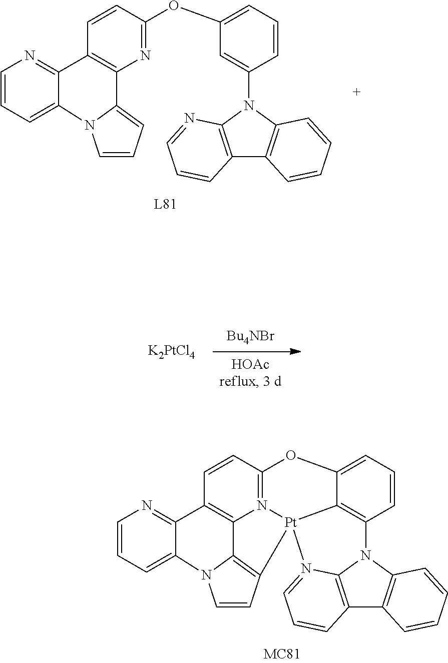

L81 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC81 in 10%˜50% yield.

### Example 82

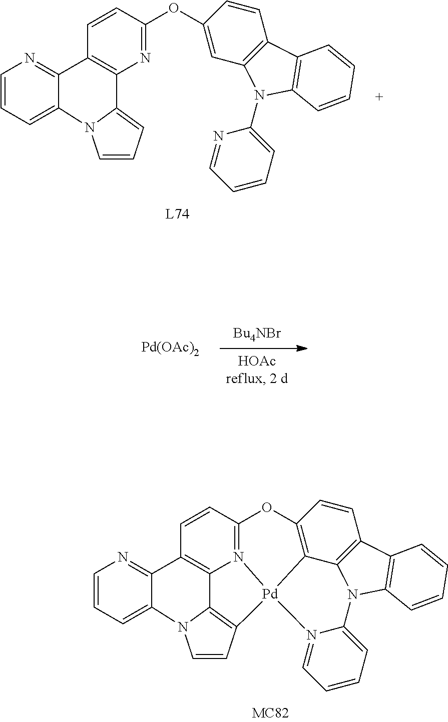

L74 (0.11 mmol, 1.0 eq), Pd(OAc)₂ (0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC82 in 10%˜50% yield.

### Example 83

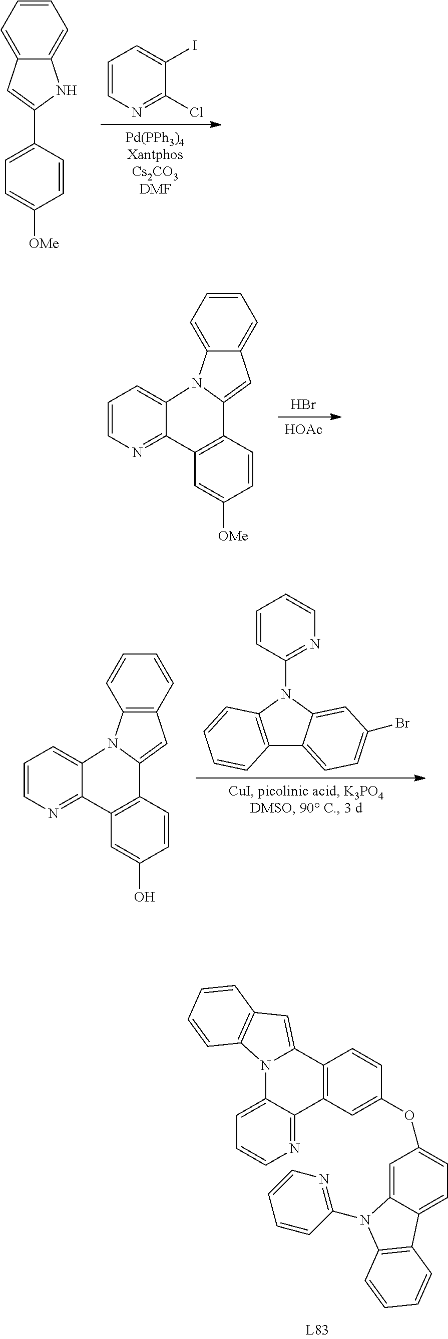

Benzo[c]indolo[1,2-a][1,5]naphthyridin-6-ol (1 mmol, 1.0 eq), 2-bromo-9-(pyridin-2-yl)-9H-carbazole (388 mg, 1.2 mmol, 1.2 eq). CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L83 as a white solid in 65% yield.

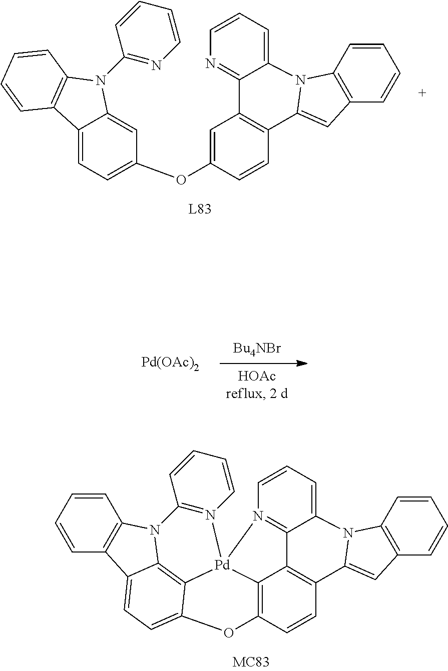

L83 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC83 as a white solid in 35% yield.

### Example 84

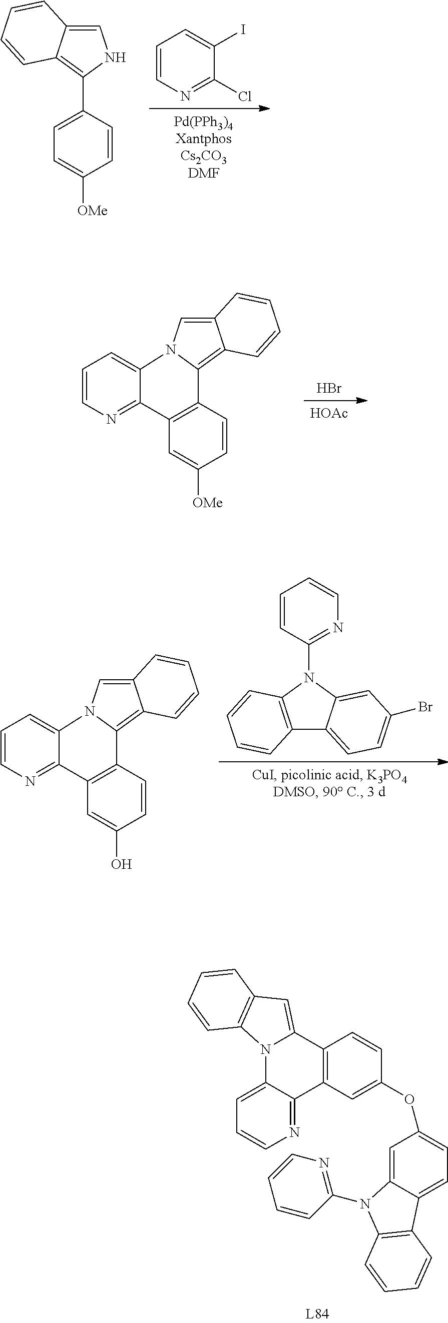

Benzo[c]isoindolo[2,1-a][1,5]naphthyridin-6-ol (1 mmol, 1.0 eq), 2-bromo-9-(pyridin-2-yl)-9H-carbazole (388 mg, 1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L84 as a white solid in 65% yield.

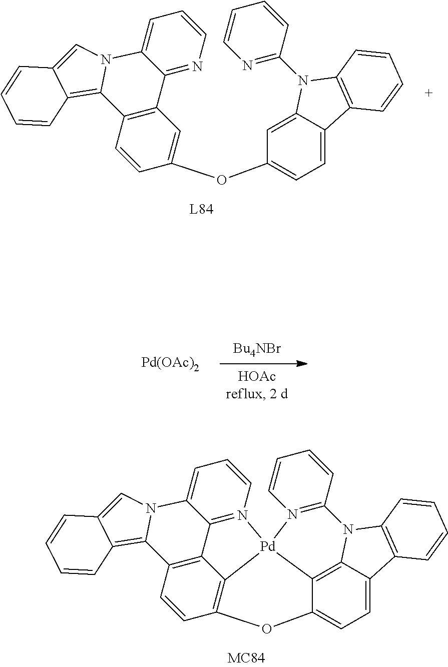

L84 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC84 as a white solid in 35% yield.

### Example 85

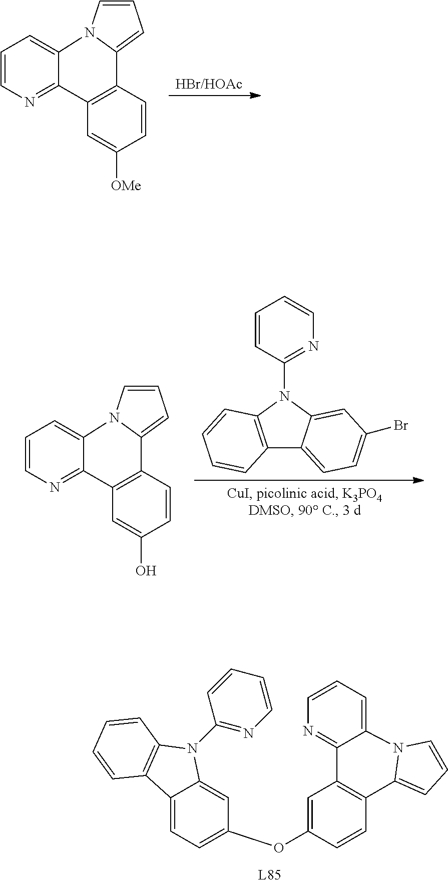

Benzo[c]pyrrolo[1,2-a][1,5]naphthyridin-11-ol (1 mmol, 1.0 eq), 2-bromo-9-(pyridin-2-yl)-9H-carbazole (388 mg, 1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L85 as a white solid in 65% yield.

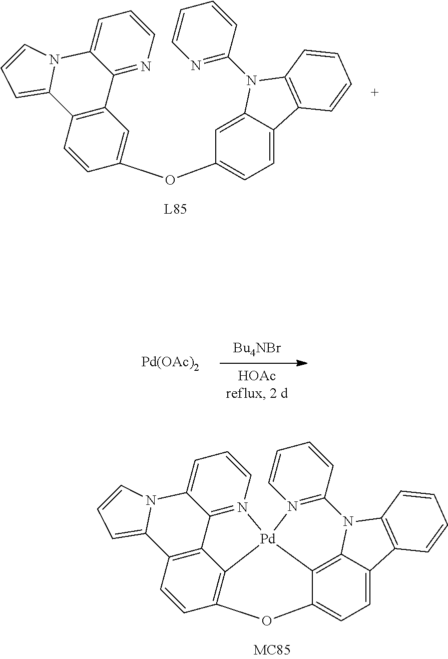

L85 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC85 as a white solid in 35% yield.

### Example 86

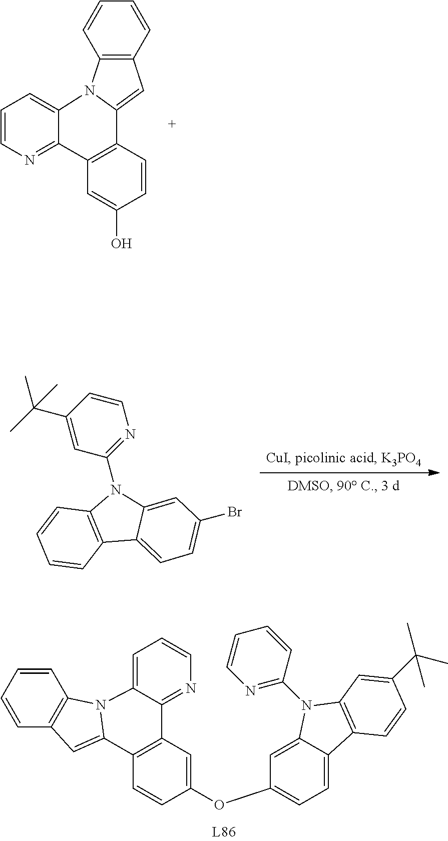 [SMILES: Oc1ccc2c(c1)c1ncccc1n1c3ccccc3cc21 ; CC(C)(C)c1ccnc(-n2c3ccccc3c3ccc(Br)cc32)c1 ; "CuI, picolinic acid, K3PO4" ; "DMSO, 90° C., 3 d" ; CC(C)(C)c1ccc2c3ccc(Oc4ccc5c(c4)c4ncccc4n4c6ccccc6cc54)cc3n(-c3ccccn3)c2c1]

Benzo[c]indolo[1,2-a][1,5]naphthyridin-6-ol (1 mmol, 1.0 eq), 2-bromo-9-(4-(tert-butyl)pyridin-2-yl)-9H-carbazole (1.2 mmol, 1.2 eq). CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L86 as a white solid in 65% yield.

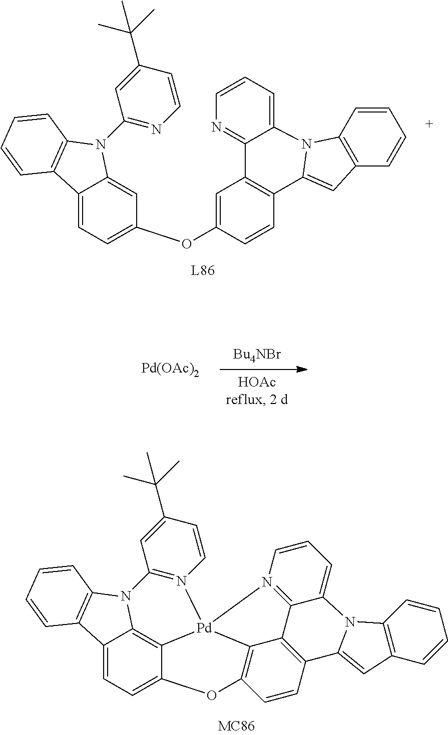

L86 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC86 as a white solid in 35% yield.

### Example 87

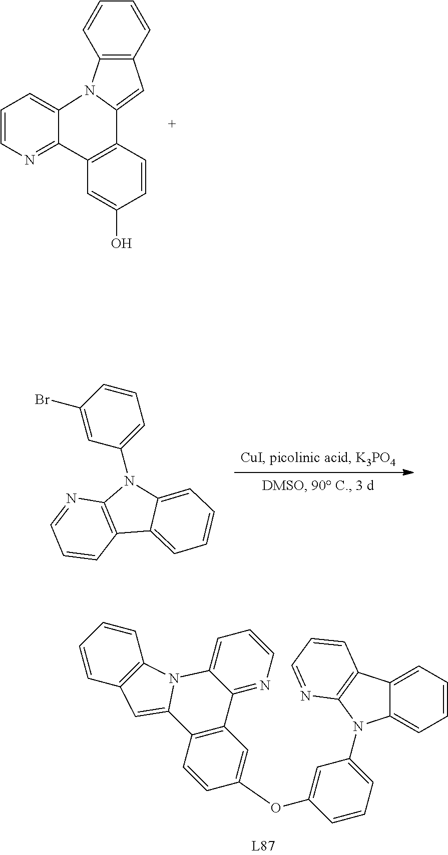 [SMILES: Oc1ccc2c(c1)c1ncccc1n1c3ccccc3cc21 ; Brc1cccc(-n2c3ccccc3c3cccnc32)c1 ; "CuI, picolinic acid, K3PO4" ; "DMSO, 90° C., 3 d" ; c1cc(Oc2ccc3c(c2)c2ncccc2n2c4ccccc4cc32)cc(-n2c3ccccc3c3cccnc32)c1]

Benzo[c]indolo[1,2-a][1,5]naphthyridin-6-ol (1 mmol, 1.0 eq), 9-(3-bromophenyl)-9H-pyrido[2,3-b]indole (388 mg, 1.2 mmol, 1.2 eq), CuI (38 mg, 0.2 mmol, 0.2 eq), picolinic acid (49 mg, 0.4 mmol, 0.4 eq) and K₃PO₄ (425 mg, 2 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate (2:1) as eluent to obtain the desired product ligand L87 as a white solid in 65% yield.

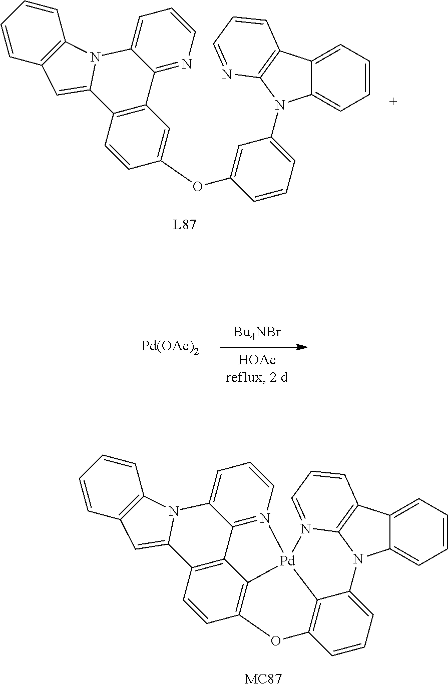

L87 (0.20 mmol, 1.0 eq), Pd(OAc)₂ (54 mg, 0.24 mmol, 1.2 eq) and n-Bu₄NBr (6.5 mg, 0.02 mmol, 0.1 eq) were added to a dry pressure tube was then taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and removed the solvent. Then the solid was purified through column chromatography on silica gel using dichloromethane as eluent to obtain to obtain the desired product MC87 as a white solid in 35% yield.

### Example 88

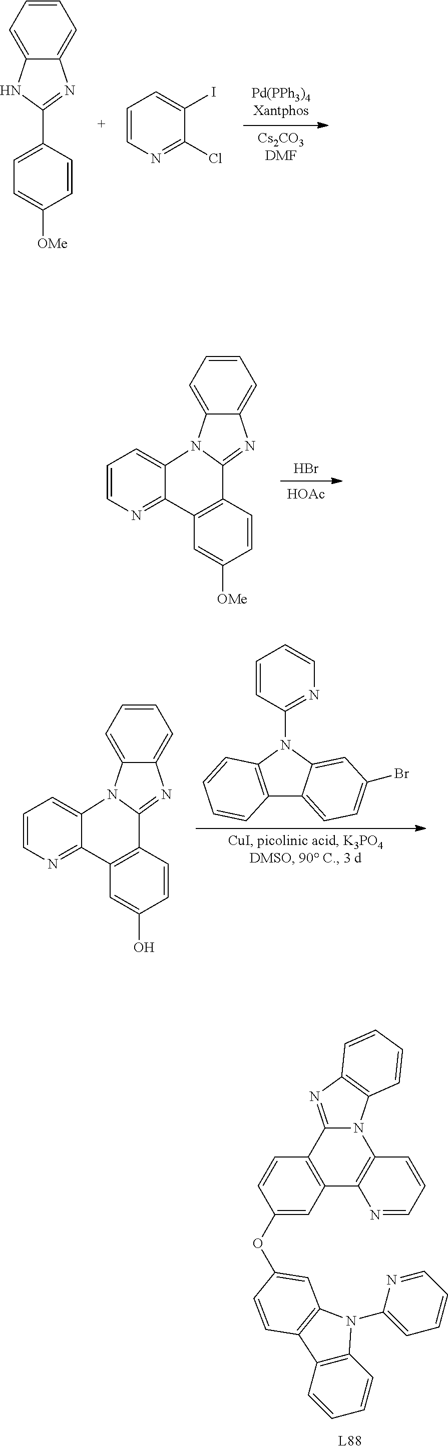

Benzo[c]benzo[4,5]imidazo[1,2-a][1,5]naphthyridin-6-ol (114 mg, 0.4 mmol, 1.0 eq), 2-bromo-9-(pyridin-2-yl)-9H-carbazole (156 mg, 0.48 mmol, 1.2 eq), CuI (15 mg, 0.08 mmol, 0.2 eq), picolinic acid (10 mg, 0.08 mmol, 0.2 eq) and K₃PO₄ (170 mg, 0.8 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L88 as an orange yellow solid 92 mg in 44% yield.

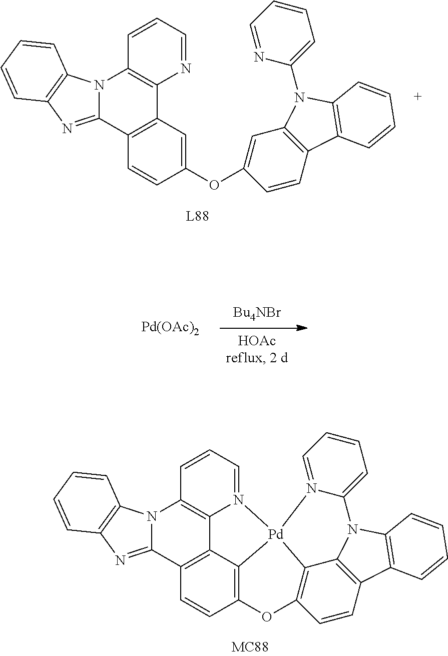

L88 (52 mg, 0.09 mmol, 1.0 eq), Pd(OAc)₂ (23 mg, 0.10 mmol, 1.1 eq) and n-Bu₄NBr (3 mg, 0.01 mmol, 0.1 eq) were added to a dry pressure tube, which was taken into a glove box and acetic acid (10 mL) was added. The mixture was bubbled with nitrogen for 30 minutes and then the tube was sealed. Then the mixture was heated to reflux in an oil bath and stirred for 2 days, cooled to ambient temperature and the solvent removed. Then the solid was purified through column chromatography on silica gel using dichloromethane as eluent to obtain the desired product MC88 in 10%˜50% yield.

### Example 89

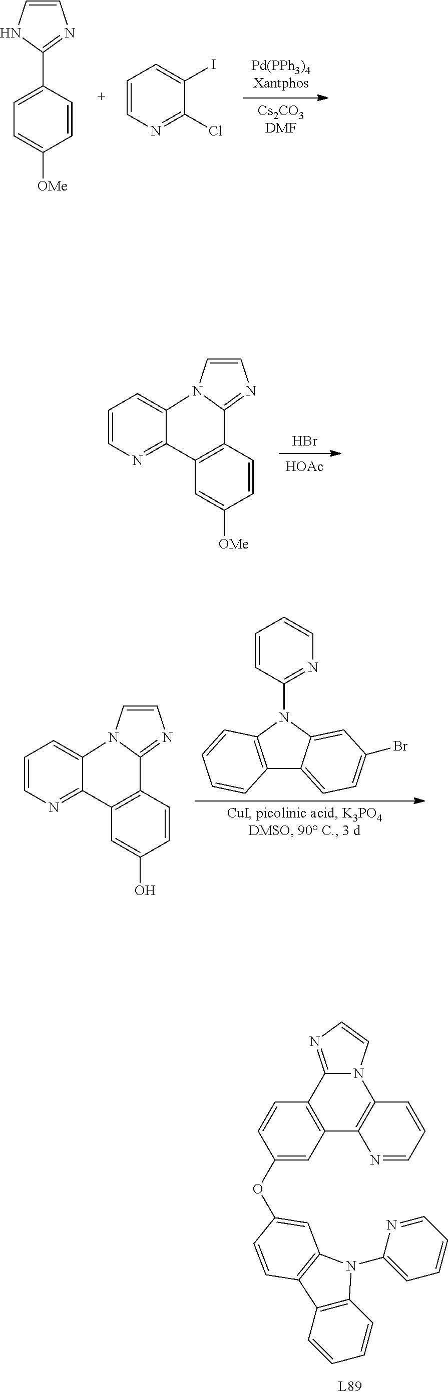

Benzo[c]imidazo[1,2-a][1,5]naphthyridin-10-ol (0.4 mmol, 1.0 eq), 2-bromo-9-(pyridin-2-yl)-9H-carbazole (156 mg, 0.48 mmol, 1.2 eq), CuI (15 mg, 0.08 mmol, 0.2 eq), picolinic acid (10 mg, 0.08 mmol, 0.2 eq) and K₃P04 (170 mg, 0.8 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L89 in 30%˜70% yield.

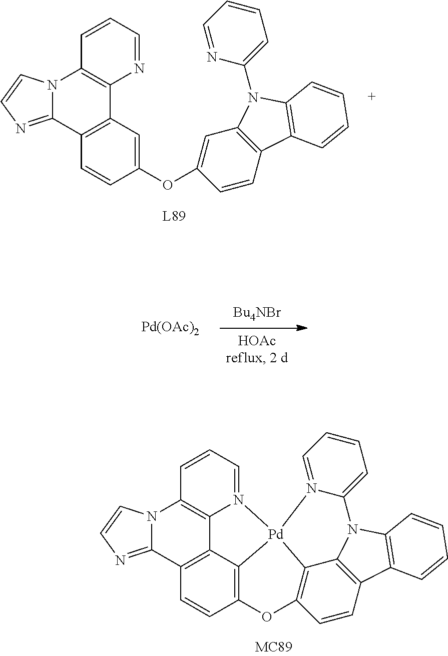

L89 (0.09 mmol, 1.0 eq), Pd(OAc)₂ (23 mg, 0.10 mmol, 1.1 eq) and n-Bu₄NBr (3 mg, 0.01 mmol, 0.1 eq) were added to a dry pressure tube, which was taken into a glove box and acetic acid (10 mL) was added. The mixture was bubbled with nitrogen for 30 minutes and then the tube was scaled. Then the mixture was heated to reflux in an oil bath and stirred for 2 days, cooled to ambient temperature and the solvent removed. Then the solid was purified through column chromatography on silica gel using dichloromethane as eluent to obtain the desired product MC89 in 10%˜50% yield.

### Example 90

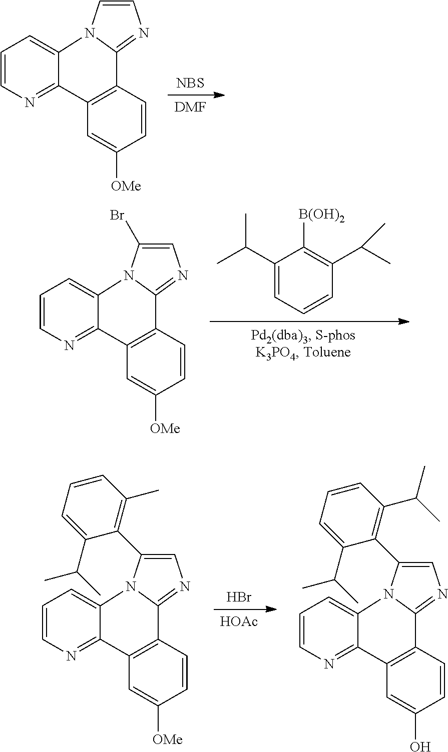

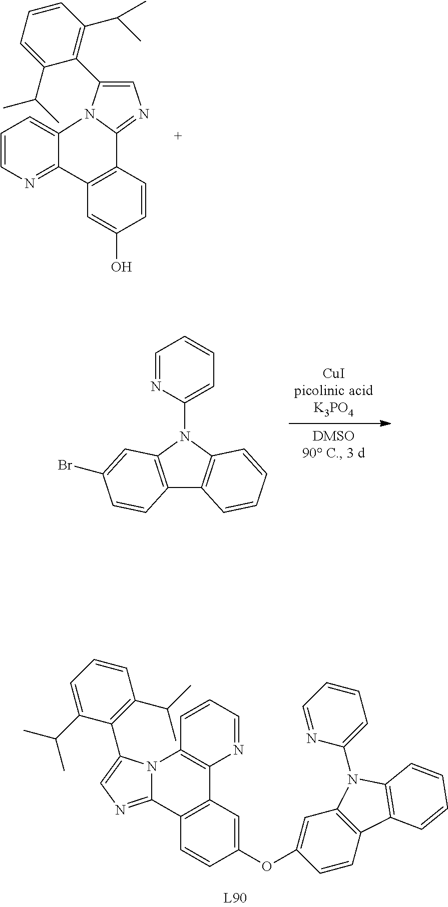 [SMILES: CC(C)c1cccc(C(C)C)c1-c1cnc2c3ccc(O)cc3c3ncccc3n12 ; Brc1ccc2c3ccccc3n(-c3ccccn3)c2c1 ; "CuIpicolinic acidK3PO4" ; "DMSO90° C., 3 d" ; CC(C)c1cccc(C(C)C)c1-c1cnc2c3ccc(Oc4ccc5c6ccccc6n(-c6ccccn6)c5c4)cc3c3ncccc3n12]

3-(2,6-diisopropylphenyl)benzo[c]imidazo[1,2-a][1,5]naphthyridin-10-ol (0.4 mmol, 1.0 eq), 2-bromo-9-(pyridin-2-yl)-9H-carbazole (156 mg, 0.48 mmol, 1.2 eq), CuI (15 mg, 0.08 mmol, 0.2 eq), picolinic acid (10 mg, 0.08 mmol, 0.2 eq) and K₃PO₄ (170 mg, 0.8 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (5 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L90 in 30%˜70%

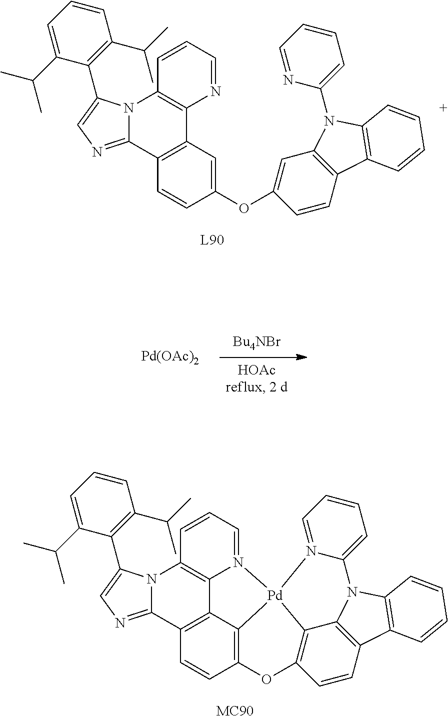

L90 (0.09 mmol, 1.0 eq), Pd(OAc)₂ (23 mg, 0.10 mmol, 1.1 eq) and n-Bu₄NBr (3 mg, 0.01 mmol, 0.1 eq) were added to a dry pressure tube, which was taken into a glove box and acetic acid (10 mL) was added. The mixture was bubbled with nitrogen for 30 minutes and then the tube was scaled. Then the mixture was heated to reflux in an oil bath and stirred for 2 days, cooled to ambient temperature and the solvent removed. Then the solid was purified through column chromatography on silica gel using dichloromethane as eluent to obtain the desired product MC90 in 10%˜50% yield.

### Example 91

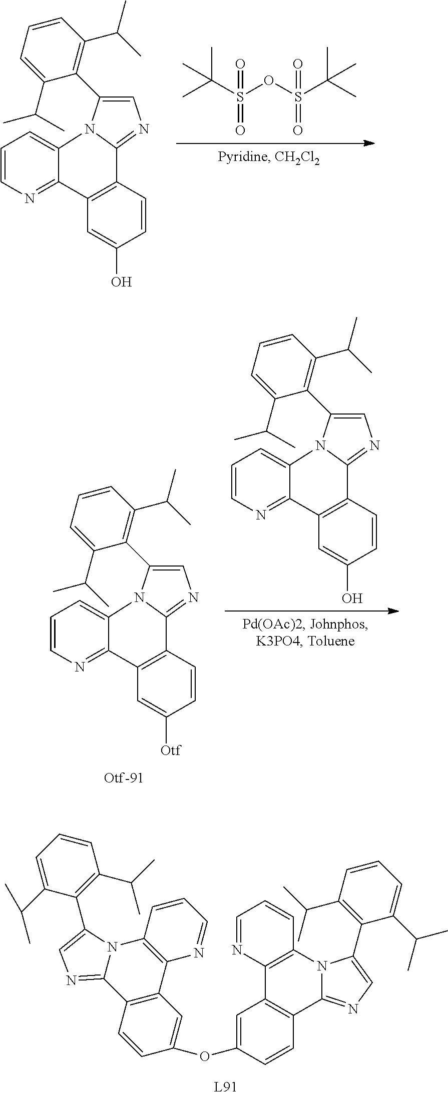

Otf-91 (0.85 mmol, 1.0 eq), 3-(2,6-diisopropylphenyl)benzo[c]imidazo[1,2-a][1,5]naphthyridin-10-ol (1.10 mmol, 1.3 eq), CuI (32 mg, 0.17 mmol, 0.2 eq), picolinic acid (21 mg, 0.17 mmol, 0.2 eq) and K₃PO₄ (356 mg, 1.7 mmol, 2.0 eq) were added to a dry Shlenck tube equipped with a magnetic stir bar. The tube was evacuated and backfilled with nitrogen. The evacuation and backfill procedure was repeated for a total of three times. Then solvent DMSO (10 mL) was added under the protection of nitrogen. The mixture was stirred in an oil bath at a temperature of 90° C. for 3 days and then cooled down to ambient temperature, diluted with ethyl acetate. The mixture was washed with water three times and then dried over sodium sulfate and filtered. The solvent was removed under reduced pressure, and the residue was purified through column chromatography on silica gel using hexane/ethyl acetate as eluent to obtain the desired product ligand L91 in 30%˜70% yield.

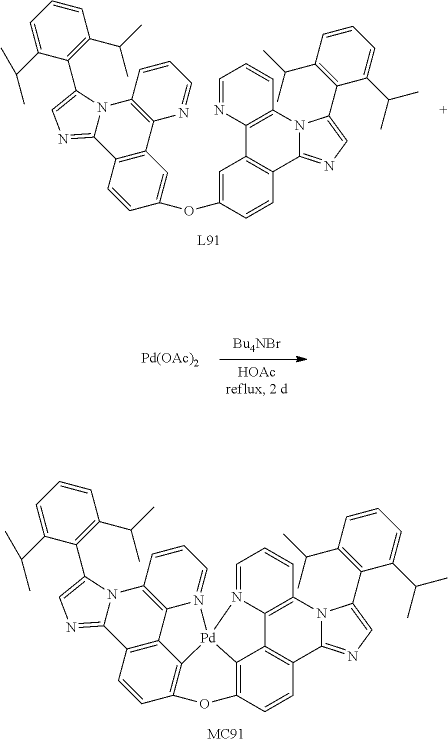

L91 (0.11 mmol, 1.0 eq), K₂PtCl₄ (48 mg, 0.12 mmol, 1.1 eq) and n-Bu₄NBr (3 mg, 0.011 mmol, 0.1 eq) were added to a dry pressure tube, which was taken into a glove box and acetic acid (7 mL) was added. The mixture was bubbled with nitrogen for 30 minutes and then the tube was sealed. Then the mixture was heated to reflux in an oil bath and stirred for 3 days, cooled to ambient temperature and the solvent removed. Then the solid was purified through column chromatography on silica gel using dichloromethane as eluent to obtain the desired product MC91 in 10%˜50% yield.

### EXAMPLES OF GENERAL FORMULAS XIV-XVII

### Example 92

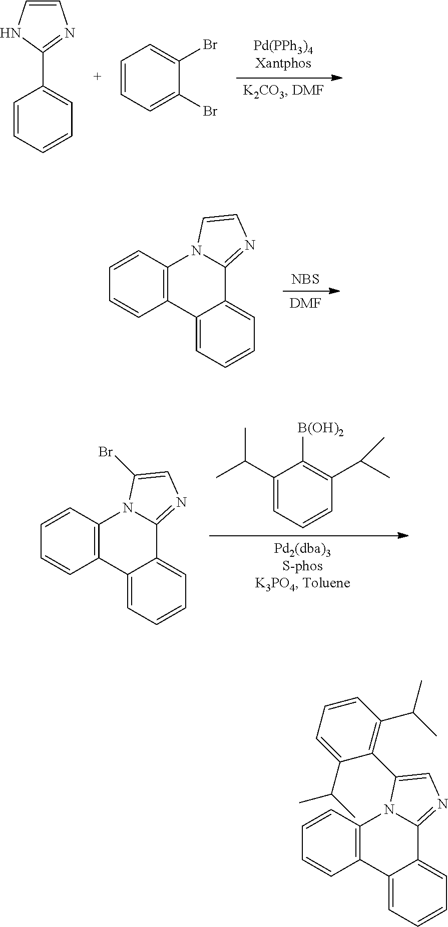

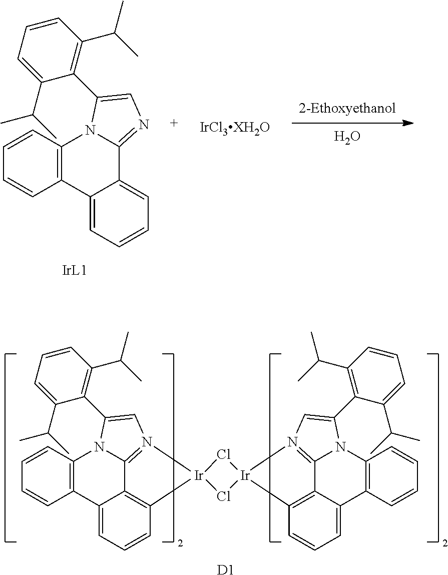

IrL1 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D1 in 40%˜80% yield.

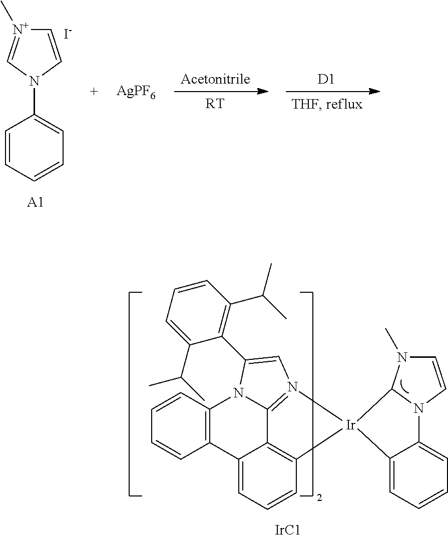

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D1 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC1 in 20%˜-60% yield.

### Example 93

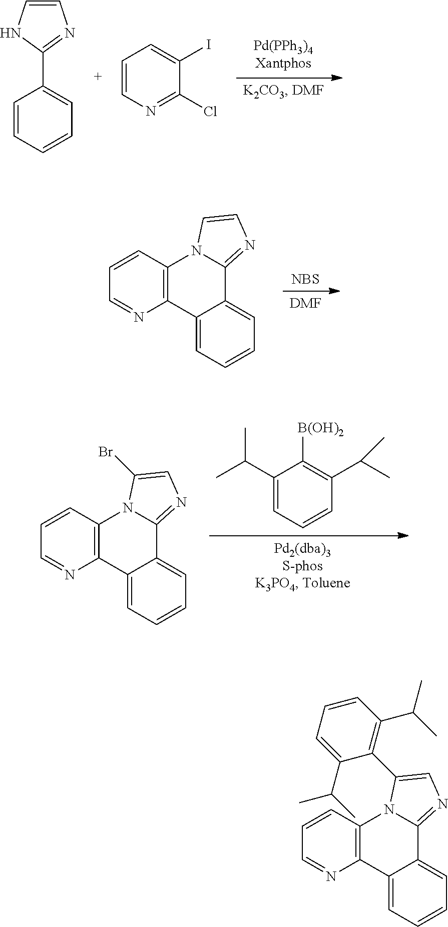

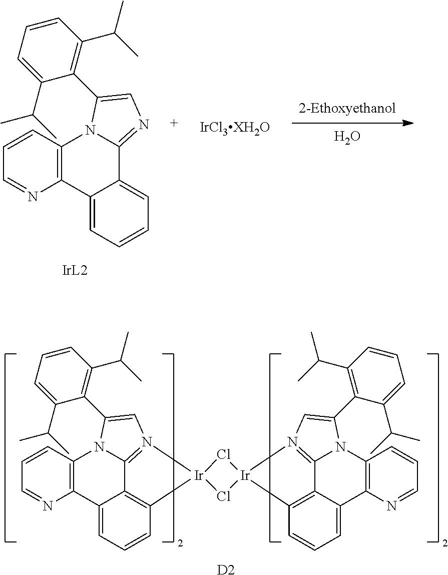

IrL2 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D2 in 40%˜80% yield.

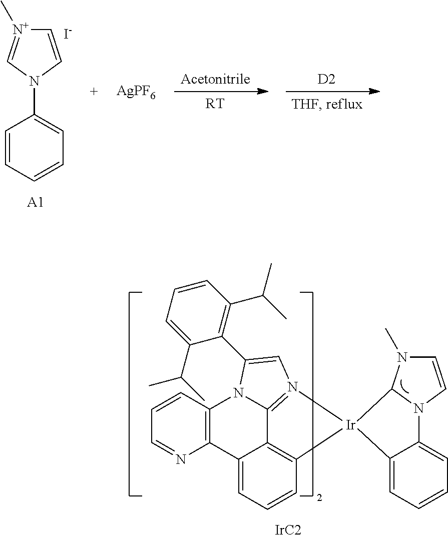

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D2 (1.0 mmol, 1.0 eq) and 150 ml, of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC2 in 20%˜60% yield.

### Example 94

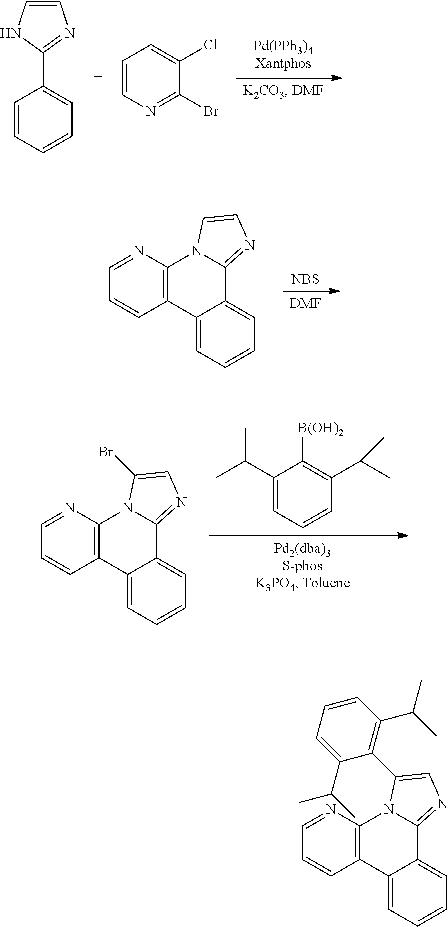

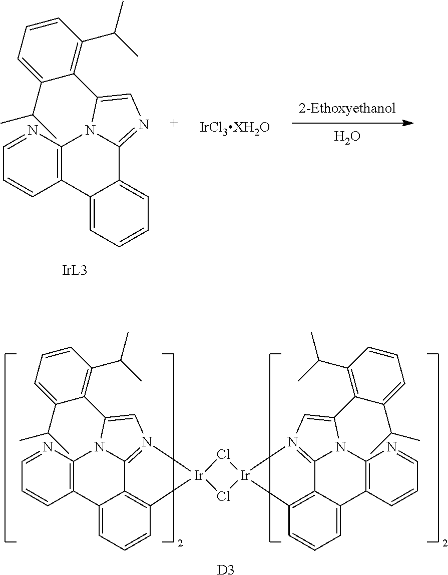

IrL3 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D3 in 40%˜80% yield.

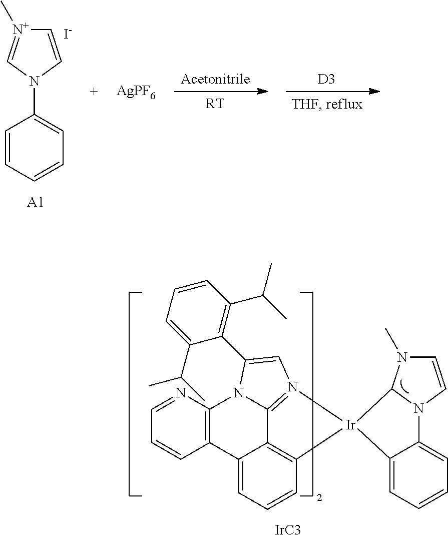

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D3 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC3 in 20%˜60% yield.

### Example 95

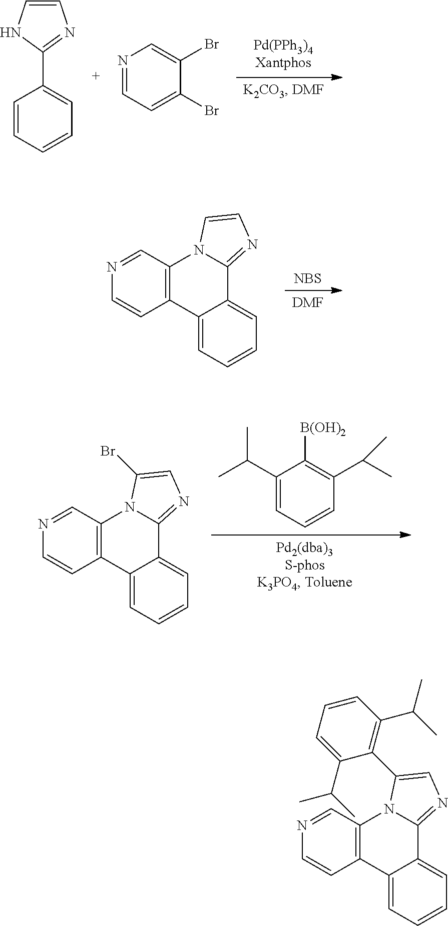

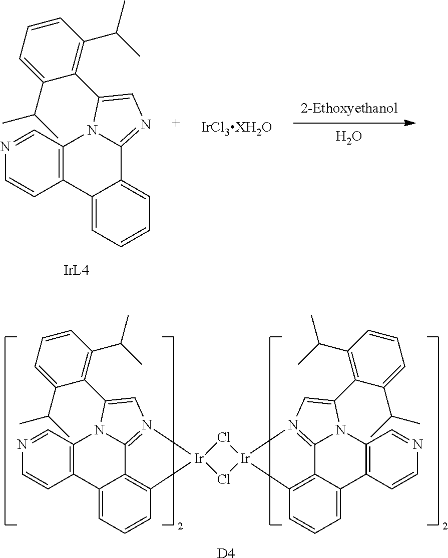

IrL4 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D4 in 40%˜80% yield.

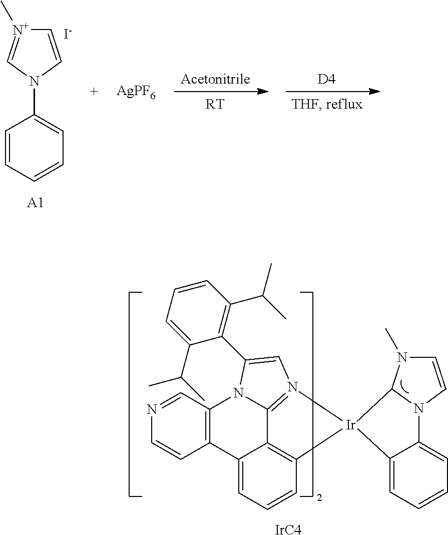

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D4 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC4 in 20%˜60% yield.

### Example 96

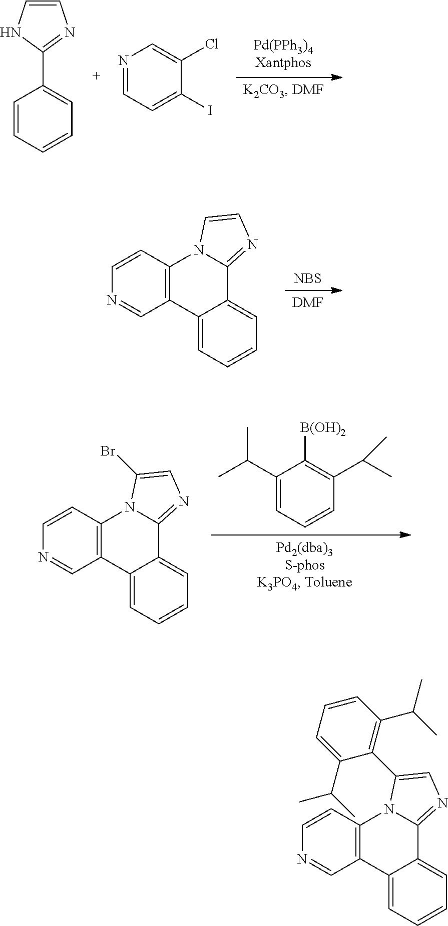

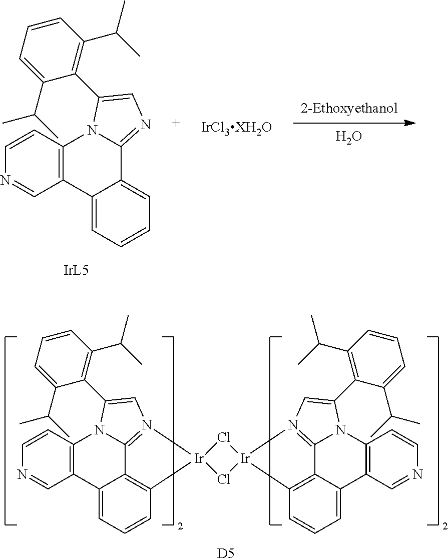

IrL5 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D5 in 40%˜80% yield.

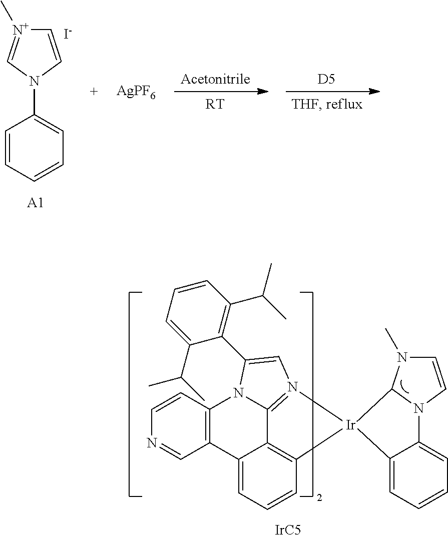

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D5 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC5 in 20%˜60% yield.

### Example 97

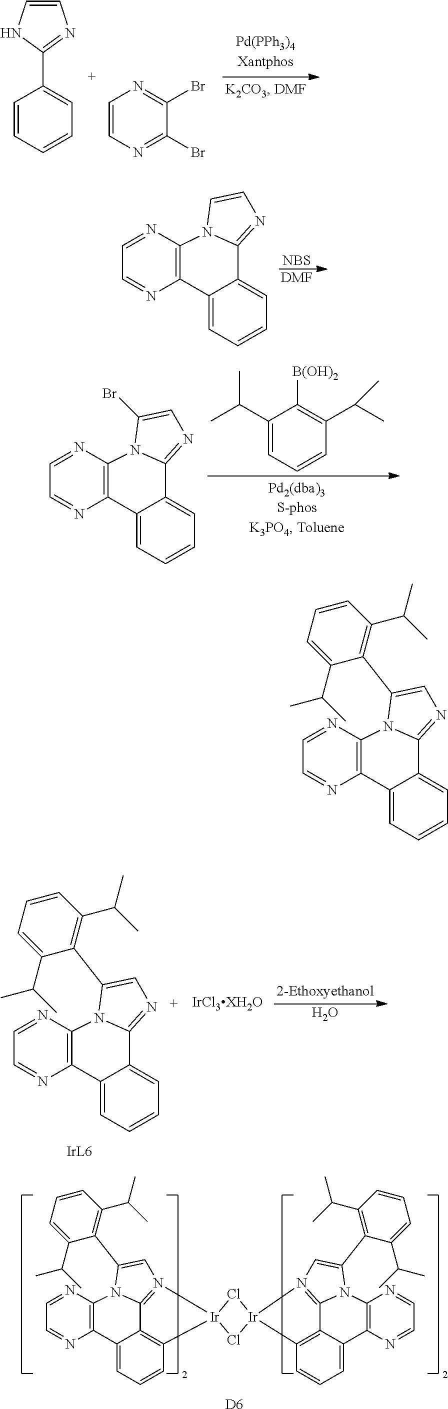

IrL6 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D6 in 40%·80% yield.

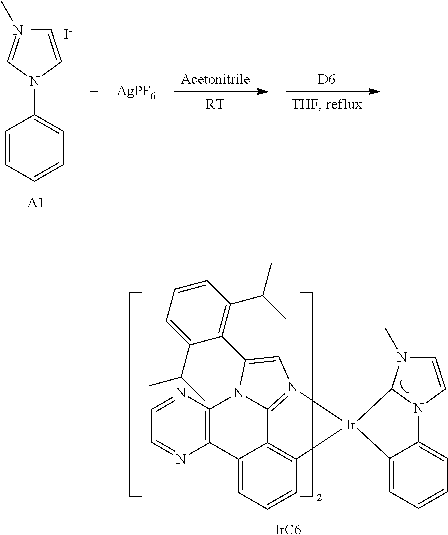

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D6 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC6 in 20%-˜60% yield.

### Example 98

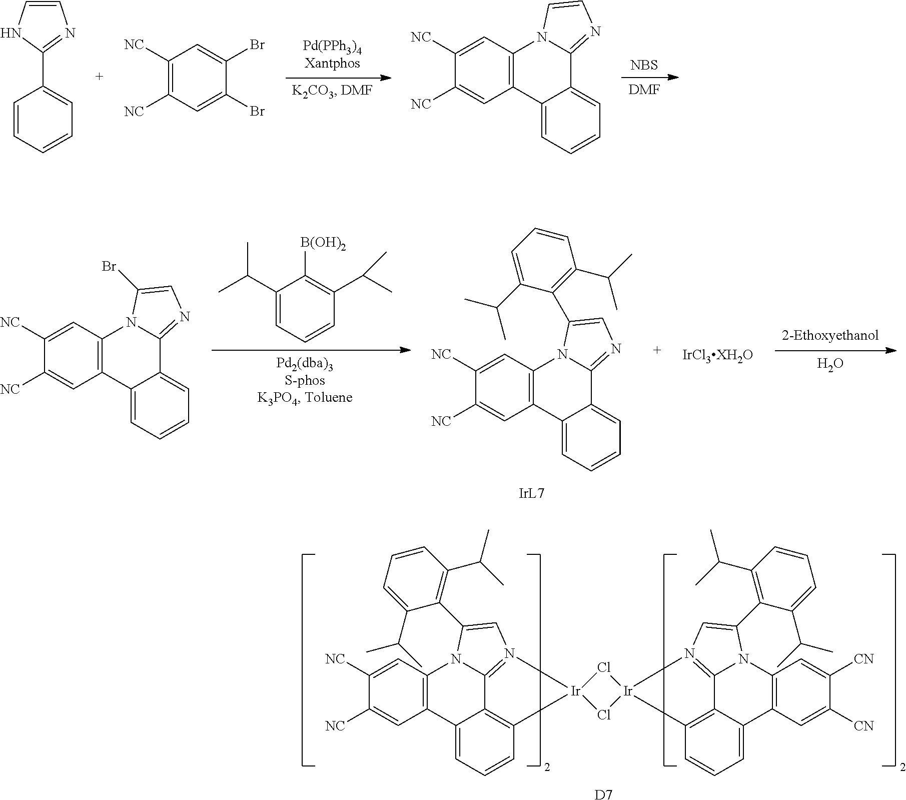

IrL7 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D7 in 40%˜80% yield.

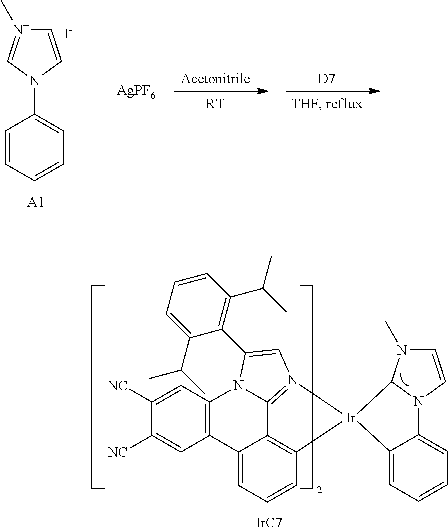

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D7 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC7 in 20%˜60% yield.

### Example 29

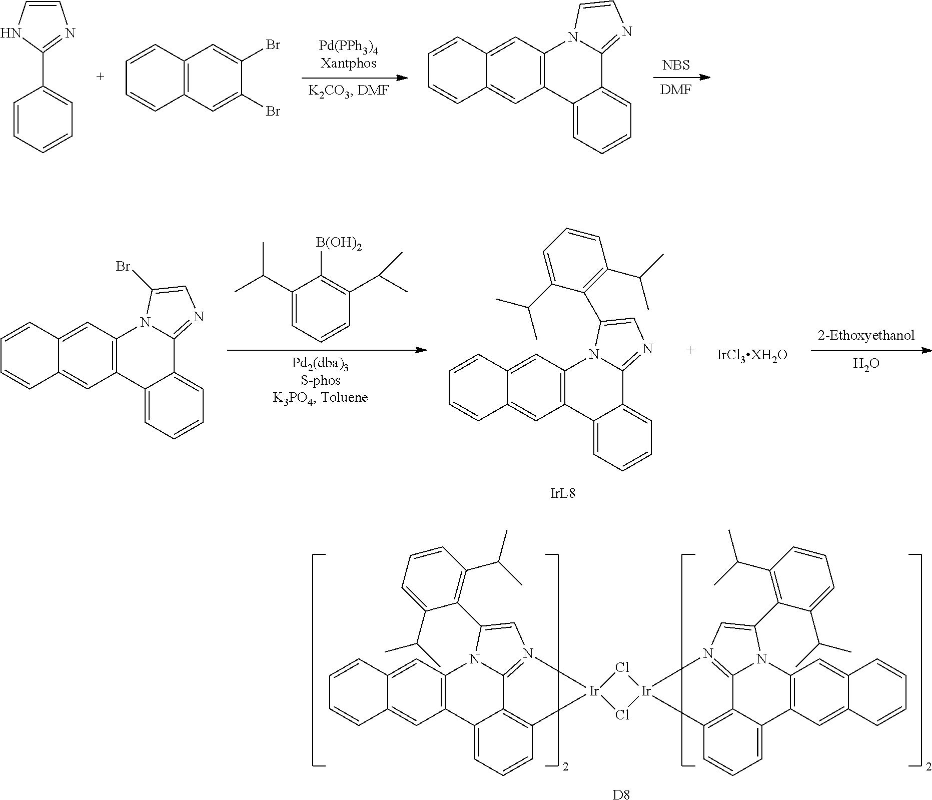

IrL8 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D8 in 40%˜80% yield.

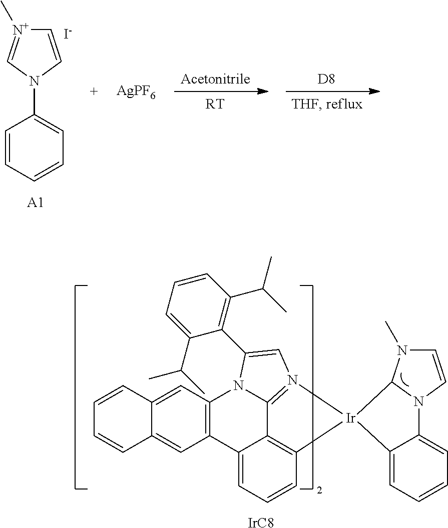

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D8 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC8 in 20%˜60% yield.

### Example 100

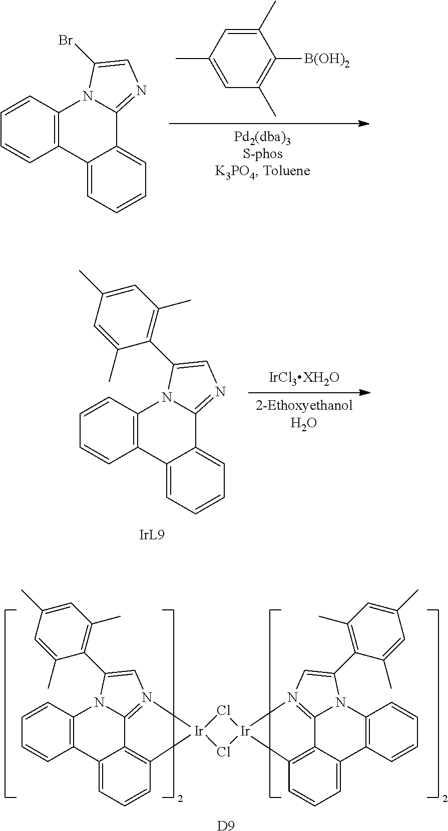

IrL9 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D9 in 40%˜80% yield.

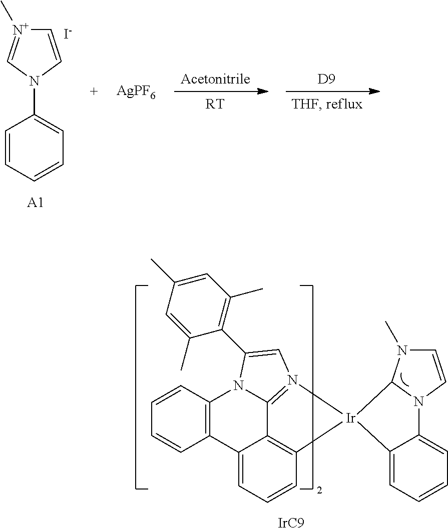

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D9 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC9 in 20%˜60% yield.

### Example 101

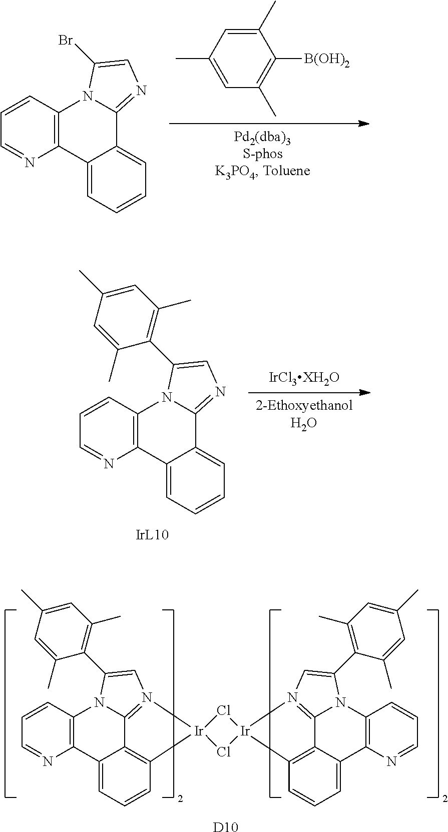

IrL10 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D10 in 40%˜80% yield.

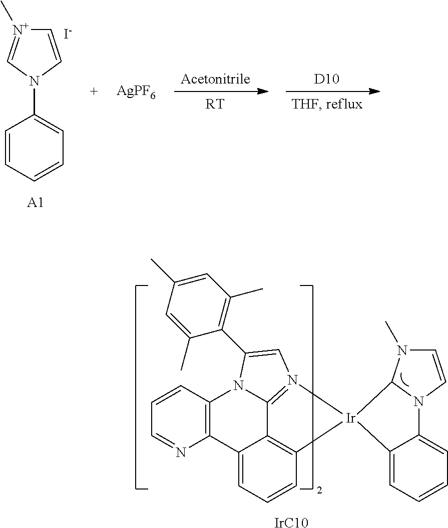

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D10 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC10 in 20%˜60% yield.

### Example 102

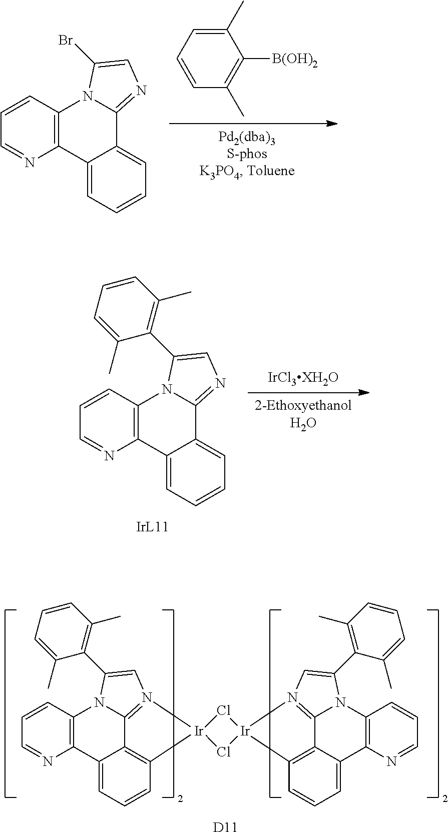

IrL11 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D11 in 40%˜80% yield.

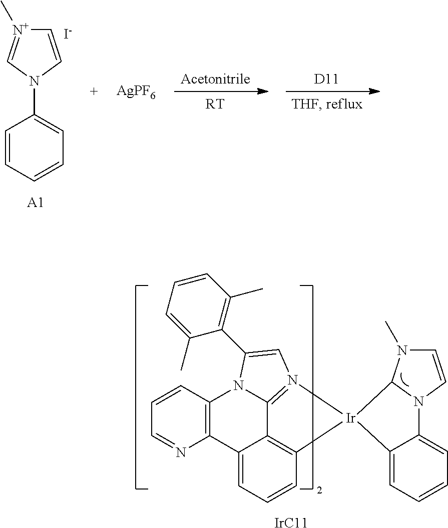

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D11 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC11 in 20%˜60% yield.

### Example 103

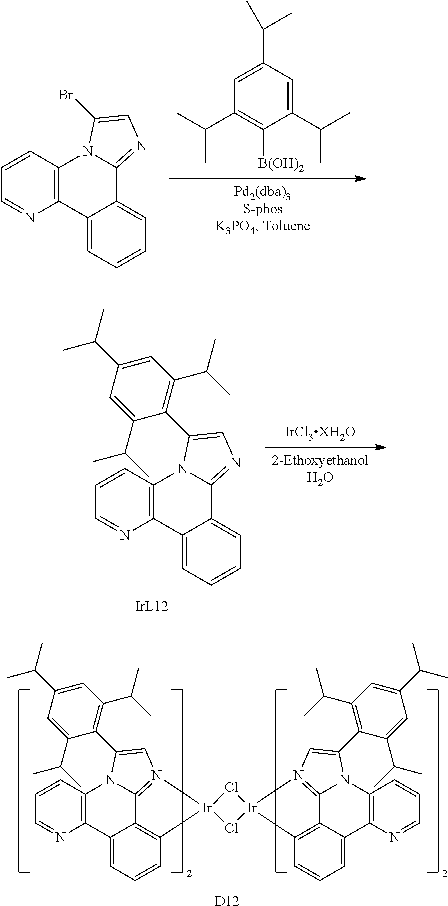

IrL12 (2.2 mmol, 2.2 eq) and IrCl·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D12 in 40%˜80% yield.

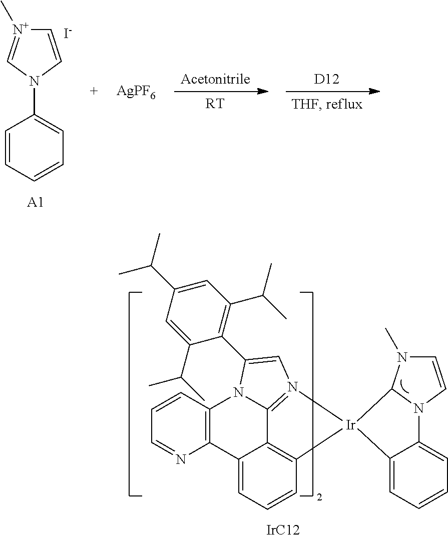

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D12 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC12 in 20%˜60% yield.

### Example 104

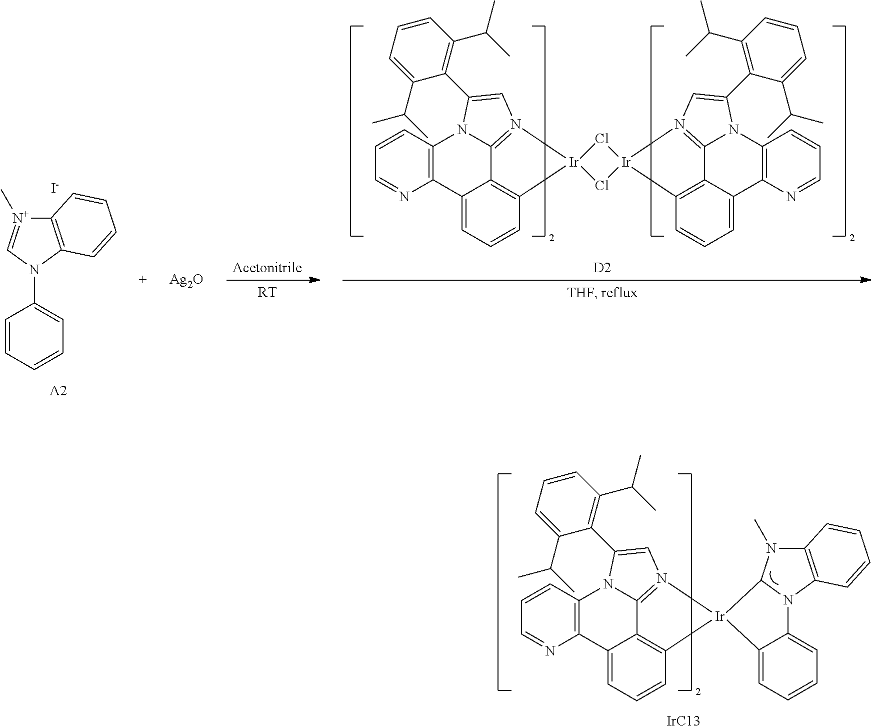

A mixture of ancillary ligand A2 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D2 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrCl3 in 20%˜60% yield.

### Example 105

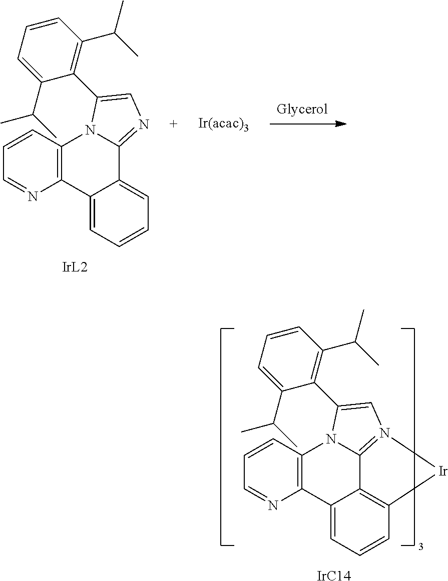

IrL2 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl2. Then the organic extracts were combined, and dried with MgSO₄. The mixture was evaporated to dryness under reduced pressure, and then purified by column chromatography to obtain the emitter IrC14 in 5%˜50% yield.

### Example 106

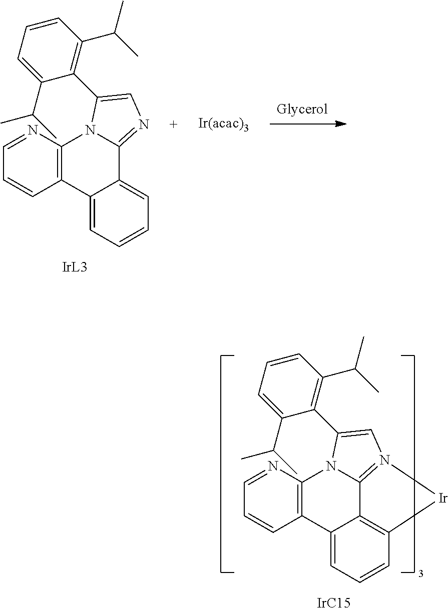

IrL3 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC15 in 5%˜50% yield.

### Example 107

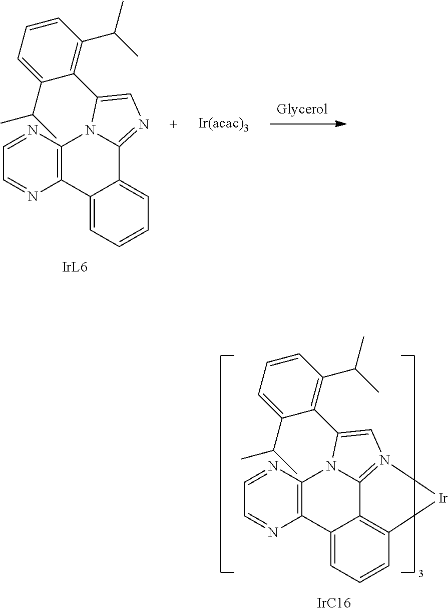

IrL6 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC16 in 5%˜50% yield.

### Example 108

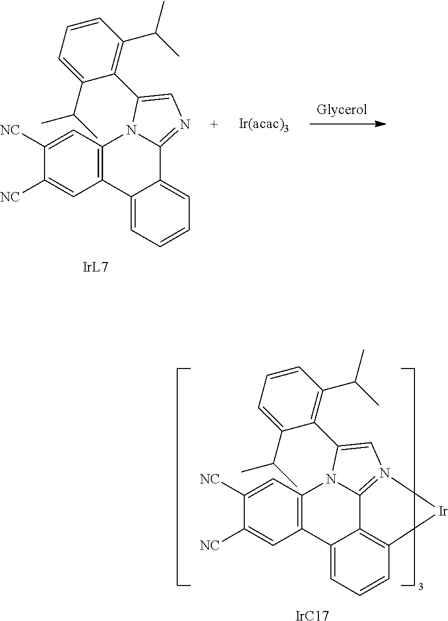

IrL7 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC17 in 5%˜50% yield.

### Example 109

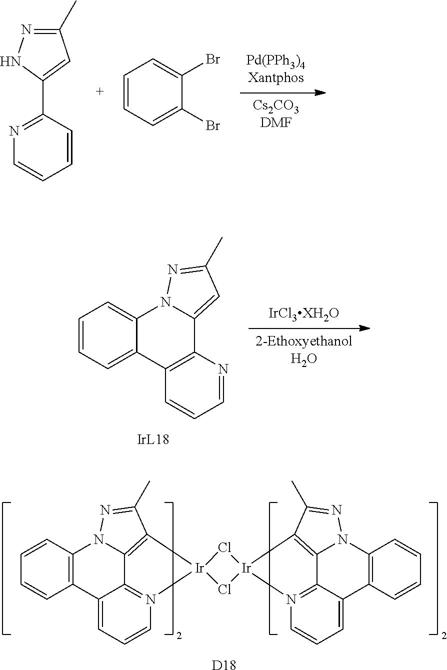

IrL18 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D18 in 40%˜80% yield.

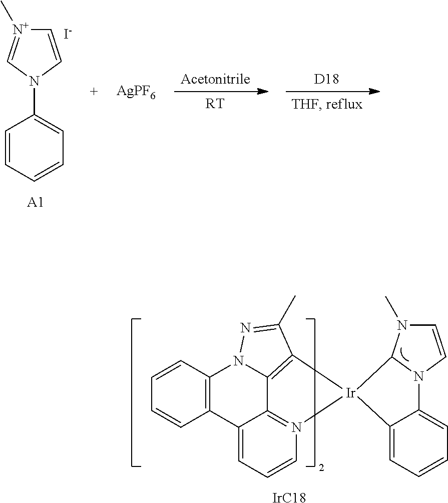

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D18 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC18 in 20%˜60% yield.

### Example 110

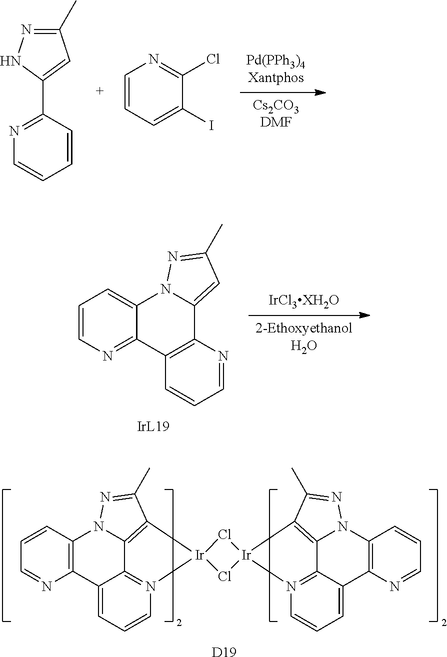

IrL19 (2.2 mmol, 2.2 eq) and IrCl·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D19 in 40%˜80% yield.

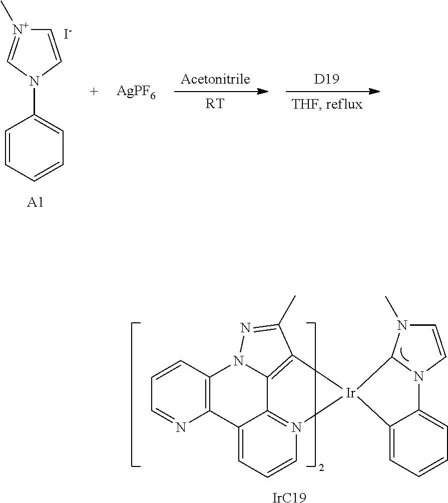

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D19 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC19 in 20%˜60% yield.

### Example 111

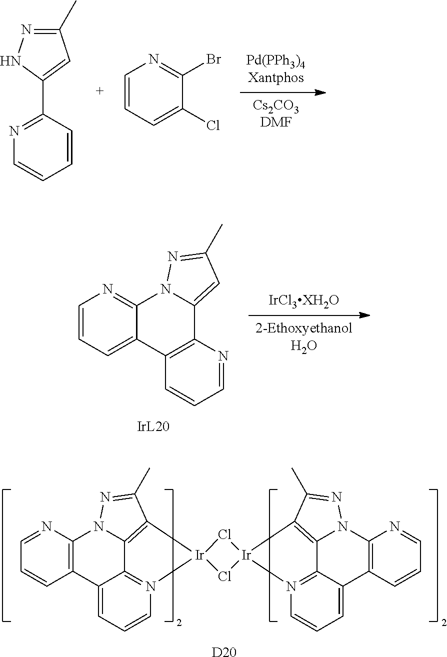

IrL20 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D20 in 40%˜80% yield.

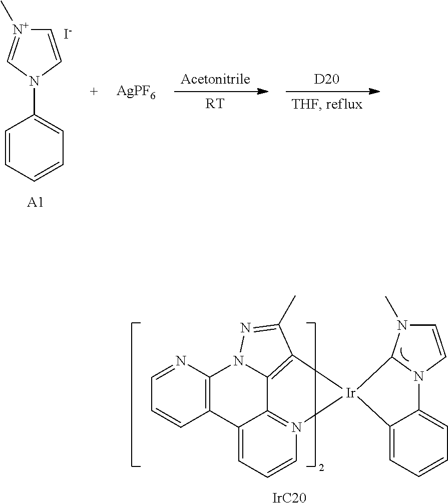

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D20 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC20 in 20%˜60% yield.

### Example 112

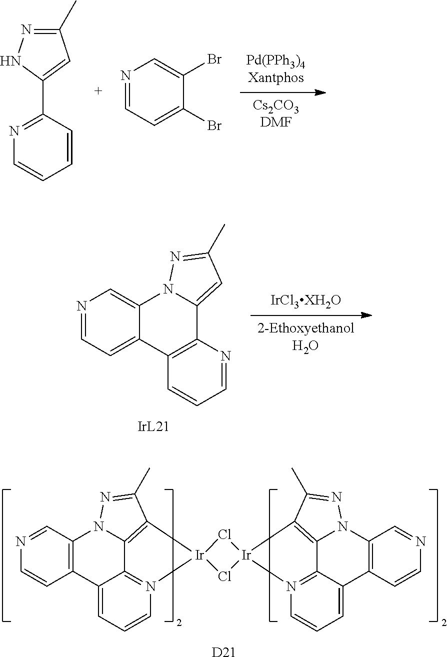

IrL21 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D21 in 40%˜80% yield.

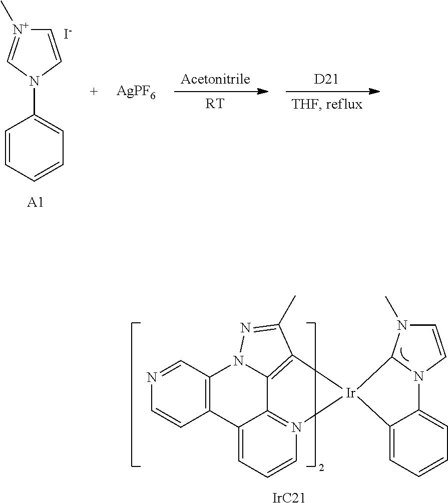

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D21 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC21 in 20%˜60% yield.

### Example 113

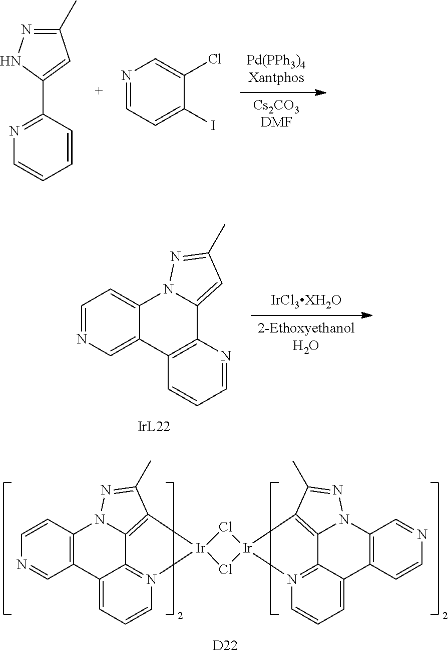

IrL22 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D22 in 40%˜80% yield.

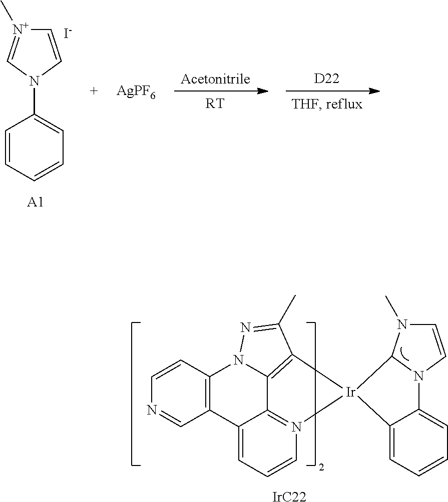

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D22 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC22 in 20%˜60% yield.

### Example 114

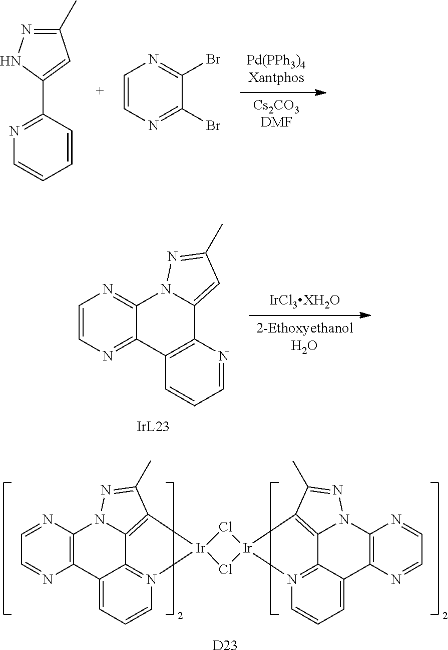

IrL23 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D23 in 40%˜80% yield.

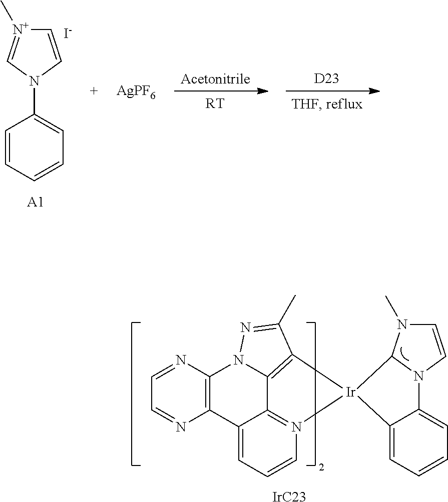

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D23 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC23 in 20%˜60% yield.

### Example 115

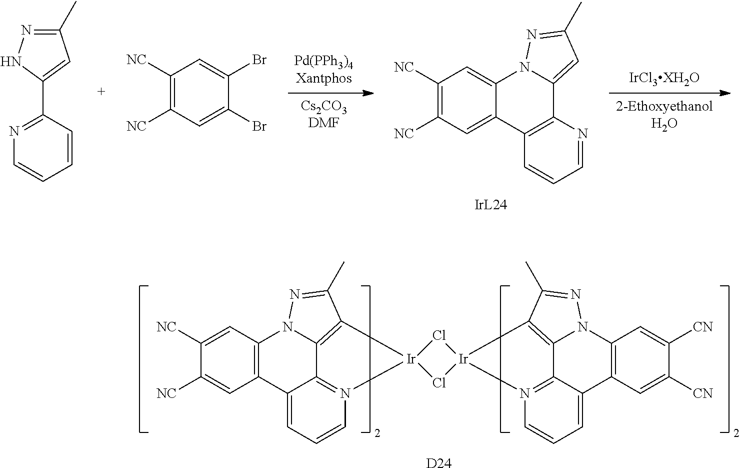

IrL24 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D24 in 40%˜80% yield.

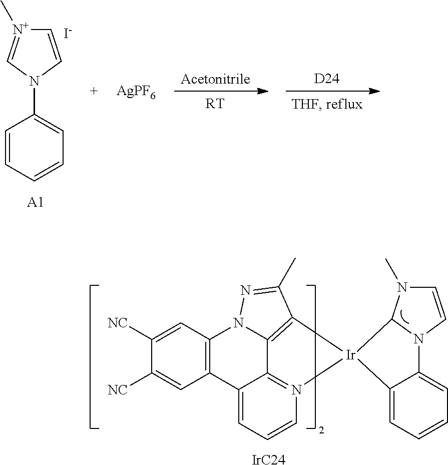

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D24 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC24 in 20%˜60% yield.

### Example 116

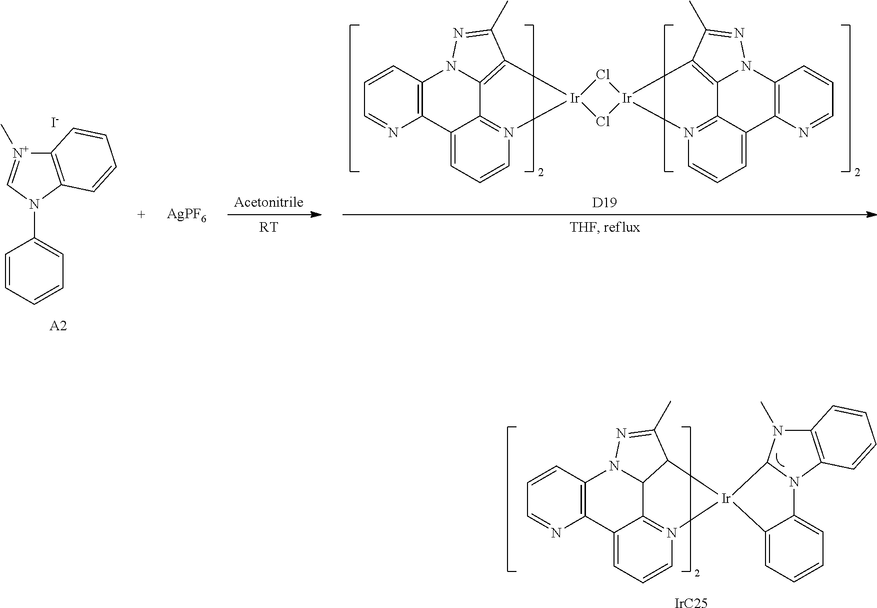

A mixture of ancillary ligand A2 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D19 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC25 in 20%˜60% yield.

### Example 117

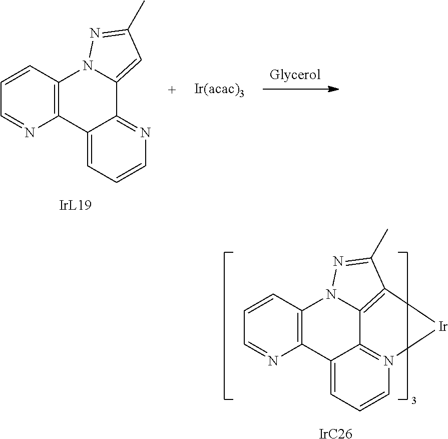

IrL19 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC26 in 5%˜50% yield.

### Example 118

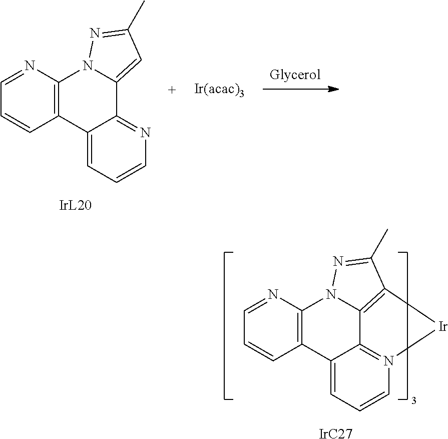

IrL20 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC27 in 5%˜50% yield.

### Example 119

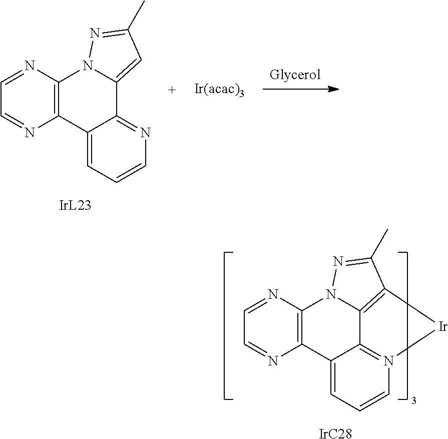

IrL23 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC28 in 5%˜50% yield.

### Example 120

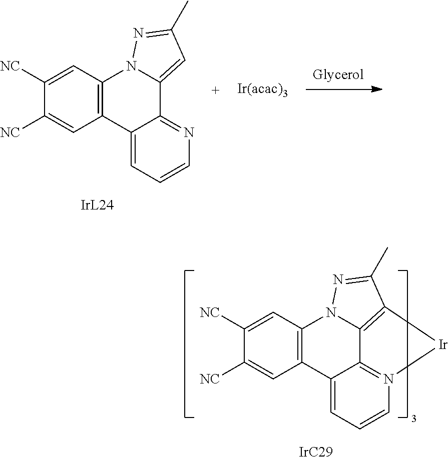

IrL24 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC29 in 5%˜50% yield.

### Example 121

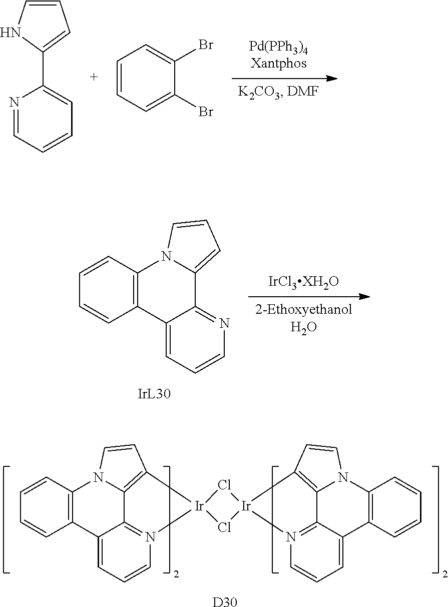

IrL30 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D30 in 40%˜80% yield.

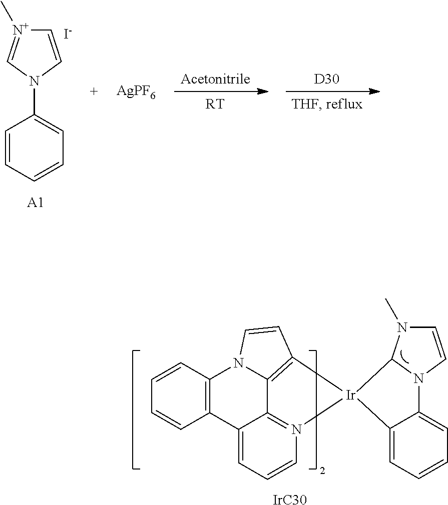

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D30 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC30 in 20%˜60% yield.

### Example 122

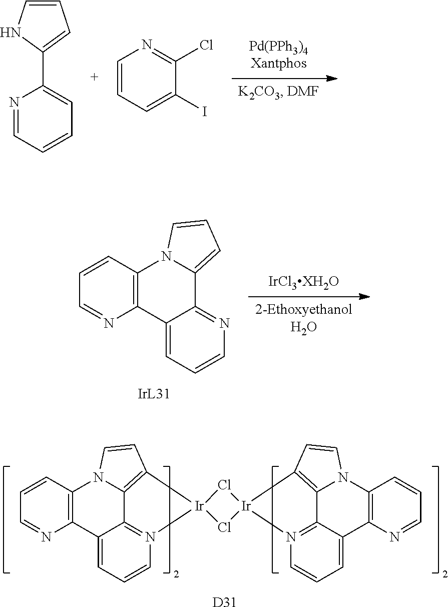

IrL31 (2.2 mmol, 2.2 eq) and IrC₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D31 in 40%˜80% yield.

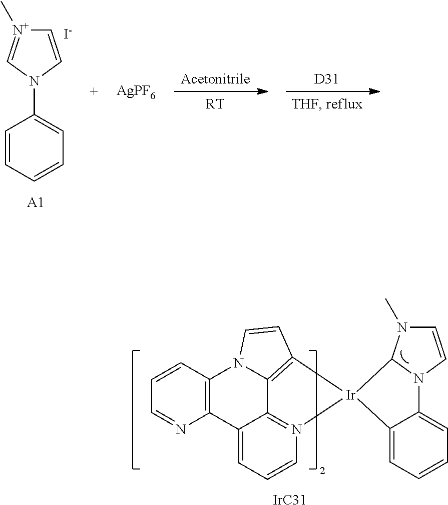

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D31 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC31 in 20%˜60% yield.

### Example 123

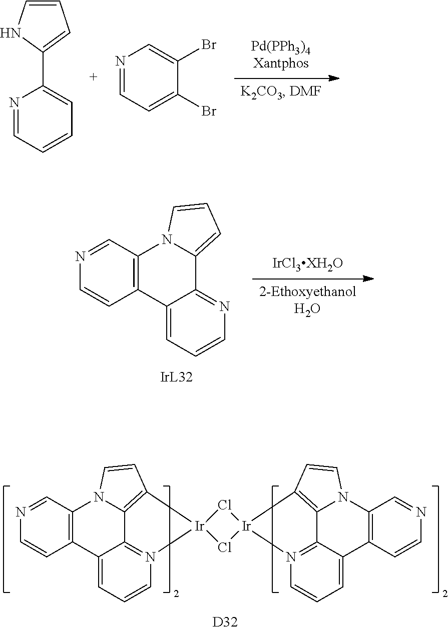

IrL32 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D32 in 40%˜80% yield.

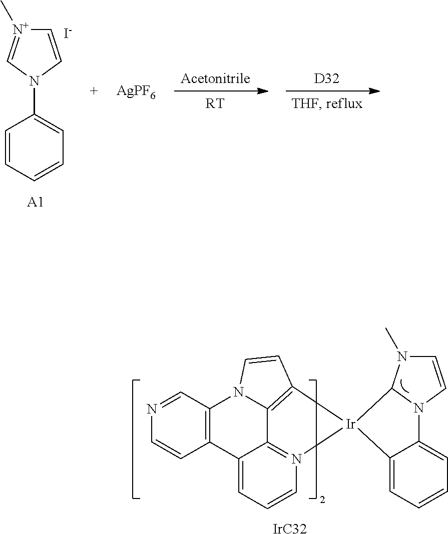

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D32 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC32 in 20%˜60% yield.

### Example 124

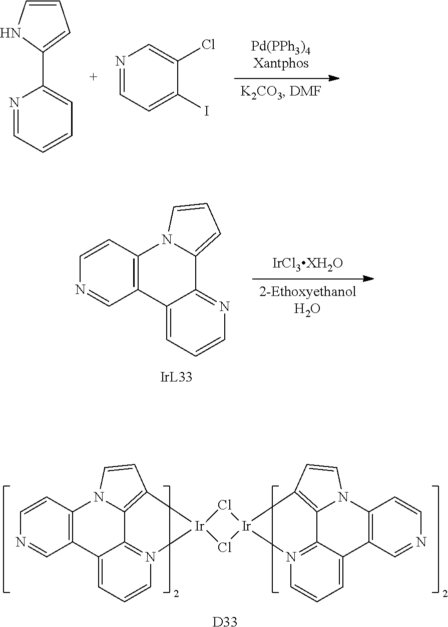

IrL33 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D33 in 40%˜80% yield.

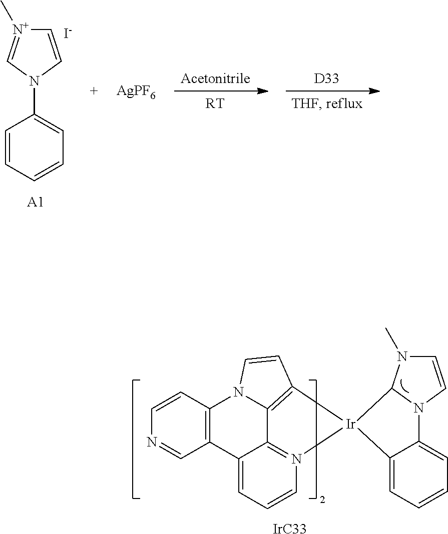

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D33 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC33 in 20%˜60% yield.

### Example 125

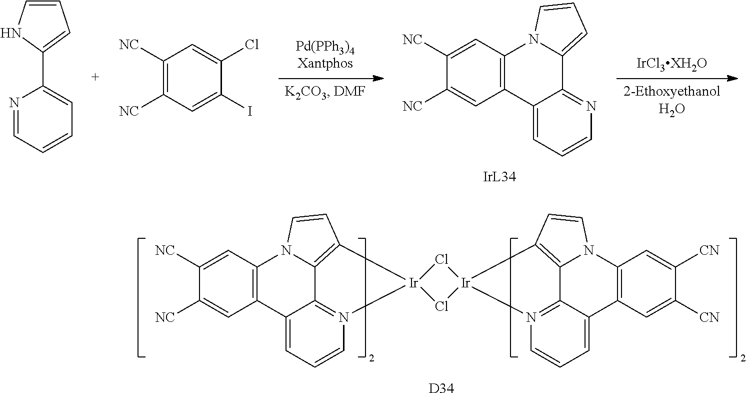

IrL34 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D34 in 40%˜80% yield.

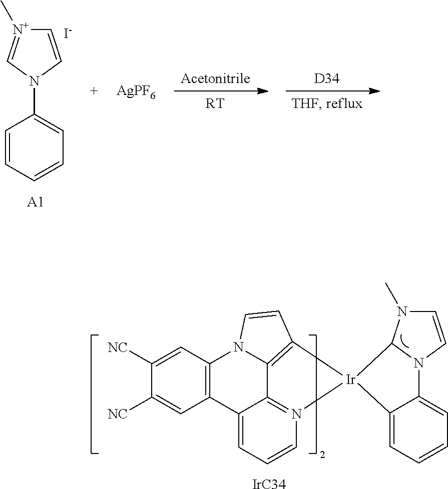

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D34 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC34 in 20%˜60% yield.

### Example 126

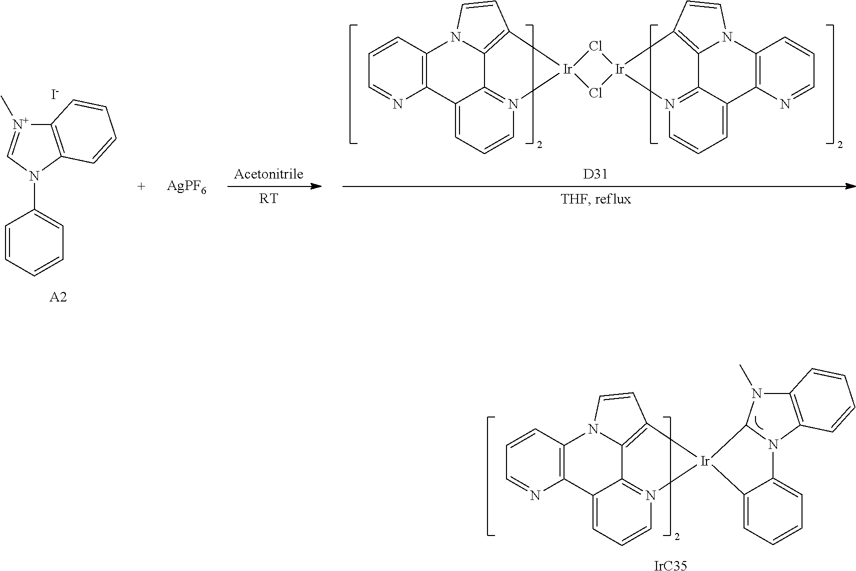

A mixture of ancillary ligand A2 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D31 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC35 in 20%˜60% yield.

### Example 127

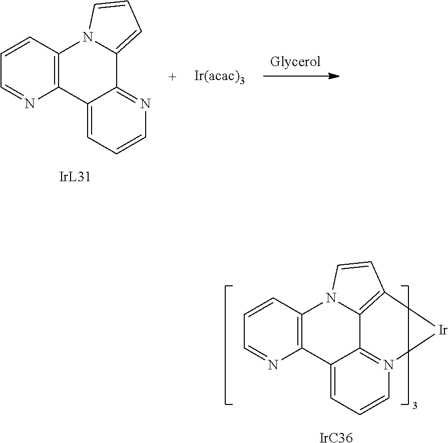

IrL31 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC36 in 5%˜50% yield.

### Example 128

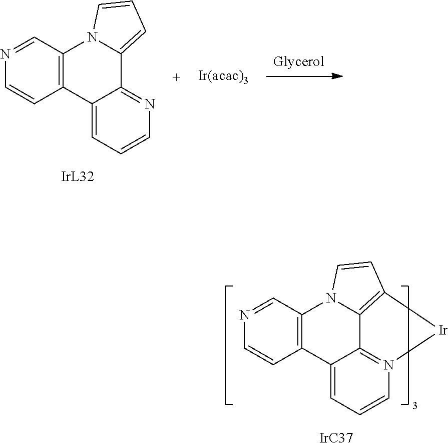

IrL32 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrLC37 in 5%˜50% yield.

### Example 129

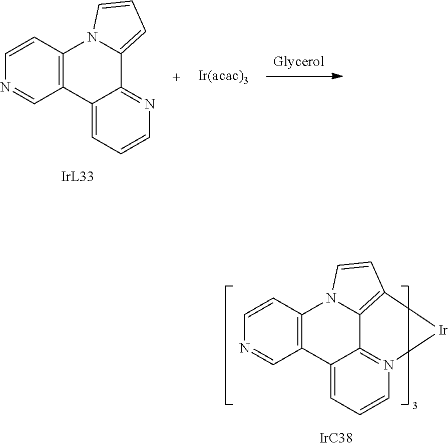

IrL33 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC38 in 5%˜50% yield.

### Example 130

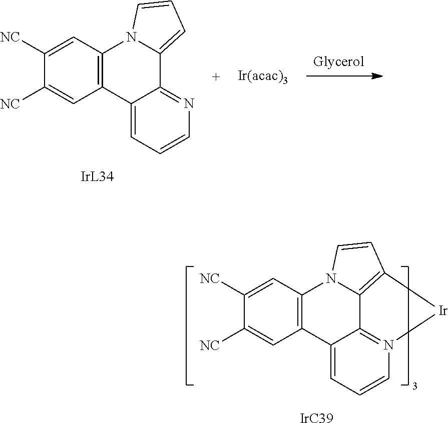

IrL34 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC39 in 5%˜50% yield.

### Example 131

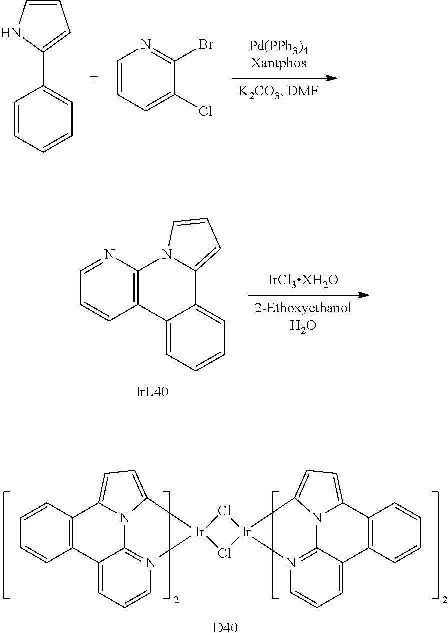

IrL40 (2.2 mmol, 2.2 eq) and IrC₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D40 in 40%˜80% yield.

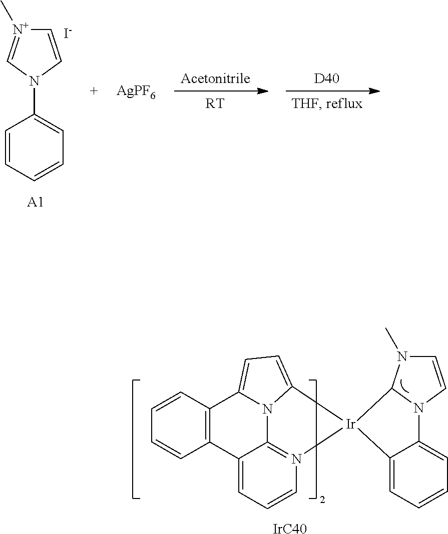

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D40 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC40 in 20%˜60% yield.

### Example 132

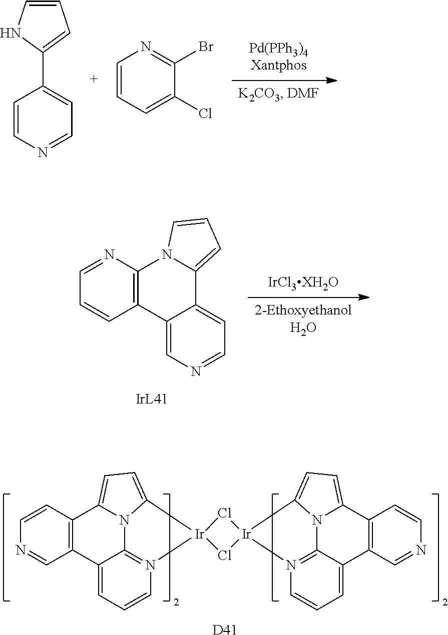

IrL41 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D41 in 40%˜80% yield.

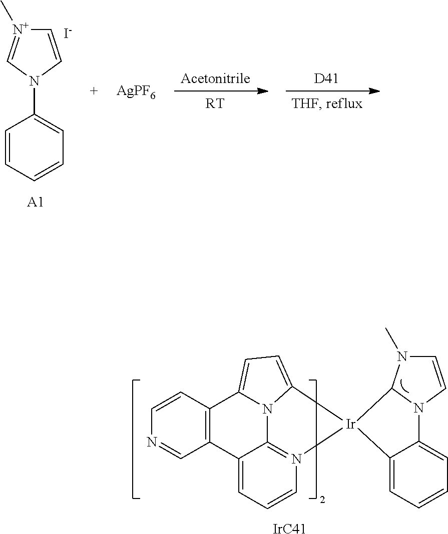

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D41 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC41 in 20%˜60% yield.

### Example 133

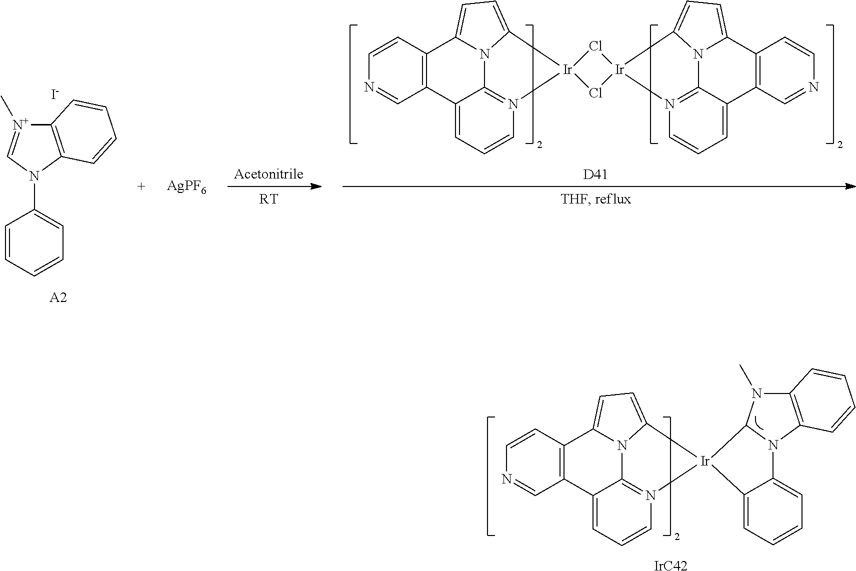

A mixture of ancillary ligand A2 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D41 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC42 in 20%˜60% yield.

### Example 134

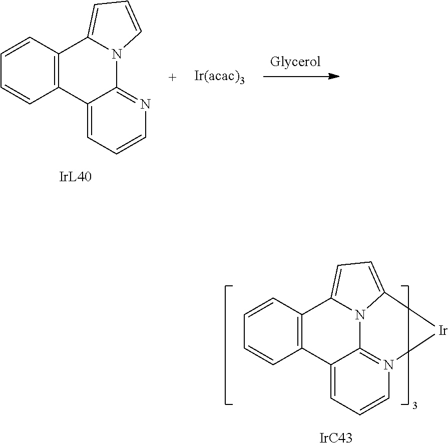

IrL40 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC43 in 5%˜50% yield.

### Example 135

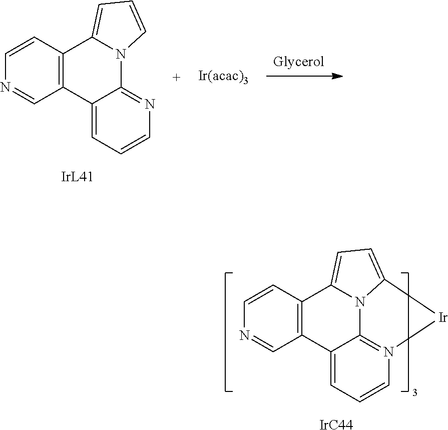

IrL41 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC44 in 5%˜50% yield.

### Example 136

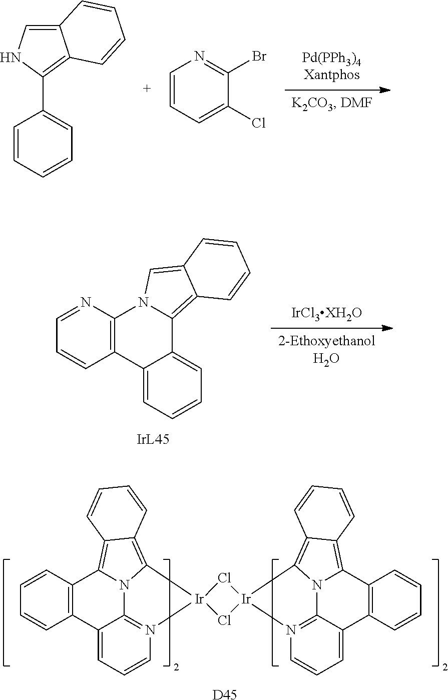

IrL45 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D45 in 40%˜80% yield.

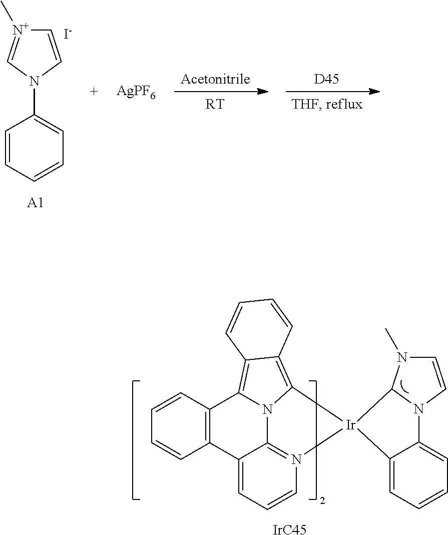

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D45 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC45 in 20%˜60% yield.

### Example 137

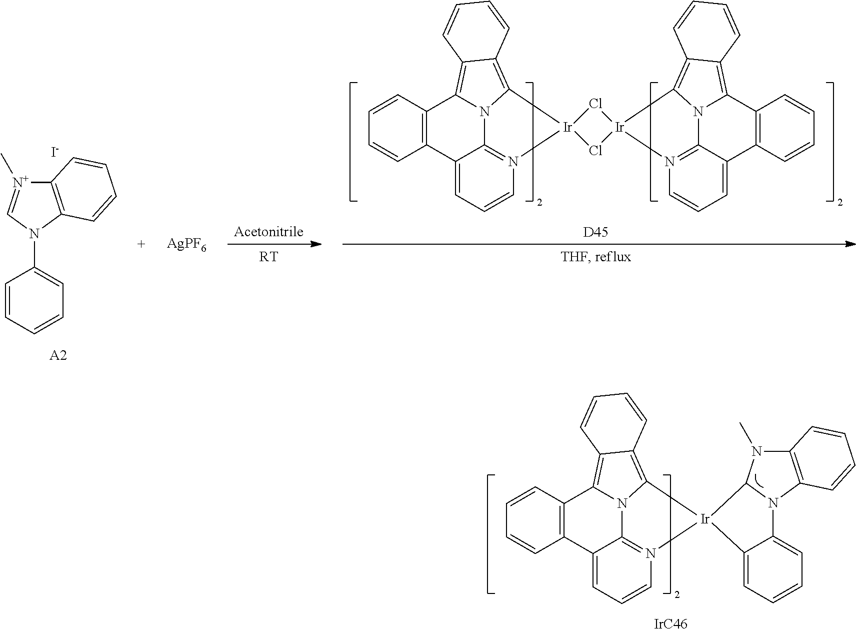

A mixture of ancillary ligand A2 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D45 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC46 in 20%˜60% yield.

### Example 138

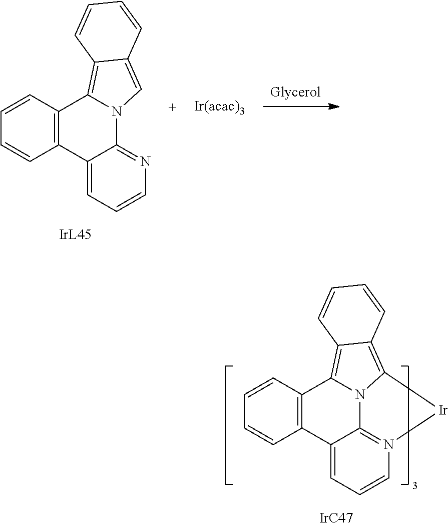

IrL45 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC47 in 5%˜50% yield.

### Example 139

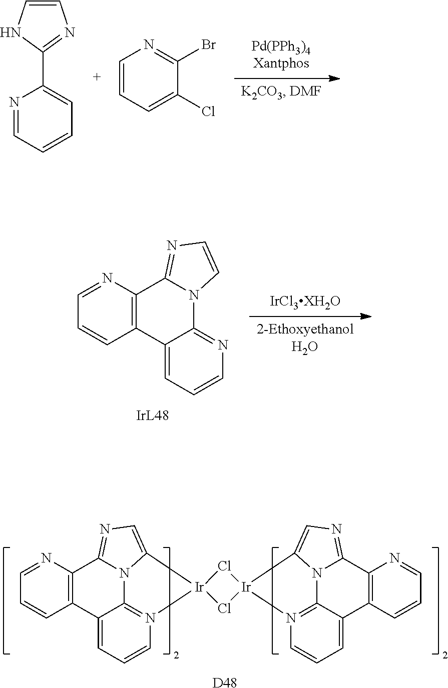

IrL48 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D48 in 40%˜80% yield.

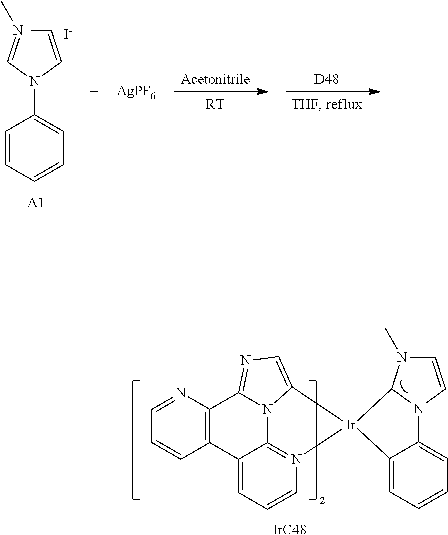

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D48 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC48 in 20%˜60% yield.

### Example 140

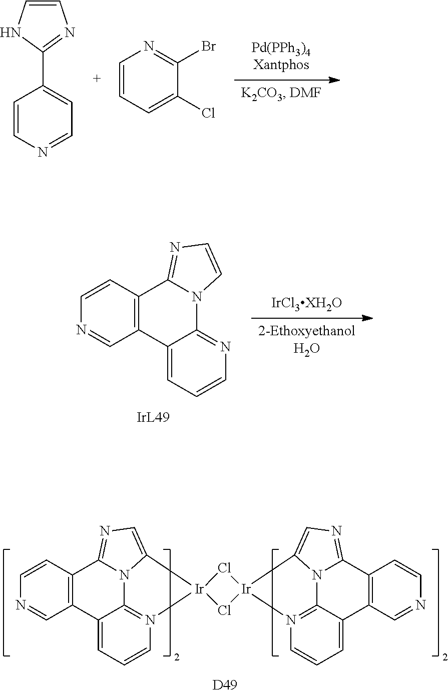

IrL49 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D49 in 40%·80% yield.

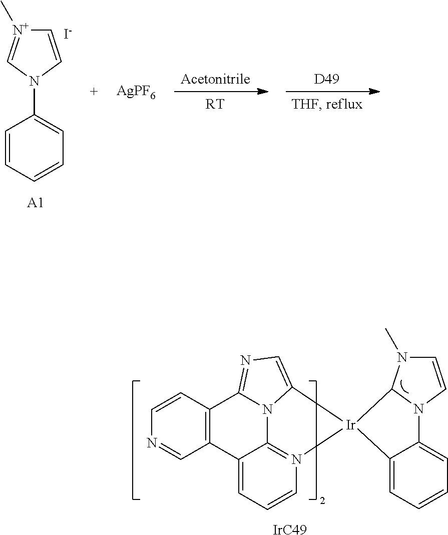

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D49 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC49 in 20%˜60% yield.

### Example 141

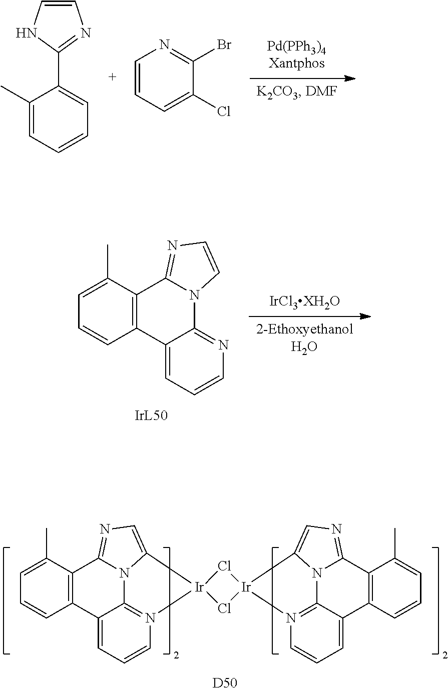

IrL50 (2.2 mmol, 2.2 eq) and IrCl₃·XH₂O (1.0 mmol, 1.0 eq) were added to a dry Shlenck tube equipped with a magnetic stir bar. The tube was evacuated and backfilled with nitrogen. The evacuation and backfill procedure was repeated for a total of three times. Then 2-ethoxyethanol (30 mL) and H₂O (10 mL) were added under the protection of nitrogen. The mixture was stirred in an oil bath at a temperature of 110° C. overnight and then cooled down to ambient temperature. The precipitate was filtered and washed with methanol several times to obtain the desired product chlorodimer D50 in 40%˜80% yield.

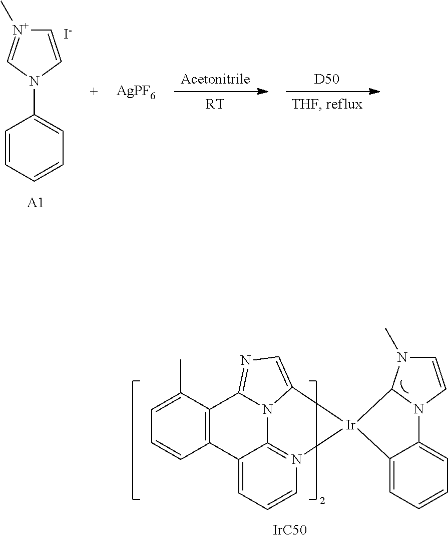

A mixture of ancillary ligand A1 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D50 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC50 in 20%˜60% yield.

### Example 142

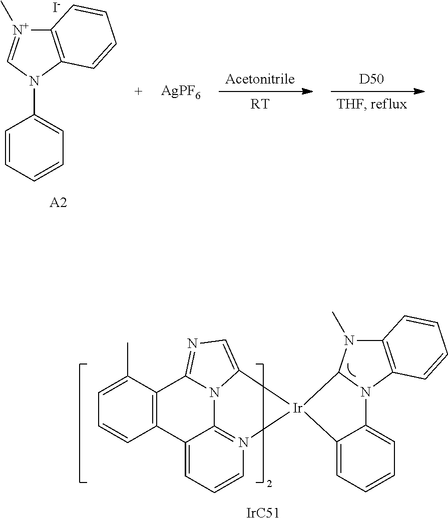

A mixture of ancillary ligand A2 (1.5 mmol, 1.5 eq) and AgPF₆ (0.75 mmol, 0.75 eq) was stirred in a solution of 100 mL of acetonitrile at room temperature for 24 h. The solvent was evaporated to dryness under reduced pressure. Then chlorodimer D50 (1.0 mmol, 1.0 eq) and 150 mL of THF were added. The reaction mixture was heated to reflux for 24 h. Then the mixture was cooled to room temperature, and the precipitate was filtered off. The filtrate was evaporated to dryness under reduced pressure, and then purified by column chromatography to obtain the emitter IrC51 in 20%˜60% yield.

### Example 143

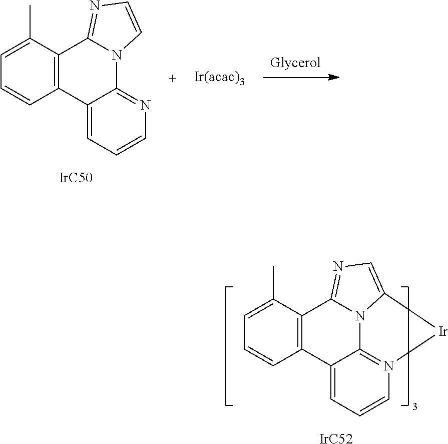

IrL50 (2.5 mmol, 5.0 eq) and Ir(acac)₃ (0.5 mmol, 1.0 eq) were added to a dry Shlenck tube equipped with a magnetic stir bar. The tube was evacuated and backfilled with nitrogen. The evacuation and backfill procedure was repeated for a total of three times. Then 45 mL of glycerol was added under the protection of nitrogen. The mixture was stirred in an oil bath at a temperature of 240° C. for 3 days. After the mixture was cooled down to ambient temperature, 150 mL of 1M HCl solution was added, and the product was thrice extracted with CH₂Cl₂. Then the organic extracts were combined, and dried with MgSO₄. The mixture was evaporated to dryness under reduced pressure, and then purified by column chromatography to obtain the emitter IrC52 in 5%˜50% yield.

Only a few implementations are described and illustrated. Variations, enhancements and improvements of the described implementations and other implementations can be made based on what is described and illustrated in this document.

1.-12. (canceled)

13. A complex represented by General Formula III: 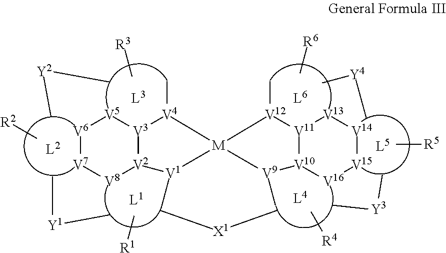
wherein:
M is Pt (II) or Pd (II),
each of V¹—V¹⁶, if present, is independently C, N, Si, O, S, Ge, P, As, Se, B, Al, or Bi, each of X¹, Y¹, Y², Y³, and Y⁴ is independently present or absent, and each X¹, Y¹, Y², Y³, and Y⁴ present independently represents C, N, Si, O, S, Ge, P, As, Se, B, Al, or Bi, or if valency permits, each independently represents CR⁷, SiR⁷, GeR⁷, NR⁷, P═O, As═O, B, BR⁷, AlR⁷, Bi═O, CR⁷R⁸, C═O, SiR⁷R⁸, GeR⁷R⁸, NR⁷, PR⁷, PR⁷R⁸, R⁷P═O, AsR⁷, R⁷As═O, S═O, SO₂, Se═O, SeO₂, BR⁷, BR⁷R⁸, AlR⁷, AlR⁷R⁸, R⁷Bi═O, or BiR⁷,
each of L¹, L², L³, L⁴, L⁵, and L⁶ is independently present or absent, and each L¹, L², L³, L⁴, L⁵, and L⁶ present independently represents a substituted or unsubstituted aryl, heteroaryl, or N-heterocyclic carbene, and
each of R¹, R², R³, R⁴, R⁵, R⁶, R⁷, and R⁸ is independently absent or present as a single substituent or multiple substituents, valency permitting, and each R, R¹, R², R³, R⁴, R⁵, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

14. The complex of claim 13, wherein X¹ represents O.

15. The complex of claim 13, wherein at least one of R¹, R², R³, R⁴, R⁵, or R⁶ represents substituted or unsubstituted aryl.

16. The complex of claim 13, wherein the complex is symmetric.

17. The complex of claim 13, wherein at least one of V⁴ and V¹² is N.

18. The complex of claim 13, wherein the complex is further represented by General Formula V: 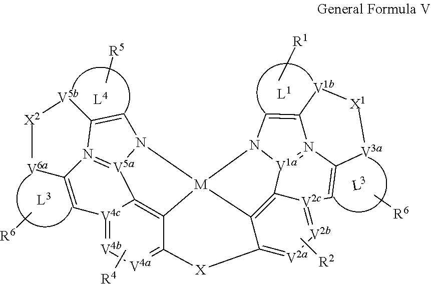
wherein:
M is Pt (II) or Pd (II),
N is nitrogen,
each of V^{1a}, V^{1b}, V^{2a}, V^{2b}, V^{2c}, V^{3a}, V^{4a}, V^{4b}, V^{4c}, V^{5a}, V^{5b}, and V^{6a} is independently N, C, P, O, S, or Si,
each of X, X¹, and X² is independently present or absent, and each X, X¹, and X² present independently represents a single bond, CR⁷R⁸, C═O, SiR⁷R⁸, GeR⁷R⁸, NR⁷, PR⁷, PR⁷R⁸, R⁷P═O, AsR⁷, R⁷As═O, O, S, S═O, SO₂, Se, Se═O, SeO₂, BR⁷, BR⁷R⁸, AlR⁷, AlR⁷R⁸, R⁷Bi═O, or BiR⁷,
each of L¹, L², L³, and L⁴ is independently present or absent, and each L¹, L², L³, and L⁴ present independently represents a substituted or unsubstituted aryl, heteroaryl, or N-heterocyclic carbene,
each of R¹, R², R³, R⁴, R⁵, R⁶, R⁷, and R⁸ is independently absent or present as a single substituent or multiple substituents, valency permitting, and each R¹, R², R³, R⁴, R, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

19. The complex of claim 18, wherein L¹ and L⁴ are each substituted or unsubstituted aryl.

20. The complex of claim 18, wherein at least one of L² and L³ is substituted or unsubstituted heteroaryl.

21. The complex of claim 18, wherein X¹ and X² are absent.

22. The complex of claim 18, wherein L¹ and L⁴ are absent.

23. The complex of claim 13, wherein the complex is further represented by General Formula IX: 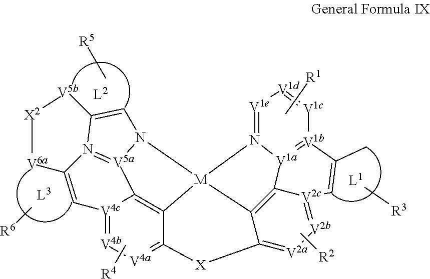
wherein:
M is Pt (II) or Pd (II),
N is nitrogen,
each of V^{1a}-V^{1e}, V^{2a}-V^{2c}, V^{4a}-V^{4c}, V^{5a}, V^{5b}, and V^{6a} is independently N, C, P, O, S, or Si,
each of X and X² is independently present or absent, and each X and X² present independently represents a single bond, CR⁷R⁸, C═O, SiR⁷R⁸, GeR⁷R⁸, NR⁷, PR⁷, PR⁷R⁸, R⁷P═O, AsR⁷, R⁷As═O, O, S, S═O, SO₂, Se, Se═O, SeO₂, BR⁷, BR⁷R⁸, AlR⁷, AlR⁷R⁸, R⁷Bi═O, or BiR⁷,
each of L¹, L², and L³ is independently present or absent, and each L¹, L², and L³ present independently represents a substituted or unsubstituted aryl, heteroaryl, or N-heterocyclic carbene,
each of R¹, R², R³, R⁴, R⁵, R⁶, R⁷, and R⁸ is independently absent or present as a single substituent or multiple substituents, valency permitting, and each R¹, R², R³, R⁴, R⁵, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

24. The complex of claim 13, wherein the complex is further represented by General Formula XIII: 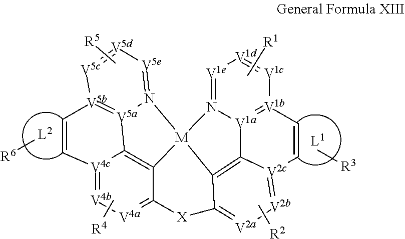
M is Pt (II) or Pd (II),
N is nitrogen,
each of V^{1a}-V^{1e}, V^{2a}-V^{2c}, V^{4a}-V^{4c}, and V^{5a}—V^{5e} is independently N, C, P, O, S, or Si,
X is present or absent, and when present represents a single bond, CR⁷R⁸, C═O, SiR⁷R⁸, GeR⁷R⁸, NR⁷, PR⁷, PR⁷R⁸, R⁷P═O, AsR⁷, R⁷As═O, O, S, S═O, SO₂, Se, Se═O, SeO₂, BR⁷, BR⁷R⁸, AlR⁷, AlR⁷R⁸, R⁷Bi═O, or BiR⁷,
each of L¹ and L² is independently present or absent, and each L¹ and L² present independently represents a substituted or unsubstituted aryl, heteroaryl, or N-heterocyclic carbene,
each of R¹, R², R³, R⁴, R⁵, R⁶, R⁷, and R⁸ is independently absent or present as a single substituent or multiple substituents, valency permitting, and each R¹, R², R³, R⁴, R, R⁶, R⁷, and R⁸ present independently represents deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

25. A light emitting diode comprising the complex of claim 13.

26. A light emitting device comprising the light emitting diode of claim 25.

27. A light emitting diode comprising the complex of claim 18.

28. A light emitting device comprising the light emitting diode of claim 27.

29. A light emitting diode comprising the complex of claim 23.

30. A light emitting device comprising the light emitting diode of claim 29.

31. A light emitting diode comprising the complex of claim 24.

32. A light emitting device comprising the light emitting diode of claim 31.
